(19) United States
(12) Patent Application Publication
(10) Pub. No.: US 2026/0282739 A1
(43) Pub. Date: Sep. 17, 2026

(54) ORGANIC ELECTROLUMINESCENT ELEMENT AND ELECTRONIC DEVICE

(71) Applicant: IDEMITSU KOSAN CO.,LTD., Tokyo (JP)

(72) Inventors: Kazuma MASE, Tokyo (JP); Satomi TASAKI, Tokyo (JP); Tetsuya MASUDA, Tokyo (JP)

(73) Assignee: IDEMITSU KOSAN CO.,LTD., Tokyo (JP)

(21) Appl. No.: 18/871,968

(22) PCT Filed: Jun. 7, 2023
(86) PCT No.: PCT/JP2023/021196

§ 371 Date: Dec. 5, 2024

(30) Foreign Application Priority Data
Jun. 7, 2022 (JP) 2022-092448

(51) Int. Cl. H10K 85/60; C09K 11/02; C09K 11/06; H10K 50/12; H10K 101/00

(52) U.S. Cl. CPC H10K 85/636; C09K 11/02; C09K 11/06; C09K 2211/1007; C09K 2211/1011; C09K 2211/1014; C09K 2211/1022; H10K 50/12; H10K 85/615; H10K 85/658; H10K 2101/90

(57) ABSTRACT

An organic electroluminescence device includes a first and second emitting layer, in which the first emitting layer contains a first host material and a first luminescent compound, the second emitting layer contains a second host material and a second luminescent compound, the first and second host material are mutually different, the first and second luminescent compound are mutually the same or different, a triplet energy of the first host material T₁(H1) and a triplet energy of the second one T₁(H2) satisfy a relationship of a Numerical Formula 1 below, the first luminescent compound exhibits a first orientation (σ₁) in a first film, the second one exhibits a second orientation (σ₂) in a second film, and a ratio of the first orientation (σ₁) to the second orientation (σ₂) satisfies a relationship of a Numerical Formula 2 below,

$${T}_{1} ( H 1 ) > {T}_{1} ( H 2 ) \qquad ( Numerical Formula 1 )$$

$${σ}_{1} / {σ}_{2} \geq 0.9 . \qquad ( Numerical Formula 2 )$$

### TECHNICAL FIELD

The present invention relates to an organic electroluminescence device and an electronic device.

### BACKGROUND ART

An organic electroluminescence device (hereinafter, occasionally referred to as “organic EL device”) has found its application in a full-color display for mobile phones, televisions, and the like. When voltage is applied to an organic EL device, holes are injected from an anode and electrons are injected from a cathode into an emitting layer. The injected holes and electrons are recombined in the emitting layer to form excitons. At this time, according to the electron spin statistics theory, singlet excitons and triplet excitons are generated at a ratio of 25%:75%.

In order to improve the performance of the organic EL device, various studies have been made on compounds to be used for an organic EL device in, for instance, Patent Literature 1.

The performance of the organic EL device is evaluable in terms of, for instance, luminance, emission wavelength, chromaticity, luminous efficiency, drive voltage, and lifetime.

### CITATION LIST

### Patent Literature(s)

Patent Literature 1: International Publication No. WO 2021/210305

### SUMMARY OF THE INVENTION

### Problem(s) to be Solved by the Invention

An object of the invention is to provide an organic electroluminescence device with improved performance. Another object of the invention is to provide an organic electroluminescence device with improved luminous efficiency and an electronic device including such an organic electroluminescence device.

### Means for Solving the Problem(s)

According to an aspect of the invention, there is provided an organic electroluminescence device that includes an anode; a cathode; and an emitting region between the anode and the cathode, in which the emitting region includes a first emitting layer and a second emitting layer, the first emitting layer contains a first host material and a first luminescent compound, the second emitting layer contains a second host material and a second luminescent compound, the first host material and the second host material are mutually different, the first luminescent compound and the second luminescent compound are mutually the same or different, a triplet energy of the first host material T₁(H1) and a triplet energy of the second host material T₁(H2) satisfy a relationship of a numerical formula (Numerical Formula 1) below, the first luminescent compound exhibits a first orientation (σ₁) in a first film containing the first host material and the first luminescent compound, the second luminescent compound exhibits a second orientation (σ₂) in a second film containing the second host material and the second luminescent compound, and a ratio of the first orientation (σ₁) to the second orientation (σ₂) satisfies a relationship of a numerical formula (Numerical Formula 2) below.

$${T}_{1} ( H 1 ) > {T}_{1} ( H 2 ) \qquad ( Numerical Formula 1 )$$

$${σ}_{1} / {σ}_{2} \geq 0.9 \qquad ( Numerical Formula 2 )$$

According to another aspect of the invention, there is provided an electronic device including the organic electroluminescence device according to the above aspect of the invention.

According to the above aspect of the invention, an organic electroluminescence device with improved performance can be provided. According to the above aspect of the invention, an organic electroluminescence device with improved luminous efficiency can be provided. According to the above aspect of the invention, there is provided an electronic device including such an organic electroluminescence device.

### BRIEF DESCRIPTION OF DRAWINGS

FIG. 1 schematically illustrates an exemplary arrangement of an organic electroluminescence device according to an exemplary embodiment of the invention.

FIG. 2 schematically illustrates another exemplary arrangement of the organic electroluminescence device according to the exemplary embodiment of the invention.

FIG. 3 is a view for explaining a method of measuring a first orientation and a second orientation.

FIG. 4 is a view for explaining the method of measuring the first orientation and the second orientation.

FIG. 5 is a view for explaining the method of measuring the first orientation and the second orientation.

FIG. 6 schematically illustrates an exemplary apparatus used in the method of measuring the first orientation and the second orientation.

FIG. 7 is a graph illustrating an example of angular dependency of photoluminescence intensity of p polarized light, at 465 nm of a photoluminescence spectrum.

FIG. 8 illustrates a measurement system of transient EL waveform.

FIG. 9 is a diagram illustrating a method of measuring a ratio of luminous intensity derived from TTF and a time-varying luminous intensity of an EL device.

FIG. 10 is a diagram illustrating a method of measuring a ratio of luminous intensity derived from TTF and a time-varying inverse number of a square root of luminous intensity.

### DESCRIPTION OF EMBODIMENT(S)

### Definitions

Herein, a hydrogen atom includes isotope having different numbers of neutrons, specifically, protium, deuterium and tritium.

In chemical formulae herein, it is assumed that a hydrogen atom (i.e. protium, deuterium and tritium) is bonded to each of bondable positions that are not annexed with signs “R” or the like or “D” representing a deuterium.

Herein, the ring carbon atoms refer to the number of carbon atoms among atoms forming a ring of a compound (e.g., a monocyclic compound, fused-ring compound, crosslinking compound, carbon ring compound, and heterocyclic compound) in which the atoms are bonded to each other to form the ring. When the ring is substituted by a substituent(s), carbon atom(s) contained in the substituent(s) is not counted in the ring carbon atoms. Unless specifically described, the same applies to the “ring carbon atoms” described later. For instance, a benzene ring has 6 ring carbon atoms, a naphthalene ring has 10 ring carbon atoms, a pyridine ring has 5 ring carbon atoms, and a furan ring has 4 ring carbon atoms. Further, for instance, 9,9-diphenylfluorenyl group has 13 ring carbon atoms and 9,9′-spirobifluorenyl group has 25 ring carbon atoms.

When a benzene ring is substituted by a substituent in a form of, for instance, an alkyl group, the number of carbon atoms of the alkyl group is not counted in the number of the ring carbon atoms of the benzene ring. Accordingly, the benzene ring substituted by an alkyl group has 6 ring carbon atoms. When a naphthalene ring is substituted by a substituent in a form of, for instance, an alkyl group, the number of carbon atoms of the alkyl group is not counted in the number of the ring carbon atoms of the naphthalene ring. Accordingly, the naphthalene ring substituted by an alkyl group has 10 ring carbon atoms.

Herein, the ring atoms refer to the number of atoms forming a ring of a compound (e.g., a monocyclic compound, fused-ring compound, cross-linking compound, carbon ring compound, and heterocyclic compound) in which the atoms are bonded to each other to form the ring (e.g., monocyclic ring, fused ring, and ring assembly). Atom(s) not forming the ring (e.g., hydrogen atom(s) for saturating the valence of the atom which forms the ring) and atom(s) in a substituent by which the ring is substituted are not counted as the ring atoms. Unless otherwise specified, the same applies to the “ring atoms” described later. For instance, a pyridine ring has 6 ring atoms, a quinazoline ring has 10 ring atoms, and a furan ring has 5 ring atoms. For instance, the number of hydrogen atom(s) bonded to a pyridine ring or the number of atoms forming a substituent is not counted as the ring atoms of the pyridine ring. Accordingly, a pyridine ring bonded to a hydrogen atom(s) or a substituent(s) has 6 ring atoms. For instance, the hydrogen atom(s) bonded to carbon atom(s) of a quinazoline ring or the atoms forming a substituent are not counted as the quinazoline ring atoms. Accordingly, a quinazoline ring bonded to hydrogen atom(s) or a substituent(s) has 10 ring atoms.

Herein, “XX to YY carbon atoms” in the description of “substituted or unsubstituted ZZ group having XX to YY carbon atoms” represent carbon atoms of an unsubstituted ZZ group and do not include carbon atoms of a substituent(s) of the substituted ZZ group. Herein, “YY” is larger than “XX,” “XX” representing an integer of 1 or more and “YY” representing an integer of 2 or more.

Herein, “XX to YY atoms” in the description of “substituted or unsubstituted ZZ group having XX to YY atoms” represent atoms of an unsubstituted ZZ group and does not include atoms of a substituent(s) of the substituted ZZ group. Herein, “YY” is larger than “XX,” “XX” representing an integer of 1 or more and “YY” representing an integer of 2 or more.

Herein, an unsubstituted ZZ group refers to an “unsubstituted ZZ group” in a “substituted or unsubstituted ZZ group,” and a substituted ZZ group refers to a “substituted ZZ group” in a “substituted or unsubstituted ZZ group.”

Herein, the term “unsubstituted” used in a “substituted or unsubstituted ZZ group” means that a hydrogen atom(s) in the ZZ group is not substituted with a substituent(s). The hydrogen atom(s) in the “unsubstituted ZZ group” is protium, deuterium, or tritium.

Herein, the term “substituted” used in a “substituted or unsubstituted ZZ group” means that at least one hydrogen atom in the ZZ group is substituted with a substituent. Similarly, the term “substituted” used in a “BB group substituted by AA group” means that at least one hydrogen atom in the BB group is substituted with the AA group.

### Substituents Mentioned Herein

Substituents mentioned herein will be described below.

An “unsubstituted aryl group” mentioned herein has, unless otherwise specified herein, 6 to 50, preferably 6 to 30, more preferably 6 to 18 ring carbon atoms.

An “unsubstituted heterocyclic group” mentioned herein has, unless otherwise specified herein, 5 to 50, preferably 5 to 30, more preferably 5 to 18 ring atoms.

An “unsubstituted alkyl group” mentioned herein has, unless otherwise specified herein, 1 to 50, preferably 1 to 20, more preferably 1 to 6 carbon atoms.

An “unsubstituted alkenyl group” mentioned herein has, unless otherwise specified herein, 2 to 50, preferably 2 to 20, more preferably 2 to 6 carbon atoms.

An “unsubstituted alkynyl group” mentioned herein has, unless otherwise specified herein, 2 to 50, preferably 2 to 20, more preferably 2 to 6 carbon atoms.

An “unsubstituted cycloalkyl group” mentioned herein has, unless otherwise specified herein, 3 to 50, preferably 3 to 20, more preferably 3 to 6 ring carbon atoms.

An “unsubstituted arylene group” mentioned herein has, unless otherwise specified herein, 6 to 50, preferably 6 to 30, more preferably 6 to 18 ring carbon atoms.

An “unsubstituted divalent heterocyclic group” mentioned herein has, unless otherwise specified herein, 5 to 50, preferably 5 to 30, more preferably 5 to 18 ring atoms.

An “unsubstituted alkylene group” mentioned herein has, unless otherwise specified herein, 1 to 50, preferably 1 to 20, more preferably 1 to 6 carbon atoms.

### Substituted or Unsubstituted Aryl Group

Specific examples (specific example group G1) of the “substituted or unsubstituted aryl group” mentioned herein include unsubstituted aryl groups (specific example group G1A) and substituted aryl groups (specific example group G1B) below. (Herein, an unsubstituted aryl group refers to an “unsubstituted aryl group” in a “substituted or unsubstituted aryl group”, and a substituted aryl group refers to a “substituted aryl group” in a “substituted or unsubstituted aryl group.”) A simply termed “aryl group” herein includes both of an “unsubstituted aryl group” and a “substituted aryl group”.

The “substituted aryl group” refers to a group derived by substituting at least one hydrogen atom in an “unsubstituted aryl group” with a substituent. Examples of the “substituted aryl group” include a group derived by substituting at least one hydrogen atom in the “unsubstituted aryl group” in the specific example group G1A below with a substituent, and examples of the substituted aryl group in the specific example group G1B below. It should be noted that the examples of the “unsubstituted aryl group” and the “substituted aryl group” mentioned herein are merely exemplary, and the “substituted aryl group” mentioned herein includes a group derived by further substituting a hydrogen atom bonded to a carbon atom of a skeleton of a “substituted aryl group” in the specific example group G1B below with a substituent, and a group derived by further substituting a hydrogen atom of a substituent of the “substituted aryl group” in the specific example group G1B below with a substituent.

### Unsubstituted Aryl Group (Specific Example Group G1A):

a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, benzanthryl group, phenanthryl group, benzophenanthryl group, phenalenyl group, pyrenyl group, chrysenyl group, benzochrysenyl group, triphenylenyl group, benzotriphenylenyl group, tetracenyl group, pentacenyl group, fluorenyl group, 9,9′-spirobifluorenyl group, benzofluorenyl group, dibenzofluorenyl group, fluoranthenyl group, benzofluoranthenyl group, perylenyl group, and monovalent aryl group derived by removing one hydrogen atom from cyclic structures represented by formulae (TEMP-1) to (TEMP-15) below.

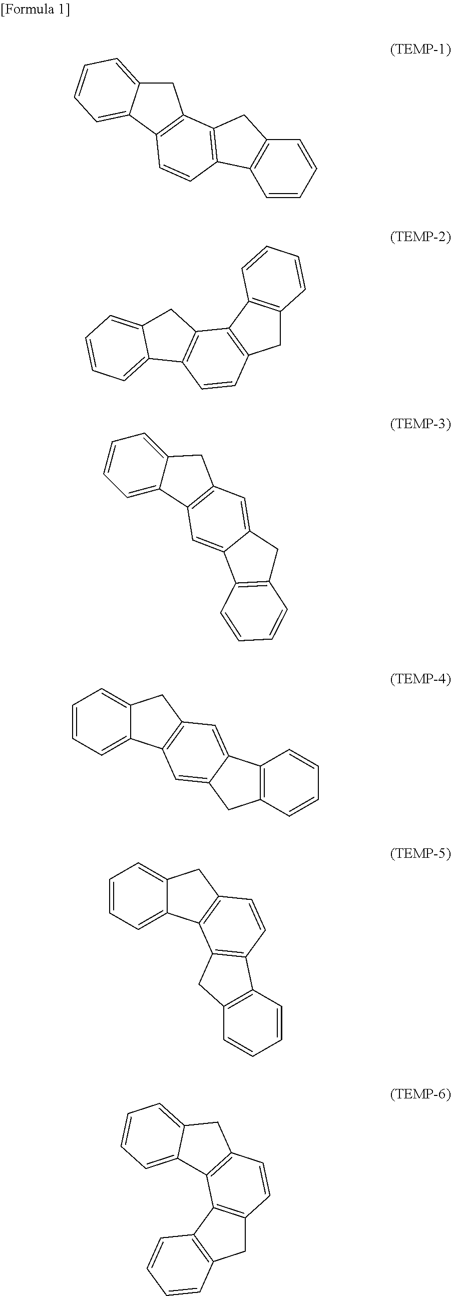

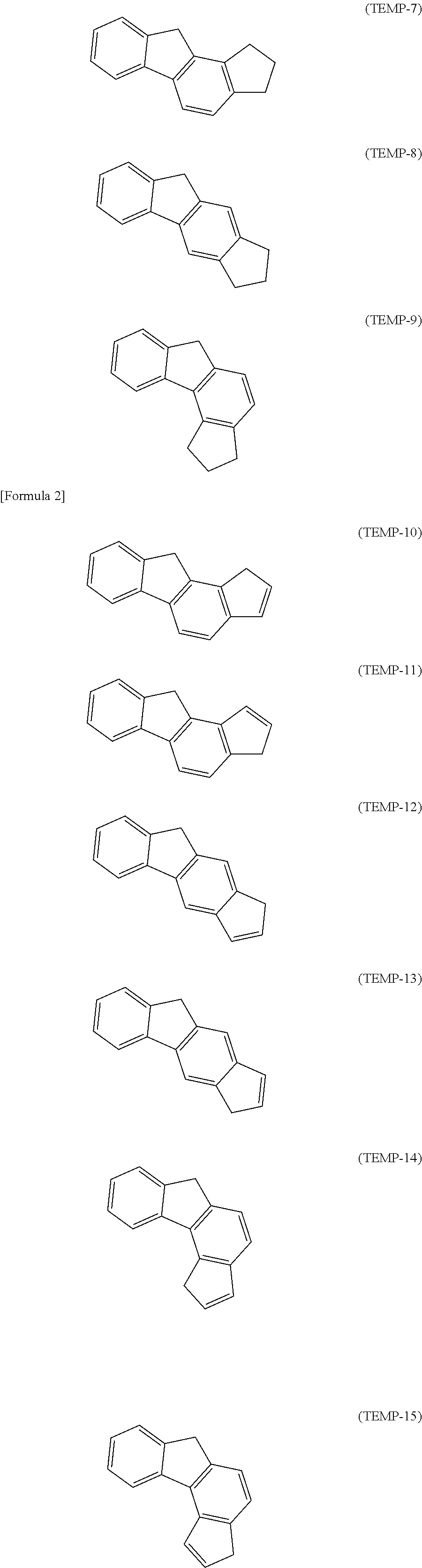

### Substituted Aryl Group (Specific Example Group G1B):

an o-tolyl group, m-tolyl group, p-tolyl group, para-xylyl group, meta-xylyl group, ortho-xylyl group, para-isopropylphenyl group, meta-isopropylphenyl group, ortho-isopropylphenyl group, para-t-butylphenyl group, meta-t-butylphenyl group, ortho-t-butylphenyl group, 3,4,5-trimethylphenyl group, 9,9-dimethylfluorenyl group, 9,9-diphenylfluorenyl group, 9,9-bis(4-methylphenyl)fluorenyl group, 9,9-bis(4-isopropylphenyl)fluorenyl group, 9,9-bis(4-t-butylphenyl)fluorenyl group, cyanophenyl group, triphenylsilylphenyl group, trimethylsilylphenyl group, phenylnaphthyl group, naphthylphenyl group, and group derived by substituting at least one hydrogen atom of a monovalent group derived from one of the cyclic structures represented by the formulae (TEMP-1) to (TEMP-15) with a substituent.

### Substituted or Unsubstituted Heterocyclic Group

The “heterocyclic group” mentioned herein refers to a cyclic group having at least one hetero atom in the ring atoms. Specific examples of the hetero atom include a nitrogen atom, oxygen atom, sulfur atom, silicon atom, phosphorus atom, and boron atom.

The “heterocyclic group” mentioned herein is a monocyclic group or a fused-ring group.

The “heterocyclic group” mentioned herein is an aromatic heterocyclic group or a non-aromatic heterocyclic group.

Specific examples (specific example group G2) of the “substituted or unsubstituted heterocyclic group” mentioned herein include unsubstituted heterocyclic groups (specific example group G2A) and substituted heterocyclic groups (specific example group G2B) below. (Herein, an unsubstituted heterocyclic group refers to an “unsubstituted heterocyclic group” in a “substituted or unsubstituted heterocyclic group,” and a substituted heterocyclic group refers to a “substituted heterocyclic group” in a “substituted or unsubstituted heterocyclic group.”) A simply termed “heterocyclic group” herein includes both of an “unsubstituted heterocyclic group” and a “substituted heterocyclic group.”

The “substituted heterocyclic group” refers to a group derived by substituting at least one hydrogen atom in an “unsubstituted heterocyclic group” with a substituent. Specific examples of the “substituted heterocyclic group” include examples of a group derived by substituting at least one hydrogen atom in the “unsubstituted heterocyclic group” in the specific example group G2A below with a substituent, and examples of the substituted heterocyclic group in the specific example group G2B below. It should be noted that the examples of the “unsubstituted heterocyclic group” and the “substituted heterocyclic group” mentioned herein are merely exemplary, and the “substituted heterocyclic group” mentioned herein includes a group derived by further substituting a hydrogen atom bonded to a ring atom of a skeleton of a “substituted heterocyclic group” in the specific example group G2B below with a substituent, and a group derived by further substituting a hydrogen atom of a substituent of the “substituted heterocyclic group” in the specific example group G2B below with a substituent.

The specific example group G2A includes, for instance, unsubstituted heterocyclic groups including a nitrogen atom (specific example group G2A1) below, unsubstituted heterocyclic groups including an oxygen atom (specific example group G2A2) below, unsubstituted heterocyclic groups including a sulfur atom (specific example group G2A3) below, and monovalent heterocyclic groups (specific example group G2A4) derived by removing one hydrogen atom from cyclic structures represented by formulae (TEMP-16) to (TEMP-33) below.

The specific example group G2B includes, for instance, substituted heterocyclic groups including a nitrogen atom (specific example group G2B1) below, substituted heterocyclic groups including an oxygen atom (specific example group G2B2) below, substituted heterocyclic groups including a sulfur atom (specific example group G2B3) below, and groups derived by substituting at least one hydrogen atom of the monovalent heterocyclic groups (specific example group G2B4) derived from the cyclic structures represented by the formulae (TEMP-16) to (TEMP-33) below with a substituent.

### Unsubstituted Heterocyclic Groups Including Nitrogen Atom (Specific Example Group G2A1):

a pyrrolyl group, imidazolyl group, pyrazolyl group, triazolyl group, tetrazolyl group, oxazolyl group, isoxazolyl group, oxadiazolyl group, thiazolyl group, isothiazolyl group, thiadiazolyl group, pyridyl group, pyridazynyl group, pyrimidinyl group, pyrazinyl group, triazinyl group, indolyl group, isoindolyl group, indolizinyl group, quinolizinyl group, quinolyl group, isoquinolyl group, cinnolyl group, phthalazinyl group, quinazolinyl group, quinoxalinyl group, benzimidazolyl group, indazolyl group, phenanthrolinyl group, phenanthridinyl group, acridinyl group, phenazinyl group, carbazolyl group, benzocarbazolyl group, morpholino group, phenoxazinyl group, phenothiazinyl group, azacarbazolyl group, and diazacarbazolyl group.

### Unsubstituted Heterocyclic Groups Including Oxygen Atom (Specific Example Group G2A2):

a furyl group, oxazolyl group, isoxazolyl group, oxadiazolyl group, xanthenyl group, benzofuranyl group, isobenzofuranyl group, dibenzofuranyl group, naphthobenzofuranyl group, benzoxazolyl group, benzisoxazolyl group, phenoxazinyl group, morpholino group, dinaphthofuranyl group, azadibenzofuranyl group, diazadibenzofuranyl group, azanaphthobenzofuranyl group, and diazanaphthobenzofuranyl group.

### Unsubstituted Heterocyclic Groups Including Sulfur Atom (Specific Example Group G2A3):

a thienyl group, thiazolyl group, isothiazolyl group, thiadiazolyl group, benzothiophenyl group (benzothienyl group), isobenzothiophenyl group (isobenzothienyl group), dibenzothiophenyl group (dibenzothienyl group), naphthobenzothiophenyl group (nahthobenzothienyl group), benzothiazolyl group, benzisothiazolyl group, phenothiazinyl group, dinaphthothiophenyl group (dinaphthothienyl group), azadibenzothiophenyl group (azadibenzothienyl group), diazadibenzothiophenyl group (diazadibenzothienyl group), azanaphthobenzothiophenyl group (azanaphthobenzothienyl group), and diazanaphthobenzothiophenyl group (diazanaphthobenzothienyl group).
   Monovalent Heterocyclic Groups Derived by Removing One Hydrogen Atom from Cyclic Structures Represented by Formulae (TEMP-16) to (TEMP-33) (Specific Example Group G2A4):

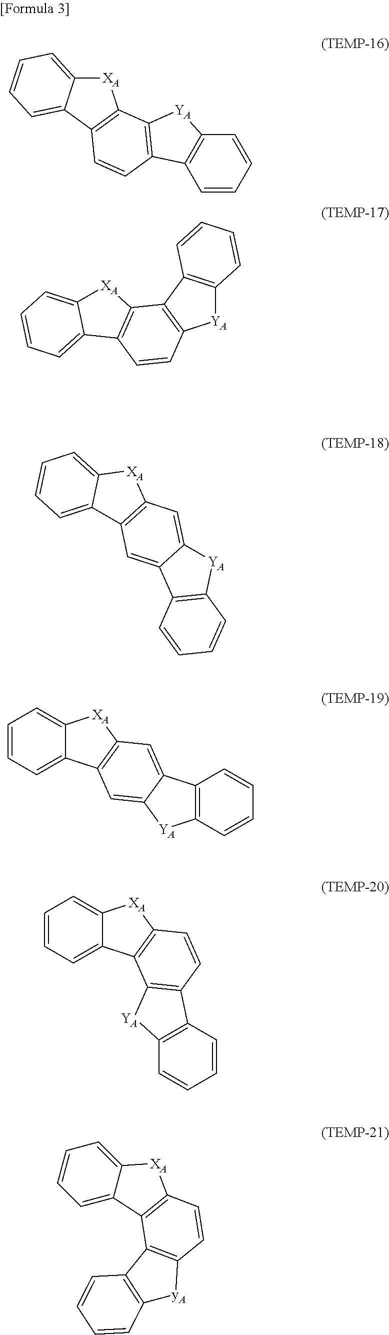

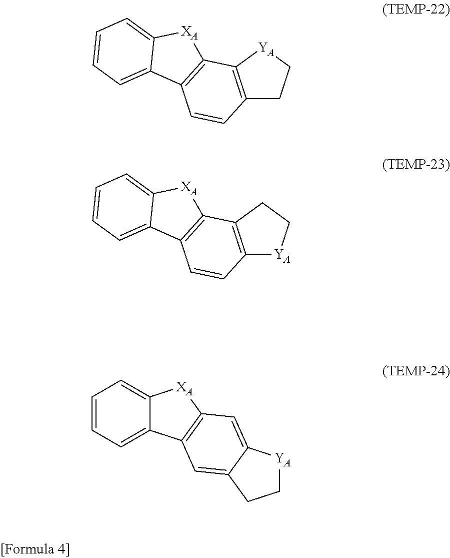

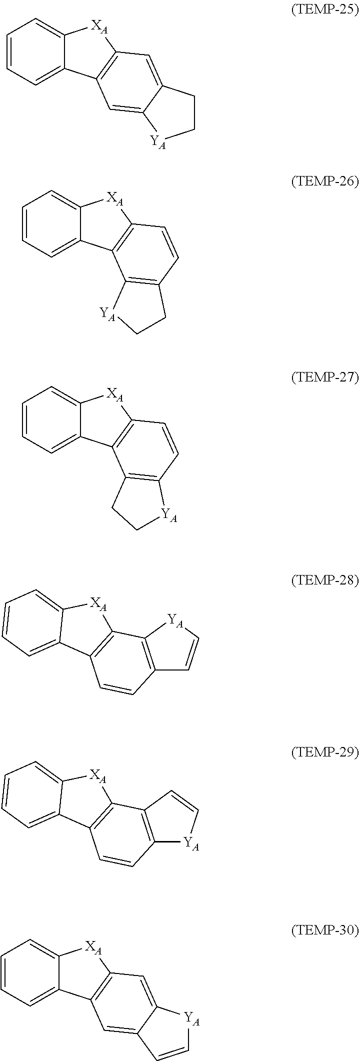

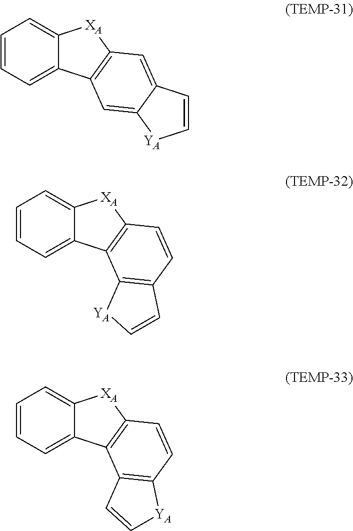

In the formulae (TEMP-16) to (TEMP-33), X_{A} and Y_{A} are each independently an oxygen atom, a sulfur atom, NH or CH₂, with a proviso that at least one of X_{A} or Y_{A} is an oxygen atom, a sulfur atom, or NH.

When at least one of X_{A} or Y_{A} in the formulae (TEMP-16) to (TEMP-33) is NH or CH₂, the monovalent heterocyclic groups derived from the cyclic structures represented by the formulae (TEMP-16) to (TEMP-33) include a monovalent group derived by removing one hydrogen atom from NH or CH₂.

### Substituted Heterocyclic Groups Including Nitrogen Atom (Specific Example Group G2B1):

a (9-phenyl)carbazolyl group, (9-biphenylyl)carbazolyl group, (9-phenyl)phenylcarbazolyl group, (9-naphthyl)carbazolyl group, diphenylcarbazole-9-yl group, phenylcarbazole-9-yl group, methylbenzimidazolyl group, ethylbenzimidazolyl group, phenyltriazinyl group, biphenylyltriazinyl group, diphenyltriazinyl group, phenylquinazolinyl group, and biphenylquinazolinyl group.

### Substituted Heterocyclic Groups Including Oxygen Atom (Specific Example Group G2B2):

a phenyldibenzofuranyl group, methyldibenzofuranyl group, t-butyl dibenzofuranyl group, and monovalent residue of spiro[9H-xanthene-9,9′-[9H]fluorene].

### Substituted Heterocyclic Groups Including Sulfur Atom (Specific Example Group G2B3):

a phenyldibenzothiophenyl group, methyldibenzothiophenyl group, t-butyl dibenzothiophenyl group, and monovalent residue of spiro[9H-thioxanthene-9,9′-[9H]fluorene].
   Groups Obtained by Substituting at Least One Hydrogen Atom of Monovalent Heterocyclic Group Derived from Cyclic Structures Represented by Formulae (TEMP-16) to (TEMP-33) with Substituent (Specific Example Group G2B4):

The “at least one hydrogen atom of a monovalent heterocyclic group” means at least one hydrogen atom selected from a hydrogen atom bonded to a ring carbon atom of the monovalent heterocyclic group, a hydrogen atom bonded to a nitrogen atom of at least one of X_{A} or Y_{A} in a form of NH, and a hydrogen atom of one of X_{A} and Y_{A} in a form of a methylene group (CH₂).

### Substituted or Unsubstituted Alkyl Group

Specific examples (specific example group G3) of the “substituted or unsubstituted alkyl group” mentioned herein include unsubstituted alkyl groups (specific example group G3A) and substituted alkyl groups (specific example group G3B) below. (Herein, an unsubstituted alkyl group refers to an “unsubstituted alkyl group” in a “substituted or unsubstituted alkyl group,” and a substituted alkyl group refers to a “substituted alkyl group” in a “substituted or unsubstituted alkyl group.”) A simply termed “alkyl group” herein includes both of an “unsubstituted alkyl group” and a “substituted alkyl group”.

The “substituted alkyl group” refers to a group derived by substituting at least one hydrogen atom in an “unsubstituted alkyl group” with a substituent. Specific examples of the “substituted alkyl group” include a group derived by substituting at least one hydrogen atom of an “unsubstituted alkyl group” (specific example group G3A) below with a substituent, and examples of the substituted alkyl group (specific example group G3B) below. Herein, the alkyl group for the “unsubstituted alkyl group” refers to a chain alkyl group. Accordingly, the “unsubstituted alkyl group” include linear “unsubstituted alkyl group” and branched “unsubstituted alkyl group.” It should be noted that the examples of the “unsubstituted alkyl group” and the “substituted alkyl group” mentioned herein are merely exemplary, and the “substituted alkyl group” mentioned herein includes a group derived by further substituting a hydrogen atom of a skeleton of the “substituted alkyl group” in the specific example group G3B with a substituent, and a group derived by further substituting a hydrogen atom of a substituent of the “substituted alkyl group” in the specific example group G3B with a substituent.

### Unsubstituted Alkyl Group (Specific Example Group G3A):

a methyl group, ethyl group, n-propyl group, isopropyl group, n-butyl group, isobutyl group, s-butyl group, and t-butyl group.

### Substituted Alkyl Groups (Specific Example Group G3B):

Heptafluoropropyl Group (including Isomer thereof), pentafluoroethyl group, 2,2,2-trifluoroethyl group, and trifluoromethyl group.

### Substituted or Unsubstituted Alkenyl Group

Specific examples (specific example group G4) of the “substituted or unsubstituted alkenyl group” mentioned herein include unsubstituted alkenyl groups (specific example group G4A) and substituted alkenyl groups (specific example group G4B). (Herein, an unsubstituted alkenyl group refers to an “unsubstituted alkenyl group” in a “substituted or unsubstituted alkenyl group,” and a substituted alkenyl group refers to a “substituted alkenyl group” in a “substituted or unsubstituted alkenyl group.”) A simply termed “alkenyl group” herein includes both of an “unsubstituted alkenyl group” and a “substituted alkenyl group”.

The “substituted alkenyl group” refers to a group derived by substituting at least one hydrogen atom in an “unsubstituted alkenyl group” with a substituent. Specific examples of the “substituted alkenyl group” include an “unsubstituted alkenyl group” (specific example group G4A) substituted by a substituent, and examples of the substituted alkenyl group (specific example group G4B) below. It should be noted that the examples of the “unsubstituted alkenyl group” and the “substituted alkenyl group” mentioned herein are merely exemplary, and the “substituted alkenyl group” mentioned herein includes a group derived by further substituting a hydrogen atom of a skeleton of the “substituted alkenyl group” in the specific example group G4B with a substituent, and a group derived by further substituting a hydrogen atom of a substituent of the “substituted alkenyl group” in the specific example group G4B with a substituent.

### Unsubstituted Alkenyl Group (Specific Example Group G4A):

a vinyl group, allyl group, 1-butenyl group, 2-butenyl group, and 3-butenyl group.

### Substituted Alkenyl Group (Specific Example Group G4B):

a 1,3-butanedienyl group, 1-methylvinyl group, 1-methylallyl group, 1,1-dimethylallyl group, 2-methylallyl group, and 1,2-dimethylallyl group.

### Substituted or Unsubstituted Alkynyl Group

Specific examples (specific example group G5) of the “substituted or unsubstituted alkynyl group” mentioned herein include unsubstituted alkynyl groups (specific example group G5A) below. (Herein, an unsubstituted alkynyl group refers to an “unsubstituted alkynyl group” in a “substituted or unsubstituted alkynyl group.”) A simply termed “alkynyl group” herein includes both of “unsubstituted alkynyl group” and “substituted alkynyl group”.

The “substituted alkynyl group” refers to a group derived by substituting at least one hydrogen atom in an “unsubstituted alkynyl group” with a substituent. Specific examples of the “substituted alkynyl group” include a group derived by substituting at least one hydrogen atom of the “unsubstituted alkynyl group” (specific example group G5A) below with a substituent.

### Unsubstituted Alkynyl Group (Specific Example Group G5A):

an ethynyl group.

### Substituted or Unsubstituted Cycloalkyl Group

Specific examples (specific example group G6) of the “substituted or unsubstituted cycloalkyl group” mentioned herein include unsubstituted cycloalkyl groups (specific example group G6A) and substituted cycloalkyl groups (specific example group G6B). (Herein, an unsubstituted cycloalkyl group refers to an “unsubstituted cycloalkyl group” in a “substituted or unsubstituted cycloalkyl group,” and a substituted cycloalkyl group refers to a “substituted cycloalkyl group” in a “substituted or unsubstituted cycloalkyl group.”) A simply termed “cycloalkyl group” herein includes both of “unsubstituted cycloalkyl group” and “substituted cycloalkyl group”.

The “substituted cycloalkyl group” refers to a group derived by substituting at least one hydrogen atom of an “unsubstituted cycloalkyl group” with a substituent. Specific examples of the “substituted cycloalkyl group” include a group derived by substituting at least one hydrogen atom of the “unsubstituted cycloalkyl group” (specific example group G6A) below with a substituent, and examples of the substituted cycloalkyl group (specific example group G6B) below. It should be noted that the examples of the “unsubstituted cycloalkyl group” and the “substituted cycloalkyl group” mentioned herein are merely exemplary, and the “substituted cycloalkyl group” mentioned herein includes a group derived by substituting at least one hydrogen atom bonded to a carbon atom of a skeleton of the “substituted cycloalkyl group” in the specific example group G6B with a substituent, and a group derived by further substituting a hydrogen atom of a substituent of the “substituted cycloalkyl group” in the specific example group G6B with a substituent.

### Unsubstituted Cycloalkyl Group (Specific Example Group G6A):

a cyclopropyl group, cyclobutyl group, cyclopentyl group, cyclohexyl group, 1-adamantyl group, 2-adamantyl group, 1-norbornyl group, and 2-norbornyl group.

### Substituted Cycloalkyl Group (Specific Example Group G6B):

a 4-methylcyclohexyl group.
   Group Represented by —Si(R₉₀₁)(R₉₀₂)(R₉₀₃)

Specific examples (specific example group G7) of the group represented herein by —Si(R₉₀₁)(R₉₀₂)(R₉₀₃) include: —Si(G1)(G1)(G1); —Si(G1)(G2)(G2); —Si(G1)(G1)(G2); —Si(G2)(G2)(G2); —Si(G3)(G3)(G3); and —Si(G6)(G6)(G6);

where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3;
G6 represents a “substituted or unsubstituted cycloalkyl group” in the specific example group G6;
a plurality of G1 in —Si(G1)(G1)(G1) are mutually the same or different;
a plurality of G2 in —Si(G1)(G2)(G2) are mutually the same or different;
a plurality of G1 in —Si(G1)(G1)(G2) are mutually the same or different;
a plurality of G2 in —Si(G2)(G2)(G2) are mutually the same or different;
a plurality of G3 in —Si(G3)(G3)(G3) are mutually the same or different; and
a plurality of G6 in —Si(G6)(G6)(G6) are mutually the same or different.

### Group Represented by —O—(R₉₀₄)

Specific examples (specific example group G8) of a group represented by —O—(R₉₀₄) herein include: —O(G1); —O(G2); —O(G3); and —O(G6);

where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.

### Group Represented by —S—(R₉₀₅)

Specific examples (specific example group G9) of a group represented herein by —S—(R₉₀₅) include: —S(G1); —S(G2); —S(G3); and —S(G6);

where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.
   Group Represented by —N(R₉₀₆)(R₉₀₇)

Specific examples (specific example group G10) of a group represented herein by —N(R₉₀₆)(R₉₀₇) include: —N(G1)(G1); —N(G2)(G2); —N(G1)(G2); —N(G3)(G3); and —N(G6)(G6);

where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3;
G6 represents a “substituted or unsubstituted cycloalkyl group” in the specific example group G6;
a plurality of G1 in —N(G1)(G1) are mutually the same or different;
a plurality of G2 in —N(G2)(G2) are mutually the same or different;
a plurality of G3 in —N(G3)(G3) are mutually the same or different; and
a plurality of G6 in —N(G6)(G6) are mutually the same or different.

### Halogen Atom

Specific examples (specific example group G11) of “halogen atom” mentioned herein include a fluorine atom, chlorine atom, bromine atom, and iodine atom.

### Substituted or Unsubstituted Fluoroalkyl Group

The “substituted or unsubstituted fluoroalkyl group” mentioned herein refers to a group derived by substituting at least one hydrogen atom bonded to at least one of carbon atoms forming an alkyl group in the “substituted or unsubstituted alkyl group” with a fluorine atom, and also includes a group (perfluoro group) derived by substituting all of hydrogen atoms bonded to carbon atoms forming the alkyl group in the “substituted or unsubstituted alkyl group” with fluorine atoms. An “unsubstituted fluoroalkyl group” has, unless otherwise specified herein, 1 to 50, preferably 1 to 30, more preferably 1 to 18 carbon atoms. The “substituted fluoroalkyl group” refers to a group derived by substituting at least one hydrogen atom in a “fluoroalkyl group” with a substituent. It should be noted that the examples of the “substituted fluoroalkyl group” mentioned herein include a group derived by further substituting at least one hydrogen atom bonded to a carbon atom of an alkyl chain of a “substituted fluoroalkyl group” with a substituent, and a group derived by further substituting at least one hydrogen atom of a substituent of the “substituted fluoroalkyl group” with a substituent. Specific examples of the “unsubstituted fluoroalkyl group” include a group derived by substituting at least one hydrogen atom of the “alkyl group” (specific example group G3) with a fluorine atom.

### Substituted or Unsubstituted Haloalkyl Group

The “substituted or unsubstituted haloalkyl group” mentioned herein refers to a group derived by substituting at least one hydrogen atom bonded to carbon atoms forming the alkyl group in the “substituted or unsubstituted alkyl group” with a halogen atom, and also includes a group derived by substituting all hydrogen atoms bonded to carbon atoms forming the alkyl group in the “substituted or unsubstituted alkyl group” with halogen atoms. An “unsubstituted haloalkyl group” has, unless otherwise specified herein, 1 to 50, preferably 1 to 30, more preferably 1 to 18 carbon atoms. The “substituted haloalkyl group” refers to a group derived by substituting at least one hydrogen atom in a “haloalkyl group” with a substituent. It should be noted that the examples of the “substituted haloalkyl group” mentioned herein include a group derived by further substituting at least one hydrogen atom bonded to a carbon atom of an alkyl chain of a “substituted haloalkyl group” with a substituent, and a group derived by further substituting at least one hydrogen atom of a substituent of the “substituted haloalkyl group” with a substituent. Specific examples of the “unsubstituted haloalkyl group” include a group derived by substituting at least one hydrogen atom of the “alkyl group” (specific example group G3) with a halogen atom. The haloalkyl group is occasionally referred to as a halogenated alkyl group.

### Substituted or Unsubstituted Alkoxy Group

Specific examples of a “substituted or unsubstituted alkoxy group” mentioned herein include a group represented by —O(G3), G3 being the “substituted or unsubstituted alkyl group” in the specific example group G3. An “unsubstituted alkoxy group” has, unless otherwise specified herein, 1 to 50, preferably 1 to 30, more preferably 1 to 18 carbon atoms.

### Substituted or Unsubstituted Alkylthio Group

Specific examples of a “substituted or unsubstituted alkylthio group” mentioned herein include a group represented by —S(G3), G3 being the “substituted or unsubstituted alkyl group” in the specific example group G3. An “unsubstituted alkylthio group” has, unless otherwise specified herein, 1 to 50, preferably 1 to 30, more preferably 1 to 18 carbon atoms.

### Substituted or Unsubstituted Aryloxy Group

Specific examples of a “substituted or unsubstituted aryloxy group” mentioned herein include a group represented by —O(G1), G1 being the “substituted or unsubstituted aryl group” in the specific example group G1. An “unsubstituted aryloxy group” has, unless otherwise specified herein, 6 to 50, preferably 6 to 30, more preferably 6 to 18 ring carbon atoms.

### Substituted or Unsubstituted Arylthio Group

Specific examples of a “substituted or unsubstituted arylthio group” mentioned herein include a group represented by —S(G1), G1 being the “substituted or unsubstituted aryl group” in the specific example group G1. An “unsubstituted arylthio group” has, unless otherwise specified herein, 6 to 50, preferably 6 to 30, more preferably 6 to 18 ring carbon atoms.

### Substituted or Unsubstituted Trialkylsilyl Group

Specific examples of a “trialkylsilyl group” mentioned herein include a group represented by —Si(G3)(G3)(G3), G3 being the “substituted or unsubstituted alkyl group” in the specific example group G3. A plurality of G3 in —Si(G3)(G3)(G3) are mutually the same or different. Each of the alkyl groups in the “trialkylsilyl group” has, unless otherwise specified herein, 1 to 50, preferably 1 to 20, more preferably 1 to 6 carbon atoms.

### Substituted or Unsubstituted Aralkyl Group

Specific examples of a “substituted or unsubstituted aralkyl group” mentioned herein include a group represented by -(G3)-(G1), G3 being the “substituted or unsubstituted alkyl group” in the specific example group G3, G1 being the “substituted or unsubstituted aryl group” in the specific example group G1. Accordingly, the “aralkyl group” is a group derived by substituting a hydrogen atom of the “alkyl group” with a substituent in a form of the “aryl group,” which is an example of the “substituted alkyl group.” An “unsubstituted aralkyl group,” which is an “unsubstituted alkyl group” substituted by an “unsubstituted aryl group,” has, unless otherwise specified herein, 7 to 50 carbon atoms, preferably 7 to 30 carbon atoms, more preferably 7 to 18 carbon atoms.

Specific examples of the “substituted or unsubstituted aralkyl group” include a benzyl group, 1-phenylethyl group, 2-phenylethyl group, 1-phenylisopropyl group, 2-phenylisopropyl group, phenyl-t-butyl group, a-naphthylmethyl group, 1-a-naphthylethyl group, 2-a-naphthylethyl group, 1-a-naphthylisopropyl group, 2-a-naphthylisopropyl group, β-naphthylmethyl group, 1-p-naphthylethyl group, 2-p-naphthylethyl group, 1-p-naphthylisopropyl group, and 2-β-naphthylisopropyl group.

Preferable examples of the substituted or unsubstituted aryl group mentioned herein include, unless otherwise specified herein, a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, phenanthryl group, pyrenyl group, chrysenyl group, triphenylenyl group, fluorenyl group, 9,9′-spirobifluorenyl group, 9,9-dimethylfluorenyl group, and 9,9-diphenylfluorenyl group.

Preferable examples of the substituted or unsubstituted heterocyclic group mentioned herein include, unless otherwise specified herein, a pyridyl group, pyrimidinyl group, triazinyl group, quinolyl group, isoquinolyl group, quinazolinyl group, benzimidazolyl group, phenanthrolinyl group, carbazolyl group (1-carbazolyl group, 2-carbazolyl group, 3-carbazolyl group, 4-carbazolyl group, or 9-carbazolyl group), benzocarbazolyl group, azacarbazolyl group, diazacarbazolyl group, dibenzofuranyl group, naphthobenzofuranyl group, azadibenzofuranyl group, diazadibenzofuranyl group, dibenzothiophenyl group, naphthobenzothiophenyl group, azadibenzothiophenyl group, diazadibenzothiophenyl group, (9-phenyl)carbazolyl group ((9-phenyl)carbazole-1-yl group, (9-phenyl)carbazole-2-yl group, (9-phenyl)carbazole-3-yl group, or (9-phenyl)carbazole-4-yl group), (9-biphenylyl)carbazolyl group, (9-phenyl)phenylcarbazolyl group, diphenylcarbazole-9-yl group, phenylcarbazole-9-yl group, phenyltriazinyl group, biphenylyltriazinyl group, diphenyltriazinyl group, phenyldibenzofuranyl group, and phenyldibenzothiophenyl group.

The carbazolyl group mentioned herein is, unless otherwise specified herein, specifically a group represented by one of formulae below.

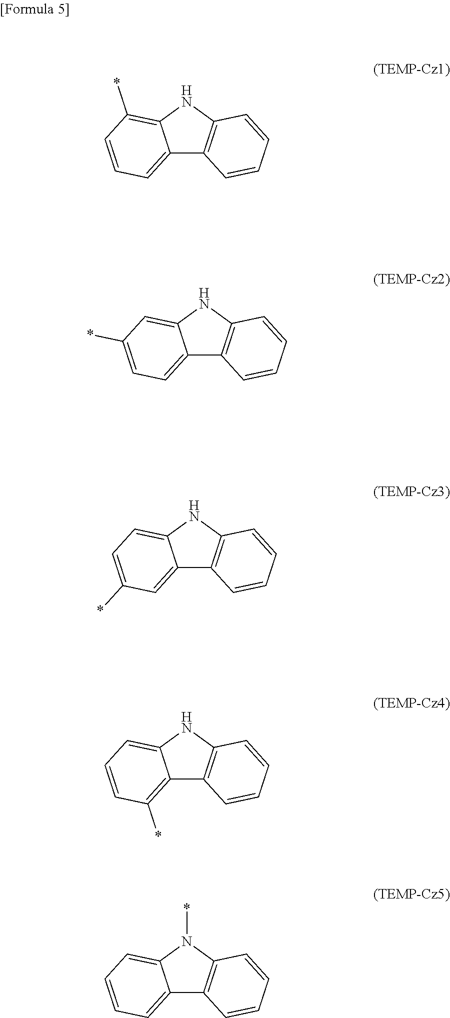 [SMILES: *c1cccc2c1[nH]c1ccccc12 ; *c1ccc2c(c1)[nH]c1ccccc12 ; *c1ccc2[nH]c3ccccc3c2c1 ; *c1cccc2[nH]c3ccccc3c12 ; *n1c2ccccc2c2ccccc21]

The (9-phenyl)carbazolyl group mentioned herein is, unless otherwise specified herein, specifically a group represented by one of formulae below.

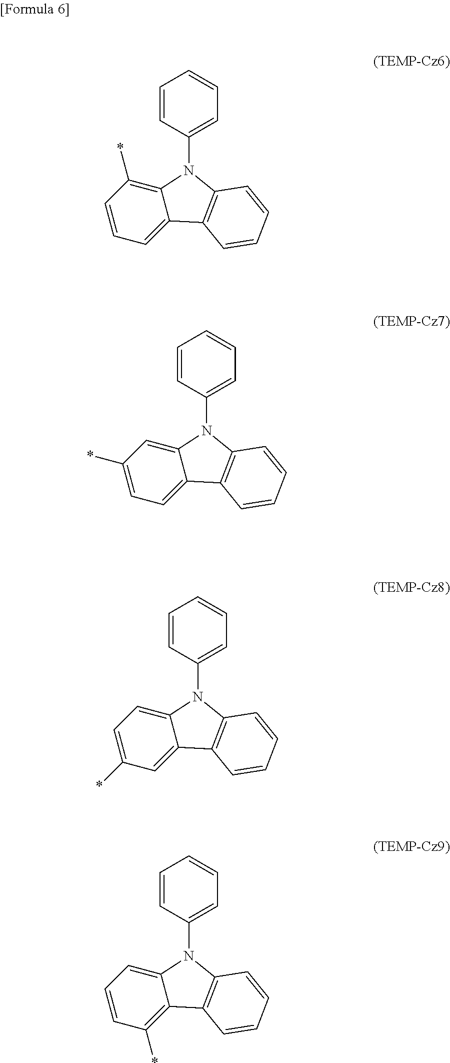 [SMILES: *c1cccc2c3ccccc3n(-c3ccccc3)c12 ; *c1ccc2c3ccccc3n(-c3ccccc3)c2c1 ; *c1ccc2c(c1)c1ccccc1n2-c1ccccc1 ; *c1cccc2c1c1ccccc1n2-c1ccccc1]

In the formulae (TEMP-Cz1) to (TEMP-Cz9), * represents a bonding position.

The dibenzofuranyl group and dibenzothiophenyl group mentioned herein are, unless otherwise specified herein, each specifically represented by one of formulae below.

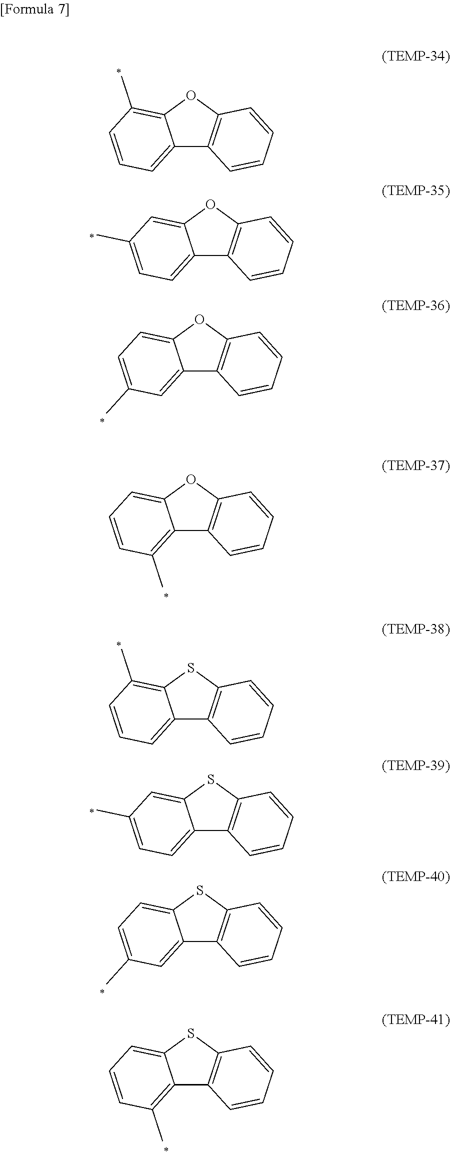

In the formulae (TEMP-34) to (TEMP-41), * represents a bonding position.

Preferable examples of the substituted or unsubstituted alkyl group mentioned herein include, unless otherwise specified herein, a methyl group, ethyl group, propyl group, isopropyl group, n-butyl group, isobutyl group, and t-butyl group.

### Substituted or Unsubstituted Arylene Group

The “substituted or unsubstituted arylene group” mentioned herein is, unless otherwise specified herein, a divalent group derived by removing one hydrogen atom on an aryl ring of the “substituted or unsubstituted aryl group.” Specific examples of the “substituted or unsubstituted arylene group” (specific example group G12) include a divalent group derived by removing one hydrogen atom on an aryl ring of the “substituted or unsubstituted aryl group” in the specific example group G1.

### Substituted or Unsubstituted Divalent Heterocyclic Group

The “substituted or unsubstituted divalent heterocyclic group” mentioned herein is, unless otherwise specified herein, a divalent group derived by removing one hydrogen atom on a heterocycle of the “substituted or unsubstituted heterocyclic group.” Specific examples of the “substituted or unsubstituted divalent heterocyclic group” (specific example group G13) include a divalent group derived by removing one hydrogen atom on a heterocycle of the “substituted or unsubstituted heterocyclic group” in the specific example group G2.

### Substituted or Unsubstituted Alkylene Group

The “substituted or unsubstituted alkylene group” mentioned herein is, unless otherwise specified herein, a divalent group derived by removing one hydrogen atom on an alkyl chain of the “substituted or unsubstituted alkyl group.” Specific examples of the “substituted or unsubstituted alkylene group” (specific example group G14) include a divalent group derived by removing one hydrogen atom on an alkyl chain of the “substituted or unsubstituted alkyl group” in the specific example group G3.

The substituted or unsubstituted arylene group mentioned herein is, unless otherwise specified herein, preferably a group represented by one of formulae (TEMP-42) to (TEMP-68) below.

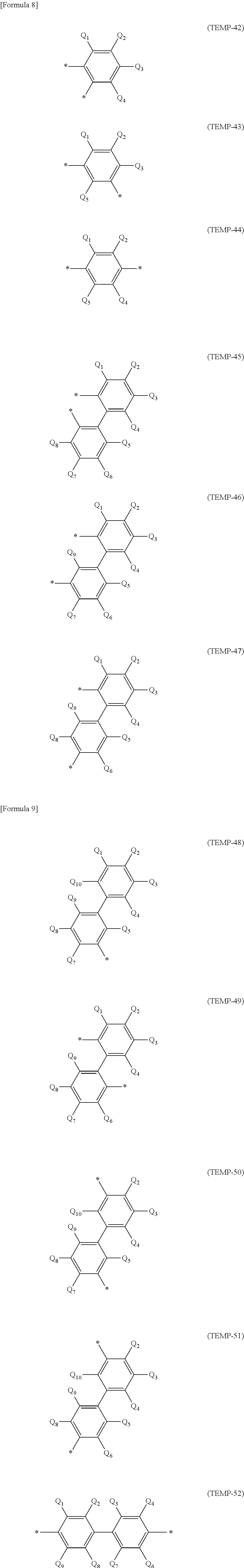

In the formulae (TEMP-42) to (TEMP-52), Q₁ to Q₁₀ are each independently a hydrogen atom or a substituent.

In the formulae (TEMP-42) to (TEMP-52), * represents a bonding position.

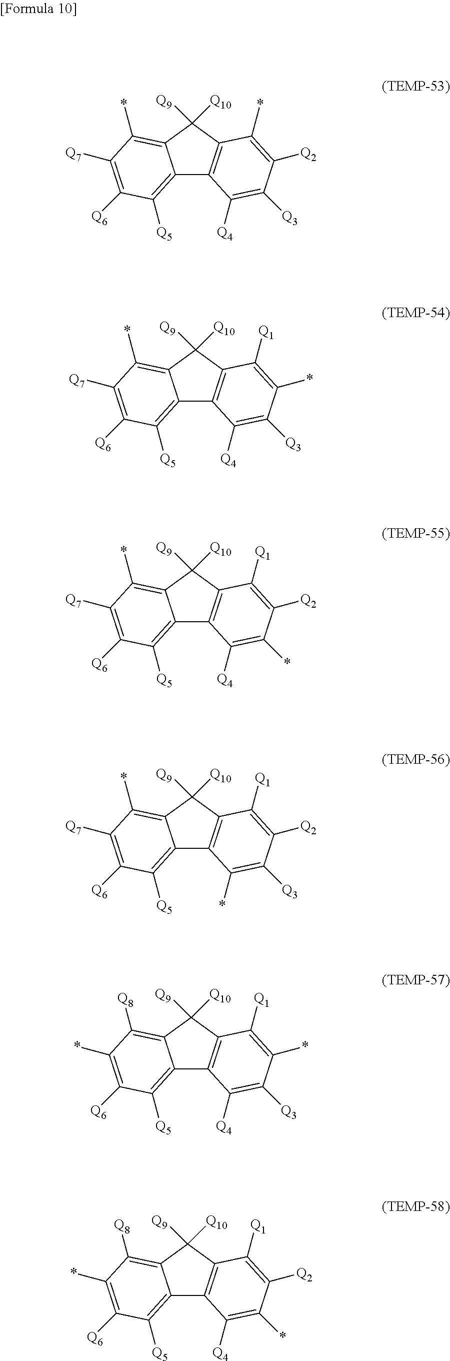

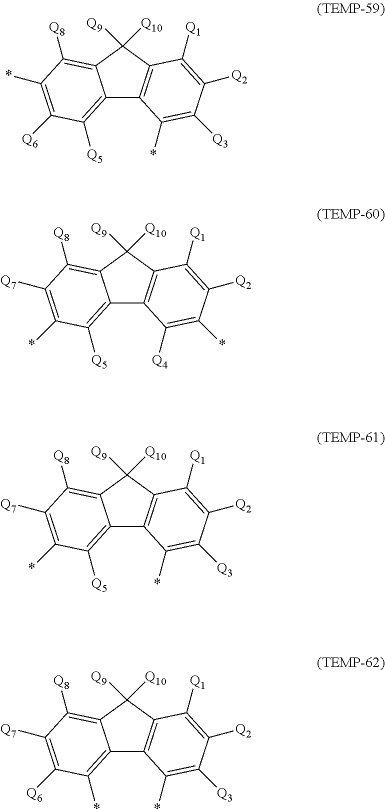

In the formulae (TEMP-53) to (TEMP-62), Q₁ to Q₁₀ are each independently a hydrogen atom or a substituent.

In the formulae, Q₉ and Q₁₀ may be mutually bonded through a single bond to form a ring.

In the formulae (TEMP-53) to (TEMP-62), * represents a bonding position.

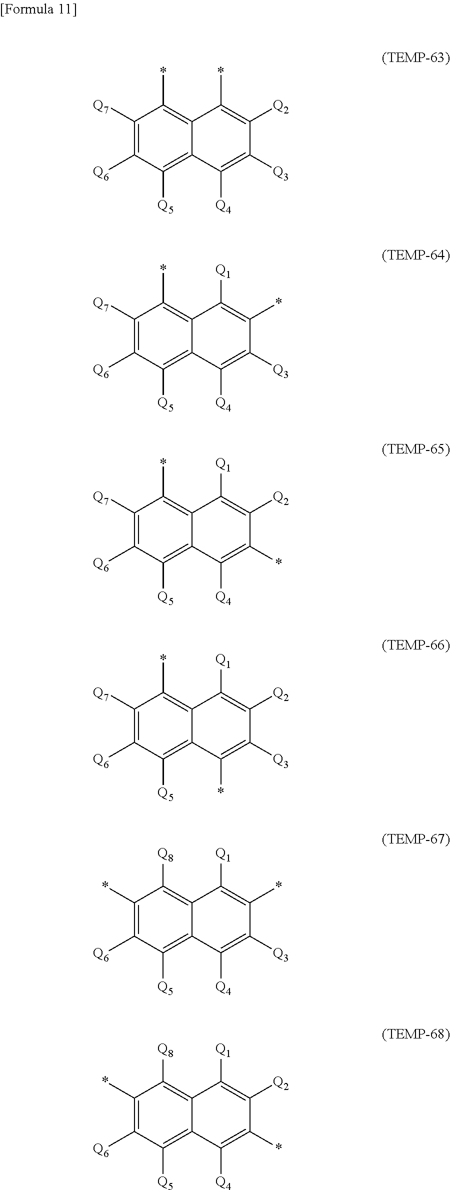

In the formulae (TEMP-63) to (TEMP-68), Q₁ to Q₈ are each independently a hydrogen atom or a substituent.

In the formulae (TEMP-63) to (TEMP-68), * represents a bonding position.

The substituted or unsubstituted divalent heterocyclic group mentioned herein is, unless otherwise specified herein, preferably a group represented by one of formulae (TEMP-69) to (TEMP-102) below.

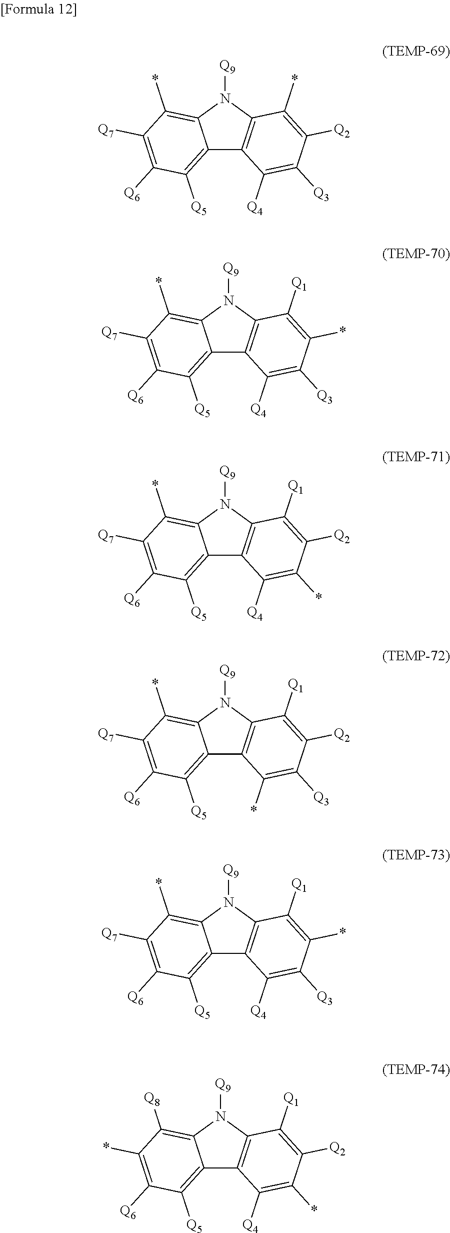

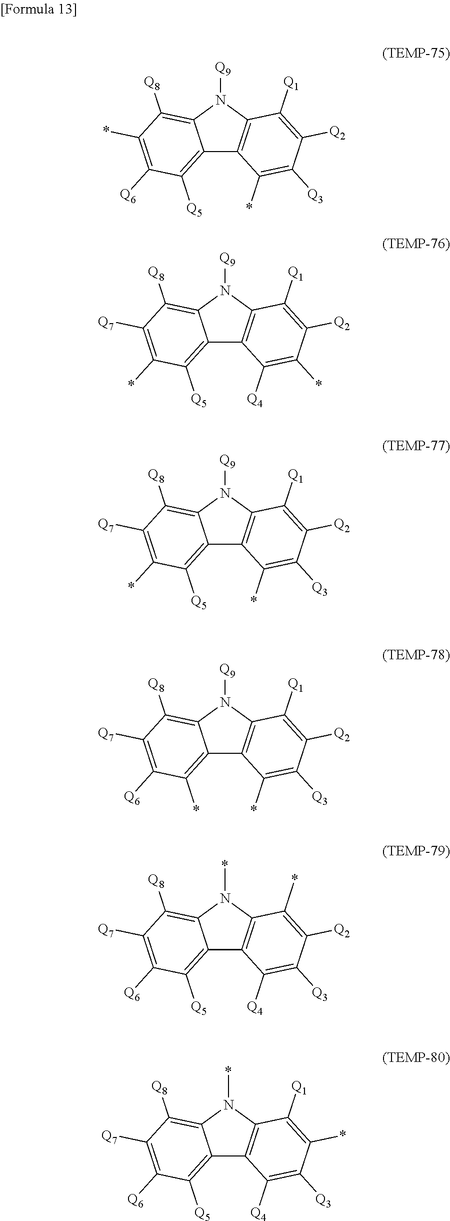

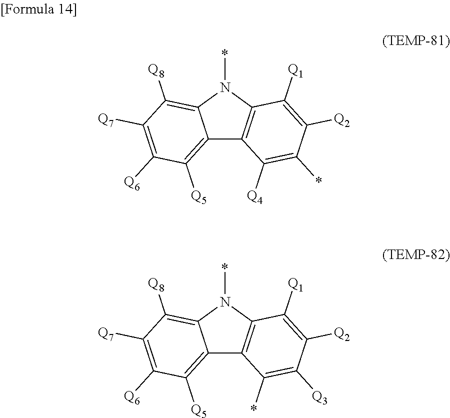

In the formulae (TEMP-69) to (TEMP-82), Q₁ to Q₉ are each independently a hydrogen atom or a substituent.

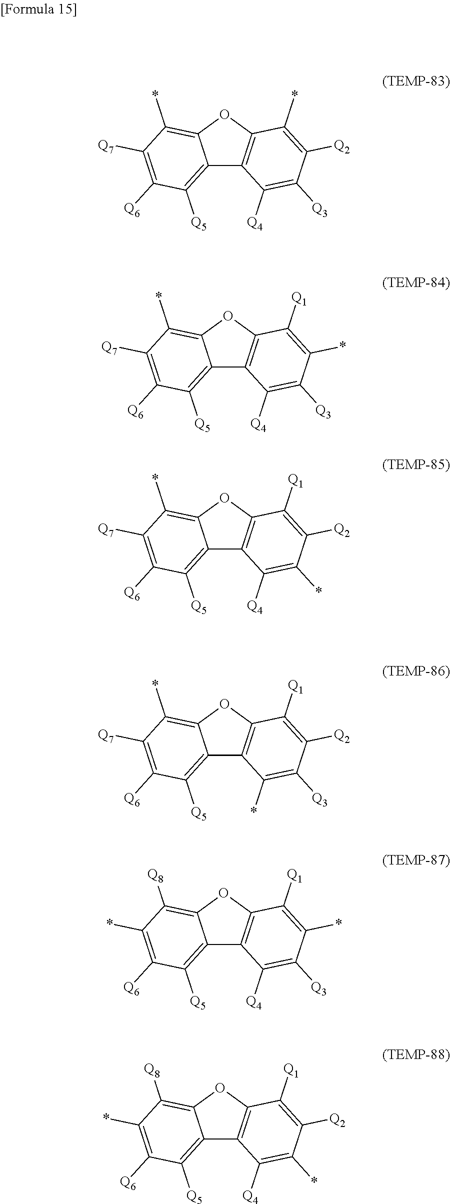

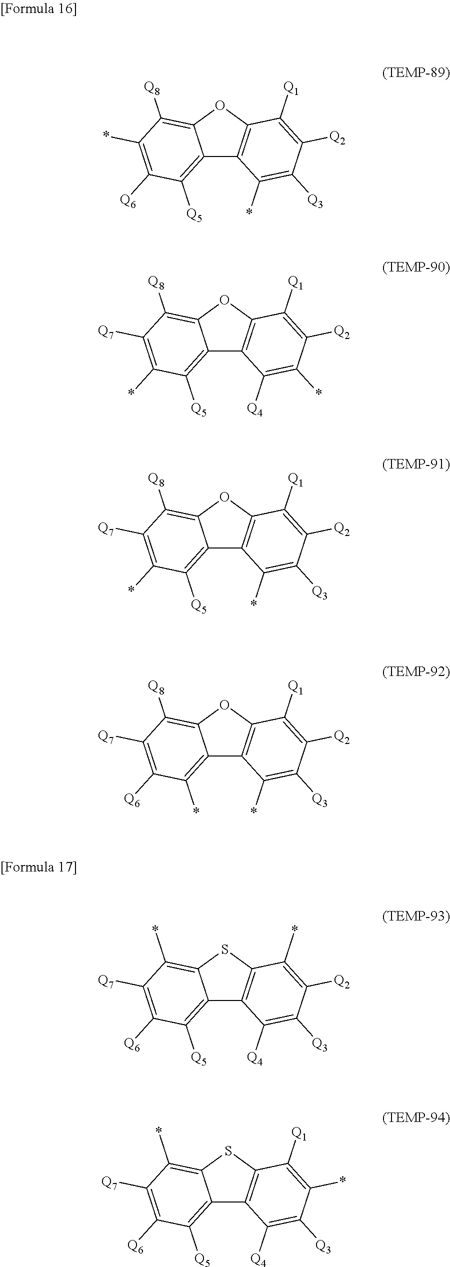

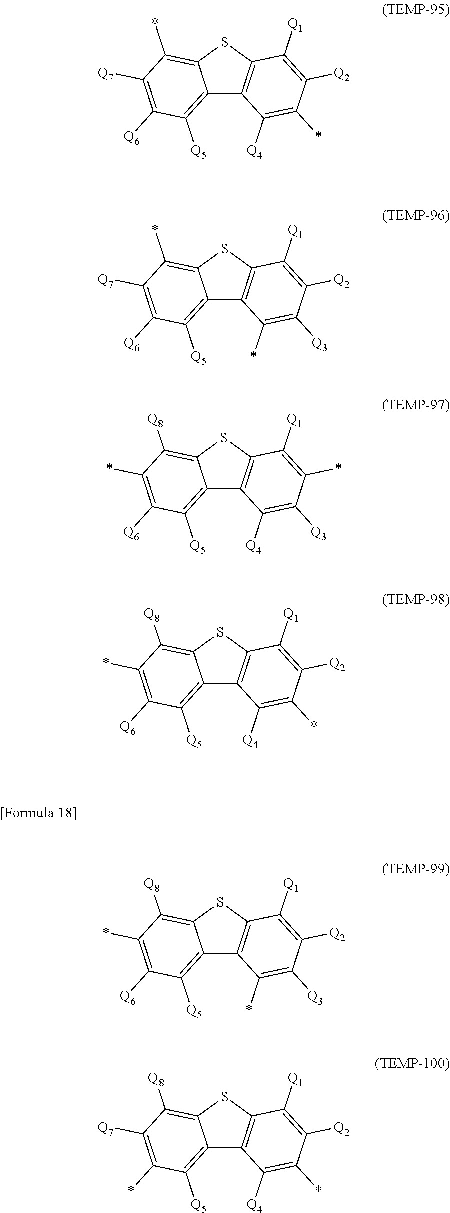

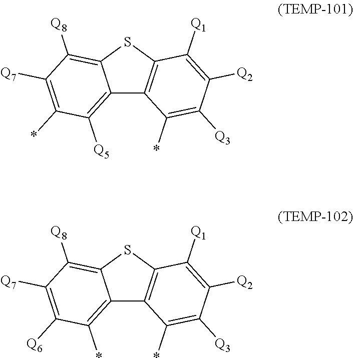

In the formulae (TEMP-83) to (TEMP-102), Q₁ to Q₈ are each independently a hydrogen atom or a substituent.

The substituent mentioned herein has been described above.

### Instance of “Bonded to Form Ring”

Instances where “at least one combination of adjacent two or more (of . . . ) are mutually bonded to form a substituted or unsubstituted monocyclic ring, mutually bonded to form a substituted or unsubstituted fused ring, or not mutually bonded” mentioned herein refer to instances where “at least one combination of adjacent two or more (of . . . ) are mutually bonded to form a substituted or unsubstituted monocyclic ring”, “at least one combination of adjacent two or more (of . . . ) are mutually bonded to form a substituted or unsubstituted fused ring,” and “at least one combination of adjacent two or more (of . . . ) are not mutually bonded.”

Instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (these instances will be sometimes collectively referred to as an instance of “bonded to form a ring” hereinafter) will be described below. An anthracene compound having a basic skeleton in a form of an anthracene ring and represented by a formula (TEMP-103) below will be used as an example for the description.

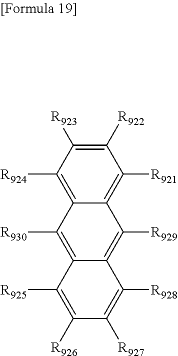

For instance, when “at least one combination of adjacent two or more of R₉₂₁ to R₉₃₀ are mutually bonded to form a ring,” the combination of adjacent ones of R₉₂₁ to R₉₃₀ (i.e. the combination at issue) is a combination of R₉₂₁ and R₉₂₂, a combination of R₉₂₂ and R₉₂₃, a combination of R₉₂₃ and R₉₂₄, a combination of R₉₂₄ and R₉₃₀, a combination of R₉₃₀ and R₉₂₅, a combination of R₉₂₅ and R₉₂₆, a combination of R₉₂₆ and R₉₂₇, a combination of R₉₂₇ and R₉₂₈, a combination of R₉₂₈ and R₉₂₉, or a combination of R₉₂₉ and R₉₂₁.

The term “at least one combination” means that two or more of the above combinations of adjacent two or more of R₉₂₁ to R₉₃₀ may simultaneously form rings. For instance, when R₉₂₁ and R₉₂₂ are mutually bonded to form a ring Q_{A} and R₉₂₅ and R₉₂₆ are simultaneously mutually bonded to form a ring QB, the anthracene compound represented by the formula (TEMP-103) is represented by a formula (TEMP-104) below.

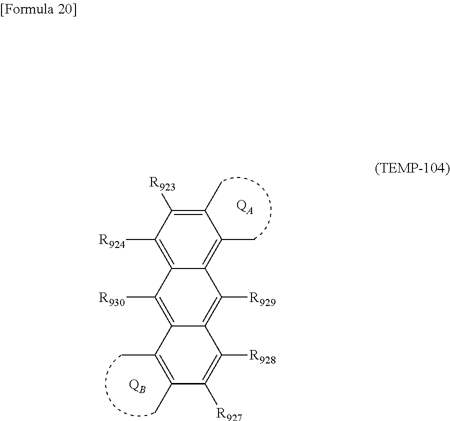

The instance where the “combination of adjacent two or more” form a ring means not only an instance where the “two” adjacent components are bonded but also an instance where adjacent “three or more” are bonded. For instance, R₉₂₁ and R₉₂₂ are mutually bonded to form a ring Q_{A} and R₉₂₂ and R₉₂₃ are mutually bonded to form a ring Q_{C}, and mutually adjacent three components (R₉₂₁, R₉₂₂ and R₉₂₃) are mutually bonded to form a ring fused to the anthracene basic skeleton. In this case, the anthracene compound represented by the formula (TEMP-103) is represented by a formula (TEMP-105) below. In the formula (TEMP-105) below, the ring Q_{A} and the ring Q_{C} share R₉₂₂.

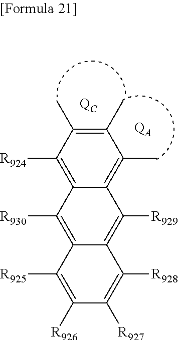

The formed “monocyclic ring” or “fused ring” may be, in terms of the formed ring in itself, a saturated ring or an unsaturated ring. When the “combination of adjacent two” form a “monocyclic ring” or a “fused ring,” the “monocyclic ring” or “fused ring” may be a saturated ring or an unsaturated ring. For instance, the ring Q_{A} and the ring QB formed in the formula (TEMP-104) are each independently a “monocyclic ring” or a “fused ring.” Further, the ring Q_{A} and the ring Q_{C} formed in the formula (TEMP-105) are each a “fused ring.” The ring Q_{A} and the ring Q_{C} in the formula (TEMP-105) are fused to form a fused ring. When the ring Q_{A} in the formula (TEMP-104) is a benzene ring, the ring Q_{A} is a monocyclic ring. When the ring Q_{A} in the formula (TEMP-104) is a naphthalene ring, the ring Q_{A} is a fused ring.

The “unsaturated ring” represents an aromatic hydrocarbon ring or an aromatic heterocycle. The “saturated ring” represents an aliphatic hydrocarbon ring or a non-aromatic heterocycle.

Specific examples of the aromatic hydrocarbon ring include a ring formed by terminating a bond of a group in the specific examples of the specific example group G1 with a hydrogen atom.

Specific examples of the aromatic heterocycle include a ring formed by terminating a bond of an aromatic heterocyclic group in the specific examples of the specific example group G2 with a hydrogen atom.

Specific examples of the aliphatic hydrocarbon ring include a ring formed by terminating a bond of a group in the specific examples of the specific example group G6 with a hydrogen atom.

The phrase “to form a ring” herein means that a ring is formed only by a plurality of atoms of a basic skeleton, or by a combination of a plurality of atoms of the basic skeleton and one or more optional atoms. For instance, the ring Q_{A} formed by mutually bonding R₉₂₁ and R₉₂₂ shown in the formula (TEMP-104) is a ring formed by a carbon atom of the anthracene skeleton bonded to R₉₂₁, a carbon atom of the anthracene skeleton bonded to R₉₂₂, and one or more optional atoms. Specifically, when the ring Q_{A} is a monocyclic unsaturated ring formed by R₉₂₁ and R₉₂₂, the ring formed by a carbon atom of the anthracene skeleton bonded to R₉₂₁, a carbon atom of the anthracene skeleton bonded to R₉₂₂, and four carbon atoms is a benzene ring.

The “optional atom” is, unless otherwise specified herein, preferably at least one atom selected from the group consisting of a carbon atom, nitrogen atom, oxygen atom, and sulfur atom. A bond of the optional atom (e.g. a carbon atom and a nitrogen atom) not forming a ring may be terminated by a hydrogen atom or the like or may be substituted by an “optional substituent” described later. When the ring includes any other optional atom than the carbon atom, the resultant ring is a heterocycle.

The number of “one or more optional atoms” forming the monocyclic ring or fused ring is, unless otherwise specified herein, preferably in a range from 2 to 15, more preferably in a range from 3 to 12, and still more preferably in a range from 3 to 5.

Unless otherwise specified herein, the ring, which may be a “monocyclic ring” or “fused ring,” is preferably a “monocyclic ring.”

Unless otherwise specified herein, the ring, which may be a “saturated ring” or “unsaturated ring,” is preferably an “unsaturated ring.”

Unless otherwise specified herein, the “monocyclic ring” is preferably a benzene ring.

Unless otherwise specified herein, the “unsaturated ring” is preferably a benzene ring.

When “at least one combination of adjacent two or more” (of . . . ) are “mutually bonded to form a substituted or unsubstituted monocyclic ring” or “mutually bonded to form a substituted or unsubstituted fused ring,” unless otherwise specified herein, at least one combination of adjacent two or more of components are preferably mutually bonded to form a substituted or unsubstituted “unsaturated ring” formed of a plurality of atoms of the basic skeleton, and 1 to 15 atoms of at least one element selected from the group consisting of carbon, nitrogen, oxygen and sulfur.

When the “monocyclic ring” or the “fused ring” has a substituent, the substituent is the substituent described in later-described “optional substituent.” When the “monocyclic ring” or the “fused ring” has a substituent, specific examples of the substituent are the substituents described in the above under the subtitle “Substituent Mentioned Herein.”

When the “saturated ring” or the “unsaturated ring” has a substituent, the substituent is the substituent described in later-described “optional substituent.” When the “monocyclic ring” or the “fused ring” has a substituent, specific examples of the substituent are the substituents described in the above under the subtitle “Substituent Mentioned Herein.”

The above is the description for the instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (sometimes referred to as an instance of “bonded to form a ring”).

### Substituent for Substituted or Unsubstituted Group

In an exemplary embodiment herein, the substituent for the substituted or unsubstituted group (sometimes referred to as an “optional substituent” hereinafter) is, for instance, a group selected from the group consisting of an unsubstituted alkyl group having 1 to 50 carbon atoms, an unsubstituted alkenyl group having 2 to 50 carbon atoms, an unsubstituted alkynyl group having 2 to 50 carbon atoms, an unsubstituted cycloalkyl group having 3 to 50 ring carbon atoms, —Si(R₉₀₁)(R₉₀₂)(R₉₀₃), —O—(R₉₀₄), —S—(R₉₀₅), —N(R₉₀₆)(R₉₀₇), a halogen atom, a cyano group, a nitro group, an unsubstituted aryl group having 6 to 50 ring carbon atoms, and an unsubstituted heterocyclic group having 5 to 50 ring atoms;
R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when two or more R₉₀₁ are present, the two or more R₉₀₁ are mutually the same or different;
when two or more R₉₀₂ are present, the two or more R₉₀₂ are mutually the same or different;
when two or more R₉₀₃ are present, the two or more R₉₀₃ are mutually the same or different;
when two or more R₉₀₄ are present, the two or more R₉₀₄ are mutually the same or different;
when two or more R₉₀₅ are present, the two or more R₉₀₅ are mutually the same or different;
when two or more R₉₀₅ are present, the two or more R₉₀₅ are mutually the same or different; and
when two or more R₉₀₇ are present, the two or more R₉₀₇ are mutually the same or different.

In an exemplary embodiment, the substituent for the substituted or unsubstituted group is a group selected from the group consisting of an alkyl group having 1 to 50 carbon atoms, an aryl group having 6 to 50 ring carbon atoms, and a heterocyclic group having 5 to 50 ring atoms.

In an exemplary embodiment, the substituent for the substituted or unsubstituted group is a group selected from the group consisting of an alkyl group having 1 to 18 carbon atoms, an aryl group having 6 to 18 ring carbon atoms, and a heterocyclic group having 5 to 18 ring atoms.

Specific examples of the above optional substituent are the same as the specific examples of the substituent described in the above under the subtitle “Substituent Mentioned Herein.”

Unless otherwise specified herein, adjacent ones of the optional substituents may form a “saturated ring” or an “unsaturated ring,” preferably a substituted or unsubstituted saturated five-membered ring, a substituted or unsubstituted saturated six-membered ring, a substituted or unsubstituted unsaturated five-membered ring, or a substituted or unsubstituted unsaturated six-membered ring, more preferably a benzene ring.

Unless otherwise specified herein, the optional substituent may further include a substituent. Examples of the substituent for the optional substituent are the same as the examples of the optional substituent.

Herein, numerical ranges represented by “AA to BB” represent a range whose lower limit is the value (AA) recited before “to” and whose upper limit is the value (BB) recited after “to.”

### First Exemplary Embodiment

### Organic Electroluminescence Device

An organic electroluminescence device according to the first exemplary embodiment includes an anode, a cathode and an emitting region between the anode and the cathode, in which the emitting region includes a first emitting layer and a second emitting layer, the first emitting layer contains a first host material and a first luminescent compound, the second emitting layer contains a second host material and a second luminescent compound, the first host material and the second host material are mutually different, the first luminescent compound and the second luminescent compound are mutually the same or different, a triplet energy of the first host material T₁(H1) and a triplet energy of the second host material T₁(H2) satisfy a relationship of a numerical formula (Numerical Formula 1) below, the first luminescent compound exhibits a first orientation (σ₁) in a first film containing the first host material and the first luminescent compound, the second luminescent compound exhibits a second orientation (σ₂) in a second film containing the second host material and the second luminescent compound, and a ratio of the first orientation (σ₁) to the second orientation (σ₂) satisfies a relationship of a numerical formula (Numerical Formula 2) below.

$${T}_{1} ( H 1 ) > {T}_{1} ( H 2 ) \qquad ( Numerical Formula 1 )$$

$${σ}_{1} / {σ}_{2} \geq 0.9 \qquad ( Numerical Formula 2 )$$

According to the exemplary embodiment, an organic electroluminescence device with improved luminous efficiency can be provided.

Conventionally, triplet-triplet annihilation (occasionally referred to as TTA) is known as a technique for improving the luminous efficiency of the organic electroluminescence device. TTA is a mechanism in which triplet excitons collide with one another to generate singlet excitons. It should be noted that the TTA mechanism is occasionally referred to as a Triplet-Triplet Fusion (TTF) mechanism.

The TTF phenomenon will be described. Holes injected from an anode and electrons injected from a cathode are recombined in an emitting layer to generate excitons. As for the spin state, as is conventionally known, singlet excitons account for 25% and triplet excitons account for 75%. In a conventionally known fluorescent device, light is emitted when singlet excitons of 25% are relaxed to the ground state. The remaining triplet excitons of 75% are returned to the ground state without emitting light through a thermal deactivation process. Accordingly, the theoretical limit value of the internal quantum efficiency of the conventional fluorescent device is believed to be 25%.

The behavior of triplet excitons generated within an organic substance has been theoretically examined. According to S. M. Bachilo et al. (J. Phys. Chem. A, 104, 7711 (2000)), assuming that high-order excitons such as quintet excitons are quickly returned to triplet excitons, triplet excitons (hereinafter abbreviated as ³A*) collide with one another with an increase in density thereof, whereby a reaction shown by the following formula occurs. In the formula, ¹A represents the ground state and ¹A* represents the lowest singlet excitons.

$${}^{3} {A}^{*} + {}^{3} {A}^{*} \to ( 4 / 9 ) {}^{1} A + ( 1 / 9 ) {}^{1} {A}^{*} + ( 13 / 9 ) {}^{3} {A}^{*}$$

In other words, 5³A*→4¹A+¹A* is satisfied, and it is expected that, among triplet excitons initially generated, which account for 75%, one fifth thereof (i.e., 20%) is changed to singlet excitons. Accordingly, the amount of singlet excitons which contribute to emission is 40%, which is a value obtained by adding 15% (75%×(1/5)=15%) to 25%, which is the amount ratio of initially generated singlet excitons. At this time, a ratio of luminous intensity derived from TTF (TTF ratio) relative to the total luminous intensity is 15/40, i.e., 37.5%. Assuming that singlet excitons are generated by collision of initially generated triplet excitons accounting for 75% (i.e., one singlet exciton is generated from two triplet excitons), a significantly high internal quantum efficiency of 62.5% is obtained, which is a value obtained by adding 37.5% (75%×(1/2)=37.5%) to 25% (the amount ratio of initially generated singlet excitons). At this time, the TTF ratio is 37.5/62.5=60%.

In the organic electroluminescence device according to the exemplary embodiment, it is considered that triplet excitons generated by recombination of holes and electrons in the first emitting layer and present on an interface between the first emitting layer and the organic layer(s) in direct contact therewith are not likely to be quenched even under the presence of excessive carriers on the interface between the first emitting layer and the organic layer(s). For instance, the presence of a recombination region locally on an interface between the first emitting layer and a hole transporting layer or an electron blocking layer is considered to cause quenching by excessive electrons. Meanwhile, the presence of a recombination region locally on an interface between the first emitting layer and the electron transporting layer or the hole blocking layer is considered to cause quenching by excessive holes.

The organic electroluminescence device according to the exemplary embodiment includes at least two emitting layers (i.e., the first emitting layer and the second emitting layer) satisfying a predetermined relationship. The triplet energy of the first host material T₁(H1) in the first emitting layer and the triplet energy of the second host material T₁(H2) in the second emitting layer satisfy the relationship of the numerical formula (Numerical Formula 1).

The organic electroluminescence device includes the first emitting layer and the second emitting layer so as to satisfy the relationship of the numerical formula (Numerical Formula 1), and thereby triplet excitons generated in the first emitting layer can transfer to the second emitting layer without being quenched by excessive carriers and be inhibited from back-transferring from the second emitting layer to the first emitting layer. Consequently, the second emitting layer exhibits the TTF mechanism to effectively generate singlet excitons, thereby improving the luminous efficiency.

Accordingly, the organic electroluminescence device includes, as different regions, the first emitting layer mainly generating triplet excitons and the second emitting layer mainly exhibiting the TTF mechanism with triplet excitons having transferred from the first emitting layer, and has a difference in triplet energy provided by using a compound having a smaller triplet energy than that of the first host material in the first emitting layer as the second host material in the second emitting layer. The luminous efficiency is thus improved.

In the organic electroluminescence device according to the exemplary embodiment, the triplet energy of the first host material T₁(H1) and the triplet energy of the second host material T₁(H2) preferably satisfy a relationship of a numerical formula (Numerical Formula 1A) below.

$${T}_{1} ( H 1 ) - {T}_{1} ( H 2 ) > 0.03 eV \qquad ( Numerical Formula 1 A )$$

In the organic electroluminescence device including the emitting region in which a plurality of emitting layers are layered, light emission is generated by a total of two luminescence components, i.e., a prompt luminescence component and a luminescence component by the TTF mechanism. Such an organic electroluminescence device includes the emitting region that includes the first emitting layer containing the first host material and the first luminescent compound and the second emitting layer containing the second host material and the second luminescent compound. The holes and electrons are recombined in the first emitting layer, and the second emitting layer exhibits the TTF mechanism.

In such an organic electroluminescence device, typically, the second emitting layer exhibits the TTF mechanism to effectively generate singlet excitons, thereby improving the luminous efficiency. However, since the light extraction efficiency of the prompt luminescence component is low in the first emitting layer, the effect of improving the luminous efficiency is small as the entire organic electroluminescence device.

It has been found in the study of the invention that the orientation of the luminescent compound contained in the first emitting layer is likely to decrease, compared with the orientation of the luminescent compound contained in the second emitting layer, in that organic electroluminescence device. When the emitting region is in an ideal state, a ratio of the prompt luminescence component is 62.5% and a ratio of the luminescence component by the TTF mechanism is 37.5%. Thus, the orientation of the luminescent compound contained in the first emitting layer significantly affects the luminous efficiency of the entire organic electroluminescence device.

In the organic electroluminescence device according to the exemplary embodiment, the orientation (the first orientation (σ₁)) of the first luminescent compound in the first film containing the first host material and the first luminescent compound and the orientation (the second orientation (σ₂)) of the second luminescent compound in the second film containing the second host material and the second luminescent compound are easily maintained at the same level. This makes it possible to extract a larger amount of prompt luminescence component light in the first emitting layer in a layer-stacking direction, and reduction in the light extraction efficiency of the prompt luminescence component in the first emitting layer can be inhibited, thereby further improving the luminous efficiency of the entire organic electroluminescence device.

### First Orientation and Second Orientation

In the organic electroluminescence device according to the exemplary embodiment, a ratio (σ₁/σ₂) of the first orientation (σ₁) to the second orientation (σ₂) is preferably 0.91 or more, more preferably 0.94 or more, and still more preferably 0.97 or more. The ratio (σ₁/σ₂) of the first orientation (σ₁) to the second orientation (σ₂) may be more than 1.

In the organic electroluminescence device according to the exemplary embodiment, when the first emitting layer and the second emitting layer contain the same luminescent compound, such a combination is preferable that the orientation of the first luminescent compound in the first film formed from the component of the first emitting layer and the orientation of the second luminescent compound in the second film formed from the component of the second emitting layer can be close to the same level. In this regard, the ratio (σ₁/σ₂) of the first orientation (σ₁) to the second orientation (σ₂) is preferably a value close to 1. The ratio (σ₁/σ₂) of the first orientation (σ₁) to the second orientation (σ₂) is also preferably 1.12 or less, also preferably 1.10 or less, also preferably 1.06 or less, also preferably 1.03 or less, or also preferably 1.00 or less. As a result, the luminous efficiency of the entire organic electroluminescence device can be more easily improved.

In the organic electroluminescence device according to the exemplary embodiment, the first orientation (σ₁) is preferably 0.80 or more. The first orientation (σ₁) is more preferably 0.82 or more, still more preferably 0.85 or more, and still further more preferably 0.90 or more.

In the organic electroluminescence device according to the exemplary embodiment, the second orientation (σ₂) is preferably 0.90 or more. The second orientation (σ₂) is more preferably 0.91 or more, and still more preferably 0.92 or more.

### Method of Measuring First Orientation and Second Orientation

A method of calculating the first orientation (σ₁) and the second orientation (σ₂) from angle-resolved photoluminescence is described below.

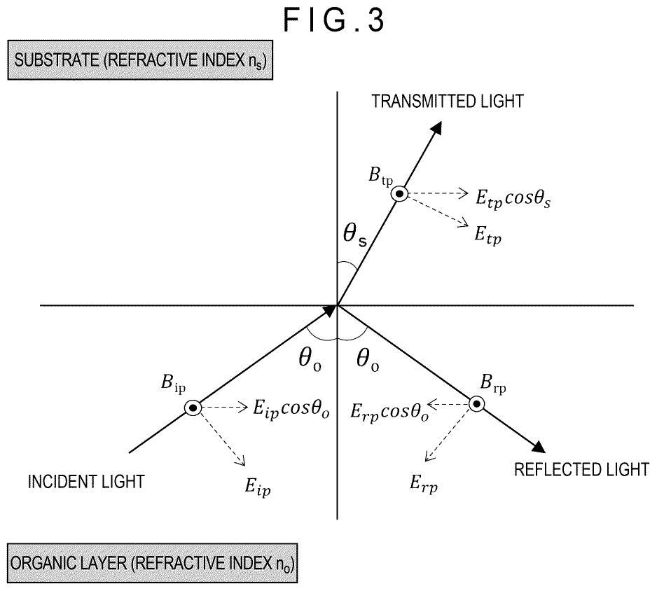

As illustrated in FIG. 3, a refractive index in a substrate is denoted by nₛ, and a refractive index in an organic film is denoted by n₀. When light generated in the organic film is incident at an angle of θ₀ on an interface between the organic film and the substrate, reflected light is generated at the angle of θ₀ in the organic film and transmitted light is generated at the angle of θₛ at a side on which the substrate is provided. The electric field and the magnetic flux density in p polarized light of the incident light are denoted by Eᵢₚ and Bᵢₚ, respectively. Likewise, the electric field and the magnetic flux density of the reflected light are denoted by Eᵣₚ and Bᵣₚ, respectively, and the electric field and the magnetic flux density of the transmitted light are denoted by Eₜₚ and Bₜₚ, respectively. Numerical formulae (F1) and (F2) below are satisfied from a boundary condition of electromagnetic wave.

$$\begin{matrix}( F1 ) & \\ {E}_{ip} cos {θ}_{o} - {E}_{rp} cos {θ}_{o} = {E}_{tp} cos {θ}_{s} & [ Numerical Formula 1 ]\end{matrix}$$

$$\begin{matrix}( F2 ) & \\ {B}_{ip} + {B}_{rp} = {B}_{tp} & \end{matrix}$$

The electric field E and the magnetic flux density B are expressed by a numerical formula (F2A) below using a velocity c and a refractive index n in the medium of the light. Accordingly, when the numerical formula (F2A) below is assigned to the numerical formula (F2) and rearranged, a numerical formula (F3) below is obtained.

$$\begin{matrix}( F2A ) & \\ E = \frac{c}{n} B & [ Numerical Formula 2 ]\end{matrix}$$

$$\begin{matrix}( F3 ) & \\ {n}_{o} ( {E}_{ip} + {E}_{rp} ) = {n}_{s} {E}_{tp} & [ Numerical Formula 3 ]\end{matrix}$$

When Eₜₚ is eliminated from the numerical formulae (F1) and (F3) and the formulae are rearranged, an amplitude reflection coefficient rₚ of the p polarized light is expressed by a numerical formula (F4) below. Likewise, an amplitude transmission coefficient tₚ of the p polarized light is expressed by a numerical formula (F5) below.

$$\begin{matrix}( F4 ) & \\ {r}_{p} ≡ \frac{{E}_{rp}}{{E}_{ip}} = \frac{{n}_{o} cos {θ}_{s} - {n}_{s} cos {θ}_{o}}{{n}_{o} cos {θ}_{s} + {n}_{s} cos {θ}_{o}} & [ Numerical Formula 4 ]\end{matrix}$$

$$\begin{matrix}( F5 ) & \\ {t}_{p} ≡ \frac{{E}_{tp}}{{E}_{ip}} = \frac{2 {n}_{o} cos {θ}_{s}}{{n}_{o} cos {θ}_{s} + {n}_{s} cos {θ}_{o}} & \end{matrix}$$

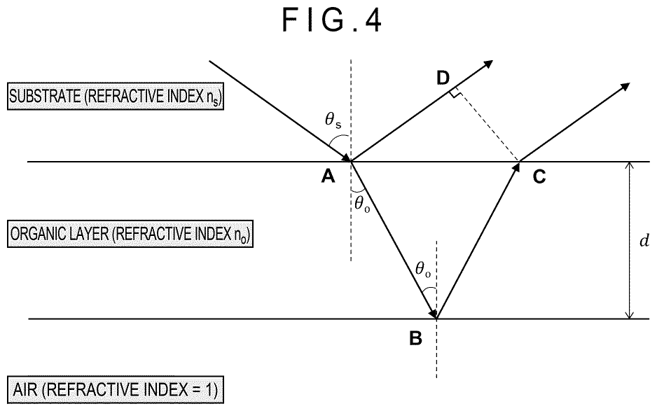

When lights propagated from different positions overlap each other, overlapping of waves generates optical interference. The optical interference is also observed in a thin film formed on the substrate and a change in amplitude is determined by a phase shift. In FIG. 4, when a distance from an A point to a B point is defined as AB- (“-” put after “B” should be formally put above “AB” as in a numerical formula (F6) below; and the same is applied to BC-, AD- and AC- in numerical formulae (F6) to (F8)), a phase change a is expressed by the numerical formula (F6) below, where a wavelength of the propagated light is denoted by λ and a film thickness of the organic film is denoted by d.

$$\begin{matrix}( F6 ) & \\ α = \frac{2 π {n}_{o}}{λ} ( \overline{AB} + \overline{BC} ) - \frac{2 π {n}_{s}}{λ} \overline{AD} & [ Numerical Formula 5 ]\end{matrix}$$

When the numerical formulae (F7) and (F8) below are assigned to the numerical formula (F6) and rearranged, the phase change a can be expressed by a numerical formula (F9) below.

$$\begin{matrix}( F7 ) & \\ \overline{AD} = 2 d \frac{{n}_{o}}{{n}_{s}} \frac{{sin}^{2} {θ}_{o}}{cos {θ}_{o}} & [ Numerical Formula 6 ]\end{matrix}$$

$$\begin{matrix}( F8 ) & \\ \overline{AB} = \overline{BC} = \frac{d}{cos {θ}_{o}} & \end{matrix}$$

$$\begin{matrix}( F9 ) & \\ α = \frac{4 π d}{λ} {n}_{o} cos {θ}_{o} & [ Numerical Formula 7 ]\end{matrix}$$

Since the phase change a is a phase change of the light being reflected and reciprocating, a film phase thickness p is expressed by a numerical formula (F10) below.

$$\begin{matrix}( F10 ) & \\ β = \frac{2 π d}{λ} {n}_{o} cos {θ}_{o} & [ Numerical Formula 8 ]\end{matrix}$$

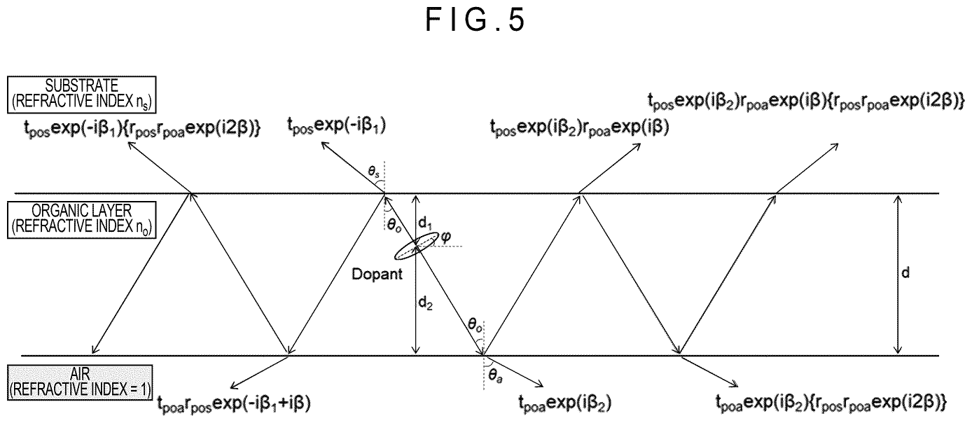

Since the luminescent compound in the organic film emits light in actual EL emission, a state as illustrated in FIG. 5 is assumed. Of the amplitude reflection coefficient of the p polarized light described above, an amplitude reflection coefficient of light reflected off the interface between the organic film and the substrate is defined as rₚₒₛ and an amplitude reflection coefficient of light reflected off an interface between the organic film and air is defined as rₚₒₐ. Likewise, of the transmission reflection coefficient of the p polarized light described above, a transmission reflection coefficient of light reflected off the interface between the organic film and air is defined as tₚₒₛ and a transmission reflection coefficient of light reflected off the interface between the organic film and air is defined as tₚₒₐ. When a single luminescent compound is present in a position whose distance to the substrate interface is d₁ and whose distance to the air interface is d₂, an electric field E_{py} of the p polarized light in a vertical direction at a side on which the substrate is provided is expressed by a numerical formula (F11) below.

$$\begin{matrix}( F11 ) & \\ {E}_{py} = \frac{{t}_{pos} \{ exp ( - i {β}_{o} ) + {r}_{poa} exp ( i β + i {β}_{o} ) \}}{1 - {r}_{pos} {r}_{poa} exp ( i 2 β )} sin {θ}_{s} & [ Numerical Formula 9 ]\end{matrix}$$

The photoluminescence intensity of the p polarized light can be calculated by a numerical formula (F12) below.

$$\begin{matrix}( F12 ) & \\ {F}_{p} = {\vert {E}_{py} \vert}^{2} & [ Numerical Formula 10 ]\end{matrix}$$

According to the principle as described above, angular dependency of the intensity of the p polarized light can be calculated by a simulation in which a refractive index of each layer, the film thickness of the organic film, and an orientation angle of the luminescent compound are defined.

In the exemplary embodiment, a degree of orientation of the luminescent compound can be calculated by comparing simulation results obtained using an optical simulation software Setfos 5.0 (produced by Fluxim AG) with experimental values.

$$\vert λ1 - λ2 \vert and \vert FWHM 1 - FWHM 2 \vert$$

In the organic electroluminescence device according to the exemplary embodiment, preferably, a maximum peak wavelength λ1 and a full width at half maximum FWHM1 of a photoluminescence spectrum of the first film, and a maximum peak wavelength λ2 and a full width at half maximum FWHM2 of a photoluminescence spectrum of the second film satisfy numerical formulae (Numerical Formulae 20 and 30) below.

$$\vert λ1 - λ2 \vert \leq 3 nm \qquad ( Numerical Formula 20 )$$

$$\vert FWHM 1 - FWHM 2 \vert \leq 2 nm \qquad ( Numerical Formula 30 )$$

Herein, the full width at half maximum FWHM1 refers to a full width at half maximum relating to the maximum peak wavelength λ1 of the photoluminescence spectrum of the first film, and the full width at half maximum FWHM2 refers to a full width at half maximum relating to the maximum peak wavelength λ1 of the photoluminescence spectrum of the second film.

The loss of light extracted from an upper electrode (cathode) or a lower electrode (anode) is reduced by combining the first film formed from the component of the first emitting layer and the second film formed from the component of the second emitting layer so that the change (difference) between the photoluminescence spectra is small. It is considered that the luminous efficiency is consequently improved.

In the organic EL device according to the exemplary embodiment, the maximum peak wavelength λ1 of the photoluminescence spectrum of the first film and the maximum peak wavelength λ2 of the photoluminescence spectrum of the second film preferably satisfy a numerical formula (Numerical Formula 20A) below, more preferably satisfy a numerical formula (Numerical Formula 20B) below.

$$\vert λ1 - λ2 \vert \leq 2 nm \qquad ( Numerical Formula 20 A )$$

$$\vert λ1 - λ2 \vert \leq 1 nm \qquad ( Numerical Formula 20 B )$$

In the organic EL device according to the first exemplary embodiment, the full width at half maximum FWHM1 of the photoluminescence spectrum of the first film and the full width at half maximum FWHM2 of the photoluminescence spectrum of the second film preferably satisfy a numerical formula (Numerical Formula 30A) below

$$\vert FWHM 1 - FWHM 2 \vert \leq 1 nm \qquad ( Numerical Formula 30 A )$$

The maximum peak wavelength λ1 and the full width at half maximum FWHM1 of the photoluminescence spectrum of the first film and the maximum peak wavelength λ2 and the full width at half maximum FWHM2 of the photoluminescence spectrum of the second film can be measured by a method below.

First, a measurement sample for the first film is prepared to have the same arrangement as that of the first emitting layer, as described below. A measurement sample for the second film is prepared to have the same arrangement as that of the second emitting layer, as described below.

The wording “the same arrangement as that of the first emitting layer” refers to that the same material is used for the first film and the first emitting layer. Specifically, when the first emitting layer is formed from the first host material and the first luminescent compound, a mass ratio of the first luminescent compound to the first host material in the first emitting layer (first luminescent compound/first host material) is identical to a mass ratio of the first luminescent compound to the first host material in the first film (first luminescent compound/first host material).

The same applies to the wording “the same arrangement as that of the second emitting layer”.

The method of producing the measurement sample for the first film and the measurement sample for the second film is as follows.

The first host material (BH1) and the first luminescent compound (BD1) are co-deposited on a quartz substrate (25×25 mm) so that the mass ratio of the first luminescent compound to the first host material in the first film (first luminescent compound/first host material) is the same as that of the first emitting layer. The measurement sample for the first film having a film thickness of 50 nm is thus formed. A sealing glass (external dimension: 17×17 mm, internal dimension: 13×13 mm, dig depth: 0.5 mm) coated with a coating-type drying agent (OleDry-P2 produced by Futaba Corporation) is placed on the formed sample, and the formed sample is sealed with an ultraviolet-curing resin (TB3124N(IE) produced by ThreeBond Fine Chemical Co., Ltd). The measurement sample for the second film is formed as above.

For photoluminescence spectrum measurement, a fluorescence spectrometer (spectrophotofluorometer F-7000 produced by Hitachi High-Tech Science Corporation) is used.

The measurement conditions are as follows.

The maximum peak wavelength λ (unit: nm) and the full width at half maximum FWHM (unit: nm) of each film are calculated from the photoluminescence spectrum obtained by exciting the measurement sample for the film with a specific wavelength (a value of wavelength shorter by 30 nm than a maximum peak wavelength of an absorption spectrum).

Herein, the “host material” refers to, for instance, a material that accounts for “50 mass % or more of the layer”. That is, for instance, the first emitting layer contains 50 mass % or more of the first host material with respect to the total mass of the first emitting layer. For instance, the second emitting layer contains 50 mass % or more of the second host material with respect to the total mass of the second emitting layer.

### Emitting Region

The emitting region is disposed between the anode and the cathode. In the organic EL device according to the exemplary embodiment, the emitting region includes the first emitting layer and the second emitting layer.

In the organic EL device according to the exemplary embodiment, the first emitting layer may be disposed between the anode and the second emitting layer, or the first emitting layer may be disposed between the cathode and the second emitting layer. In the organic EL device according to the exemplary embodiment, the first emitting layer is preferably disposed between the anode and the second emitting layer.

In the organic EL device according to the exemplary embodiment, among a plurality of layers of the emitting region, one of the first emitting layer and the second emitting layer is preferably disposed closest to the cathode.

The organic EL device according to the exemplary embodiment may include the anode, the first emitting layer, the second emitting layer, and the cathode in this order, or the order of the first emitting layer and the second emitting layer may be reversed. In other words, the organic EL device may include the anode, the second emitting layer, the first emitting layer, and the cathode in this order.

In the organic EL device according to the exemplary embodiment, the first luminescent compound and the second luminescent compound are preferably each independently a compound that emits light having a maximum peak wavelength of 500 nm or less.

### First Emitting Layer

The first emitting layer contains the first host material and the first luminescent compound. The first host material is a compound different from the second host material contained in the second emitting layer.

In the organic EL device according to the exemplary embodiment, the first luminescent compound preferably emits light having a maximum peak wavelength of 500 nm or less. The first luminescent compound more preferably emits light having a maximum peak wavelength of 480 nm or less, still more preferably emits light having a maximum peak wavelength of 460 nm or less, and still further more preferably emits light having a maximum peak wavelength of 455 nm or less.

In the organic EL device according to the exemplary embodiment, the first luminescent compound preferably emits light having a maximum peak wavelength of 430 nm or more, more preferably emits light having a maximum peak wavelength of 440 nm or more, and still more preferably emits light having a maximum peak wavelength of 445 nm or more.

In the organic EL device according to the exemplary embodiment, the first luminescent compound is preferably a fluorescent compound.

In the organic EL device according to the exemplary embodiment, the first luminescent compound preferably emits fluorescence having a maximum peak wavelength of 500 nm or less. The first luminescent compound more preferably emits fluorescence having a maximum peak wavelength of 480 nm or less, still more preferably emits fluorescence having a maximum peak wavelength of 460 nm or less, and still further more preferably emits fluorescence having a maximum peak wavelength of 455 nm or less.

In the organic EL device according to the exemplary embodiment, the first luminescent compound preferably emits fluorescence having a maximum peak wavelength of 430 nm or more, more preferably emits fluorescence having a maximum peak wavelength of 440 nm or more, and still more preferably emits fluorescence having a maximum peak wavelength of 445 nm or more.

A method of measuring the maximum peak wavelength of the compound is as follows. A toluene solution of the measurement target compound at a concentration of 5 μmol/L is prepared and put in a quartz cell. An emission spectrum (ordinate axis: luminous intensity, abscissa axis: wavelength) of the thus-obtained sample is measured at a normal temperature (300K). The emission spectrum can be measured using a spectrophotofluorometer (apparatus name: F-7000) produced by Hitachi High-Tech Science Corporation. It should be noted that the apparatus for measuring the emission spectrum is not limited to the apparatus used herein.

A peak wavelength of the emission spectrum exhibiting the maximum luminous intensity is defined as the maximum peak wavelength. Herein, the maximum peak wavelength of fluorescence is occasionally referred to as a maximum fluorescence peak wavelength (FL-peak).

In an emission spectrum of the first luminescent compound, where a peak exhibiting a maximum luminous intensity is defined as a maximum peak and a height of the maximum peak is defined as 1, heights of other peaks appearing in the emission spectrum are preferably less than 0.6. It should be noted that the peaks in the emission spectrum are defined as local maximum values.

In addition, in the emission spectrum of the first luminescent compound, the number of peaks is preferably less than three.

In the organic EL device according to the exemplary embodiment, the first luminescent compound is preferably a compound containing no azine ring structure in a molecule.

In the organic EL device according to the exemplary embodiment, the first luminescent compound is preferably not a boron-containing complex, more preferably not a complex.

In the organic EL device according to the exemplary embodiment, the first emitting layer preferably does not contain a metal complex. In the organic EL device according to the exemplary embodiment, the first emitting layer also preferably does not contain a boron-containing complex.

In the organic EL device according to the exemplary embodiment, the first emitting layer preferably does not contain a phosphorescent material (dopant material).

In addition, the first emitting layer preferably does not contain a heavy-metal complex and a phosphorescent rare earth metal complex. Examples of the heavy-metal complex herein include an iridium complex, osmium complex, and platinum complex.

In the organic EL device according to the exemplary embodiment, the triplet energy of the first host material T₁(H1) and a triplet energy of the first luminescent compound T₁(D1) preferably satisfy a relationship of a numerical formula (Numerical Formula 3) below.

$${T}_{1} ( D 1 ) > {T}_{1} ( H 1 ) \qquad ( Numerical Formula 3 )$$

When the first host material and the first luminescent compound satisfy the relationship of the numerical formula (Numerical Formula 3), triplet excitons generated in the first emitting layer are transferred not onto the first luminescent compound having higher triplet energy but onto the first host material, thereby being easily transferred to the second emitting layer.

In the organic EL device according to the exemplary embodiment, a singlet energy of the first host material S₁(H1) and a singlet energy of the first luminescent compound S₁(D1) preferably satisfy a relationship of a numerical formula (Numerical Formula 4) below. The singlet energy S₁ refers to an energy difference between the lowest singlet state and the ground state.

$${S}_{1} ( H 1 ) > {S}_{1} ( D 1 ) \qquad ( Numerical Formula 4 )$$

When the first host material and the first luminescent compound satisfy the relationship of the numerical formula (Numerical Formula 4), singlet excitons generated on the first host material easily energy-transfer from the first host material to the first luminescent compound, thereby contributing to fluorescence of the first luminescent compound.

The organic EL device according to the exemplary embodiment preferably satisfies a relationship of a numerical formula (Numerical Formula 3B) below.

$${T}_{1} ( D 1 ) > {T}_{1} ( H 1 ) > {T}_{1} ( H 2 ) \qquad ( Numerical Formula 3 B )$$

### Triplet Energy T₁

A method of measuring a triplet energy T₁ is exemplified by a method below.

A measurement target compound is dissolved in EPA (diethylether:isopentane:ethanol=5:5:2 in volume ratio) so as to fall within a range from 10⁻⁵ mol/L to 10⁻⁴ mol/L, and the obtained solution is put in a quartz cell to provide a measurement sample. A phosphorescence spectrum (ordinate axis: phosphorescent luminous intensity, abscissa axis: wavelength) of the measurement sample is measured at a low temperature (77K). A tangent is drawn to the rise of the phosphorescence spectrum close to the short-wavelength region. An energy amount is calculated by a conversion equation (F1) below on a basis of a wavelength value λ_{edge} [nm] at an intersection of the tangent and the abscissa axis. The calculated energy amount is defined as triplet energy T₁.

$${T}_{1} [ eV ] = 1239.85 / {λ}_{edge} \qquad Conversion Equation ( F1 )$$

The tangent to the rise of the phosphorescence spectrum close to the short-wavelength region is drawn as follows. While moving on a curve of the phosphorescence spectrum from the short-wavelength region to the local maximum value closest to the short-wavelength region among the local maximum values of the phosphorescence spectrum, a tangent is checked at each point on the curve toward the long-wavelength of the phosphorescence spectrum. An inclination of the tangent is increased along the rise of the curve (i.e., a value of the ordinate axis is increased). A tangent drawn at a point of the local maximum inclination (i.e., a tangent at an inflection point) is defined as the tangent to the rise of the phosphorescence spectrum close to the short-wavelength region.

A local maximum point where a peak intensity is 15% or less of the maximum peak intensity of the spectrum is not counted as the above-mentioned local maximum peak intensity closest to the short-wavelength region. The tangent drawn at a point that is closest to the local maximum peak intensity closest to the short-wavelength region and where the inclination of the curve is the local maximum is defined as a tangent to the rise of the phosphorescence spectrum close to the short-wavelength region.

For phosphorescence measurement, a spectrophotofluorometer body F-4500 produced by Hitachi High-Technologies Corporation is usable. The measurement instrument is not limited to this arrangement. A combination of a cooling unit, a low temperature container, an excitation light source and a light-receiving unit may be used for the measurement.

### Singlet Energy S₁

A method of measuring the singlet energy S₁ with use of a solution (occasionally referred to as a solution method) is exemplified by a method below.

A toluene solution of a measurement target compound at a concentration ranging from 10⁻⁵ mol/L to 10⁻⁴ mol/L is prepared and put in a quartz cell. An absorption spectrum (ordinate axis: absorption intensity, abscissa axis: wavelength) of the thus-obtained sample is measured at a normal temperature (300K). A tangent is drawn to the fall of the absorption spectrum close to the long-wavelength region, and a wavelength value λ_{edge} [nm] at an intersection of the tangent and the abscissa axis is assigned to a conversion equation (F2) below to calculate a singlet energy.

$${S}_{1} [ eV ] = 1239.85 / {λ}_{edge} \qquad Conversion Equation ( F2 )$$

Any instrument for measuring absorption spectrum is usable. For instance, a spectrophotometer (U3310 manufactured by Hitachi, Ltd.) is usable.

The tangent to the fall of the absorption spectrum close to the long-wavelength region is drawn as follows. While moving on a curve of the absorption spectrum from the local maximum value closest to the long-wavelength region, among the local maximum values of the absorption spectrum, in a long-wavelength direction, a tangent at each point on the curve is checked. An inclination of the tangent is decreased and increased in a repeated manner as the curve falls (i.e., a value of the ordinate axis is decreased). A tangent drawn at a point where the inclination of the curve is the local minimum closest to the long-wavelength region (except when absorbance is 0.1 or less) is defined as the tangent to the fall of the absorption spectrum close to the long-wavelength region.

The local maximum absorbance of 0.2 or less is not counted as the above-mentioned local maximum absorbance closest to the long-wavelength region.

In the organic EL device according to the exemplary embodiment, the first luminescent compound is preferably contained at 0.5 mass % or more in the first emitting layer. Specifically, the first emitting layer contains the first luminescent compound preferably at 0.5 mass % or more, more preferably at 1.0 mass % or more, still more preferably at 1.2 mass % or more, and still further more preferably at 1.5 mass % or more, with respect to the total mass of the first emitting layer.

The first emitting layer contains the first luminescent compound preferably at 10 mass % or less, more preferably at 7 mass % or less, and still more preferably at 5 mass % or less, with respect to the total mass of the first emitting layer.

In the organic EL device according to the exemplary embodiment, the first emitting layer contains a first compound as the first host material preferably at 60 mass % or more, more preferably at 70 mass % or more, still more preferably at 80 mass % or more, still further more preferably at 90 mass % or more, and yet still further more preferably at 95 mass % or more, with respect to the total mass of the first emitting layer.

The first emitting layer preferably contains the first host material at 99 mass % or less with respect to the total mass of the first emitting layer.

When the first emitting layer contains the first host material and the first luminescent compound, the upper limit of the total of the content ratios of the first host material and the first luminescent compound is 100 mass %.

The first emitting layer of the exemplary embodiment may further contain any other material than the first host material and the first luminescent compound.

The first emitting layer may contain a single type of the first host material or may contain two or more types of the first host material. The first emitting layer may contain a single type of the first luminescent compound or may contain two or more types of the first luminescent compound.

In the organic EL device according to the exemplary embodiment, a film thickness of the first emitting layer is preferably 3 nm or more, more preferably 5 nm or more. A film thickness of the first emitting layer of 3 nm or more is sufficient for causing recombination of holes and electrons in the first emitting layer.

In the organic EL device according to the exemplary embodiment, the film thickness of the first emitting layer is preferably 15 nm or less, more preferably 10 nm or less. A film thickness of the first emitting layer of 15 nm or less is thin enough for transfer of triplet excitons to the second emitting layer.

In the organic EL device according to the exemplary embodiment, the film thickness of the first emitting layer is more preferably in a range from 3 nm to 15 nm.

### Second Emitting Layer

In the organic EL device according to the exemplary embodiment, the second emitting layer contains the second host material and the second luminescent compound. The second host material is a compound different from the first host material contained in the first emitting layer. In the organic EL device of the exemplary embodiment, the first luminescent compound and the second luminescent compound are mutually the same or different.

In the organic EL device according to the exemplary embodiment, the second luminescent compound preferably emits light having a maximum peak wavelength of 500 nm or less. The second luminescent compound more preferably emits light having a maximum peak wavelength of 480 nm or less, still more preferably emits light having a maximum peak wavelength of 460 nm or less, and still further more preferably emits light having a maximum peak wavelength of 455 nm or less.

In the organic EL device according to the exemplary embodiment, the second luminescent compound preferably emits light having a maximum peak wavelength of 430 nm or more, more preferably emits light having a maximum peak wavelength of 440 nm or more, and still more preferably emits light having a maximum peak wavelength of 445 nm or more.

In the organic EL device according to the exemplary embodiment, the second luminescent compound is preferably a fluorescent compound.

In the organic EL device according to the exemplary embodiment, the second luminescent compound preferably emits fluorescence having a maximum peak wavelength of 500 nm or less. The second luminescent compound more preferably emits fluorescence having a maximum peak wavelength of 480 nm or less, still more preferably emits fluorescence having a maximum peak wavelength of 460 nm or less, and still further more preferably emits fluorescence having a maximum peak wavelength of 455 nm or less.

In the organic EL device according to the exemplary embodiment, the second luminescent compound preferably emits fluorescence having a maximum peak wavelength of 430 nm or more, more preferably emits fluorescence having a maximum peak wavelength of 440 nm or more, and still more preferably emits fluorescence having a maximum peak wavelength of 445 nm or more.

A method of measuring the maximum peak wavelength of the compound is as described above.

In the organic EL device according to the exemplary embodiment, the full width at half maximum of a maximum peak of the second luminescent compound is preferably in a range from 1 nm to 20 nm.

In the organic EL device according to the exemplary embodiment, a triplet energy of the second luminescent compound T₁(D2) and the triplet energy of the second host material T₁(H2) preferably satisfy a relationship of a numerical formula (Numerical Formula 5) below.

$${T}_{1} ( D 2 ) > {T}_{1} ( H 2 ) \qquad ( Numerical Formula 5 )$$

When the second luminescent compound and the second host material satisfy the relationship of the numerical formula (Numerical Formula 5) in the organic EL device according to the exemplary embodiment, in transfer of triplet excitons generated in the first emitting layer to the second emitting layer, the triplet excitons energy-transfer not onto the second luminescent compound having higher triplet energy but onto molecules of the second host material. In addition, triplet excitons generated by recombination of holes and electrons on the second host material do not transfer to the second luminescent compound having higher triplet energy. Triplet excitons generated by recombination on molecules of the second luminescent compound quickly energy-transfer to molecules of the second host material.

Triplet excitons in the second host material do not transfer to the second luminescent compound but efficiently collide with one another on the second host material to generate singlet excitons by the TTF phenomenon.

In the organic EL device according to the exemplary embodiment, a singlet energy of the second host material S₁(H2) and a singlet energy of the second luminescent compound S₁(D2) preferably satisfy a relationship of a numerical formula (Numerical Formula 6) below.

$${S}_{1} ( H 2 ) > {S}_{1} ( D 2 ) \qquad ( Numerical Formula 6 )$$

When the second luminescent compound and the second host material satisfy the relationship of the numerical formula (Numerical Formula 6) in the organic EL device according to the exemplary embodiment, due to the singlet energy of the second luminescent compound being smaller than the singlet energy of the second host material, singlet excitons generated by the TTF phenomenon energy-transfer from the second host material to the second luminescent compound, thereby contributing to fluorescence of the second luminescent compound.

In the organic EL device according to the exemplary embodiment, the second luminescent compound is preferably a compound containing no azine ring structure in a molecule.

In the organic EL device according to the exemplary embodiment, the second luminescent compound is preferably not a boron-containing complex, more preferably not a complex.

In the organic EL device according to the exemplary embodiment, the second emitting layer preferably does not contain a metal complex. In the organic EL device according to the exemplary embodiment, the second emitting layer also preferably does not contain a boron-containing complex.

In the organic EL device according to the exemplary embodiment, the second emitting layer preferably does not contain a phosphorescent material (dopant material).

Further, the second emitting layer preferably does not contain a heavy-metal complex and a phosphorescent rare earth metal complex. Examples of the heavy-metal complex herein include an iridium complex, osmium complex, and platinum complex.

In the organic EL device according to the exemplary embodiment, the second luminescent compound is preferably contained at 0.5 mass % or more in the second emitting layer. Specifically, the second emitting layer contains the second luminescent compound preferably at 0.5 mass % or more, more preferably at 1.0 mass % or more, still more preferably at 1.2 mass % or more, and still further more preferably at 1.5 mass % or more, with respect to the total mass of the second emitting layer.

The second emitting layer contains the second luminescent compound preferably at 10 mass % or less, more preferably at 7 mass % or less, and still more preferably at 5 mass % or less with respect to the total mass of the second emitting layer.

The second emitting layer contains a second compound as the second host material preferably at 60 mass % or more, more preferably at 70 mass % or more, still more preferably at 80 mass % or more, still further more preferably at 90 mass % or more, and yet still further more preferably at 95 mass % or more, with respect to the total mass of the second emitting layer.

The second emitting layer preferably contains the second host material at 99 mass % or less with respect to the total mass of the second emitting layer.

When the second emitting layer contains the second host material and the second luminescent compound, the upper limit of the total of the content ratios of the second host material and the second luminescent compound is 100 mass %.

The second emitting layer of the exemplary embodiment may further contain any other material than the second host material and the second luminescent compound.

The second emitting layer may contain a single type of the second host material or may contain two or more types of the second host material. The second emitting layer may contain a single type of the second luminescent compound or may contain two or more types of the second luminescent compound.

In the organic EL device according to the exemplary embodiment, the film thickness of the second emitting layer is preferably 5 nm or more, more preferably 15 nm or more. When the film thickness of the second emitting layer is 5 nm or more, it is easy to inhibit triplet excitons having transferred from the first emitting layer to the second emitting layer from returning to the first emitting layer. Further, when the film thickness of the second emitting layer is 5 nm or more, triplet excitons can be sufficiently separated from the recombination portion in the first emitting layer.

In the organic EL device according to the exemplary embodiment, the film thickness of the second emitting layer is preferably 20 nm or less. When the film thickness of the second emitting layer is 20 nm or less, a density of the triplet excitons in the second emitting layer is improved to cause the TTF phenomenon more easily.

In the organic EL device according to the exemplary embodiment, the film thickness of the second emitting layer is preferably in a range from 5 nm to 20 nm.

In the organic EL device according to the exemplary embodiment, a triplet energy of a compound that emits fluorescence having a maximum peak wavelength of 500 nm or less contained in the first emitting layer or a compound that emits fluorescence having a maximum peak wavelength of 500 nm or less contained in the second emitting layer T₁(DX), the triplet energy of the first host material T₁(H1), and the triplet energy of the second host material T₁(H2) also preferably satisfy a relationship of a numerical formula (Numerical Formula 9) below, or also preferably satisfy a relationship of a numerical formula (Numerical Formula 10) below.

$$2.7 eV > {T}_{1} ( DX ) > {T}_{1} ( H 1 ) > {T}_{1} ( H 2 ) \qquad ( Numerical Formula 9 )$$

$$2.6 eV > {T}_{1} ( DX ) > {T}_{1} ( H 1 ) > {T}_{1} ( H 2 ) \qquad ( Numerical Formula 10 )$$

When the first emitting layer contains the first luminescent compound, the triplet energy of the first luminescent compound T₁(D1) also preferably satisfies a relationship of a numerical formula (Numerical Formula 9A) below, or also preferably satisfies a relationship of a numerical formula (Numerical Formula 10A) below.

$$2.7 V > {T}_{1} ( D 1 ) > {T}_{1} ( H 1 ) > {T}_{1} ( H 2 ) \qquad ( Numerical Formula 9 A )$$

$$2.6 eV > {T}_{1} ( D 1 ) > {T}_{1} ( H 1 ) > {T}_{1} ( H 2 ) \qquad ( Numerical Formula 10 A )$$

When the second emitting layer contains the second luminescent compound, the triplet energy of the second luminescent compound T₁(D2) also preferably satisfies a relationship of a numerical formula (Numerical Formula 9B) below, or also preferably satisfies a relationship of a numerical formula (Numerical Formula 10B) below.

$$2.7 eV > {T}_{1} ( D 2 ) > {T}_{1} ( H 1 ) > {T}_{1} ( H 2 ) \qquad ( Numerical Formula 9 B )$$

$$2.6 eV > {T}_{1} ( D 2 ) > {T}_{1} ( H 1 ) > {T}_{1} ( H 2 ) \qquad ( Numerical Formula 10 B )$$

In the organic EL device according to the exemplary embodiment, the triplet energy of a compound that emits fluorescence having a maximum peak wavelength of 500 nm or less contained in the first emitting layer or a compound that emits fluorescence having a maximum peak wavelength of 500 nm or less contained in the second emitting layer T₁(DX), and the triplet energy of the first host material T₁(H1) preferably satisfy a relationship of a numerical formula (Numerical Formula 11) below.

$$0 eV < {T}_{1} ( DX ) - {T}_{1} ( H 1 ) < 0.6 eV \qquad ( Numerical Formula 11 )$$

When the first emitting layer contains the first luminescent compound, the triplet energy of the first luminescent compound T₁(D1) preferably satisfies a relationship of a numerical formula (Numerical Formula 11A) below.

$$0 eV < {T}_{1} ( D 1 ) - {T}_{1} ( H 1 ) < 0.6 eV \qquad ( Numerical Formula 11 A )$$

When the second emitting layer contains the second luminescent compound, the triplet energy of the second luminescent compound T₁(D2) preferably satisfies a relationship of a numerical formula (Numerical Formula 11B) below.

$$0 eV < {T}_{1} ( D 2 ) - {T}_{1} ( H 2 ) < 0.8 eV \qquad ( Numerical Formula 11 B )$$

In the organic EL device according to the exemplary embodiment, the triplet energy of the first host material T₁(H1) preferably satisfies a relationship of a numerical formula (Numerical Formula 12) below.

$${T}_{1} ( H 1 ) > 2. eV \qquad ( Numerical Formula 12 )$$

In the organic EL device according to the exemplary embodiment, the triplet energy of the first host material T₁(H1) also preferably satisfies a relationship of a numerical formula (Numerical Formula 12A) below, or also preferably satisfies a relationship of a numerical formula (Numerical Formula 12B) below.

$${T}_{1} ( H 2 ) > 2.1 eV \qquad ( Numerical Formula 12 A )$$

$${T}_{1} ( H 1 ) > 2.15 eV \qquad ( Numerical Formula 12 B )$$

In the organic EL device according to the exemplary embodiment, when the triplet energy of the first host material T₁(H1) satisfies the relationship of the numerical formula (Numerical Formula 12A) or of the numerical formula (Numerical Formula 12B), triplet excitons generated in the first emitting layer are easily transferred to the second emitting layer, and also are easily inhibited from back-transferring from the second emitting layer to the first emitting layer. Consequently, singlet excitons are efficiently generated in the second emitting layer, thereby improving luminous efficiency.

In the organic EL device according to the exemplary embodiment, the triplet energy of the first host material T₁(H1) also preferably satisfies a relationship of a numerical formula (Numerical Formula 12C) below, or also preferably satisfies a relationship of a numerical formula (Numerical Formula 12D) below.

$$2.08 eV > {T}_{1} ( H 1 ) > 1.87 eV \qquad ( Numerical Formula 12 C )$$

$$2.05 eV > {T}_{1} ( H 1 ) > 1.9 eV \qquad ( Numerical Formula 12 D )$$

In the organic EL device according to the exemplary embodiment, when the triplet energy of the first host material T₁(H1) satisfies the relationship of the numerical formula (Numerical Formula 12C) or of the numerical formula (Numerical Formula 12D), the energy of triplet excitons generated in the first emitting layer is reduced. The organic EL device of the exemplary embodiment can thus be expected to have a longer lifetime.

In the organic EL device according to the exemplary embodiment, a triplet energy of a compound that emits fluorescence having a maximum peak wavelength of 500 nm or less contained in the first emitting layer T₁(F1) also preferably satisfies a relationship of a numerical formula (Numerical Formula 14A) below, or also preferably satisfies a relationship of a numerical formula (Numerical Formula 14B) below.

$$2.6 eV > {T}_{1} ( F 1 ) \qquad ( Numerical Formula 14 A )$$

$$2.5 eV > {T}_{1} ( F 1 ) \qquad ( Numerical Formula 14 B )$$

The organic EL device has a longer lifetime when the first emitting layer contains the compound that satisfies the relationship of the numerical formula (Numerical Formula 14A) or (Numerical Formula 14B).

In the organic EL device according to the exemplary embodiment, a triplet energy of a compound that emits fluorescence having a maximum peak wavelength of 500 nm or less contained in the second emitting layer T₁(F2) also preferably satisfies a relationship of a numerical formula (Numerical Formula 14C) below, or also preferably satisfies a relationship of a numerical formula (Numerical Formula 14D) below.

$$2.6 eV > {T}_{1} ( F 2 ) \qquad ( Numerical Formula 14 C )$$

$$2.5 eV > {T}_{1} ( F 2 ) \qquad ( Numerical Formula 14 D )$$

The organic EL device has a longer lifetime when the second emitting layer contains the compound that satisfies the relationship of the numerical formula (Numerical Formula 14C) or (Numerical Formula 14D).

In the organic EL device according to the exemplary embodiment, the triplet energy of the second host material T₁(H2) also preferably satisfies a relationship of a numerical formula (Numerical Formula 13) below.

$${T}_{1} ( H 2 ) \geq 1.9 eV \qquad ( Numerical Formula 13 )$$

In the organic EL device according to the exemplary embodiment, the triplet energy of the second host material T₁(H2) also preferably satisfies a relationship of a numerical formula (Numerical Formula 13A) below.

$$1.9 eV > {T}_{1} ( H 2 ) \qquad ( Numerical Formula 13 A )$$

### Additional Layers of Organic EL Device

In addition to the first and second emitting layers, the organic EL device according to the exemplary embodiment may include at least one layer containing an organic compound(s). Examples of the layer containing the organic compound(s) include at least one layer selected from the group consisting of a hole injecting layer, a hole transporting layer, an electron blocking layer, a hole blocking layer, an electron injecting layer, and an electron transporting layer. The layer containing the organic compound(s) may further contain an inorganic compound(s).

The organic layer of the organic EL device according to the exemplary embodiment may consist of the first emitting layer and the second emitting layer, or may further include, for instance, at least one layer selected from the group consisting of a hole injecting layer, a hole transporting layer, an electron blocking layer, a hole blocking layer, an electron injecting layer, and an electron transporting layer.

In the organic EL device according to the exemplary embodiment, when the first emitting layer and the second emitting layer are layered in this order from a side close to the anode, an electron mobility of the first host material μe(H1) and an electron mobility of the second host material μe(H2) preferably satisfy a relationship of a numerical formula (Numerical Formula 70) below.

$$μ e ( H 2 ) > μ e ( H 1 ) \qquad ( Numerical Formula 70 )$$

When the first host material and the second host material satisfy the relationship of the numerical formula (Numerical Formula 70), a recombination ability between holes and electrons in the first emitting layer improves.

In the organic EL device according to the exemplary embodiment, when the first emitting layer and the second emitting layer are layered in this order from a side close to the anode, a hole mobility of the first host material μh(H1) and a hole mobility of the second host material μh(H2) also preferably satisfy a relationship of a formula (Numerical Formula 71) below.

$$μ h ( H 1 ) > μ h ( H 2 ) \qquad ( Numerical Formula 71 )$$

In the organic EL device according to the exemplary embodiment, when the first emitting layer and the second emitting layer are layered in this order from a side close to the anode, the hole mobility of the first host material μh(H1), the electron mobility of the first host material μe(H1), the hole mobility of the second host material μh(H2), and the electron mobility of the second host material μe(H2) also preferably satisfy a relationship of a numerical formula (Numerical Formula 72) below.

$$( μ e ( H 2 ) / μ h ( H 2 ) ) > ( μ e ( H 1 ) / μ h ( H 1 ) ) \qquad ( Numerical Formula 72 )$$

The electron mobility can be measured according to an impedance measurement using a mobility evaluation device produced by the following steps. The device for mobility evaluation is produced, for instance, according to the following steps.

A compound Target, which is to be measured for an electron mobility, is vapor-deposited on a glass substrate having an aluminum electrode (anode) so as to cover the aluminum electrode, thereby forming a measurement target layer. A compound bET-1 below is vapor-deposited on this measurement target layer to form an electron transporting layer. LiF is vapor-deposited on this formed electron transporting layer to form an electron injecting layer. Metal aluminum (Al) is vapor-deposited on this formed electron injecting layer to form a metal cathode.

An arrangement of the mobility evaluation device above is roughly shown as follows.

$$glass / Al ( 50 ) / Target ( 200 ) / bET - 1 ( 10 ) / LiF ( 1 ) / Al ( 50 )$$

Numerals in parentheses represent a film thickness (nm).

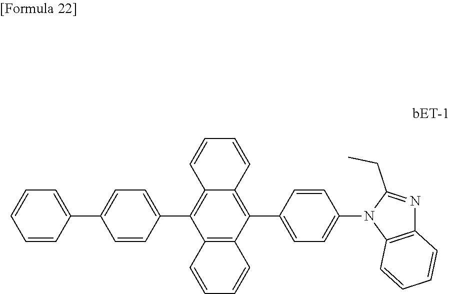 [SMILES: CCc1nc2ccccc2n1-c1ccc(-c2c3ccccc3c(-c3ccc(-c4ccccc4)cc3)c3ccccc23)cc1]

The mobility evaluation device for the electron mobility is set in an impedance measurement apparatus to perform an impedance measurement. In the impedance measurement, a measurement frequency is swept from 1 Hz to 1 MHz. At this time, an alternating current amplitude of 0.1 V and a direct current voltage V are simultaneously applied to the device. A modulus M is calculated from a measured impedance Z using a relationship of a calculation formula (C1) below.

$$M = j ω Z \qquad Calculation Formula ( C1 )$$

In the calculation formula (C1), j is an imaginary unit whose square is −1 and w is an angular frequency [rad/s].

In a bode plot in which an imaginary part of the modulus M is represented by an ordinate axis and the frequency [Hz] is represented by an abscissa axis, an electrical time constant T of the mobility evaluation device is obtained from a frequency fmax showing a peak using a calculation formula (C2) below.

$$T = 1 / ( 2 π f max ) \qquad Calculation Formula ( C2 )$$

π in the calculation formula (C2) is a symbol representing a circumference ratio.

An electron mobility μe is calculated from a relationship of a calculation formula (C3-1) below using τ.

$$μ e = {d}^{2} / ( {V}_{T} ) \qquad Calculation Formula ( C3 - 1 )$$

d in the calculation formula (C3-1) is a total film thickness of organic thin film(s) forming the device. In a case of the arrangement of the mobility evaluation device for the electron mobility, d=210 [nm] is satisfied.

The hole mobility can be measured according to an impedance measurement using a mobility evaluation device produced by the following steps. The device for mobility evaluation is produced, for instance, according to the following steps.

A compound HIL-1 below is vapor-deposited on a glass substrate having an ITO transparent electrode (anode) so as to cover the transparent electrode, thereby forming a hole injecting layer. A compound HTL-1 below is vapor-deposited on this formed hole injecting layer to form a hole transporting layer. Subsequently, a compound Target, which is to be measured for a hole mobility, is vapor-deposited to form a measurement target layer. Metal aluminum (Al) is vapor-deposited on this measurement target layer to form a metal cathode.

An arrangement of the mobility evaluation device above is roughly shown as follows.

$$ITO ( 130 ) / HIL - 1 ( 5 ) / HTL - 1 ( 10 ) / Target ( 200 ) / Al ( 80 )$$

Numerals in parentheses represent a film thickness (nm).

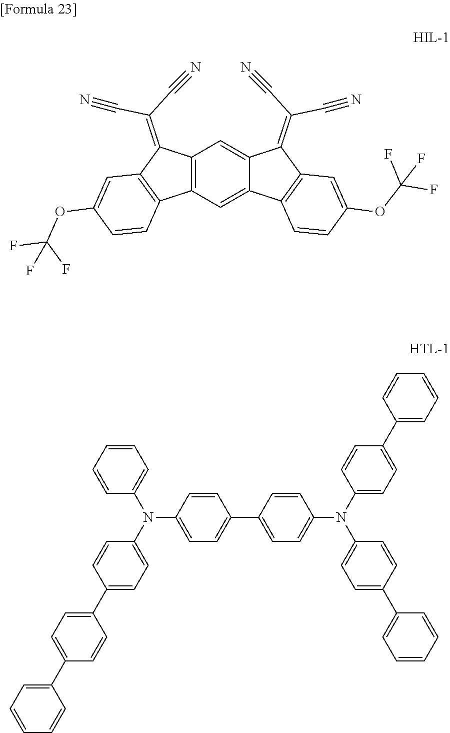 [SMILES: N#CC(C#N)=C1c2cc(OC(F)(F)F)ccc2-c2cc3c(cc21)C(=C(C#N)C#N)c1cc(OC(F)(F)F)ccc1-3 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

The mobility evaluation device for the hole mobility is set in an impedance measurement apparatus to perform an impedance measurement. In the impedance measurement, a measurement frequency is swept from 1 Hz to 1 MHz. At this time, an alternating current amplitude of 0.1 V and a direct current voltage V are simultaneously applied to the device. A modulus M is calculated from a measured impedance Z using the relationship of the calculation formula (C1).

In a bode plot in which an imaginary part of the modulus M is represented by an ordinate axis and the frequency [Hz] is represented by an abscissa axis, an electrical time constant τ of the mobility evaluation device is obtained from a frequency fmax showing a peak using the calculation formula (C2).

A hole mobility μh is calculated from a relationship of a calculation formula (C3-2) below using τ obtained from the calculation formula (C2).

$$Calculation Formula ( C 3 - 2 ) : μ h = {d}^{2} / ( {V}_{T} )$$

d in the calculation formula (C3-2) is a total film thickness of organic thin film(s) forming the device. In a case of the arrangement of the mobility evaluation device for the hole mobility, d=215 [nm] is satisfied.

The electron mobility and the hole mobility herein are each a value obtained in a case where a square root of an electric field intensity meets E^{1/2}=500 [V^{1/2}/cm^{1/2}]. The square root of the electric field intensity, E^{1/2}, can be calculated from a relationship of a calculation formula (C4) below.

$$Calculation formula ( C 4 ) : {E}^{1 / 2} = {V}^{1 / 2} / {d}^{1 / 2}$$

For the impedance measurement, a 1260 type by Solartron Analytical is used as the impedance measurement apparatus, and for a higher accuracy, a 1296 type dielectric constant measurement interface by Solartron Analytical can be used together therewith.

In the organic EL device according to the exemplary embodiment, the first emitting layer and the second emitting layer are preferably in direct contact with each other.

Herein, a layer arrangement in which “the first emitting layer and the second emitting layer are in direct contact with each other” may include, for instance, one of arrangements (LS1), (LS2), and (LS3) below.

(LS1) An arrangement in which a region containing both the first host material and the second host material is generated in a process of vapor-depositing the compound of the first emitting layer and vapor-depositing the compound of the second emitting layer, and is present on the interface between the first emitting layer and the second emitting layer.

(LS2) An arrangement in which in a case of containing a luminescent compound in the first emitting layer and the second emitting layer, a region containing the first host material, the second host material and the luminescent compound is generated in a process of vapor-depositing the compound of the first emitting layer and vapor-depositing the compound of the second emitting layer, and is present on the interface between the first emitting layer and the second emitting layer.

(LS3) An arrangement in which in a case of containing a luminescent compound in the first emitting layer and the second emitting layer, a region containing the luminescent compound, a region containing the first host material, or a region containing the second host material is generated in a process of vapor-depositing the compound of the first emitting layer and vapor-depositing the compound of the second emitting layer, and is present on the interface between the first emitting layer and the second emitting layer.

### Schematic Arrangement of Organic EL Devices

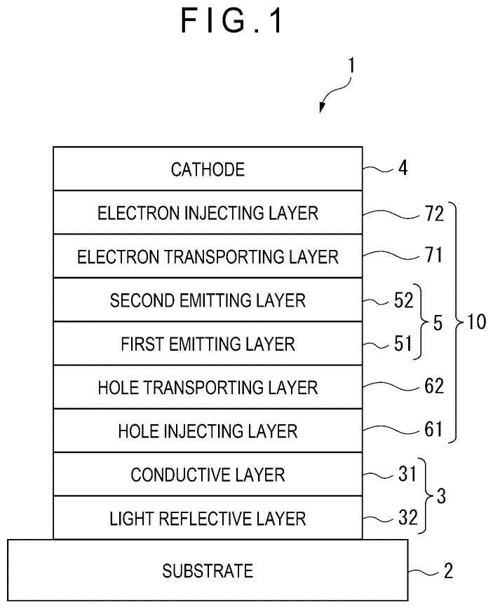

FIG. 1 schematically illustrates an exemplary arrangement of an organic EL device according to the exemplary embodiment. An organic EL device 1 illustrated in FIG. 1 is an organic EL device of a top emission type, in which a side of the organic EL device through which light is extracted is a side on which a cathode 4 is provided.

The organic EL device 1 includes a substrate 2, an anode 3, the cathode 4, and an organic layer 10 disposed between the anode 3 and the cathode 4. The organic layer 10 includes a hole injecting layer 61, a hole transporting layer 62, a first emitting layer 51, a second emitting layer 52, an electron transporting layer 71, and an electron injecting layer 72 that are layered on the anode 3 in this order. The anode 3 of the organic EL device 1 includes a conductive layer 31 and a light reflective layer 32. The conductive layer 31 is disposed between the light reflective layer 32 and the hole injecting layer 61. An emitting region 5 of the organic EL device 1 includes the first emitting layer 51 at a side close to the anode 3 and the second emitting layer 52 at a side close to the cathode 4.

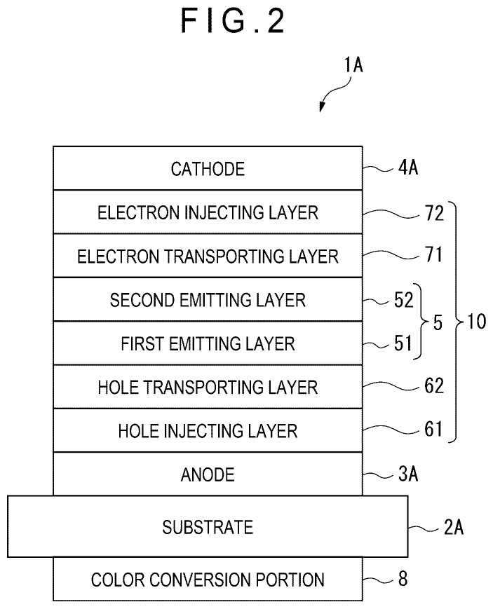

FIG. 2 schematically illustrates another exemplary arrangement of the organic EL device according to the exemplary embodiment. An organic EL device 1A illustrated in FIG. 2 is an organic EL device of a bottom emission type, in which a side of the organic EL device through which light is extracted is a side on which an anode 3A is provided.

The organic EL device 1A includes a light transmissive substrate 2A, the anode 3A, a cathode 4A, and the organic layer 10 disposed between the anode 3A and the cathode 4A. The organic layer 10 includes the hole injecting layer 61, the hole transporting layer 62, the first emitting layer 51, the second emitting layer 52, the electron transporting layer 71, and the electron injecting layer 72 that are layered on the anode 3A in this order. The organic EL device 1A further includes a color conversion portion 8 through which light emitted from the first emitting layer 51 and the second emitting layer 52 is transmitted. In the organic EL device 1A, the color conversion portion 8 is a color filter. The color conversion portion 8 is disposed at a side of the organic EL device 1A through which light is extracted, that is, a side on which the anode 3A is provided. In an example illustrated in FIG. 2, the color conversion portion 8 is disposed on a surface opposite a surface facing the anode 3A of the substrate 2A.

The organic EL device according to the exemplary embodiment is not limited to the organic EL devices illustrated in FIGS. 1 and 2.

The organic EL device having another arrangement is exemplified by an organic EL device including the organic layer in which the hole injecting layer, the hole transporting layer, the second emitting layer, the first emitting layer, the electron transporting layer, and the electron injecting layer that are layered on the anode in this order.

The organic EL device having still another arrangement is exemplified by an organic EL device of the top emission type in which the color conversion portion is disposed at a side of the organic EL device through which light is extracted, that is, on which the cathode is provided. In this arrangement, for instance, the color conversion portion (e.g., a color filter and a quantum dot) may be disposed on the cathode.

The organic EL device having a further arrangement is exemplified by an organic EL device of the top emission type in which the light reflective layer, the substrate, and the conductive layer are arranged in this order.

The organic EL device having a still further arrangement is exemplified by an organic EL device of the bottom emission type in which the color conversion portion is disposed between the substrate and the anode.

The organic EL device having a yet still further arrangement is exemplified by an organic EL device of the bottom emission type in which the color conversion portion is not provided.

The arrangement of the organic EL device will be further described below. It should be noted that the reference numerals are occasionally omitted below.

In the organic EL device according to the exemplary embodiment, the organic layer may be disposed between the first emitting layer and the second emitting layer.

### Interposed Layer

The organic EL device according to the exemplary embodiment may include an interposed layer, as the organic layer disposed between the first emitting layer and the second emitting layer.

In the exemplary embodiment, in order to inhibit an overlap between a Singlet emitting region and a TTF emitting region, the interposed layer contains no luminescent compound or may contain the luminescent compound in an insubstantial amount provided that the overlap can be inhibited.

For instance, the interposed layer contains 0 mass % of the luminescent compound. Alternatively, for instance, the interposed layer may contain the luminescent compound provided that the luminescent compound contained is a component accidentally mixed in a producing process or a component contained as impurities in a material.

For instance, when the interposed layer consists of a material A, a material B, and a material C, the content ratios of the materials A, B, and C in the interposed layer are each 10 mass % or more, and the total of the content ratios of the materials A, B, and C is 100 mass %.

In the following, the interposed layer is occasionally referred to as a “non-doped layer”. A layer containing a luminescent compound is occasionally referred to as a “doped layer”.

It is considered that luminous efficiency is improvable in an arrangement including layered emitting layers because the Singlet emitting region and the TTF emitting region are typically likely to be separated from each other.

In the organic EL device of the exemplary embodiment, when the interposed layer (non-doped layer) is disposed between the first emitting layer and the second emitting layer in the emitting region, it is expected that a region where the Singlet emitting region and the TTF emitting region overlap with each other is reduced to inhibit a decrease in TTF efficiency, which may otherwise be caused by collision between triplet excitons and carriers. That is, it is considered that providing the interposed layer (non-doped layer) between the emitting layers contributes to the improvement in the efficiency of TTF emission.

The interposed layer is a non-doped layer.

The interposed layer contains no metal atom. The interposed layer thus contains no metal complex.

The interposed layer contains an interposed layer material. The interposed layer material is not the luminescent compound.

The interposed layer material may be any material except for the luminescent compound.

Examples of the interposed layer material include: 1) a heterocyclic compound such as an oxadiazole derivative, benzimidazole derivative, or phenanthroline derivative; 2) a fused aromatic compound such as a carbazole derivative, anthracene derivative, phenanthrene derivative, pyrene derivative or chrysene derivative; and 3) an aromatic amine compound such as a triarylamine derivative or a fused polycyclic aromatic amine derivative.

One or both of the first host material and the second host material may be used as the interposed layer material. The interposed layer material may be any material provided that the Singlet emitting region and the TTF emitting region are separated from each other and the Singlet emission and the TTF emission are not hindered.

In the organic EL device according to the exemplary embodiment, the content ratios of all the materials forming the interposed layer in the interposed layer are each 10 mass % or more.

The interposed layer contains the interposed layer material as a material forming the interposed layer.

The interposed layer contains the interposed layer material preferably at 60 mass % or more, more preferably at 70 mass % or more, still more preferably at 80 mass % or more, still further more preferably at 90 mass % or more, and yet still further more preferably at 95 mass % or more, with respect to the total mass of the interposed layer.

The interposed layer may contain a single type of interposed layer material or two or more types of interposed layer materials.

When the interposed layer contains two or more types of interposed layer materials, the upper limit of the total of the content ratios of the two or more types of interposed layer materials is 100 mass %.

It should be noted that the interposed layer of the exemplary embodiment may further contain any other material than the interposed layer material.

The interposed layer may be provided in the form of a single layer or a laminate of two or more layers.

As long as the overlap between the Singlet emitting region and the TTF emitting region is inhibited, a film thickness of the interposed layer is not particularly limited but each layer in the interposed layer is preferably in a range from 3 nm to 15 nm, more preferably in a range from 5 nm to 10 nm.

The interposed layer having a film thickness of 3 nm or more easily separates the Singlet emitting region from the emitting region derived from TTF.

The interposed layer having a film thickness of 15 nm or less easily inhibits a phenomenon in which the host material of the interposed layer emits light.

It is preferable that the interposed layer contains the interposed layer material as a material forming the interposed layer and the triplet energy of the first host material T₁(H1), the triplet energy of the second host material T₁(H2), and a triplet energy of at least one interposed layer material T₁(M_{mid}) satisfy a relationship of a numerical formula (Numerical Formula 21) below.

$${T}_{1} ( H 1 ) \geq {T}_{1} ( {M}_{mid} ) \geq {T}_{1} ( H 2 ) \qquad ( Numerical Formula 21 )$$

When the interposed layer contains two or more interposed layer materials as a material forming the interposed layer, the triplet energy of the first host material T₁(H1), the triplet energy of the second host material T₁(H2), and a triplet energy of each interposed layer material T₁(M_{EA}) more preferably satisfy a relationship of a numerical formula (Numerical Formula 21A) below.

$${T}_{1} ( H 1 ) \geq {T}_{1} ( {M}_{EA} ) \geq {T}_{1} ( H 2 ) \qquad ( Numerical Formula 21 A )$$

### Substrate

A substrate is used as a support for the organic EL device. For instance, glass, quartz, plastics and the like are usable for the substrate. A flexible substrate is also usable. The flexible substrate, which is a bendable substrate, is exemplified by a plastic substrate. Examples of a material for the plastic substrate include polycarbonate, polyarylate, polyethersulfone, polypropylene, polyester, polyvinyl fluoride, polyvinyl chloride, polyimide, and polyethylene naphthalate. Further, an inorganic vapor deposition film is also usable.

### Anode

Metal, an alloy, an electrically conductive compound, a mixture thereof, or the like having a large work function (specifically, 4.0 eV or more) is preferably used as the anode formed on the substrate. Specific examples of the material include indium tin oxide (ITO), indium oxide-tin oxide containing silicon or silicon oxide, indium oxide-zinc oxide, indium oxide containing tungsten oxide and zinc oxide, and graphene. In addition, gold (Au), platinum (Pt), nickel (Ni), tungsten (W), chrome (Cr), molybdenum (Mo), iron (Fe), cobalt (Co), copper (Cu), palladium (Pd), titanium (Ti), and nitrides of a metal material (e.g., titanium nitride) are usable.

The material is typically formed into a film by a sputtering method. For instance, the indium oxide-zinc oxide can be formed into a film by the sputtering method using a target in which zinc oxide in a range from 1 mass % to 10 mass % is added to indium oxide. Moreover, for instance, the indium oxide containing tungsten oxide and zinc oxide can be formed by the sputtering method using a target in which tungsten oxide in a range from 0.5 mass % to 5 mass % and zinc oxide in a range from 0.1 mass % to 1 mass % are added to indium oxide. In addition, the anode may be formed by a vacuum deposition method, a coating method, an inkjet method, a spin coating method or the like.

Among the EL layers formed on the anode, since the hole injecting layer adjacent to the anode is formed of a composite material into which holes are easily injectable irrespective of the work function of the anode, a material usable as an electrode material (e.g., metal, an alloy, an electroconductive compound, a mixture thereof, and the elements belonging to the Group 1 or 2 of the periodic table) is also usable for the anode.

A material having a small work function such as elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), alloys containing the alkali metal or the alkaline earth metal (e.g., MgAg and AlLi), a rare earth metal such as europium (Eu) and ytterbium (Yb), and alloys containing the rare earth metal are also usable for the anode. It should be noted that the vacuum deposition method and the sputtering method are usable for forming the anode using the alkali metal, alkaline earth metal and/or the alloy thereof. Further, when a silver paste is used for the anode, the coating method and the inkjet method are usable.

When the organic EL device is of the bottom emission type, the anode is a light transmissive electrode having light transmissivity. The light transmissive electrode is preferably formed from a light transmissive or semi-transmissive metallic material that allows light from the emitting layer to pass through. The light transmissive or semi-transmissive property herein refers to a property of allowing a transmittance of 50% or more (preferably 80% or more) of the light emitted from the emitting layer. The light transmissive or semi-transmissive metallic material can be selected in use as needed from the above materials listed in the description about the anode. Any material usable for the later-described conductive layer (or a transparent conductive layer) may be used as the light transmissive or semi-transmissive metallic material.

When the organic EL device is of the top emission type, the anode is the light reflective electrode including the light reflective layer. The light reflective layer is preferably formed from a metallic material having light reflectivity. The light reflectivity herein refers to a property of reflecting 50% or more (preferably 80% or more) of light emitted from the emitting layer. The metallic material having light reflectivity can be selected in use as needed from the above materials listed in the description about the anode.

Examples of the metallic material used for the light reflective layer include: a single metal material selected from the group consisting of Al, Ag, Ta, Zn, Mo, W, Ni, Cr, and the like, or an alloy material containing a metal selected from the above group as a main component (preferably 50 mass % or more of the whole); an amorphous alloy selected from the group consisting of NiP, NiB, CrP, CrB, and the like; and microcrystalline alloy selected from the group consisting of NiAl, a silver alloy, and the like.

Also, as the metallic material used for the light reflective layer, at least one alloy selected from the group consisting of APC (silver, palladium and copper alloy), ARA (silver, rubidium and gold alloy), MoCr (molybdenum and chromium alloy), and NiCr (nickel and chromium alloy) is usable.

The light reflective layer may be provided by a single layer or a plurality of layers.

The anode as the light reflectivity electrode may consist of the light reflective layer, or may have a multilayer structure having the light reflective layer and the conductive layer (preferably, the transparent conductive layer). When the anode includes the light reflective layer and the conductive layer, the conductive layer is preferably provided between the light reflective layer and a layer included in a hole transporting zone (e.g., a hole injection layer or a hole transporting layer). Alternatively, the anode may have a multilayer structure in which the light reflective layer is provided between two conductive layers (first conductive layer and second conductive layer). In such a multilayer structure, the first and second conductive layers may be formed from the same material or mutually different materials.

The material used for the conductive layer can be selected in use as needed from the above materials listed in the description about the anode. Metal, an alloy, an electrically conductive compound, a mixture thereof, or the like having a large work function (specifically, 4.0 eV or more) can also be used as the conductive layer (transparent conductive layer) as the transparent electrode.

Further, an alkali metal such as lithium (Li) and cesium (Cs), an alkaline earth metal such as magnesium (Mg), calcium (Ca) and strontium (Sr), an alloy containing at least one selected from the group consisting of an alkali metal and an alkaline earth metal (e.g., MgAg and AlLi), a rare earth metal such as europium (Eu) and ytterbium (Yb), an alloy containing at least one rare earth metal, or the like are also usable for the conductive layer.

### Cathode

It is preferable to use metal, an alloy, an electroconductive compound, a mixture thereof, or the like having a small work function (specifically, 3.8 eV or less) for the cathode. Specific examples of the material for the cathode include elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), an alloy containing the alkali metal or the alkaline earth metal (e.g., MgAg and AlLi), a rare earth metal such as europium (Eu) and ytterbium (Yb), and an alloy containing the rare earth metal.

It should be noted that the vacuum deposition method and the sputtering method are usable for forming the cathode using the alkali metal, alkaline earth metal and/or the alloy thereof. Further, when a silver paste is used for the cathode, the coating method and the inkjet method are usable.

By providing the electron injecting layer, various conductive materials such as Al, Ag, ITO, graphene, and indium oxide-tin oxide containing silicon or silicon oxide may be used for forming the cathode regardless of the work function. The conductive materials can be formed into a film using the sputtering method, inkjet method, spin coating method, and the like.

When the organic EL device is of the bottom emission type, the cathode is the light reflective electrode. The light reflective electrode is preferably formed from a metallic material having light reflectivity. The metallic material having light reflectivity can be selected in use as needed from the above materials listed in the description about the cathode. Further, any metallic material usable for the light reflective layer given above may be used as the metallic material having light reflectivity.

When the organic EL device is of the top emission type, the cathode is the light transmissive electrode having light transmissivity. The light transmissive electrode is preferably formed from a light transmissive or semi-transmissive metallic material that allows light from the emitting layer to pass through. The light transmissive or semi-transmissive property refers to a property of allowing a transmittance of 50% or more (preferably 80% or more) of the light emitted from the emitting layer. The light transmissive or semi-transmissive metallic material can be selected in use as needed from the above materials listed in the description about the cathode. Any material usable for the above-described conductive layer (or the transparent conductive layer) may be used as the light transmissive or semi-transmissive metallic material.

### Capping Layer

The organic EL device of the top emission type may include a capping layer on the top of the cathode. The capping layer may be disposed on a surface of the cathode opposite a surface facing the anode.

The capping layer may contain, for instance, at least one compound selected from the group consisting of a high polymer compound, metal oxide, metal fluoride, metal boride, silicon nitride, and silicon compound (e.g., silicon oxide).

In addition, the capping layer may contain, for instance, at least one compound selected from the group consisting of an aromatic amine derivative, anthracene derivative, pyrene derivative, fluorene derivative, or dibenzofuran derivative.

Moreover, a laminate obtained by layering two or more layers containing the compound(s) usable for the capping layer is also usable as the capping layer.

### Color Conversion Portion

The color conversion portion is provided on a side of the organic EL device through which light is extracted, and serves as converting the light extracted through the light extraction side to light with a desired color.

The color conversion portion is preferably disposed on an electrode (transparent electrode) that is either the anode or the cathode, which is provided on the side through which light is extracted.

The color conversion portion may be, for instance, a color filter, a material including a quantum dot, or a combination of the color filter and the material including the quantum dot.

### Color Filter

A material for the color filter is exemplified by the following dyes only and solid materials obtained by dissolving or dispersing the following dyes in a binder resin.

### Red (R) Dye

It is possible to use one selected from the group consisting of a perylene pigment, lake pigment, azo pigment, quinacridone pigment, anthraquinone pigment, anthracene pigment, isoindoline pigment, isoindolinone pigment, and the like, or a mixture containing two or more thereof.

### Green (G) Dye

It is possible to use one selected from the group consisting of a halogen polysubstituted phthalocyanine pigment, halogen polysubstituted copper phthalocyanine pigment, triphenylmethane basic dye, isoindoline pigment, isoindolinone pigment, and the like, or a mixture containing two or more thereof.

### Blue (B) Dye

It is possible to use one selected from the group consisting of a copper phthalocyanine pigment, indanthrone pigment, indophenol pigment, cyanine pigment, dioxazine pigment, and the like, or a mixture containing two or more thereof.

The binder resin used as the material for the color filter is preferably a transparent material. For instance, a material having a transmittance of 50% or more in a visible light region is preferably used.

The binder resin used as the material for the color filter is preferably a transparent resin (polymer) or the like. The binder resin used as the material for the color filter is preferably one selected from the group consisting of polymethyl methacrylate, polyacrylate, polycarbonate, polyvinyl alcohol, polyvinyl pyrrolidone, hydroxyethyl cellulose, carboxymethyl cellulose, and the like, or a mixture containing two or more thereof.

### Quantum Dot

A material including the quantum dot is exemplified by a material in which quantum dots are dispersed in a resin. For instance, it is possible to use, as the quantum dot, at least one selected from the group consisting of CdSe, ZnSe, CdS, CdSeS/ZnS, InP, InP/ZnS, CdS/CdSe, CdS/ZnS, PbS, and CdTe.

The color conversion portion may include a red conversion area where blue light is converted to red light, a green conversion area where blue light is converted to green light, and a blue transmissive area through which blue light passes. The color conversion portion is also preferably configured to obtain three colors of light from the organic EL device or a mixed-color light thereof. For instance, when a full width at half maximum of an emission peak of the blue light emitted from the first emitting layer and the second emitting layer is narrow and color purity thereof is high, the light emitted through the red conversion area is converted to red light with high color purity and the light emitted through the green conversion area is converted to green light with high color purity.

### Hole Injecting Layer

The hole injecting layer is a layer containing a substance exhibiting a high hole injectability. Examples of the substance exhibiting a high hole injectability include molybdenum oxide, titanium oxide, vanadium oxide, rhenium oxide, ruthenium oxide, chrome oxide, zirconium oxide, hafnium oxide, tantalum oxide, silver oxide, tungsten oxide, and manganese oxide.

In addition, the examples of the substance exhibiting a high hole injectability include: aromatic amine compounds, which are low-molecule organic compounds, such as 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl (abbreviation: DPAB), 4,4′-bis(N-{4-[N′-(3-methylphenyl)-N′-phenylamino]phenyl}-N-phenylamino)biphenyl (abbreviation: DNTPD), 1,3,5-tris[N-(4-diphenylaminophenyl)-N-phenylamino]benzene (abbreviation: DPA3B), 3-[N-(9-phenylcarbazole-3-yl)-N-phenylamino]-9-phenylcarbazole (abbreviation: PCzPCA1), 3,6-bis[N-(9-phenylcarbazole-3-yl)-N-phenylamino]-9-phenylcarbazole (abbreviation: PCzPCA2), and 3-[N-(1-naphthyl)-N-(9-phenylcarbazole-3-yl)amino]-9-phenylcarbazole (abbreviation: PCzPCN1); and dipyrazino[2,3-f:20,30-h]quinoxaline-2,3,6,7,10,11-hexacarbonitrile (HAT-CN), which are low-molecule organic compounds.

In addition, a high polymer compound (e.g., oligomer, dendrimer and polymer) is usable as the substance exhibiting a high hole injectability. Examples of the high polymer compound include poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide](abbreviation: PTPDMA), and poly[N,N′-bis(4-butylphenyl)-N,N′-bis(phenyl)benzidine](abbreviation: Poly-TPD). Moreover, an acid-added high polymer compound such as poly(3,4-ethylenedioxythiophene)/poly(styrene sulfonic acid) (PEDOT/PSS) and polyaniline/poly(styrene sulfonic acid) (PAni/PSS) is also usable.

### Hole Transporting Layer

The hole transporting layer is a layer containing a substance exhibiting high hole transportability.

In the organic EL device according to the exemplary embodiment, the hole transporting layer is preferably disposed between the anode and the emitting region. In the organic EL device according to the exemplary embodiment, the hole transporting layer is more preferably disposed between the anode and the first emitting layer.

In the organic EL device according to the exemplary embodiment, the hole transporting layer preferably contains a third compound represented by a formula (H1) or a formula (H2) below.

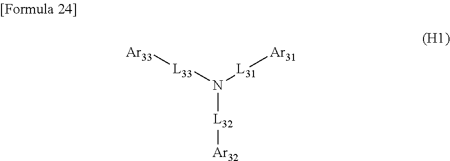

In the formula (H1):
L₃₁, L₃₂, and L₃₃ are each independently a single bond, or a substituted or unsubstituted arylene group having 6 to 18 ring carbon atoms;
Ar₃₁, Ar₃₂, and Ar₃₃ are each independently a substituted or unsubstituted aryl group having 6 to 30 ring carbon atoms, a substituted or unsubstituted heterocyclic group having 5 to 30 ring atoms, or a group represented by —Si(R_{C1})(R_{C2})(R_{C3});
R_{C1}, R_{C2}, and R_{C3} are each independently a substituted or unsubstituted aryl group having 6 to 30 ring carbon atoms;
when a plurality of R_{C1} are present, the plurality of R_{C1} are mutually the same or different;
when a plurality of R_{C2} are present, the plurality of R_{C2} are mutually the same or different; and
when a plurality of R_{C3} are present, the plurality of R_{C3} are mutually the same or different.

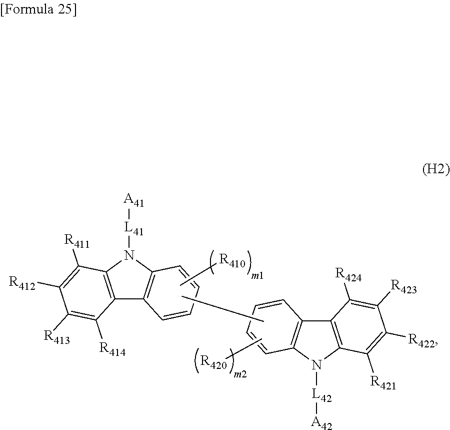

In the formula (H2):
A₄₁ and A₄₂ are each independently a substituted or unsubstituted aryl group having 6 to 30 ring carbon atoms or a substituted or unsubstituted heterocyclic group having 5 to 30 ring atoms;
at least one combination of adjacent two or more of R₄₁₀ to R₄₁₄ are mutually bonded to form a substituted or unsubstituted monocyclic ring, mutually bonded to form a substituted or unsubstituted fused ring, or not mutually bonded;
at least one combination of adjacent two or more of R₄₂₀ to R₄₂₄ are mutually bonded to form a substituted or unsubstituted monocyclic ring, mutually bonded to form a substituted or unsubstituted fused ring, or not mutually bonded;
R₄₁₀ to R₄₁₄ and R₄₂₀ to R₄₂₄ forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a halogen atom, a nitro group, a substituted or unsubstituted aryl group having 6 to 50 ring carbon atoms, or a substituted or unsubstituted heterocyclic group having 5 to 50 ring atoms;
m1 is three, and three R₄₁₀ are mutually the same or different;
m2 is three, and three R₄₂₀ are mutually the same or different; and
L₄₁ and L₄₂ are each independently a single bond, a substituted or unsubstituted arylene group having 6 to 30 ring carbon atoms, or a substituted or unsubstituted divalent heterocyclic group having 5 to 30 ring atoms.
R₉₀₁, R₉₀₂, R₉₀₃ and R₉₀₄ in the third compound represented by the formula (H2) are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different; and
when a plurality of R₉₀₄ are present, the plurality of R₉₀₄ are mutually the same or different.

In the organic EL device according to the exemplary embodiment, at least one of Ar₃₁, Ar₃₂ or Ar₃₃ of the third compound is also preferably a group represented by a formula (H1A) below.

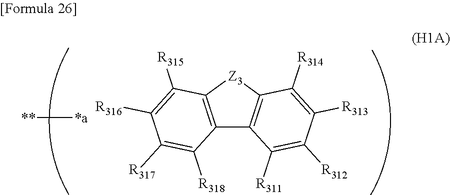

In the formula (H1A):
X₃ is an oxygen atom, a sulfur atom, NR₃₁₉, or C(R₃₂₀)(R₃₂₁);
a combination of adjacent two or more of R₃₁₁ to R₃₁₈ are mutually bonded to form a substituted or unsubstituted monocyclic ring, mutually bonded to form a substituted or unsubstituted fused ring, or not mutually bonded;
a combination of R₃₂₀ and R₃₂₁ are mutually bonded to form a substituted or unsubstituted monocyclic ring, mutually bonded to form a substituted or unsubstituted fused ring, or not mutually bonded;
one of R₃₁₁ to R₃₂₁ is a single bond bonded to *a, a carbon atom forming a cyclic skeleton of the substituted or unsubstituted monocyclic ring or the substituted or unsubstituted fused ring formed by mutual bonding of a combination of adjacent two or more of R₃₁₁ to R₃₁₈ is bonded to *a with a single bond, or a carbon atom forming a cyclic skeleton of the substituted or unsubstituted monocyclic ring or the substituted or unsubstituted fused ring formed by mutual bonding of a combination of R₃₂₀ and R₃₂₁ is bonded to *a with a single bond;
R₃₁₁ to R₃₁₈ forming neither the substituted or unsubstituted monocyclic ring nor the substituted or unsubstituted fused ring and not being the single bond bonded to *a are each independently a hydrogen atom, a substituted or unsubstituted alkyl group having 1 to 6 carbon atoms, a substituted or unsubstituted aryl group having 6 to 12 ring carbon atoms, or a substituted or unsubstituted heterocyclic group having 5 to 10 ring atoms;
R₃₁₉ not being the single bond bonded to *a is a hydrogen atom, a substituted or unsubstituted alkyl group having 1 to 6 carbon atoms, or a substituted or unsubstituted aryl group having 6 to 12 ring carbon atoms;
R₃₂₀ and R₃₂₁ not being the single bond bonded to *a, and forming neither the substituted or unsubstituted monocyclic ring nor the substituted or unsubstituted fused ring are each independently a hydrogen atom, a substituted or unsubstituted alkyl group having 1 to 6 carbon atoms, or a substituted or unsubstituted aryl group having 6 to 12 ring carbon atoms; and
each ** is independently a bonding position to L₃₁, L₃₂ or L₃₃, or a bonding position to a nitrogen atom of an amino group.

In at least one group represented by the formula (H1A) in the third compound, it is also preferable that at least one combination of two or more of R₃₁₁ to R₃₁₈ are mutually bonded to form a substituted or unsubstituted monocyclic ring or a substituted or unsubstituted fused ring.

In at least one group represented by the formula (H1A) in the third compound, it is also preferable that at least one combination of adjacent two or more of R₃₁₁ to R₃₁₈ are mutually bonded to form a substituted or unsubstituted benzene ring.

In at least one group represented by the formula (H1A) in the third compound, it is also preferable that one or two combinations of adjacent two or more of R₃₁₁ to R₃₁₈ are mutually bonded to form one or two substituted or unsubstituted benzene rings.

In at least one group represented by the formula (H1A) in the third compound, it is also preferable that none of combinations of adjacent two or more of R₃₁₁ to R₃₁₈ are mutually bonded.

In the organic EL device according to the exemplary embodiment, the third compound is also preferably at least one amine compound selected from the group consisting of a monoamine compound having one substituted or unsubstituted amino group in a molecule, a diamine compound having two substituted or unsubstituted amino groups in a molecule, a triamine compound having three substituted or unsubstituted amino groups in a molecule, and a tetraaminea compound having four substituted or unsubstituted amino groups in a molecule.

In the organic EL device according to the exemplary embodiment, the third compound is also preferably at least one amine compound selected from the group consisting of a monoamine compound and a diamine compound.

In the organic EL device according to the exemplary embodiment, the third compound is also preferably a monoamine compound.

In the organic EL device according to the exemplary embodiment, an aromatic amine compound, a carbazole derivative, an anthracene derivative and the like are usable for the hole transporting layer. Specific examples of a material for the hole transporting layer include an aromatic amine compound such as 4,4′-bis[N-(1-naphthyl)-N-phenylamino]biphenyl (abbreviation: NPB), N,N′-bis(3-methylphenyl)-N,N′-diphenyl-[1,1′-biphenyl]-4,4′-diamine (abbreviation: TPD), 4-phenyl-4′-(9-phenylfluorene-9-yl)triphenylamine (abbreviation: BAFLP), 4,4′-bis[N-(9,9-dimethylfluorene-2-yl)-N-phenylamino]biphenyl (abbreviation: DFLDPBi), 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), and 4,4′-bis[N-(spiro-9,9′-bifluorene-2-yl)-N-phenylamino]biphenyl (abbreviation: BSPB). The above-described substances mostly have a hole mobility of 10⁻⁶ cm²/(V·s) or more.

For the hole transporting layer, a carbazole derivative such as CBP, 9-[4-(N-carbazolyl)]phenyl-10-phenylanthracene (CzPA) and 9-phenyl-3-[4-(10-phenyl-9-anthryl)phenyl]-9H-carbazole (PCzPA), and an anthracene derivative such as t-BuDNA, DNA, and DPAnth may be used. A high polymer compound such as poly(N-vinylcarbazole) (abbreviation: PVK) and poly(4-vinyltriphenylamine) (abbreviation: PVTPA) is also usable.

However, in addition to the above substances, any substance exhibiting higher hole transportability than an electron transportability may be used. It should be noted that the layer containing the substance exhibiting high hole transportability may be not only a single layer but also a laminate of two or more layers formed of the above substance(s).

### Electron Blocking Layer

Preferably, the electron blocking layer permits transport of holes and blocks electrons from reaching a layer provided closer to the anode (e.g., the hole transporting layer) beyond the electron blocking layer. Examples of the compound contained in the electron blocking layer include a well-known compound used for the electron blocking layer, which is preferably at least one compound selected from the group consisting of an aromatic amine compound and a carbazole derivative. The compound contained in the electron blocking layer may be a monoamine compound having one substituted or unsubstituted amino group in a molecule. Further, the compound contained in the electron blocking layer may be a compound having, in a molecule, a substituted or unsubstituted carbazolyl group and one substituted or unsubstituted amino group.

In order to prevent excitation energy from leaking out from the emitting layer toward neighboring layer(s), the electron blocking layer may block excitons generated in the emitting layer from being transferred to a layer(s) closer to the anode (e.g., the hole transporting layer and the hole injecting layer) beyond the electron blocking layer.

### Hole Blocking Layer

Preferably, the hole blocking layer permits transport of electrons and blocks holes from reaching a layer provided closer to the cathode (e.g., the electron transporting layer) beyond the hole blocking layer. Examples of the compound contained in the hole blocking layer include a well-known compound used for the hole blocking layer. The compound contained in the hole blocking layer, which is similar to a compound usable for the later-described electron transporting layer, is preferably, for instance, at least one compound selected from the group consisting of a metal complex, a hetero aromatic compound, and a high polymer compound. The compound contained in the hole blocking layer may be, for instance, at least one compound selected from the group consisting of an imidazole derivative, benzimidazole derivative, azine derivative, carbazole derivative, and phenanthroline derivative.

In order to prevent excitation energy from leaking out from the emitting layer toward neighboring layer(s), the hole blocking layer preferably block excitons generated in the emitting layer from being transferred to a layer(s) closer to the cathode (e.g., the electron transporting layer and the electron injecting layer) beyond the hole blocking layer.

### Electron Transporting Layer

The electron transporting layer is a layer containing a substance exhibiting high electron transportability.

In the organic EL device according to the exemplary embodiment, the electron transporting layer is preferably disposed between an emitting zone and the cathode. In the organic EL device according to the exemplary embodiment, the electron transporting layer is more preferably disposed between the second emitting layer and the cathode.

In the organic EL device according to the exemplary embodiment, the electron transporting layer preferably contains a fourth compound represented by a formula (E1) below.

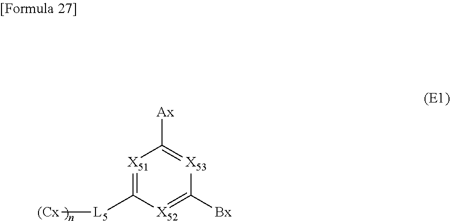

In the formula (E1):
X₅₁, X₅₂ and X₅₃ are each independently a nitrogen atom or CR₅;
at least one of X₅₁, X₅₂ or X₅₃ is a nitrogen atom;
R₅ is a hydrogen atom, a cyano group, a substituted or unsubstituted alkyl group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms;
Ax is a substituted or unsubstituted aryl group having 6 to 18 ring carbon atoms, or a substituted or unsubstituted heterocyclic group having 5 to 13 ring atoms;
Bx is a substituted or unsubstituted aryl group having 6 to 18 ring carbon atoms, or a substituted or unsubstituted heterocyclic group having 5 to 13 ring atoms;
L₅ is a single bond, a substituted or unsubstituted (n+1)-valent aromatic hydrocarbon ring group having 6 to 18 ring carbon atoms, or a substituted or unsubstituted (n+1)-valent heterocyclic group having 5 to 13 ring atoms;
n is 1, 2 or 3, and when n is 2 or 3, L₅ is not a single bond;
each Cx is independently a substituted or unsubstituted aryl group having 6 to 30 ring carbon atoms, or a substituted or unsubstituted heterocyclic group having 5 to 60 ring atoms; and
when a plurality of Cx are present, the plurality of Cx are mutually the same or different.

In the fourth compound, R₉₀₁, R₉₀₂, R₉₀₃, and R₉₀₄ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different; and
when a plurality of R₉₀₄ are present, the plurality of R₉₀₄ are mutually the same or different.

In the organic EL device according to the exemplary embodiment, two or three of X₅₁, X₅₂ and X₅₃ of the fourth compound are each preferably a nitrogen atom.

In the organic EL device according to the exemplary embodiment, the fourth compound is preferably a compound represented by a formula (E11), (E12), (E13) or (E14) below.

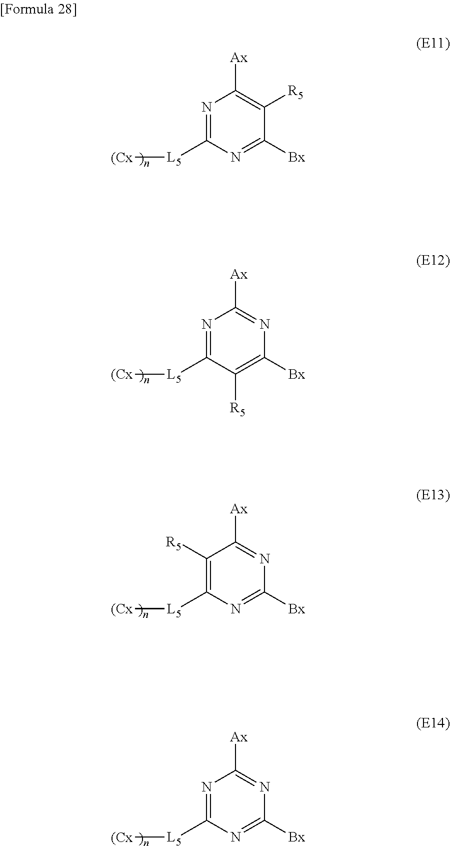

In the formulae (E11) to (E14), Ax, Bx, Cx, R₅, L₅, and n are each as defined in the formula (E1).

In the organic EL device according to the exemplary embodiment, for the electron transporting layer, 1) a metal complex such as an aluminum complex, beryllium complex, and zinc complex, 2) a hetero aromatic compound such as imidazole derivative, benzimidazole derivative, azine derivative, carbazole derivative, and phenanthroline derivative, and 3) a high polymer compound are usable. Specifically, as a low-molecule organic compound, a metal complex such as Alq, tris(4-methyl-8-quinolinolato)aluminum (abbreviation: Almq₃), bis(10-hydroxybenzo[h]quinolinato)beryllium (abbreviation: BeBq₂), BAlq, Znq, ZnPBO and ZnBTZ is usable. In addition to the metal complex, a heteroaromatic compound such as 2-(4-biphenylyl)-5-(4-tert-butylphenyl)-1,3,4-oxadiazole (abbreviation: PBD), 1,3-bis[5-(ptert-butylphenyl)-1,3,4-oxadiazole-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), and 4,4′-bis(5-methylbenzoxazole-2-yl)stilbene (abbreviation: BzOs) is usable. In the exemplary embodiment, a benzimidazole compound is suitably usable. The above-described substances mostly have an electron mobility of 10⁻⁶ cm²/V·s or more. It should be noted that any other substance than the above substances may be used for the electron transporting layer as long as the substance exhibits higher electron transportability than the hole transportability. The electron transporting layer may be a single layer or a laminate of two or more layers formed of the above substance(s).

Further, a high polymer compound is usable for the electron transporting layer. For instance, poly[(9,9-dihexylfluorene-2,7-diyl)-co-(pyridine-3,5-diyl)](abbreviation: PF-Py), and poly[(9,9-dioctylfluorene-2,7-diyl)-co-(2,2′-bipyridine-6,6′-diyl)](abbreviation: PF-BPy) are usable.

### Electron Injecting Layer

The electron injecting layer is a layer that contains a substance exhibiting high electron injectability.

In the organic EL device according to the exemplary embodiment, examples of a material for the electron injecting layer include an alkali metal, alkaline earth metal and a compound thereof, examples of which include lithium (Li), cesium (Cs), calcium (Ca), lithium fluoride (LiF), cesium fluoride (CsF), calcium fluoride (CaF2), and lithium oxide (LiOx). In addition, the alkali metal, alkaline earth metal or the compound thereof may be added to the substance exhibiting electron transportability in use. Specifically, for instance, magnesium (Mg) added to Alq may be used. In this case, the electrons can be more efficiently injected from the cathode.

Alternatively, the electron injecting layer may be provided by a composite material in a form of a mixture of an organic compound and an electron donor. Such a composite material exhibits excellent electron injectability and electron transportability since electrons are generated in the organic compound by the electron donor. In this case, the organic compound is preferably a material excellent in transporting the generated electrons. Specifically, the above examples (e.g., the metal complex and the hetero aromatic compound) of the substance forming the electron transporting layer are usable. As the electron donor, any substance exhibiting electron donating property to the organic compound is usable. Specifically, the electron donor is preferably alkali metal, alkaline earth metal and rare earth metal such as lithium, cesium, magnesium, calcium, erbium and ytterbium. The electron donor is also preferably alkali metal oxide and alkaline earth metal oxide such as lithium oxide, calcium oxide, and barium oxide. Further, a Lewis base such as magnesium oxide is usable. Furthermore, the organic compound such as tetrathiafulvalene (abbreviation: TTF) is usable.

### Layer Formation Method

A method of forming each layer of the organic EL device in the exemplary embodiment is subject to no limitation except for the above particular description. Known methods of dry film-forming such as vacuum deposition, sputtering, plasma or ion plating and wet film-forming such as spin coating, dipping, flow coating or inkjet are applicable.

### Film Thickness

The film thickness of each organic layer of the organic EL device in the exemplary embodiment is not limited unless otherwise specified in the above. In general, the thickness preferably ranges from several nanometers to 1 μm because an excessively small film thickness is likely to cause defects (e.g. pin holes) and an excessively large thickness leads to the necessity of applying high voltage and consequent reduction in efficiency.

### Emission Wavelength of Organic EL Device

The organic electroluminescence device according to the exemplary embodiment preferably emits, when being driven, light having a maximum peak wavelength of 500 nm or less.

The organic electroluminescence device according to the exemplary embodiment more preferably emits, when being driven, light having a maximum peak wavelength in a range from 430 nm to 480 nm.

The maximum peak wavelength of the light emitted from the organic EL device when being driven is measured as follows. Voltage is applied on the organic EL device such that a current density becomes 10 mA/cm², where spectral radiance spectrum is measured by a spectroradiometer CS-2000 (manufactured by Konica Minolta, Inc.). A peak wavelength of an emission spectrum, at which the luminous intensity of the resultant spectral radiance is at the maximum, is measured and defined as a maximum peak wavelength (unit: nm).

### First Host Material

In the organic EL device according to the exemplary embodiment, the first host material is not particularly limited. Examples of the first host material include a compound represented by a formula (H11) below, a compound represented by a formula (H12) below, a compound represented by a formula (H13) below, a compound represented by a formula (H14) below, a compound represented by a formula (H15) below, and a compound represented by a formula (H16) below.

### First Compound

In an exemplary arrangement of the organic EL device according to the exemplary embodiment, the first host material is preferably the first compound. The first compound is preferably one compound selected from the group consisting of the compound represented by the formula (H11) below, the compound represented by the formula (H12) below, the compound represented by the formula (H13) below, the compound represented by the formula (H14) below, the compound represented by the formula (H15) below, and the compound represented by the formula (H16) below.

### Compound Represented by Formula (H11)

The compound represented by the formula (H11) will be described.

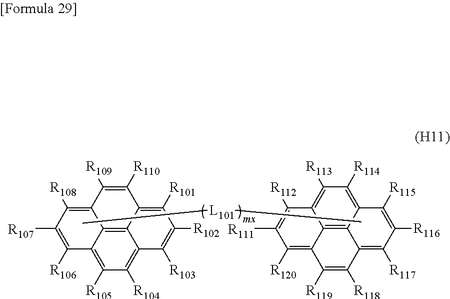

In the formula (H11):
R₁₀₁ to R₁₁₀ and R₁₁₁ to R₁₂₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
one of R₁₀₁ to R₁₁₀ represents a bonding position to L₁₀₁, and one of R₁₁₁ to R₁₂₀ represents a bonding position to L₁₀₁;
L₁₀₁ is a single bond, a substituted or unsubstituted arylene group having 6 to 24 ring carbon atoms, or a substituted or unsubstituted divalent heterocyclic group having 5 to 24 ring atoms;
mx is 0, 1, 2, 3, 4 or 5; and
when two or more L₁₀₁ are present, the two or more L₁₀₁ are mutually the same or different.

In the first compound, R₉₀₁, R₉₀₂, R₉₀₃, R₉₀₄, R₉₀₅, R₉₀₆, R₉₀₇, R₈₀₁ and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

In an exemplary arrangement of the organic EL device according to the exemplary embodiment, the group represented by the formula (H11) is a group represented by a formula (H111) below.

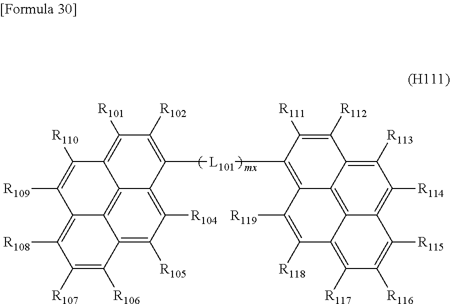

In the formula (H111):
R₁₀₁, R₁₀₂, R₁₀₄ to R₁₁₀, and R₁₁₁ to R₁₁₉ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms; and
L₁₀₁ and mx respectively represent the same as L₁₀₁ and mx in the formula (H11).

In an exemplary arrangement of the organic EL device according to the exemplary embodiment, mx is 1 or 2.

In an exemplary arrangement of the organic EL device according to the exemplary embodiment, L₁₀₁ is a substituted or unsubstituted arylene group having 6 to 24 ring carbon atoms.

In an exemplary arrangement of the organic EL device according to the exemplary embodiment, the first compound is a compound containing only two pyrene rings in a molecule (occasionally referred to as a bispyrene compound).

In an exemplary arrangement of the organic EL device according to the exemplary embodiment, the compound represented by the formula (H11) is the bispyrene compound.

### Compound Represented by Formula (H12)

The compound represented by the formula (H12) will be described.

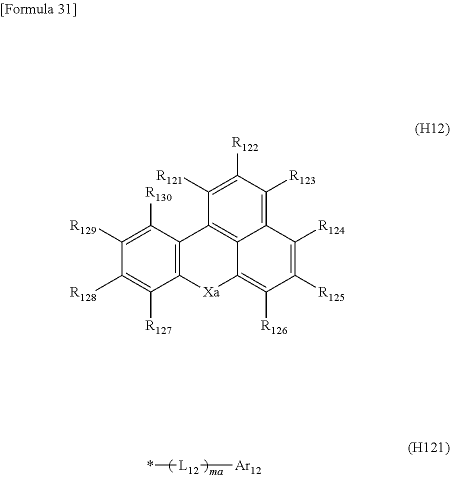

In the formula (H12):
Xa is an oxygen atom, a sulfur atom, C(R₁₂₀₁)(R₁₂₀₂), or Si(R₁₂₀₃)(R₁₂₀₄);
R₁₂₀₁ to R₁₂₀₄ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
at least one combination of adjacent two or more of R₁₂₁ to R₁₃₀ are mutually bonded to form a substituted or unsubstituted monocyclic ring, mutually bonded to form a substituted or unsubstituted fused ring, or not mutually bonded;
R₁₂₁ to R₁₃₀ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a nitro group, a substituted or unsubstituted aryl group having 6 to 50 ring carbon atoms, a substituted or unsubstituted heterocyclic group having 5 to 50 ring atoms, or a group represented by the formula (H121);
at least one of R₁₂₁ to R₁₃₀ is a group represented by the formula (H121);
when a plurality of groups represented by the formula (H121) are present, the plurality of groups represented by the formula (H121) are mutually the same or different;
L₁₂ is a single bond, a substituted or unsubstituted arylene group having 6 to 50 ring carbon atoms, or a substituted or unsubstituted divalent heterocyclic group having 5 to 50 ring atoms;
ma is 0, 1, 2 or 3;
when two or more L₁₂ are present, the two or more L₁₂ are mutually the same or different;
Ar₁₂ is a substituted or unsubstituted aryl group having 6 to 50 ring carbon atoms, or a substituted or unsubstituted heterocyclic group having 5 to 50 ring atoms;
when two or more Ar₁₂ are present, the two or more Ar₁₂ are mutually the same or different; and
* in the formula (H121) represents a bonding position.

In an exemplary arrangement of the organic EL device in the exemplary embodiment, L₁₂ is a single bond, a substituted or unsubstituted arylene group having 6 to 15 ring carbon atoms, or a substituted or unsubstituted divalent heterocyclic group having 5 to 15 ring atoms.

In an exemplary arrangement of the organic EL device according to the exemplary embodiment, Ar₁₂ is a substituted or unsubstituted aryl group including four or more rings, or a substituted or unsubstituted heterocyclic group including four or more rings.

In an exemplary arrangement of the organic EL device according to the exemplary embodiment, Ar₁₂ is a substituted or unsubstituted aryl group including four or more rings.

In an exemplary arrangement of the organic EL device according to the exemplary embodiment, R₁₂₉ is a group represented by the formula (H121).

In an exemplary arrangement of the organic EL device according to the exemplary embodiment, Xa is an oxygen atom.

In an exemplary arrangement of the organic EL device according to the exemplary embodiment, the compound represented by the formula (H12) is a compound represented by a formula (H122) below.

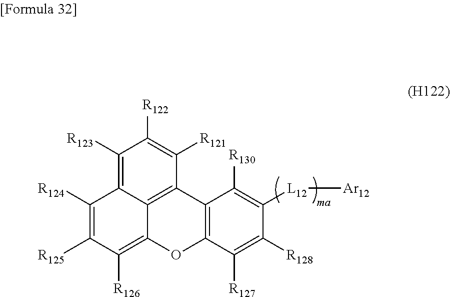

In the formula (H122):
R₁₂₁ to R₁₂₈ and R₁₃₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a nitro group, a substituted or unsubstituted aryl group having 6 to 50 ring carbon atoms, or a substituted or unsubstituted heterocyclic group having 5 to 50 ring atoms, and
Ar₁₂, L₁₂, and ma respectively represent the same as Ar₁₂, L₁₂, and ma in the formula (H121).

In an exemplary arrangement of the organic EL device according to the exemplary embodiment, ma is 1 or 2.

### Compound Represented by Formula (H13)

The compound represented by the formula (H13) will be described.

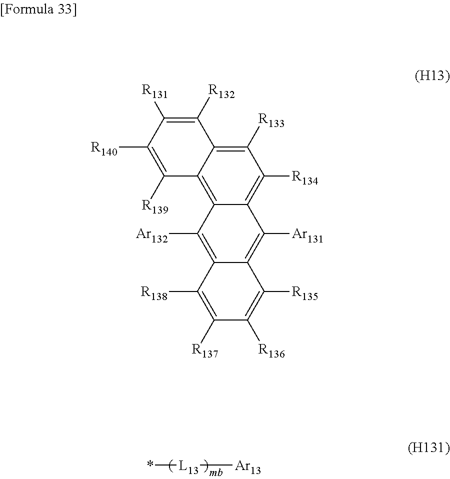

In the formula (H13):
R₁₃₁ to R₁₄₀, Ar₁₃₁, and Ar₁₃₂ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (H131);
at least one of R₁₃₁ to R₁₄₀, Ar₁₃₁, or Ar₁₃₂ is a group represented by the formula (H131);
when a plurality of groups represented by the formula (H131) are present, the plurality of groups represented by the formula (H131) are mutually the same or different;
L₁₃ is a single bond, a substituted or unsubstituted arylene group having 6 to 50 ring carbon atoms, or a substituted or unsubstituted divalent heterocyclic group having 5 to 50 ring atoms;
Ar₁₃ is a substituted or unsubstituted aryl group having 6 to 50 ring carbon atoms, or a substituted or unsubstituted heterocyclic group having 5 to 50 ring atoms;
mb is 0,1, 2, 3, 4 or 5;
when two or more L₁₃ are present, the two or more L₁₃ are mutually the same or different;
when two or more Ar₁₃ are present, the two or more Ar₁₃ are mutually the same or different; and
* in the formula (H131) represents a bonding position to a benz[a]anthracene ring in the formula (H13).

In an exemplary arrangement of the organic EL device according to the exemplary embodiment, at least one of Ar₁₃₁ or Ar₁₃₂ is a group represented by the formula (H131).

In an exemplary arrangement of the organic EL device according to the exemplary embodiment, the compound represented by the formula (H13) is a compound represented by a formula (H132) or (H133) below.

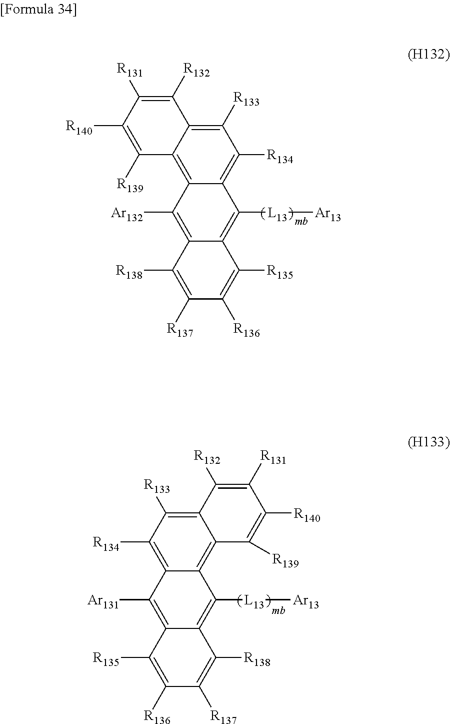

In the formulae (H132) and (H133):
R₁₃₁ to R₁₄₀, Ar₁₃₁, and Ar₁₃₂ are each a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms; and
L₁₃, Ar₁₃ and mb respectively represent the same as L₁₃, Ar₁₃ and mb in the formula (H131).

In an exemplary arrangement of the organic EL device according to the exemplary embodiment, mb is 0, 1 or 2.

### Compound Represented by Formula (H14)

The compound represented by the formula (H14) will be described.

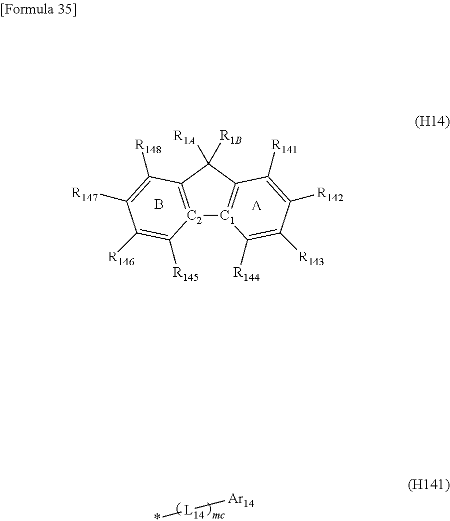

In the formula (H14):
R_{1A} and R_{1B} are each independently a substituted or unsubstituted alkyl group having 1 to 15 carbon atoms, a substituted or unsubstituted aryl group having 6 to 17 ring carbon atoms, or a substituted or unsubstituted heterocyclic group having 5 to 17 ring atoms;
at least one of R_{1A} or R_{1B} is a substituted or unsubstituted alkyl group having 1 to 15 carbon atoms;
one combination of a combination of adjacent two or more of R₁₄₁ to R₁₄₄ and a combination of adjacent two or more of R₁₄₅ to R₁₄₈ are mutually bonded to form a substituted or unsubstituted monocyclic ring, or mutually bonded to form a substituted or unsubstituted fused ring;
when the substituted or unsubstituted monocyclic ring or the substituted or unsubstituted fused ring is formed with a ring A, a group represented by a formula (H141) above is bonded to a carbon atom bonded to R₁₄₂ or a carbon atom, among carbon atoms forming the substituted or unsubstituted monocyclic ring or the substituted or unsubstituted fused ring, at a position farthest from a carbon atom C₁ of the ring A, the carbon atom C₁ being bonded by a single bond to a carbon atom C₂ of a ring B;
when the substituted or unsubstituted monocyclic ring or the substituted or unsubstituted fused ring is formed not with the ring A but with the ring B, the group represented by the formula (H141) is bonded to the carbon atom bonded to R₁₄₂; and
R₁₄₂ not being the group represented by the formula (H141), and R₁₄₁, R₁₄₃, R₁₄₄ and R₁₄₅ to R₁₄₈ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 17 ring carbon atoms, or a substituted or unsubstituted heterocyclic group having 5 to 17 ring atoms;
in the formula (H141):
Ar₁₄ is a substituted or unsubstituted aryl group including four or more fused rings, or a substituted or unsubstituted heterocyclic group including four or more fused rings;
L₁₄ is a single bond, a substituted or unsubstituted arylene group having 6 to 17 ring carbon atoms, or a substituted or unsubstituted divalent heterocyclic group having 5 to 17 ring atoms;
mc is 0, 1 or 2;
* represents a bonding position to an atom forming a ring of the formula (H14); and
the compound represented by the formula (H14) does not include, in a molecule of the compound represented by the formula (H14), three or more of: a substituted or unsubstituted aryl group including four or more fused rings, and a substituted or unsubstituted heterocyclic group including four or more fused rings.

In an exemplary arrangement of the organic EL device according to the exemplary embodiment, R₁₄₂ is the group represented by the formula (H141).

In the compound represented by the formula (H14) in an exemplary arrangement of the organic EL device of the exemplary embodiment, R₉₀₁, R₉₀₂, R₉₀₃, R₉₀₄, R₉₀₅, R₉₀₆, R₉₀₇, R₈₀₁ and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 17 ring carbon atoms, or a substituted or unsubstituted heterocyclic group having 5 to 17 ring atoms.

In an exemplary arrangement of the organic EL device according to the exemplary embodiment, the compound represented by the formula (H14) is a compound represented by a formula (H142), (H143) or (H144) below.

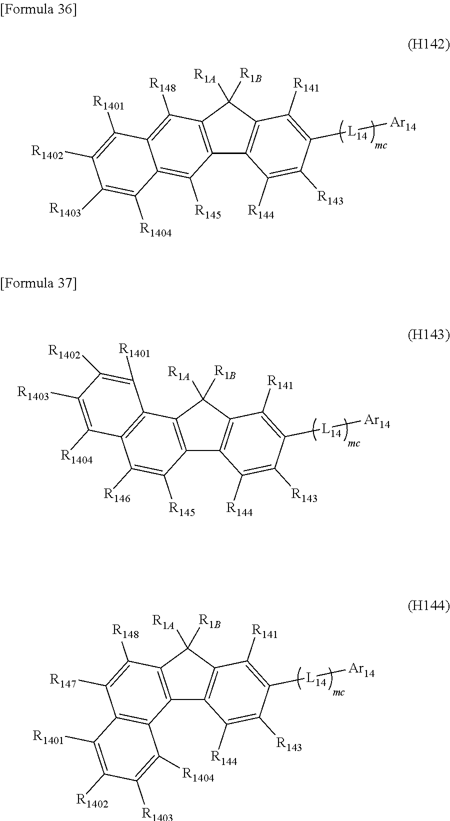

In the formula (H142), (H143) or (H144):
R_{1A}, R_{1B}, R₁₄₁, R₁₄₃, R₁₄₄, R₁₄₅, R₁₄₆, R₁₄₇, and R₁₄₈ respectively represent the same as R_{1A}, R_{1B}, R₁₄₁, R₁₄₃, R₁₄₄, R₁₄₅, R₁₄₆, R₁₄₇, and R₁₄₈ in the formula (H14);
Ar₁₄, L₁₄, and mc respectively represent the same as Ar₁₄, L₁₄, and mc in the formula (H141);
none of a combination(s) of adjacent two or more of R₁₄₀₁ to R₁₄₀₄ are mutually bonded; and
R₁₄₀₁ to R₁₄₀₄ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 17 ring carbon atoms, or a substituted or unsubstituted heterocyclic group having 5 to 17 ring atoms.

In an exemplary arrangement of the organic EL device according to the exemplary embodiment, mc is 0, 1 or 2.

### Compound Represented by Formula (H15)

The compound represented by the formula (H15) will be described.

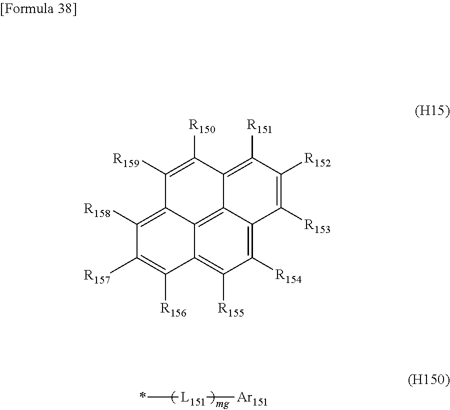

In the formula (H15):
R₁₅₀ to R₁₅₉ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by a formula (H150) above;
at least one of R₁₅₀ to R₁₅₉ is a group represented by the formula (H150);
when a plurality of groups represented by the formula (H150) are present, the plurality of groups represented by the formula (H150) are mutually the same or different;
L₁₅₁ is a single bond, a substituted or unsubstituted arylene group having 6 to 50 ring carbon atoms, or a substituted or unsubstituted divalent heterocyclic group having 5 to 50 ring atoms;
Ar₁₅₁ is a substituted or unsubstituted aryl group having 6 to 50 ring carbon atoms, or a substituted or unsubstituted heterocyclic group having 5 to 50 ring atoms;
mg is 0, 1, 2, 3, 4 or 5;
when two or more L₁₅₁ are present, the two or more L₁₅₁ are mutually the same or different;
when two or more Ar₁₅₁ are present, the two or more Ar₁₅₁ are mutually the same or different; and
* in the formula (H150) represents a bonding position to a pyrene ring in the formula (H15).

In an exemplary arrangement of the organic EL device of the exemplary embodiment, R₁₅₃ of the compound represented by the formula (H15) is the group represented by the formula (H150).

In an exemplary arrangement of the organic EL device according to the exemplary embodiment, L₁₅₁ is a single bond or a substituted or unsubstituted arylene group having 6 to 50 ring carbon atoms; and Ar₁₅₁ is a substituted or unsubstituted aryl group having 6 to 50 ring carbon atoms.

In an exemplary arrangement of the organic EL device according to the exemplary embodiment, L₁₅₁ is a single bond, or a substituted or unsubstituted arylene group having 6 to 14 ring carbon atoms; and Ar₁₅₁ is a substituted or unsubstituted aryl group having 6 to 14 ring carbon atoms.

In an exemplary arrangement of the organic EL device according to the exemplary embodiment, the group represented by the formula (H150) is a group represented by a formula (H151) below.

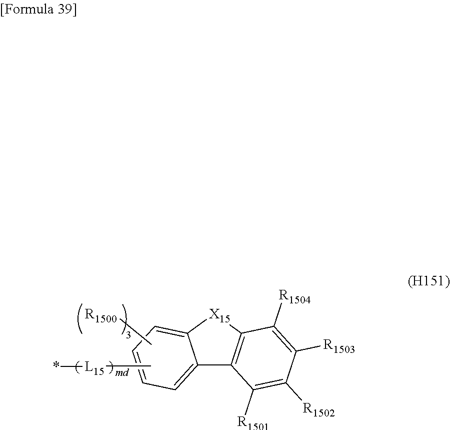

In the formula (H151):
X₁₅ is an oxygen atom or a sulfur atom;
L₁₅ is a single bond, a substituted or unsubstituted arylene group having 6 to 50 ring carbon atoms, or a substituted or unsubstituted divalent heterocyclic group having 5 to 50 ring atoms;
md is 0, 1, 2, 3, 4 or 5;
when two or more L₁₅ are present, the two or more L₁₅ are mutually the same or different;
at least one combination of adjacent two or more of R₁₅₀₀ to R₁₅₀₄ are mutually bonded to form a substituted or unsubstituted monocyclic ring, mutually bonded to form a substituted or unsubstituted fused ring, or not mutually bonded;
R₁₅₀₀ to R₁₅₀₄ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
a plurality of R₁₅₀₀ are mutually the same or different;
when a plurality of groups represented by the formula (H151) are present, the plurality of groups represented by the formula (H151) are mutually the same or different; and
* in the formula (H151) represents a bonding position to the pyrene ring in the formula (H15).

In an exemplary arrangement of the organic EL device according to the exemplary embodiment, the compound represented by the formula (H15) is a compound represented by a formula (H152) below. When R₁₅₃ of the compound represented by the formula (H15) is the group represented by the formula (H151), the compound is represented by a formula (H152) below.

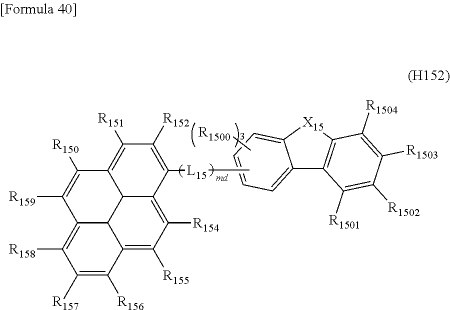

In the formula (H152):
R₁₅₀ to R₁₅₂ and R₁₅₄ to R₁₅₉ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
X₁₅, L₁₅, and md respectively represent the same as X₁₅, L₁₅, and md in the formula (H151); and
R₁₅₀₀ to R₁₅₀₄ each independently represent the same as R₁₅₀₀ to R₁₅₀₄ in the formula (H151).

In an exemplary arrangement of the organic EL device according to the exemplary embodiment, md is 0, 1 or 2.

In an exemplary arrangement of the organic EL device according to the exemplary embodiment, when md is 0, the compound represented by the formula (H152) is represented by a formula (H153) below.

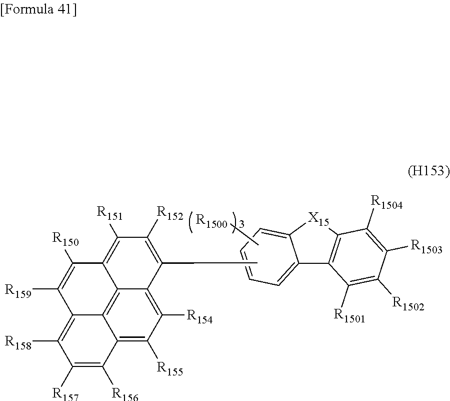

In the formula (H153):
R₁₅₀ to R₁₅₂, R₁₅₄ to R₁₅₉, R₁₅₀₀ to R₁₅₀₄, and X₁₅ respectively represent the same as R₁₅₀ to R₁₅₂, R₁₅₄ to R₁₅₉, R₁₅₀₀ to R₁₅₀₄, and X₁₅ in the formula (H152).

In an exemplary arrangement of the organic EL device according to the exemplary embodiment, the first compound is a compound containing only one pyrene ring in a molecule (occasionally referred to as a monopyrene compound).

In an exemplary arrangement of the organic EL device according to the exemplary embodiment, the compound represented by the formula (H15) is the monopyrene compound.

### Compound Represented by Formula (H16)

The compound represented by the formula (H16) will be described.

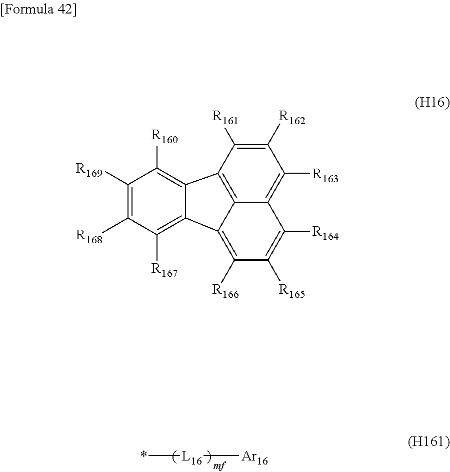

In the formula (H16):
at least one combination of adjacent two or more of R₁₆₀ to R₁₆₉ are mutually bonded to form a substituted or unsubstituted monocyclic ring, mutually bonded to form a substituted or unsubstituted fused ring, or not mutually bonded;
R₁₆₀ to R₁₆₉ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by a formula (H161) above;
at least one of a substituent, if present, for the substituted or unsubstituted monocyclic ring, a substituent, if present, for the substituted or unsubstituted fused ring, or R₁₆₀ to R₁₆₉ is the group represented by the formula (H161);
when a plurality of groups represented by the formula (H161) are present, the plurality of groups represented by the formula (H161) are mutually the same or different;
L₁₆ is a single bond, a substituted or unsubstituted arylene group having 6 to 50 ring carbon atoms, or a substituted or unsubstituted divalent heterocyclic group having 5 to 50 ring atoms;
Ar₁₆ is a substituted or unsubstituted aryl group having 6 to 50 ring carbon atoms, or a substituted or unsubstituted heterocyclic group having 5 to 50 ring atoms;
mf is 0, 1, 2, 3, 4 or 5;
when two or more L₁₆ are present, the two or more L₁₆ are mutually the same or different;
when two or more Ar₁₆ are present, the two or more Ar₁₆ are mutually the same or different; and
* in the formula (H161) represents a bonding position to a ring represented by the formula (H16).

In an exemplary arrangement of the organic EL device according to the exemplary embodiment, the first compound is a compound represented by a formula (H162) below.

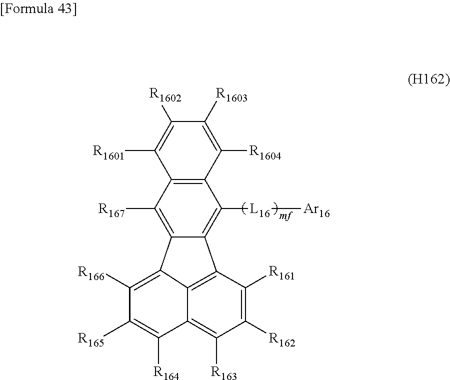

In the formula (H162):
R₁₆₁ to R₁₆₇ and R₁₆₀₁ to R₁₆₀₄ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms; and
Ar₁₆, L₁₆, and mf respectively represent the same as Ar₁₆, L₁₆, and mf in the formula (H16).

In an exemplary arrangement of the organic EL device according to the exemplary embodiment, mf is 0, 1 or 2.

In an exemplary arrangement of the organic EL device according to the exemplary embodiment, each first compound is preferably independently a compound selected from the group consisting of the compound represented by the formula (H111), the compound represented by the formula (H122), the compound represented by the formula (H132), and the compound represented by the formula (H133).

In an exemplary arrangement of the organic EL device according to the exemplary embodiment, the first compound preferably has no biscarbazole structure and no amine structure in a molecule.

In an exemplary arrangement of the organic EL device according to the exemplary embodiment, the first compound contains no compound having a biscarbazole structure and no compound having an amine structure.

In an exemplary arrangement of the organic EL device according to the exemplary embodiment, the groups specified to be “substituted or unsubstituted” in the first compound are each an “unsubstituted” group.

In the organic EL device according to the exemplary embodiment, also preferably, the first host material has, in a molecule, a linking structure including a benzene ring and a naphthalene ring that are linked with a single bond, in which the benzene ring and the naphthalene ring in the linking structure are each independently fused or not fused with a further monocyclic ring or fused ring, and the benzene ring and the naphthalene ring in the linking structure are further linked to each other by cross-linking at at least one site other than the single bond.

When the first host material has the linking structure including such cross-linking, deterioration in chromaticity of the organic EL device is expected to be inhibited.

The first host material in the above case is only required to have a linking structure as the minimum unit in a molecule, the linking structure including a benzene ring and a naphthalene ring linked to each other with a single bond (occasionally referred to as a benzene-naphthalene linking structure) and being as represented by a formula (X1) or a formula (X2) below. Further, the benzene ring may be fused with a further monocyclic ring or fused ring, and the naphthalene ring may be fused with a further monocyclic ring or fused ring. For instance, also in a case where the first host material has, in a molecule, a linking structure including a naphthalene ring and a naphthalene ring linked to each other with a single bond (occasionally referred to as a naphthalene-naphthalene linking structure) and being as represented by a formula (X3), a formula (X4), or a formula (X5) below, the naphthalene ring is regarded as including the benzene-naphthalene linking structure since one of the naphthalene rings includes a benzene ring.

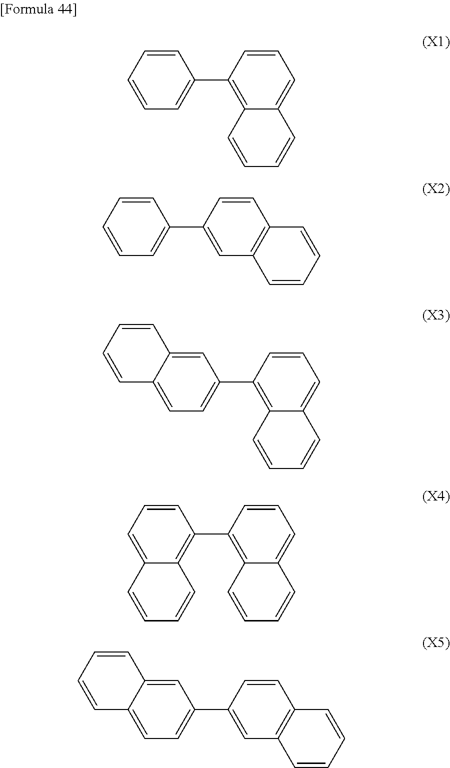

In the organic EL device according to the exemplary embodiment, the cross-linking also preferably includes a double bond. Specifically, the first host material also preferably has a structure in which the benzene ring and the naphthalene ring are further linked to each other at any other site than the single bond by the cross-linking structure including a double bond.

Assuming that the benzene ring and the naphthalene ring in the benzene-naphthalene linking structure are further linked to each other at at least one site other than the single bond by cross-linking, for instance, a linking structure (fused ring) represented by a formula (X11) below is obtained in a case of the formula (X1), and a linking structure (fused ring) represented by a formula (X31) below is obtained in a case of the formula (X3).

Assuming that the benzene ring and the naphthalene ring in the benzene-naphthalene linking structure are further linked to each other at any other site than the single bond by cross-linking including a double bond, for instance, a linking structure (fused ring) represented by a formula (X12) below is obtained in a case of the formula (X1), a linking structure (fused ring) represented by a formula (X21) or formula (X22) below is obtained in a case of the formula (X2), a linking structure (fused ring) represented by a formula (X41) below is obtained in a case of the formula (X4), and a linking structure (fused ring) represented by a formula (X51) below is obtained in a case of the formula (X5).

Assuming that the benzene ring and the naphthalene ring in the benzene-naphthalene linking structure are further linked to each other at at least one site other than the single bond by cross-linking including a hetero atom (e.g., an oxygen atom), for instance, a linking structure (fused ring) represented by a formula (X13) below is obtained in a case of the formula (X1).

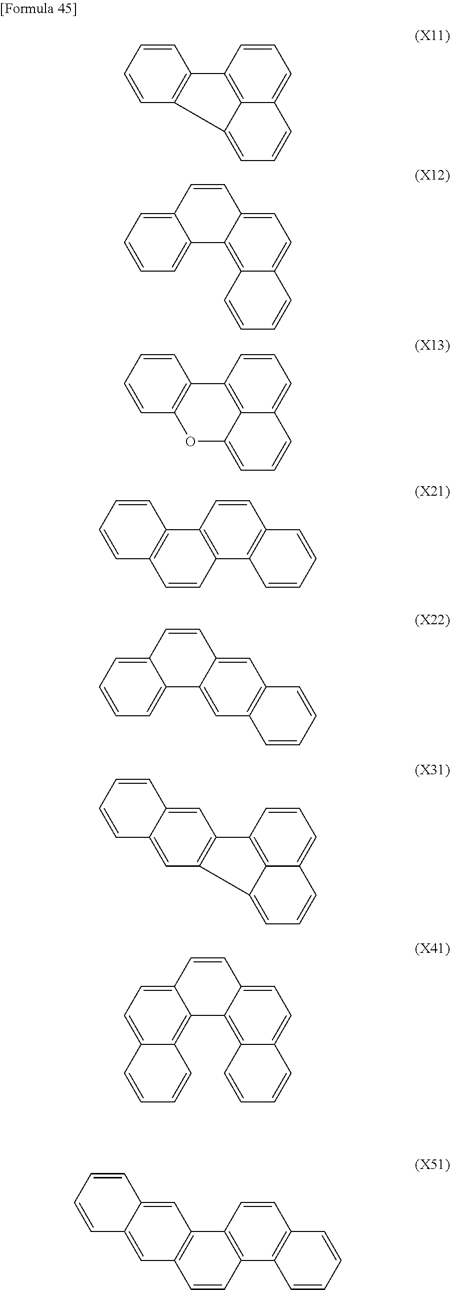

In the organic EL device according to the exemplary embodiment, also preferably, the first host material has, in a molecule, a biphenyl structure including a first benzene ring and a second benzene ring linked to each other with a single bond, and the first benzene ring and the second benzene ring in the biphenyl structure are further linked to each other by cross-linking at at least one site other than the single bond.

In the organic EL device according to the exemplary embodiment, also preferably, the first benzene ring and the second benzene ring in the biphenyl structure are further linked to each other by the cross-linking at one site other than the single bond. When the first host material has the biphenyl structure including such cross-linking, deterioration in chromaticity of the organic EL device is expected to be inhibited.

In the organic EL device according to the exemplary embodiment, the cross-linking also preferably includes a double bond.

In the organic EL device according to the above exemplary embodiment, the cross-linking also preferably includes no double bond.

Also preferably, the first benzene ring and the second benzene ring in the biphenyl structure are further linked to each other by the cross-linking at two sites other than the single bond.

In the organic EL device according to the exemplary embodiment, also preferably, the first benzene ring and the second benzene ring in the biphenyl structure are further linked to each other by the cross-linking at two sites other than the single bond, and the cross-linking includes no double bond. When the first host material has the biphenyl structure including such cross-linking, deterioration in chromaticity of the organic EL device is expected to be inhibited.

For instance, assuming that the first benzene ring and the second benzene ring in the biphenyl structure represented by a formula (BP1) below are further linked to each other by cross-linking at at least one site other than the single bond, the biphenyl structure is exemplified by linking structures (fused rings) represented by formulae (BP11) to (BP15) below.

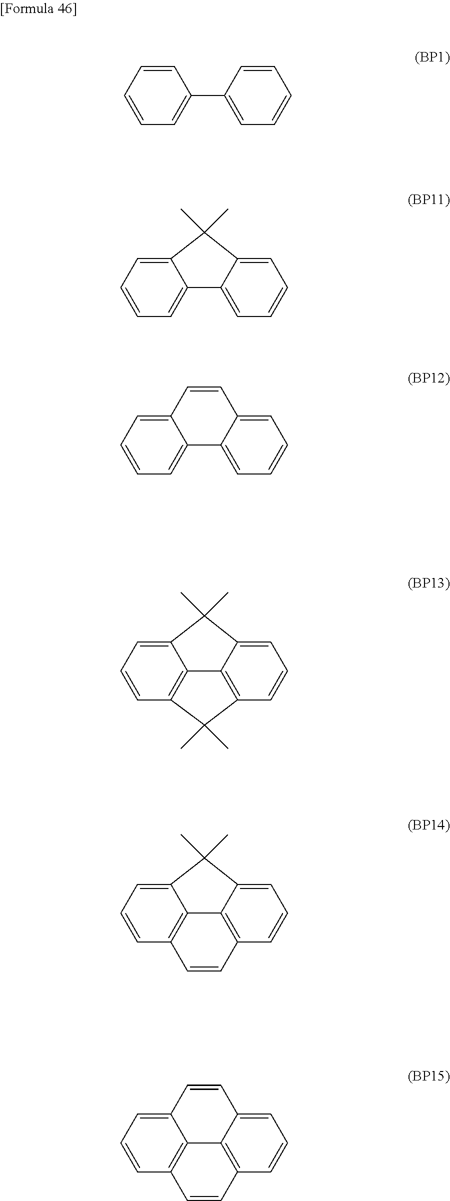

The formula (BP11) represents a linking structure in which the first benzene ring and the second benzene ring are linked to each other at one site other than the single bond by cross-linking including no double bond.

The formula (BP12) represents a linking structure in which the first benzene ring and the second benzene ring are linked to each other at one site other than the single bond by cross-linking including a double bond.

The formula (BP13) represents a linking structure in which the first benzene ring and the second benzene ring are linked to each other at two sites other than the single bond by cross-linking including no double bond.

The formula (BP14) represents a linking structure in which the first benzene ring and the second benzene ring are linked to each other by cross-linking including no double bond at one of two sites other than the single bond, and the first benzene ring and the second benzene ring are linked to each other by cross-linking including a double bond at the other of the two sites other than the single bond.

The formula (BP15) represents a linking structure in which the first benzene ring and the second benzene ring are linked to each other at two sites other than the single bond by cross-linking including a double bond.

In the first compound and the second compound, the groups specified to be “substituted or unsubstituted” are each preferably an unsubstituted group.

### Method of Producing First Compound

The first compound can be produced by a known method. The first compound can also be produced based on a known method through a known alternative reaction using a known material(s) tailored for the target compound.

### Specific Examples of First Compound

Specific examples of the first compound include the following compounds. It should however be noted that the invention is not limited to the specific examples of the first compound.

In the specific examples of the compound herein, D represents a deuterium atom, Me represents a methyl group, tBu represents a tert-butyl group, and Ph represents a phenyl group.

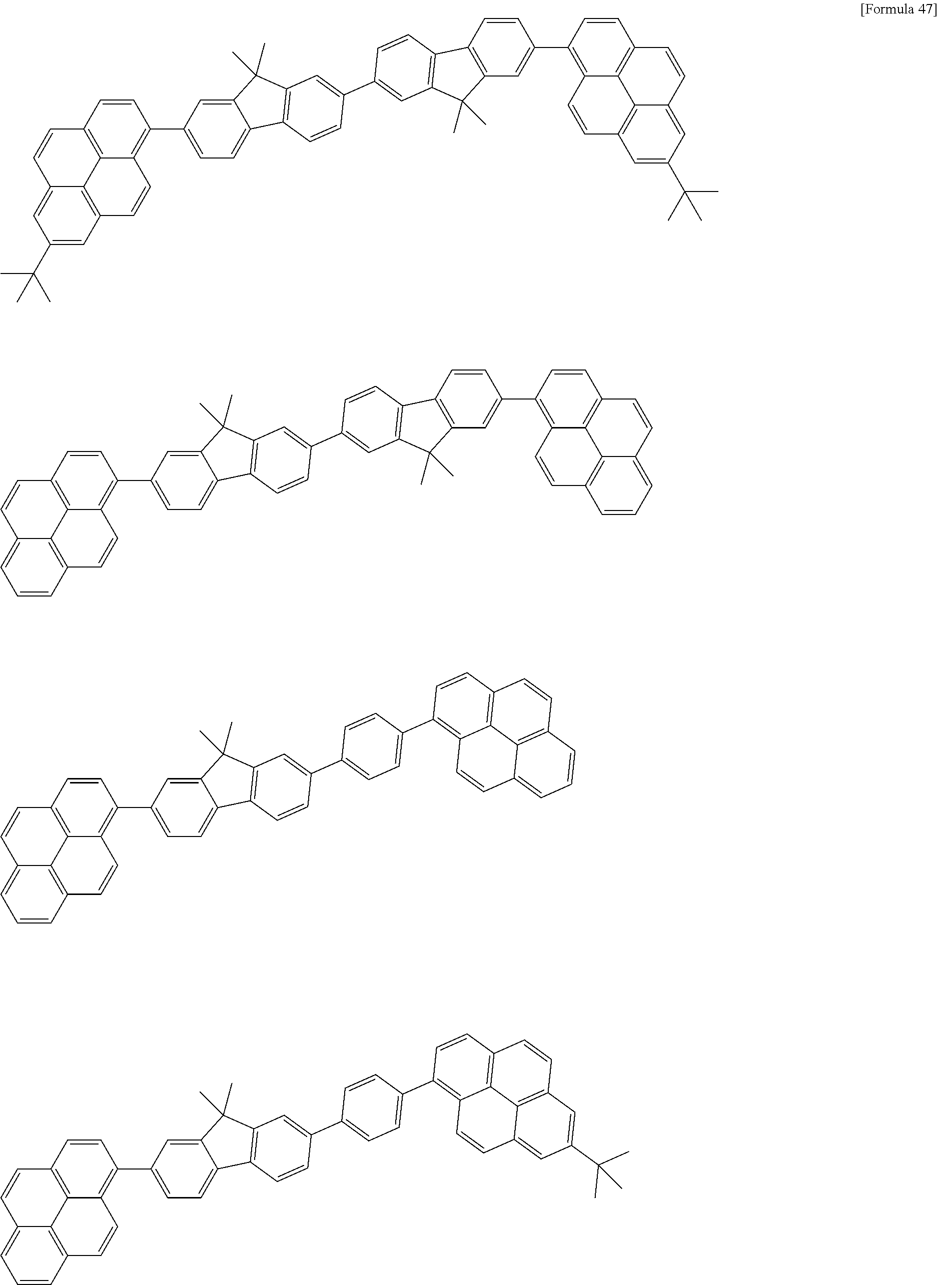

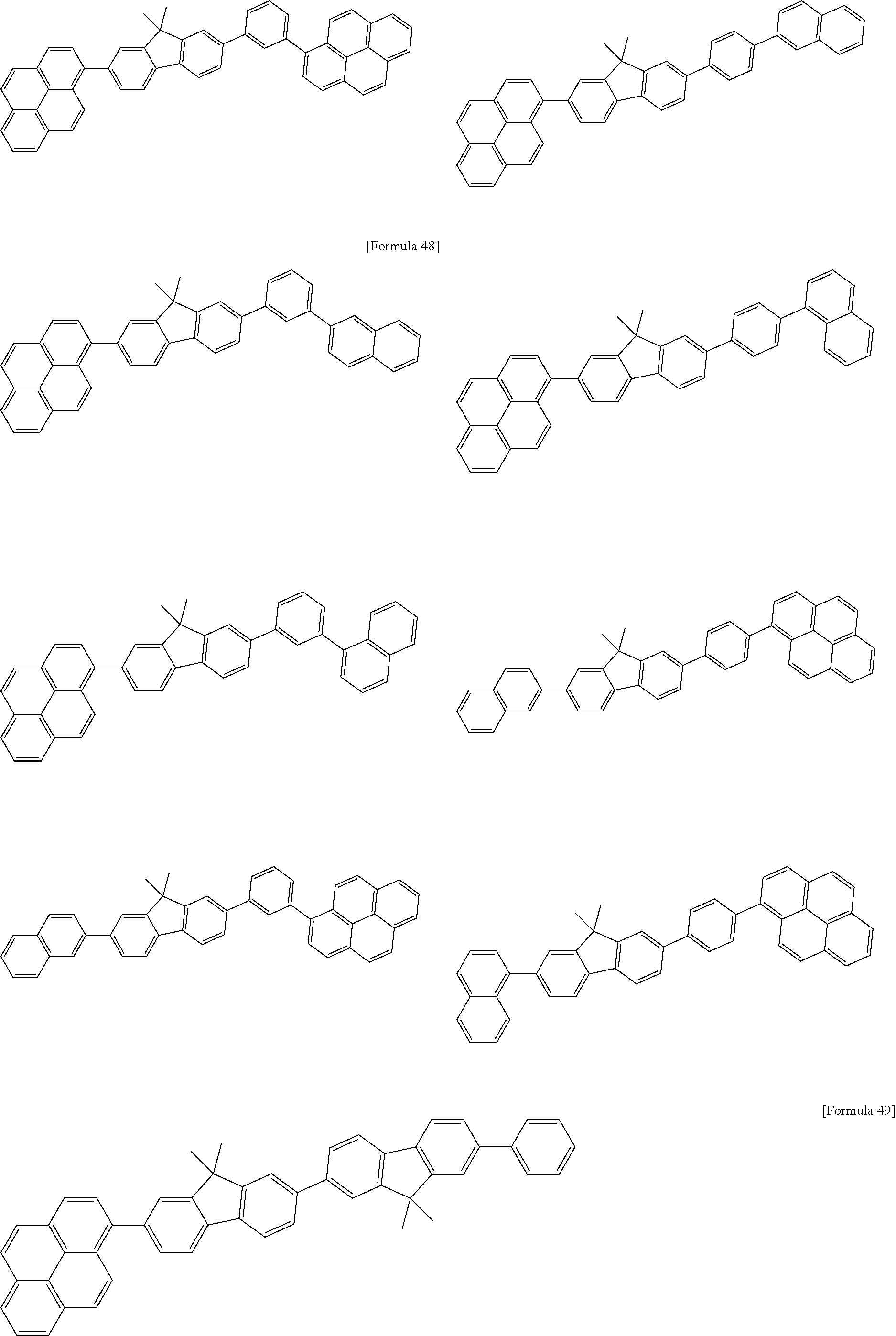

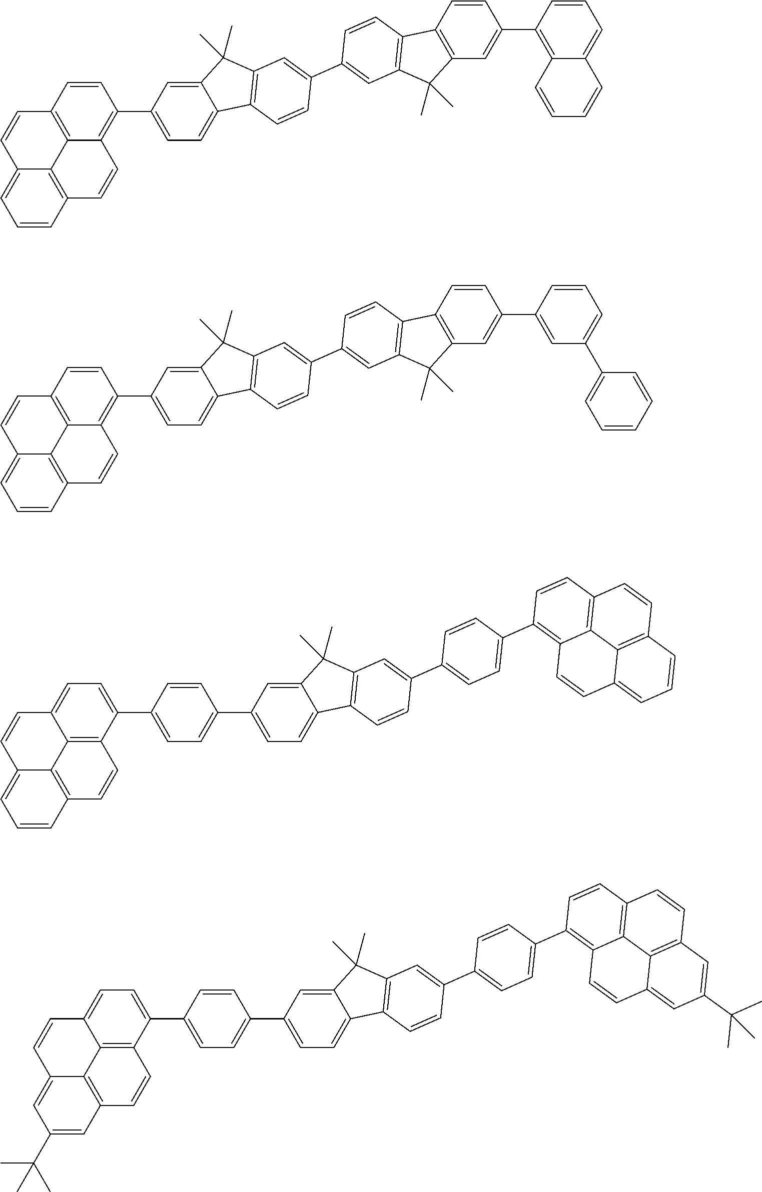

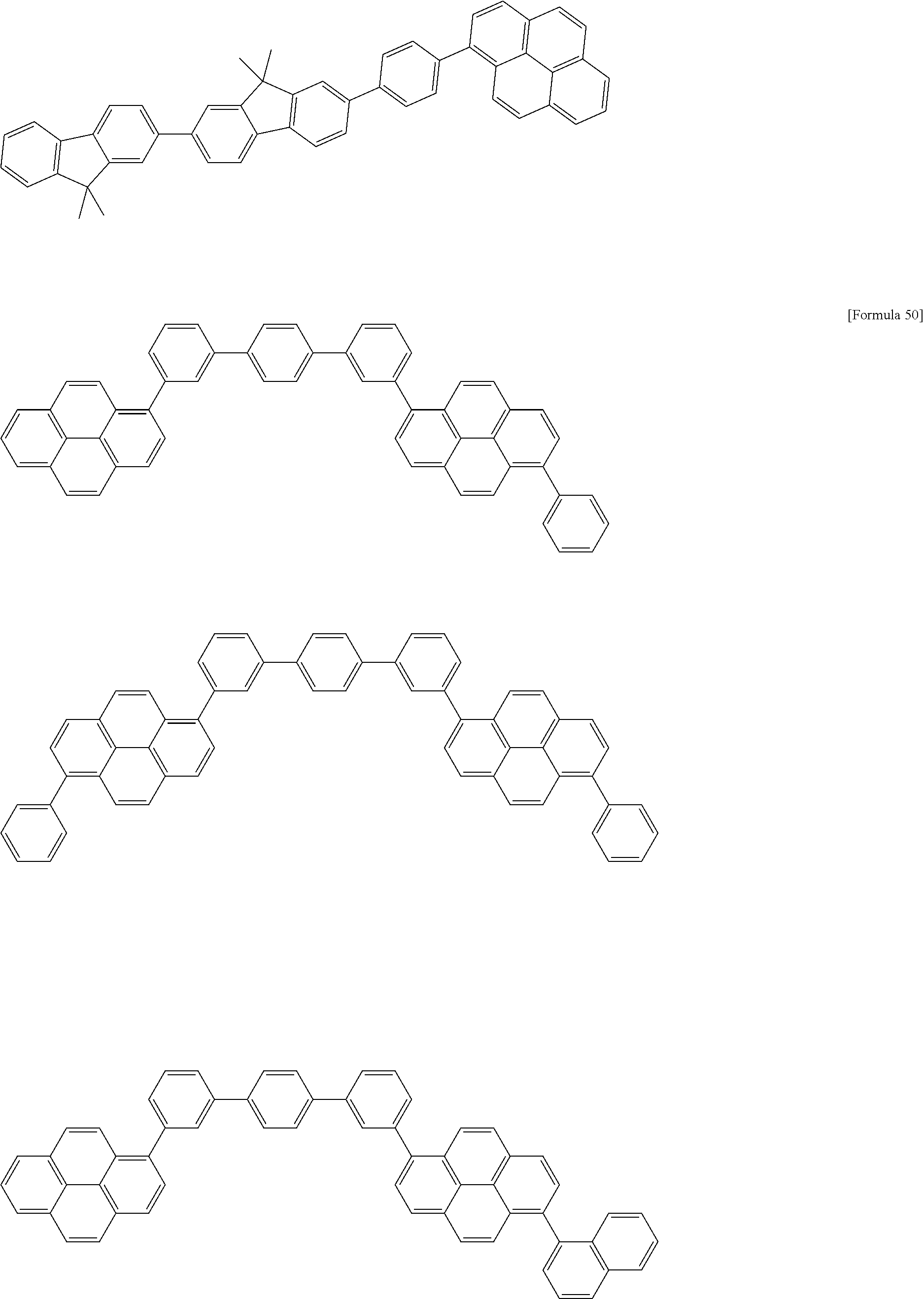

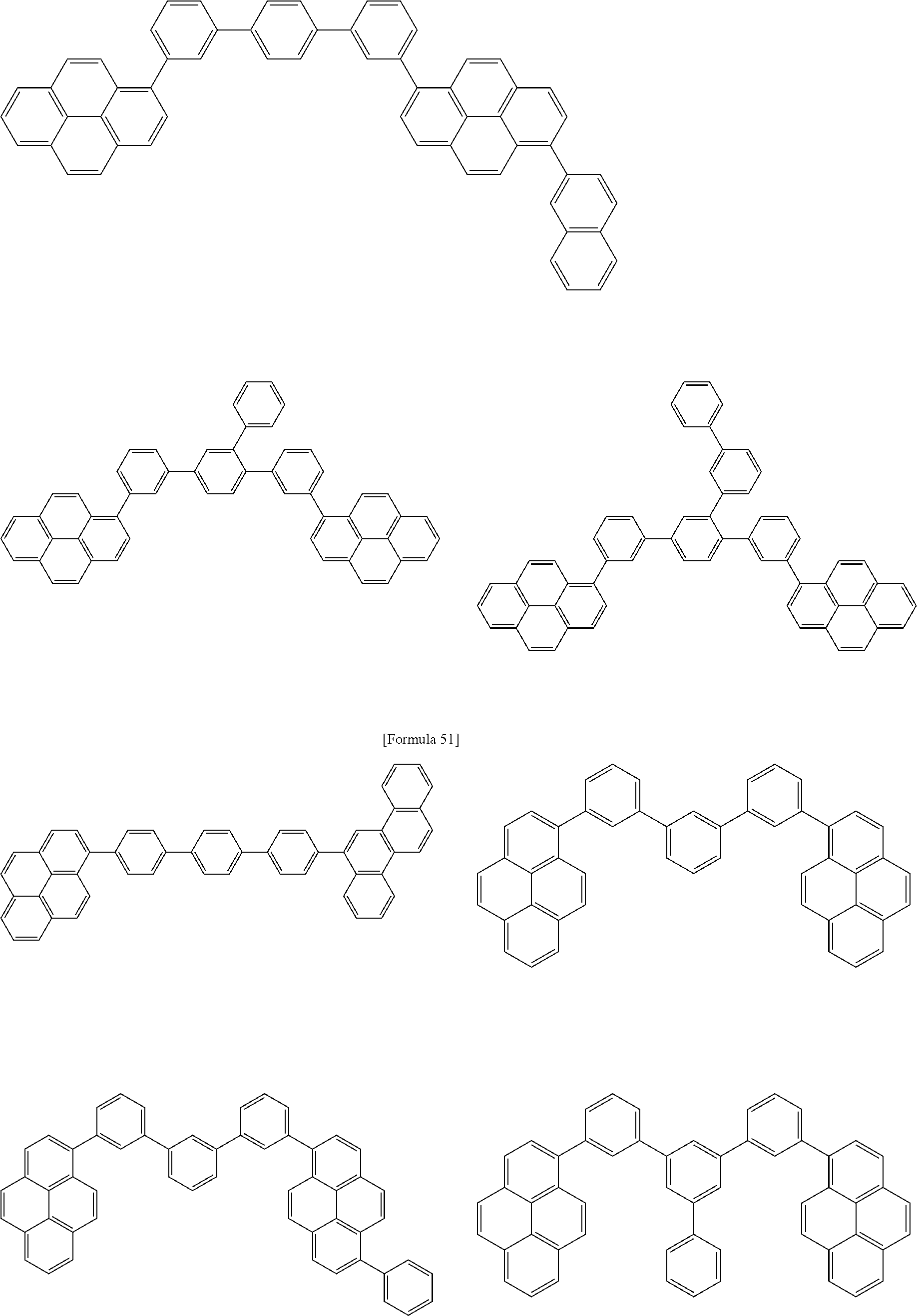

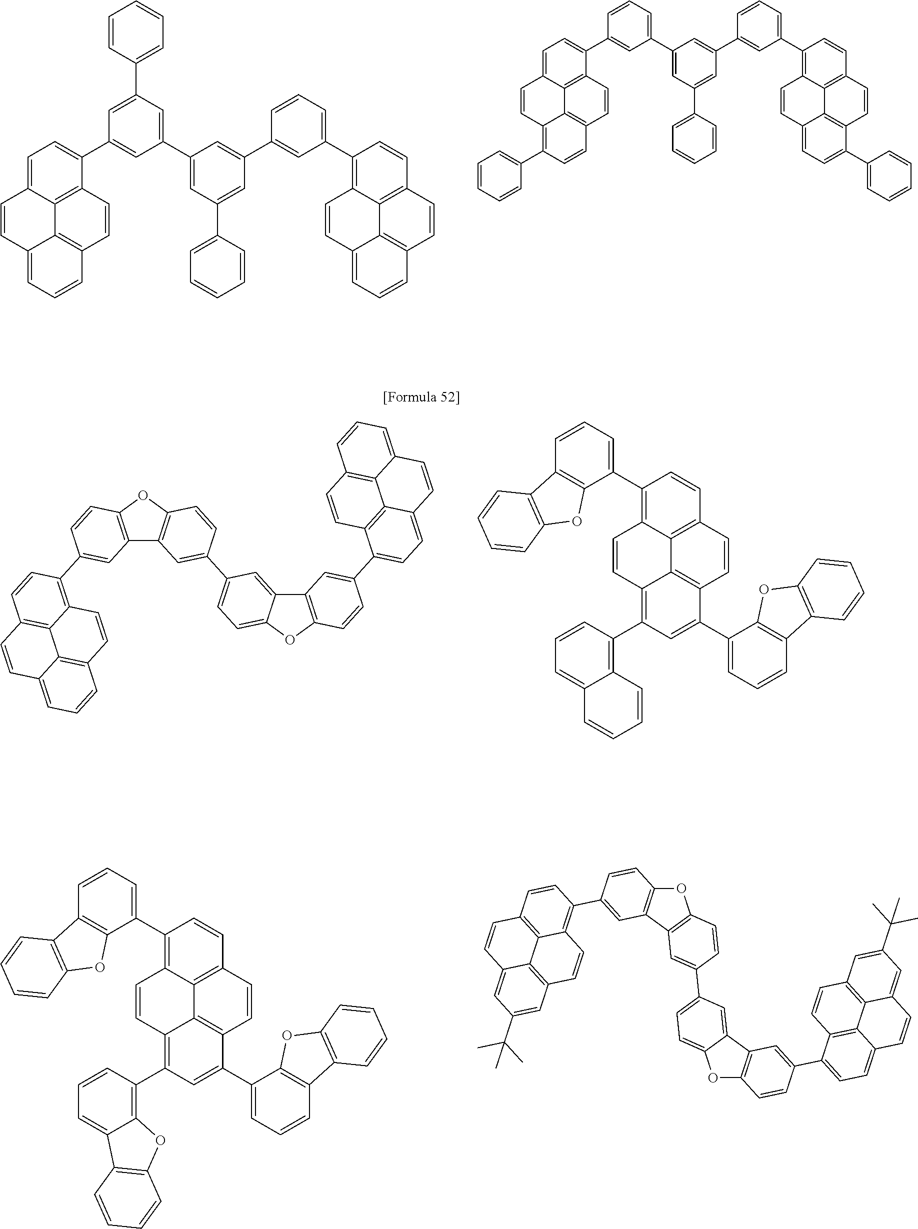

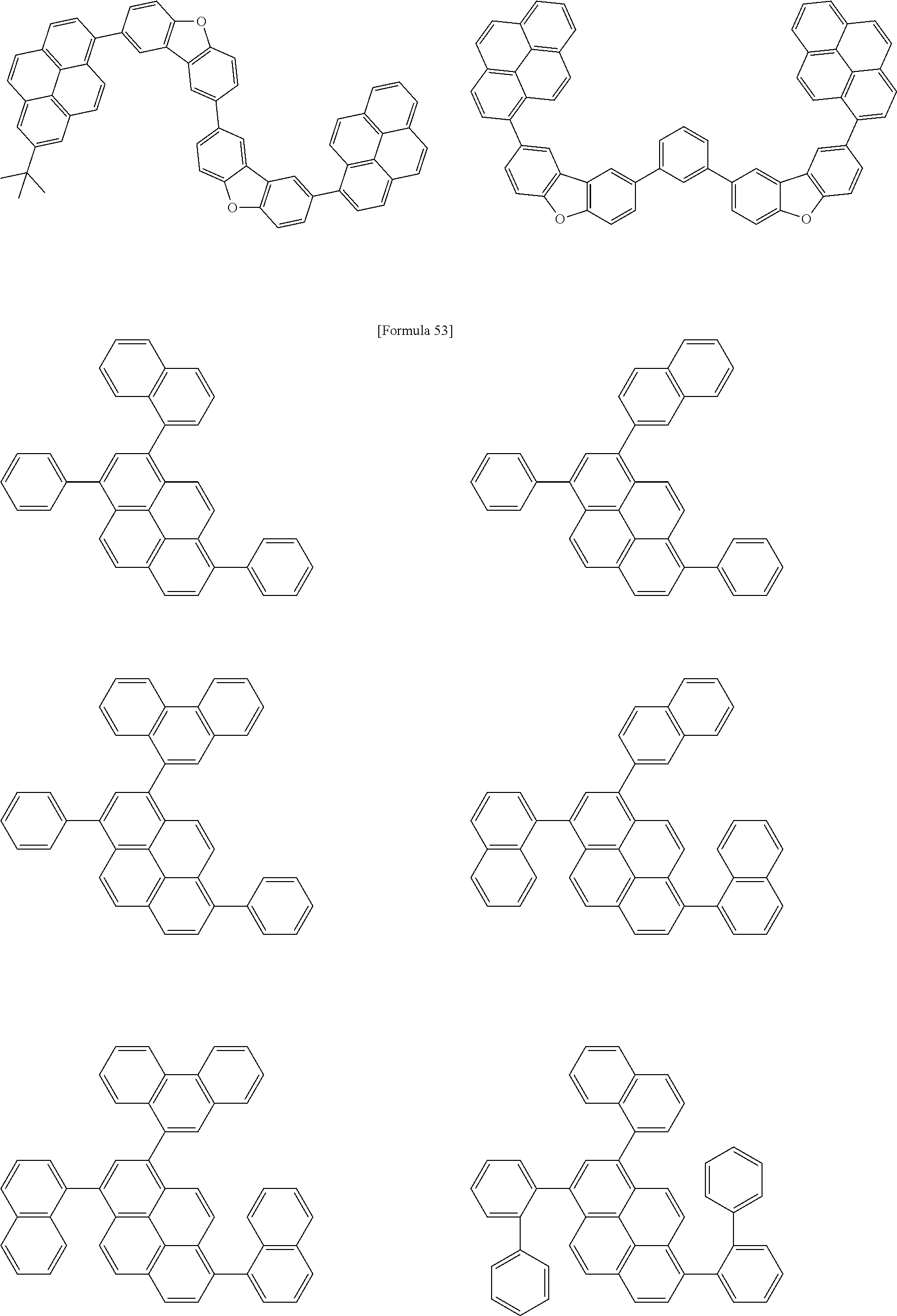

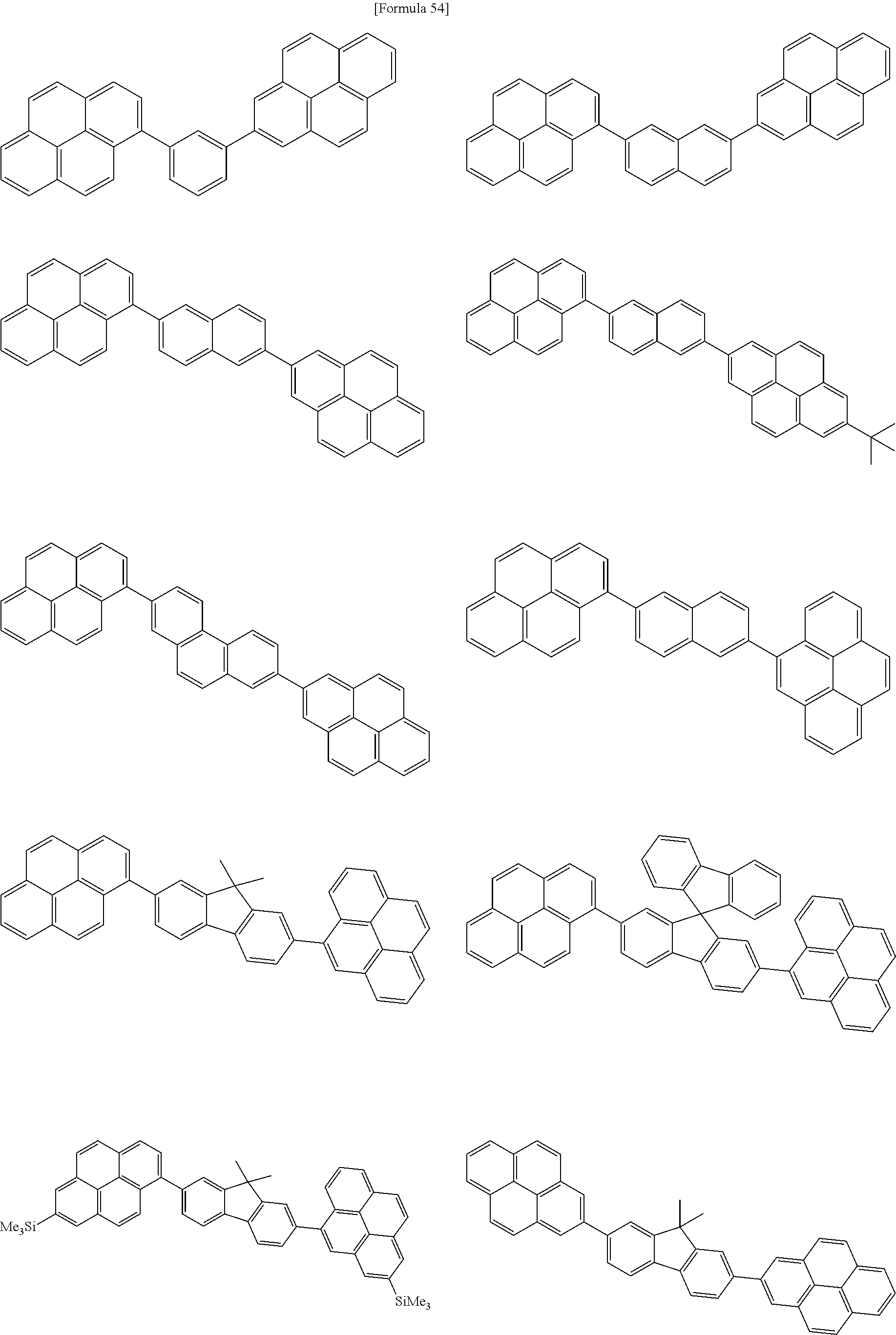

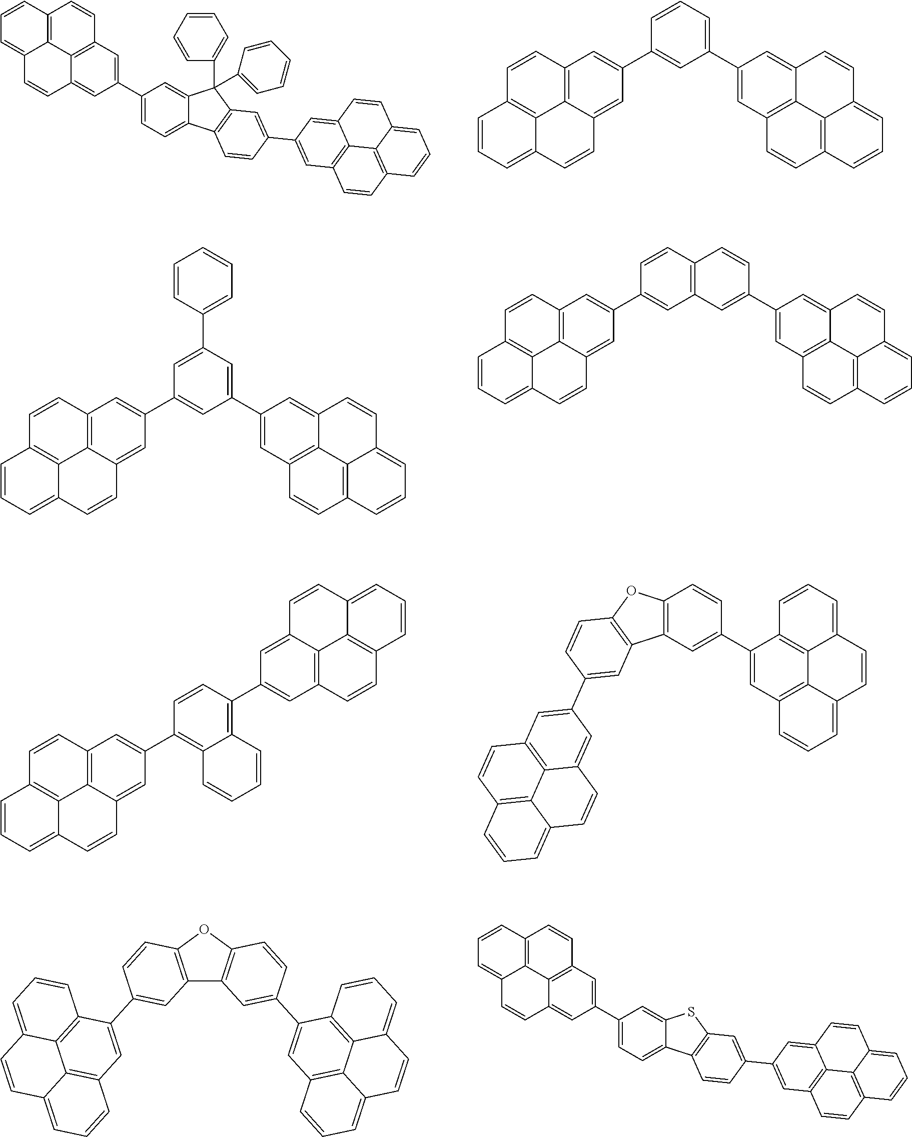

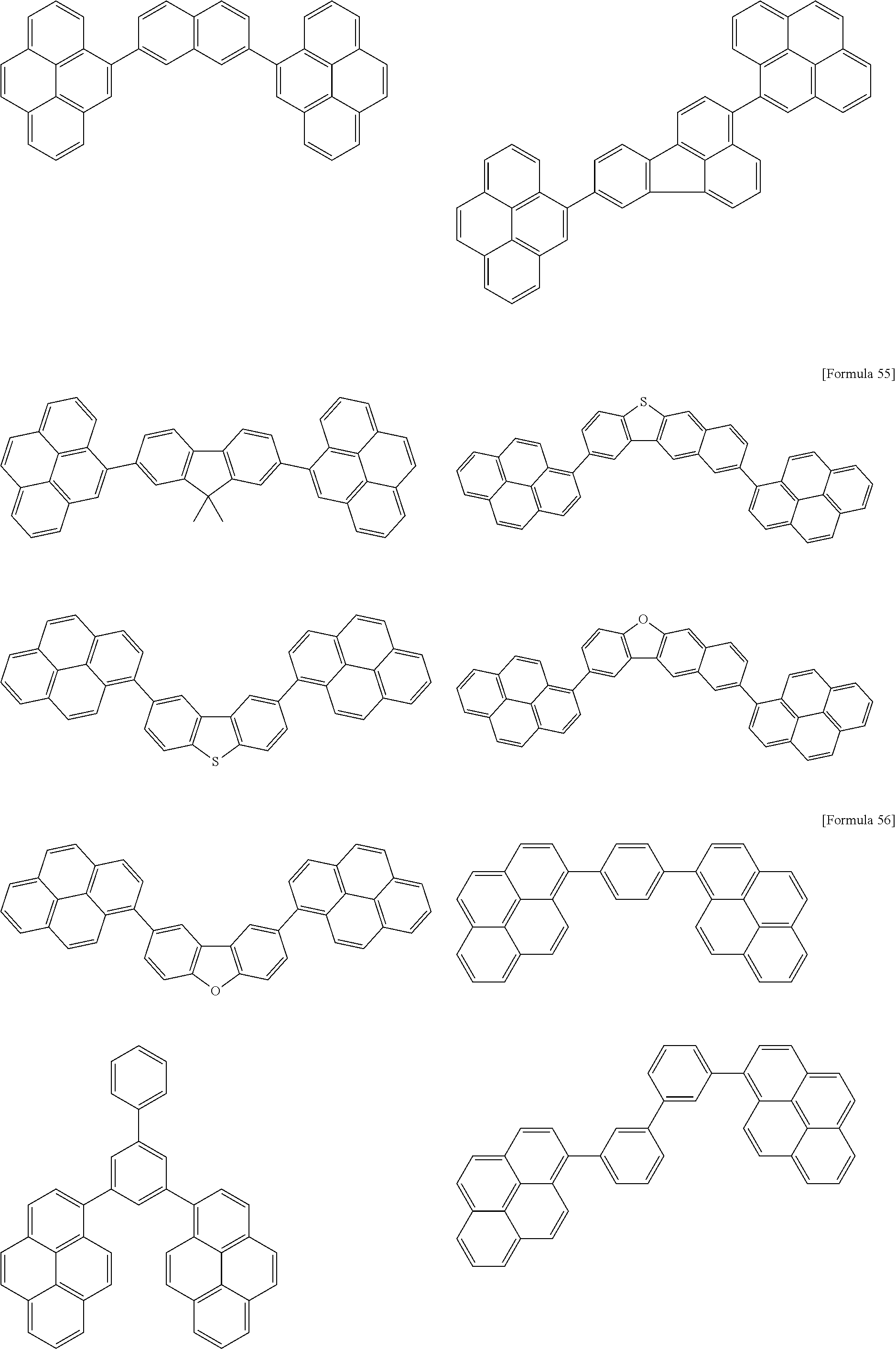

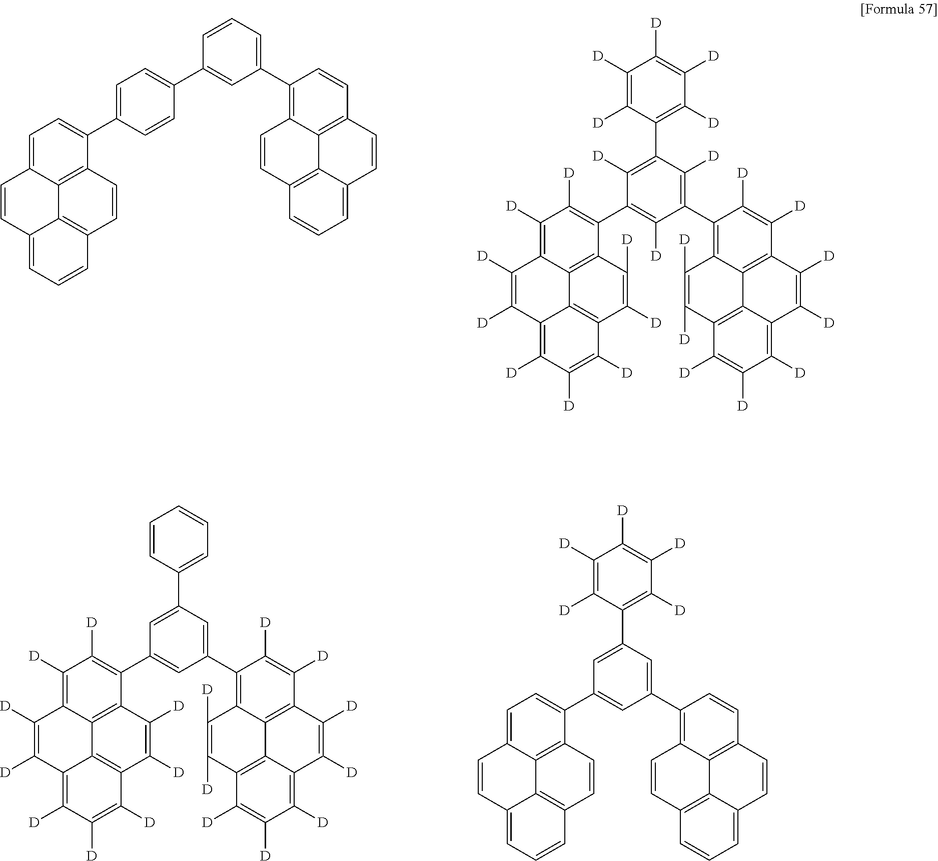

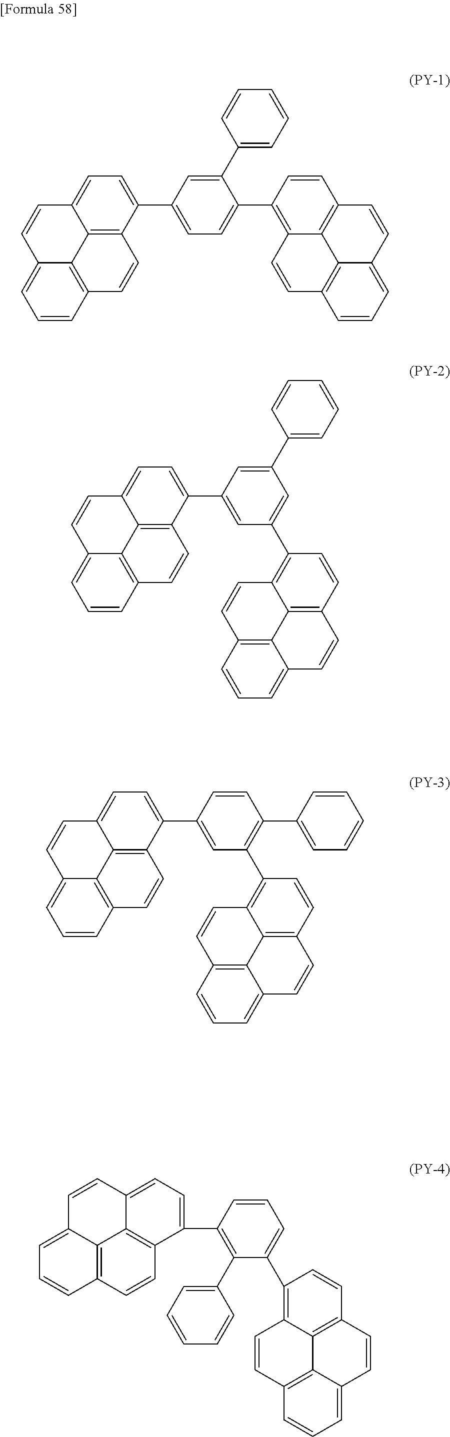

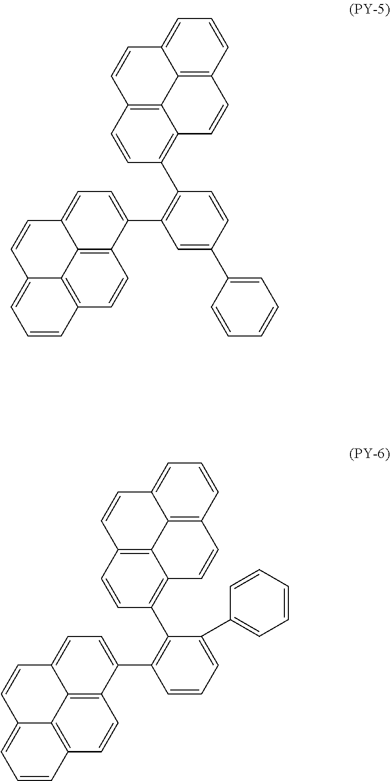

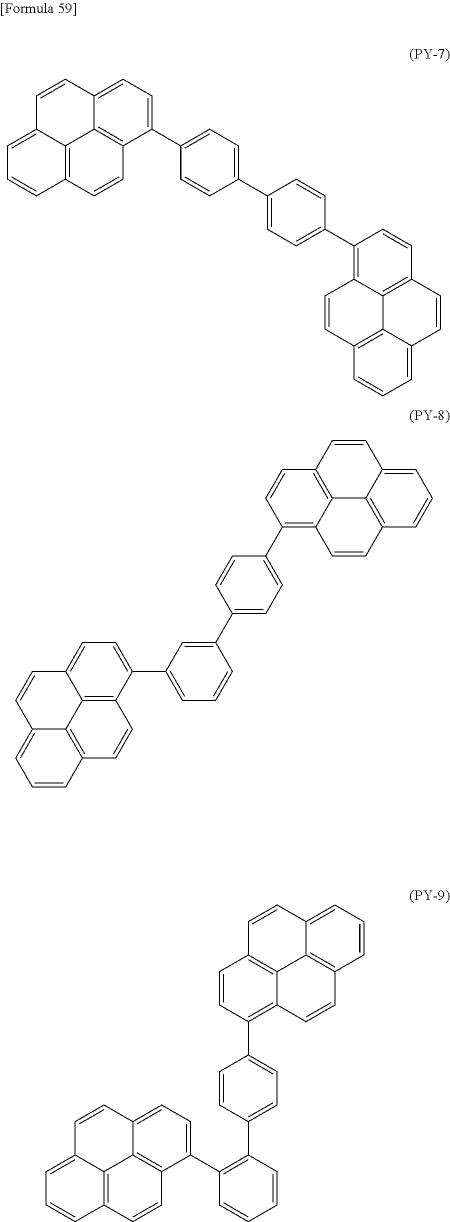

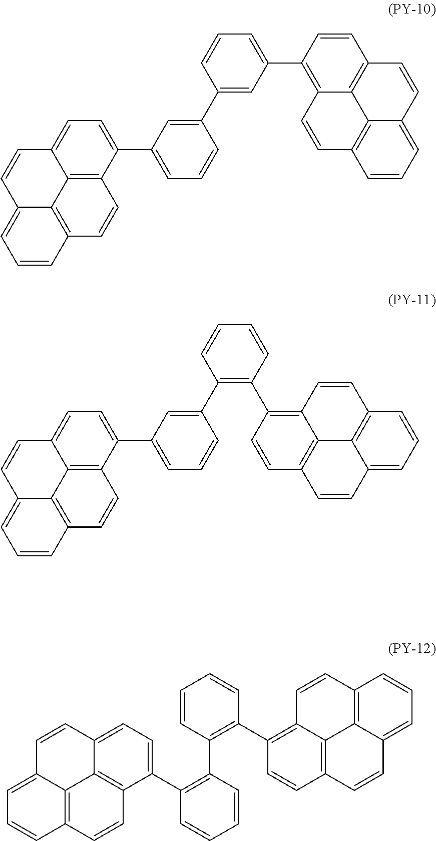

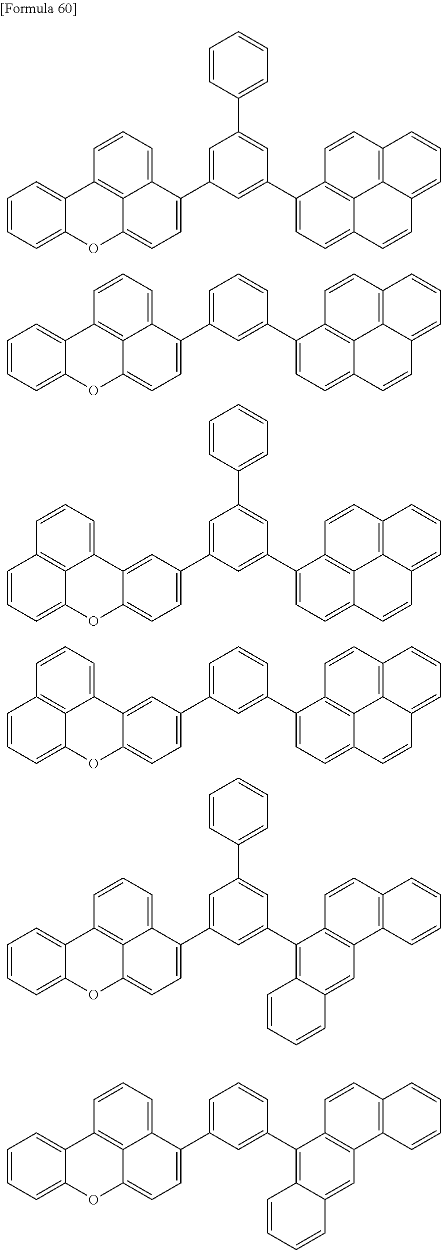

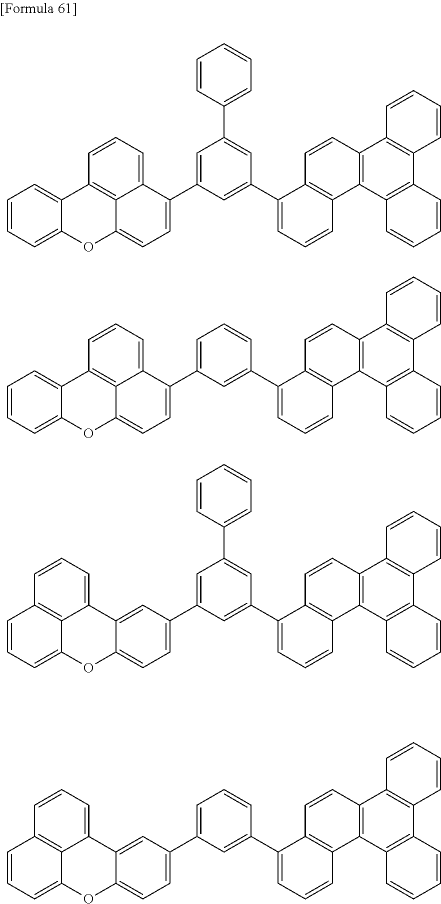

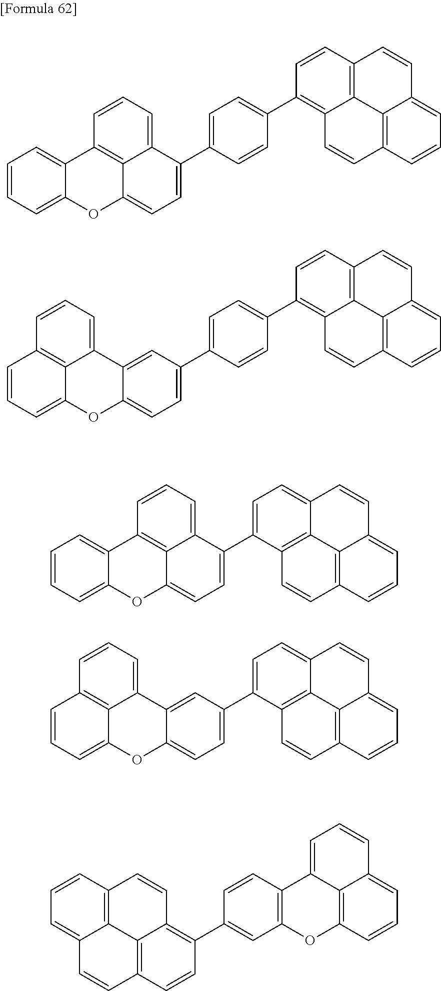 [SMILES: c1ccc2c(c1)Oc1ccc(-c3ccc(-c4ccc5ccc6cccc7ccc4c5c67)cc3)c3cccc-2c13 ; c1cc2c3c(cccc3c1)-c1cc(-c3ccc(-c4ccc5ccc6cccc7ccc4c5c67)cc3)ccc1O2 ; c1ccc2c(c1)Oc1ccc(-c3ccc4ccc5cccc6ccc3c4c56)c3cccc-2c13 ; c1cc2c3c(cccc3c1)-c1cc(-c3ccc4ccc5cccc6ccc3c4c56)ccc1O2 ; c1cc2c3c(cccc3c1)-c1ccc(-c3ccc4ccc5cccc6ccc3c4c56)cc1O2]

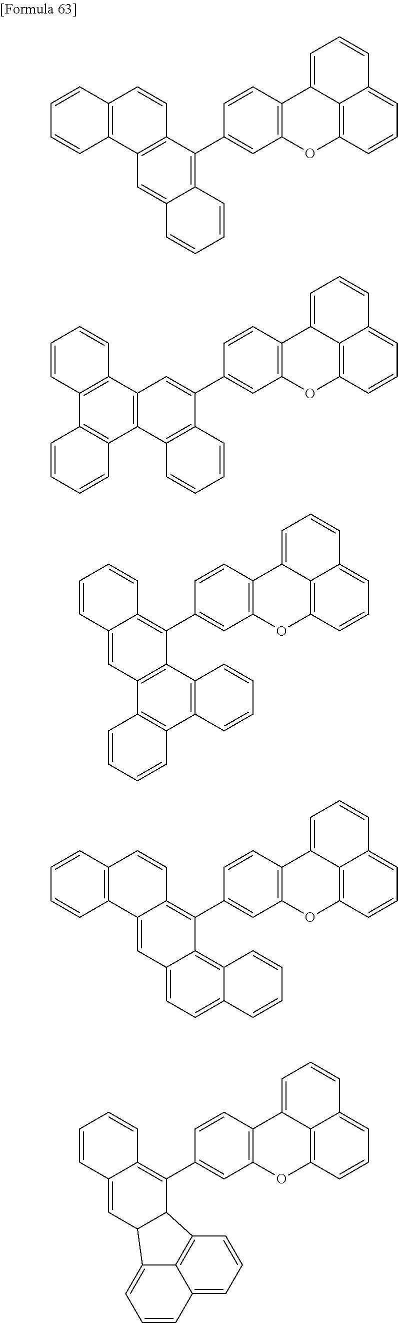 [SMILES: c1ccc2c(-c3ccc4c(c3)Oc3cccc5cccc-4c35)c3ccc4ccccc4c3cc2c1 ; c1cc2c3c(cccc3c1)-c1ccc(-c3cc4c5ccccc5c5ccccc5c4c4ccccc34)cc1O2 ; c1ccc2c(-c3ccc4c(c3)Oc3cccc5cccc-4c35)c3c4ccccc4c4ccccc4c3cc2c1 ; c1cc2c3c(cccc3c1)-c1ccc(-c3c4ccc5ccccc5c4cc4ccc5ccccc5c34)cc1O2 ; C1=c2ccccc2=C(c2ccc3c(c2)Oc2cccc4cccc-3c24)C2c3cccc4cccc(c34)C12]

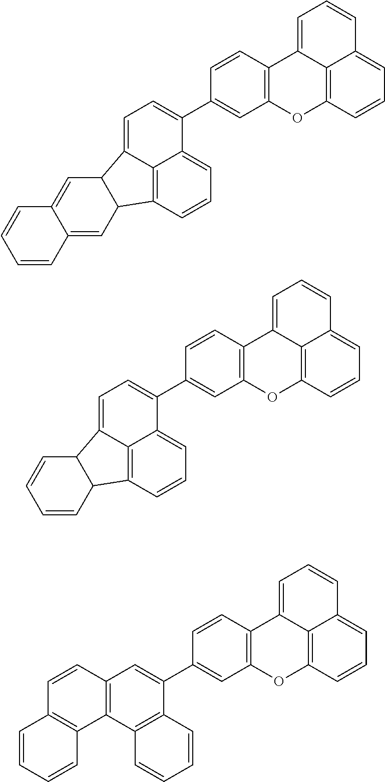 [SMILES: C1=c2ccccc2=CC2c3ccc(-c4ccc5c(c4)Oc4cccc6cccc-5c46)c4cccc(c34)C12 ; C1=CC2c3cccc4c(-c5ccc6c(c5)Oc5cccc7cccc-6c57)ccc(c34)C2C=C1 ; c1cc2c3c(cccc3c1)-c1ccc(-c3cc4ccc5ccccc5c4c4ccccc34)cc1O2]

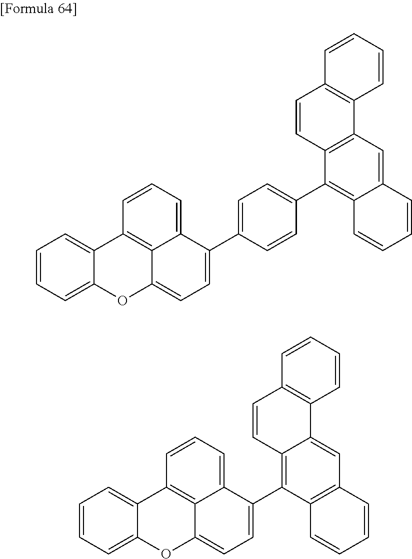 [SMILES: c1ccc2c(c1)Oc1ccc(-c3ccc(-c4c5ccccc5cc5c4ccc4ccccc45)cc3)c3cccc-2c13 ; c1ccc2c(c1)Oc1ccc(-c3c4ccccc4cc4c3ccc3ccccc34)c3cccc-2c13]

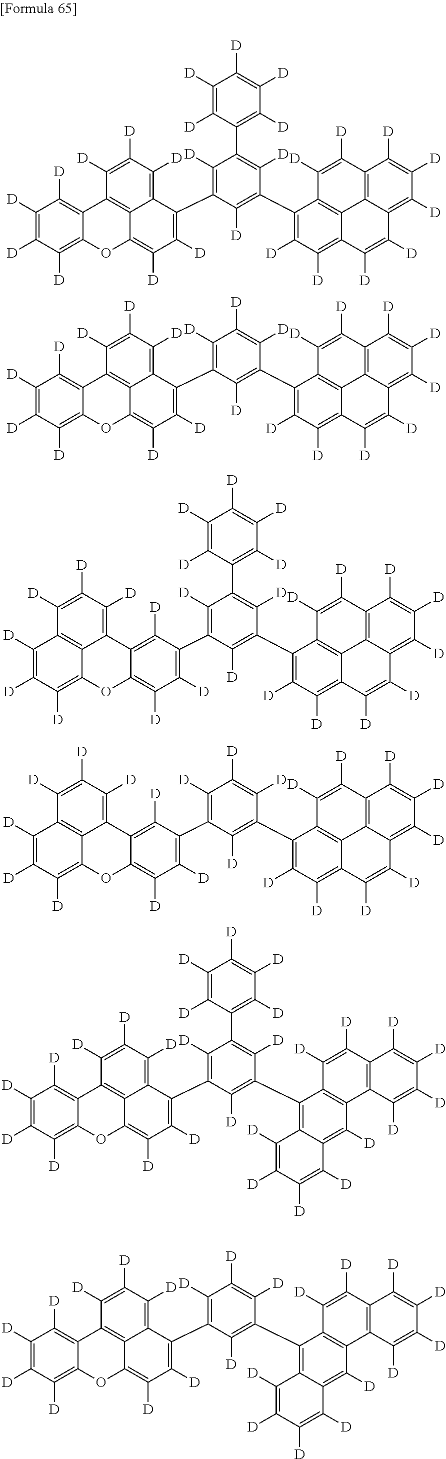

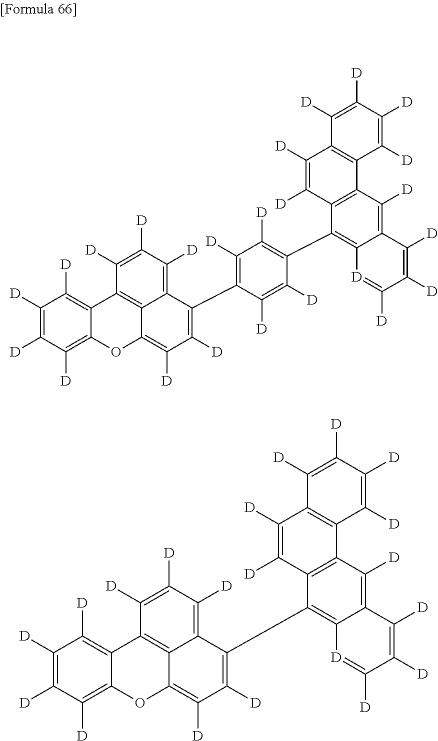

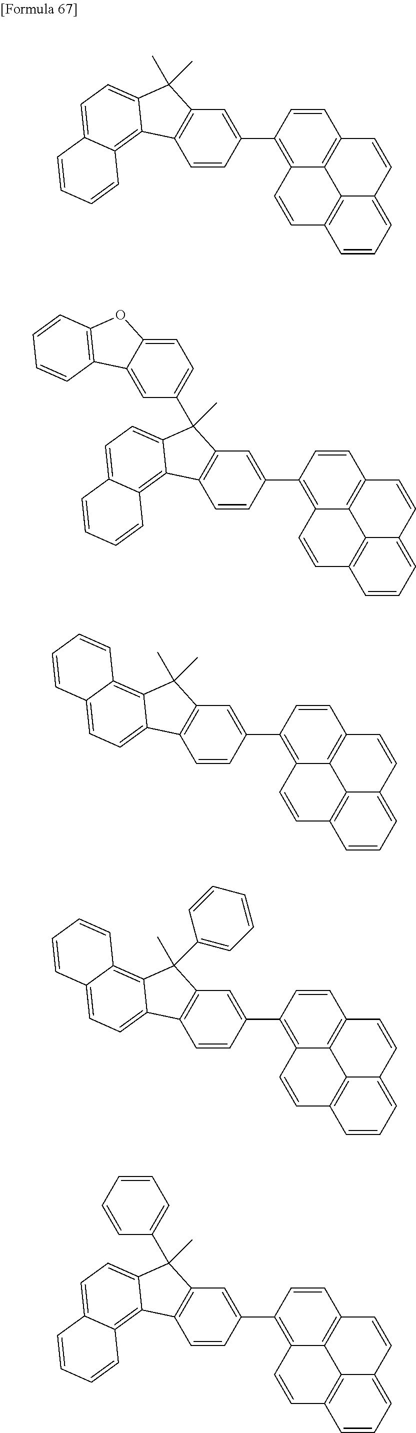

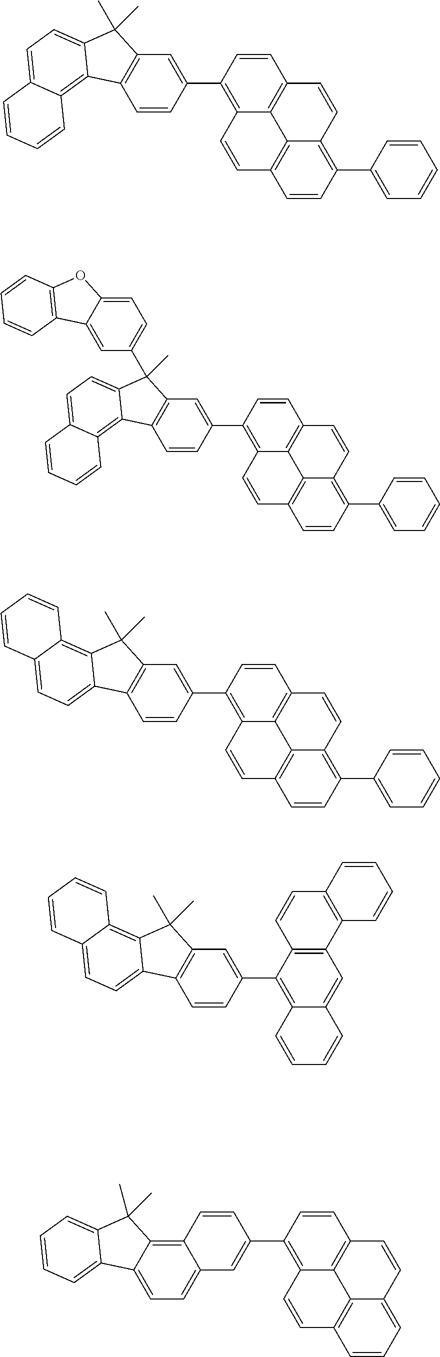

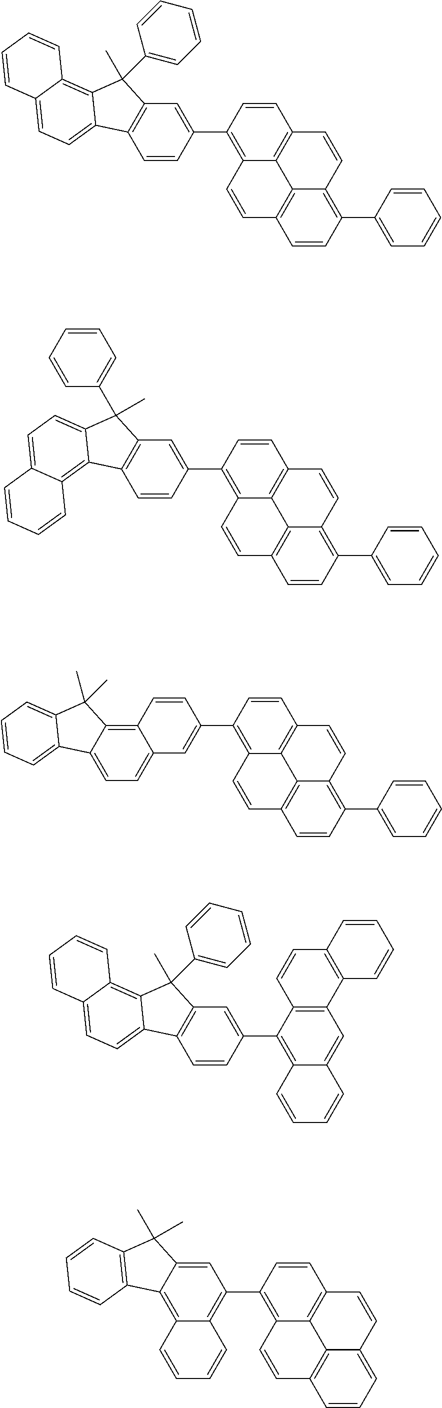

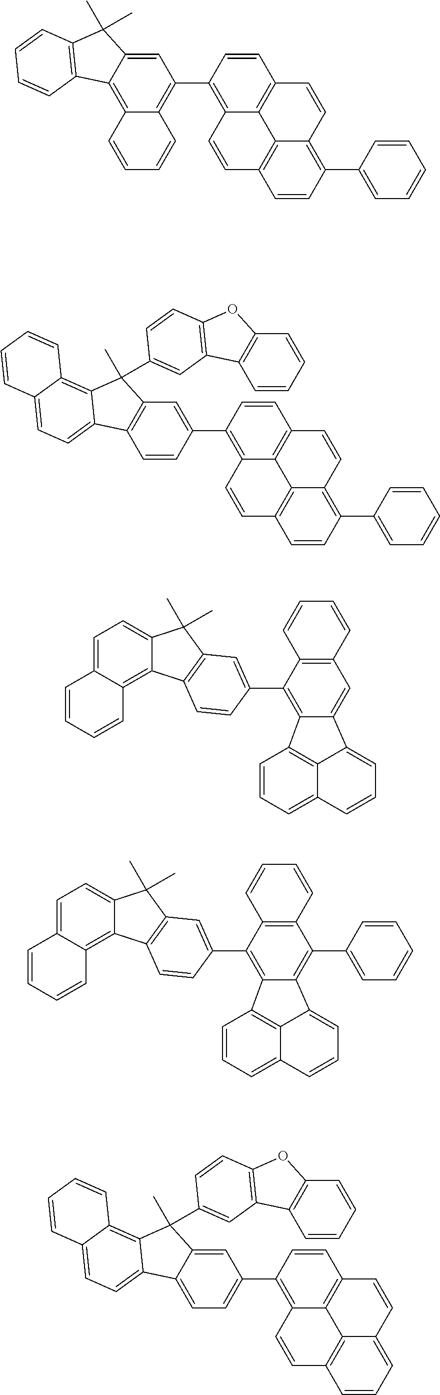

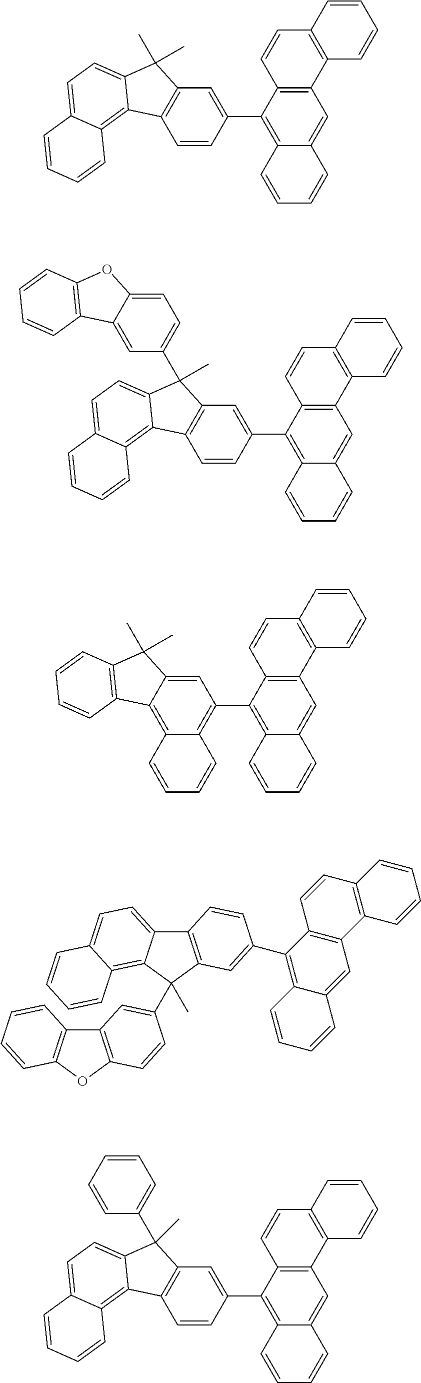

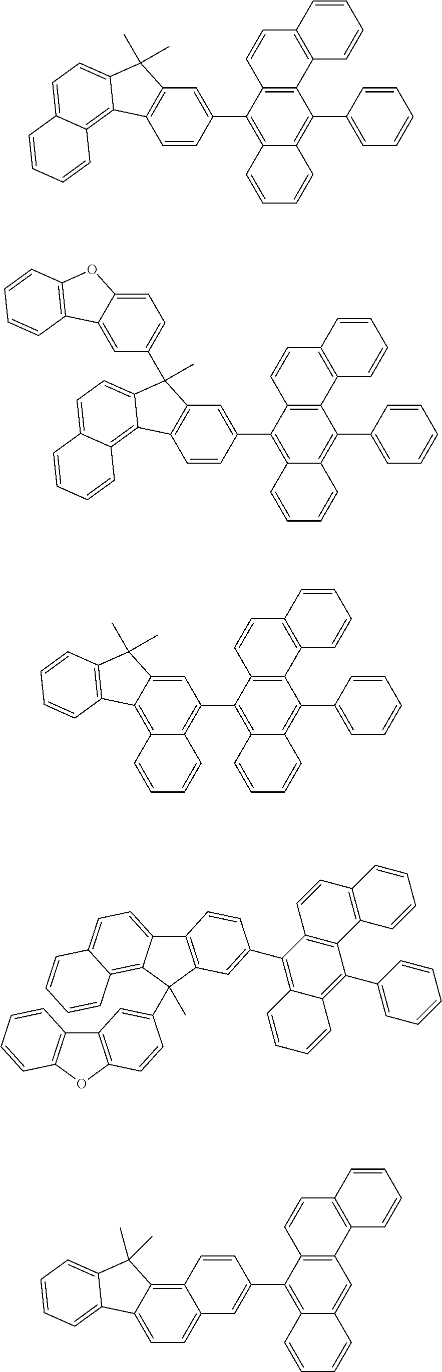

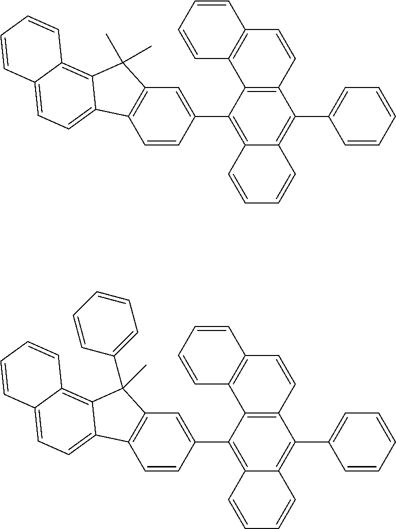

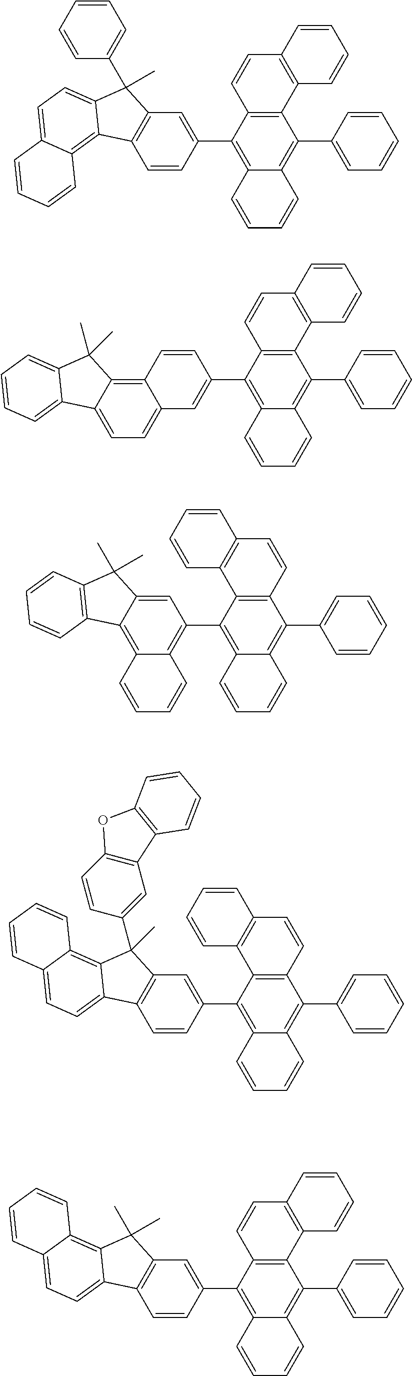

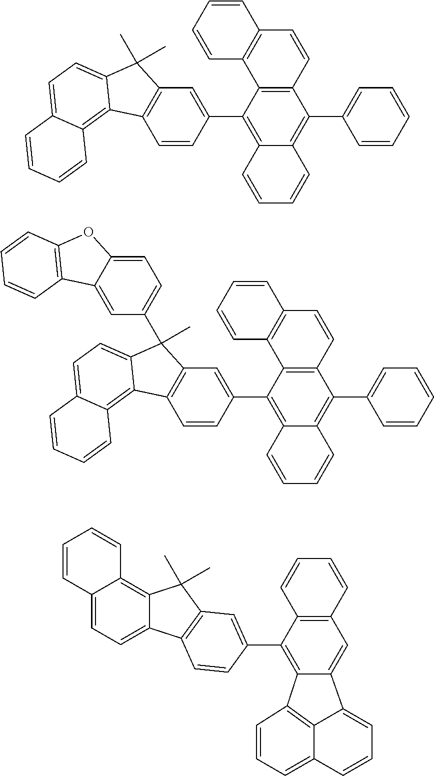

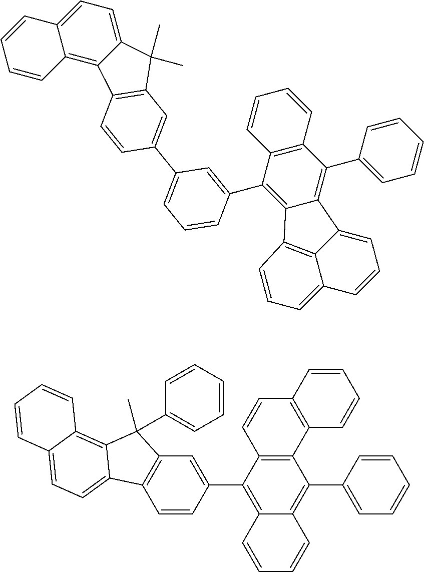

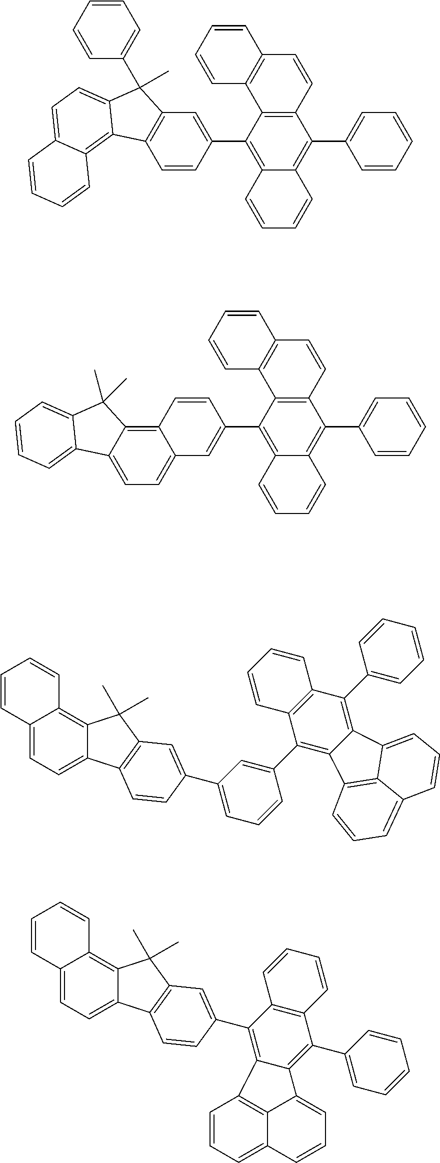

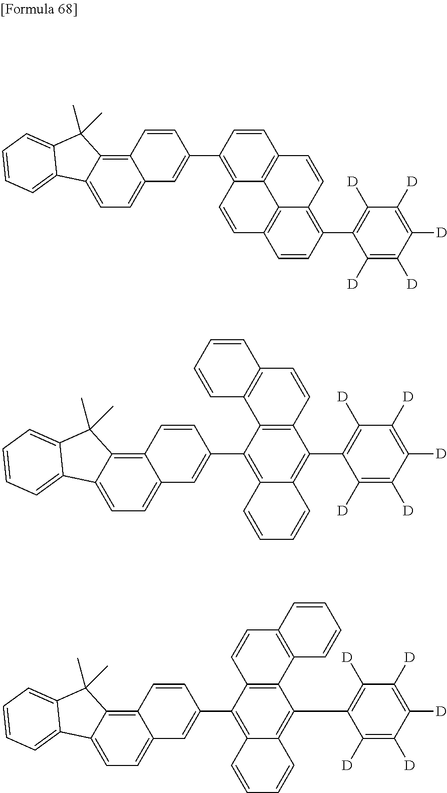 [SMILES: [2H]c1c([2H])c([2H])c(-c2ccc3ccc4c(-c5ccc6c7c(ccc6c5)-c5ccccc5C7(C)C)ccc5ccc2c3c54)c([2H])c1[2H] ; [2H]c1c([2H])c([2H])c(-c2c3ccccc3c(-c3ccc4c5c(ccc4c3)-c3ccccc3C5(C)C)c3c2ccc2ccccc23)c([2H])c1[2H] ; [2H]c1c([2H])c([2H])c(-c2c3ccccc3c(-c3ccc4c5c(ccc4c3)-c3ccccc3C5(C)C)c3ccc4ccccc4c23)c([2H])c1[2H]]

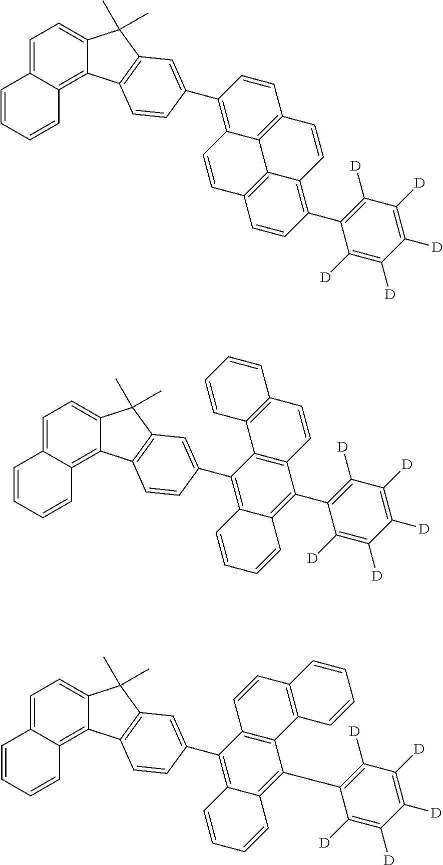 [SMILES: [2H]c1c([2H])c([2H])c(-c2ccc3ccc4c(-c5ccc6c(c5)C(C)(C)c5ccc7ccccc7c5-6)ccc5ccc2c3c54)c([2H])c1[2H] ; [2H]c1c([2H])c([2H])c(-c2c3ccccc3c(-c3ccc4c(c3)C(C)(C)c3ccc5ccccc5c3-4)c3c2ccc2ccccc23)c([2H])c1[2H] ; [2H]c1c([2H])c([2H])c(-c2c3ccccc3c(-c3ccc4c(c3)C(C)(C)c3ccc5ccccc5c3-4)c3ccc4ccccc4c23)c([2H])c1[2H]]

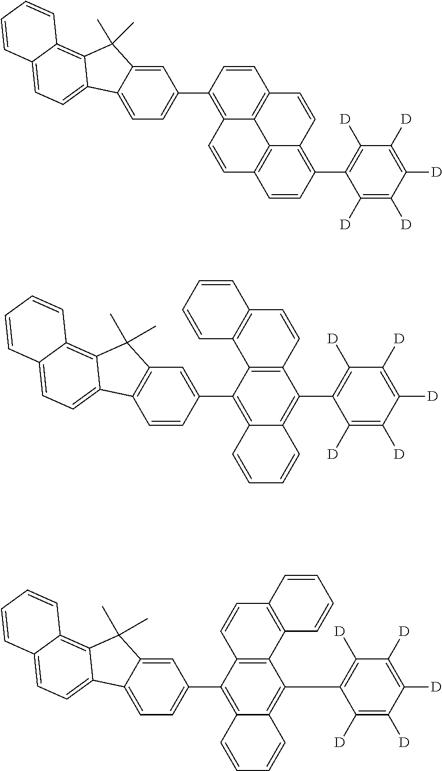 [SMILES: [2H]c1c([2H])c([2H])c(-c2ccc3ccc4c(-c5ccc6c(c5)C(C)(C)c5c-6ccc6ccccc56)ccc5ccc2c3c54)c([2H])c1[2H] ; [2H]c1c([2H])c([2H])c(-c2c3ccccc3c(-c3ccc4c(c3)C(C)(C)c3c-4ccc4ccccc34)c3c2ccc2ccccc23)c([2H])c1[2H] ; [2H]c1c([2H])c([2H])c(-c2c3ccccc3c(-c3ccc4c(c3)C(C)(C)c3c-4ccc4ccccc34)c3ccc4ccccc4c23)c([2H])c1[2H]]

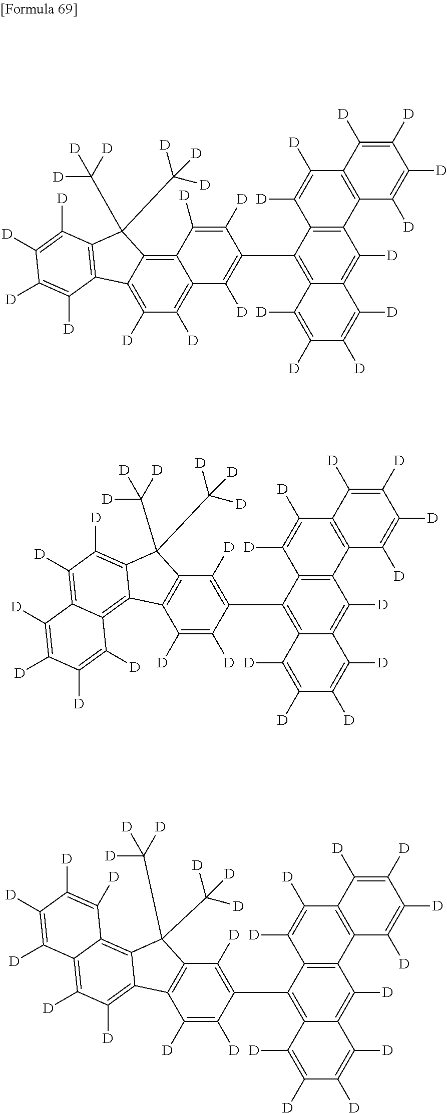

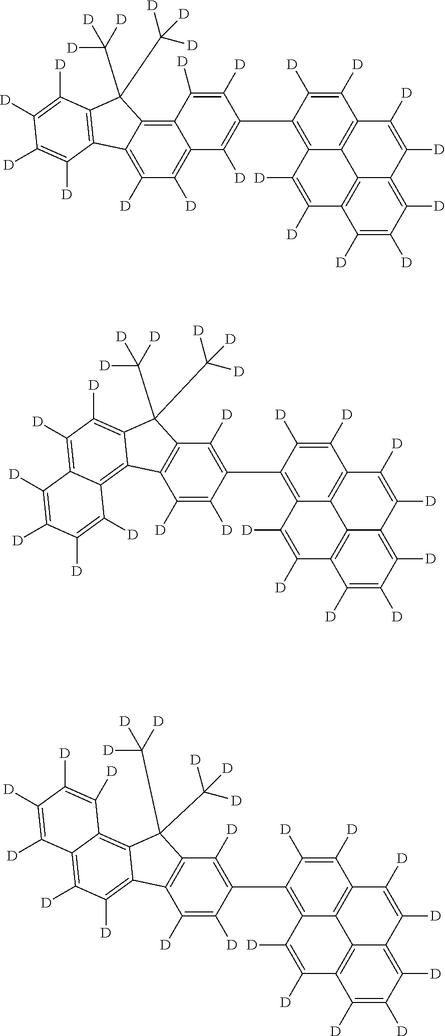

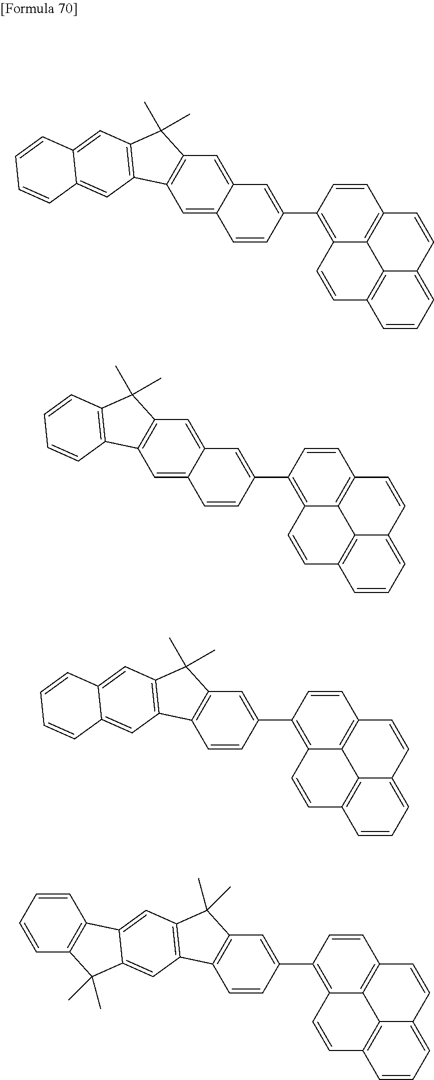

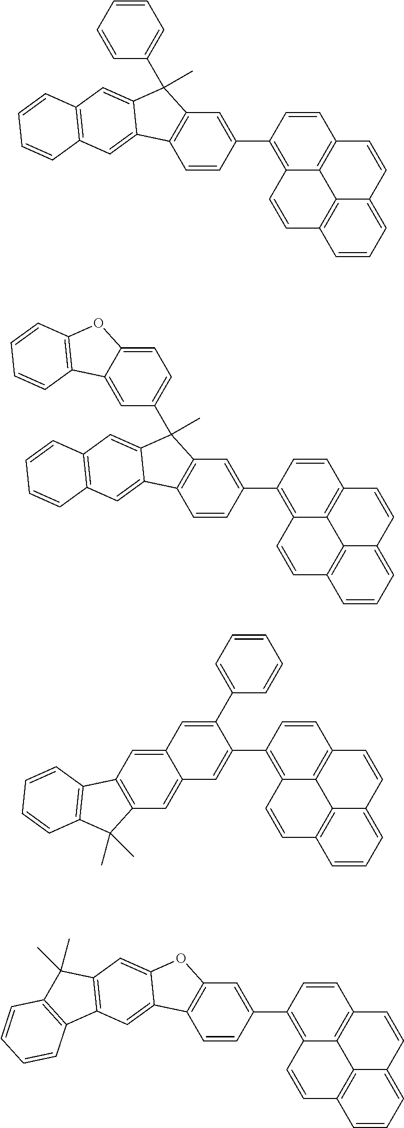

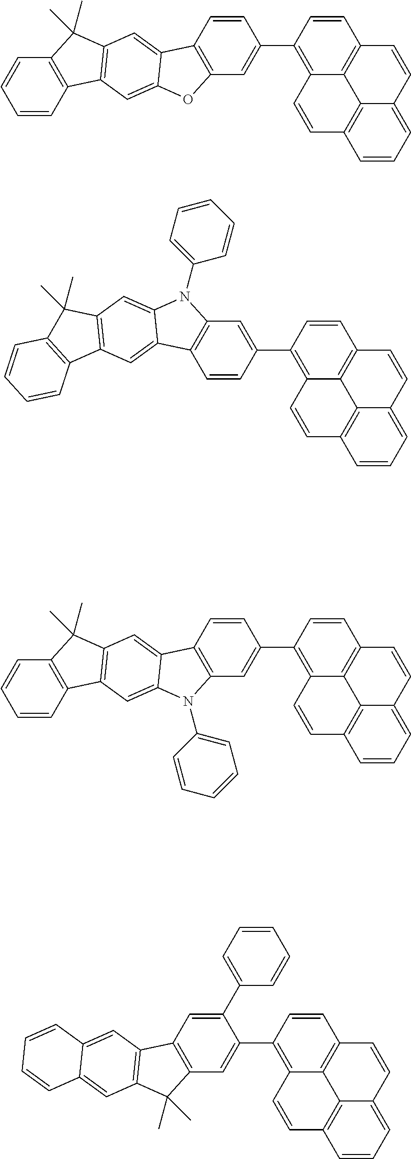

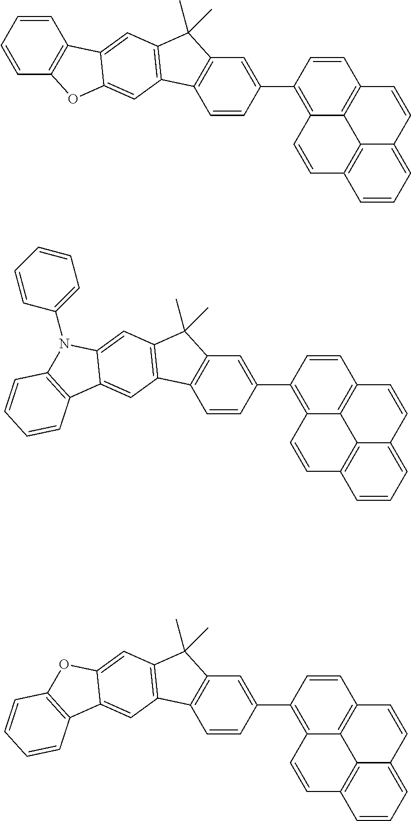 [SMILES: CC1(C)c2cc(-c3ccc4ccc5cccc6ccc3c4c56)ccc2-c2cc3oc4ccccc4c3cc21 ; CC1(C)c2cc(-c3ccc4ccc5cccc6ccc3c4c56)ccc2-c2cc3c4ccccc4n(-c4ccccc4)c3cc21 ; CC1(C)c2cc(-c3ccc4ccc5cccc6ccc3c4c56)ccc2-c2cc3c(cc21)oc1ccccc13]

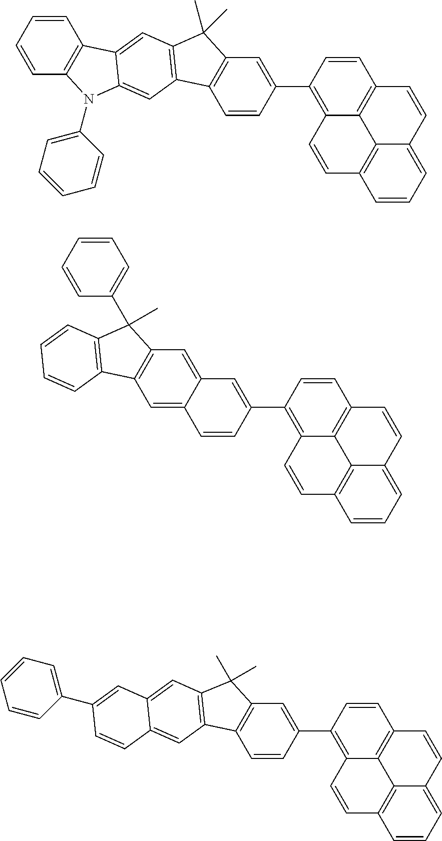

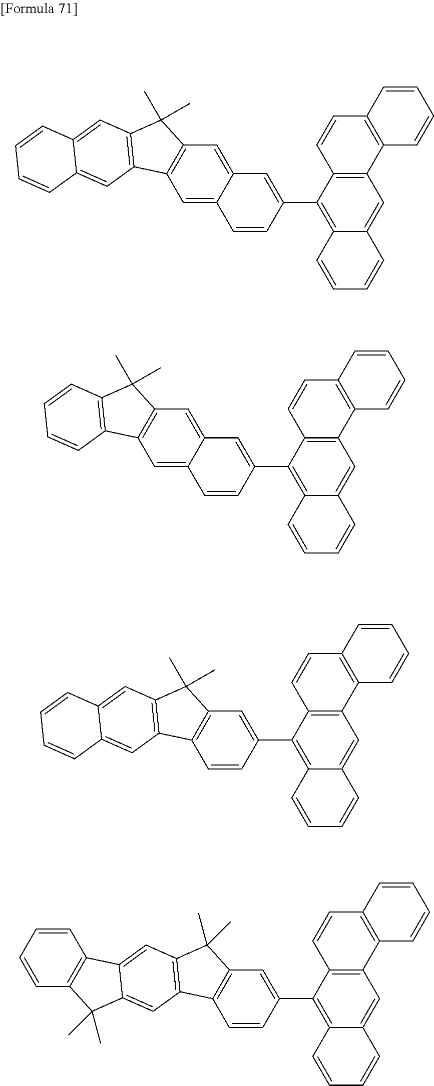

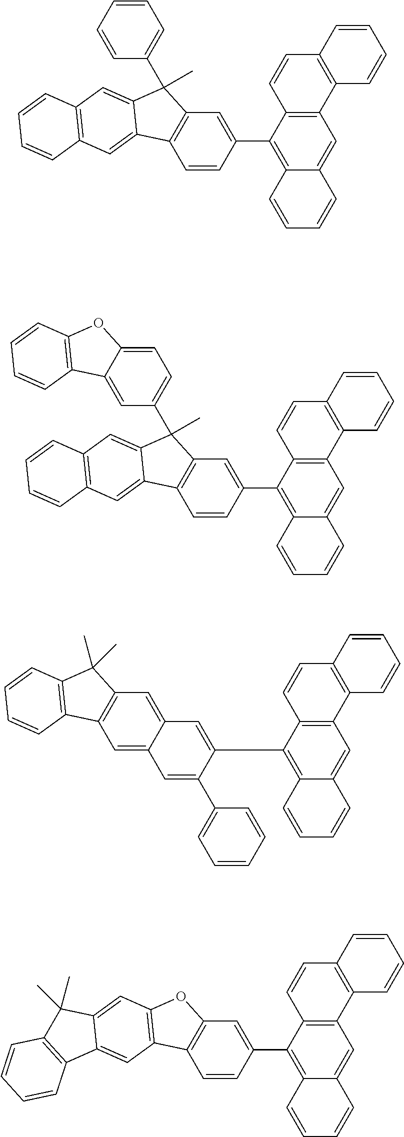

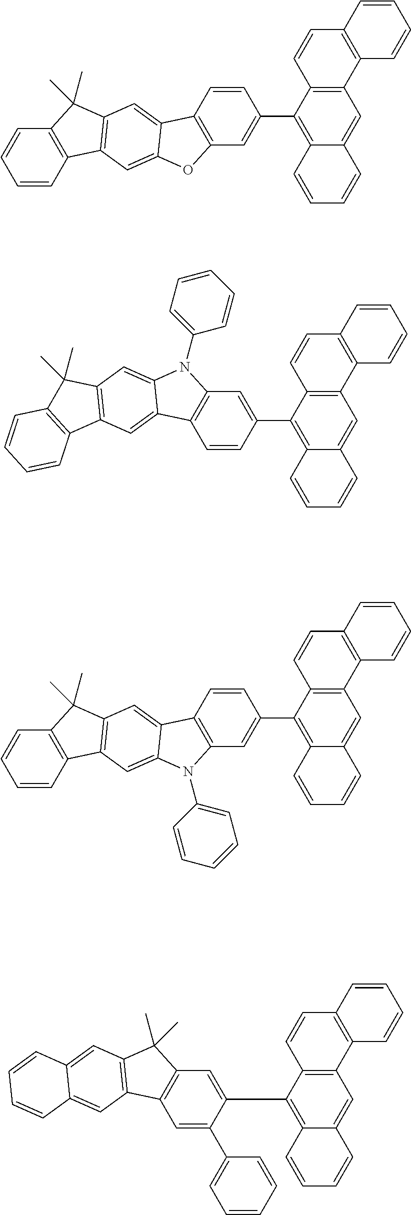

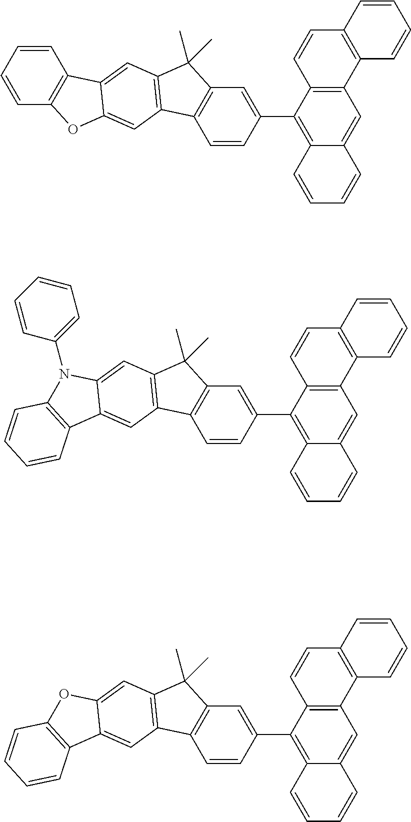 [SMILES: CC1(C)c2cc(-c3c4ccccc4cc4c3ccc3ccccc34)ccc2-c2cc3oc4ccccc4c3cc21 ; CC1(C)c2cc(-c3c4ccccc4cc4c3ccc3ccccc34)ccc2-c2cc3c4ccccc4n(-c4ccccc4)c3cc21 ; CC1(C)c2cc(-c3c4ccccc4cc4c3ccc3ccccc34)ccc2-c2cc3c(cc21)oc1ccccc13]

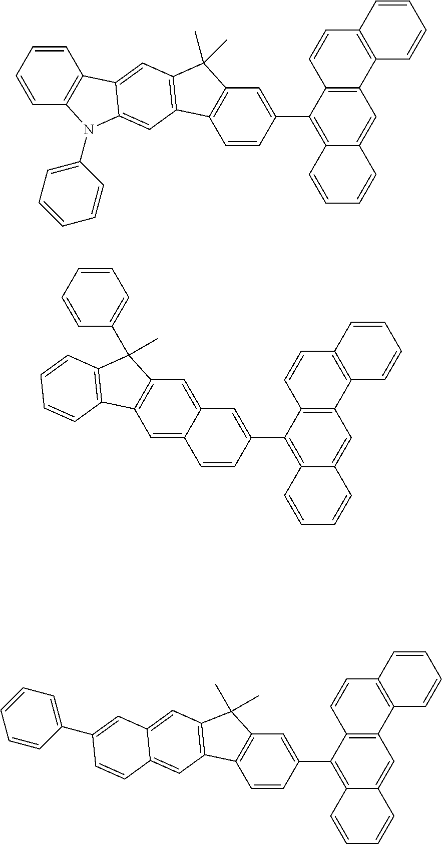

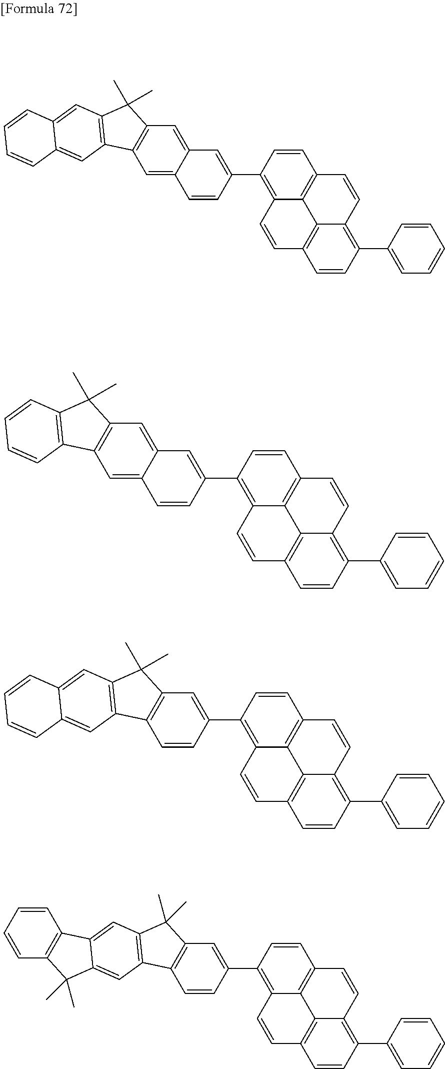

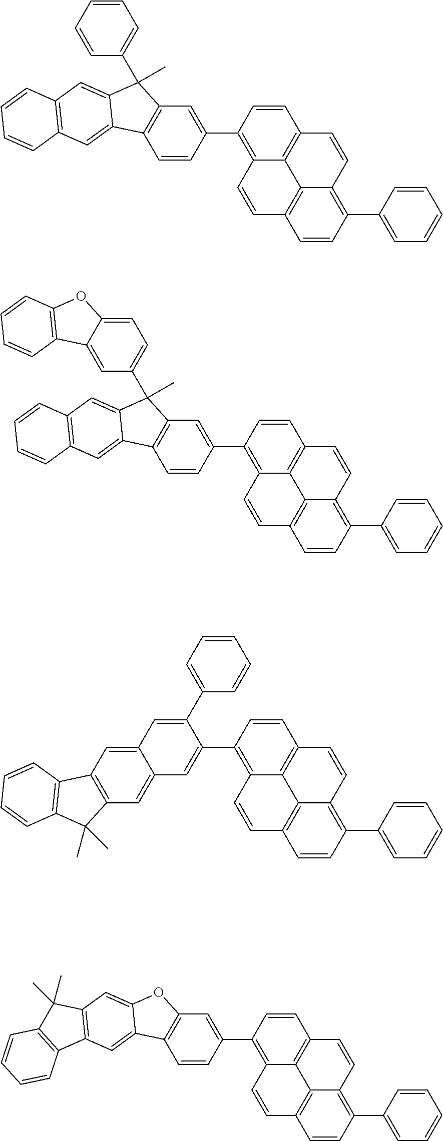

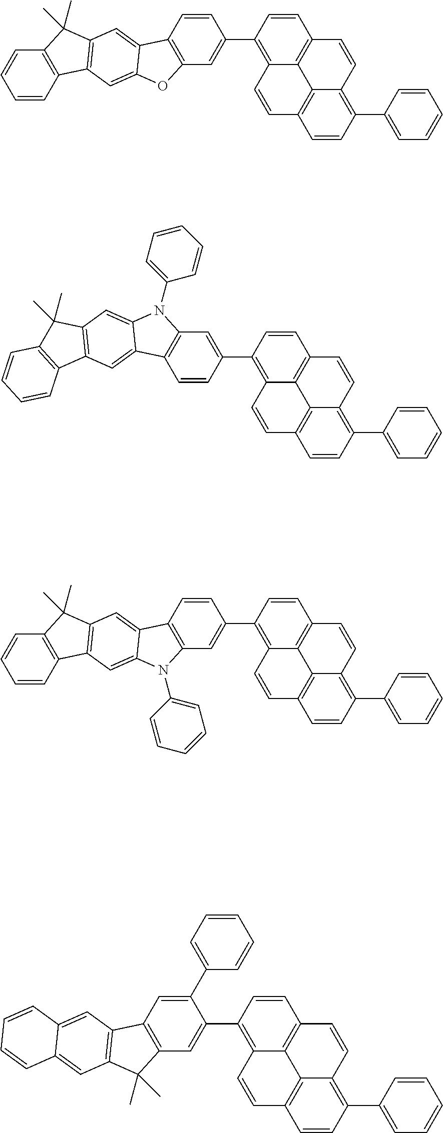

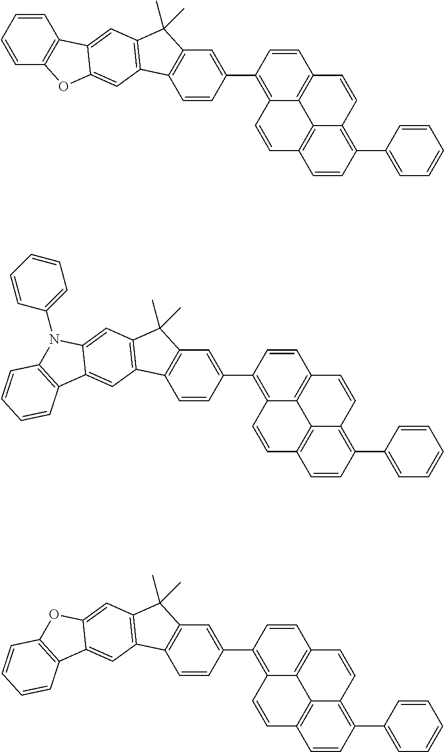 [SMILES: CC1(C)c2cc(-c3ccc4ccc5c(-c6ccccc6)ccc6ccc3c4c65)ccc2-c2cc3oc4ccccc4c3cc21 ; CC1(C)c2cc(-c3ccc4ccc5c(-c6ccccc6)ccc6ccc3c4c65)ccc2-c2cc3c4ccccc4n(-c4ccccc4)c3cc21 ; CC1(C)c2cc(-c3ccc4ccc5c(-c6ccccc6)ccc6ccc3c4c65)ccc2-c2cc3c(cc21)oc1ccccc13]

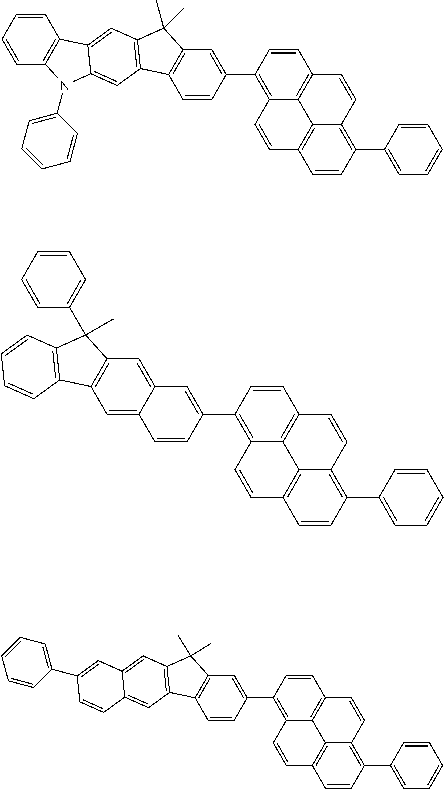

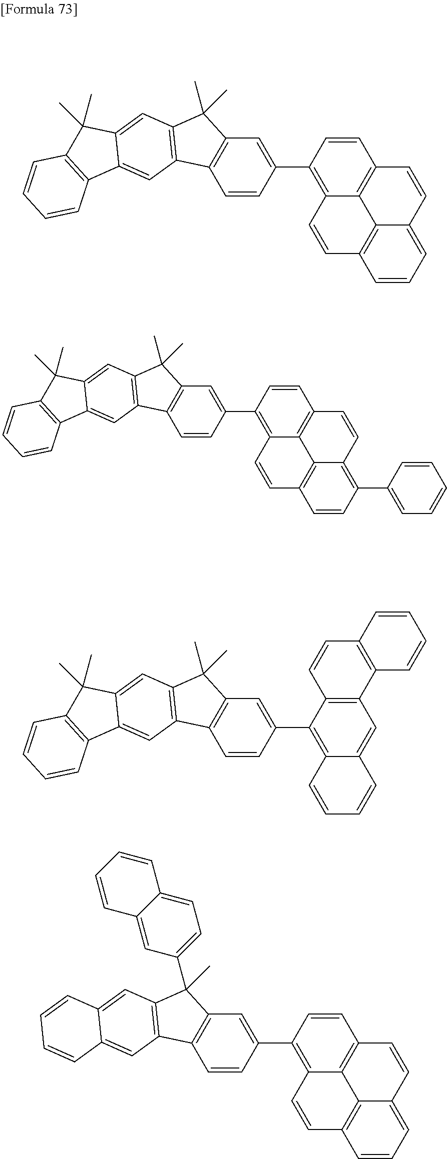

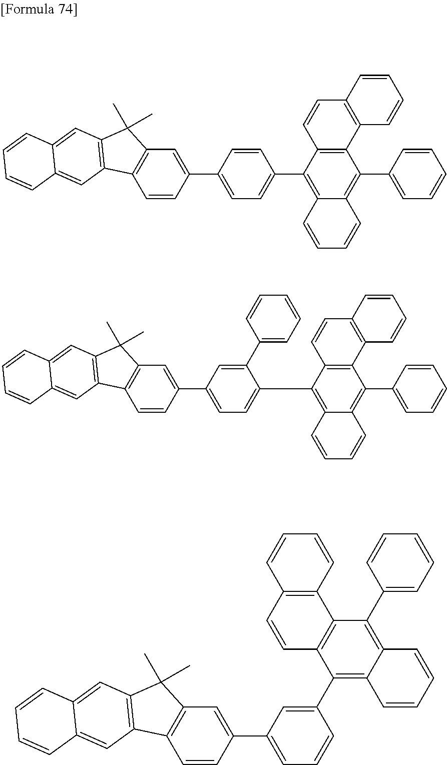

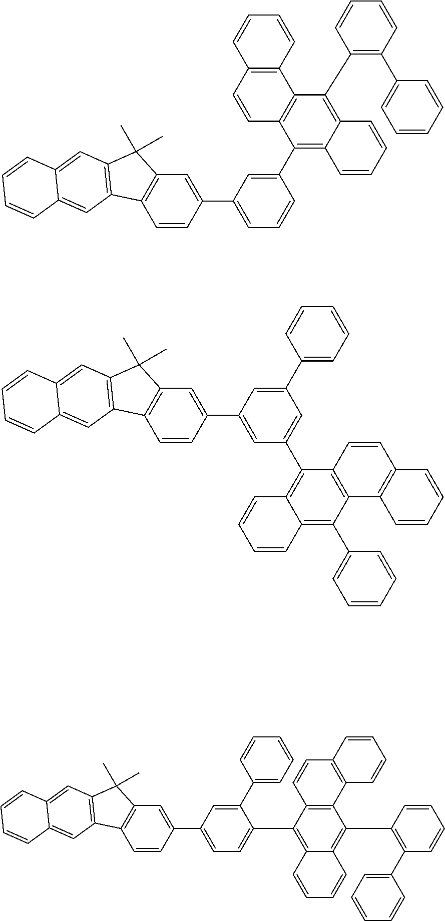

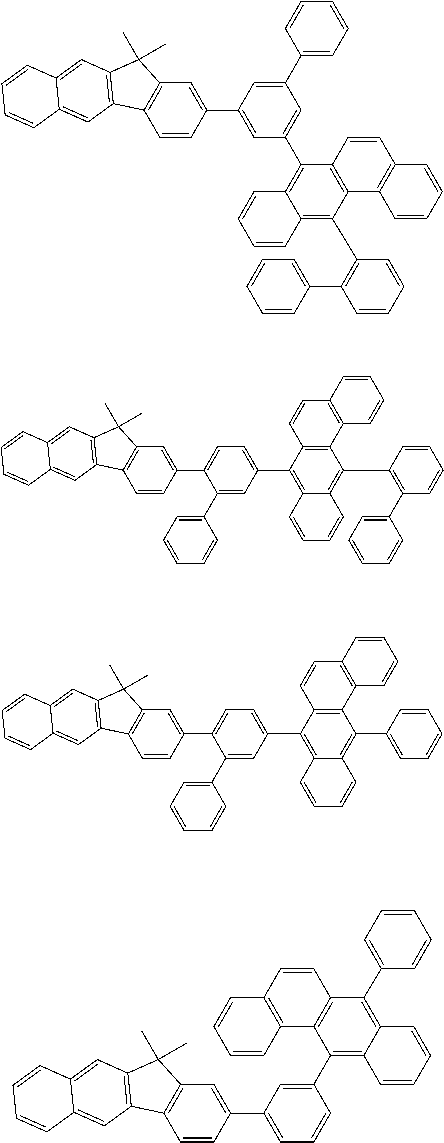

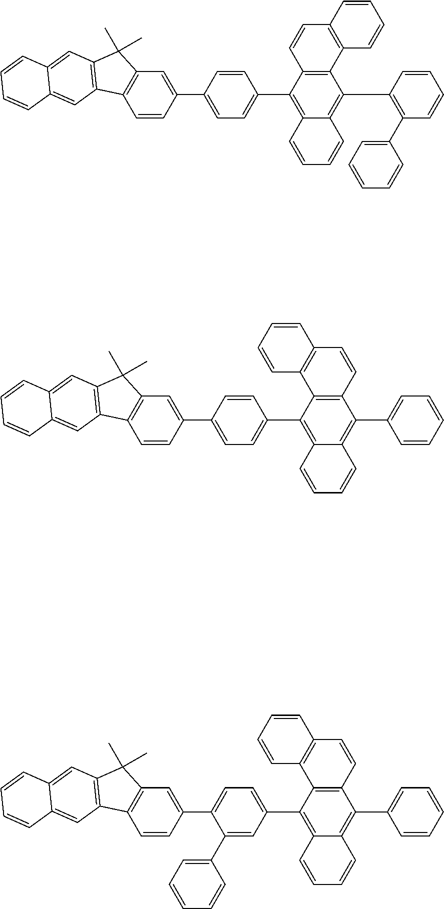

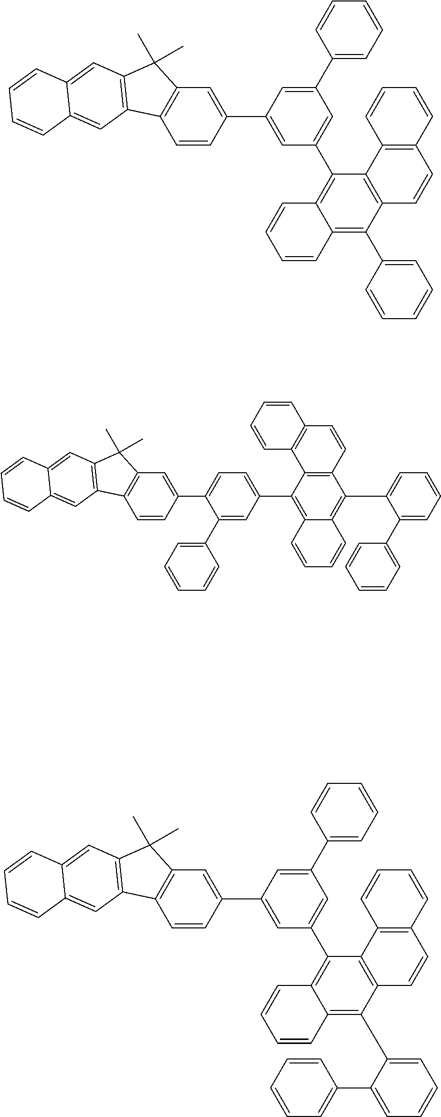

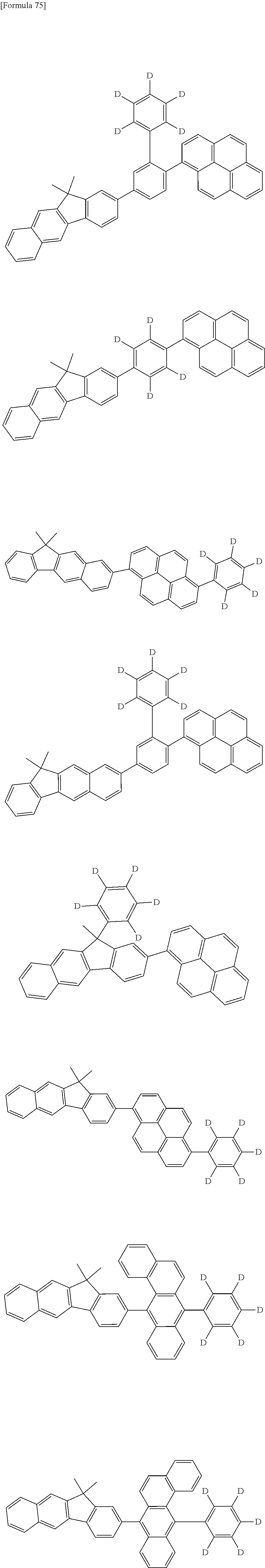

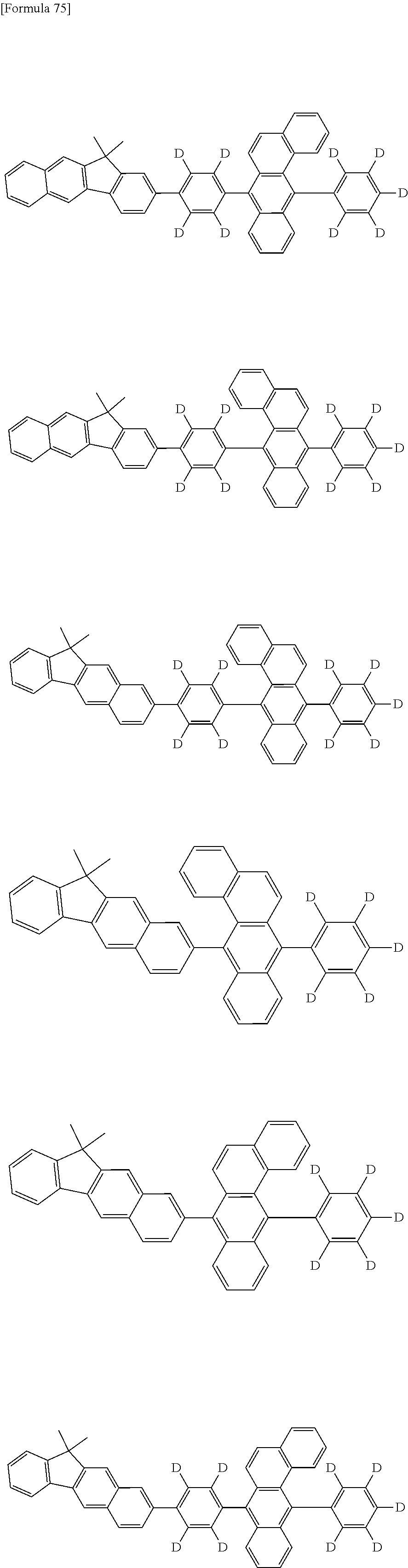

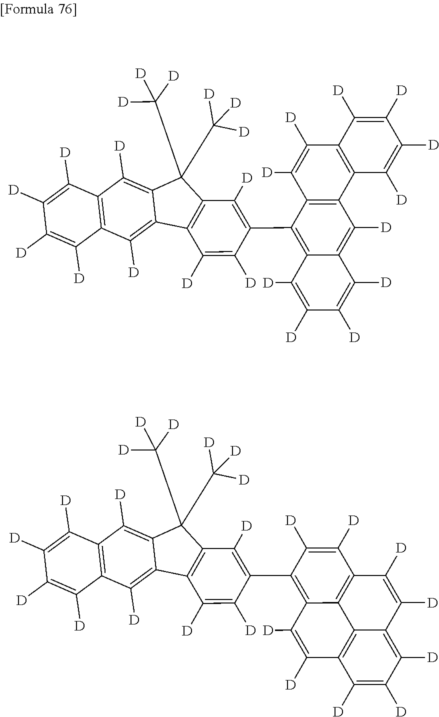 [SMILES: [2H]c1c([2H])c2c(c([2H])c1-c1c3c([2H])c([2H])c([2H])c([2H])c3c([2H])c3c1c([2H])c([2H])c1c([2H])c([2H])c([2H])c([2H])c13)C(C([2H])([2H])[2H])(C([2H])([2H])[2H])c1c-2c([2H])c2c([2H])c([2H])c([2H])c([2H])c2c1[2H] ; [2H]c1c([2H])c2c(c([2H])c1-c1c([2H])c([2H])c3c([2H])c([2H])c4c([2H])c([2H])c([2H])c5c([2H])c([2H])c1c3c45)C(C([2H])([2H])[2H])(C([2H])([2H])[2H])c1c-2c([2H])c2c([2H])c([2H])c([2H])c([2H])c2c1[2H]]

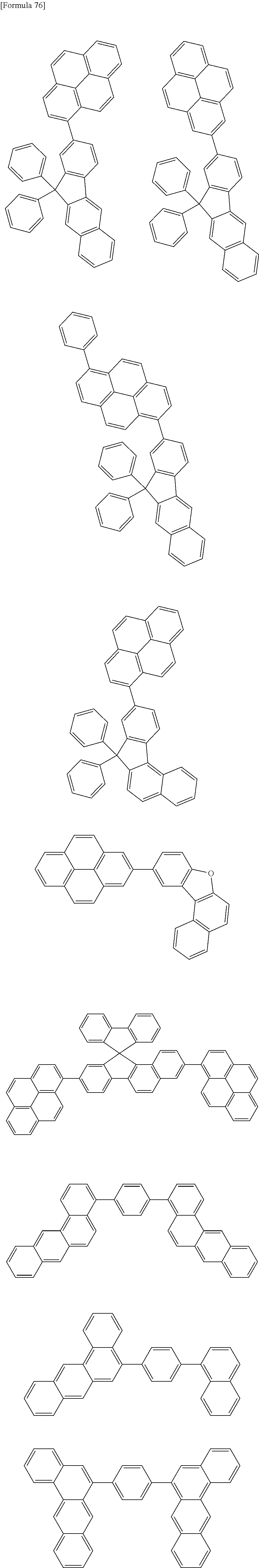

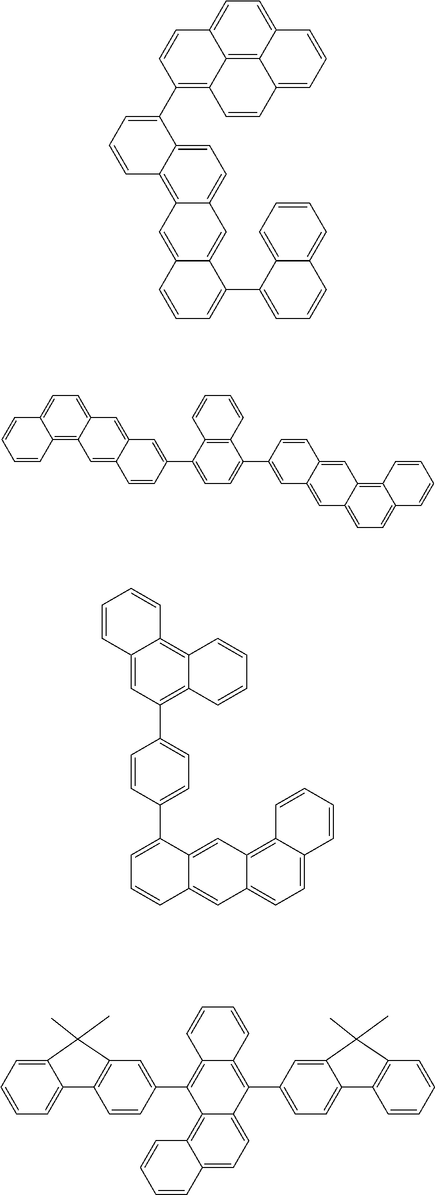

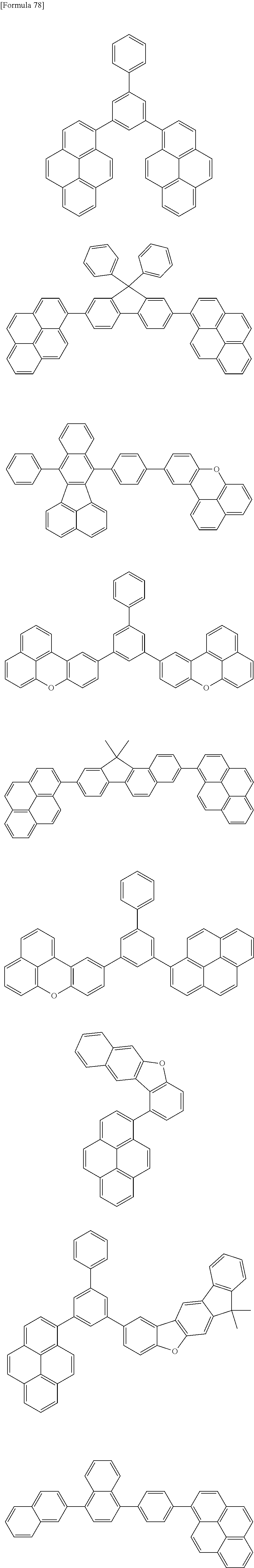

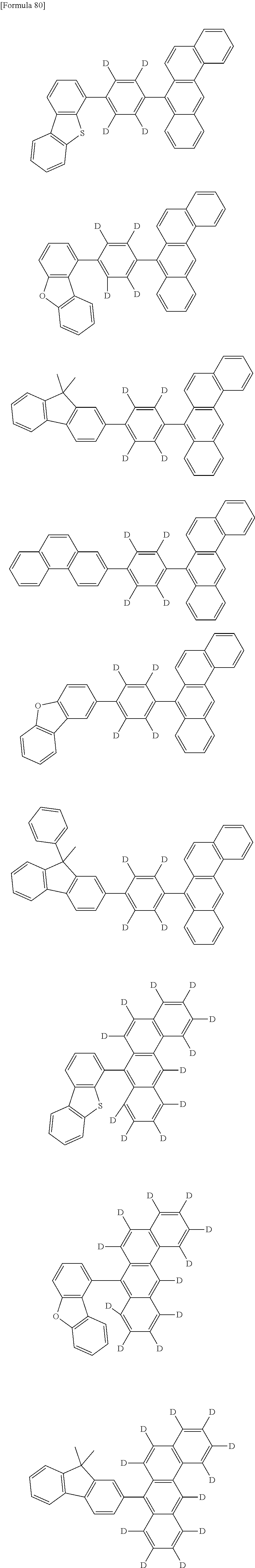

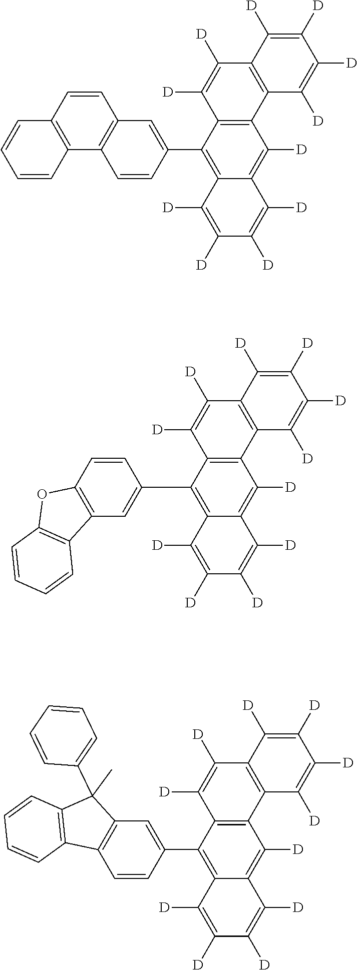 [SMILES: [2H]c1c([2H])c([2H])c2c([2H])c3c(c([2H])c([2H])c4c([2H])c([2H])c([2H])c([2H])c43)c(-c3ccc4c(ccc5ccccc54)c3)c2c1[2H] ; [2H]c1c([2H])c([2H])c2c([2H])c3c(c([2H])c([2H])c4c([2H])c([2H])c([2H])c([2H])c43)c(-c3ccc4oc5ccccc5c4c3)c2c1[2H] ; [2H]c1c([2H])c([2H])c2c([2H])c3c(c([2H])c([2H])c4c([2H])c([2H])c([2H])c([2H])c43)c(-c3ccc4c(c3)C(C)(c3ccccc3)c3ccccc3-4)c2c1[2H]]

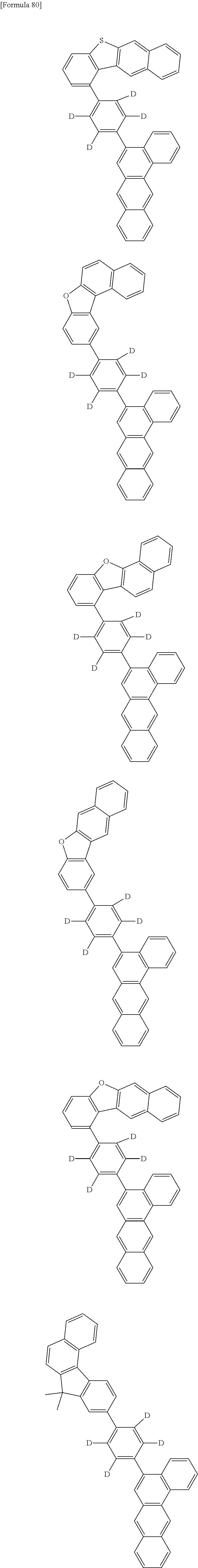

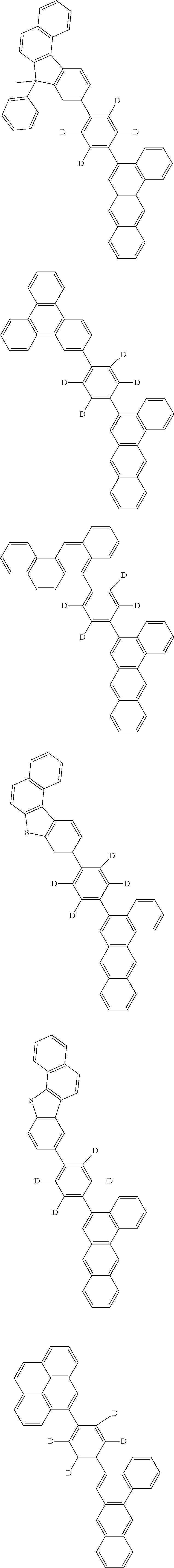

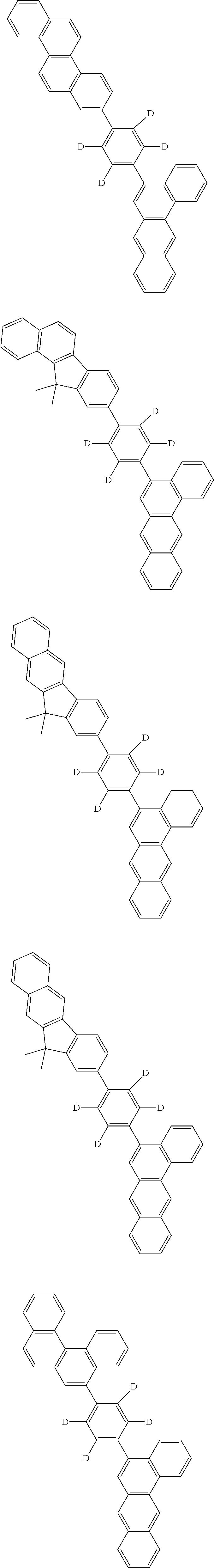 [SMILES: [2H]c1c([2H])c(-c2cc3cc4ccccc4cc3c3ccccc23)c([2H])c([2H])c1-c1ccc2c(ccc3c4ccccc4ccc23)c1 ; [2H]c1c([2H])c(-c2cc3cc4ccccc4cc3c3ccccc23)c([2H])c([2H])c1-c1ccc2c(c1)C(C)(C)c1c-2ccc2ccccc12 ; [2H]c1c([2H])c(-c2cc3cc4ccccc4cc3c3ccccc23)c([2H])c([2H])c1-c1ccc2c(c1)C(C)(C)c1cc3ccccc3cc1-2 ; [2H]c1c([2H])c(-c2cc3cc4ccccc4cc3c3ccccc23)c([2H])c([2H])c1-c1ccc2c(c1)C(C)(C)c1cc3ccccc3cc1-2 ; [2H]c1c([2H])c(-c2cc3ccc4ccccc4c3c3ccccc23)c([2H])c([2H])c1-c1cc2cc3ccccc3cc2c2ccccc12]

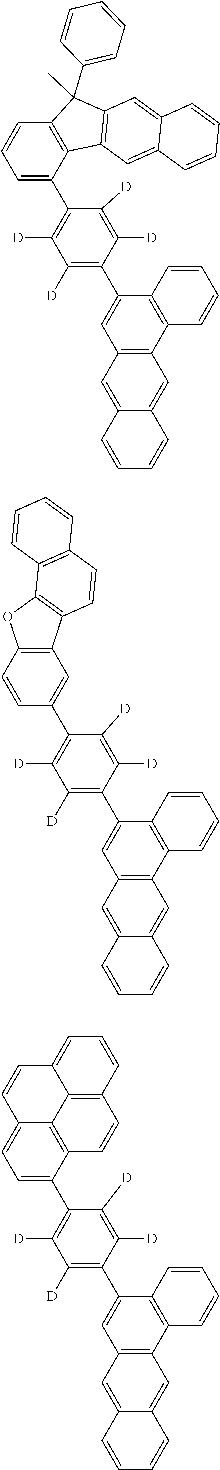

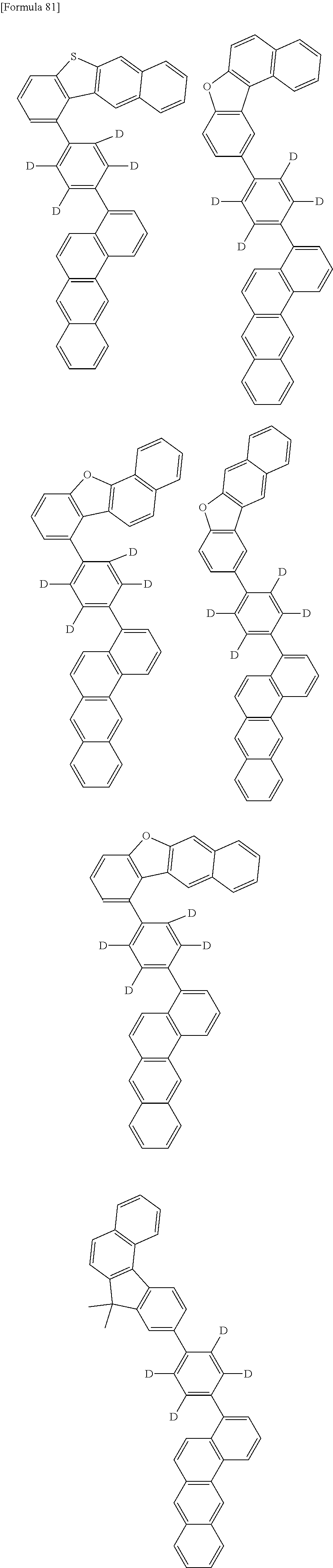

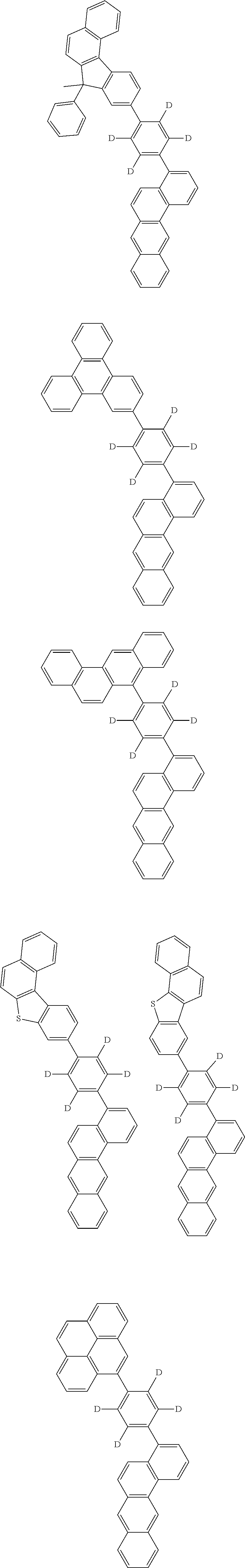

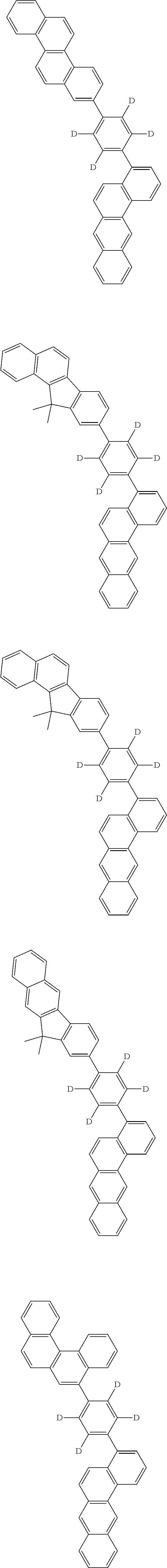 [SMILES: [2H]c1c([2H])c(-c2cccc3c2ccc2cc4ccccc4cc23)c([2H])c([2H])c1-c1ccc2c(ccc3c4ccccc4ccc23)c1 ; [2H]c1c([2H])c(-c2cccc3c2ccc2cc4ccccc4cc23)c([2H])c([2H])c1-c1ccc2c(c1)C(C)(C)c1c-2ccc2ccccc12 ; [2H]c1c([2H])c(-c2cccc3c2ccc2cc4ccccc4cc23)c([2H])c([2H])c1-c1ccc2c(c1)C(C)(C)c1c-2ccc2ccccc12 ; [2H]c1c([2H])c(-c2cccc3c2ccc2cc4ccccc4cc23)c([2H])c([2H])c1-c1ccc2c(c1)C(C)(C)c1cc3ccccc3cc1-2 ; [2H]c1c([2H])c(-c2cc3ccc4ccccc4c3c3ccccc23)c([2H])c([2H])c1-c1cccc2c1ccc1cc3ccccc3cc12]

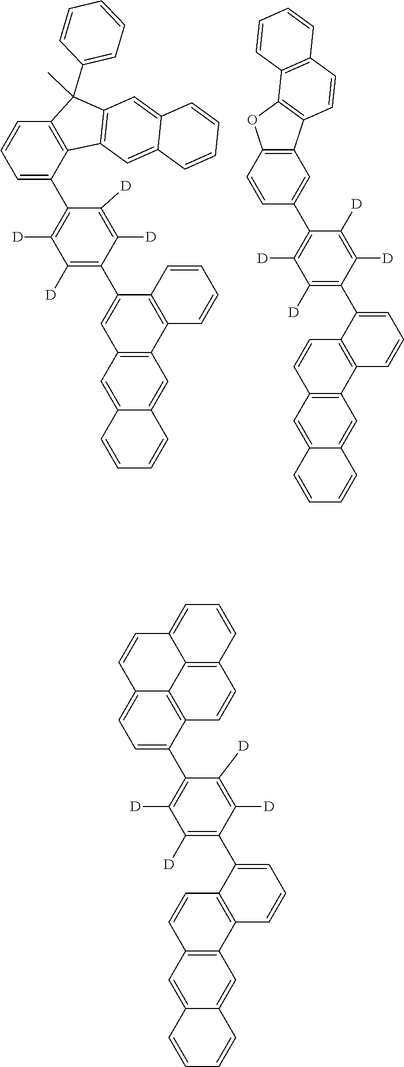

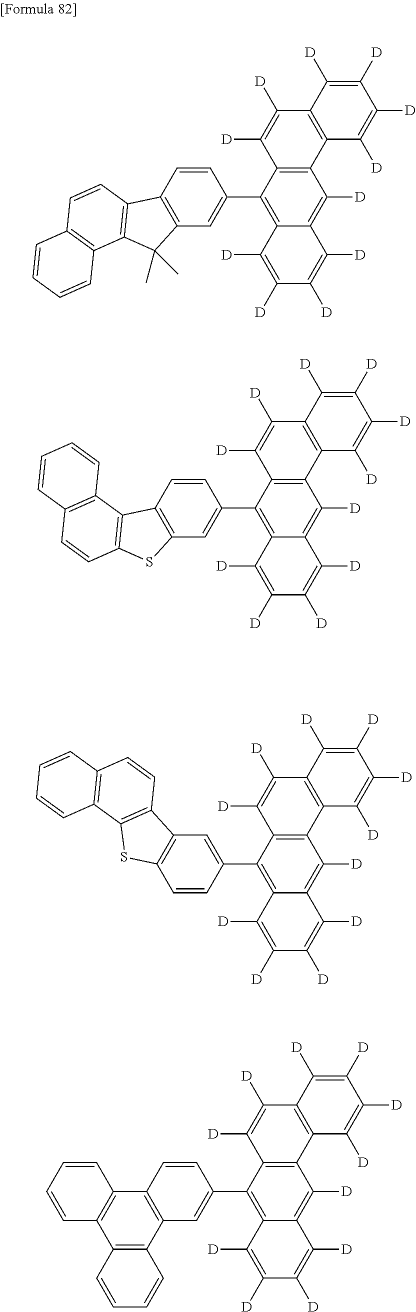 [SMILES: [2H]c1c([2H])c([2H])c2c([2H])c3c(c([2H])c([2H])c4c([2H])c([2H])c([2H])c([2H])c43)c(-c3ccc4c(c3)C(C)(C)c3c-4ccc4ccccc34)c2c1[2H] ; [2H]c1c([2H])c([2H])c2c([2H])c3c(c([2H])c([2H])c4c([2H])c([2H])c([2H])c([2H])c43)c(-c3ccc4c(c3)sc3ccc5ccccc5c34)c2c1[2H] ; [2H]c1c([2H])c([2H])c2c([2H])c3c(c([2H])c([2H])c4c([2H])c([2H])c([2H])c([2H])c43)c(-c3ccc4sc5c6ccccc6ccc5c4c3)c2c1[2H] ; [2H]c1c([2H])c([2H])c2c([2H])c3c(c([2H])c([2H])c4c([2H])c([2H])c([2H])c([2H])c43)c(-c3ccc4c5ccccc5c5ccccc5c4c3)c2c1[2H]]

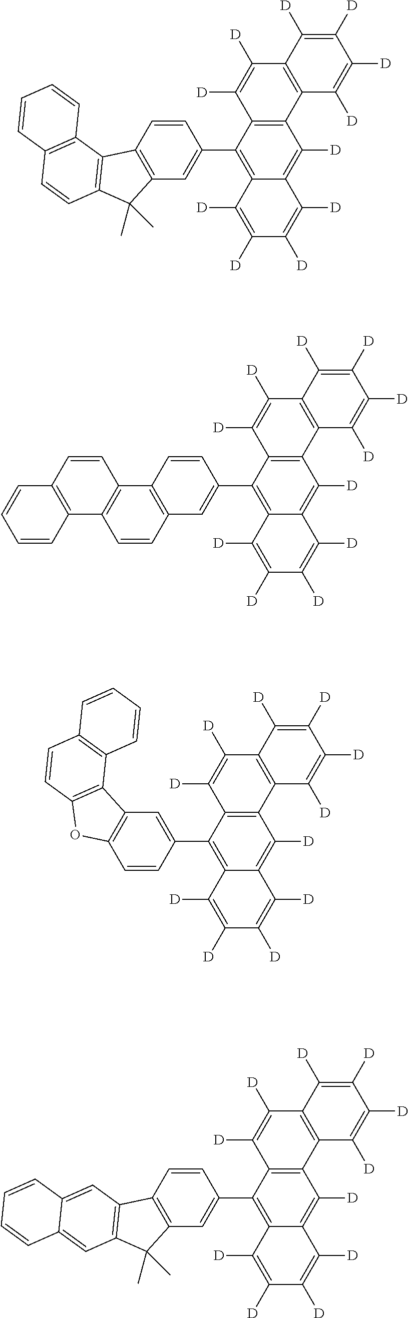

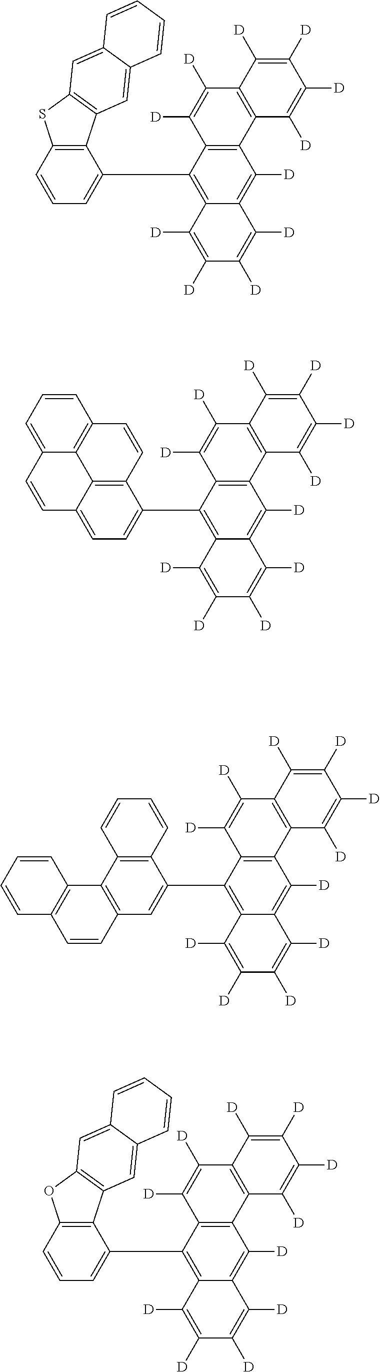 [SMILES: [2H]c1c([2H])c([2H])c2c([2H])c3c(c([2H])c([2H])c4c([2H])c([2H])c([2H])c([2H])c43)c(-c3cccc4sc5cc6ccccc6cc5c34)c2c1[2H] ; [2H]c1c([2H])c([2H])c2c([2H])c3c(c([2H])c([2H])c4c([2H])c([2H])c([2H])c([2H])c43)c(-c3ccc4ccc5cccc6ccc3c4c56)c2c1[2H] ; [2H]c1c([2H])c([2H])c2c([2H])c3c(c([2H])c([2H])c4c([2H])c([2H])c([2H])c([2H])c43)c(-c3cc4ccc5ccccc5c4c4ccccc34)c2c1[2H] ; [2H]c1c([2H])c([2H])c2c([2H])c3c(c([2H])c([2H])c4c([2H])c([2H])c([2H])c([2H])c43)c(-c3cccc4oc5cc6ccccc6cc5c34)c2c1[2H]]

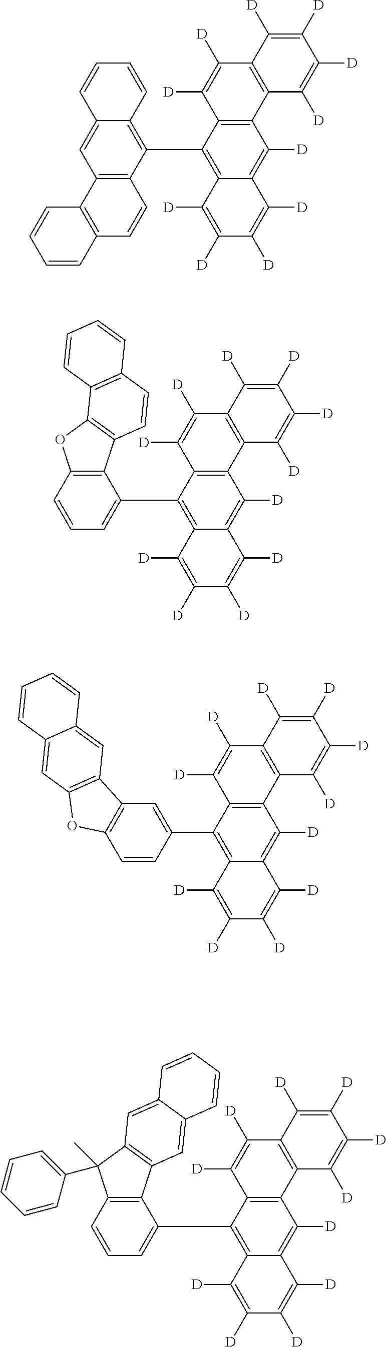 [SMILES: [2H]c1c([2H])c([2H])c2c([2H])c3c(c([2H])c([2H])c4c([2H])c([2H])c([2H])c([2H])c43)c(-c3c4ccccc4cc4c3ccc3ccccc34)c2c1[2H] ; [2H]c1c([2H])c([2H])c2c([2H])c3c(c([2H])c([2H])c4c([2H])c([2H])c([2H])c([2H])c43)c(-c3cccc4oc5c6ccccc6ccc5c34)c2c1[2H] ; [2H]c1c([2H])c([2H])c2c([2H])c3c(c([2H])c([2H])c4c([2H])c([2H])c([2H])c([2H])c43)c(-c3ccc4oc5cc6ccccc6cc5c4c3)c2c1[2H] ; [2H]c1c([2H])c([2H])c2c([2H])c3c(c([2H])c([2H])c4c([2H])c([2H])c([2H])c([2H])c43)c(-c3cccc4c3-c3cc5ccccc5cc3C4(C)c3ccccc3)c2c1[2H]]

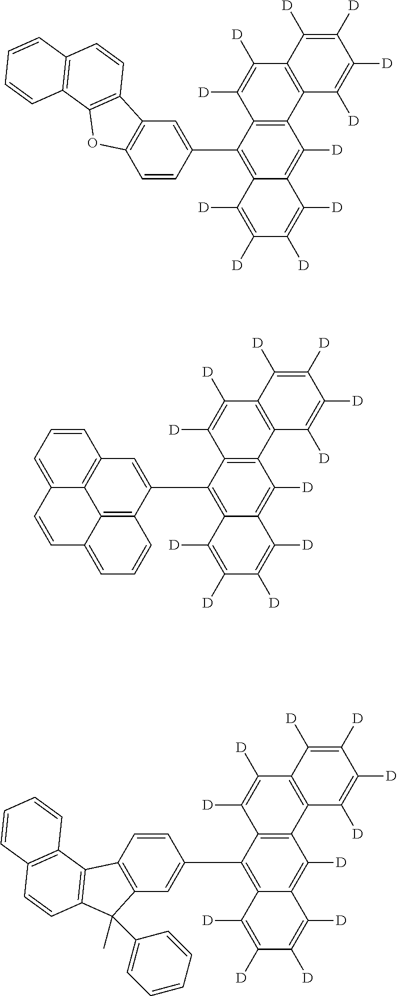 [SMILES: [2H]c1c([2H])c([2H])c2c([2H])c3c(c([2H])c([2H])c4c([2H])c([2H])c([2H])c([2H])c43)c(-c3ccc4oc5c6ccccc6ccc5c4c3)c2c1[2H] ; [2H]c1c([2H])c([2H])c2c([2H])c3c(c([2H])c([2H])c4c([2H])c([2H])c([2H])c([2H])c43)c(-c3cc4cccc5ccc6cccc3c6c54)c2c1[2H] ; [2H]c1c([2H])c([2H])c2c([2H])c3c(c([2H])c([2H])c4c([2H])c([2H])c([2H])c([2H])c43)c(-c3ccc4c(c3)C(C)(c3ccccc3)c3ccc5ccccc5c3-4)c2c1[2H]]

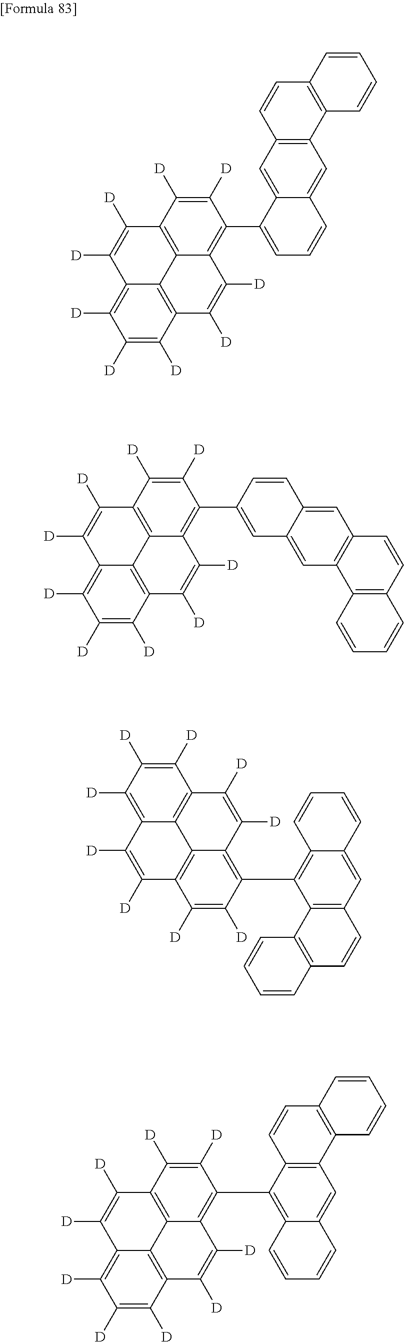 [SMILES: [2H]c1c([2H])c2c([2H])c([2H])c3c([2H])c([2H])c(-c4cccc5cc6c(ccc7ccccc76)cc45)c4c([2H])c([2H])c(c1[2H])c2c34 ; [2H]c1c([2H])c2c([2H])c([2H])c3c([2H])c([2H])c(-c4ccc5cc6ccc7ccccc7c6cc5c4)c4c([2H])c([2H])c(c1[2H])c2c34 ; [2H]c1c([2H])c2c([2H])c([2H])c3c([2H])c([2H])c(-c4c5ccccc5cc5ccc6ccccc6c45)c4c([2H])c([2H])c(c1[2H])c2c34 ; [2H]c1c([2H])c2c([2H])c([2H])c3c([2H])c([2H])c(-c4c5ccccc5cc5c4ccc4ccccc45)c4c([2H])c([2H])c(c1[2H])c2c34]

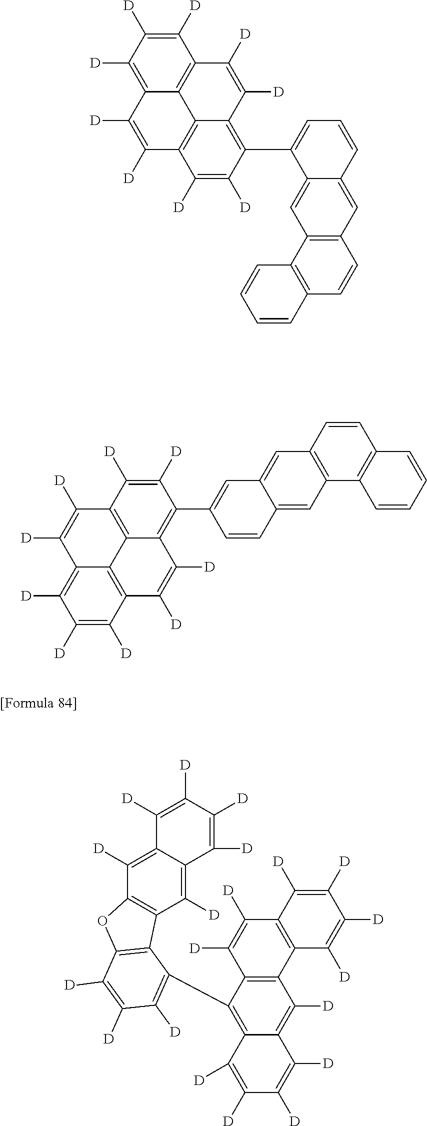 [SMILES: [2H]c1c([2H])c2c([2H])c([2H])c3c([2H])c([2H])c(-c4cccc5cc6ccc7ccccc7c6cc45)c4c([2H])c([2H])c(c1[2H])c2c34 ; [2H]c1c([2H])c2c([2H])c([2H])c3c([2H])c([2H])c(-c4ccc5cc6c(ccc7ccccc76)cc5c4)c4c([2H])c([2H])c(c1[2H])c2c34 ; [2H]c1c([2H])c(-c2c3c([2H])c([2H])c([2H])c([2H])c3c([2H])c3c2c([2H])c([2H])c2c([2H])c([2H])c([2H])c([2H])c23)c2c(oc3c([2H])c4c([2H])c([2H])c([2H])c([2H])c4c([2H])c32)c1[2H]]

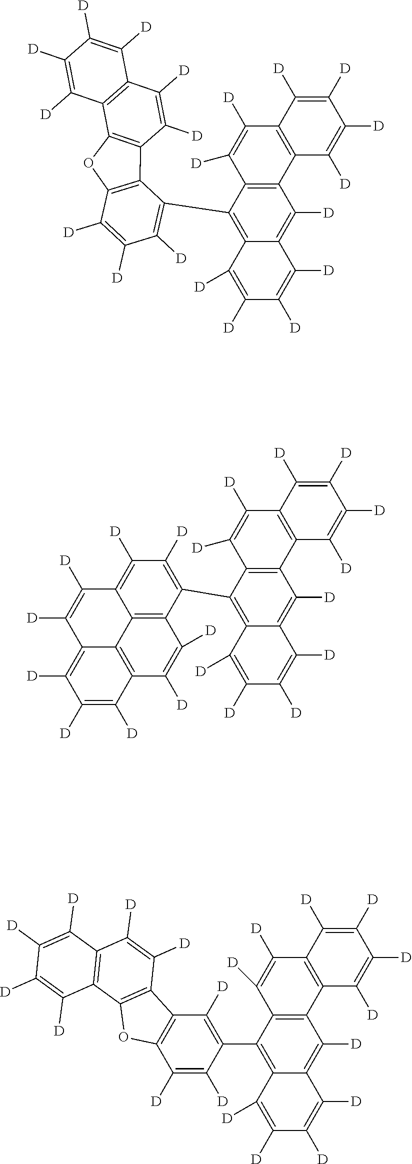

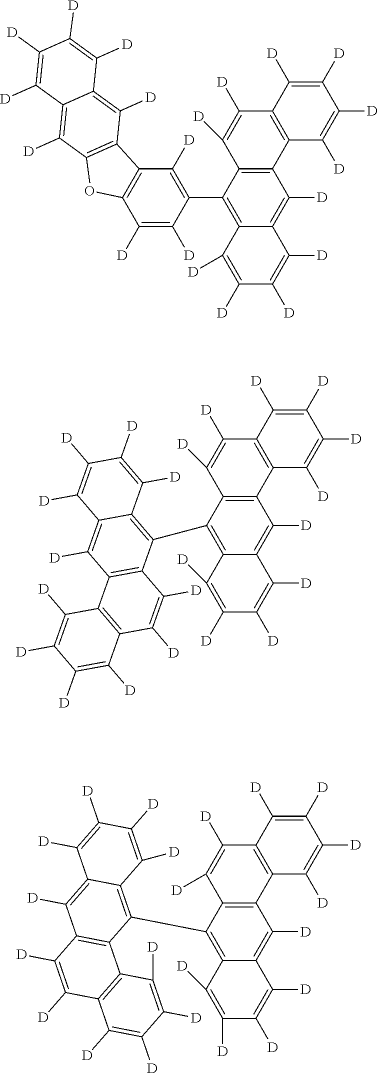

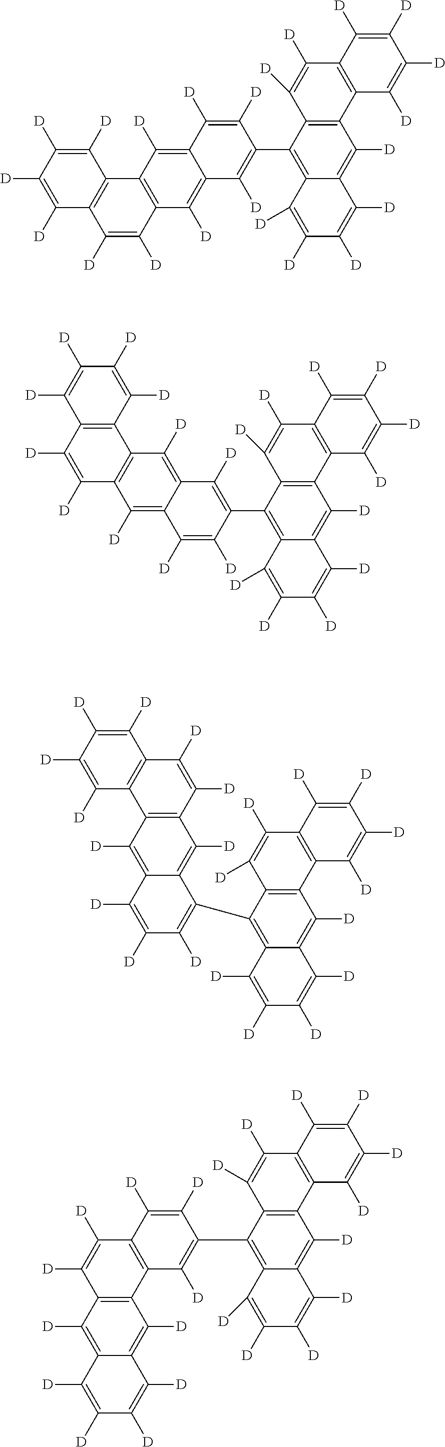

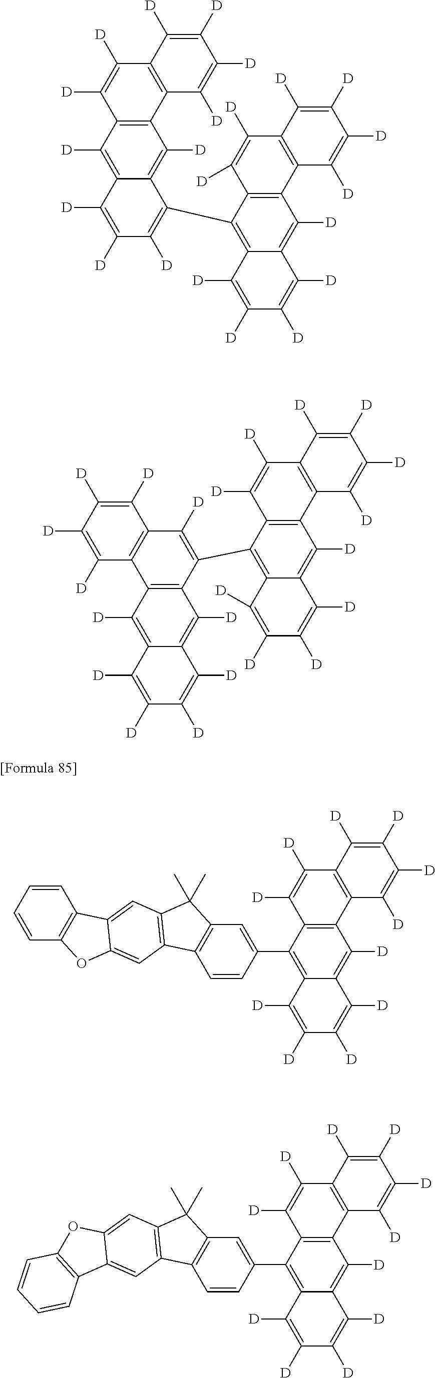

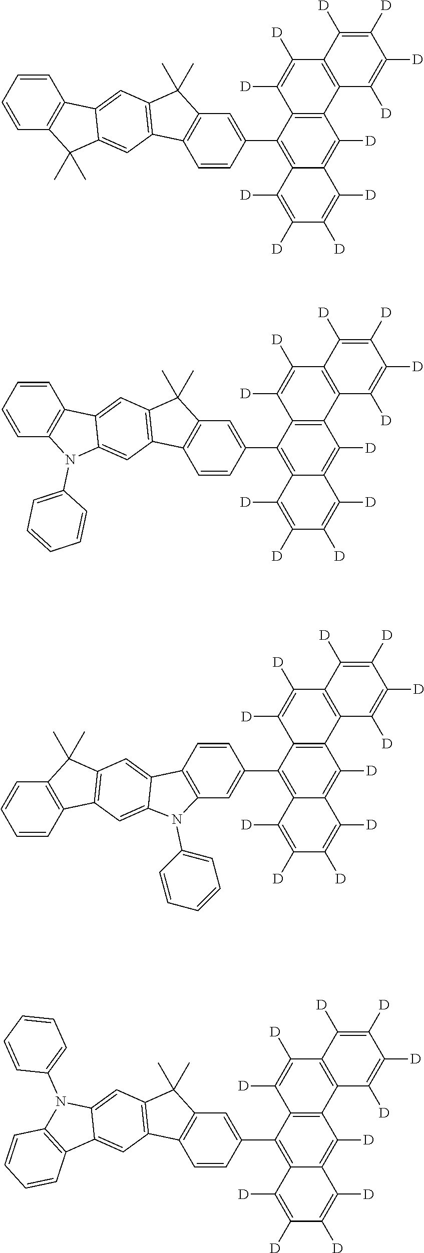

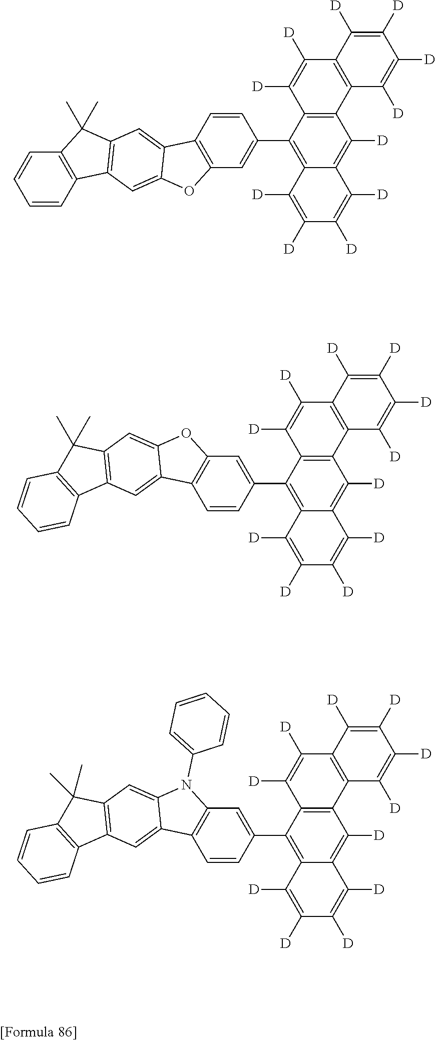 [SMILES: [2H]c1c([2H])c([2H])c2c([2H])c3c(c([2H])c([2H])c4c([2H])c([2H])c([2H])c([2H])c43)c(-c3ccc4c(c3)oc3cc5c(cc34)C(C)(C)c3ccccc3-5)c2c1[2H] ; [2H]c1c([2H])c([2H])c2c([2H])c3c(c([2H])c([2H])c4c([2H])c([2H])c([2H])c([2H])c43)c(-c3ccc4c(c3)oc3cc5c(cc34)-c3ccccc3C5(C)C)c2c1[2H] ; [2H]c1c([2H])c([2H])c2c([2H])c3c(c([2H])c([2H])c4c([2H])c([2H])c([2H])c([2H])c43)c(-c3ccc4c5cc6c(cc5n(-c5ccccc5)c4c3)C(C)(C)c3ccccc3-6)c2c1[2H]]

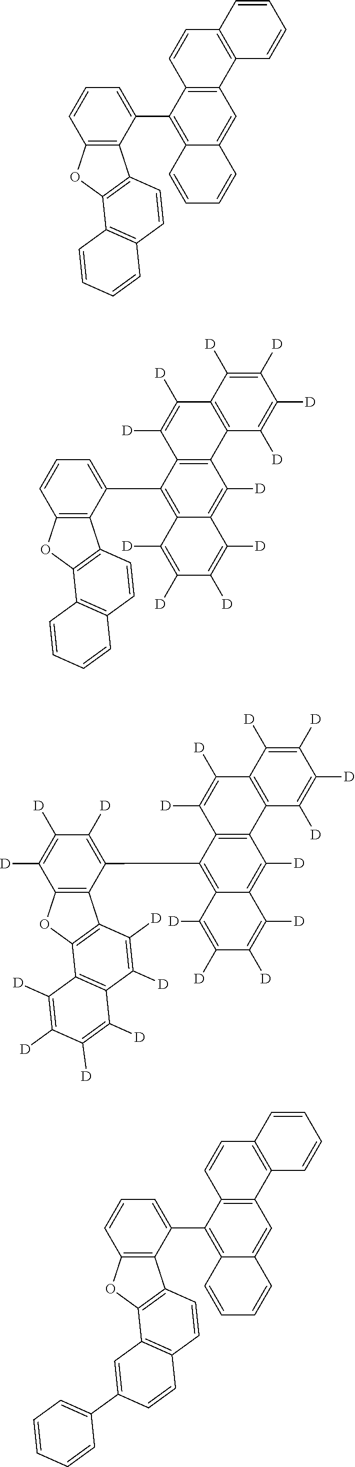 [SMILES: c1ccc2c(-c3cccc4oc5c6ccccc6ccc5c34)c3ccc4ccccc4c3cc2c1 ; [2H]c1c([2H])c([2H])c2c([2H])c3c(c([2H])c([2H])c4c([2H])c([2H])c([2H])c([2H])c43)c(-c3cccc4oc5c6ccccc6ccc5c34)c2c1[2H] ; [2H]c1c([2H])c(-c2c3c([2H])c([2H])c([2H])c([2H])c3c([2H])c3c2c([2H])c([2H])c2c([2H])c([2H])c([2H])c([2H])c23)c2c(oc3c4c([2H])c([2H])c([2H])c([2H])c4c([2H])c([2H])c32)c1[2H] ; c1ccc(-c2ccc3ccc4c(oc5cccc(-c6c7ccccc7cc7c6ccc6ccccc67)c54)c3c2)cc1]

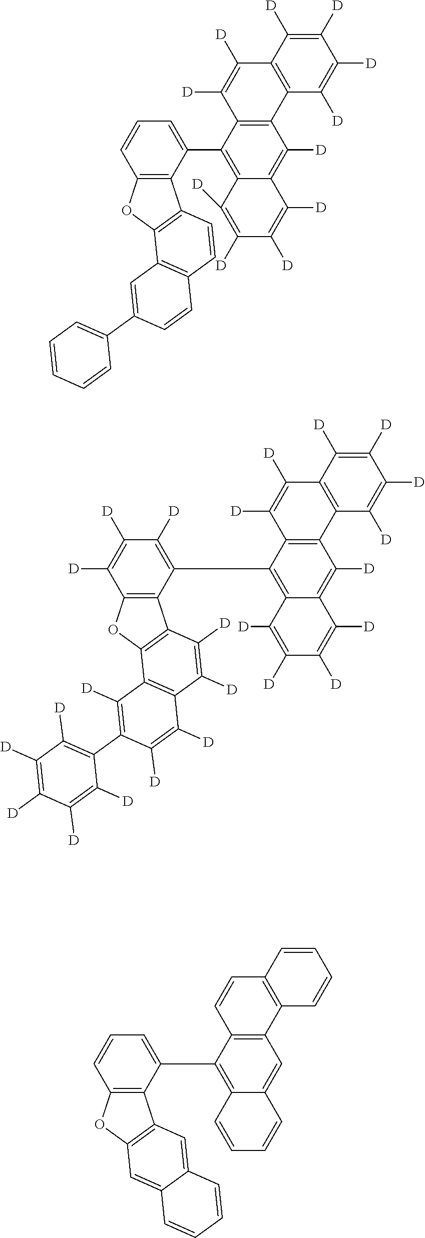 [SMILES: [2H]c1c([2H])c([2H])c2c([2H])c3c(c([2H])c([2H])c4c([2H])c([2H])c([2H])c([2H])c43)c(-c3cccc4oc5c6cc(-c7ccccc7)ccc6ccc5c34)c2c1[2H] ; [2H]c1c([2H])c([2H])c(-c2c([2H])c([2H])c3c([2H])c([2H])c4c(oc5c([2H])c([2H])c([2H])c(-c6c7c([2H])c([2H])c([2H])c([2H])c7c([2H])c7c6c([2H])c([2H])c6c([2H])c([2H])c([2H])c([2H])c67)c54)c3c2[2H])c([2H])c1[2H] ; c1ccc2cc3c(cc2c1)oc1cccc(-c2c4ccccc4cc4c2ccc2ccccc24)c13]

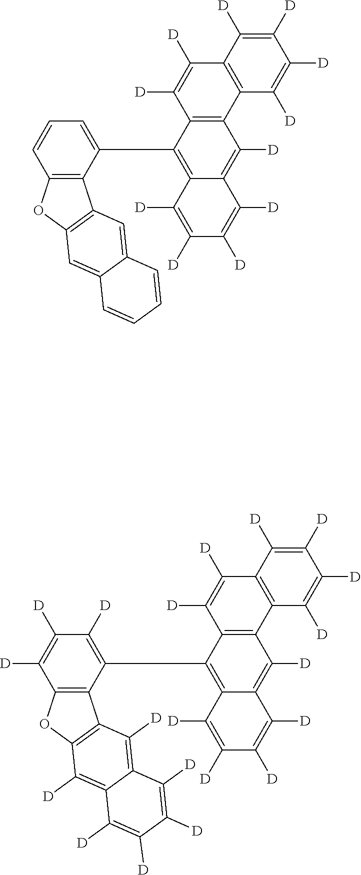 [SMILES: [2H]c1c([2H])c([2H])c2c([2H])c3c(c([2H])c([2H])c4c([2H])c([2H])c([2H])c([2H])c43)c(-c3cccc4oc5cc6ccccc6cc5c34)c2c1[2H] ; [2H]c1c([2H])c(-c2c3c([2H])c([2H])c([2H])c([2H])c3c([2H])c3c2c([2H])c([2H])c2c([2H])c([2H])c([2H])c([2H])c23)c2c(oc3c([2H])c4c([2H])c([2H])c([2H])c([2H])c4c([2H])c32)c1[2H]]

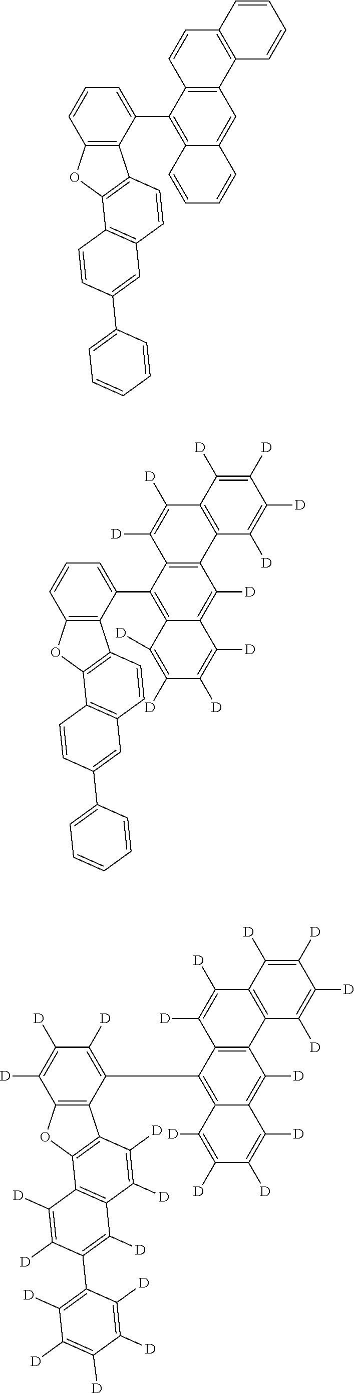 [SMILES: c1ccc(-c2ccc3c(ccc4c3oc3cccc(-c5c6ccccc6cc6c5ccc5ccccc56)c34)c2)cc1 ; [2H]c1c([2H])c([2H])c2c([2H])c3c(c([2H])c([2H])c4c([2H])c([2H])c([2H])c([2H])c43)c(-c3cccc4oc5c6ccc(-c7ccccc7)cc6ccc5c34)c2c1[2H] ; [2H]c1c([2H])c([2H])c(-c2c([2H])c([2H])c3c(c2[2H])c([2H])c([2H])c2c3oc3c([2H])c([2H])c([2H])c(-c4c5c([2H])c([2H])c([2H])c([2H])c5c([2H])c5c4c([2H])c([2H])c4c([2H])c([2H])c([2H])c([2H])c45)c32)c([2H])c1[2H]]

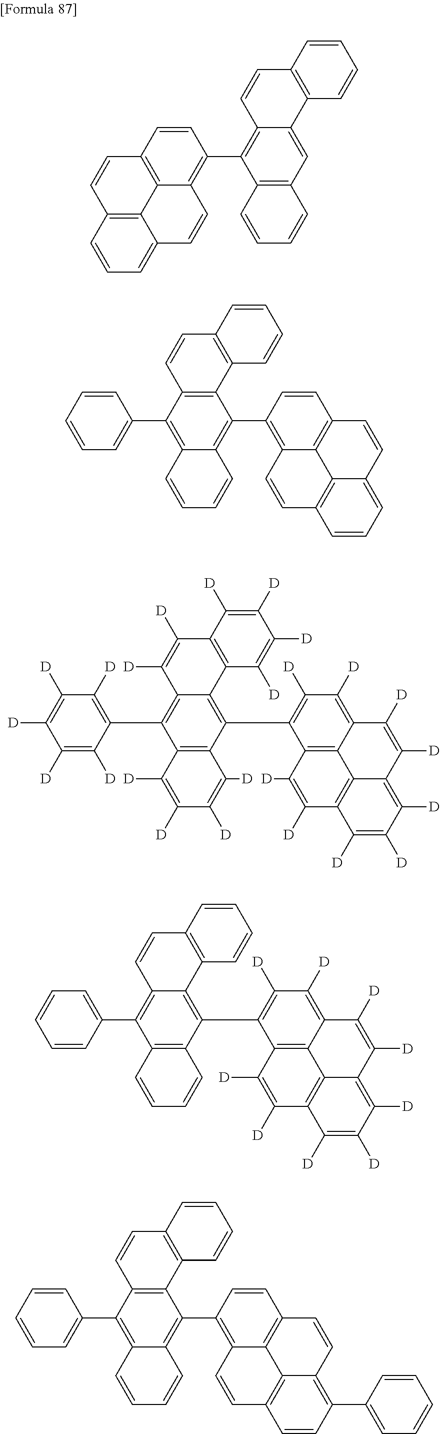

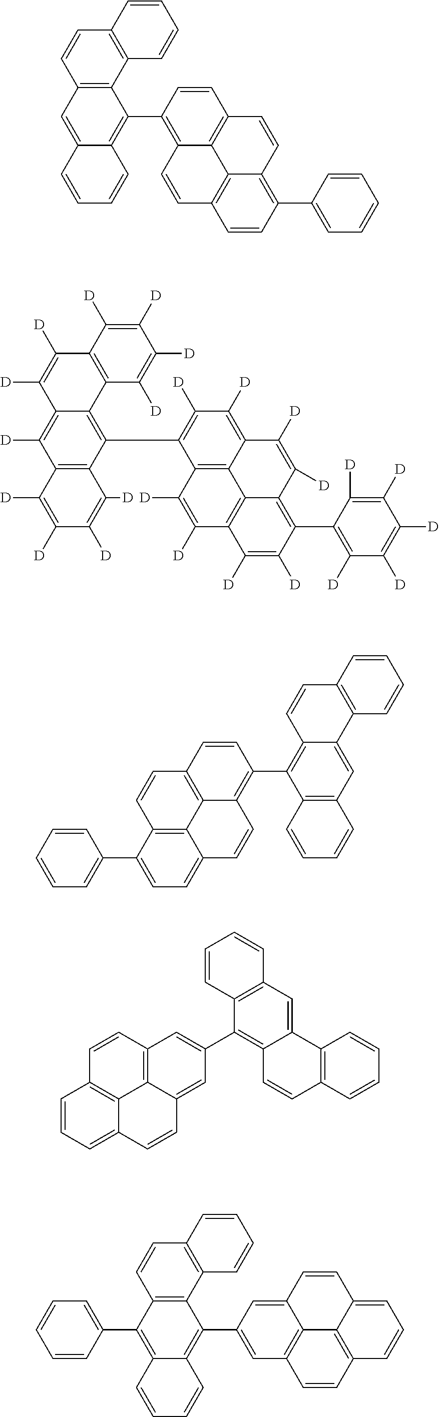

### Second Host Material

In an exemplary arrangement of the organic EL device according to the exemplary embodiment, the second host material is preferably the second compound. In the organic EL device according to the exemplary embodiment, the second host material, which is not particularly limited, is exemplified by the second compound represented by a formula (2) below.

### Second Compound

In the organic EL device according to the exemplary embodiment, the second compound is preferably a compound represented by the formula (2) below. The second host material is preferably the second compound represented by the formula (2) below.

### Compound Represented by Formula (2)

The compound represented by the formula (2) will be described.

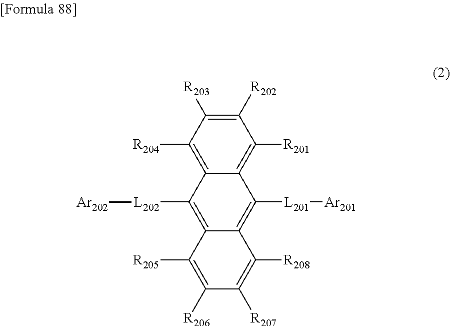

In the formula (2):
R₂₀₁ to R₂₀₈ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
L₂₀₁ and L₂₀₂ are each independently a single bond, a substituted or unsubstituted arylene group having 6 to 50 ring carbon atoms, or a substituted or unsubstituted divalent heterocyclic group having 5 to 50 ring atoms; and
Ar₂₀₁ and Ar₂₀₂ are each independently a substituted or unsubstituted aryl group having 6 to 50 ring carbon atoms, or a substituted or unsubstituted heterocyclic group having 5 to 50 ring atoms.

In the second compound, R₉₀₁, R₉₀₂, R₉₀₃, R₉₀₄, R₉₀₅, R₉₀₆, R₉₀₇, R₈₀₁ and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

In the organic EL device according to the exemplary embodiment, it is preferable that:
R₂₀₁ to R₂₀₈ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a cyano group, or a nitro group;
L₂₀₁ and L₂₀₂ are each independently a single bond, a substituted or unsubstituted arylene group having 6 to 50 ring carbon atoms, or a substituted or unsubstituted divalent heterocyclic group having 5 to 50 ring atoms; and
Ar₂₀₁ and Ar₂₀₂ are each independently a substituted or unsubstituted aryl group having 6 to 50 ring carbon atoms, or a substituted or unsubstituted heterocyclic group having 5 to 50 ring atoms.

In the organic EL device according to the exemplary embodiment, L₂₀₁ and L₂₀₂ are preferably each independently a single bond or a substituted or unsubstituted arylene group having 6 to 50 ring carbon atoms, and Ar₂₀₁ and Ar₂₀₂ are preferably each independently a substituted or unsubstituted aryl group having 6 to 50 ring carbon atoms.

In the organic EL device according to the exemplary embodiment, Ar₂₀₁ and Ar₂₀₂ are preferably each independently a phenyl group, a naphthyl group, a phenanthryl group, a biphenyl group, a terphenyl group, a diphenylfluorenyl group, a dimethylfluorenyl group, a benzodiphenylfluorenyl group, a benzodimethylfluorenyl group, a dibenzofuranyl group, a dibenzothienyl group, a naphthobenzofuranyl group, or a naphthobenzothienyl group.

In the organic EL device according to the exemplary embodiment, the second compound represented by the formula (2) is preferably a compound represented by a formula (201), a formula (202), a formula (203), a formula (204), a formula (205), a formula (206), a formula (207), a formula (208), or a formula (209) below.

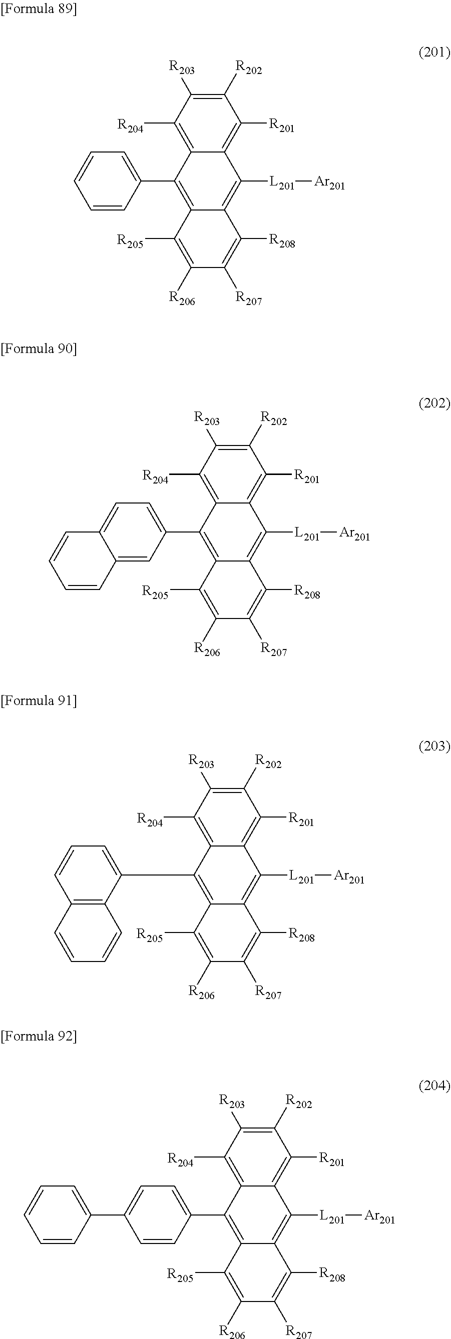

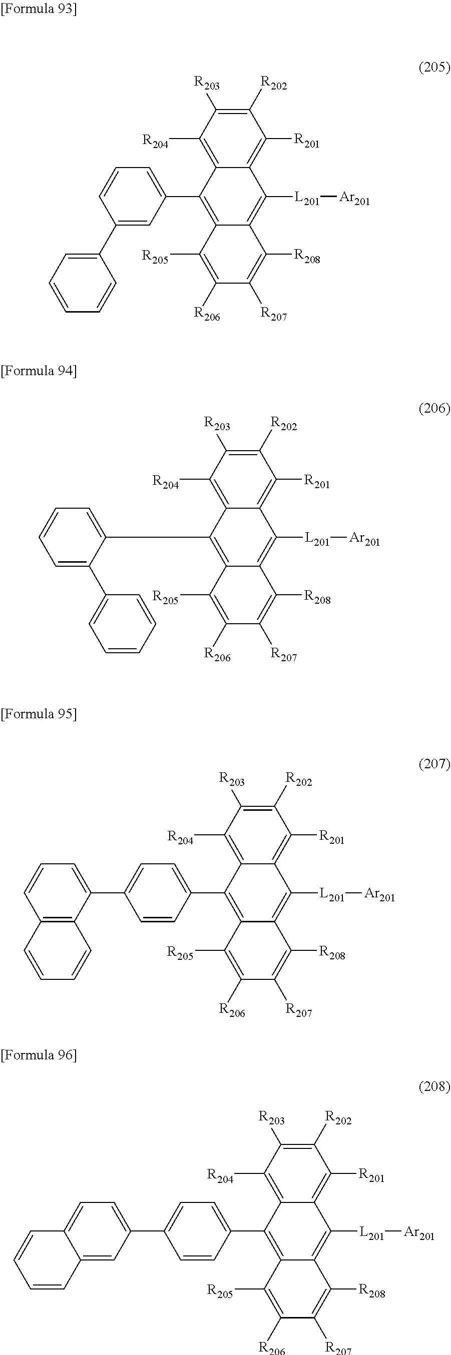

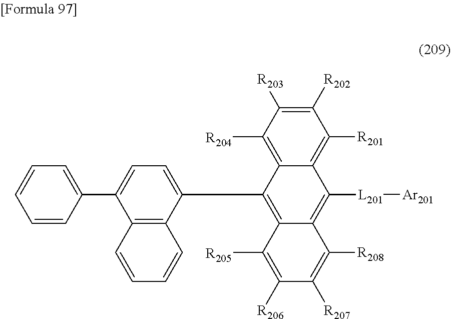

In the formulae (201) to (209):
L₂₀₁ and Ar₂₀₁ respectively represent the same as L₂₀₁ and Ar₂₀₁ in the formula (2); and
R₂₀₁ to R₂₀ each independently represent the same as R₂₀₁ to R₂₀ in the formula (2).

The second compound represented by the formula (2) is also preferably a compound represented by a formula (221), a formula (222), a formula (223), a formula (224), a formula (225), a formula (226), a formula (227), a formula (228), or a formula (229) below.

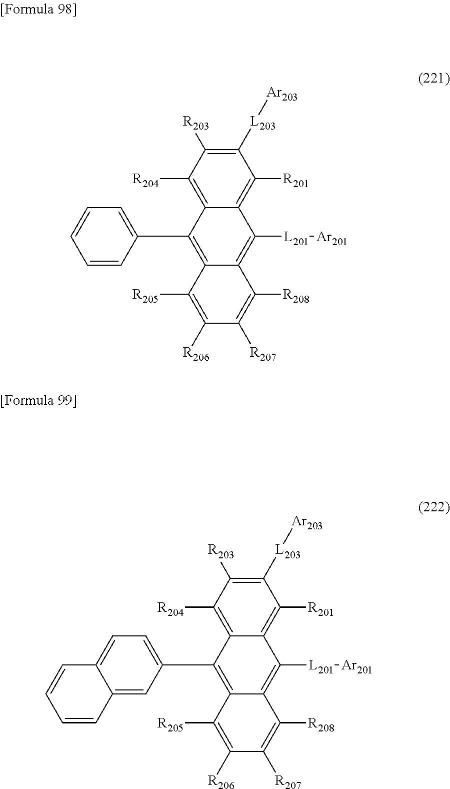

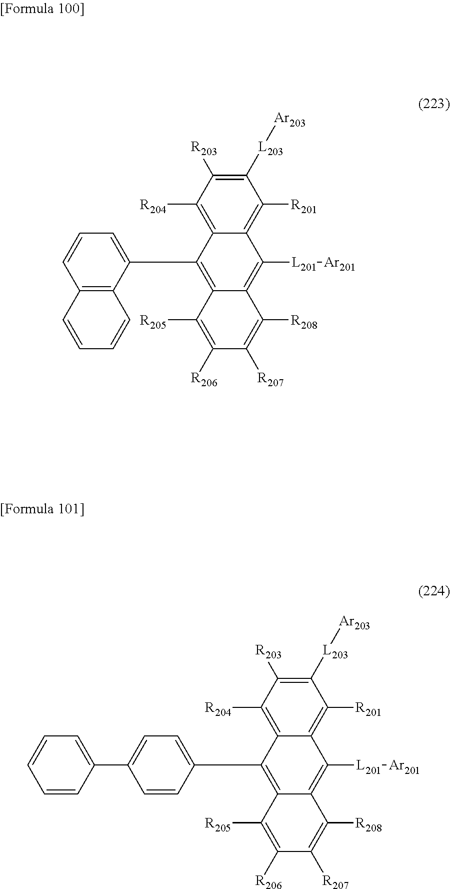

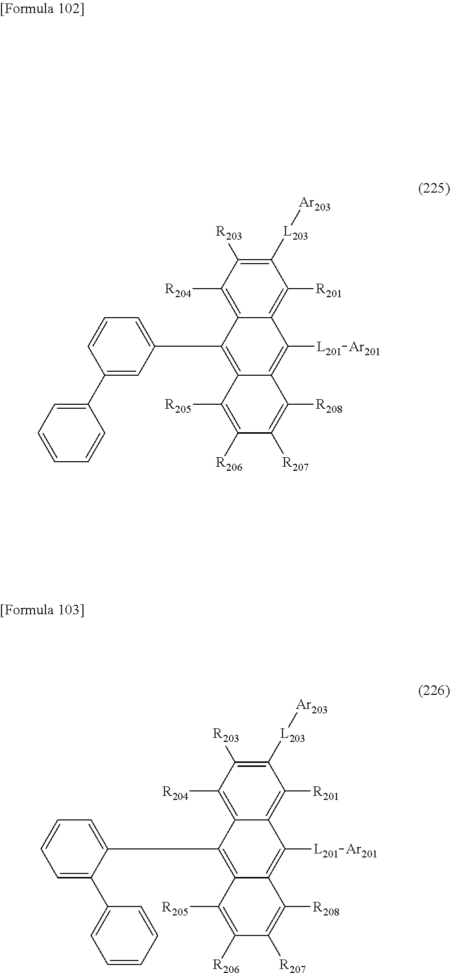

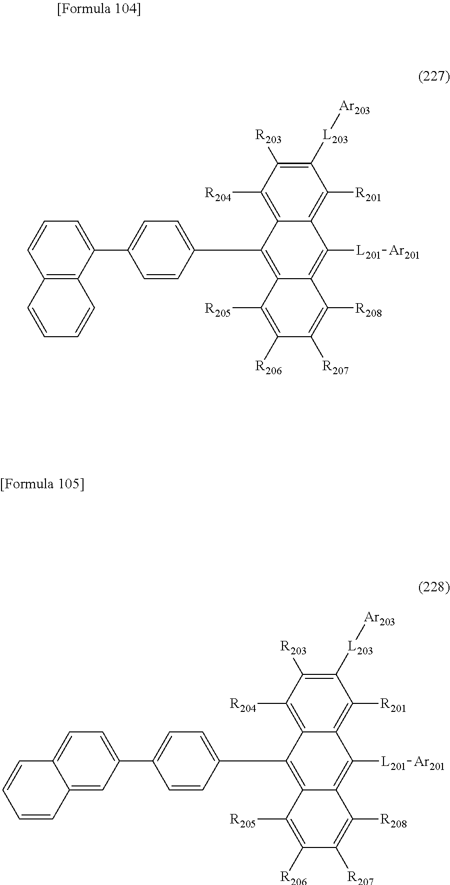

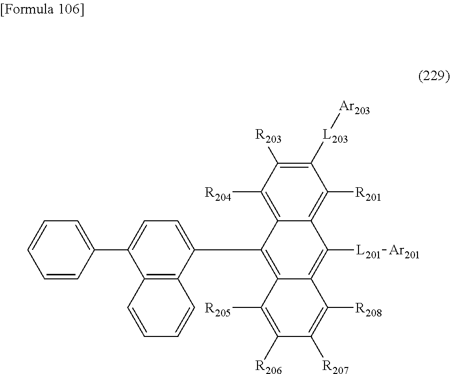

In the formulae (221), (222), (223), (224), (225), (226), (227), (228), and (229):
R₂₀₁ and R₂₀₃ to R₂₀₈ each independently represent the same as R₂₀₁ and R₂₀₃ to R₂₀₈ in the formula (2);
L₂₀₁ and Ar₂₀₁ respectively represent the same as L₂₀₁ and Ar₂₀₁ in the formula (2);
L₂₀₃ represents the same as L₂₀₁ in the formula (2);
L₂₀₃ and L₂₀₁ are mutually the same or different;
Ar₂₀₃ represents the same as Ar₂₀₁ in the formula (2); and
Ar₂₀₃ and Ar₂₀₁ are mutually the same or different.

The second compound represented by the formula (2) is also preferably a compound represented by a formula (241), a formula (242), a formula (243), a formula (244), a formula (245), a formula (246), a formula (247), a formula (248), or a formula (249) below.

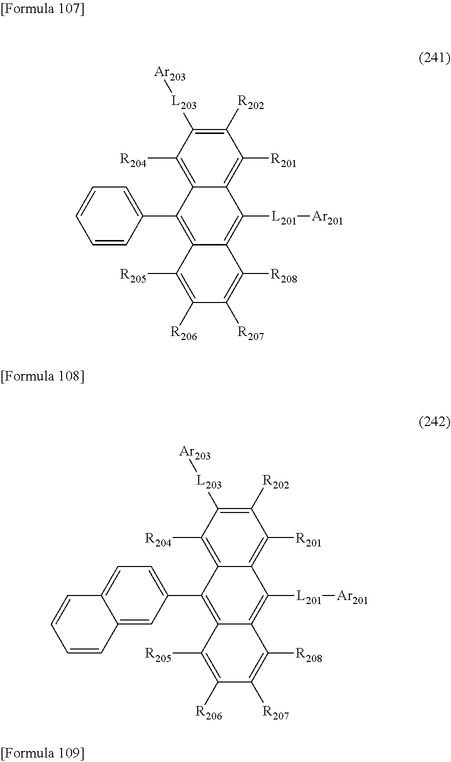

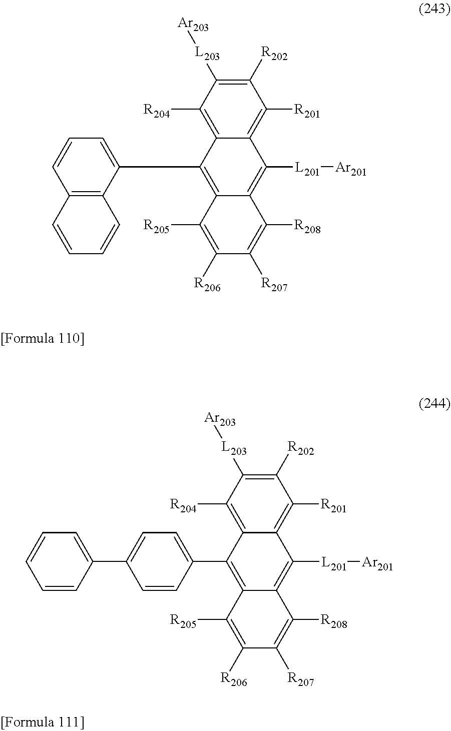

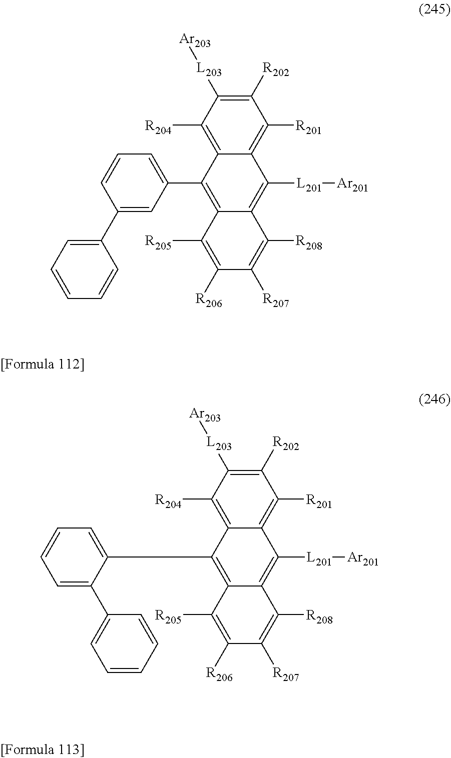

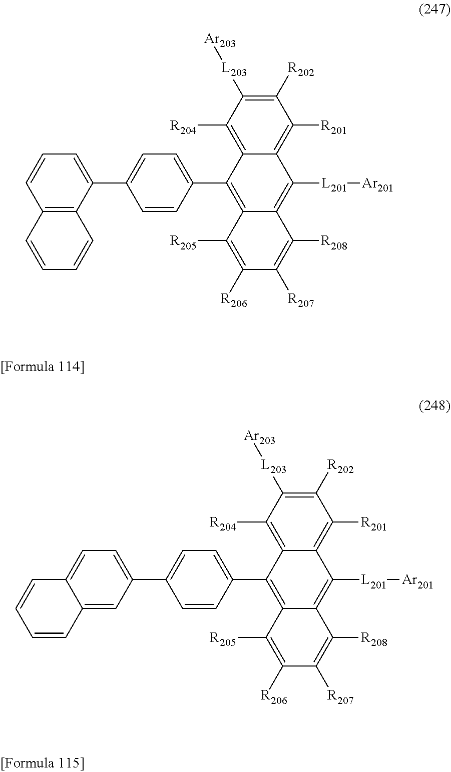

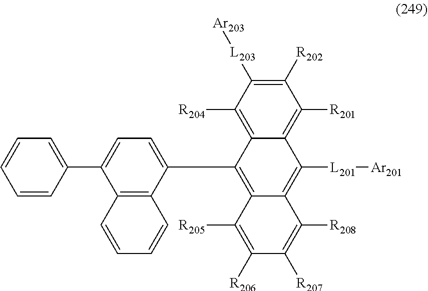

In the formulae (241), (242), (243), (244), (245), (246), (247), (248), and (249):
R₂₀₁, R₂₀₂ and R₂₀₄ to R₂₀₈ each independently represent the same as R₂₀₁, R₂₀₂ and R₂₀₄ to R₂₀₈ in the formula (2);
L₂₀₁ and Ar₂₀₁ respectively represent the same as L₂₀₁ and Ar₂₀₁ in the formula (2);
L₂₀₃ represents the same as L₂₀₁ in the formula (2);
L₂₀₃ and L₂₀₁ are mutually the same or different;
Ar₂₀₃ represents the same as Ar₂₀₁ in the formula (2); and
Ar₂₀₃ and Ar₂₀₁ are mutually the same or different.

In the second compound represented by the formula (2), R₂₀₁ to R₂₀₈ are preferably each independently a hydrogen atom, a substituted or unsubstituted alkyl group having 1 to 50 carbon atoms, a substituted or unsubstituted cycloalkyl group having 3 to 50 ring carbon atoms, or a group represented by —Si(R₉₀₁)(R₉₀₂)(R₉₀₃).

L₂₀₁ is preferably a single bond or an unsubstituted arylene group having 6 to 22 ring carbon atoms, and Ar₂₀₁ is preferably a substituted or unsubstituted aryl group having 6 to 22 ring carbon atoms.

In the organic EL device according to the exemplary embodiment, R₂₀₁ to R₂₀₈ that are substituents of an anthracene skeleton in the second compound represented by the formula (2) are each preferably a hydrogen atom in terms of preventing inhibition of intermolecular interaction and inhibiting decrease in electron mobility. However, R₂₀₁ to R₂₀₈ may each be a substituted or unsubstituted aryl group having 6 to 50 ring carbon atoms or a substituted or unsubstituted heterocyclic group having 5 to 50 ring atoms.

Assuming that R₂₀₁ to R₂₀₈ are each a bulky substituent such as an alkyl group and a cycloalkyl group, intermolecular interaction may be inhibited to decrease the electron mobility of the second compound relative to that of the first host material, so that a relationship of μe(H2)>μe(H1) shown by the numerical formula (Numerical Formula 70) may not be satisfied. When the second emitting layer contains the second compound, it can be expected that satisfying the relationship of μe(H2)>μe(H1) inhibits a decrease in a recombination ability between holes and electrons in the first emitting layer and a decrease in luminous efficiency. It should be noted that substituents, namely, a haloalkyl group, alkenyl group, alkynyl group, group represented by —Si(R₉₀₁)(R₉₀₂)(R₉₀₃), group represented by —O—(R₉₀₄), group represented by —S—(R₉₀₅), group represented by —N(R₉₀₆)(R₉₀₇), aralkyl group, group represented by —C(═O)R₈₀₁, group represented by —COOR₈₀₂, halogen atom, cyano group, and nitro group are likely to be bulky, and an alkyl group and cycloalkyl group are likely to be further bulky.

In the second compound represented by the formula (2), R₂₀₁ to R₂₀₈, which are the substituents on the anthracene skeleton, are each preferably not a bulky substituent and preferably not an alkyl group and cycloalkyl group. More preferably, R₂₀₁ to R₂₀₈ are each not an alkyl group, cycloalkyl group, haloalkyl group, alkenyl group, alkynyl group, group represented by —Si(R₉₀₁)(R₉₀₂)(R₉₀₃), group represented by —O—(R₉₀₄), group represented by —S—(R₉₀₅), group represented by —N(R₉₀₆)(R₉₀₇), aralkyl group, group represented by —C(═O)R₈₀₁, group represented by —COOR₈₀₂, halogen atom, cyano group, and nitro group.

In the organic EL device according to the exemplary embodiment, also preferably, R₂₀₁ to R₂₀₈ in the second compound represented by the formula (2) are each independently a hydrogen atom, a substituted or unsubstituted alkyl group having 1 to 50 carbon atoms, a substituted or unsubstituted cycloalkyl group having 3 to 50 ring carbon atoms, or a group represented by —Si(R₉₀₁)(R₉₀₂)(R₉₀₃).

In the organic EL device according to the exemplary embodiment, R₂₀₁ to R₂₀₈ in the second compound represented by the formula (2) are each preferably a hydrogen atom.

In the second compound, examples of the substituent for the “substituted or unsubstituted” group on R₂₀₁ to R₂₀₈ also preferably do not include the above-described substituents that are likely to be bulky, especially a substituted or unsubstituted alkyl group and a substituted or unsubstituted cycloalkyl group. When examples of the substituent for the “substituted or unsubstituted” group on R₂₀₁ to R₂₀₈ do not include a substituted or unsubstituted alkyl group and a substituted or unsubstituted cycloalkyl group, the inhibition of intermolecular interaction to be caused by the presence of a bulky substituent such as an alkyl group and a cycloalkyl group can be prevented, thereby preventing a decrease in the electron mobility. Moreover, when the second compound described above is used in the second emitting layer, a decrease in a recombination ability between holes and electrons in the first emitting layer and a decrease in the luminous efficiency can be inhibited.

Further preferably, R₂₀₁ to R₂₀₈ that are substituents on the anthracene skeleton are not bulky substituents and R₂₀₁ to R₂₀₈ as substituents are unsubstituted. Assuming that R₂₀₁ to R₂₀₈ that are substituents on the anthracene skeleton are not bulky substituents and substituents are bonded to R₂₀₁ to R₂₀₈ that are not bulky substituents, the substituents bonded to R₂₀₁ to R₂₀₈ are preferably not bulky substituents; and the substituents bonded to R₂₀₁ to R₂₀₈ serving as substituents are preferably not an alkyl group and cycloalkyl group, more preferably not an alkyl group, cycloalkyl group, haloalkyl group, alkenyl group, alkynyl group, group represented by —Si(R₉₀₁)(R₉₀₂)(R₉₀₃), group represented by —O—(R₉₀₄), group represented by —S—(R₉₀₅), group represented by —N(R₉₀₆)(R₉₀₇), aralkyl group, group represented by —C(═O)R₈₀₁, group represented by —COOR₈₀₂, halogen atom, cyano group, and nitro group.

In the second compound, the groups specified to be “substituted or unsubstituted” are each preferably an unsubstituted group.

### Method of Producing Second Compound

The second compound can be produced by a known method. Further, the second compound can be produced based on a known method through a known alternative reaction using a known material(s) tailored for the target compound.

### Specific Examples of Second Compound

Specific examples of the second compound include the following compounds. However, the invention is not limited to the specific examples of the second compound. In the specific examples below, D represents a deuterium atom.

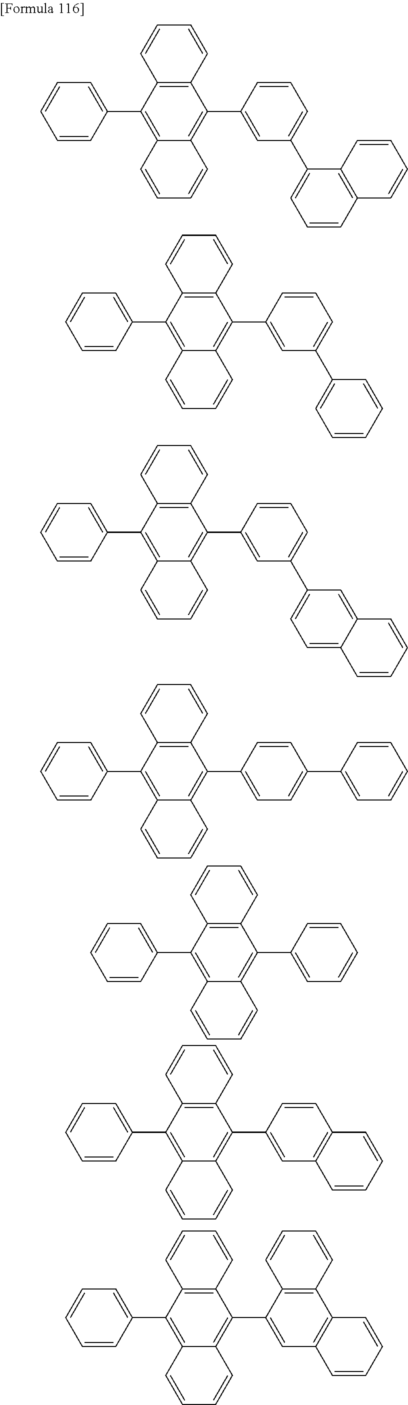

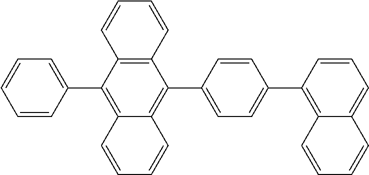 [SMILES: c1ccc(-c2c3ccccc3c(-c3ccc(-c4cccc5ccccc45)cc3)c3ccccc23)cc1]

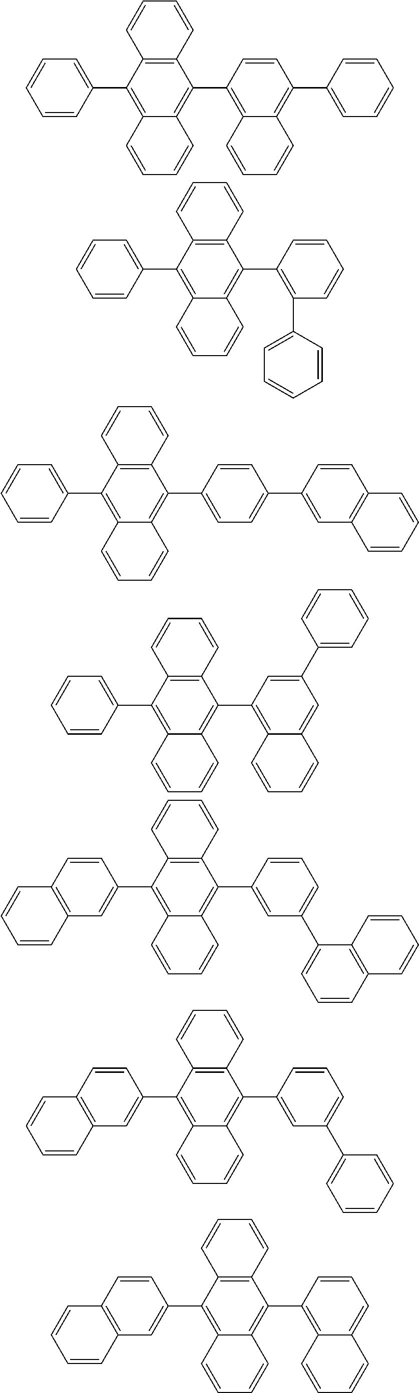

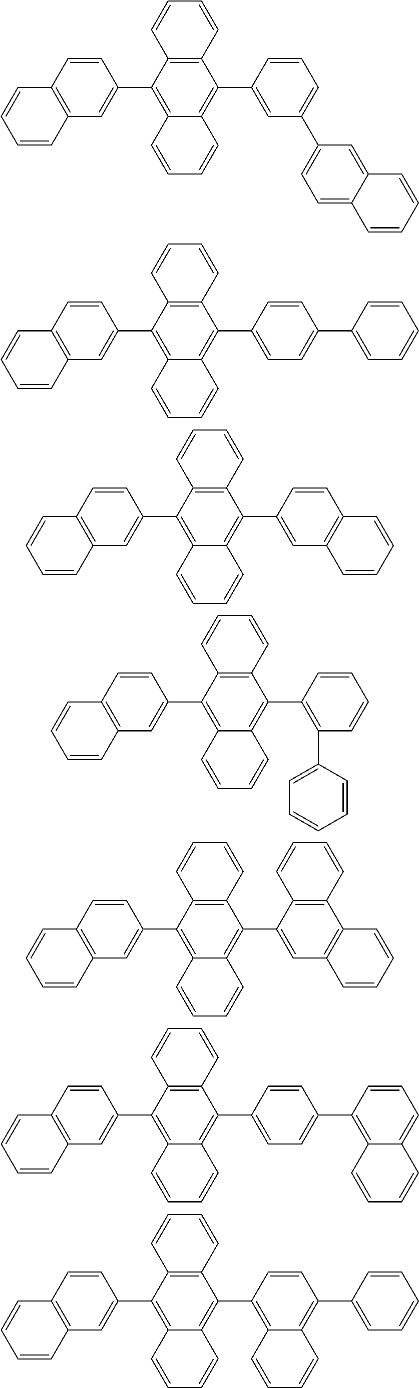

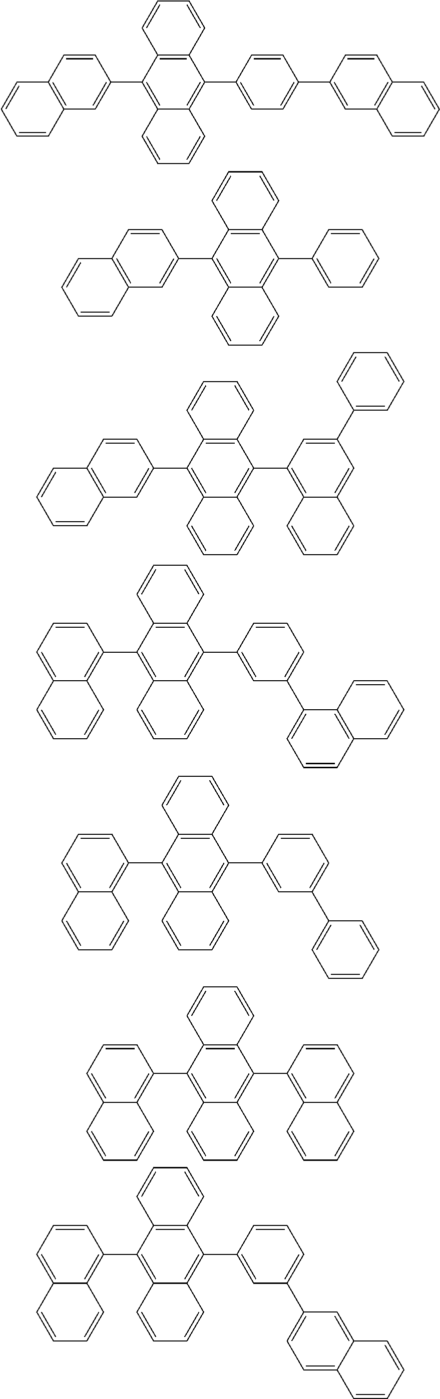

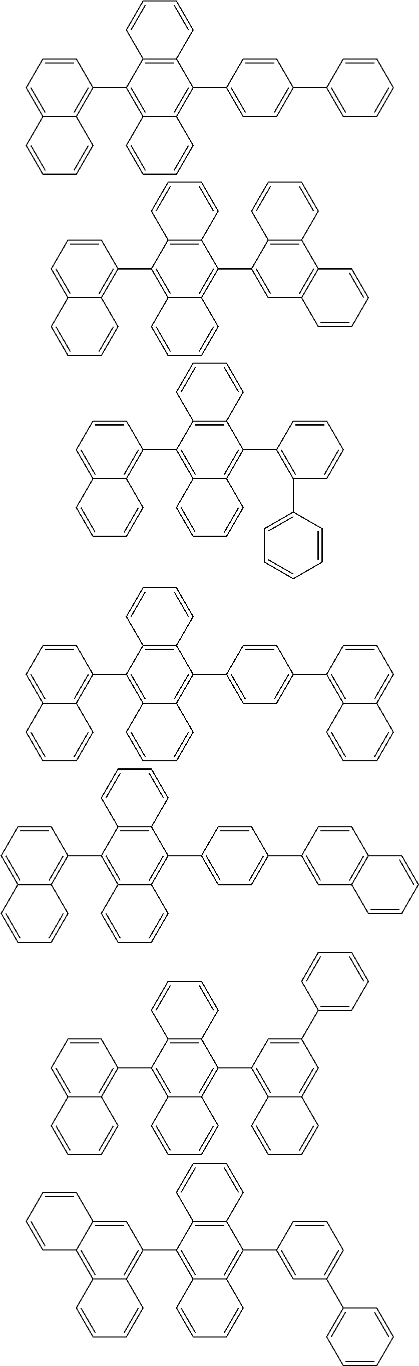

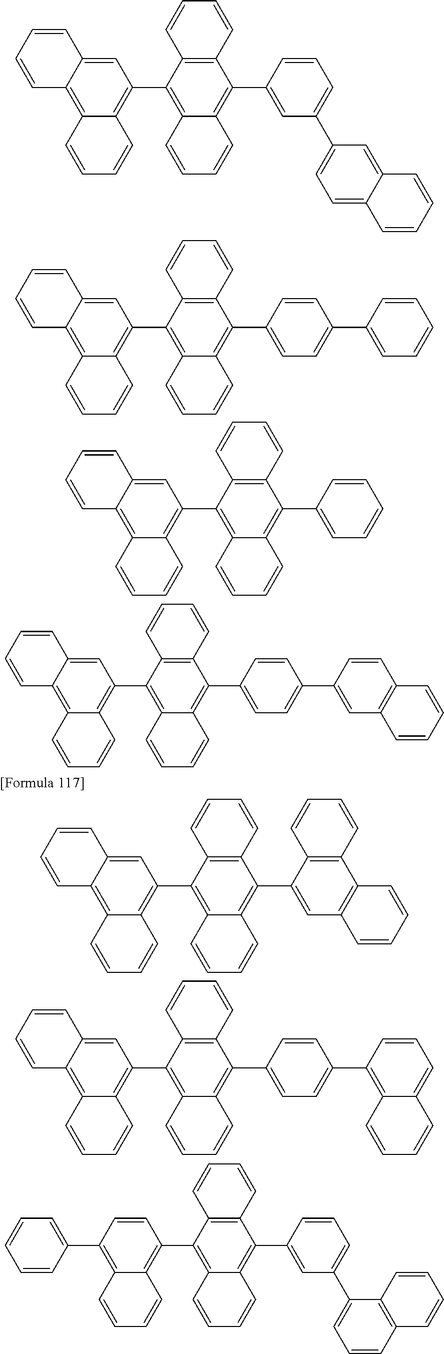

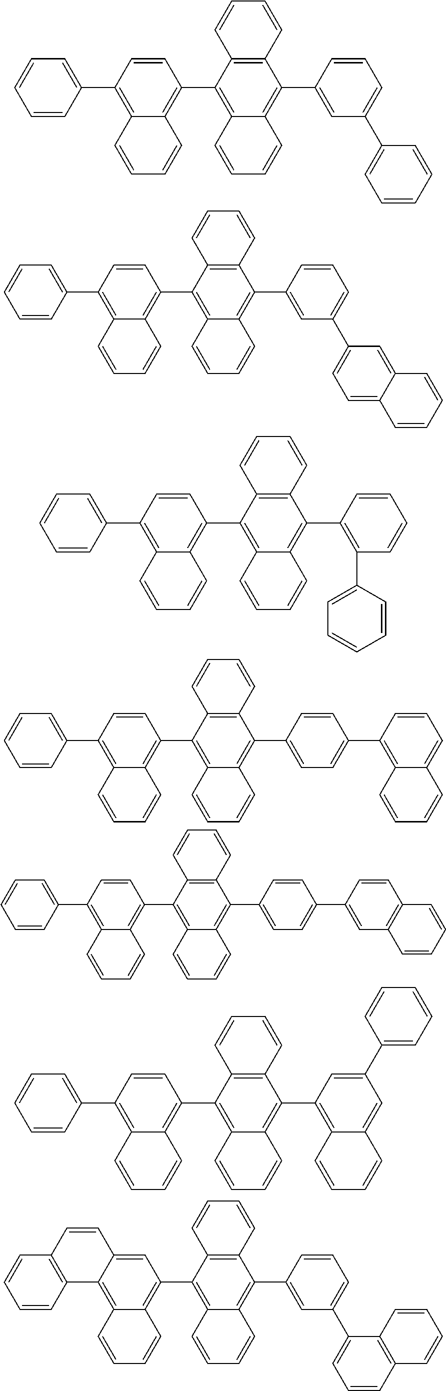

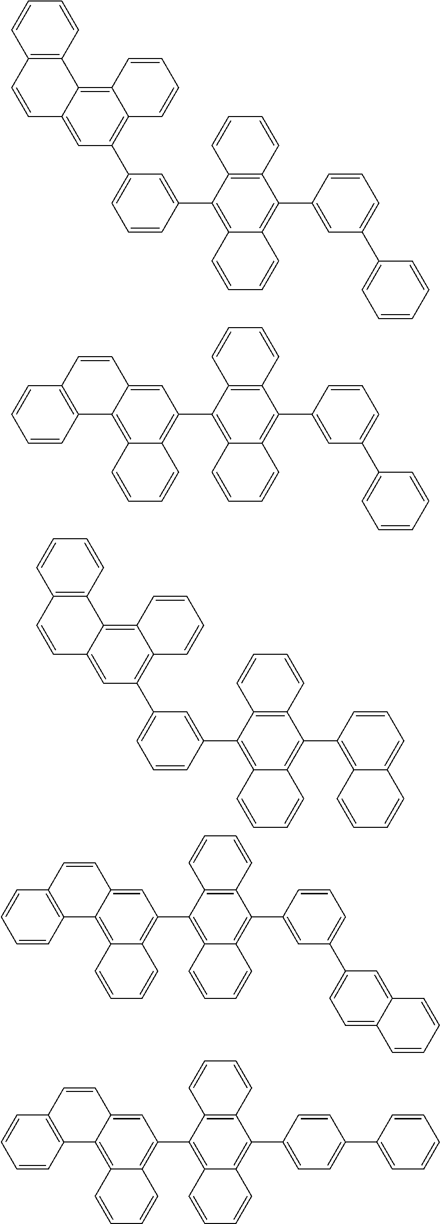

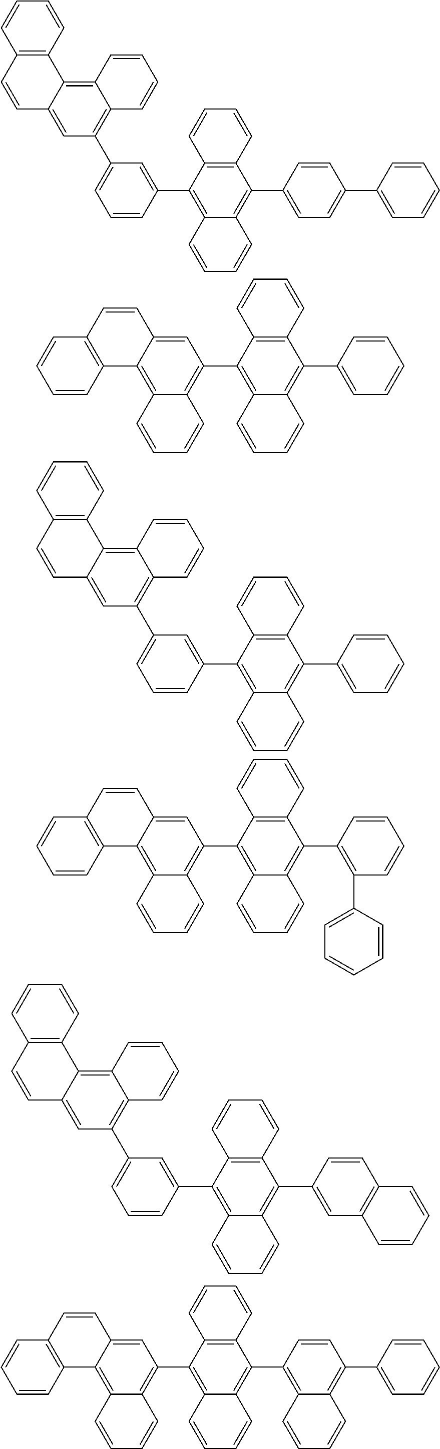

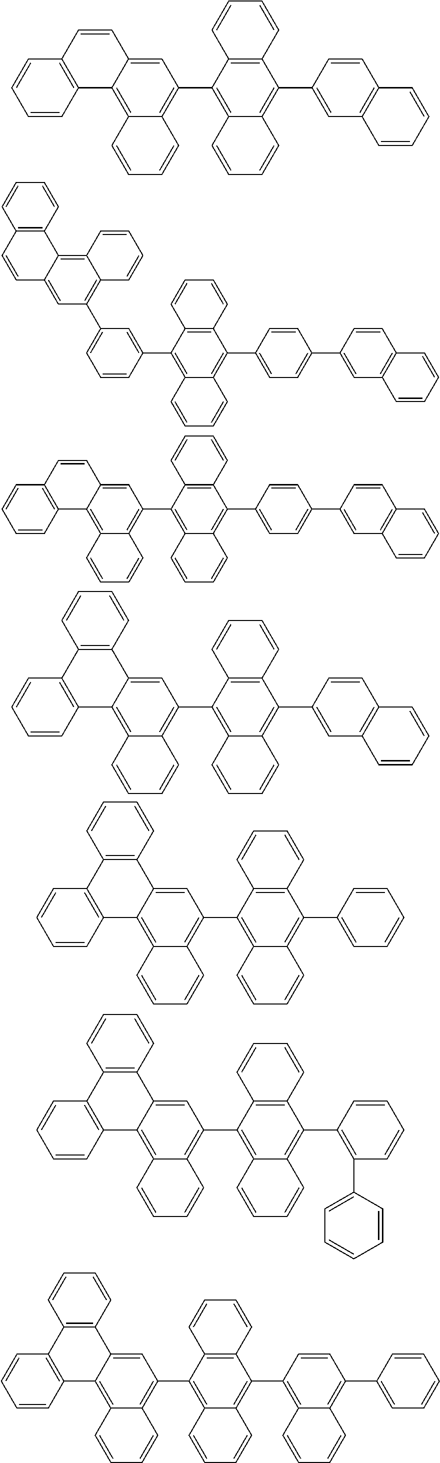

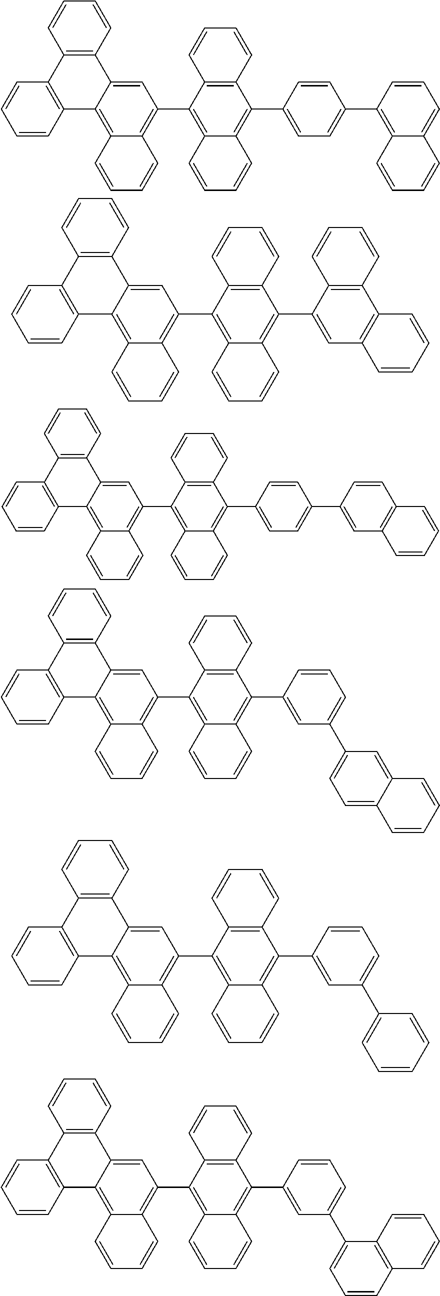

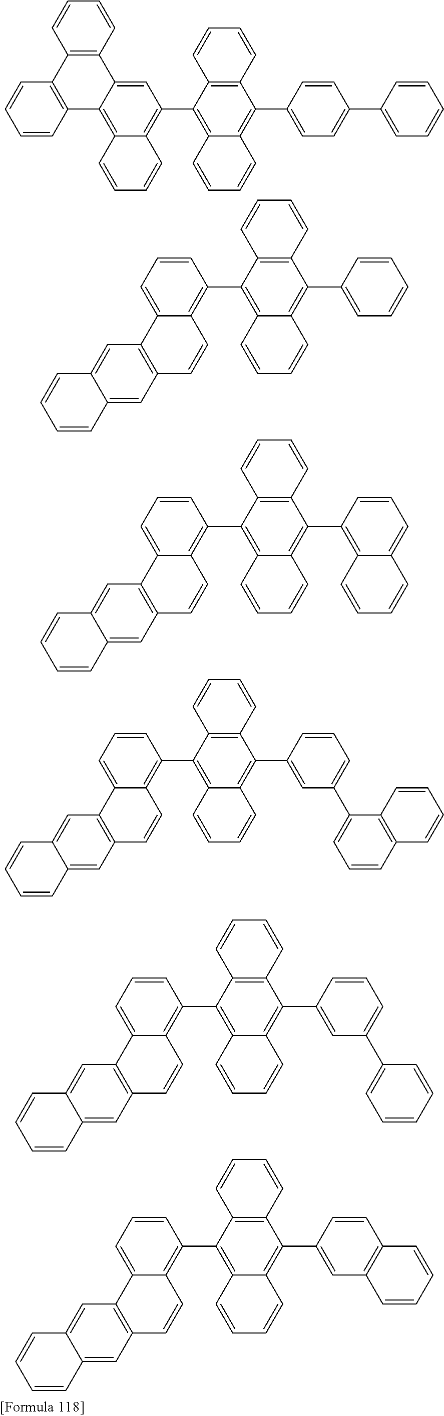

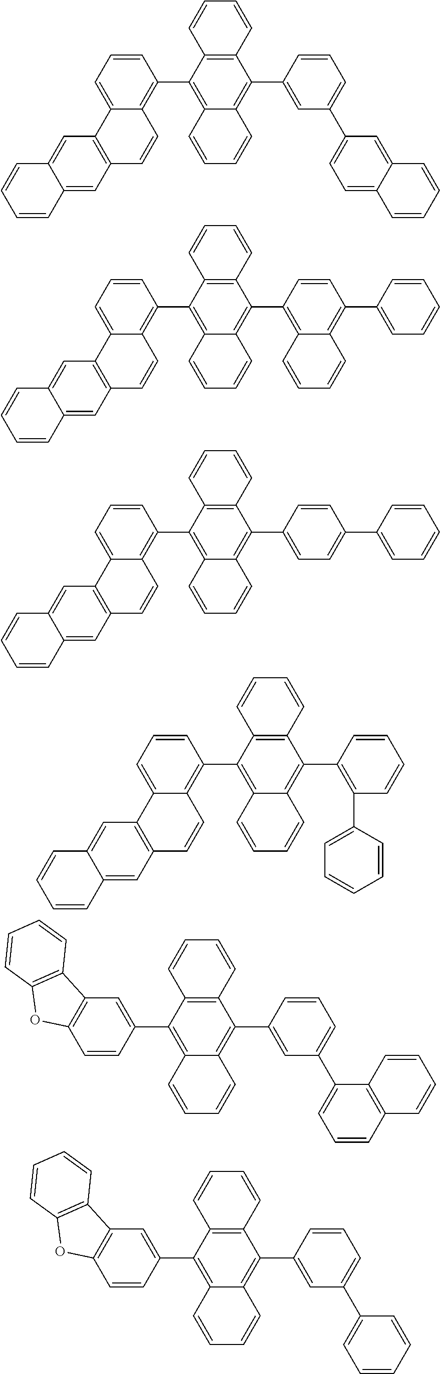

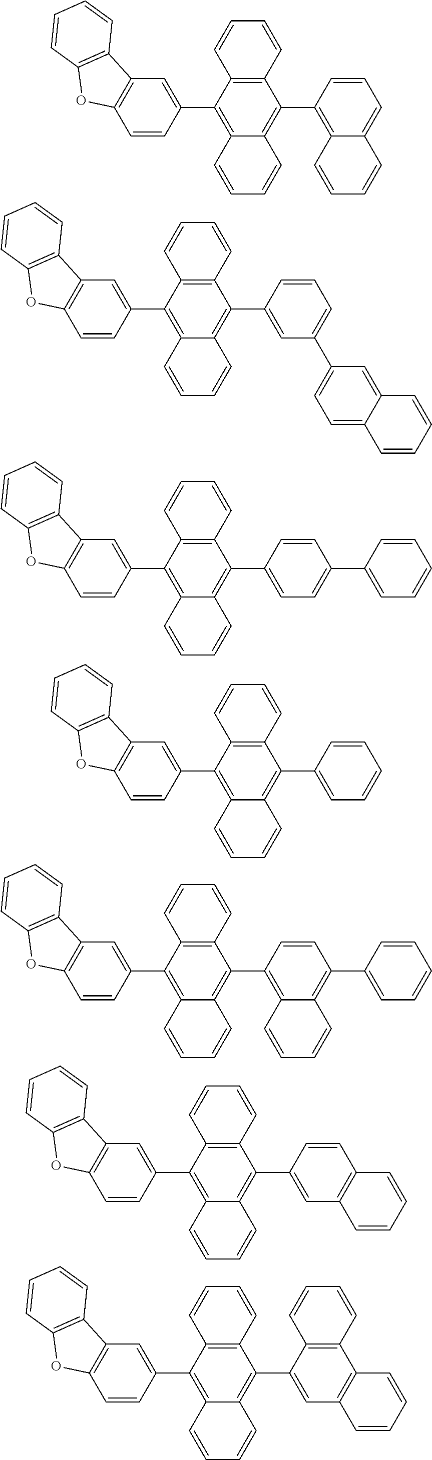

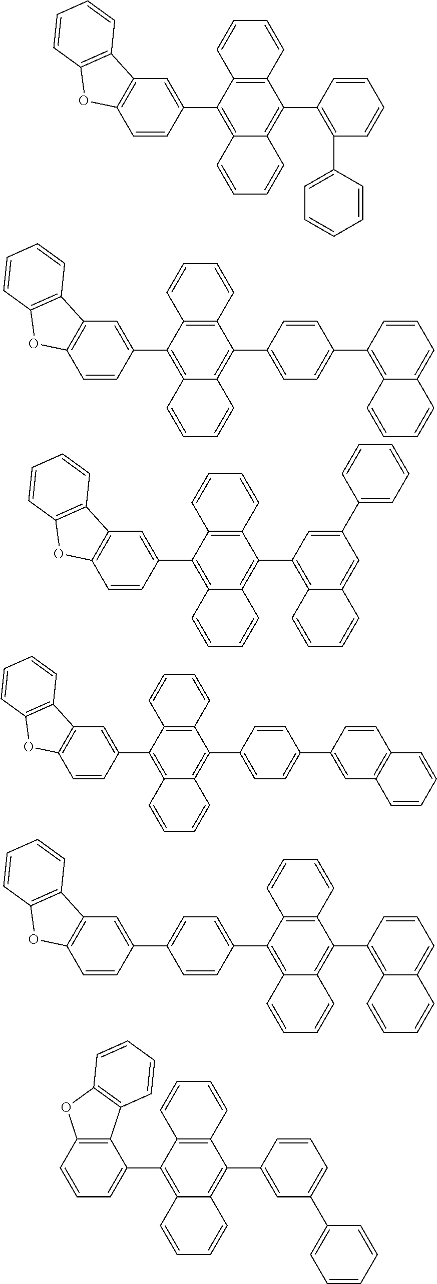

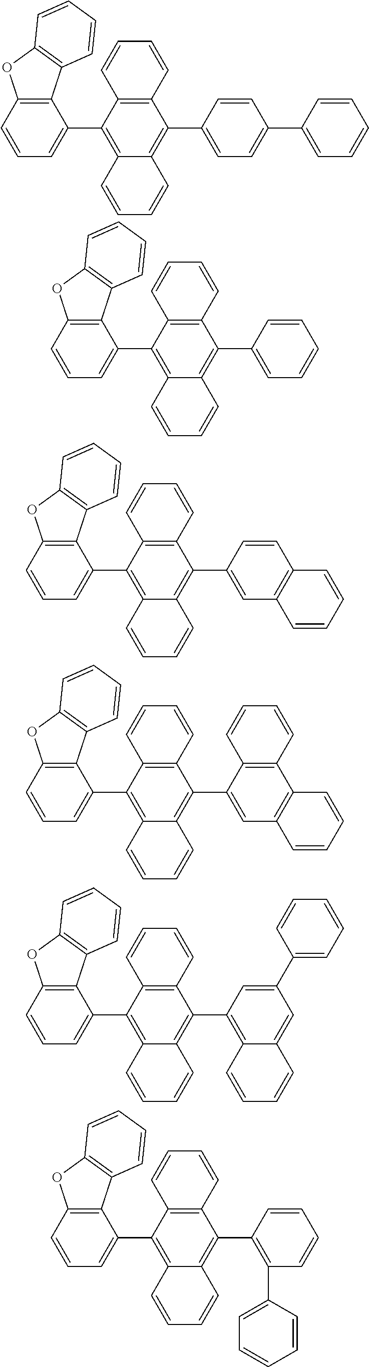

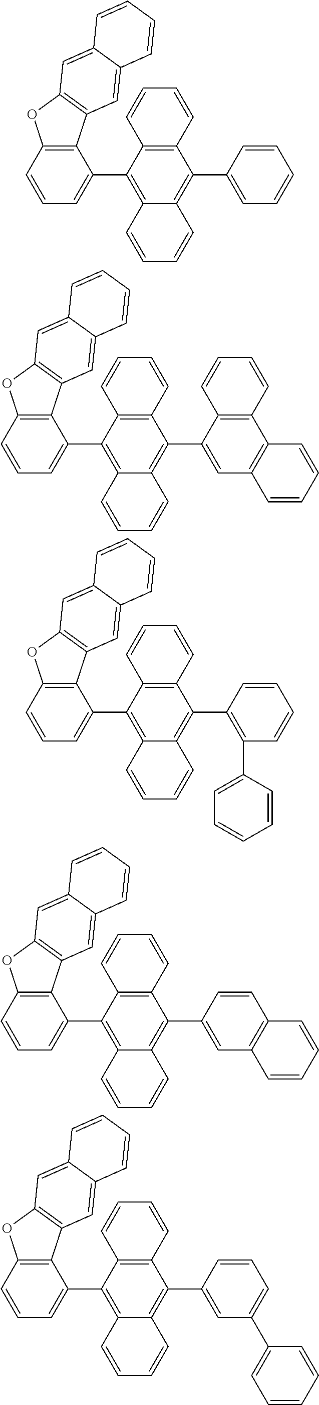

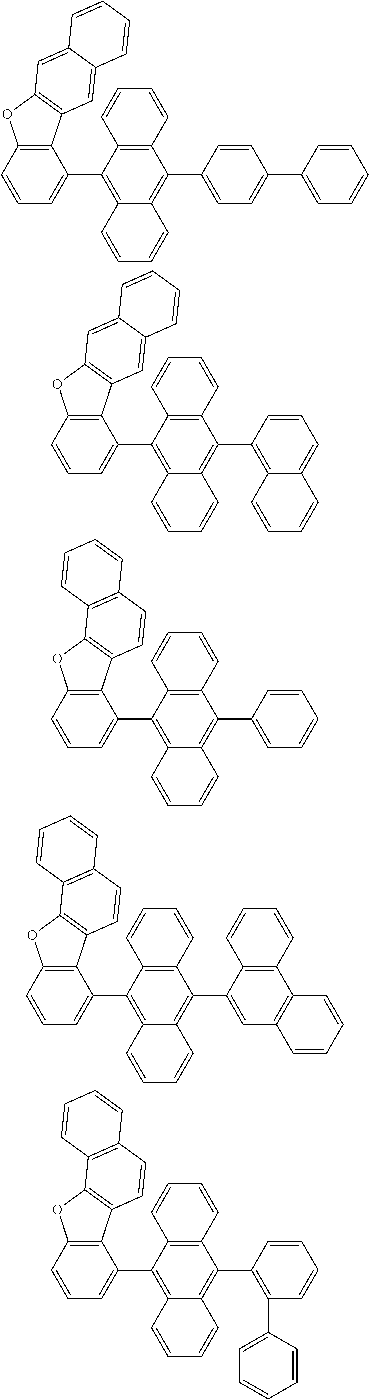

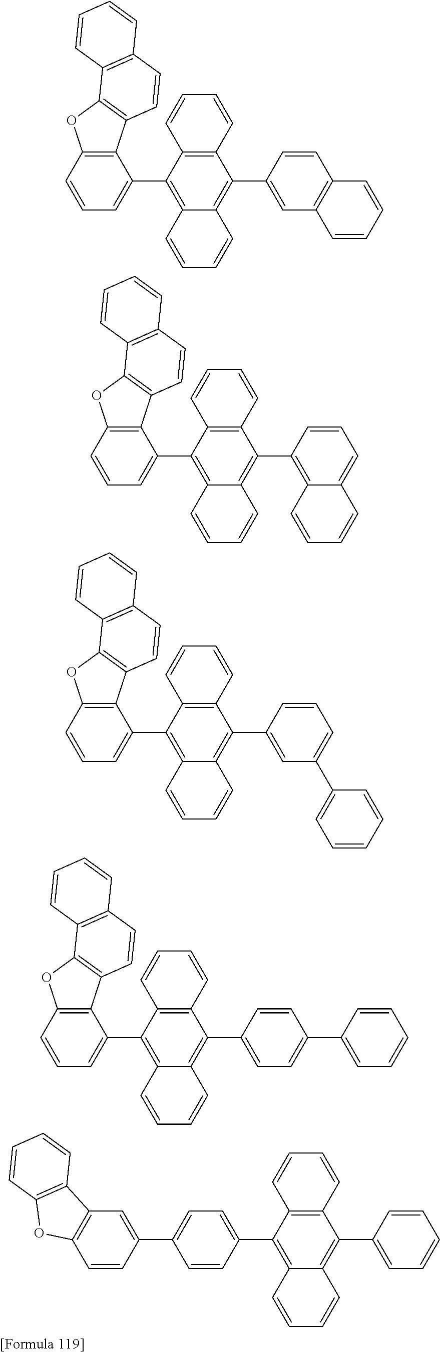

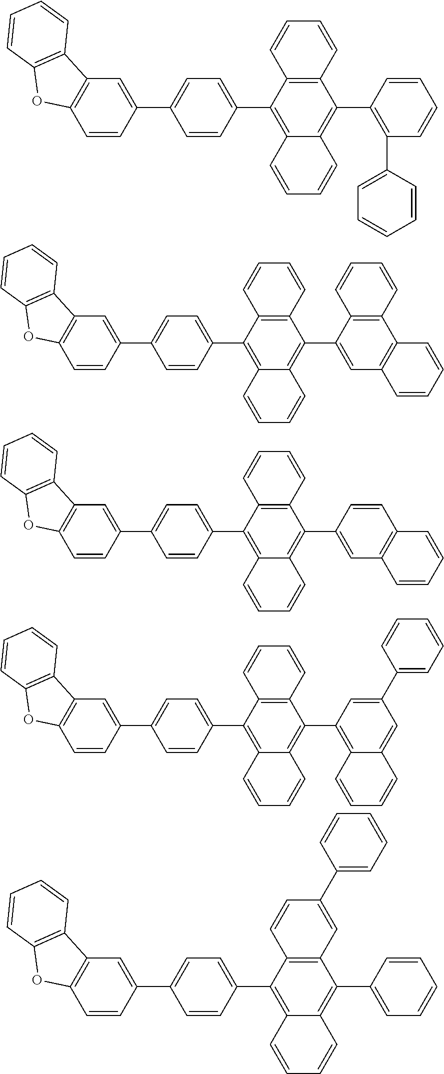

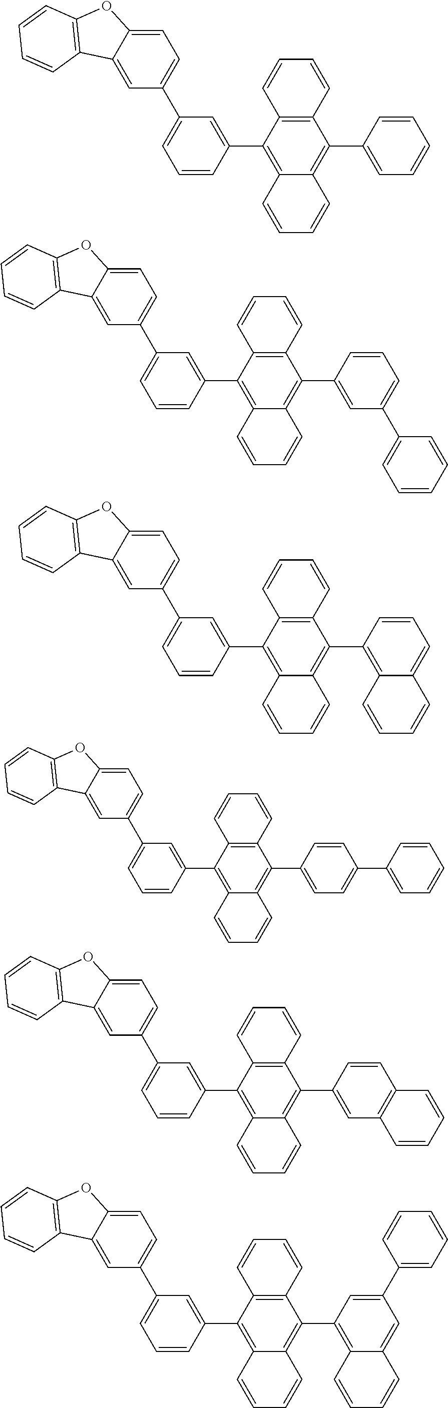 [SMILES: c1ccc(-c2c3ccccc3c(-c3cccc(-c4ccc5oc6ccccc6c5c4)c3)c3ccccc23)cc1 ; c1ccc(-c2cccc(-c3c4ccccc4c(-c4cccc(-c5ccc6oc7ccccc7c6c5)c4)c4ccccc34)c2)cc1 ; c1cc(-c2ccc3oc4ccccc4c3c2)cc(-c2c3ccccc3c(-c3cccc4ccccc34)c3ccccc23)c1 ; c1ccc(-c2ccc(-c3c4ccccc4c(-c4cccc(-c5ccc6oc7ccccc7c6c5)c4)c4ccccc34)cc2)cc1 ; c1cc(-c2ccc3oc4ccccc4c3c2)cc(-c2c3ccccc3c(-c3ccc4ccccc4c3)c3ccccc23)c1 ; c1ccc(-c2cc(-c3c4ccccc4c(-c4cccc(-c5ccc6oc7ccccc7c6c5)c4)c4ccccc34)c3ccccc3c2)cc1]

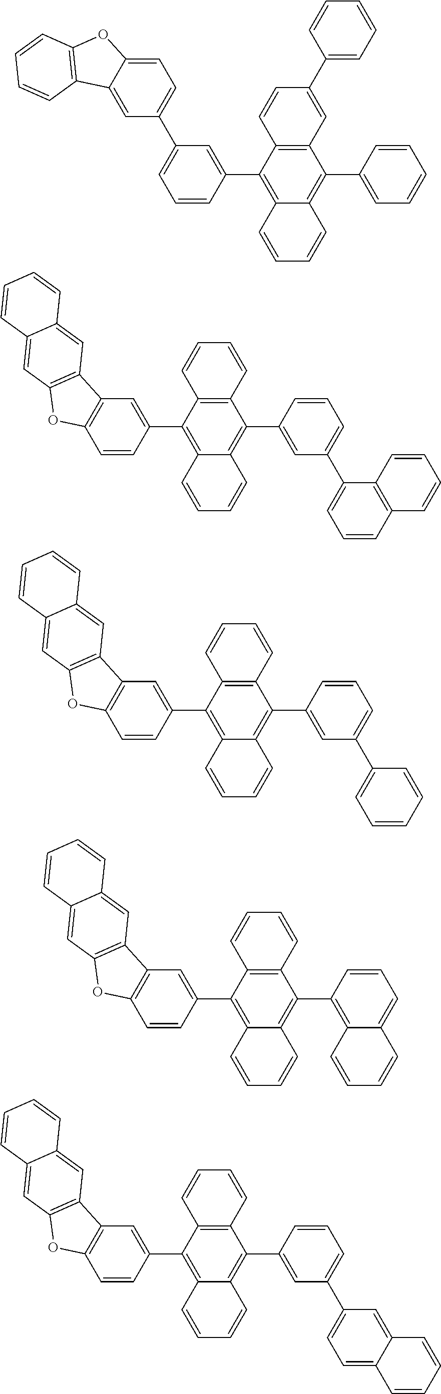 [SMILES: c1ccc(-c2ccc3c(-c4cccc(-c5ccc6oc7ccccc7c6c5)c4)c4ccccc4c(-c4ccccc4)c3c2)cc1 ; c1cc(-c2cccc3ccccc23)cc(-c2c3ccccc3c(-c3ccc4oc5cc6ccccc6cc5c4c3)c3ccccc23)c1 ; c1ccc(-c2cccc(-c3c4ccccc4c(-c4ccc5oc6cc7ccccc7cc6c5c4)c4ccccc34)c2)cc1 ; c1ccc2cc3c(cc2c1)oc1ccc(-c2c4ccccc4c(-c4cccc5ccccc45)c4ccccc24)cc13 ; c1cc(-c2ccc3ccccc3c2)cc(-c2c3ccccc3c(-c3ccc4oc5cc6ccccc6cc5c4c3)c3ccccc23)c1]

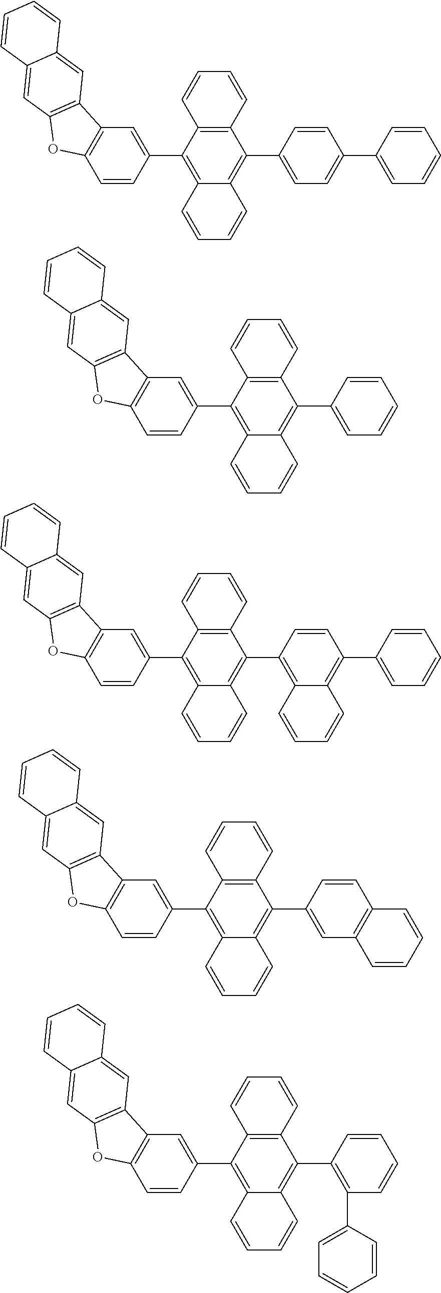 [SMILES: c1ccc(-c2ccc(-c3c4ccccc4c(-c4ccc5oc6cc7ccccc7cc6c5c4)c4ccccc34)cc2)cc1 ; c1ccc(-c2c3ccccc3c(-c3ccc4oc5cc6ccccc6cc5c4c3)c3ccccc23)cc1 ; c1ccc(-c2ccc(-c3c4ccccc4c(-c4ccc5oc6cc7ccccc7cc6c5c4)c4ccccc34)c3ccccc23)cc1 ; c1ccc2cc(-c3c4ccccc4c(-c4ccc5oc6cc7ccccc7cc6c5c4)c4ccccc34)ccc2c1 ; c1ccc(-c2ccccc2-c2c3ccccc3c(-c3ccc4oc5cc6ccccc6cc5c4c3)c3ccccc23)cc1]

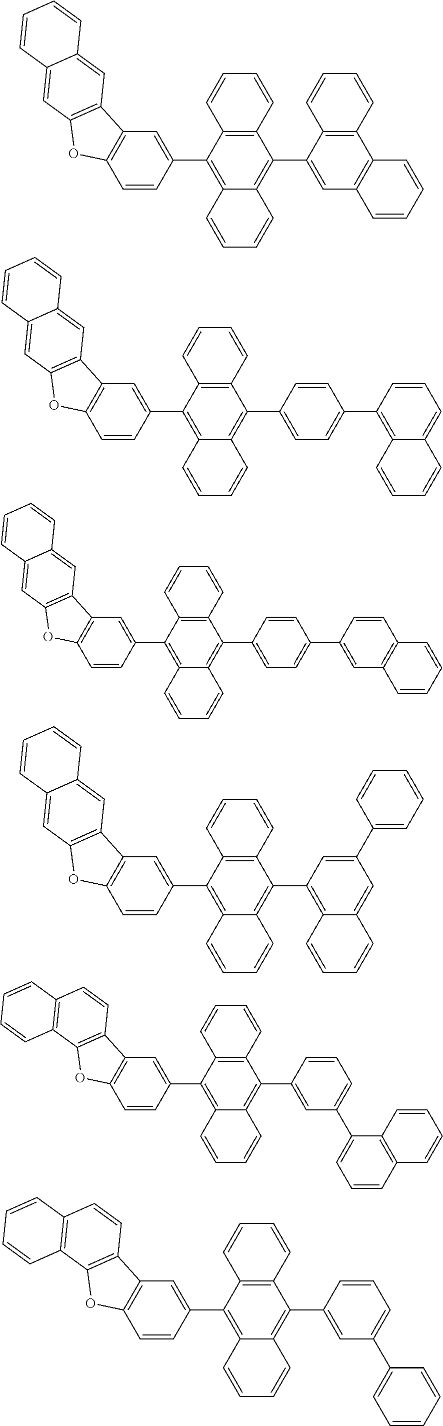

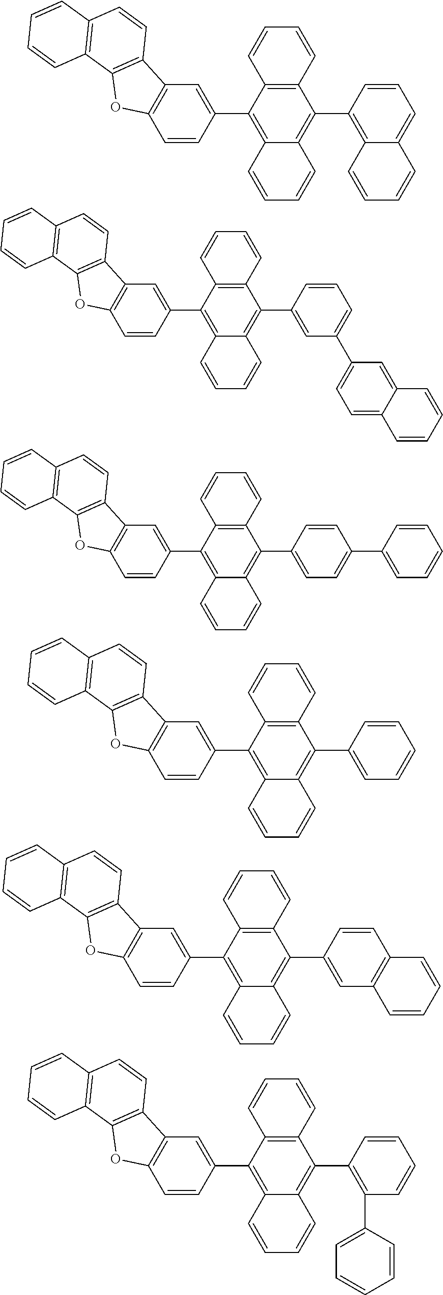

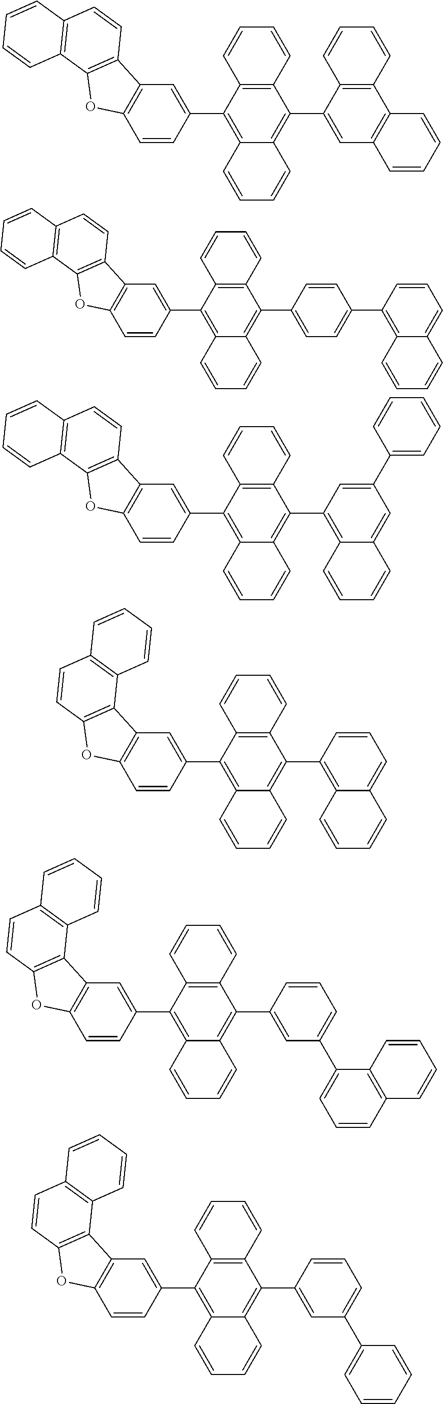

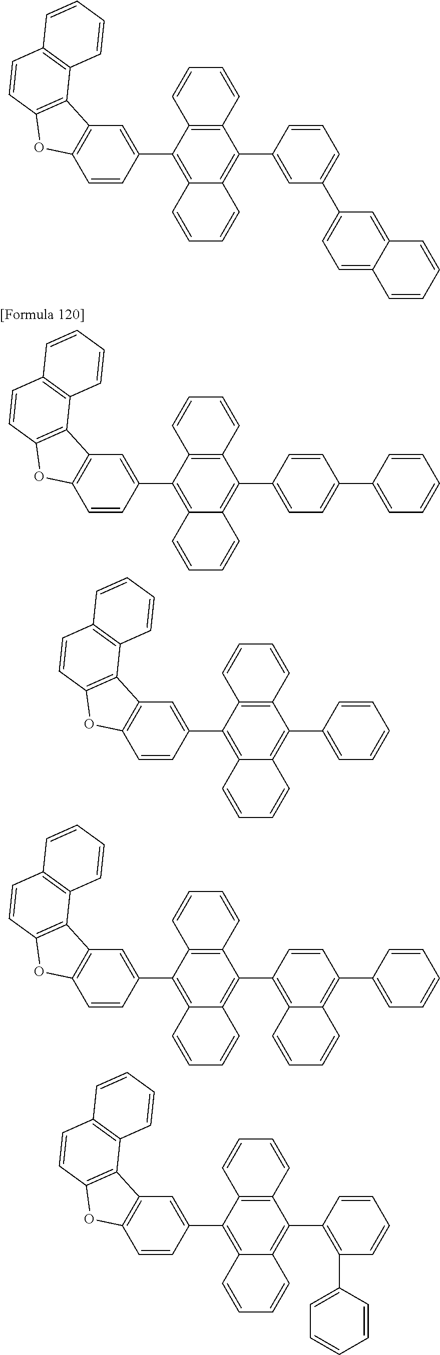

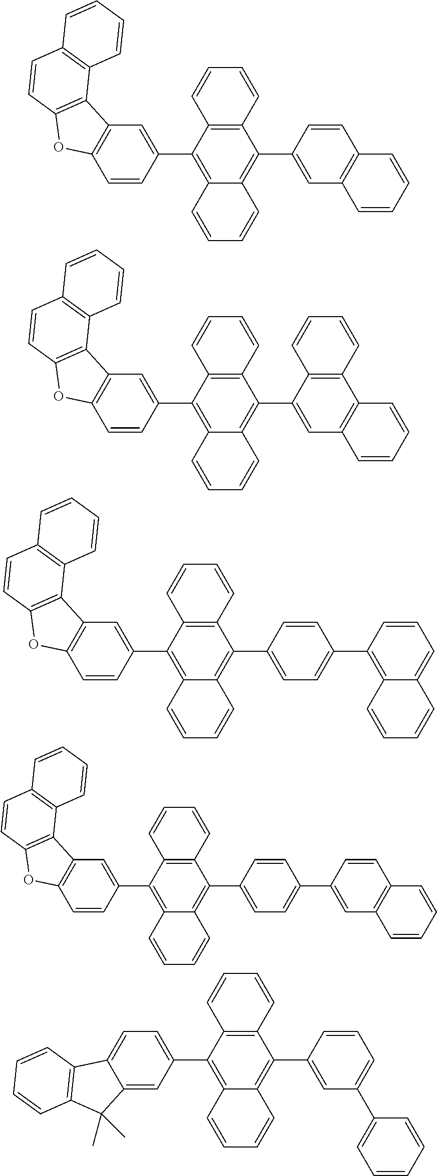

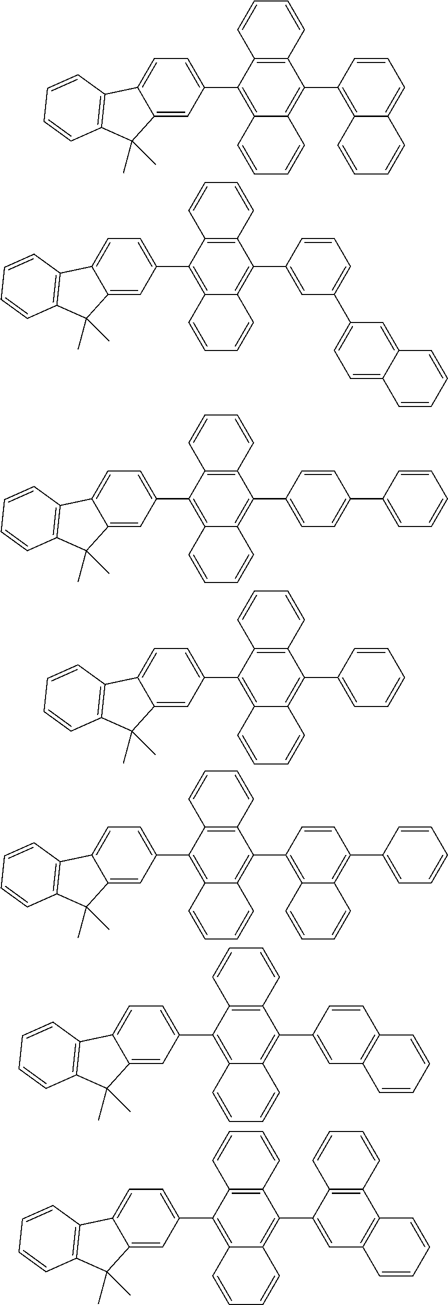

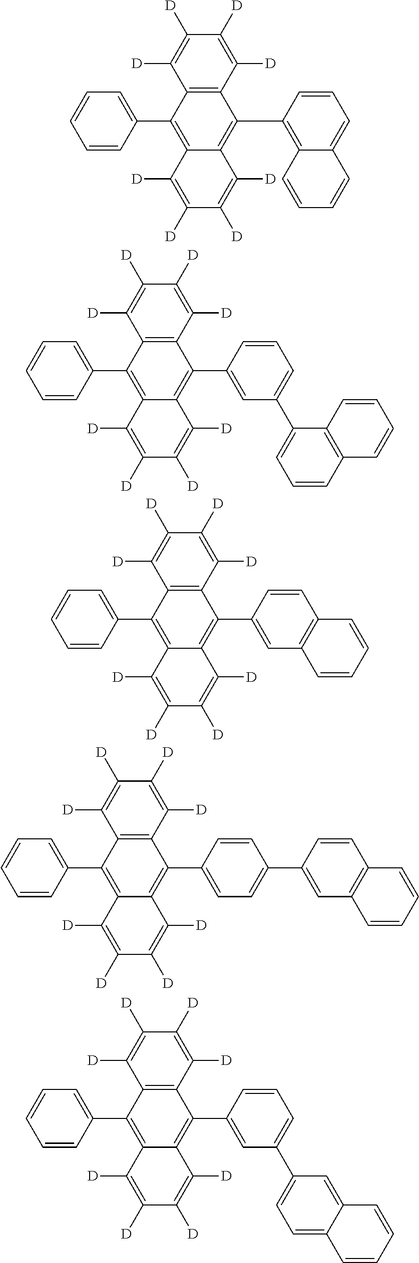

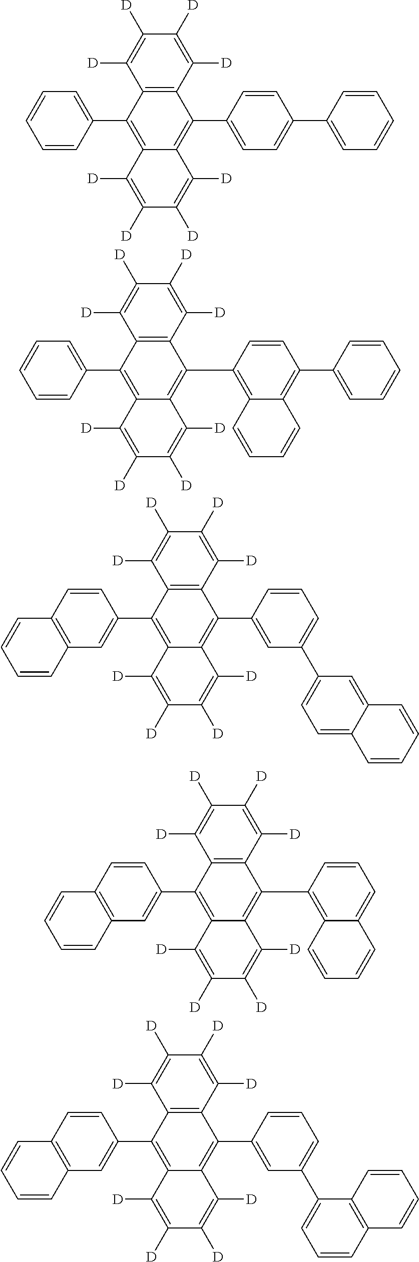

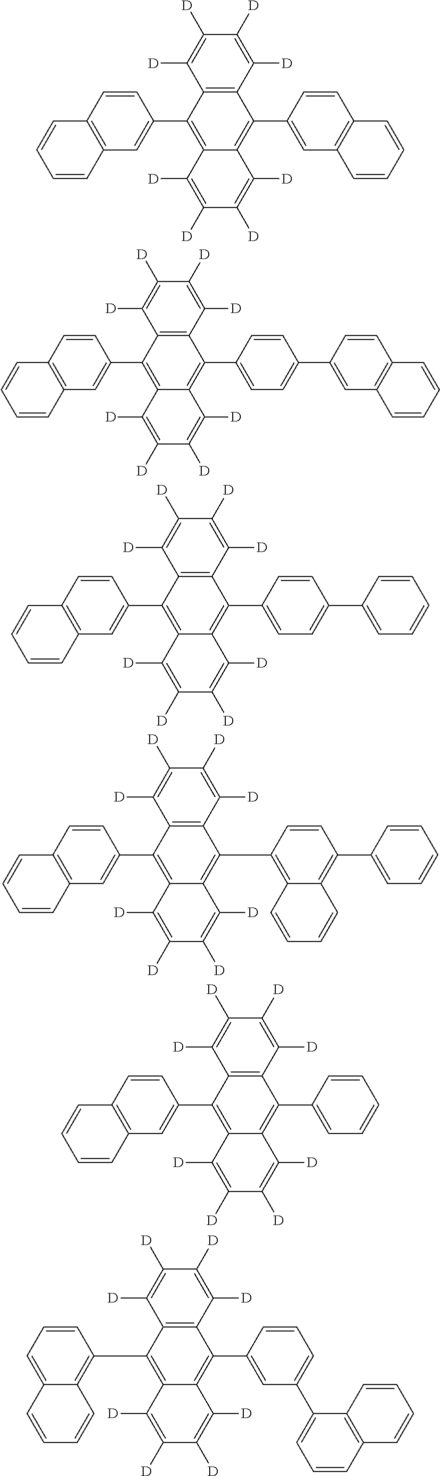

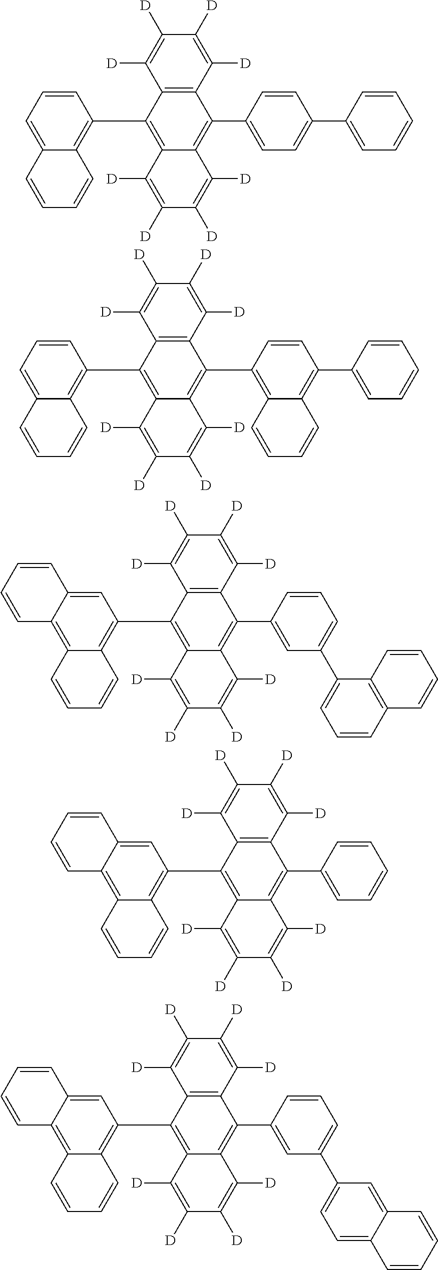

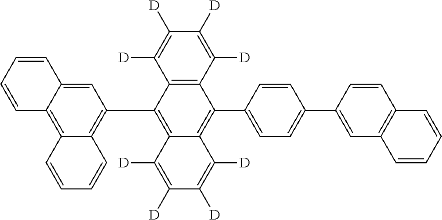 [SMILES: [2H]c1c([2H])c([2H])c2c(-c3cc4ccccc4c4ccccc34)c3c([2H])c([2H])c([2H])c([2H])c3c(-c3ccc(-c4ccc5ccccc5c4)cc3)c2c1[2H]]

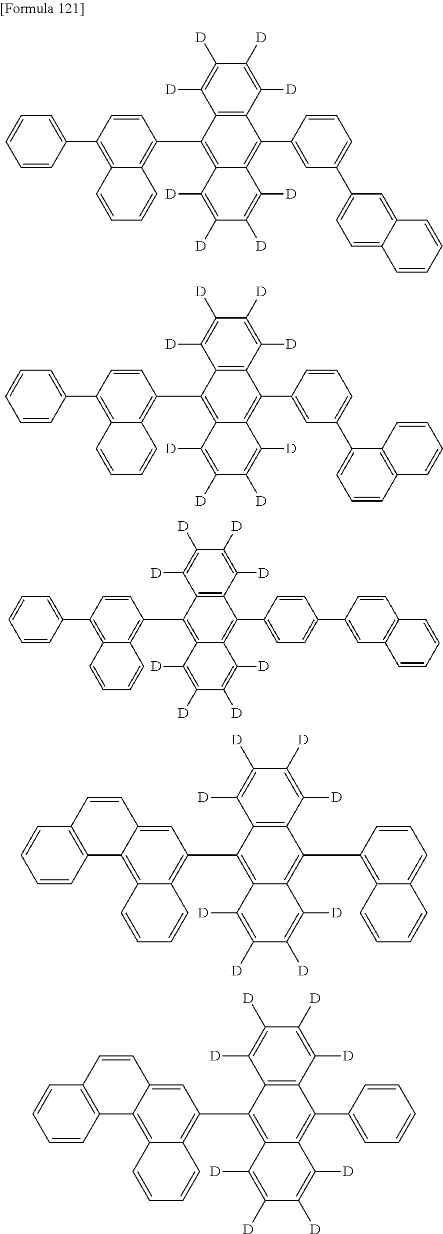

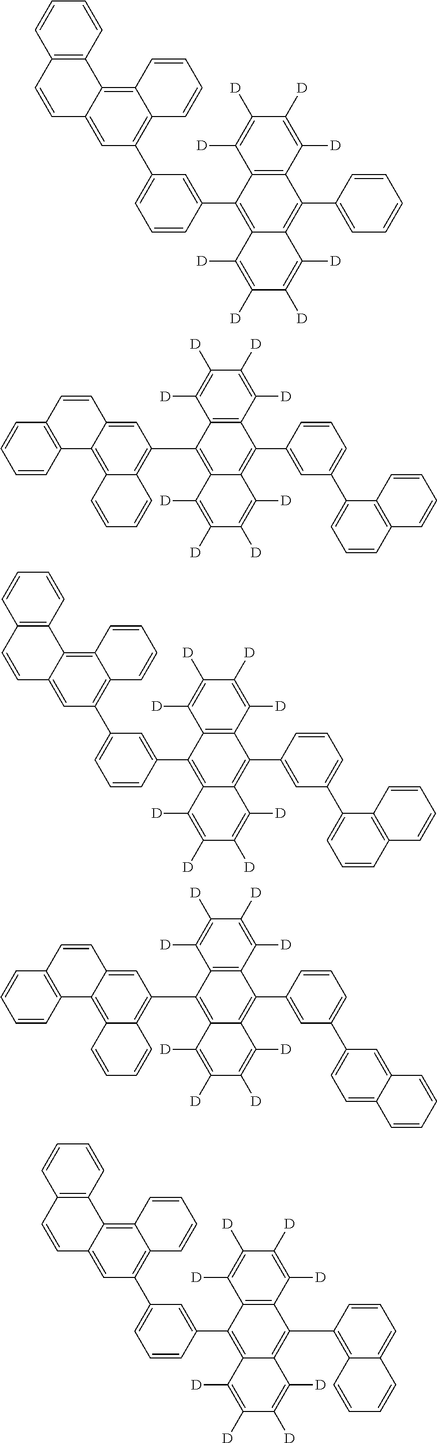

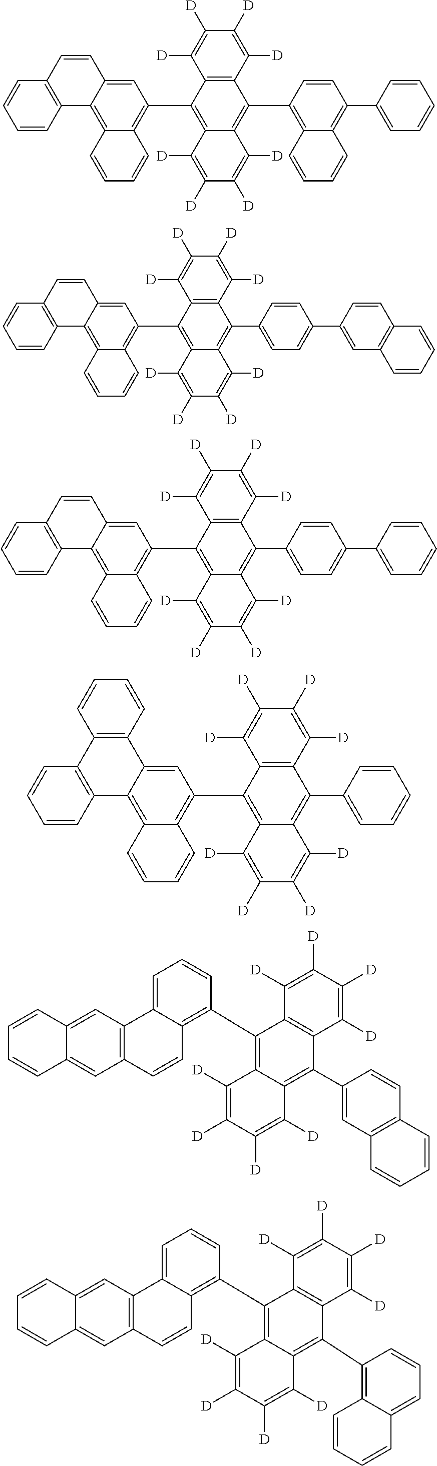

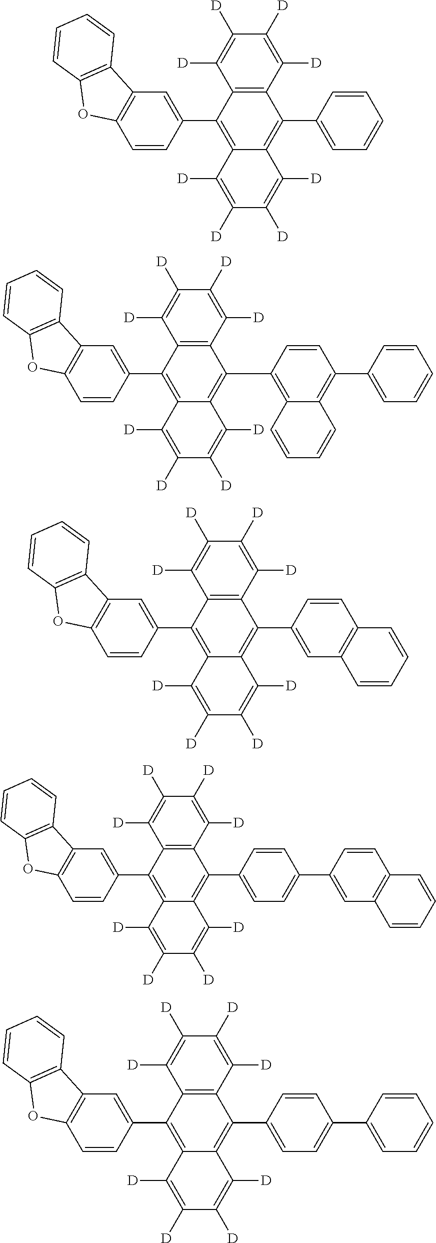

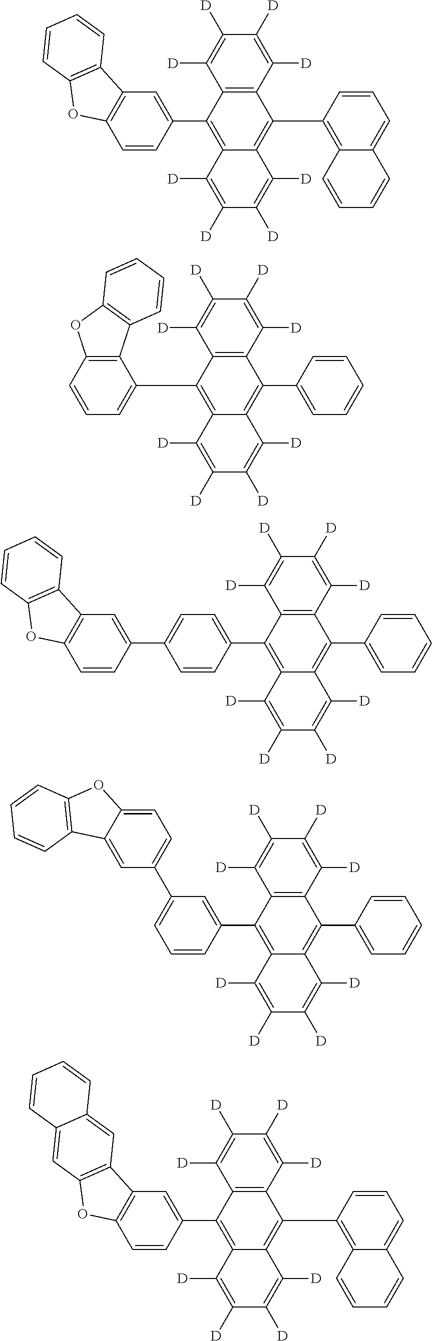

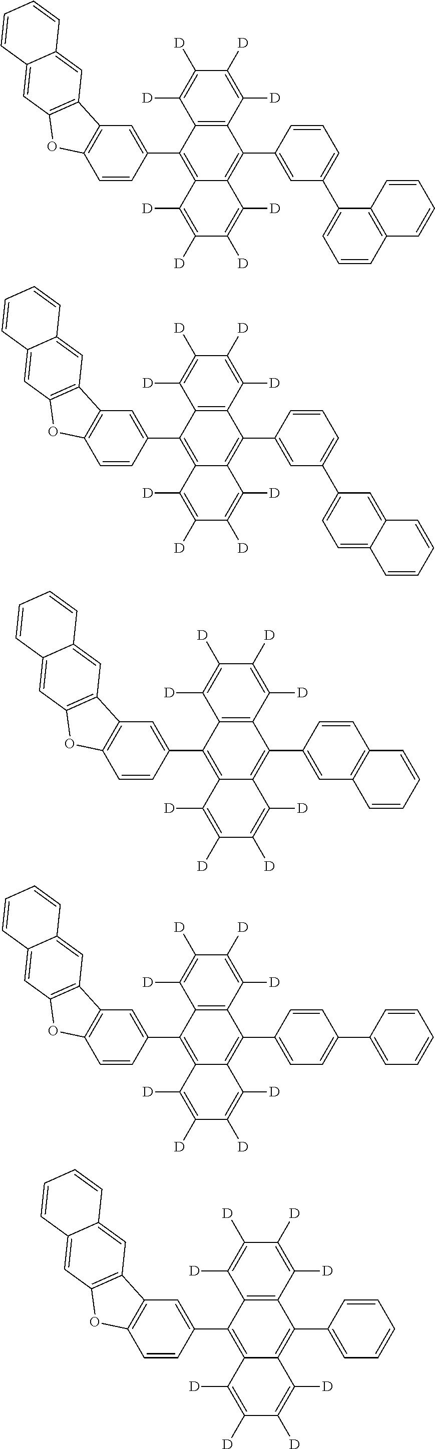

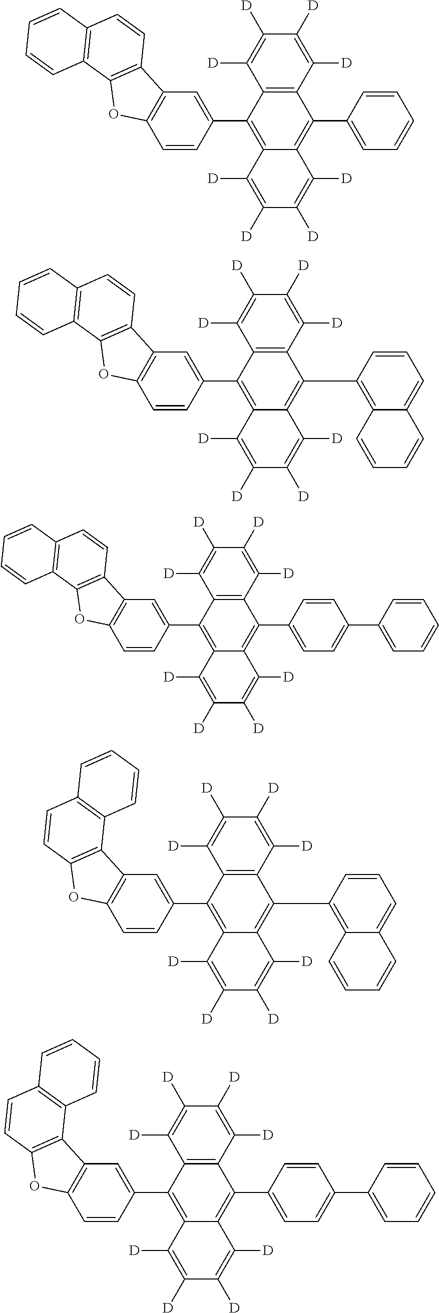

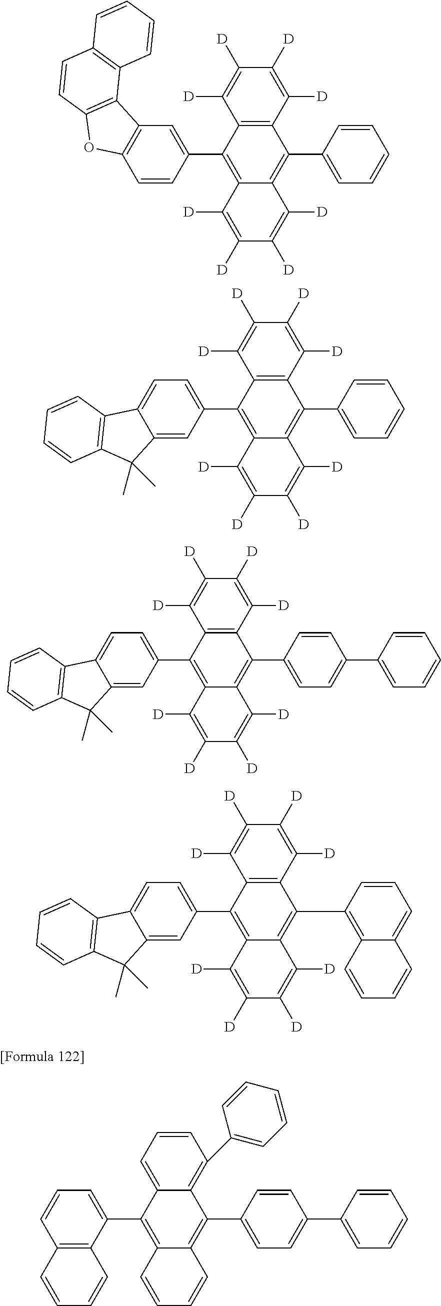

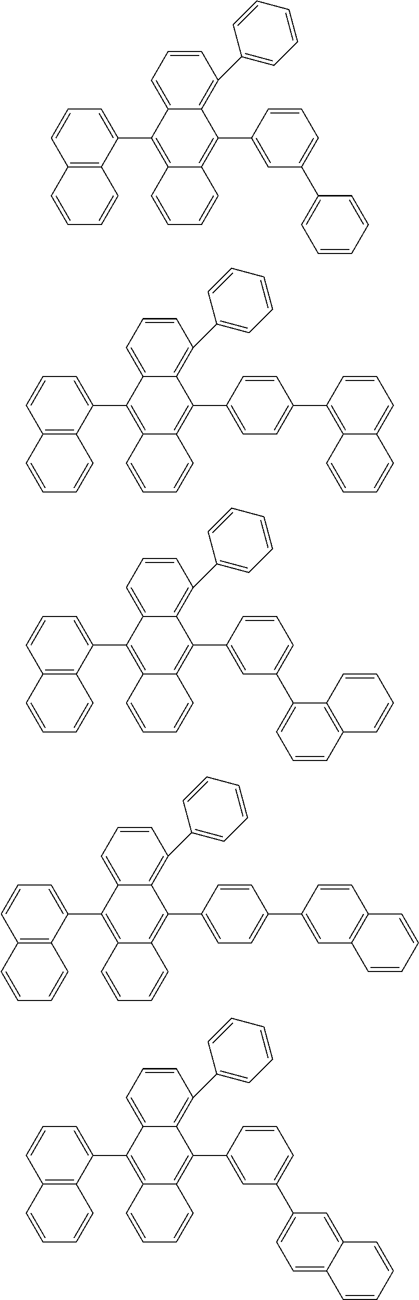

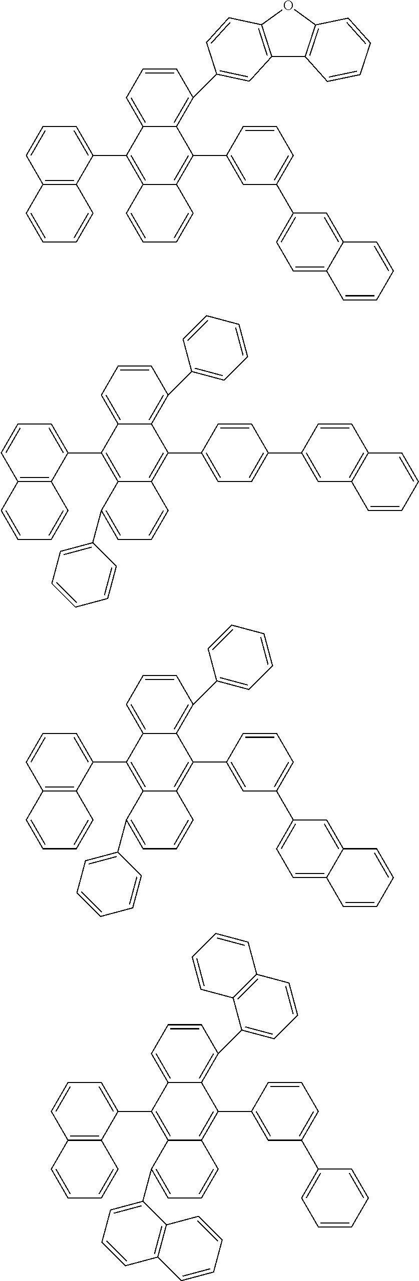

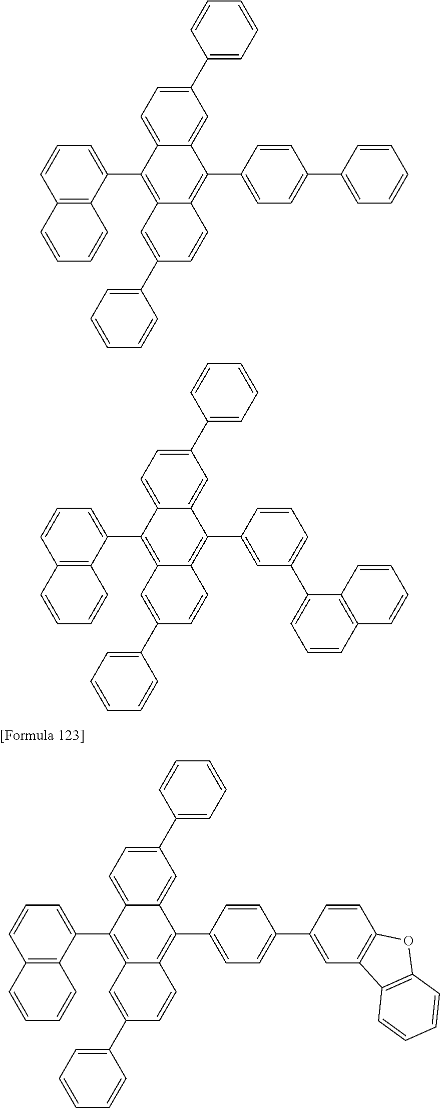

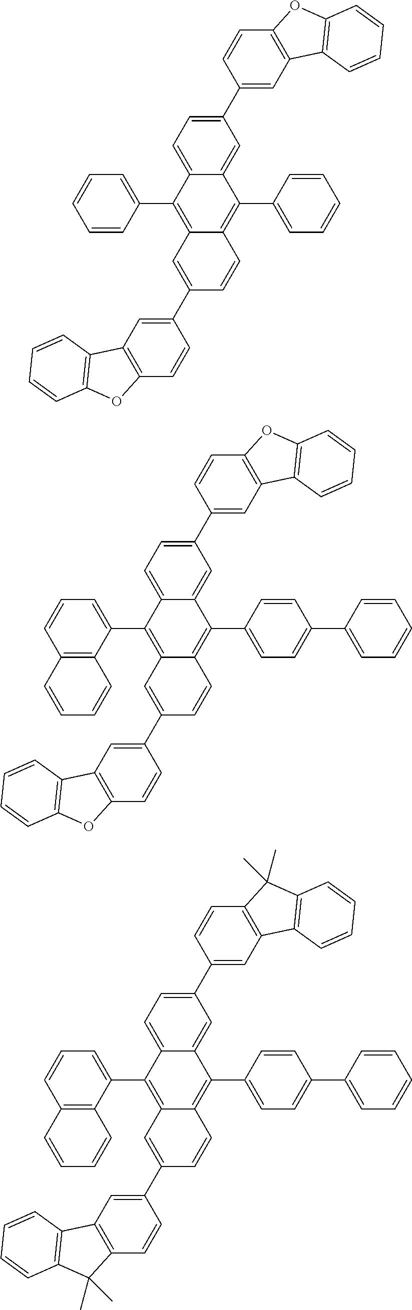

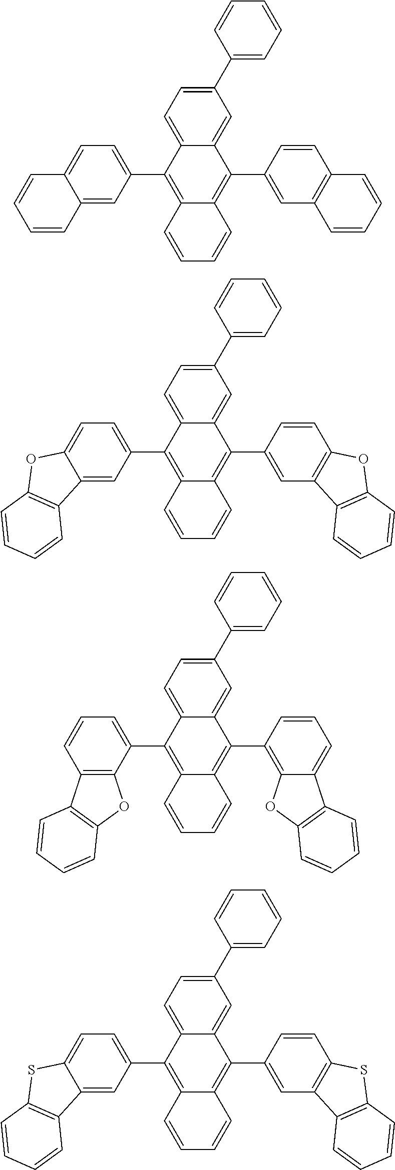

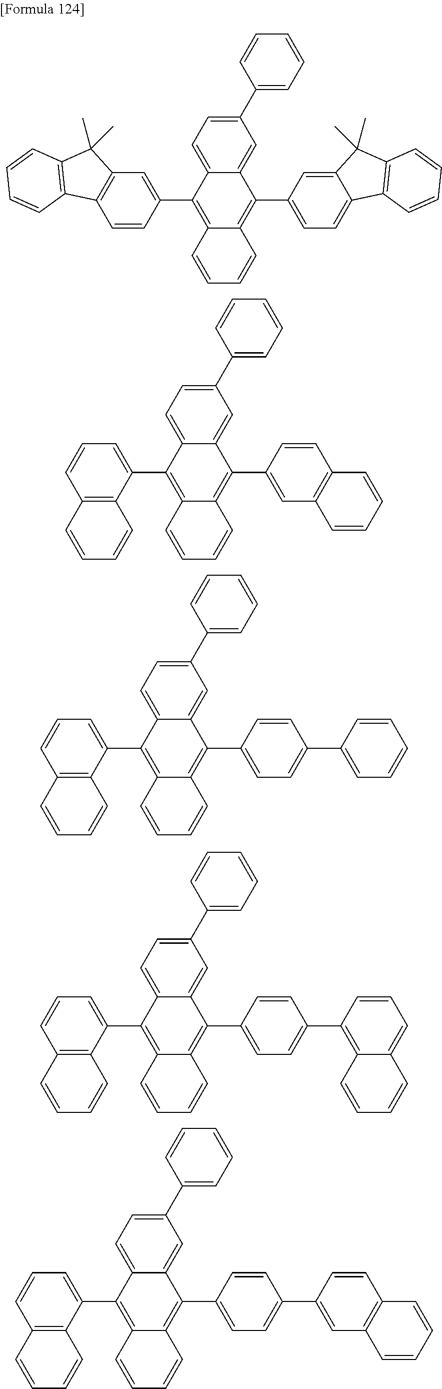

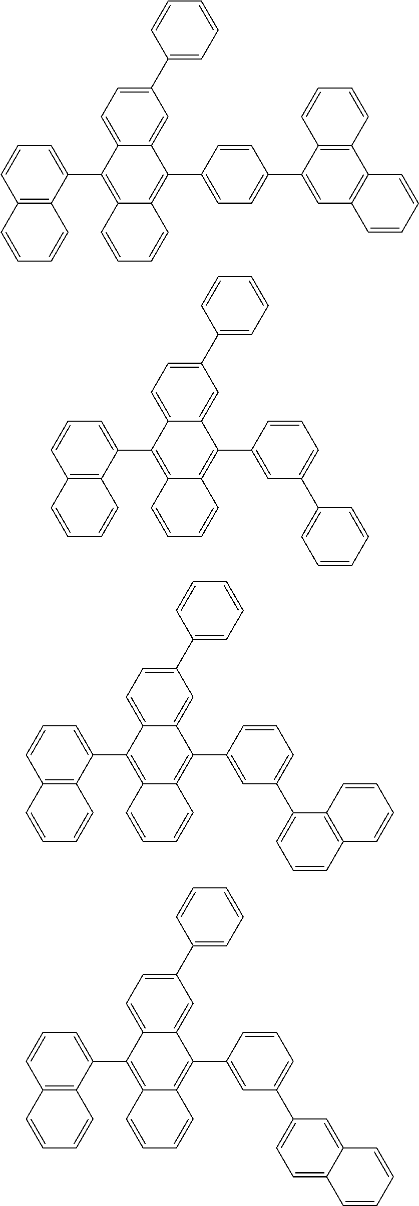

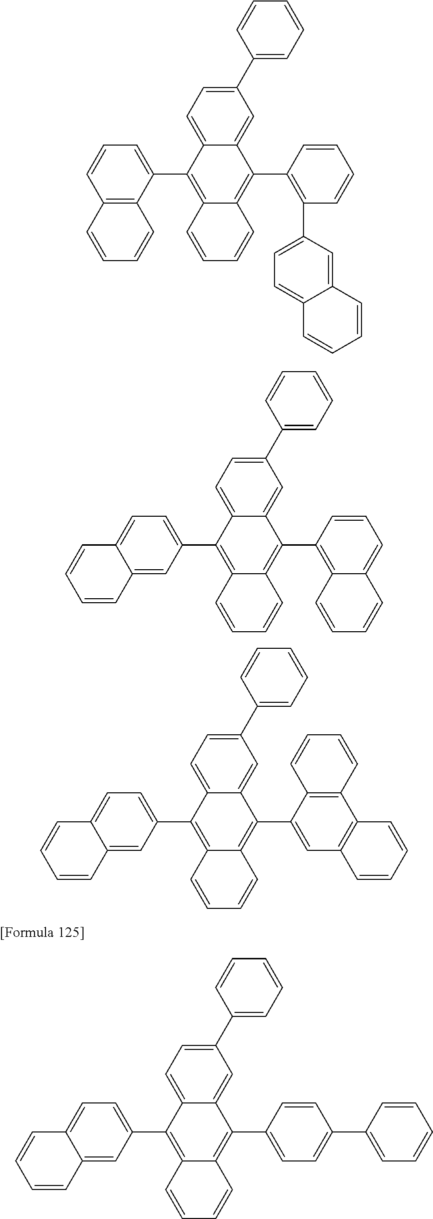

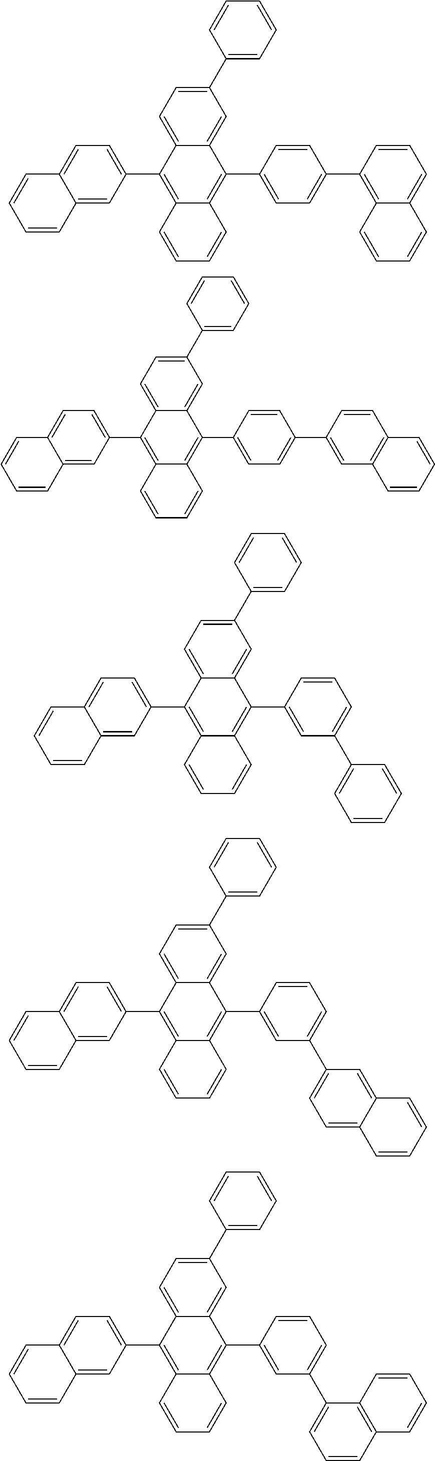

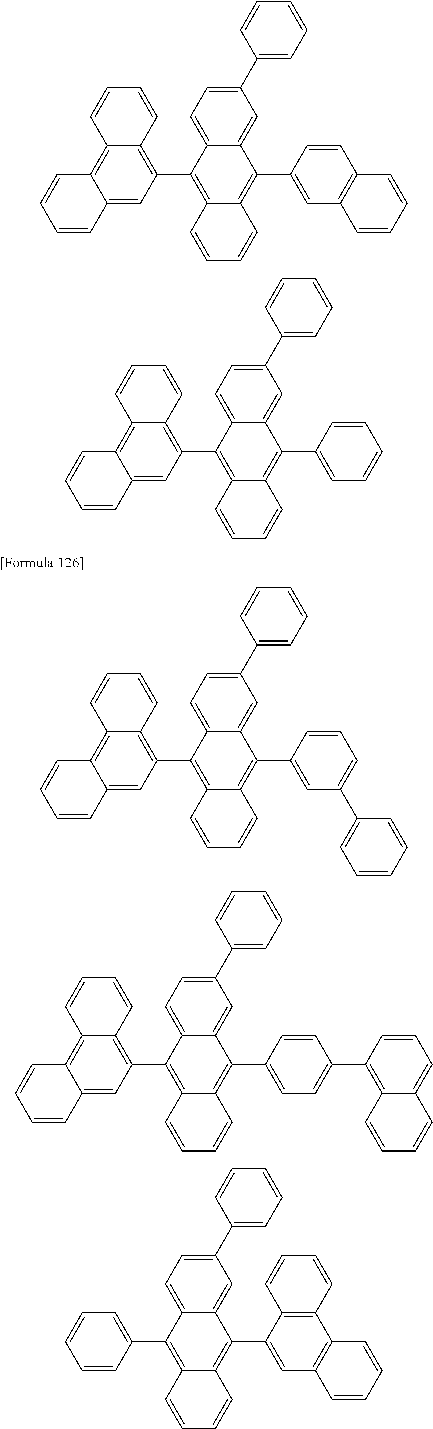

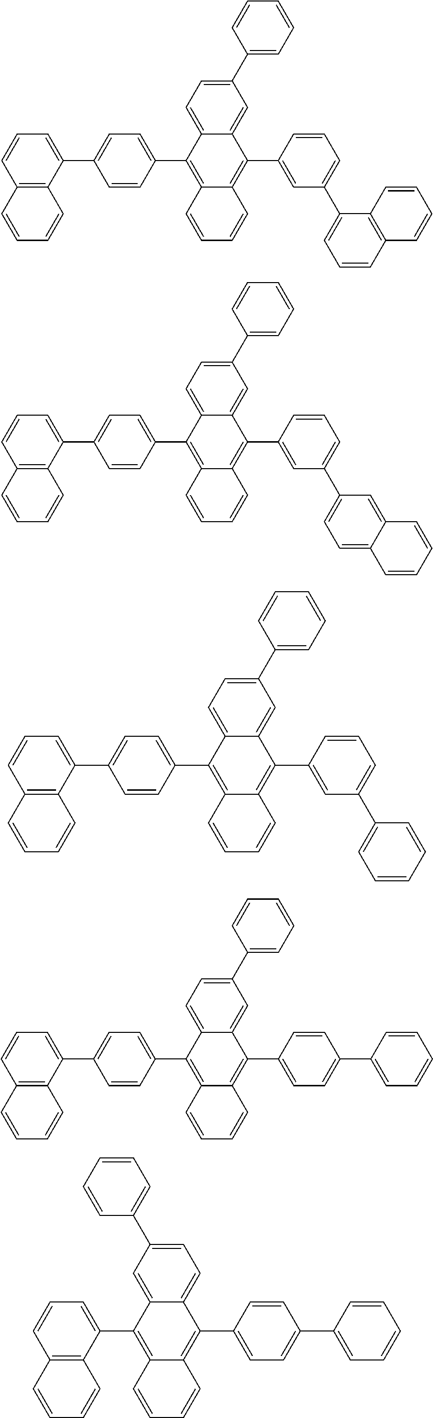

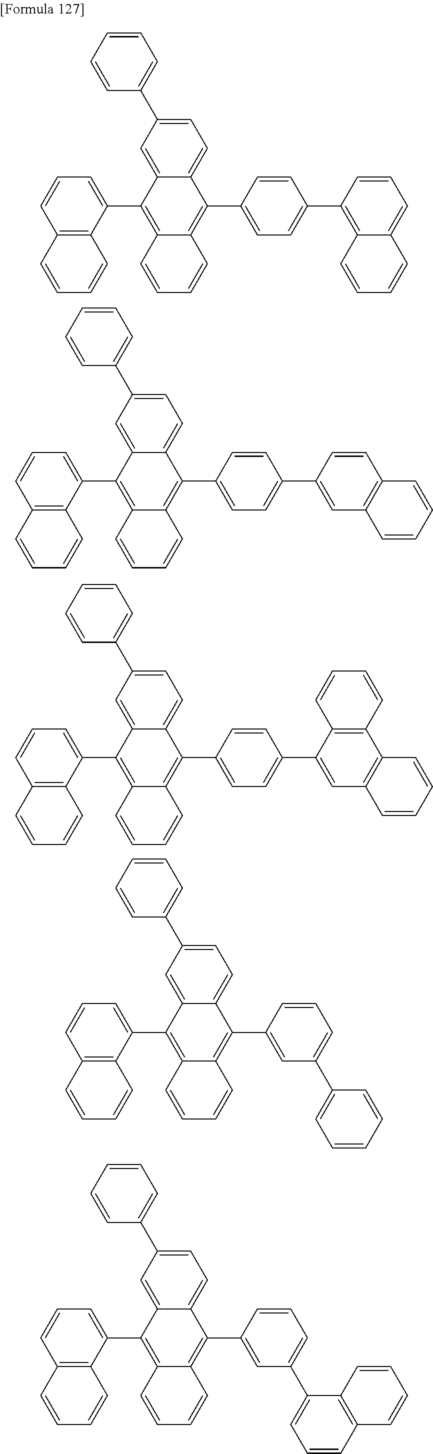

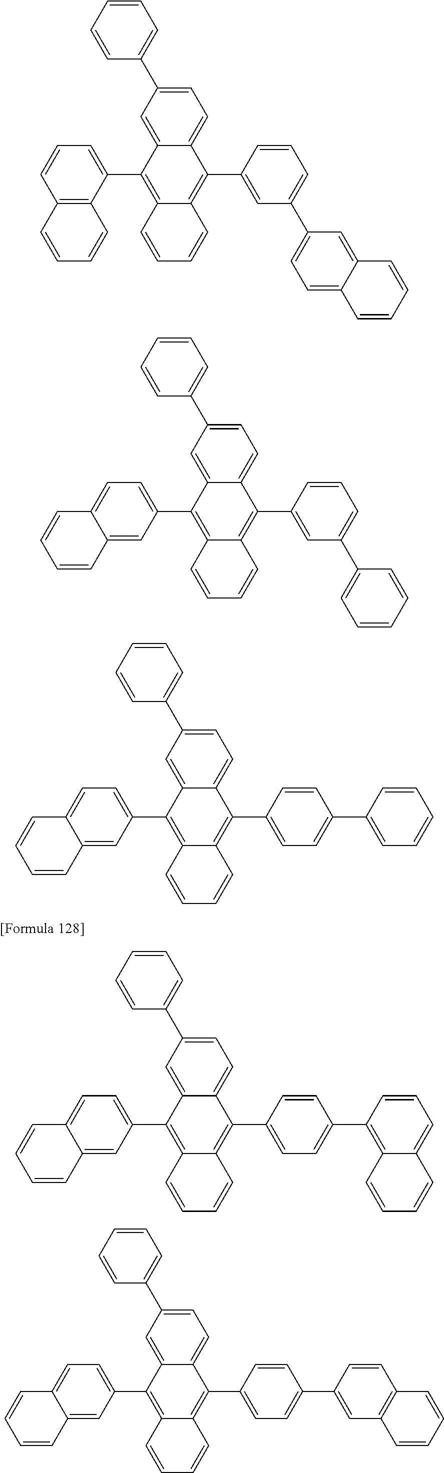

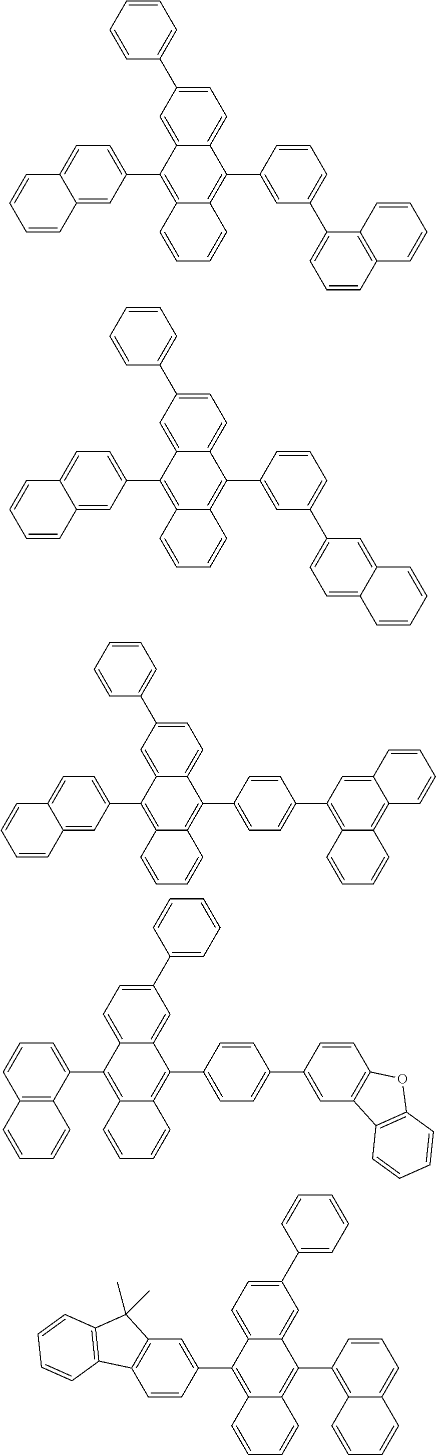

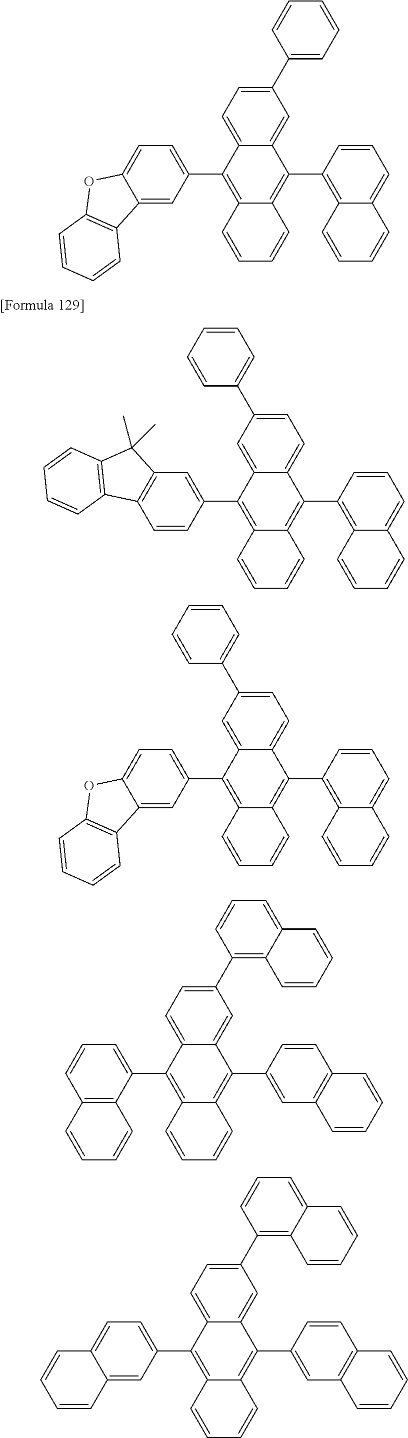

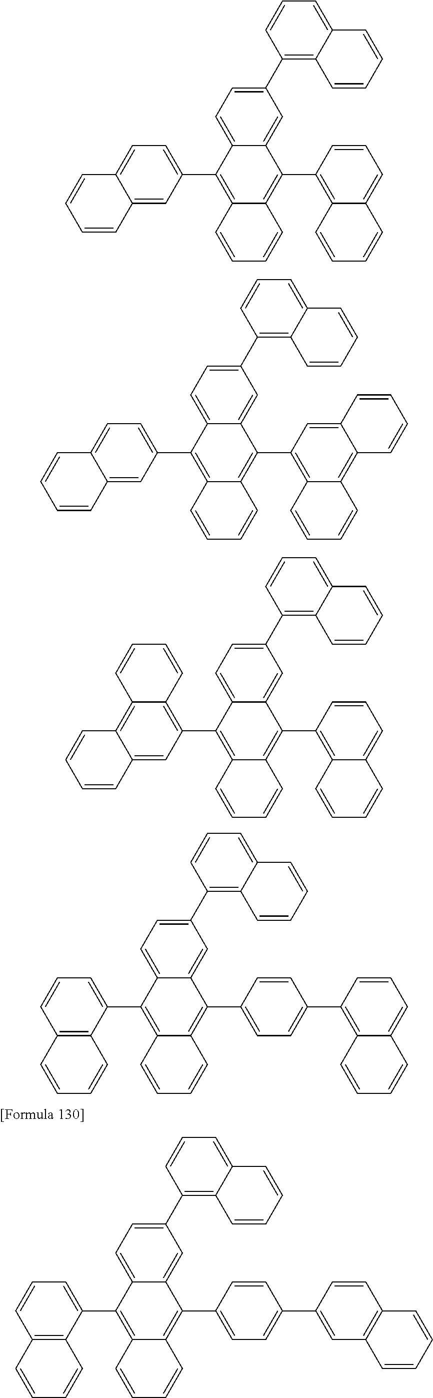

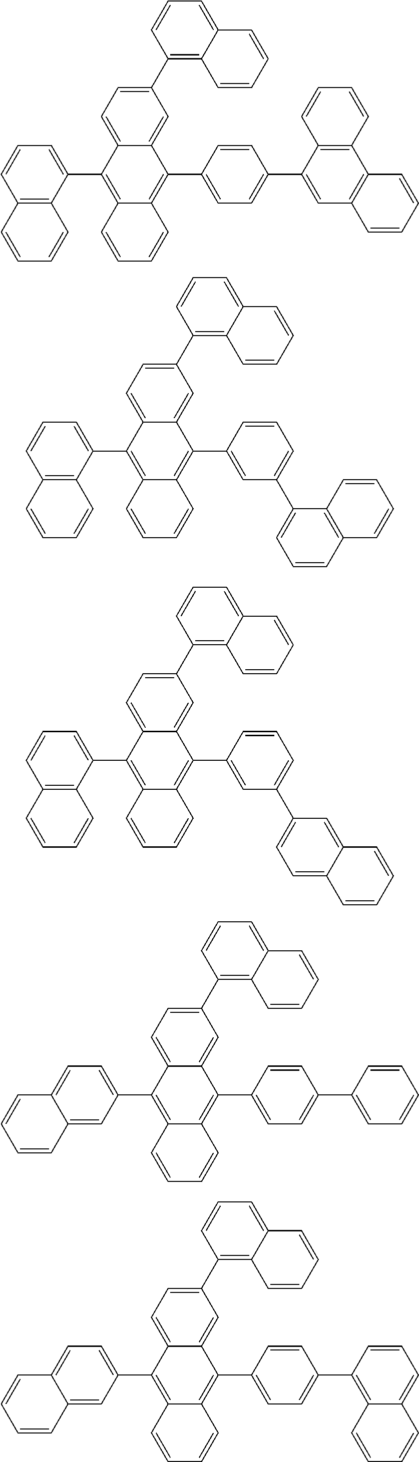

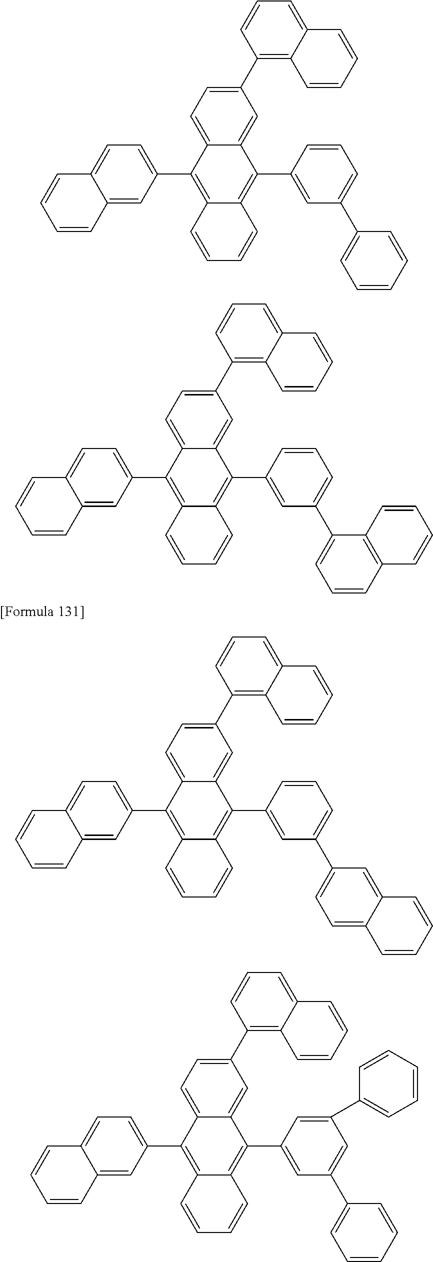

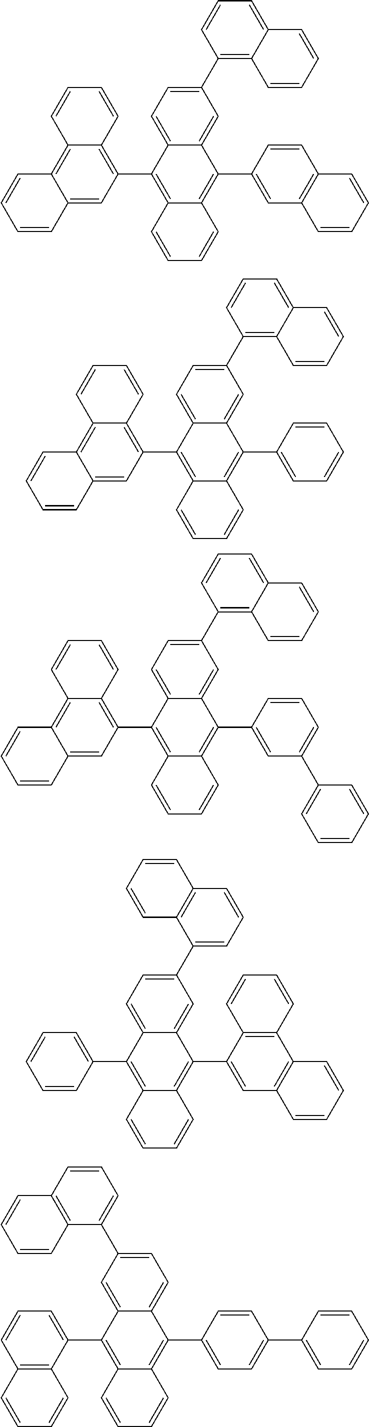

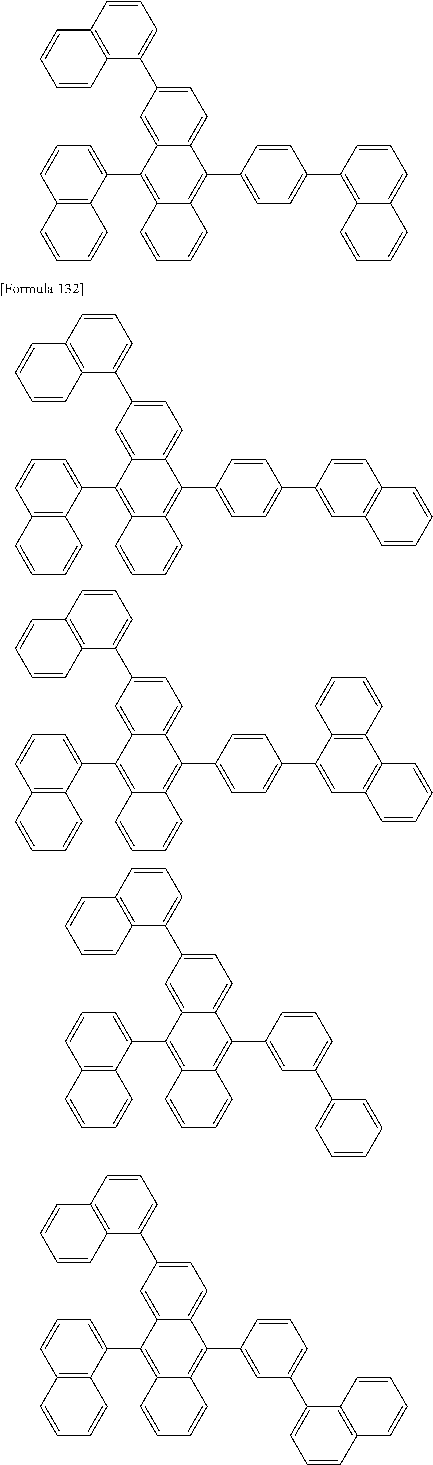

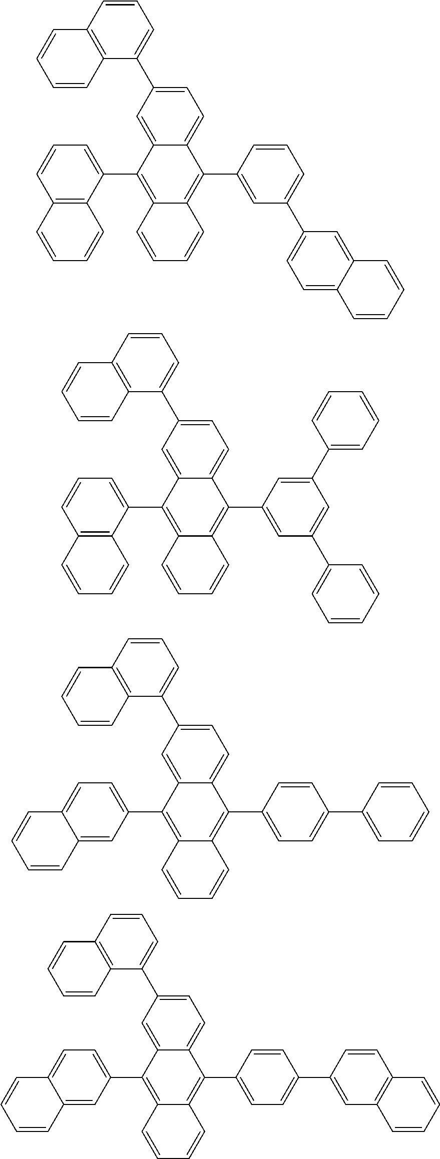

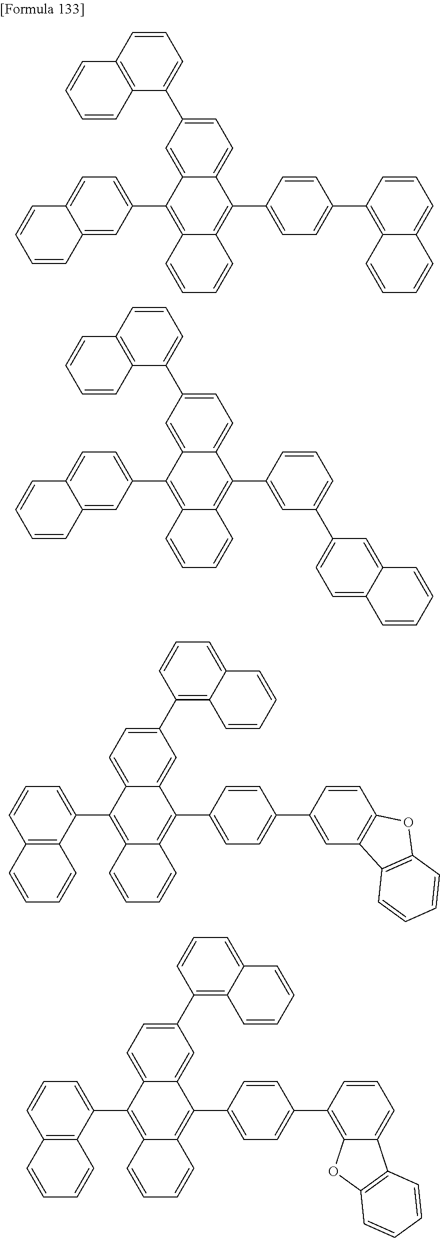

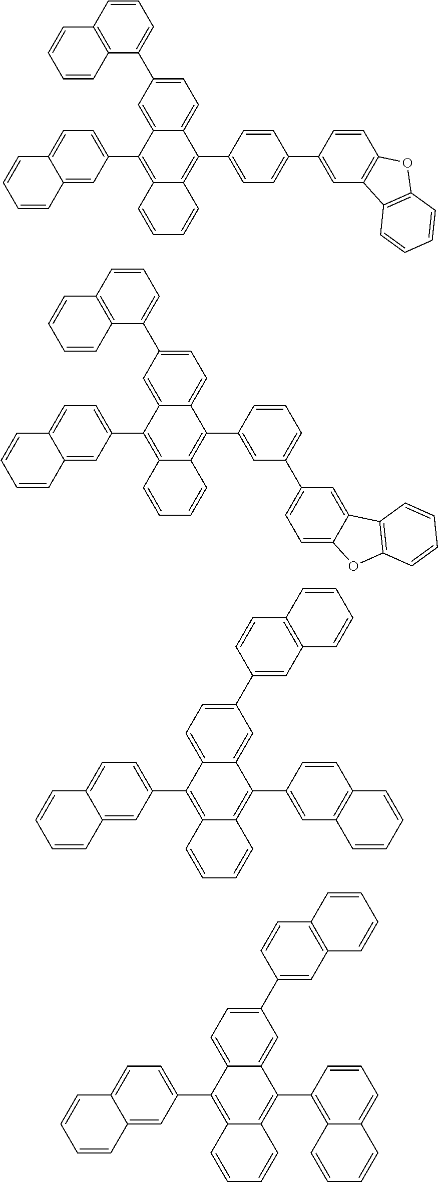

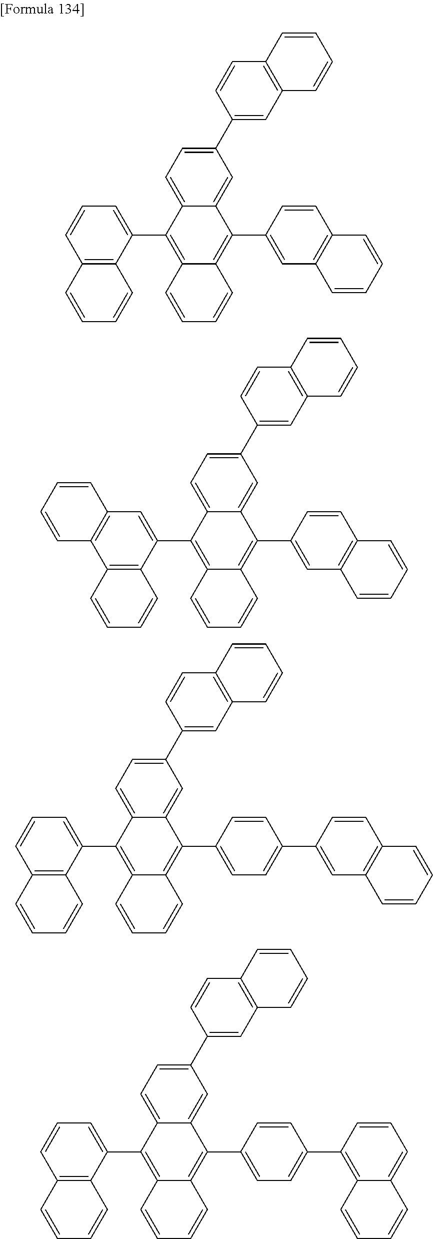

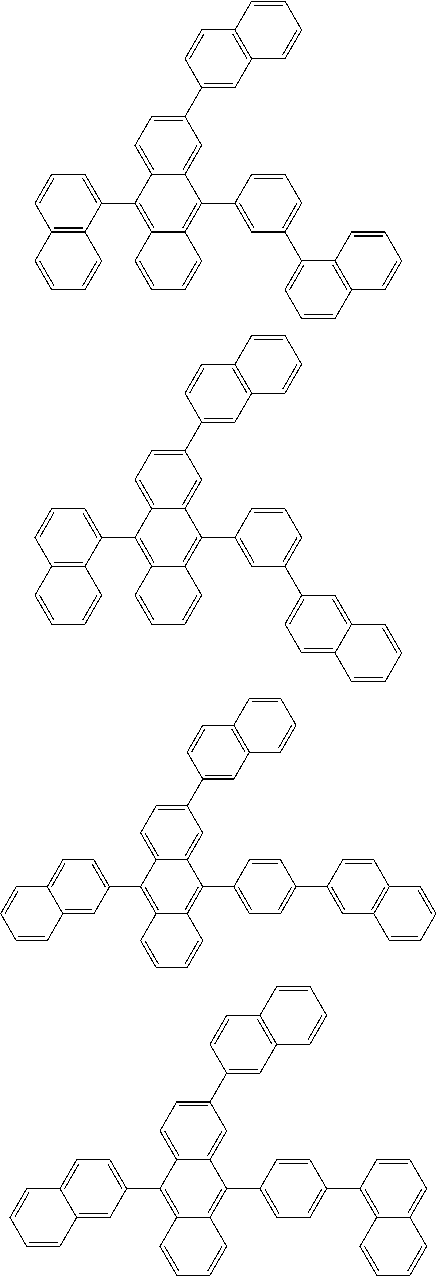

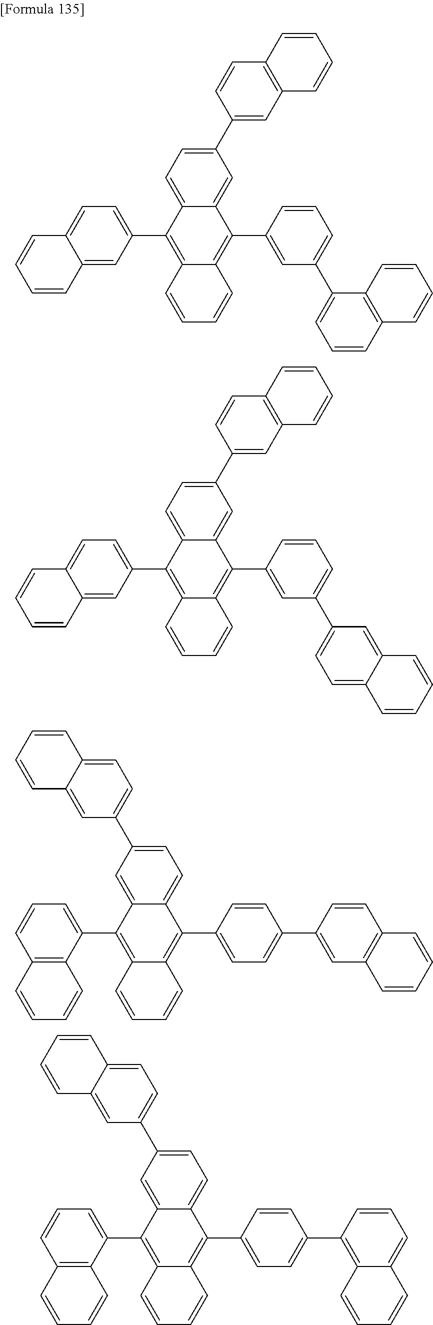

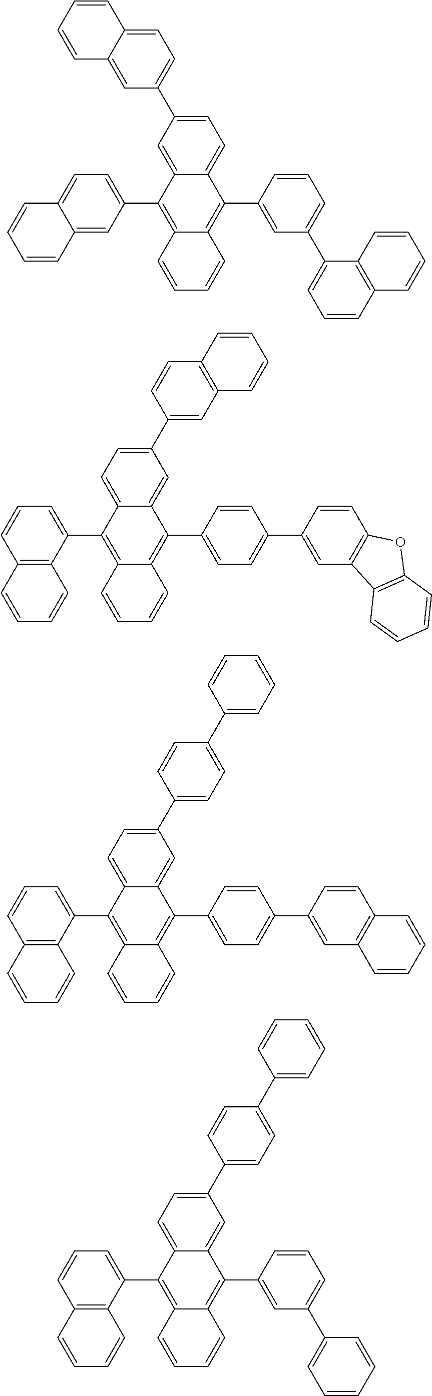

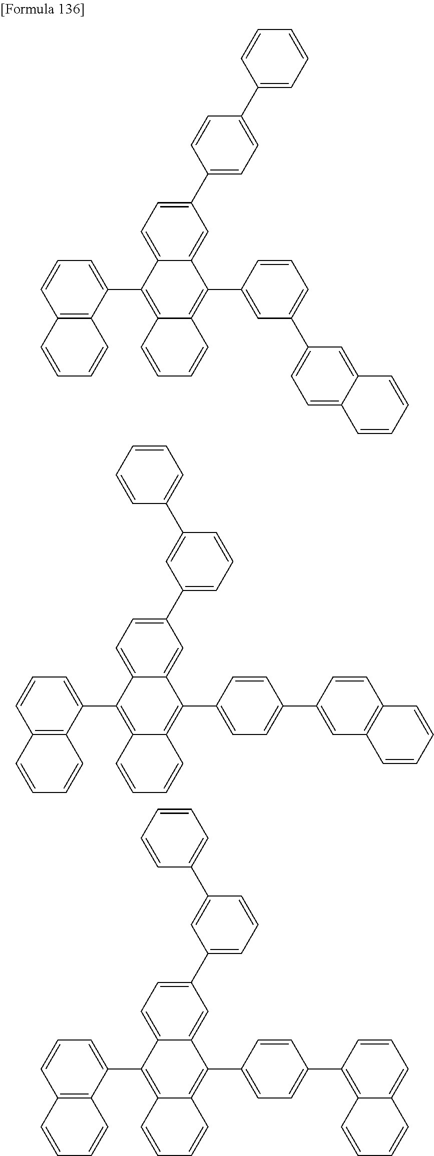

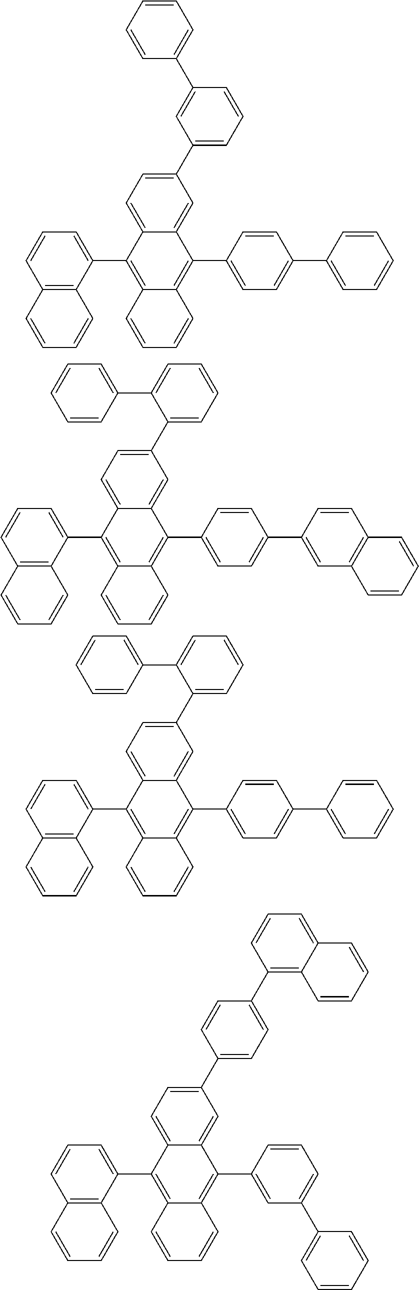

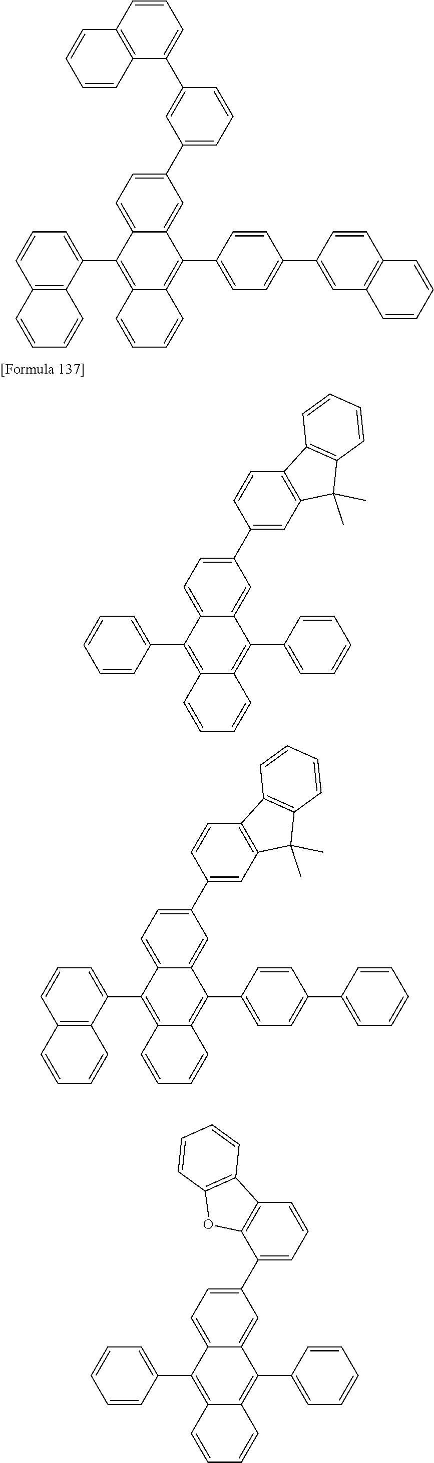

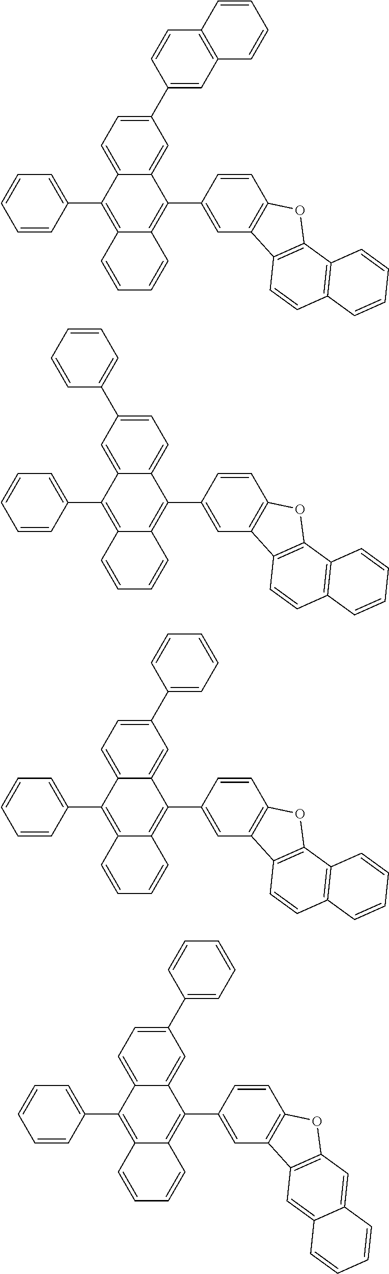

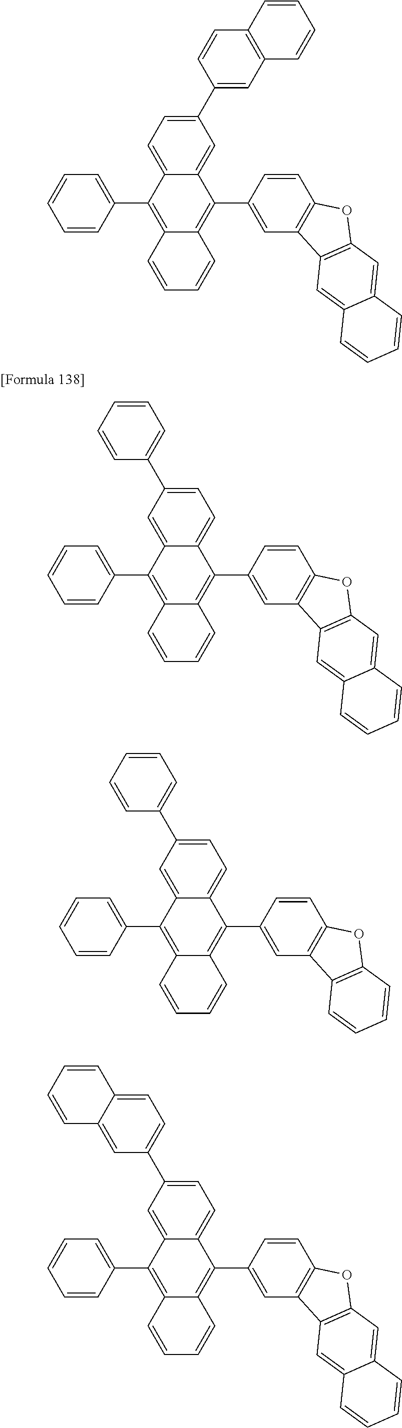 [SMILES: c1ccc(-c2c3ccccc3c(-c3ccc4oc5cc6ccccc6cc5c4c3)c3cc(-c4ccc5ccccc5c4)ccc23)cc1 ; c1ccc(-c2ccc3c(-c4ccc5oc6cc7ccccc7cc6c5c4)c4ccccc4c(-c4ccccc4)c3c2)cc1 ; c1ccc(-c2ccc3c(-c4ccc5oc6ccccc6c5c4)c4ccccc4c(-c4ccccc4)c3c2)cc1 ; c1ccc(-c2c3ccccc3c(-c3ccc4oc5cc6ccccc6cc5c4c3)c3ccc(-c4ccc5ccccc5c4)cc23)cc1]

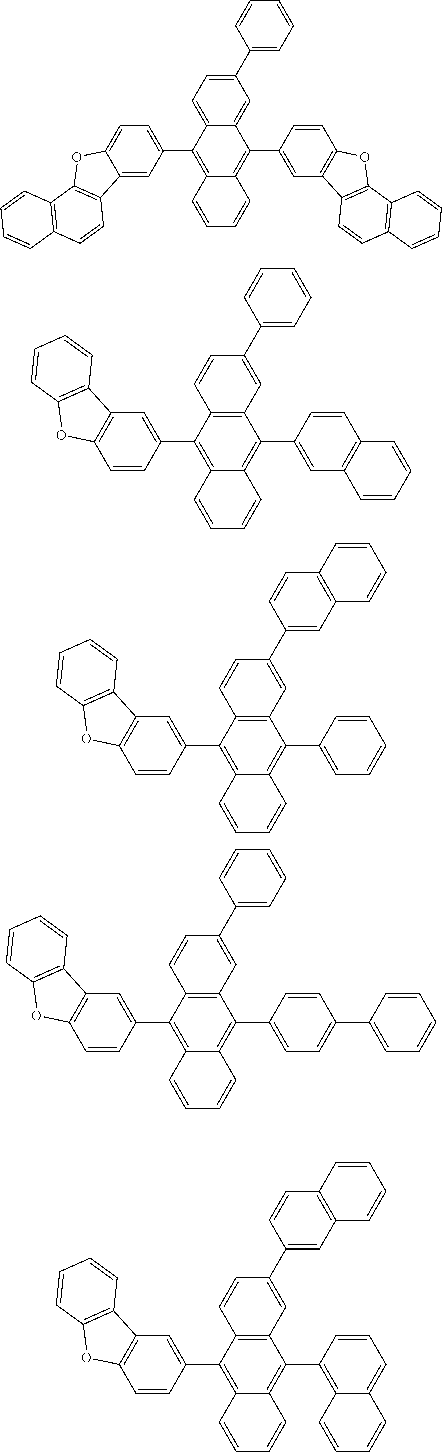

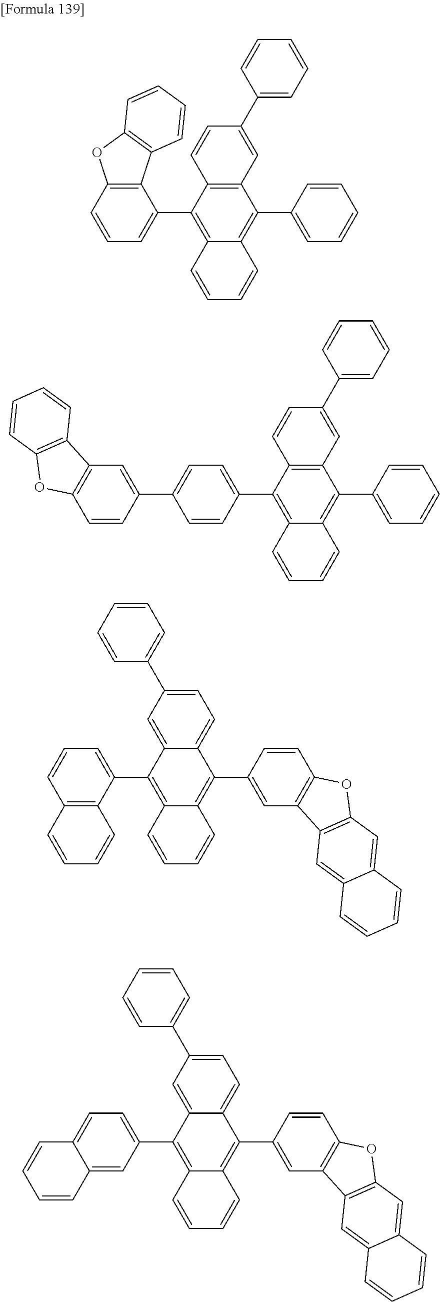 [SMILES: c1ccc(-c2ccc3c(-c4cccc5oc6ccccc6c45)c4ccccc4c(-c4ccccc4)c3c2)cc1 ; c1ccc(-c2ccc3c(-c4ccc(-c5ccc6oc7ccccc7c6c5)cc4)c4ccccc4c(-c4ccccc4)c3c2)cc1 ; c1ccc(-c2ccc3c(-c4ccc5oc6cc7ccccc7cc6c5c4)c4ccccc4c(-c4cccc5ccccc45)c3c2)cc1 ; c1ccc(-c2ccc3c(-c4ccc5oc6cc7ccccc7cc6c5c4)c4ccccc4c(-c4ccc5ccccc5c4)c3c2)cc1]

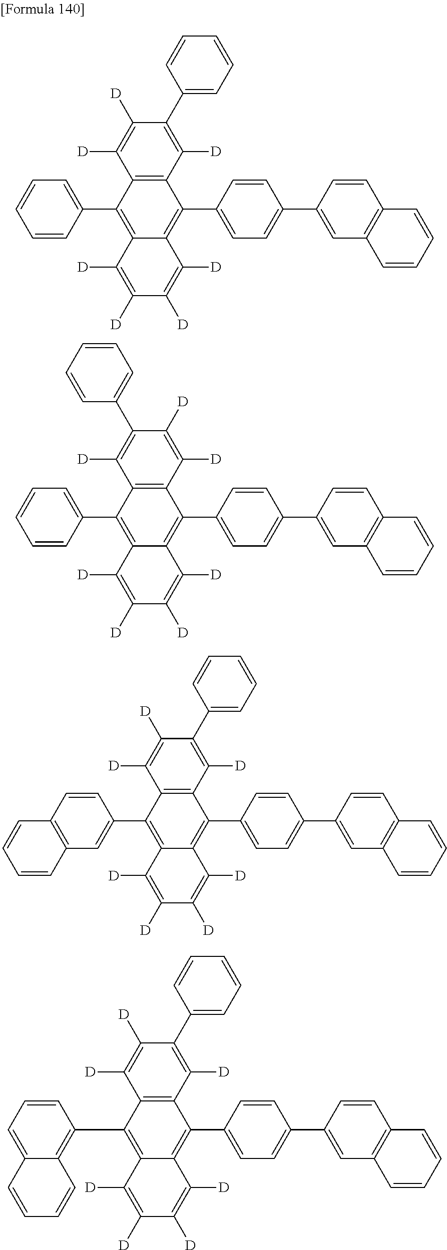

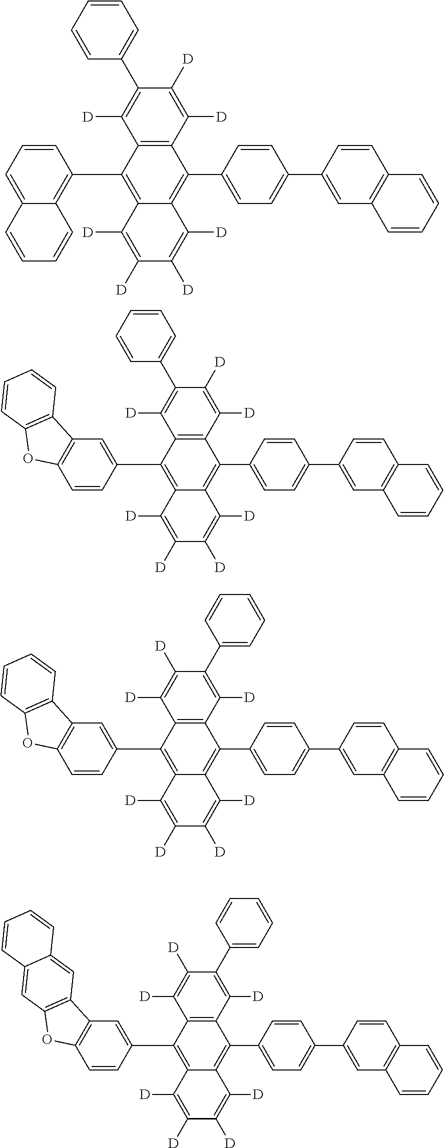

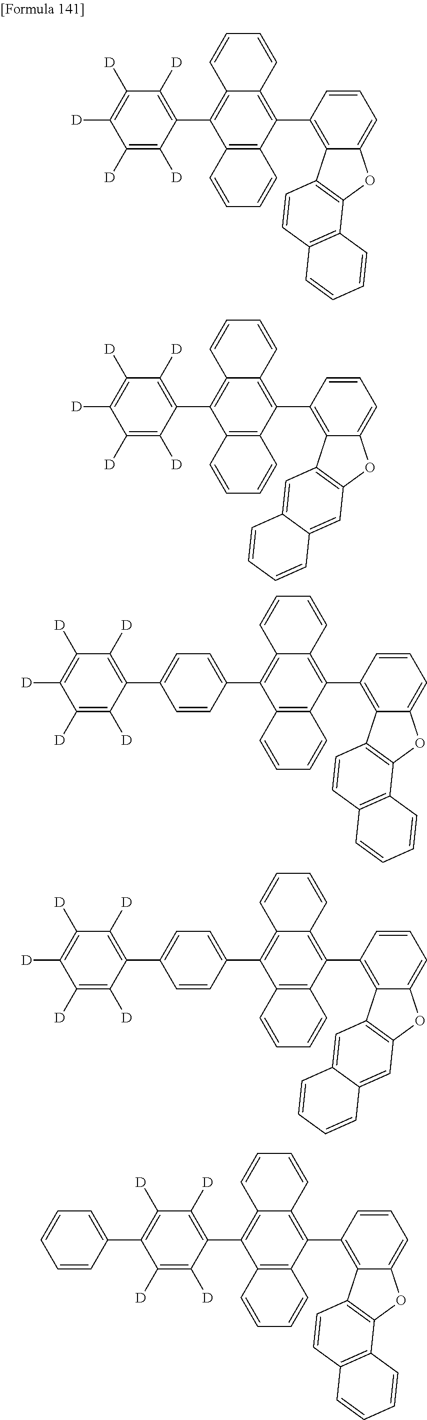

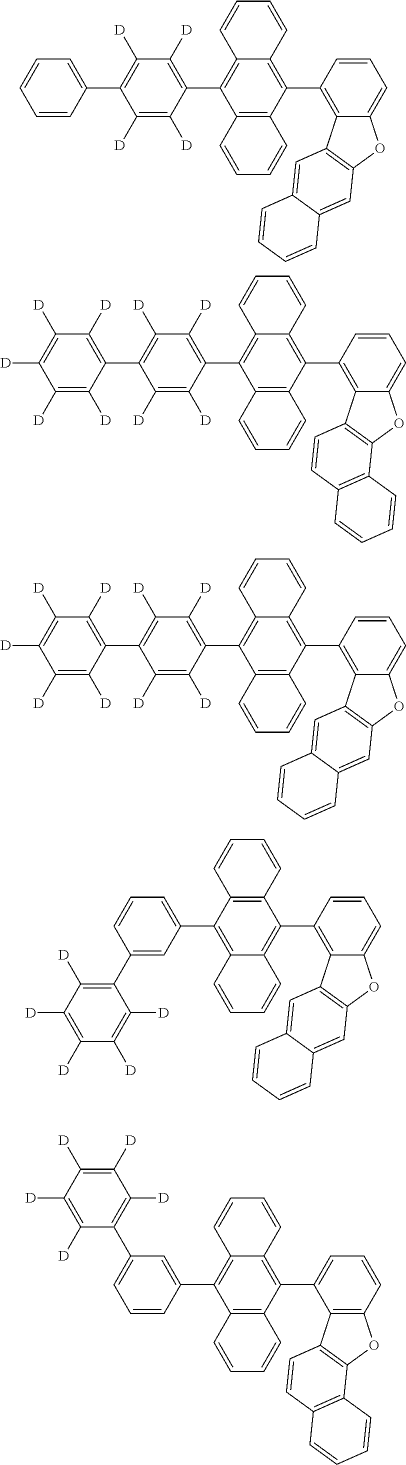

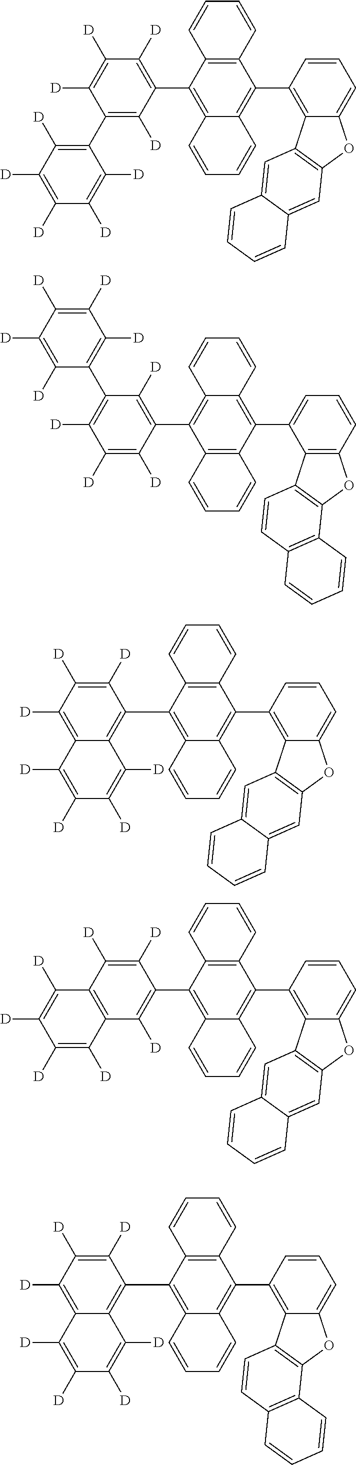

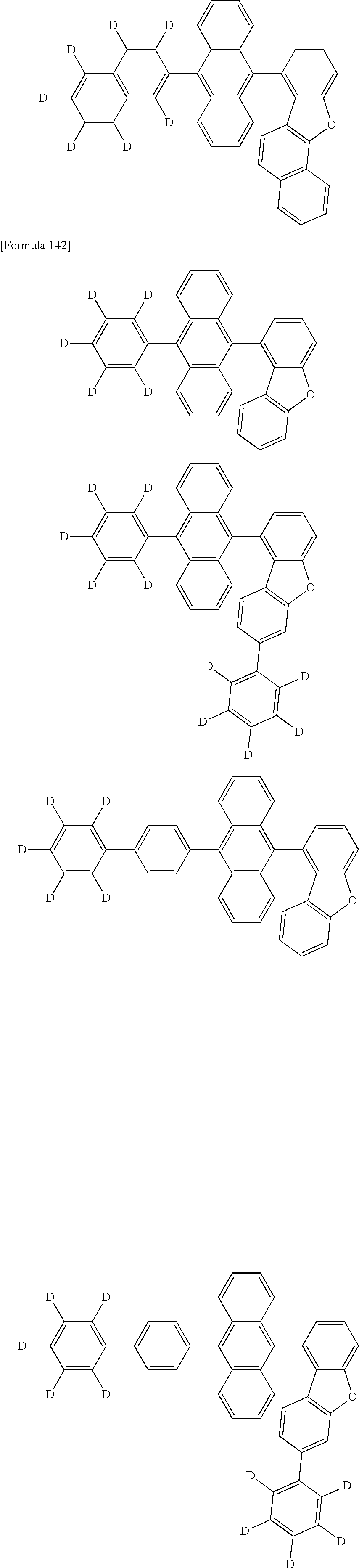

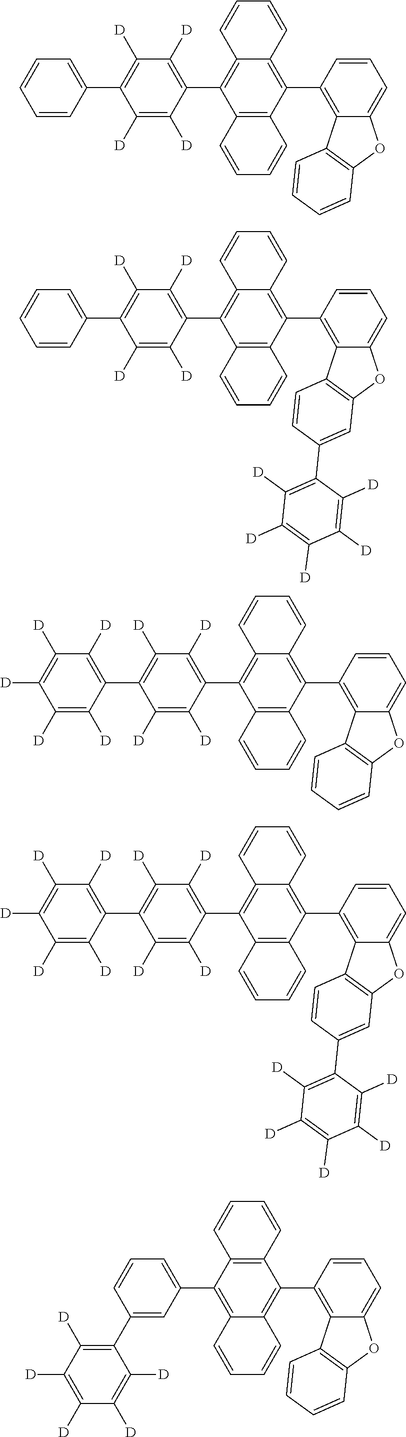

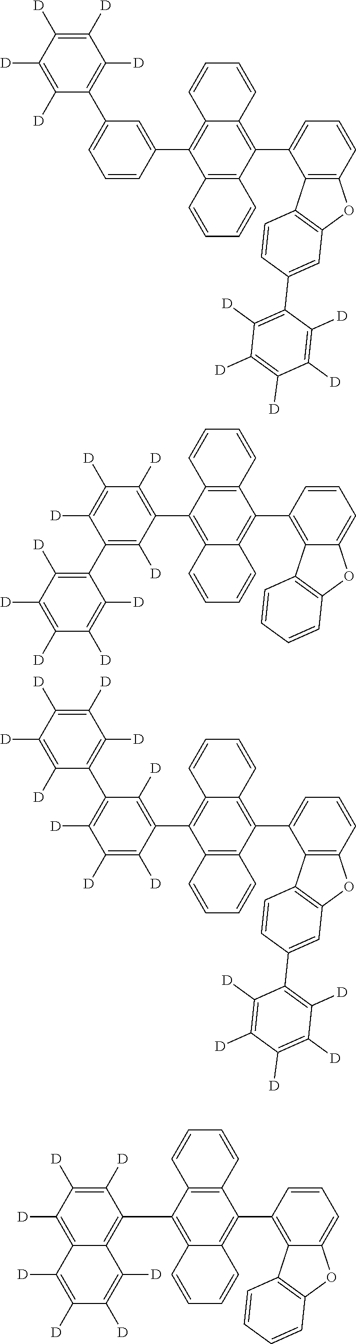

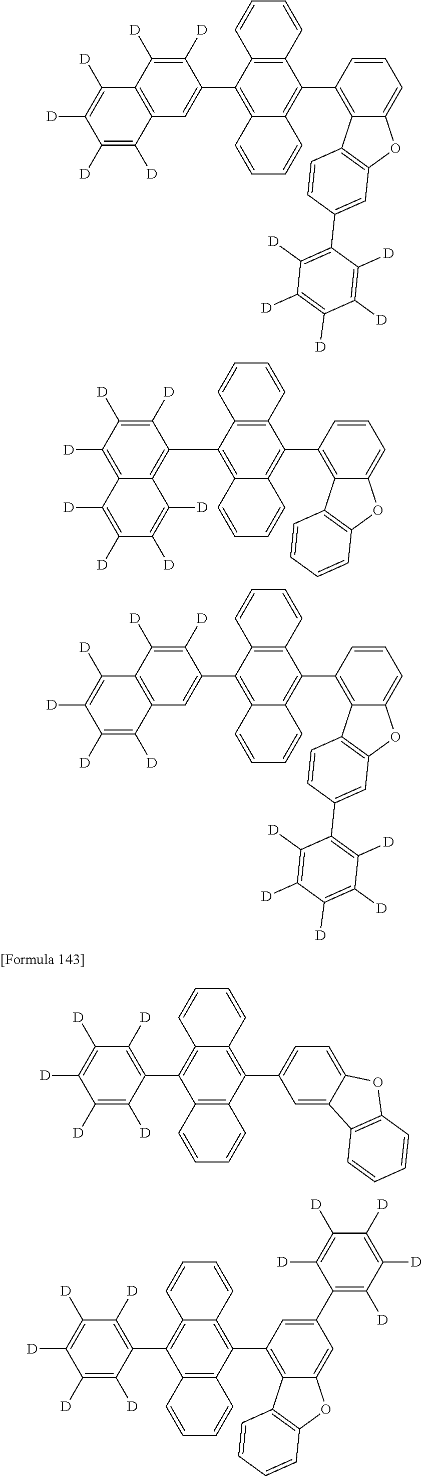

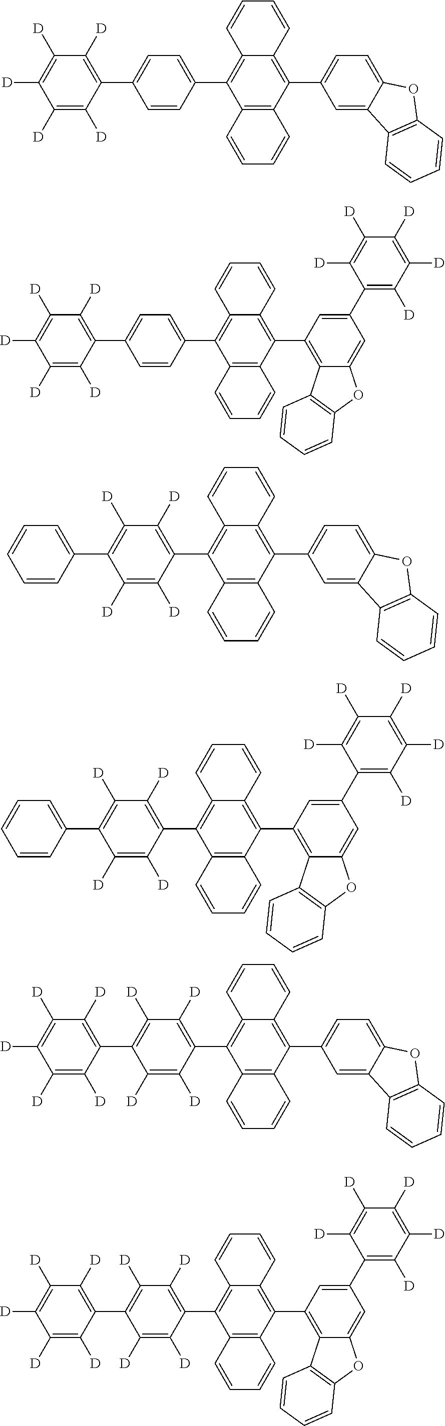

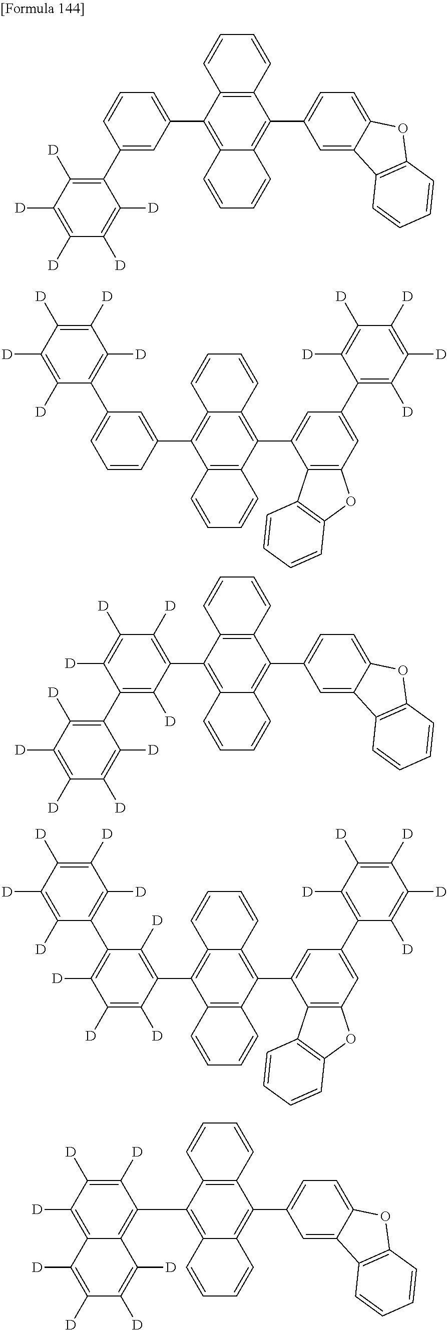

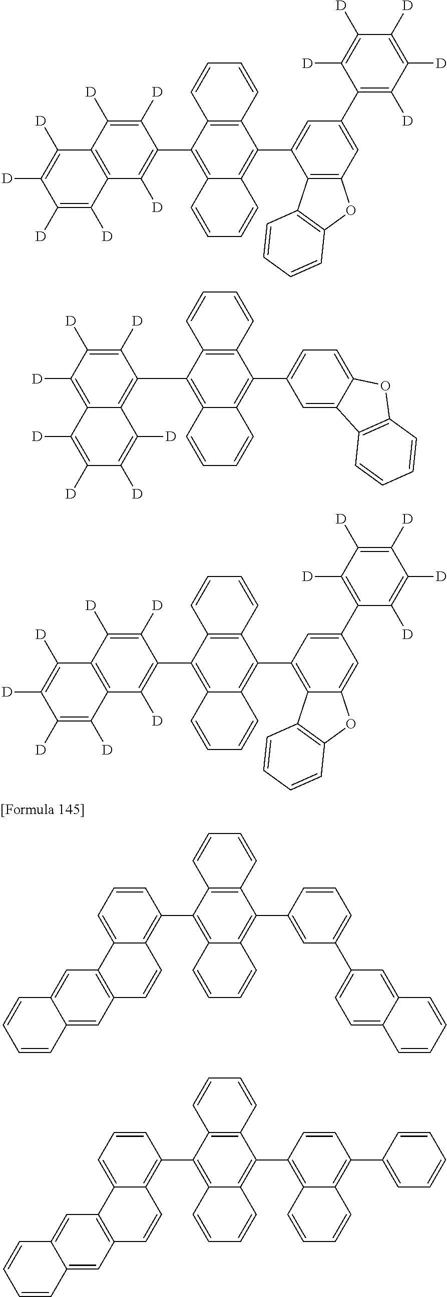

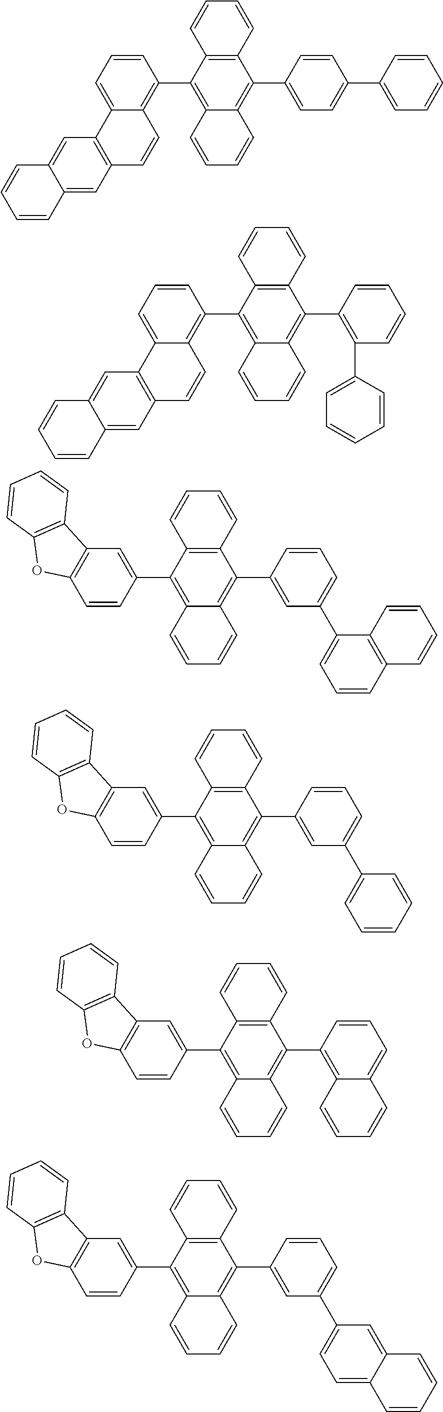

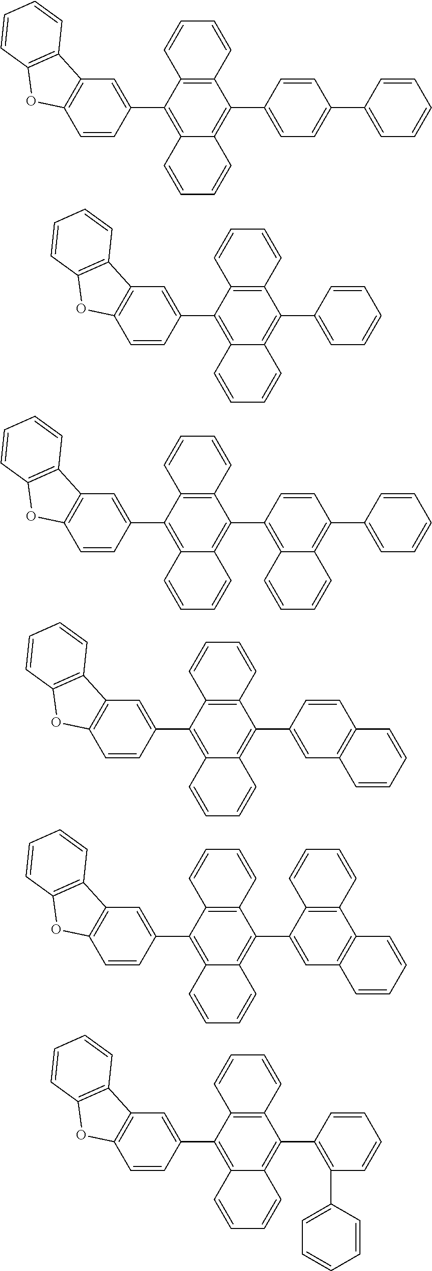

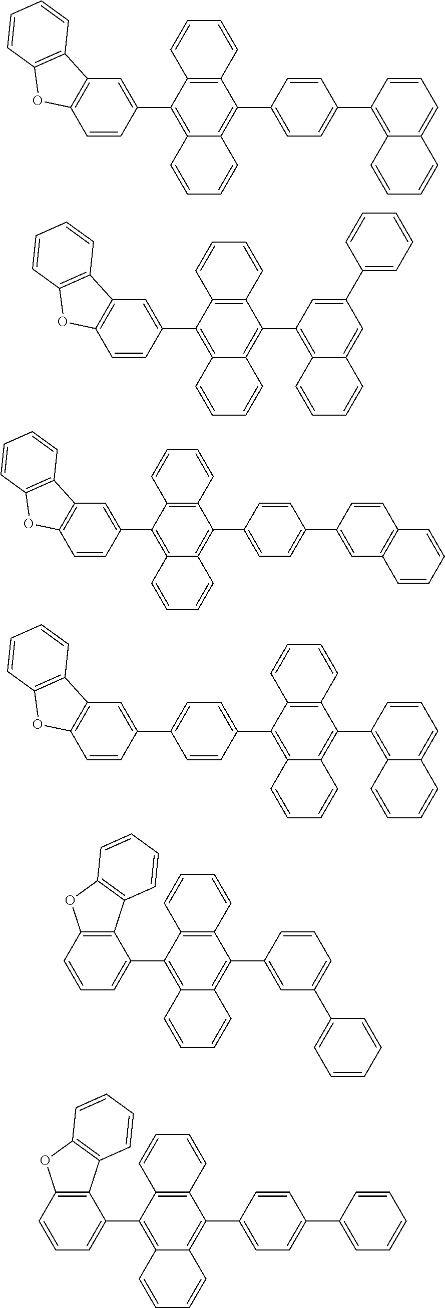

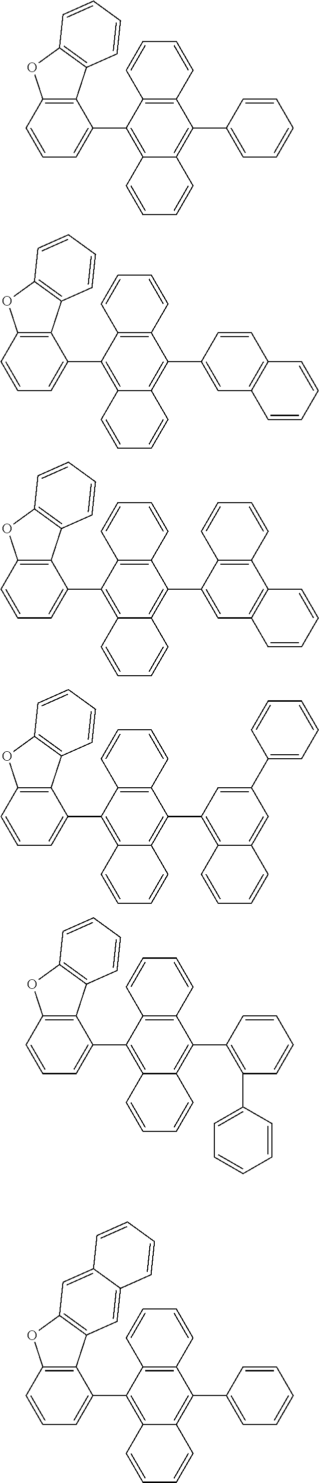

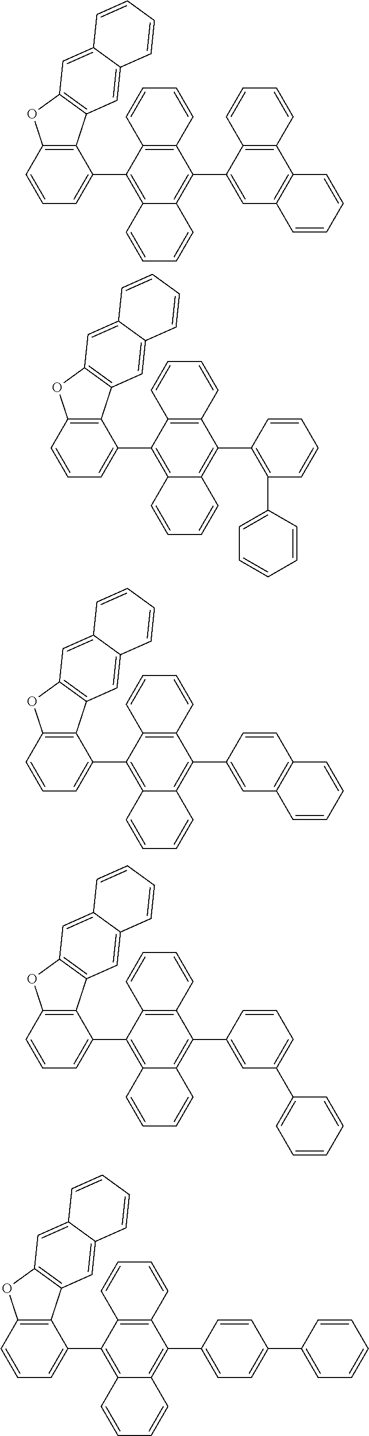

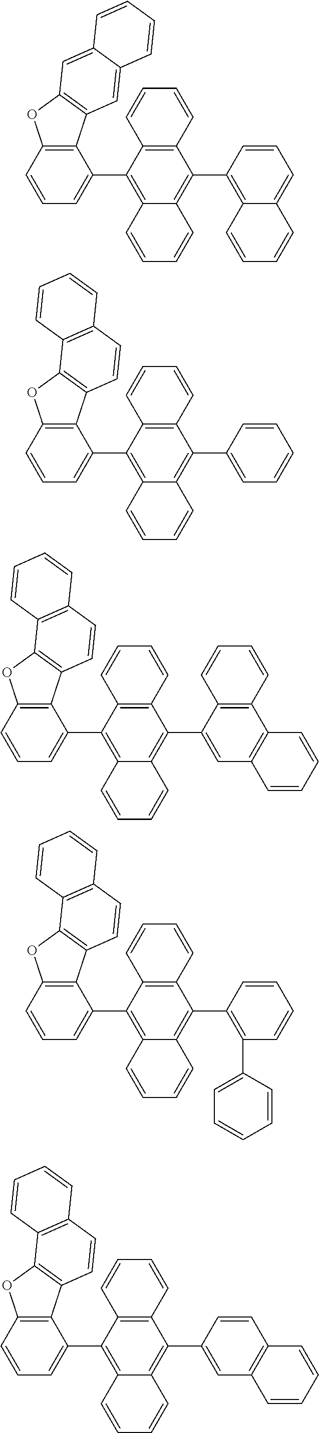

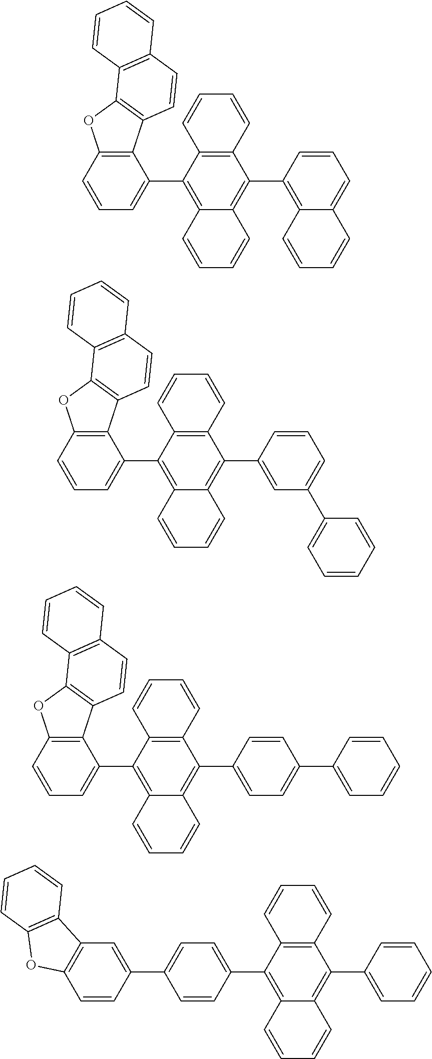 [SMILES: c1ccc2c(-c3c4ccccc4c(-c4cccc5oc6c7ccccc7ccc6c45)c4ccccc34)cccc2c1 ; c1ccc(-c2cccc(-c3c4ccccc4c(-c4cccc5oc6c7ccccc7ccc6c45)c4ccccc34)c2)cc1 ; c1ccc(-c2ccc(-c3c4ccccc4c(-c4cccc5oc6c7ccccc7ccc6c45)c4ccccc34)cc2)cc1 ; c1ccc(-c2c3ccccc3c(-c3ccc(-c4ccc5oc6ccccc6c5c4)cc3)c3ccccc23)cc1]

### Luminescent Compound

### Third Compound

In an exemplary arrangement of the organic EL device according to the exemplary embodiment, the first luminescent compound and the second luminescent compound may be mutually the same or different. In an exemplary arrangement of the organic EL device according to the exemplary embodiment, preferably, the first luminescent compound and the second luminescent compound are mutually the same.

In an exemplary arrangement of the organic EL device according to the exemplary embodiment, the luminescent compound such as the first luminescent compound and the second luminescent compound is not particularly limited, but is preferably the third compound. For instance, each third compound is also preferably independently at least one compound selected from the group consisting of a compound represented by a formula (4) below, a compound represented by a formula (5) below, and a compound represented by a formula (6) below.

### Compound Represented by Formula (4)

The compound represented by the formula (4) will be described.

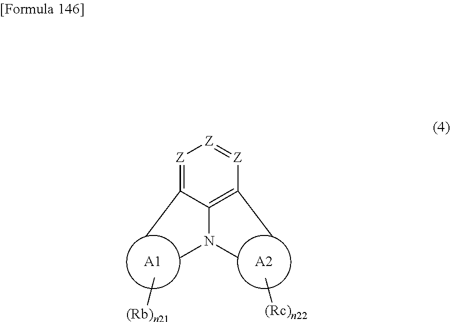

In the formula (4):
each Z is independently CRa or a nitrogen atom,
a ring A1 and a ring A2 are each independently a substituted or unsubstituted aromatic hydrocarbon ring having 6 to 50 ring carbon atoms, or a substituted or unsubstituted heterocycle having 5 to 50 ring atoms;
when a plurality of Ra are present, at least one combination of adjacent two or more of the plurality of Ra are mutually bonded to form a substituted or unsubstituted monocyclic ring, mutually bonded to form a substituted or unsubstituted fused ring, or not mutually bonded;
n21 and n22 are each independently 0, 1, 2, 3 or 4;
when a plurality of Rb are present, at least one combination of adjacent two or more of the plurality of Rb are mutually bonded to form a substituted or unsubstituted monocyclic ring, mutually bonded to form a substituted or unsubstituted fused ring, or not mutually bonded;
when a plurality of Rc are present, at least one combination of adjacent two or more of the plurality of Rc are mutually bonded to form a substituted or unsubstituted monocyclic ring, mutually bonded to form a substituted or unsubstituted fused ring, or not mutually bonded; and
Ra, Rb, and Rc forming neither the substituted or unsubstituted monocyclic ring nor the substituted or unsubstituted fused ring are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

In the third compound, R₉₀₁, R₉₀₂, R₉₀₃, R₉₀₄, R₉₀₅, R₉₀₆, R₉₀₇, R₈₀₁ and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

### Specific Examples of Compound Represented by Formula (4)

Specific examples of the compound represented by the formula (4) include compounds below. In the specific examples below, Ph represents a phenyl group, and D represents a deuterium atom.

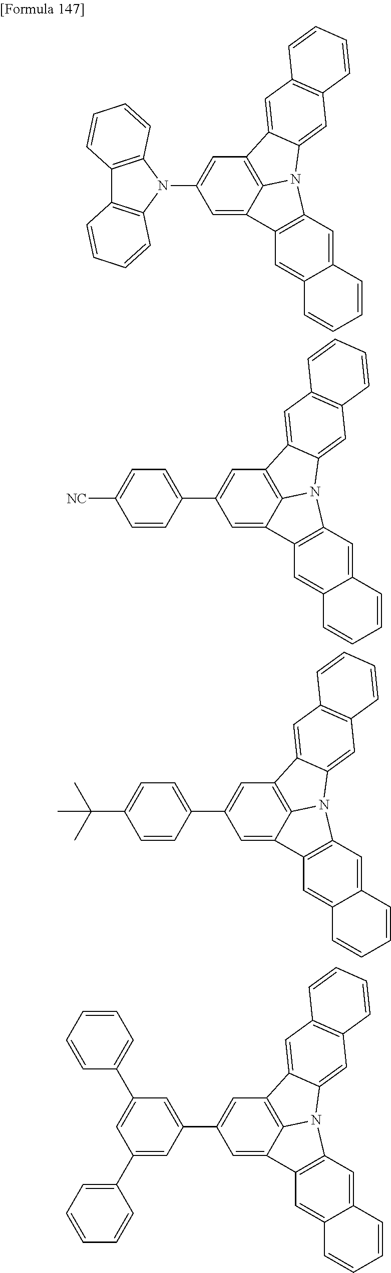

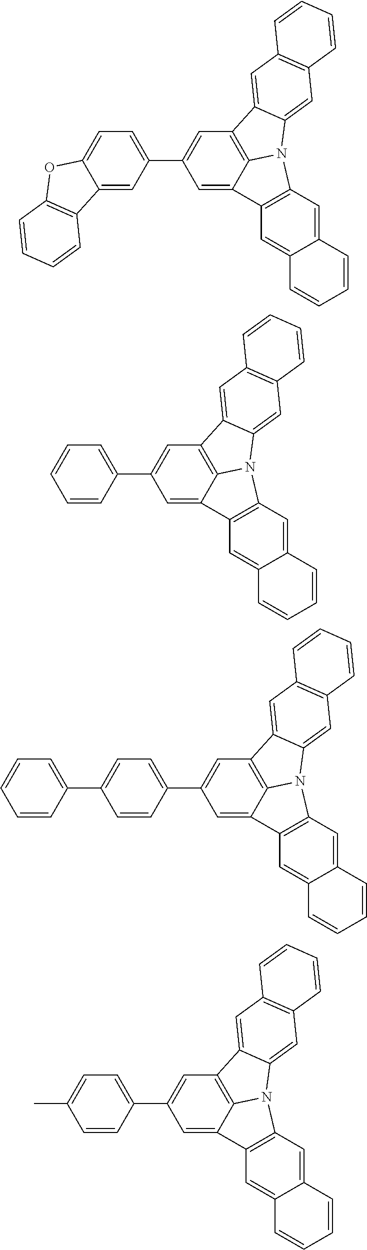

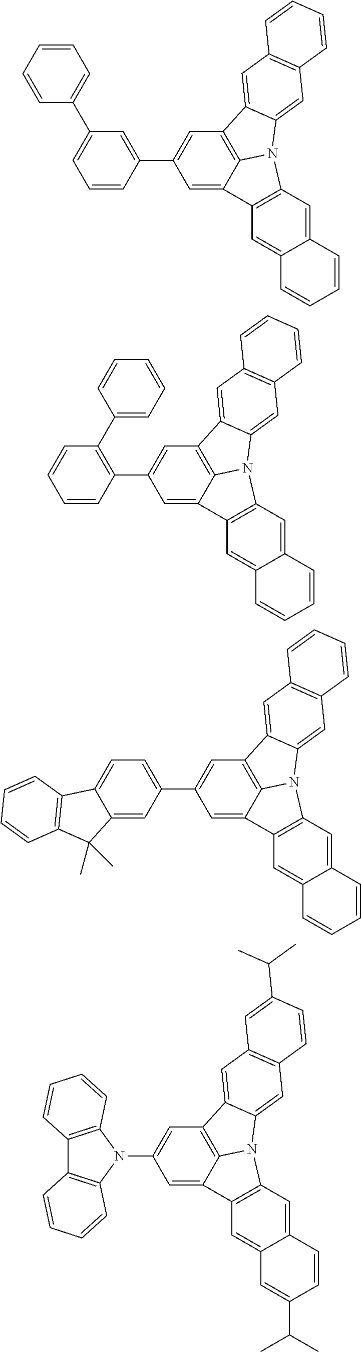

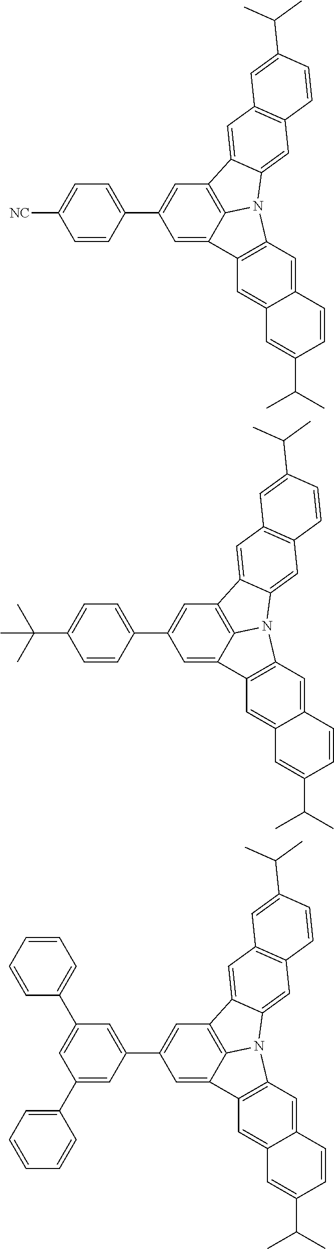

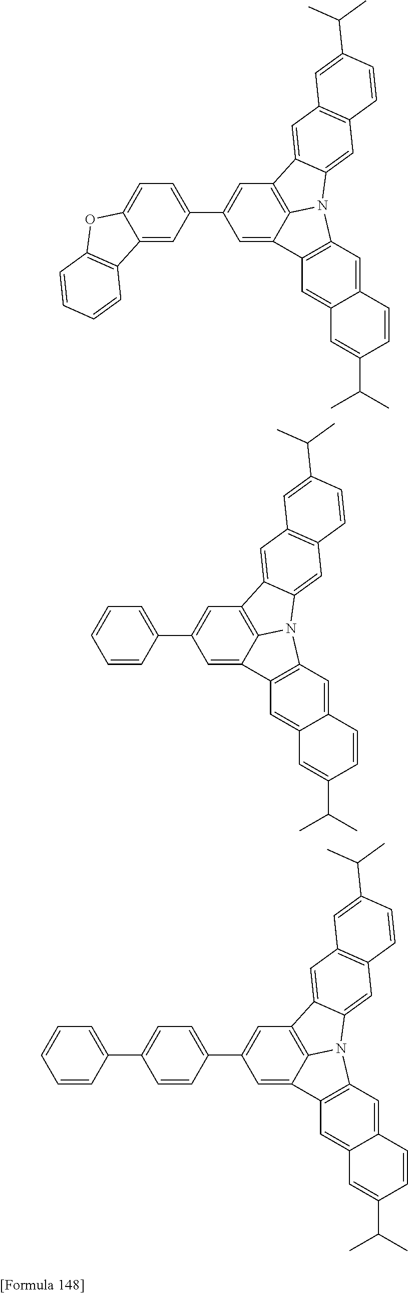

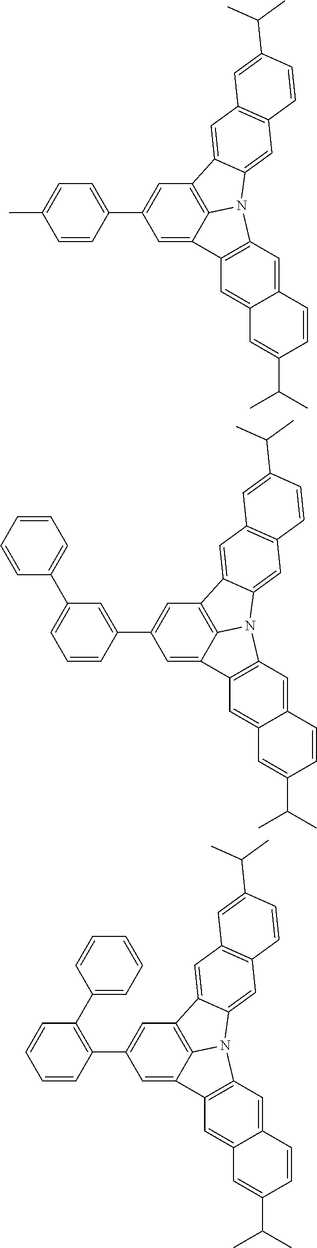

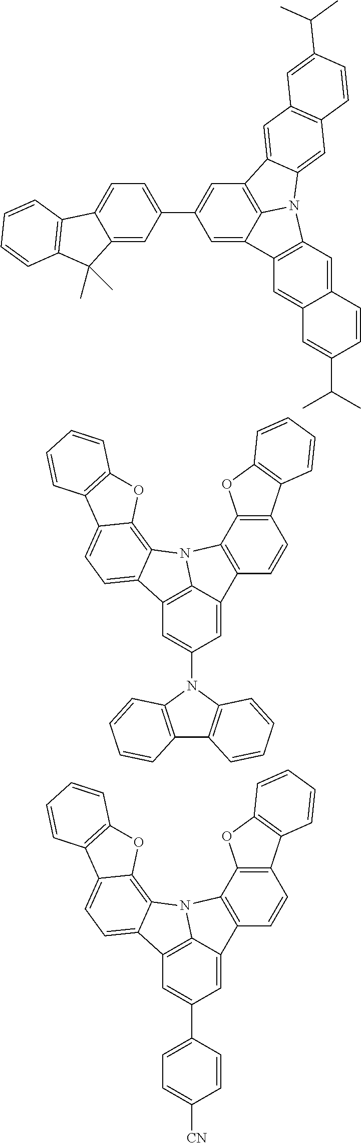

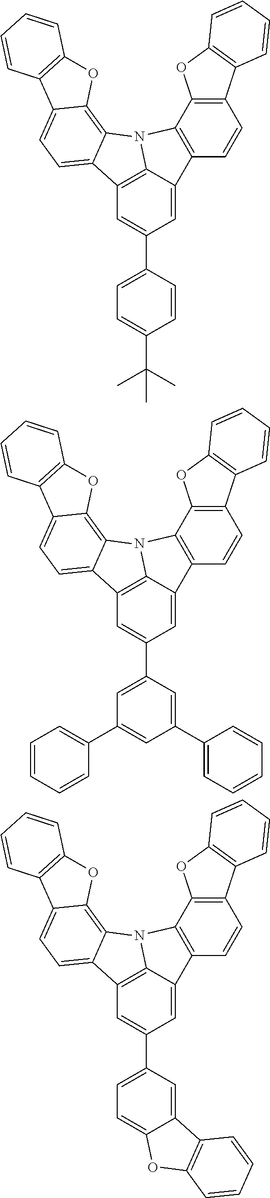

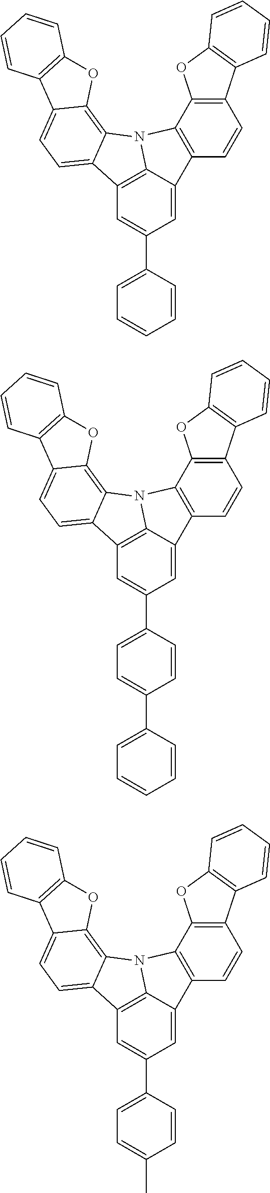 [SMILES: c1ccc(-c2cc3c4ccc5c6ccccc6oc5c4n4c3c(c2)c2ccc3c5ccccc5oc3c24)cc1 ; c1ccc(-c2ccc(-c3cc4c5ccc6c7ccccc7oc6c5n5c4c(c3)c3ccc4c6ccccc6oc4c35)cc2)cc1 ; Cc1ccc(-c2cc3c4ccc5c6ccccc6oc5c4n4c3c(c2)c2ccc3c5ccccc5oc3c24)cc1]

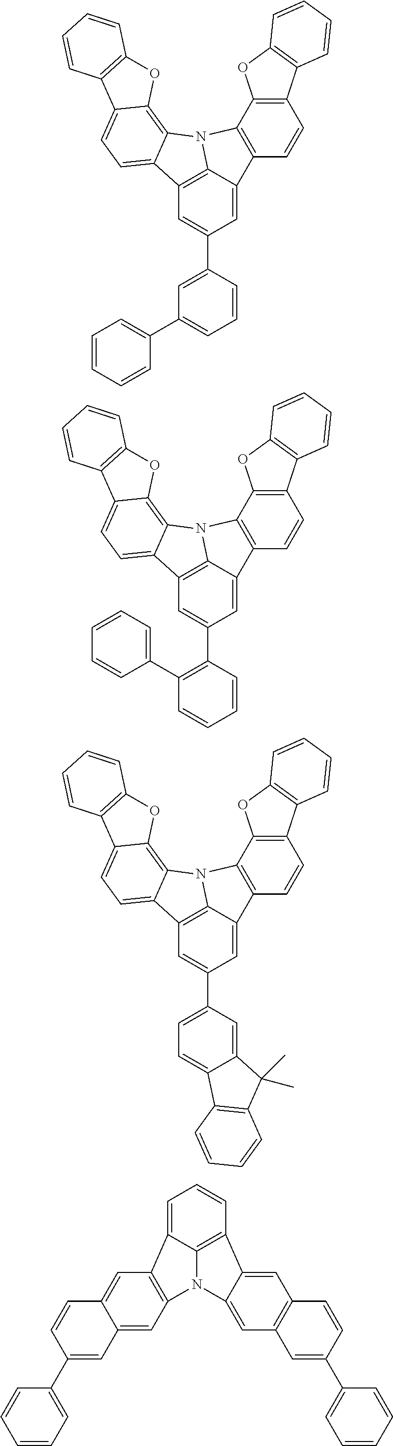

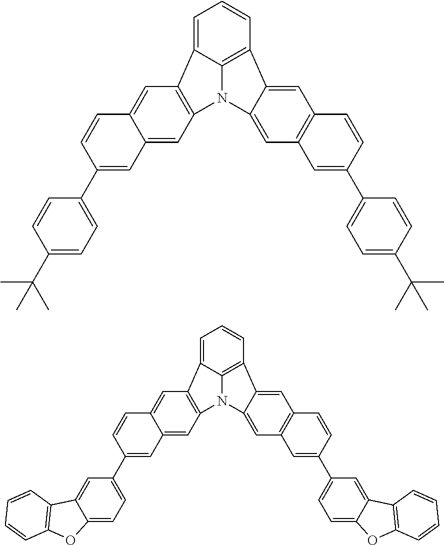 [SMILES: CC(C)(C)c1ccc(-c2ccc3cc4c5cccc6c7cc8ccc(-c9ccc(C(C)(C)C)cc9)cc8cc7n(c4cc3c2)c56)cc1 ; c1ccc2c(c1)oc1ccc(-c3ccc4cc5c6cccc7c8cc9ccc(-c%10ccc%11oc%12ccccc%12c%11c%10)cc9cc8n(c5cc4c3)c67)cc12]

### Compound Represented by Formula (5)

The compound represented by the formula (5) will be described.

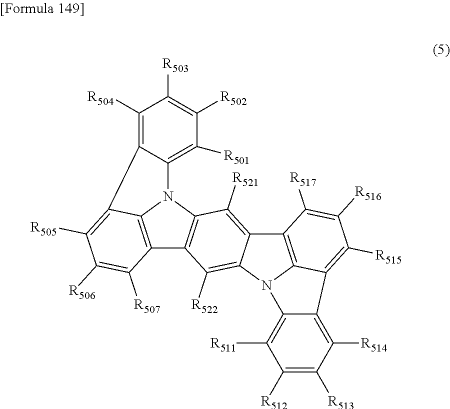

In the formula (5):
at least one combination of adjacent two or more of R₅₀₁ to R₅₀₇ and R₅₁₁ to R₅₁₇ are mutually bonded to form a substituted or unsubstituted monocyclic ring, mutually bonded to form a substituted or unsubstituted fused ring, or not mutually bonded; and
R₅₂₁, R₅₂₂, and R₅₀₁ to R₅₀₇ and R₅₁₁ to R₅₁₇ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

### Specific Examples of Compound Represented by Formula (5)

Specific examples of the compound represented by the formula (5) include compounds as below.

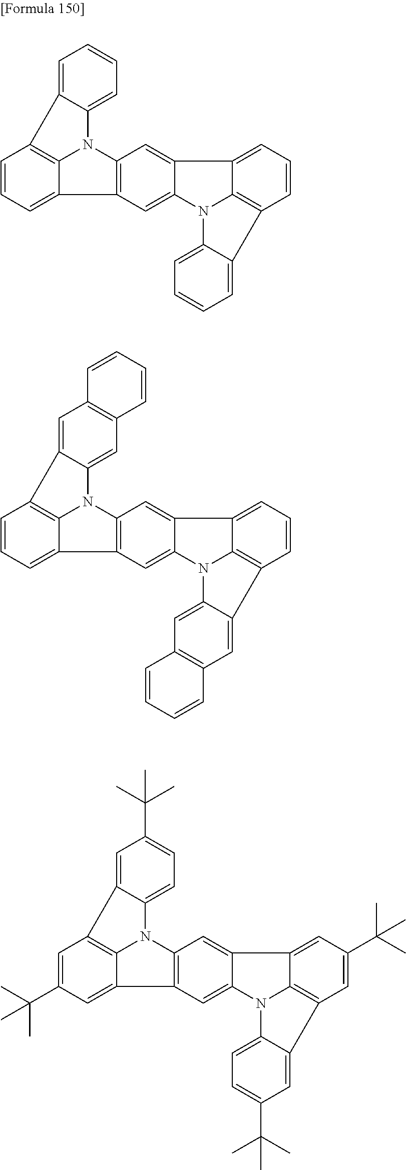 [SMILES: c1ccc2c(c1)c1cccc3c4cc5c(cc4n2c13)c1cccc2c3ccccc3n5c21 ; c1ccc2cc3c(cc2c1)c1cccc2c4cc5c(cc4n3c12)c1cccc2c3cc4ccccc4cc3n5c21 ; CC(C)(C)c1ccc2c(c1)c1cc(C(C)(C)C)cc3c4cc5c(cc4n2c13)c1cc(C(C)(C)C)cc2c3cc(C(C)(C)C)ccc3n5c21]

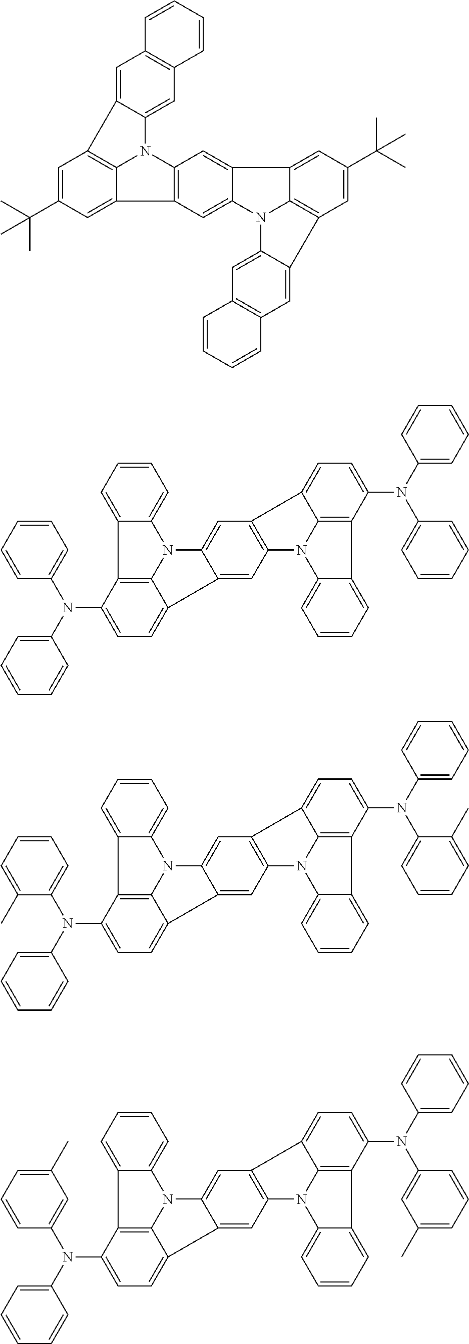

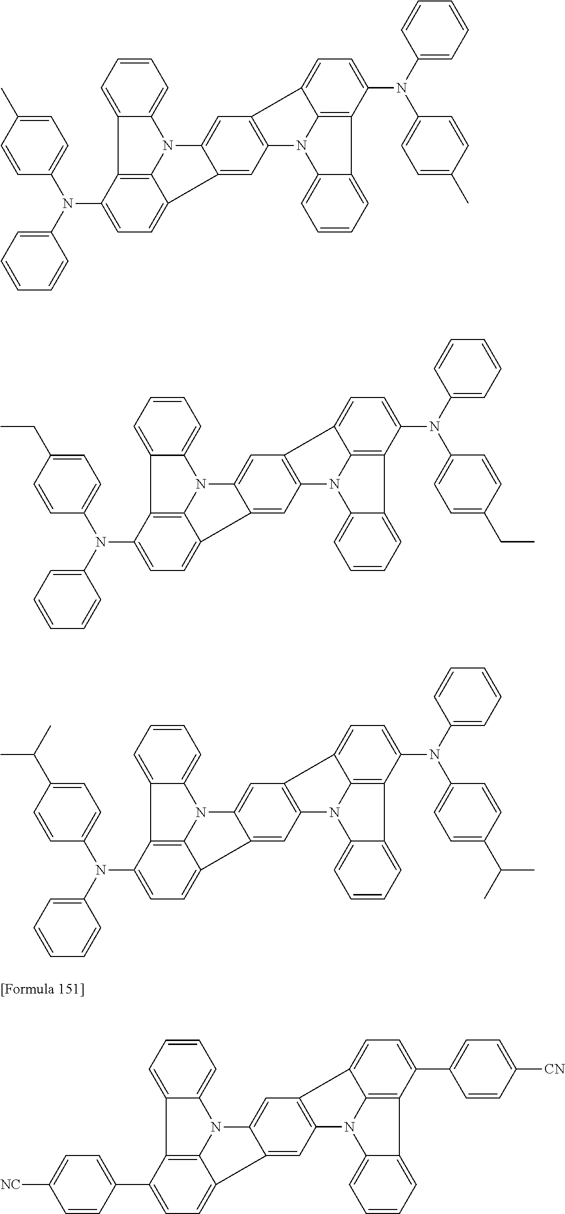

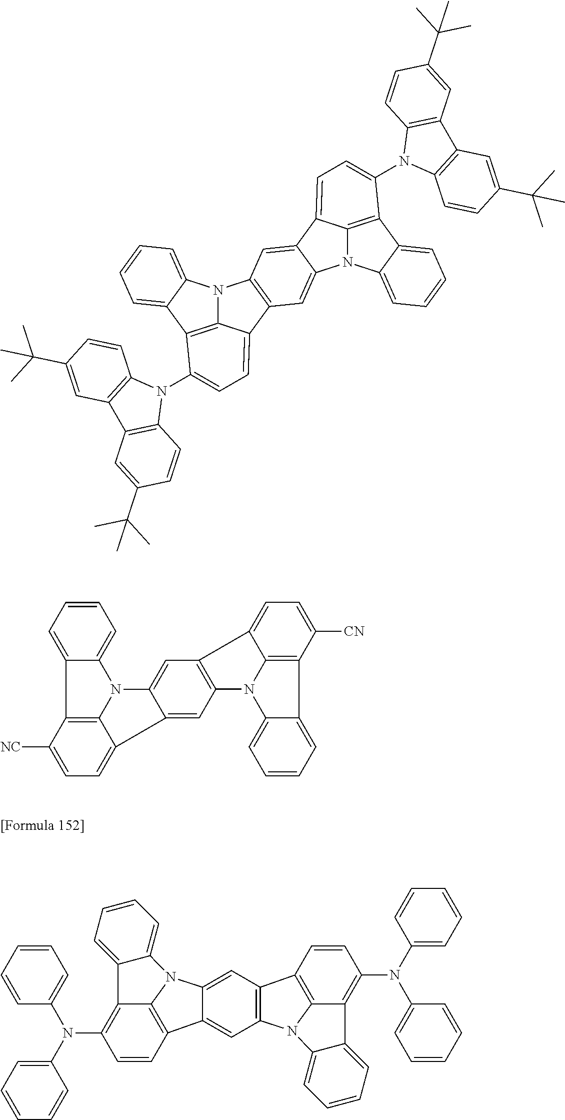 [SMILES: CC(C)(C)c1ccc2c(c1)c1cc(C(C)(C)C)ccc1n2-c1ccc2c3cc4c(cc3n3c5ccccc5c1c23)c1ccc(-n2c3ccc(C(C)(C)C)cc3c3cc(C(C)(C)C)ccc32)c2c3ccccc3n4c12 ; N#Cc1ccc2c3cc4c(cc3n3c5ccccc5c1c23)c1ccc(C#N)c2c3ccccc3n4c12 ; c1ccc(N(c2ccccc2)c2ccc3c4cc5c(cc4n4c6ccccc6c2c34)c2ccc(N(c3ccccc3)c3ccccc3)c3c4ccccc4n5c23)cc1]

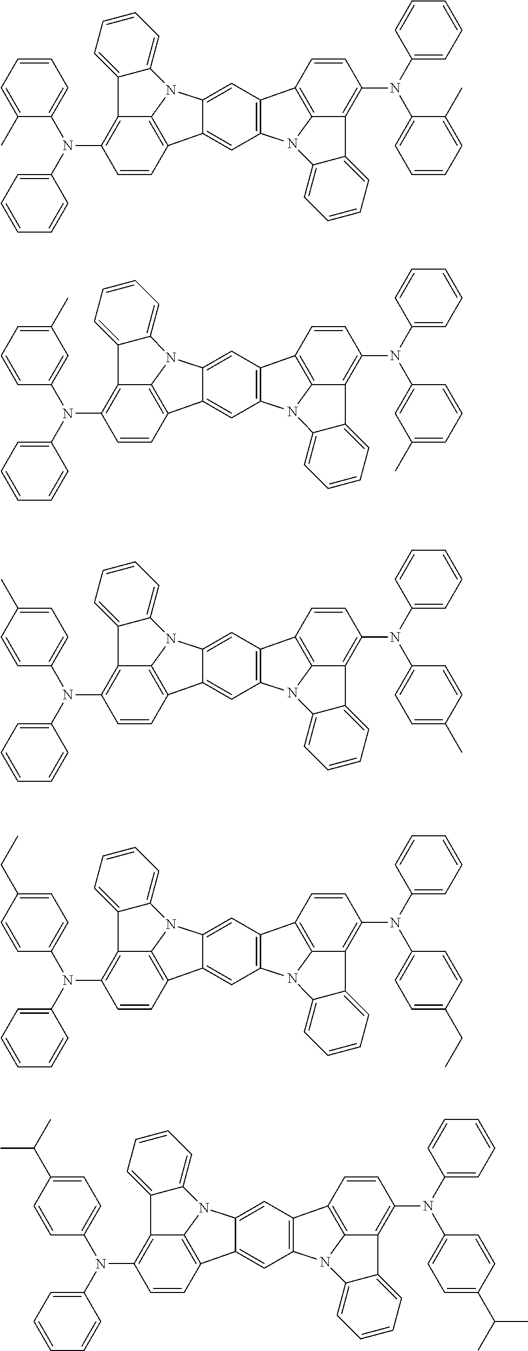

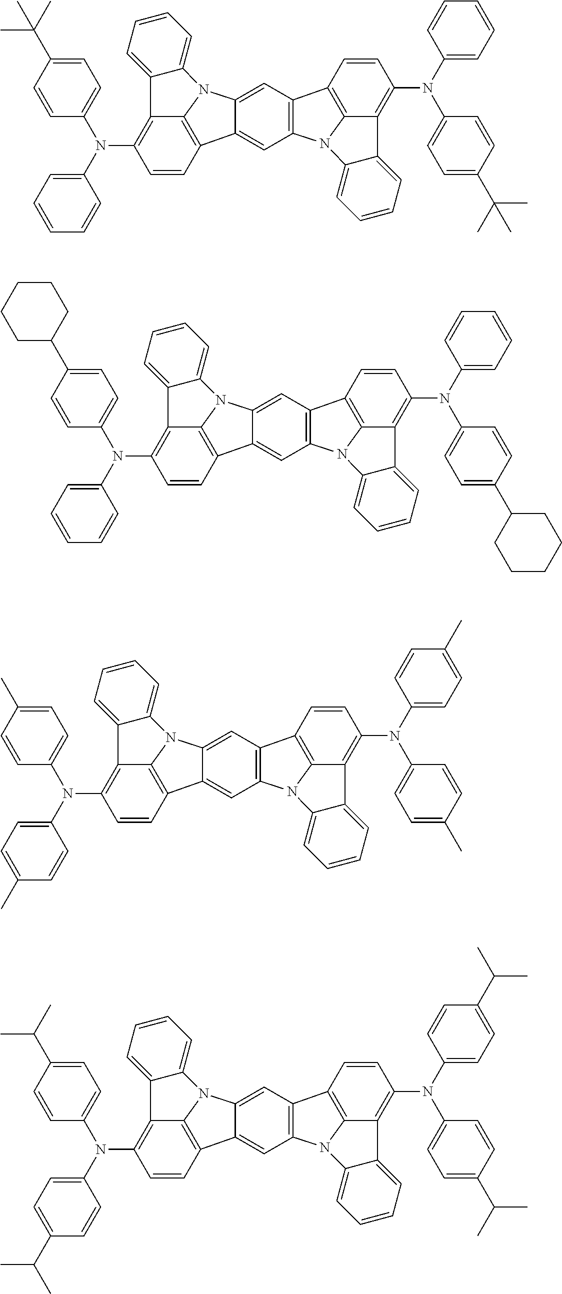

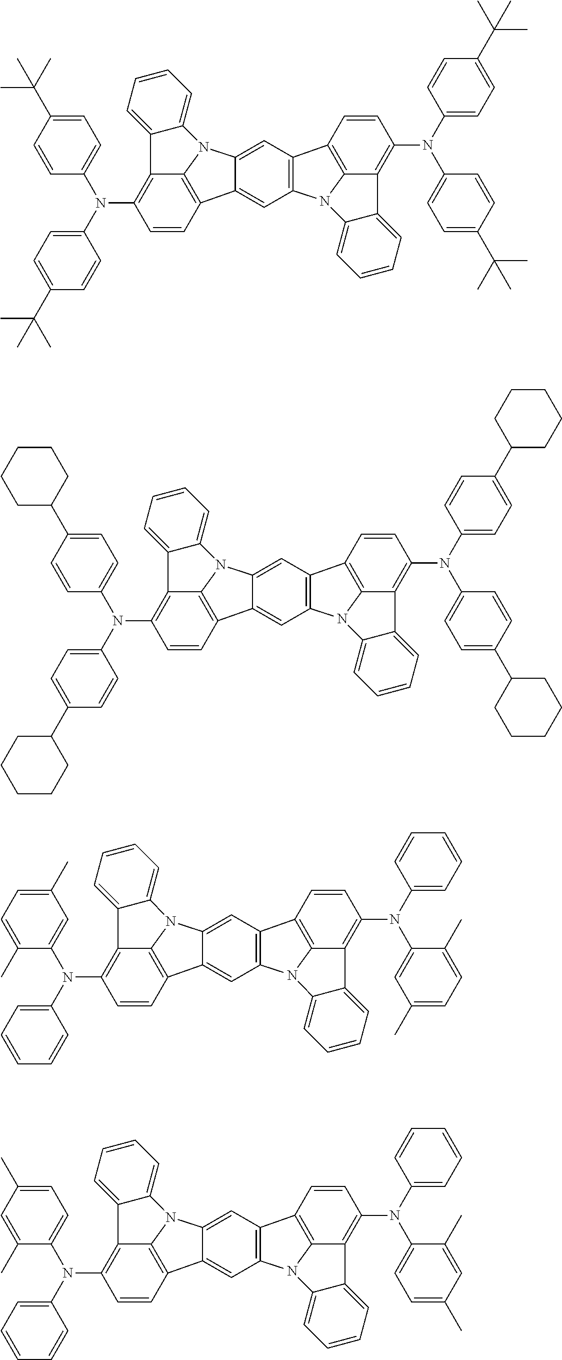 [SMILES: CC(C)(C)c1ccc(N(c2ccc(C(C)(C)C)cc2)c2ccc3c4cc5c(cc4n4c6ccccc6c2c34)c2ccc(N(c3ccc(C(C)(C)C)cc3)c3ccc(C(C)(C)C)cc3)c3c4ccccc4n5c23)cc1 ; c1ccc2c(c1)c1c(N(c3ccc(C4CCCCC4)cc3)c3ccc(C4CCCCC4)cc3)ccc3c4cc5c(cc4n2c31)c1ccc(N(c2ccc(C3CCCCC3)cc2)c2ccc(C3CCCCC3)cc2)c2c3ccccc3n5c12 ; Cc1ccc(C)c(N(c2ccccc2)c2ccc3c4cc5c(cc4n4c6ccccc6c2c34)c2ccc(N(c3ccccc3)c3cc(C)ccc3C)c3c4ccccc4n5c23)c1 ; Cc1ccc(N(c2ccccc2)c2ccc3c4cc5c(cc4n4c6ccccc6c2c34)c2ccc(N(c3ccccc3)c3ccc(C)cc3C)c3c4ccccc4n5c23)c(C)c1]

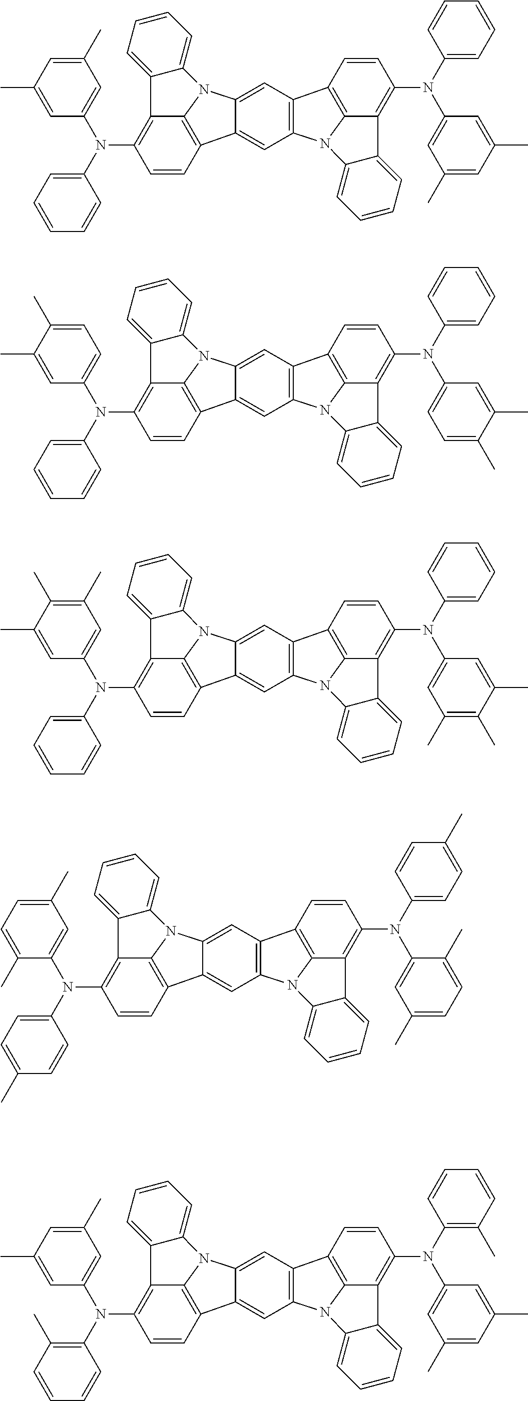

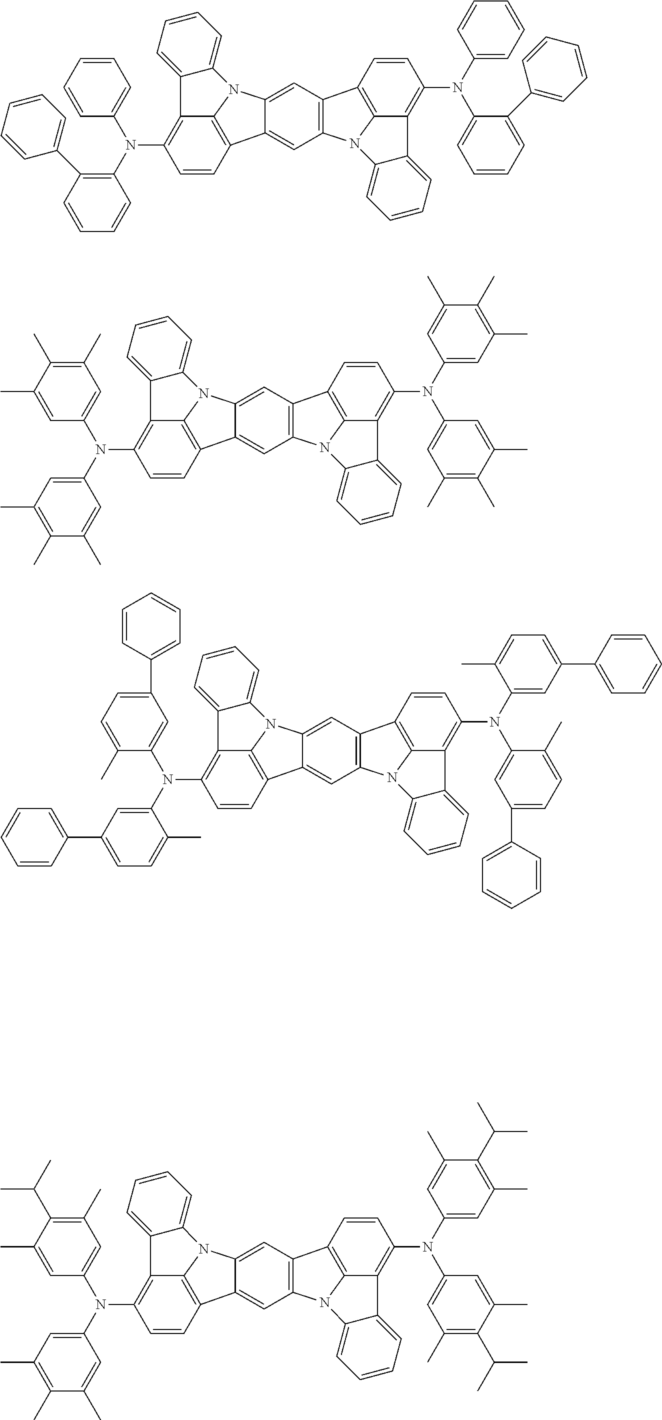

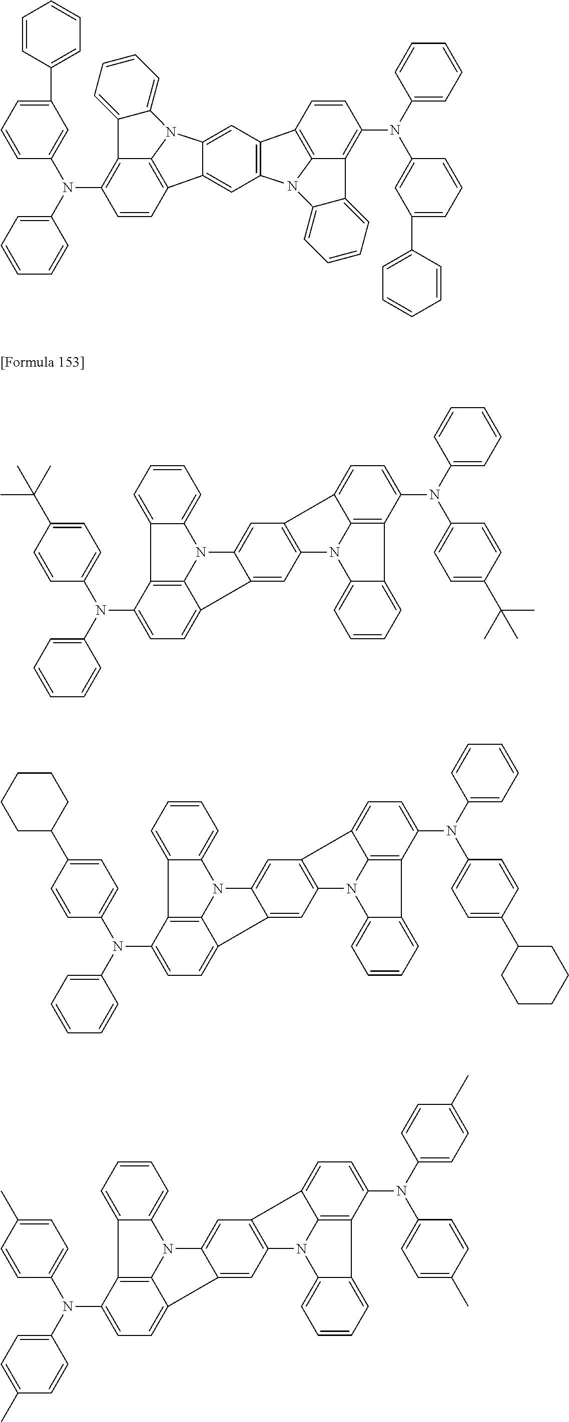

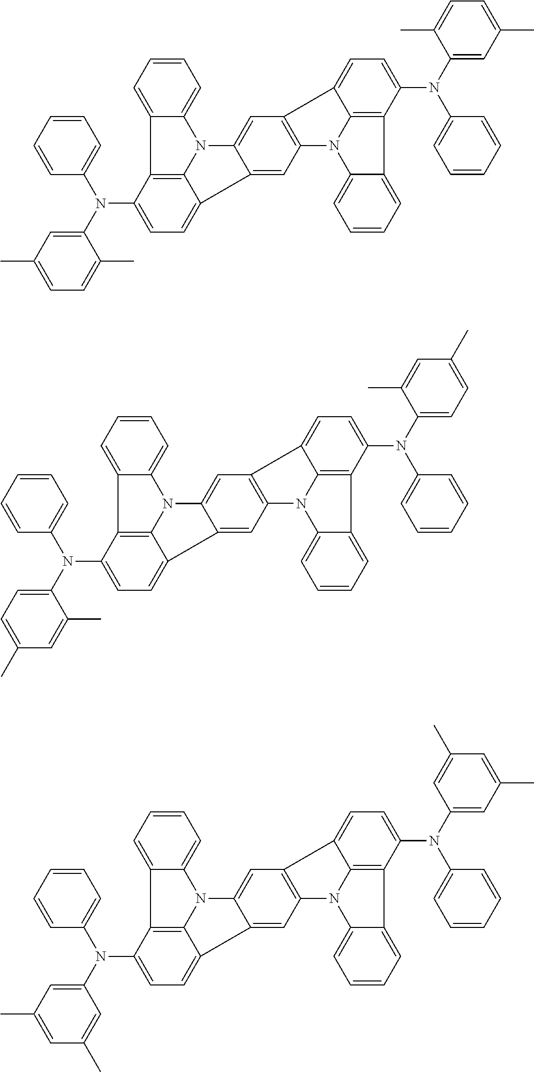

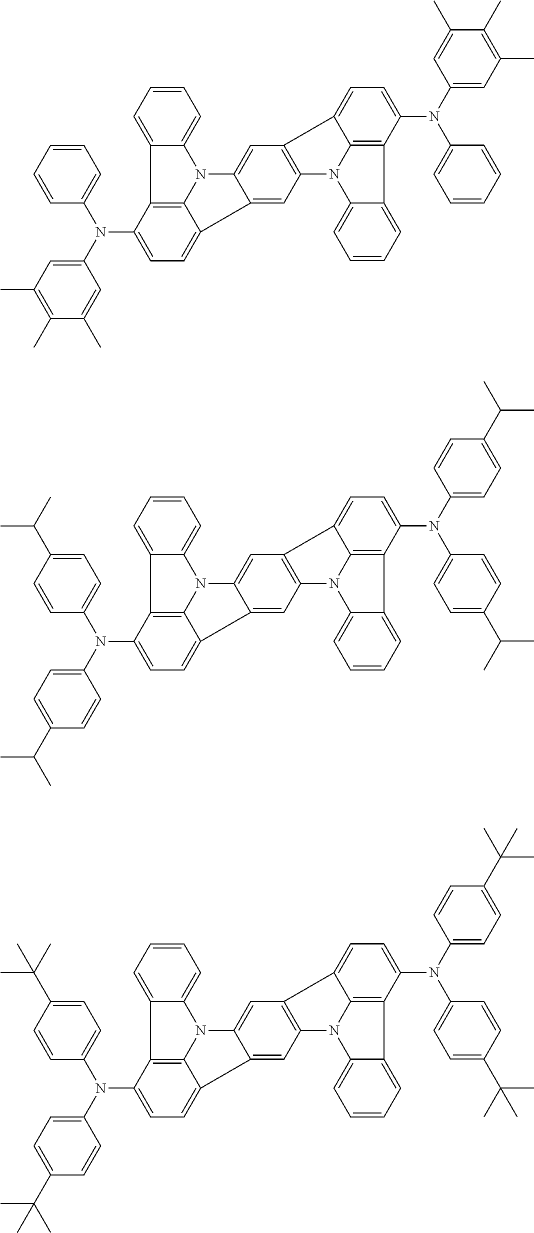

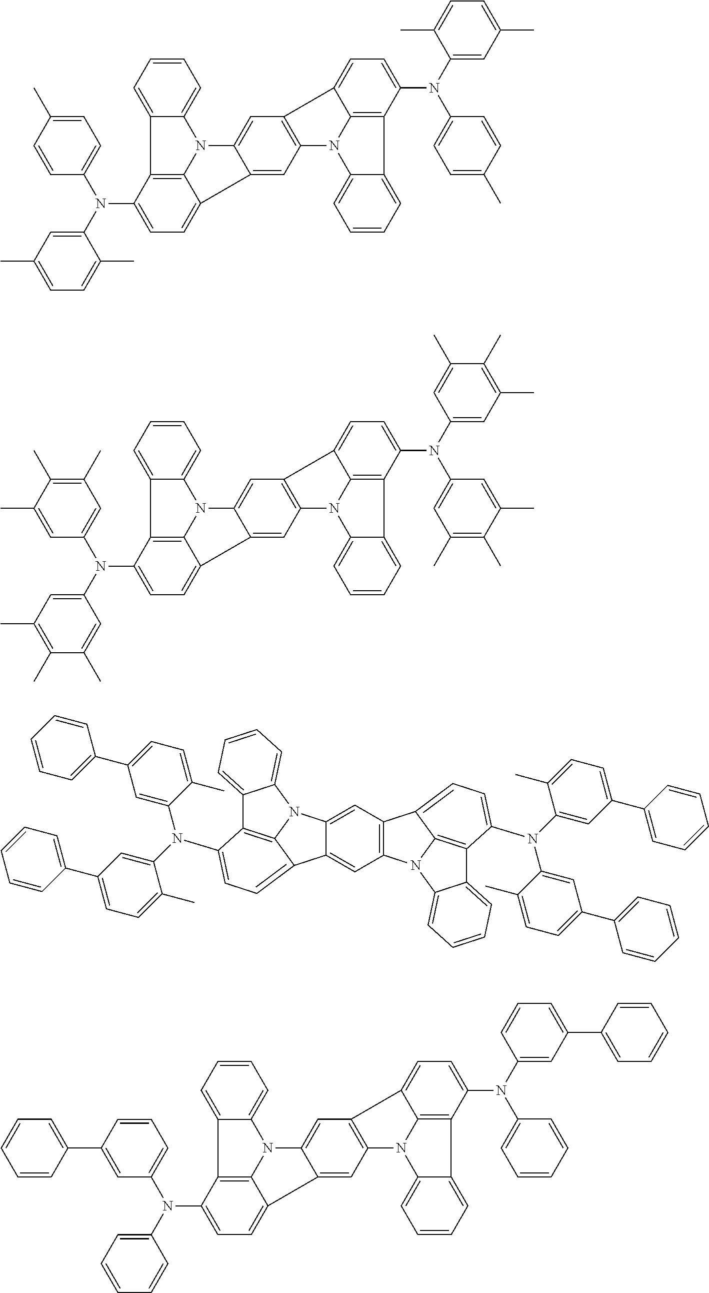

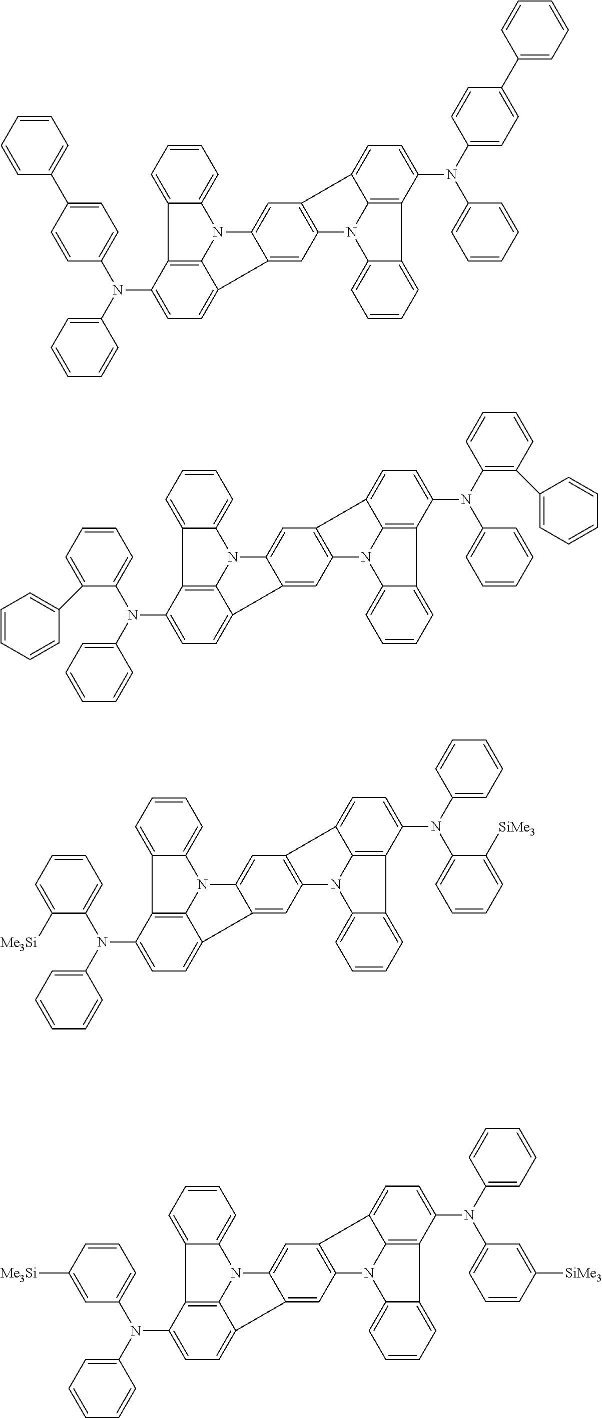 [SMILES: c1ccc(-c2ccc(N(c3ccccc3)c3ccc4c5cc6c(cc5n5c7ccccc7c3c45)c3ccc(N(c4ccccc4)c4ccc(-c5ccccc5)cc4)c4c5ccccc5n6c34)cc2)cc1 ; c1ccc(-c2ccccc2N(c2ccccc2)c2ccc3c4cc5c(cc4n4c6ccccc6c2c34)c2ccc(N(c3ccccc3)c3ccccc3-c3ccccc3)c3c4ccccc4n5c23)cc1 ; C[Si](C)(C)c1ccccc1N(c1ccccc1)c1ccc2c3cc4c(cc3n3c5ccccc5c1c23)c1ccc(N(c2ccccc2)c2ccccc2[Si](C)(C)C)c2c3ccccc3n4c12 ; C[Si](C)(C)c1cccc(N(c2ccccc2)c2ccc3c4cc5c(cc4n4c6ccccc6c2c34)c2ccc(N(c3ccccc3)c3cccc([Si](C)(C)C)c3)c3c4ccccc4n5c23)c1]

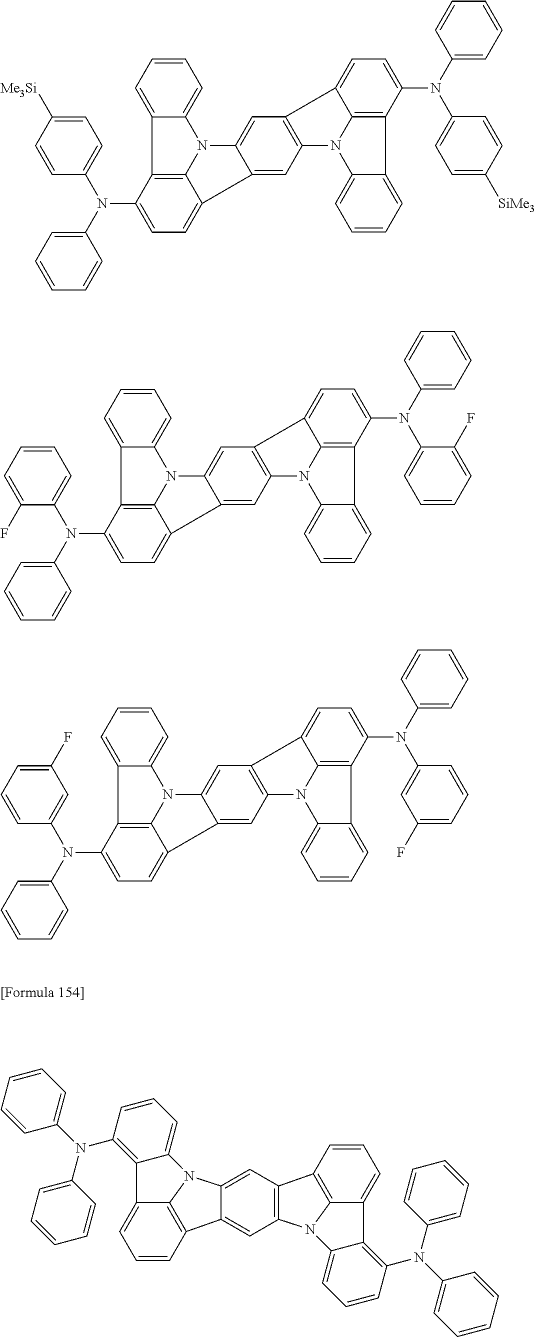 [SMILES: C[Si](C)(C)c1ccc(N(c2ccccc2)c2ccc3c4cc5c(cc4n4c6ccccc6c2c34)c2ccc(N(c3ccccc3)c3ccc([Si](C)(C)C)cc3)c3c4ccccc4n5c23)cc1 ; Fc1ccccc1N(c1ccccc1)c1ccc2c3cc4c(cc3n3c5ccccc5c1c23)c1ccc(N(c2ccccc2)c2ccccc2F)c2c3ccccc3n4c12 ; Fc1cccc(N(c2ccccc2)c2ccc3c4cc5c(cc4n4c6ccccc6c2c34)c2ccc(N(c3ccccc3)c3cccc(F)c3)c3c4ccccc4n5c23)c1 ; c1ccc(N(c2ccccc2)c2cccc3c2c2cccc4c5cc6c(cc5n3c42)c2cccc3c4c(N(c5ccccc5)c5ccccc5)cccc4n6c23)cc1]

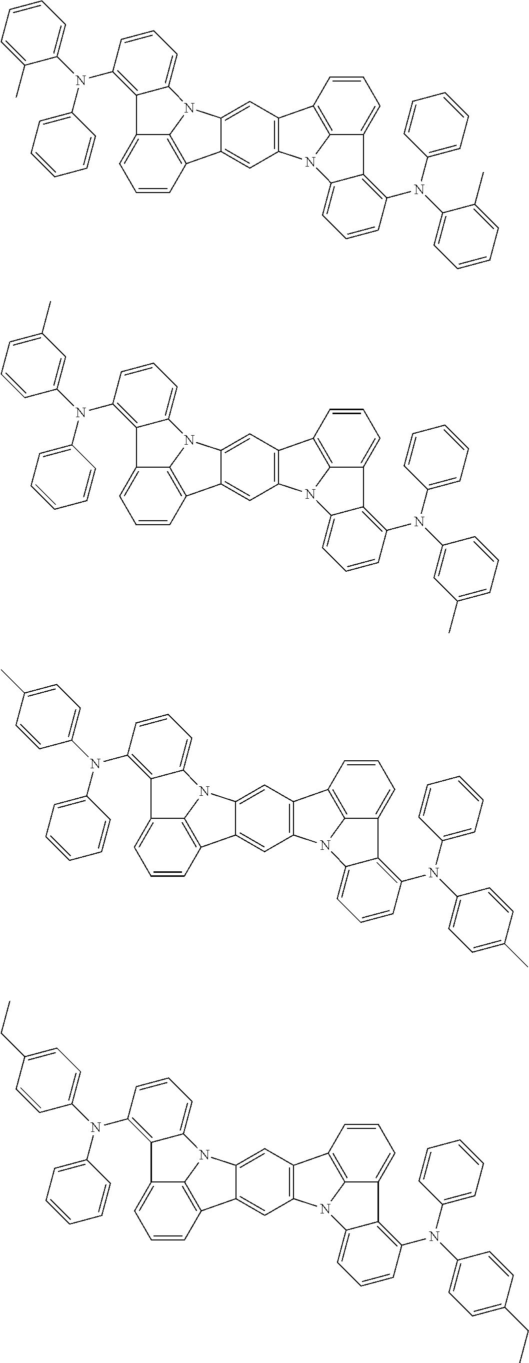

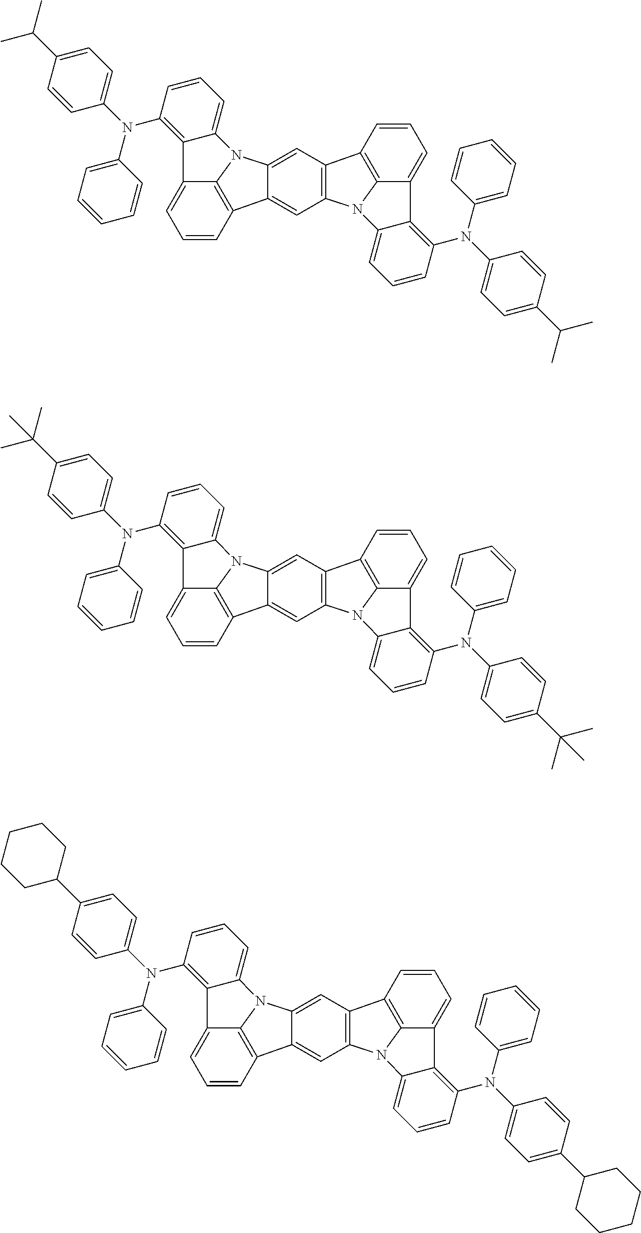

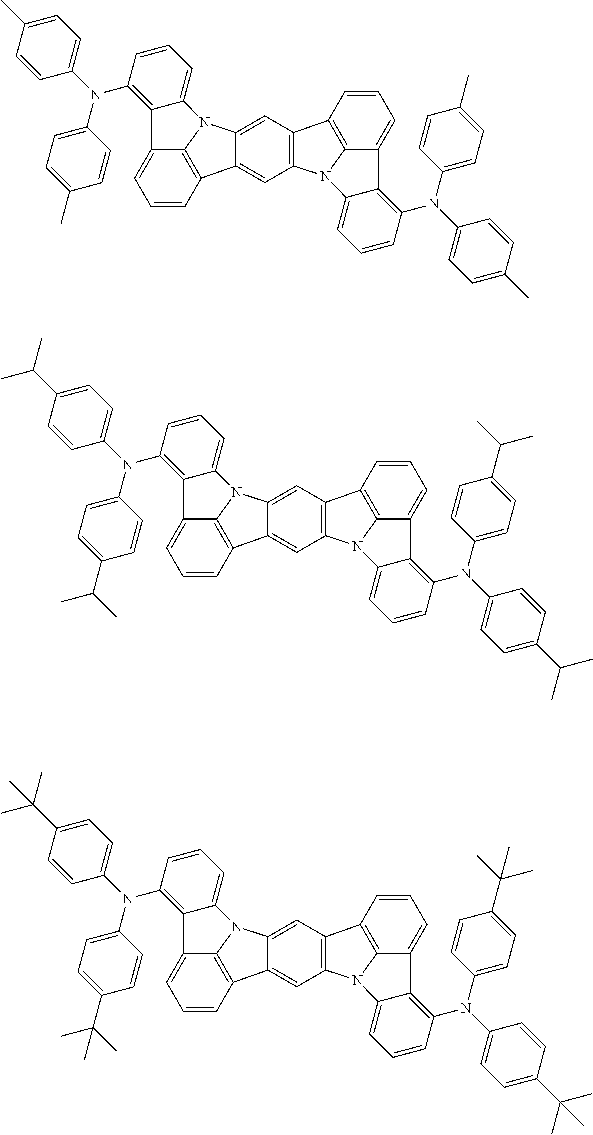

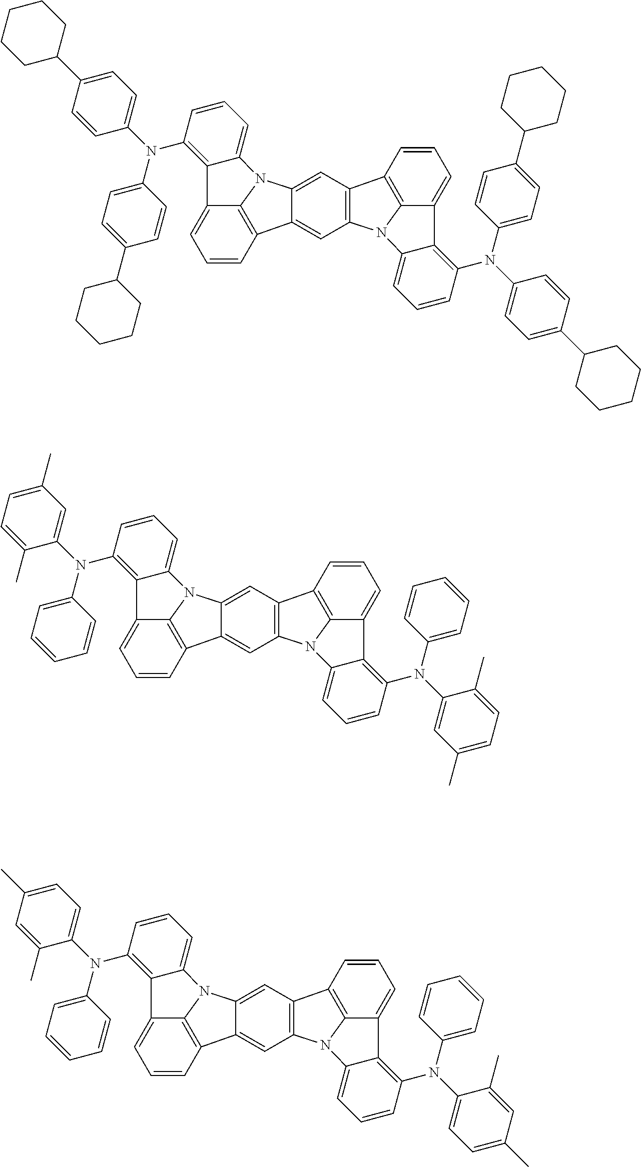

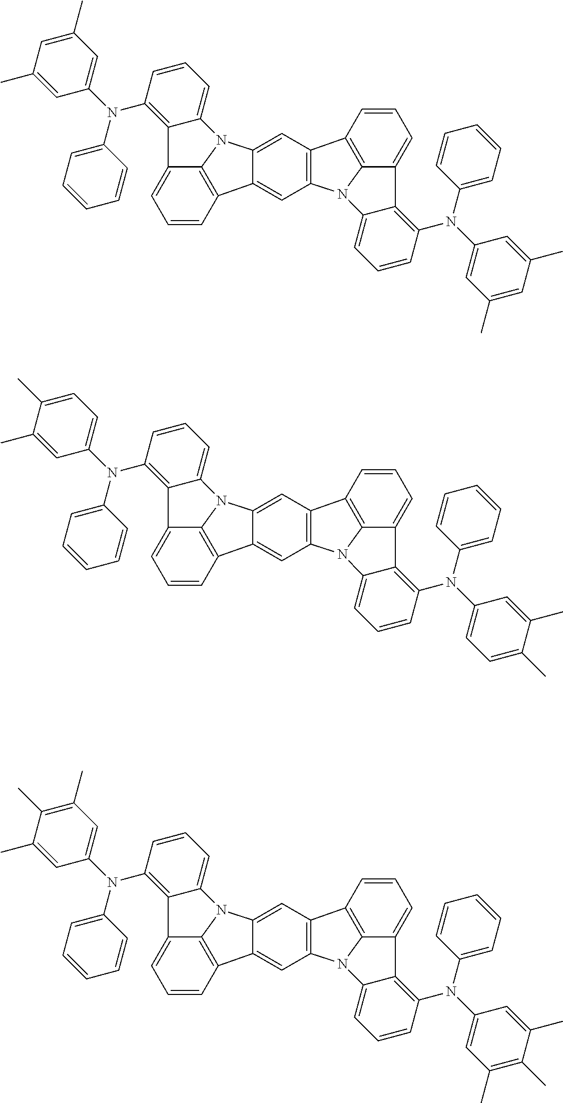

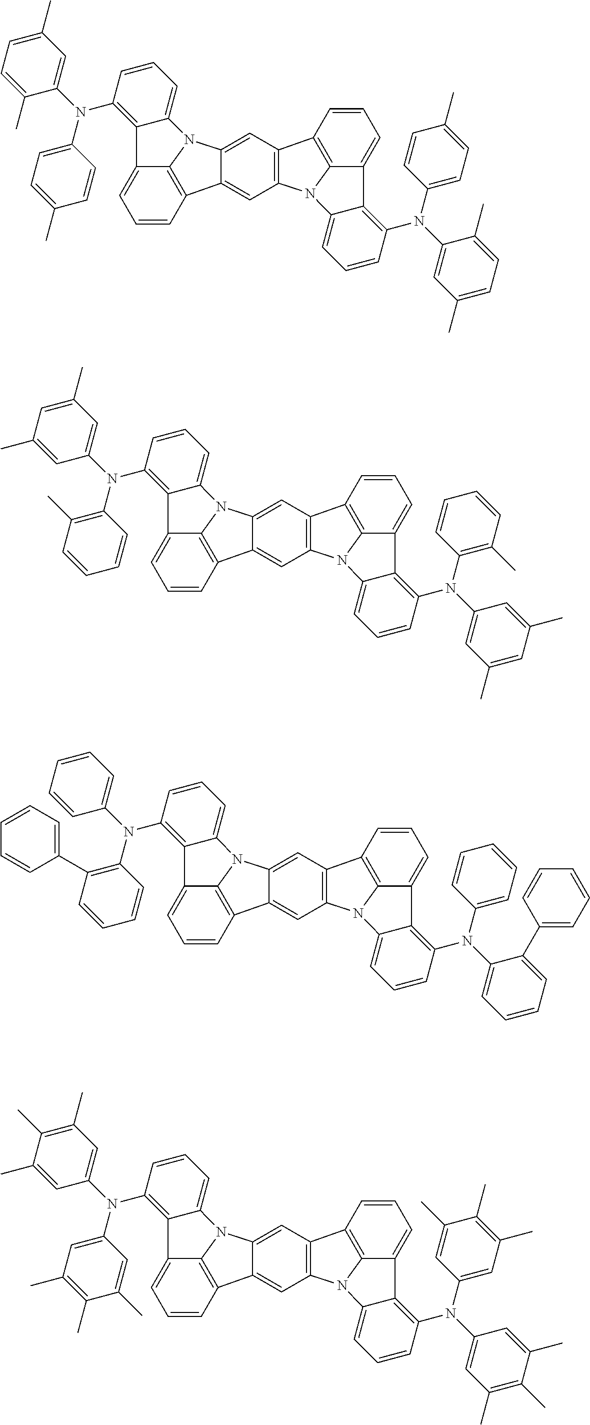

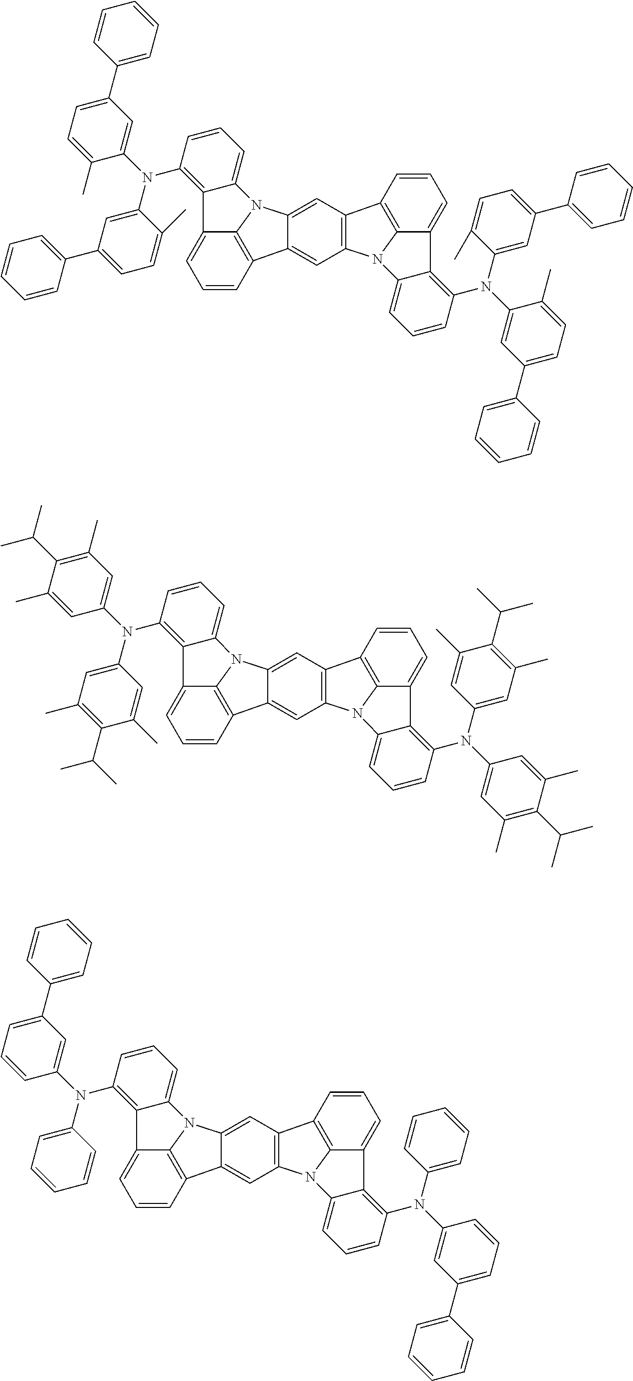 [SMILES: Cc1ccc(-c2ccccc2)cc1N(c1cc(-c2ccccc2)ccc1C)c1cccc2c1c1cccc3c4cc5c(cc4n2c31)c1cccc2c3c(N(c4cc(-c6ccccc6)ccc4C)c4cc(-c6ccccc6)ccc4C)cccc3n5c12 ; Cc1cc(N(c2cc(C)c(C(C)C)c(C)c2)c2cccc3c2c2cccc4c5cc6c(cc5n3c42)c2cccc3c4c(N(c5cc(C)c(C(C)C)c(C)c5)c5cc(C)c(C(C)C)c(C)c5)cccc4n6c23)cc(C)c1C(C)C ; c1ccc(-c2cccc(N(c3ccccc3)c3cccc4c3c3cccc5c6cc7c(cc6n4c53)c3cccc4c5c(N(c6ccccc6)c6cccc(-c8ccccc8)c6)cccc5n7c34)c2)cc1]

### Compound Represented by Formula (6)

The compound represented by the formula (6) will be described. The second luminescent compound is preferably a compound represented by the formula (6) below.

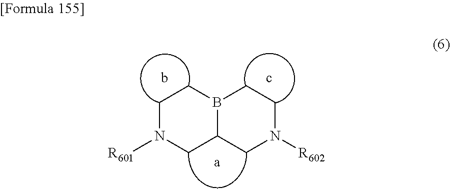

In the formula (6):
a ring a, a ring b and a ring c are each independently a substituted or unsubstituted aromatic hydrocarbon ring having 6 to 50 ring carbon atoms, or a substituted or unsubstituted heterocycle having 5 to 50 ring atoms;
R₆₀₁ and R₆₀₂ are each independently bonded with the ring a, the ring b or the ring c to form a substituted or unsubstituted heterocycle, or not bonded therewith to form no substituted or unsubstituted heterocycle; and
R₆₀₁ and R₆₀₂ not forming the substituted or unsubstituted heterocycle are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

It is preferable that: at least one ring of the ring a, the ring b or the ring c has at least one group represented by —N(R_{6A})(R_{6B});
R_{6A} and R_{6B} are each independently a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms;
when two or more R_{6A} are present, the two or more R_{6A} are mutually the same or different; and
when two or more R_{6B} are present, the two or more R_{6B} are mutually the same or different.

The ring a, ring b and ring c are each a ring (a substituted or unsubstituted aromatic hydrocarbon ring having 6 to 50 ring carbon atoms, or a substituted or unsubstituted heterocycle having 5 to 50 ring atoms) fused with a fused bicyclic structure formed of a boron atom and two nitrogen atoms at the center of the formula (6).

The “aromatic hydrocarbon ring” for the rings a, b, and c has the same structure as a compound formed by introducing a hydrogen atom to the “aryl group” described above.

Ring atoms of the “aromatic hydrocarbon ring” for the ring a include three carbon atoms on a fused bicyclic structure at the center of the formula (6).

Ring atoms of the “aromatic hydrocarbon ring” for the rings b and c include two carbon atoms on the fused bicyclic structure at the center of the formula (6).

Specific examples of the “substituted or unsubstituted aromatic hydrocarbon ring having 6 to 50 ring carbon atoms” include a compound formed by introducing a hydrogen atom to the “aryl group” described in the specific example group G1.

The “heterocycle” for the rings a, b, and c has the same structure as a compound formed by introducing a hydrogen atom to the “heterocyclic group” described above.

Ring atoms of the “heterocycle” for the ring a include three carbon atoms on the fused bicyclic structure at the center of the formula (6). Ring atoms of the “heterocycle” for the rings b and c include two carbon atoms on the fused bicyclic structure at the center of the formula (6). Specific examples of the “substituted or unsubstituted heterocycle having 5 to 50 ring atoms” include a compound formed by introducing a hydrogen atom to the “heterocyclic group” described in the specific example group G2.

R₆₀₁ and R₆₀₂ may be each independently bonded with the ring a, ring b, or ring c to form a substituted or unsubstituted heterocycle. The “heterocycle” in this arrangement includes a nitrogen atom on the fused bicyclic structure at the center of the formula (6). The heterocycle in the above arrangement optionally includes a hetero atom other than the nitrogen atom. R₆₀₁ and R₆₀₂ being bonded with the ring a, ring b, or ring c specifically means that atoms forming R₆₀₁ and R₆₀₂ are bonded with atoms forming the ring a, ring b, or ring c. For instance, R₆₀₁ may be bonded with the ring a to form a bicyclic (or tri-or-more cyclic) fused nitrogen-containing heterocycle, in which the ring including R₆₀₁ and the ring a are fused. Specific examples of the nitrogen-containing heterocycle include a compound corresponding to the nitrogen-containing bi(or-more)cyclic fused heterocyclic group in the specific example group G2.

The same applies to R₆₀₁ bonded with the ring b, R₆₀₂ bonded with the ring a, and R₆₀₂ bonded with the ring c.

In an exemplary embodiment, the ring a, ring b and ring c in the formula (6) are each independently a substituted or unsubstituted aromatic hydrocarbon ring having 6 to 50 ring carbon atoms.

In an exemplary embodiment, the ring a, ring b and ring c in the formula (6) are each independently a substituted or unsubstituted benzene ring or a substituted or unsubstituted naphthalene ring.

In an exemplary embodiment, R₆₀₁ and R₆₀₂ in the formula (6) are each independently a substituted or unsubstituted aryl group having 6 to 50 ring carbon atoms, or a substituted or unsubstituted heterocyclic group having 5 to 50 ring atoms, preferably, a substituted or unsubstituted aryl group having 6 to 50 ring carbon atoms.

In an exemplary embodiment, the compound represented by the formula (6) is a compound represented by a formula (62) below.

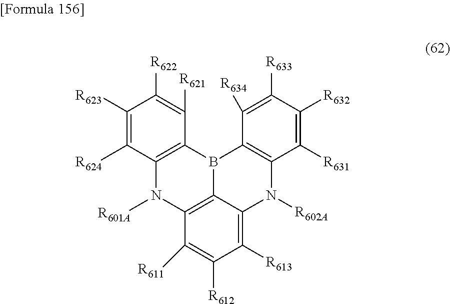

In the formula (62):
R_{601A} is bonded with at least one selected from the group consisting of R₆₁₁ and R₆₂₄ to form a substituted or unsubstituted heterocycle, or not bonded therewith to form no substituted or unsubstituted heterocycle;
R_{601A} not forming the substituted or unsubstituted heterocycle is a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
R_{602A} is bonded with at least one selected from the group consisting of R₆₁₃ and R₆₃₁ to form a substituted or unsubstituted heterocycle, or not bonded therewith to form no substituted or unsubstituted heterocycle;
R_{602A} not forming the substituted or unsubstituted heterocycle is a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, or a group represented by a formula (621) below;
at least one combination of adjacent two or more of R₆₁₁ to R₆₁₃, R₆₂₁ to R₆₂₄, and R₆₃₁ to R₆₃₄ are mutually bonded to form a substituted or unsubstituted monocyclic ring, mutually bonded to form a substituted or unsubstituted fused ring, or not mutually bonded; and
R₆₁₁ to R₆₁₃, R₆₂₁ to R₆₂₄, and R₆₃₁ to R₆₃₄ not forming the substituted or unsubstituted heterocycle, not forming the substituted or unsubstituted monocyclic ring, and not forming the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₉₀₆, a group represented by —COOR₉₀₇, a group represented by —N(R_{6A})(R_{6B}), a halogen atom, a cyano group, a nitro group, a substituted or unsubstituted aryl group having 6 to 50 ring carbon atoms, or a substituted or unsubstituted heterocyclic group having 5 to 50 ring atoms.

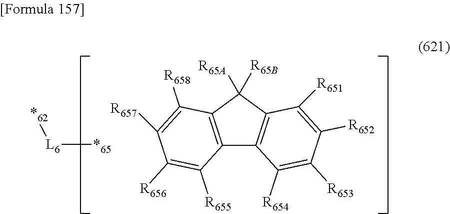

In the formula (621):
at least one combination of adjacent two or more of R₆₅₁ to R₆₅₈ are mutually bonded to form a substituted or unsubstituted monocyclic ring, mutually bonded to form a substituted or unsubstituted fused ring, or not mutually bonded;
one of R₆₅₁ to R₆₅₈ forming neither the substituted or unsubstituted monocyclic ring nor the substituted or unsubstituted fused ring is a bonding position to L₆;
R₆₅₁ to R₆₅₈ forming neither the substituted or unsubstituted monocyclic ring nor the substituted or unsubstituted fused ring and not being the bonding position to L₆ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₉₀₆, a group represented by —COOR₉₀₇, a halogen atom, a cyano group, a nitro group, a substituted or unsubstituted aryl group having 6 to 50 ring carbon atoms, or a substituted or unsubstituted heterocyclic group having 5 to 50 ring atoms;
a combination of R_{65A} to R_{65B} are mutually bonded to form a substituted or unsubstituted monocyclic ring, mutually bonded to form a substituted or unsubstituted fused ring, or not mutually bonded;
R_{65A} to R_{65B} forming neither the substituted or unsubstituted monocyclic ring nor the substituted or unsubstituted fused ring are each independently a substituted or unsubstituted alkyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
L₆ is a single bond, a substituted or unsubstituted alkylene group having 1 to 50 carbon atoms, a substituted or unsubstituted arylene group having 6 to 50 ring carbon atoms, or a substituted or unsubstituted divalent heterocyclic group having 5 to 50 ring atoms; and
*₆₂ represents a bonding position to a nitrogen atom, and *₆₅ represents a bonding position to one of R₆₅₁ to R₆₅₈.

R_{601A} and R_{602A} in the formula (62) are groups that correspond to R₆₀₁ and R₆₀₂ in the formula (6), respectively.

For instance, R_{601A} and R₆₁₁ are optionally bonded with each other to form a bicyclic (or tri-or-more cyclic) fused nitrogen-containing heterocycle, in which the ring including R_{601A} and R₆₁₁ and a benzene ring corresponding to the ring a are fused. Specific examples of the nitrogen-containing heterocycle include a compound corresponding to the nitrogen-containing bi(or-more)cyclic fused heterocyclic group in the specific example group G2. The same applies to R_{601A} bonded with R₆₂₄, R_{602A} bonded with R₆₁₃, and R_{602A} bonded with R₆₃₁.

At least one combination of adjacent two or more of R₆₁₁ to R₆₁₃, R₆₂₁ to R₆₂₄, and R₆₃₁ to R₆₃₄ may be mutually bonded to form a substituted or unsubstituted monocyclic ring, or mutually bonded to form a substituted or unsubstituted fused ring.

For instance, R₆₁₁ and R₆₁₂ are optionally mutually bonded to form a structure in which a benzene ring, indole ring, pyrrole ring, benzofuran ring, benzothiophene ring or the like is fused to the six-membered ring bonded with R₆₁₁ and R₆₁₂, the resultant fused ring forming a naphthalene ring, carbazole ring, indole ring, dibenzofuran ring, or dibenzothiophene ring, respectively.

In an exemplary embodiment, R₆₁₁ to R₆₁₃, R₆₂₁ to R₆₂₄, and R₆₃₁ to R₆₃₄ not contributing to ring formation are each independently a hydrogen atom, a substituted or unsubstituted alkyl group having 1 to 50 carbon atoms, a substituted or unsubstituted aryl group having 6 to 50 ring carbon atoms, a substituted or unsubstituted heterocyclic group having 5 to 50 ring atoms, or a group represented by —N(R_{6A})(R_{6B}).

In an exemplary embodiment, R₆₁₁ to R₆₁₃, R₆₂₁ to R₆₂₄, and R₆₃₁ to R₆₃₄ not contributing to ring formation are each independently a hydrogen atom, a substituted or unsubstituted aryl group having 6 to 50 ring carbon atoms, a substituted or unsubstituted heterocyclic group having 5 to 50 ring atoms, or a group represented by —N(R_{6A})(R_{6B}).

In an exemplary embodiment, R₆₁₃, R₆₂₁ to R₆₂₄, and R₆₃₁ to R₆₃₄ not contributing to ring formation are each independently a hydrogen atom, a substituted or unsubstituted alkyl group having 1 to 50 carbon atoms, or a group represented by —N(R_{6A})(R_{6B}).

In an exemplary embodiment, R₆₁₁ to R₆₁₃, R₆₂₁ to R₆₂₄, and R₆₃₁ to R₆₃₄ not contributing to ring formation are each independently a hydrogen atom, a substituted or unsubstituted alkyl group having 1 to 50 carbon atoms, or a group represented by —N(R_{6A})(R_{6B}); and
at least one of R₆₁₁ to R₆₁₃, R₆₂₁ to R₆₂₄, or R₆₃₁ to R₆₃₄ is at least one group of a substituted or unsubstituted alkyl group having 1 to 50 carbon atoms, or a group represented by —N(R_{6A})(R_{6B}).

In an exemplary embodiment, R₆₁₁ to R₆₁₃, R₆₂₁ to R₆₂₄, and R₆₃₁ to R₆₃₄ not contributing to ring formation are each independently a hydrogen atom, or a group represented by —N(R_{6A})(R_{6B}); and
at least one of R₆₁₁ to R₆₁₃, R₆₂₁ to R₆₂₄, or R₆₃₁ to R₆₃₄ is a group represented by —N(R_{6A})(R_{6B}).

In an exemplary embodiment, R₆₅₁ to R₆₅₈ not contributing to ring formation and not involved in bonding to L₆ is a hydrogen atom.

In an exemplary embodiment, the group represented by the formula (621) is represented by a formula (622) below.

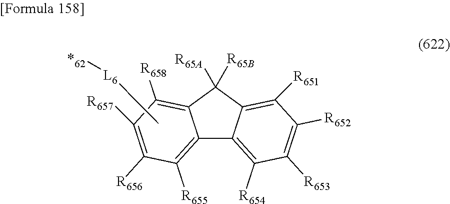

In the formula (622): one of R₆₅₅ to R₆₅₈ represents a bonding position to L₆, R₆₅₅ to R₆₅₈ not being the bonding position to L₆ each independently represent the same as R₆₅₅ to R₆₅₈ in the formula (621), R₆₅₁ to R₆₅₄ and R_{65A} to R_{65B} each independently represent the same as R₆₅₁ to R₆₅₄ and R_{65A} to R_{65B} in the formula (621), and *₆₂ represents the same as *₆₂ in the formula (621).

In an exemplary embodiment, the compound represented by the formula (62) is a compound represented by a formula (62A) below.

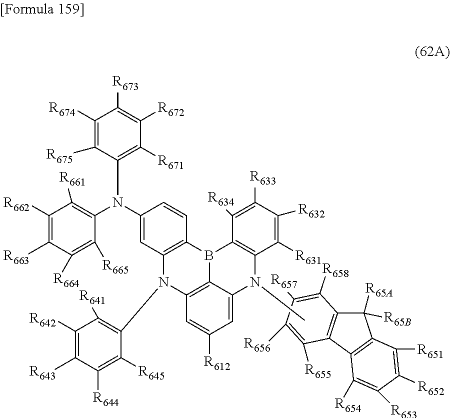

In the formula (62A):
at least one combination of adjacent two or more of R₆₄₁ to R₆₄₅, R₆₆₁ to R₆₆₅, and R₆₇₁ to R₆₇₅ are mutually bonded to form a substituted or unsubstituted monocyclic ring, mutually bonded to form a substituted or unsubstituted fused ring, or not mutually bonded,
R₆₄₁ to R₆₄₅, R₆₆₁ to R₆₆₅, and R₆₇₁ to R₆₇₅ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R_{6A})(R_{6B}), a halogen atom, a cyano group, a nitro group, a substituted or unsubstituted aryl group having 6 to 50 ring carbon atoms, or a substituted or unsubstituted heterocyclic group having 5 to 50 ring atoms;
R₆₁₂ and R₆₃₁ to R₆₃₄ each independently represent the same as R₆₁₂ and R₆₃₁ to R₆₃₄ in the formula (62); and
R₆₅₁ to R₆₅₈, and R_{65A} to R_{65B} each independently represent the same as R₆₅₁ to R₆₅₈, and R_{65A} to R_{65B} in the formula (622).

In an exemplary embodiment, the compound represented by the formula (62) is a compound represented by a formula (62B) below.

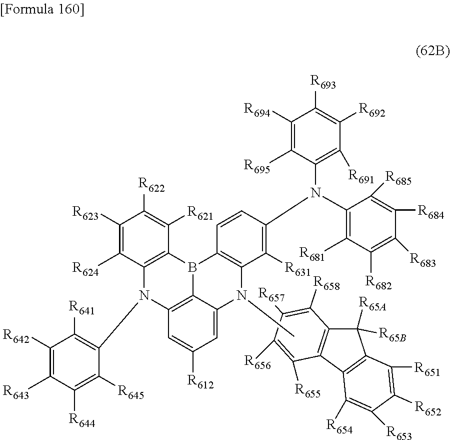

In the formula (62B):
at least one combination of adjacent two or more of R₆₄₁ to R₆₄₅, R₆₈₁ to R₆₈₅, and R₆₉₁ to R₆₉₅ are mutually bonded to form a substituted or unsubstituted monocyclic ring, mutually bonded to form a substituted or unsubstituted fused ring, or not mutually bonded;
R₆₄₁ to R₆₄₅, R₆₈₁ to R₆₈₅, and R₆₉₁ to R₆₉₅ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R_{6A})(R_{6B}), a halogen atom, a cyano group, a nitro group, a substituted or unsubstituted aryl group having 6 to 50 ring carbon atoms, or a substituted or unsubstituted heterocyclic group having 5 to 50 ring atoms;
R₆₁₂, and R₆₂₁ to R₆₂₄ are each as defined in the formula (62), and R₆₁₂, and R₆₂₁ to R₆₂₄ each independently represent the same as R₆₁₂, and R₆₂₁ to R₆₂₄ in the formula (62); and
R₆₅₁ to R₆₅₈, and R_{65A} to R_{65B} are each as defined in the formula (622), and R₆₅₁ to R₆₅₈, and R_{65A} to R_{65B} each independently represent the same as R₆₅₁ to R₆₅₈, and R_{65A} to R_{65B} in the formula (622).

In an exemplary embodiment, the compound represented by the formula (62) is a compound represented by a formula (62C) below.

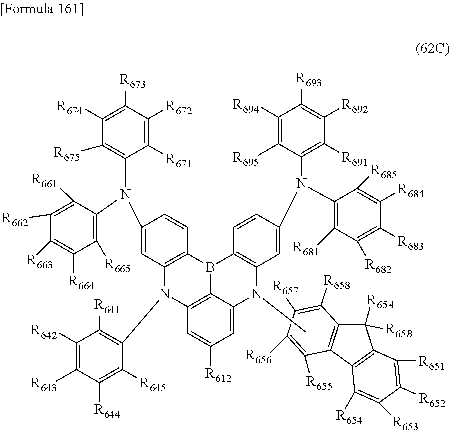

In the formula (62C):
at least one combination of adjacent two or more of R₆₄₁ to R₆₄₅, R₆₆₁ to R₆₆₅, R₆₇₁ to R₆₇₅, R₆₈₁ to R₆₈₅, and R₆₉₁ to R₆₉₅ are mutually bonded to form a substituted or unsubstituted monocyclic ring, mutually bonded to form a substituted or unsubstituted fused ring, or not mutually bonded,
R₆₄₁ to R₆₄₅, R₆₆₁ to R₆₆₅, R₆₇₁ to R₆₇₅, R₆₈₁ to R₆₈₅, and R₆₉₁ to R₆₉₅ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R_{6A})(R_{6B}), a halogen atom, a cyano group, a nitro group, a substituted or unsubstituted aryl group having 6 to 50 ring carbon atoms, or a substituted or unsubstituted heterocyclic group having 5 to 50 ring atoms;
R₆₁₂ is as defined in the formula (62), and R₆₁₂ represents the same as R₆₁₂ in the formula (62); and
R₆₅₁ to R₆₅₈, and R_{65A} to R_{65B} are each as defined in the formula (622), and R₆₅₁ to R₆₅₈, and R_{65A} to R_{65B} each independently represent the same as R₆₅₁ to R₆₅₈, and R_{65A} to R_{65B} in the formula (622).

In an exemplary embodiment, the compound represented by the formula (62A) is a compound represented by a formula (62A-1) below.

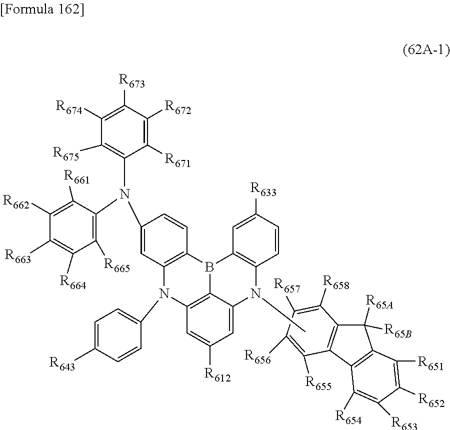

In the formula (62A-1): R₆₁₂, R₆₃₃, R₆₄₃, R₆₆₁ to R₆₆₅, R₆₇₁ to R₆₇₅, R₆₅₁ to R₆₅₈, and R_{65A} to R_{65B} each independently represent the same as R₆₁₂, R₆₃₃, R₆₄₃, R₆₆₁ to R₆₆₅, R₆₇₁ to R₆₇₅, R₆₅₁ to R₆₅₈, and R_{65A} to R_{65B} in the formula (62A).

In an exemplary embodiment, the compound represented by the formula (62B) is a compound represented by a formula (62B-1) below.

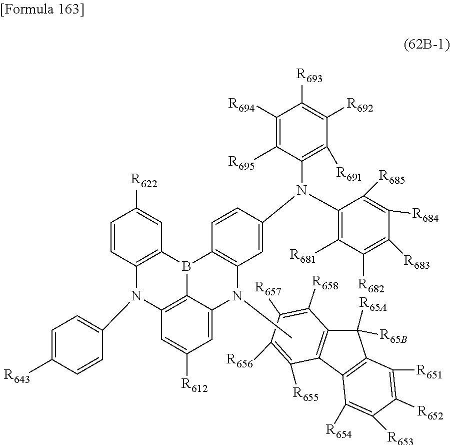

In the formula (62B-1): R₆₁₂, R₆₂₂, R₆₄₃, R₆₈₁ to R₆₈₅, R₆₉₁ to R₆₉₅, R₆₅₁ to R₆₅₈, and R_{65A} to R_{65B} each independently represent the same as R₆₁₂, R₆₂₂, R₆₄₃, R₆₈₁ to R₆₈₅, R₆₉₁ to R₆₉₅, R₆₅₁ to R₆₅₈, and R_{65A} to R_{65B} in the formula (62B).

In an exemplary embodiment, the compound represented by the formula (62C) is a compound represented by a formula (62C-1) below.

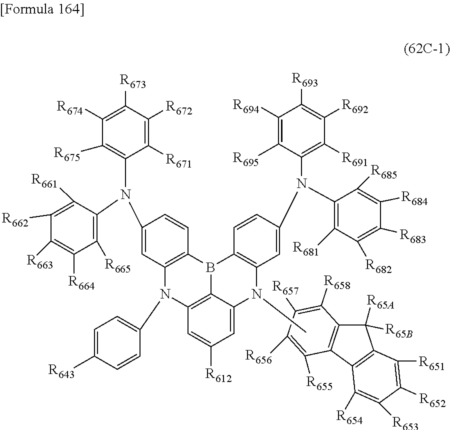

In the formula (62C-1): R₆₁₂, R₆₄₃, R₆₆₁ to R₆₆₅, R₆₇₁ to R₆₇₅, R₆₈₁ to R₆₈₅, R₆₉₁ to R₆₉₅, R₆₅₁ to R₆₅₈, and R_{65A} to R_{65B} each independently represent the same as R₆₁₂, R₆₂₂, R₆₄₃, R₆₆₁ to R₆₆₅, R₆₇₁ to R₆₇₅, R₆₈₁ to R₆₈₅, R₆₉₁ to R₆₉₅, R₆₅₁ to R₆₅₈, and R_{65A} to R_{65B} in the formula (62C).

In an exemplary embodiment, R₆₁₂, R₆₂₂, R₆₃₃, R₆₄₃, R₆₆₁ to R₆₆₅, R₆₇₁ to R₆₇₅, R₆₈₁ to R₆₈₅, and R₆₉₁ to R₆₉₅ of the formulae (62A), (62B), (62C), (62A-1), (62B-1), and (62C-1) are each independently a hydrogen atom, a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In an exemplary embodiment, R₆₁₂, R₆₂₂, R₆₃₃, R₆₄₃, R₆₆₁ to R₆₆₅, R₆₇₁ to R₆₇₅, R₆₈₁ to R₆₈₅, and R₆₉₁ to R₆₉₅ of the formulae (62A), (62B), (62C), (62A-1), (62B-1), and (62C-1) are each independently a hydrogen atom, or a substituted or unsubstituted aryl group having 6 to 50 ring carbon atoms.

The compound represented by the formula (6) is producible by initially bonding the ring a, ring b and ring c with linking groups (a group including N—R₆₀₁ and a group including N—R₆₀₂) to form an intermediate (first reaction), and bonding the ring a, ring b and ring c with a linking group (a group including a boron atom) to form a final product (second reaction). In the first reaction, an amination reaction (e.g. Buchwald-Hartwig reaction) is applicable. In the second reaction, Tandem Hetero-Friedel-Crafts Reactions or the like is applicable.

### Compounds Represented by Formulae (64-1) to (64-5)

The compounds represented by the formulae (64-1) to (64-5) will be described.

In an exemplary embodiment, the compound represented by the formula (6) is selected from the group consisting of the compounds represented by the formulae (64-1) to (64-5) below.

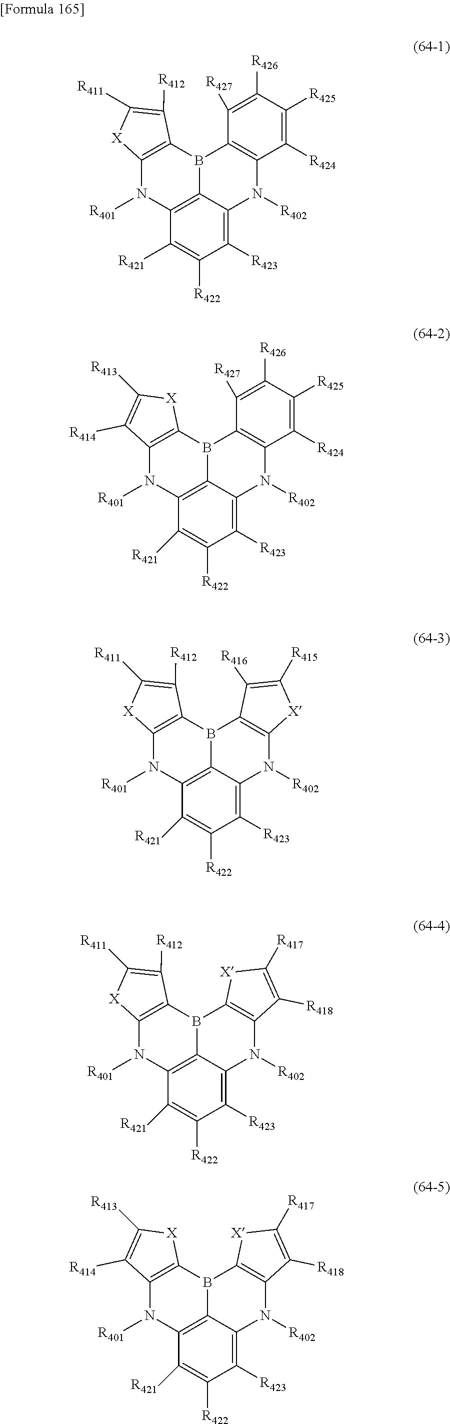

In the formula (64-1):
X is O, S, Se, C(R₄₀₃)(R₄₀₄), or NR₄₀₅.

At least one combination of a combination of R₄₀₁ and R₄₂₁, a combination of adjacent two or more of R₄₂₁ to R₄₂₃, a combination of R₄₂₃ and R₄₀₂, a combination of R₄₀₂ and R₄₂₄, a combination of adjacent two or more of R₄₂₄ to R₄₂₇, a combination of R₄₂₇ and R₄₁₂, or a combination of R₄₁₂ and R₄₁₁ are mutually bonded to form a substituted or unsubstituted monocyclic ring, mutually bonded to form a substituted or unsubstituted fused ring, or not mutually bonded; and
R₄₀₁ and R₄₀₂ forming neither the substituted or unsubstituted monocyclic ring nor the substituted or unsubstituted fused ring are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.
R₄₀₃ to R₄₀₅, and R₄₁₁, R₄₁₂ and R₄₂₁ to R₄₂₇ forming neither the substituted or unsubstituted monocyclic ring nor the substituted or unsubstituted fused ring are each independently a hydrogen atom or a substituent R;
each substituent R is independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

In the formula (64-2):

X is O, S, Se, C(R₄₀₃)(R₄₀₄), or NR₄₀₅.

At least one combination of a combination of R₄₀₁ and R₄₂₁, a combination of adjacent two or more of R₄₂₁ to R₄₂₃, a combination of R₄₂₃ and R₄₀₂, a combination of R₄₀₂ and R₄₂₄, a combination of adjacent two or more of R₄₂₄ to R₄₂₇, a combination of R₄₁₃ and R₄₁₄, or a combination of R₄₁₄ and R₄₀₁ are mutually bonded to form a substituted or unsubstituted monocyclic ring, mutually bonded to form a substituted or unsubstituted fused ring, or not mutually bonded; and
R₄₀₁ and R₄₀₂ forming neither the substituted or unsubstituted monocyclic ring nor the substituted or unsubstituted fused ring are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

R₄₀₃ to R₄₀₅, and R₄₁₃, R₄₁₄ and R₄₂₁ to R₄₂₇ forming neither the substituted or unsubstituted monocyclic ring nor the substituted or unsubstituted fused ring are each independently a hydrogen atom or a substituent R, and the substituent R represents the same as the substituent R in the formula (64-1).

In the formula (64-3):

X and X′ are each independently O, S, Se, C(R₄₀₃)(R₄₀₄), or NR₄₀₅.

At least one combination of a combination of R₄₀₁ and R₄₂₁, a combination of adjacent two or more of R₄₂₁ to R₄₂₃, a combination of R₄₂₃ and R₄₀₂, a combination of R₄₁₅ and R₄₁₆, a combination of R₄₁₆ and R₄₁₂, or a combination of R₄₁₂ and R₄₁₁ are mutually bonded to form a substituted or unsubstituted monocyclic ring, mutually bonded to form a substituted or unsubstituted fused ring, or not mutually bonded; and
R₄₀₁ and R₄₀₂ forming neither the substituted or unsubstituted monocyclic ring nor the substituted or unsubstituted fused ring are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

R₄₀₃ to R₄₀₅, and R₄₁₁, R₄₁₂, R₄₁₅, R₄₁₆ and R₄₂₁ to R₄₂₃ forming neither the substituted or unsubstituted monocyclic ring nor the substituted or unsubstituted fused ring are each independently a hydrogen atom or a substituent R, and the substituent R represents the same as the substituent R in the formula (64-1).

When a plurality of R₄₀₃ are present, the plurality of R₄₀₃ are mutually the same or different;
when a plurality of R₄₀₄ are present, the plurality of R₄₀₄ are mutually the same or different; and
when a plurality of R₄₀₅ are present, the plurality of R₄₀₅ are mutually the same or different.

In the formula (64-4):
X and X′ are each independently O, S, Se, C(R₄₀₃)(R₄₀₄), or NR₄₀₅.

At least one combination of a combination of R₄₀₁ and R₄₂₁, a combination of adjacent two or more of R₄₂₁ to R₄₂₃, a combination of R₄₂₃ and R₄₀₂, a combination of R₄₀₂ and R₄₁₈, a combination of R₄₁₈ and R₄₁₇, or a combination of R₄₁₂ and R₄₁₁ are mutually bonded to form a substituted or unsubstituted monocyclic ring, mutually bonded to form a substituted or unsubstituted fused ring, or not mutually bonded; and
R₄₀₁ and R₄₀₂ forming neither the substituted or unsubstituted monocyclic ring nor the substituted or unsubstituted fused ring are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

R₄₀₃ to R₄₀₅, and R₄₁₁, R₄₁₂, R₄₁₇, R₄₁₈ and R₄₂₁ to R₄₂₃ forming neither the substituted or unsubstituted monocyclic ring nor the substituted or unsubstituted fused ring are each independently a hydrogen atom or a substituent R, and the substituent R represents the same as the substituent R in the formula (64-1).

When a plurality of R₄₀₃ are present, the plurality of R₄₀₃ are mutually the same or different;
when a plurality of R₄₀₄ are present, the plurality of R₄₀₄ are mutually the same or different; and
when a plurality of R₄₀₅ are present, the plurality of R₄₀₅ are mutually the same or different.

In the formula (64-5):

X and X′ are each independently O, S, Se, C(R₄₀₃)(R₄₀₄), or NR₄₀₅.

At least one combination of a combination of R₄₀₁ and R₄₂₁, a combination of adjacent two or more of R₄₂₁ to R₄₂₃, a combination of R₄₂₃ and R₄₀₂, a combination of R₄₀₂ and R₄₁₈, a combination of R₄₁₈ and R₄₁₇, a combination of R₄₁₃ and R₄₁₄, or a combination of R₄₁₄ and R₄₀₁ are mutually bonded to form a substituted or unsubstituted monocyclic ring, mutually bonded to form a substituted or unsubstituted fused ring, or not mutually bonded; and
R₄₀₁ and R₄₀₂ forming neither the substituted or unsubstituted monocyclic ring nor the substituted or unsubstituted fused ring are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

R₄₀₃ to R₄₀₅, and R₄₁₃, R₄₁₄, R₄₁₇, R₄₁₈ and R₄₂₁ to R₄₂₃ forming neither the substituted or unsubstituted monocyclic ring nor the substituted or unsubstituted fused ring are each independently a hydrogen atom or a substituent R, and the substituent R represents the same as the substituent R in the formula (64-1).

When a plurality of R₄₀₃ are present, the plurality of R₄₀₃ are mutually the same or different;
when a plurality of R₄₀₄ are present, the plurality of R₄₀₄ are mutually the same or different; and
when a plurality of R₄₀₅ are present, the plurality of R₄₀₅ are mutually the same or different.

In an exemplary embodiment, the compound represented by the formula (64-2) is a compound represented by a formula (64-2A) below.

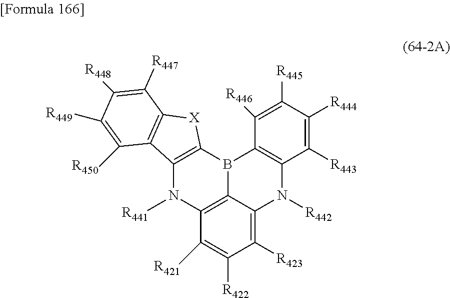

In the formula (64-2A):
at least one combination of a combination of R₄₄₁ and R₄₂₁, a combination of adjacent two or more of R₄₂₁ to R₄₂₃, a combination of R₄₂₃ and R₄₄₂, a combination of R₄₄₂ and R₄₄₃, a combination of adjacent two or more of R₄₄₃ to R₄₄₆, a combination of adjacent two or more of R₄₄₇ to R₄₅₀, or a combination of R₄₅₀ and R₄₄₁ are mutually bonded to form a substituted or unsubstituted monocyclic ring, mutually bonded to form a substituted or unsubstituted fused ring, or not mutually bonded, and
R₄₄₁ and R₄₄₂ forming neither the substituted or unsubstituted monocyclic ring nor the substituted or unsubstituted fused ring are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

R₄₂₁ to R₄₂₃ and R₄₄₃ to R₄₅₀ forming neither the substituted or unsubstituted monocyclic ring nor the substituted or unsubstituted fused ring are each independently a hydrogen atom or a substituent R, and the substituent R represents the same as the substituent R in the formula (64-1).

X is O or S.

In an exemplary embodiment, the substituent for the “substituted or unsubstituted” group in the formulae (64-1) to (64-5) is selected from the group consisting of an unsubstituted alkyl group having 1 to 50 carbon atoms, an unsubstituted haloalkyl group having 1 to 50 carbon atoms, an unsubstituted alkenyl group having 2 to 50 carbon atoms, an unsubstituted alkynyl group having 2 to 50 carbon atoms, an unsubstituted cycloalkyl group having 3 to 50 ring carbon atoms, an unsubstituted alkoxy group having 1 to 50 carbon atoms, an unsubstituted alkylthio group having 1 to 50 carbon atoms, an unsubstituted aryloxy group having 6 to 50 ring carbon atoms, an unsubstituted arylthio group having 6 to 50 ring carbon atoms, an unsubstituted aralkyl group having 7 to 50 carbon atoms, a group represented by —Si(R₄₁)(R₄₂)(R₄₃), a group represented by —C(═O)R₄₄, a group represented by —COOR₄₅, a group represented by —S(═O)₂R₄₆, a group represented by —P(═O)(R₄₇)(R₄₈), a group represented by —Ge(R₄₉)(R₅₀)(R₅₁), a group represented by —N(R₅₂)(R₅₃),
where R₄₁ to R₅₃ are each independently a hydrogen atom, an unsubstituted alkyl group having 1 to 50 carbon atoms, an unsubstituted aryl group having 6 to 50 ring carbon atoms, or an unsubstituted heterocyclic group having 5 to 50 ring atoms, when two or more R₄₁ are present, the two or more R₄₁ are mutually the same or different; when two or more R₄₂ are present, the two or more R₄₂ are mutually the same or different; when two or more R₄₃ are present, the two or more R₄₃ are mutually the same or different; when two or more R₄₄ are present, the two or more R₄₄ are mutually the same or different; when two or more R₄₅ are present, the two or more R₄₅ are mutually the same or different; when two or more R₄₆ are present, the two or more R₄₆ are mutually the same or different; when two or more R₄₇ are present, the two or more R₄₇ are mutually the same or different; when two or more R₄₈ are present, the two or more R₄₈ are mutually the same or different; when two or more R₄₉ are present, the two or more R₄₉ are mutually the same or different; when two or more R₅₀ are present, the two or more R₅₀ are mutually the same or different; when two or more R₅₁ are present, the two or more R₅₁ are mutually the same or different; when two or more R₅₂ are present, the two or more R₅₂ are mutually the same or different; and when two or more R₅₃ are present, the two or more R₅₃ are mutually the same or different,
a hydroxy group, a halogen atom, a cyano group, a nitro group, an unsubstituted aryl group having 6 to 50 ring carbon atoms, and an unsubstituted monovalent heterocyclic group having 5 to 50 ring atoms.

In an exemplary embodiment, the substituent for the “substituted or unsubstituted” group in the formulae (64-1) to (64-5) is selected from the group consisting of an unsubstituted alkyl group having 1 to 18 carbon atoms, an unsubstituted aryl group having 6 to 18 ring carbon atoms, and an unsubstituted heterocyclic group having 5 to 18 ring atoms.

The compounds represented by the formulae (64-1) to (64-5) can be produced thorough a known alternative reaction using a known material(s) tailored for the target compounds.

### Specific Examples of Compound Represented by Formula (6)

Specific examples of the compound represented by the formula (6) are given below. It should however be noted that these specific examples are merely exemplary and do not limit the compound represented by the formula (6). In the specific examples below, tBu represents a tert-butyl group, and tAm represents a tert-amyl group.

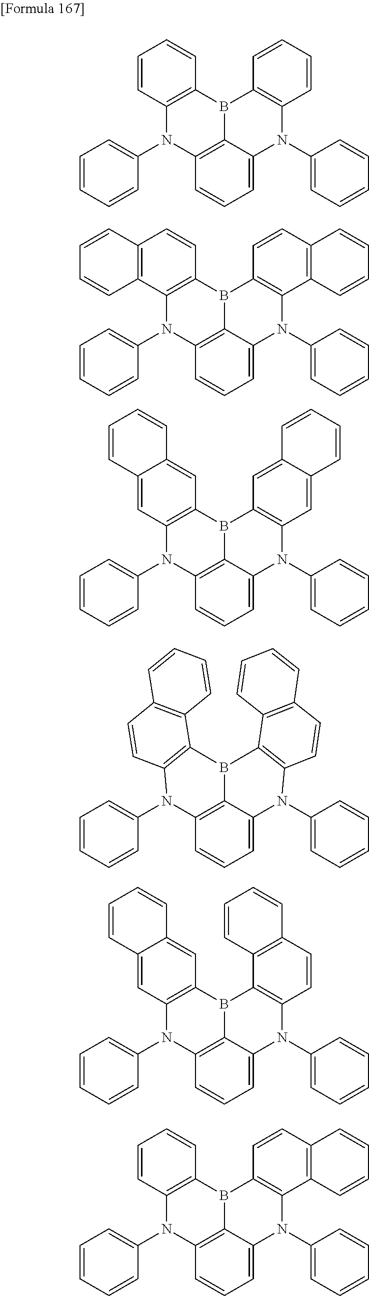

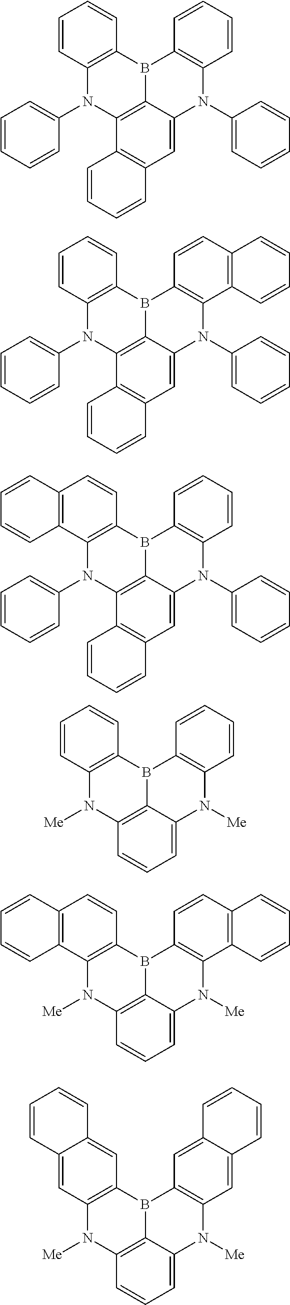

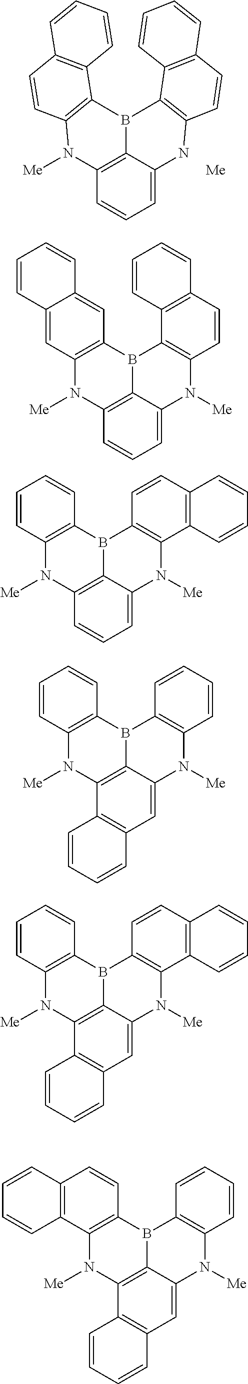

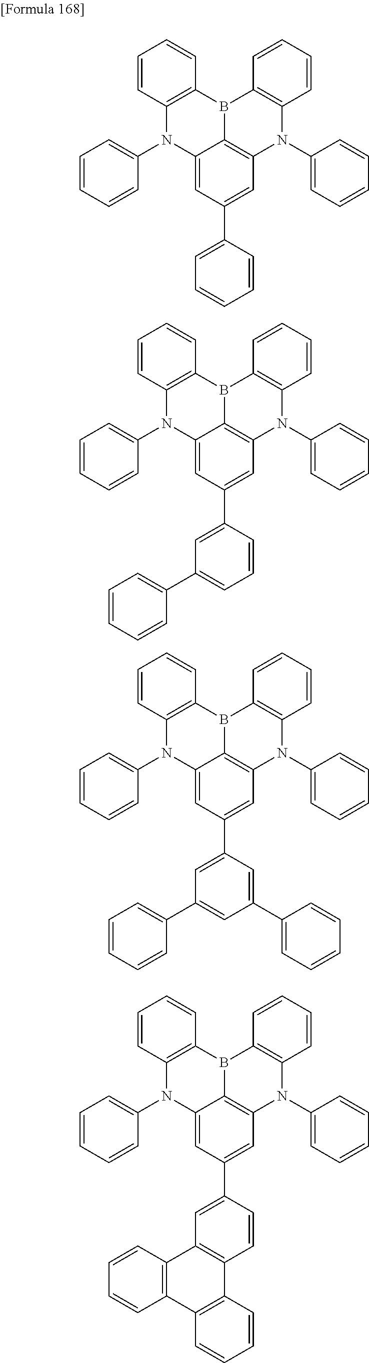

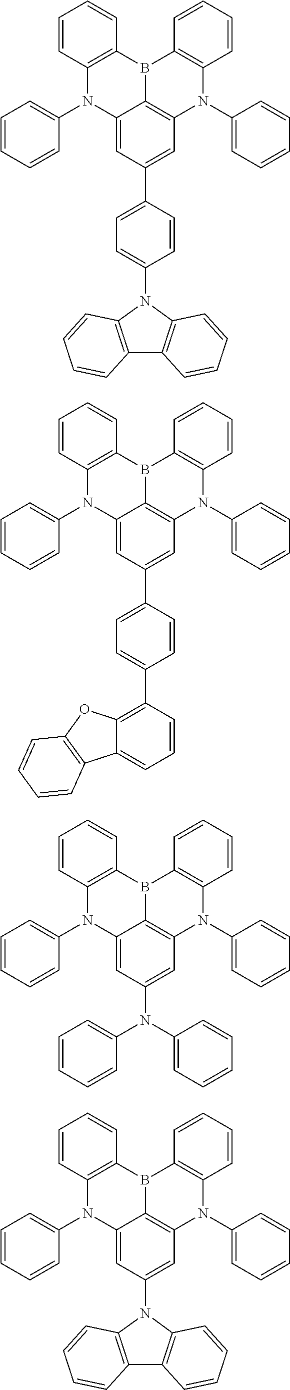

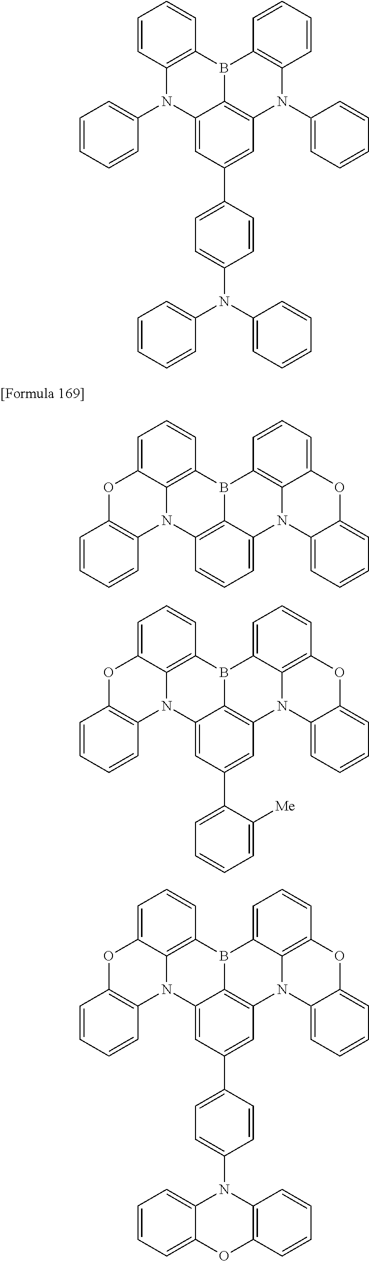

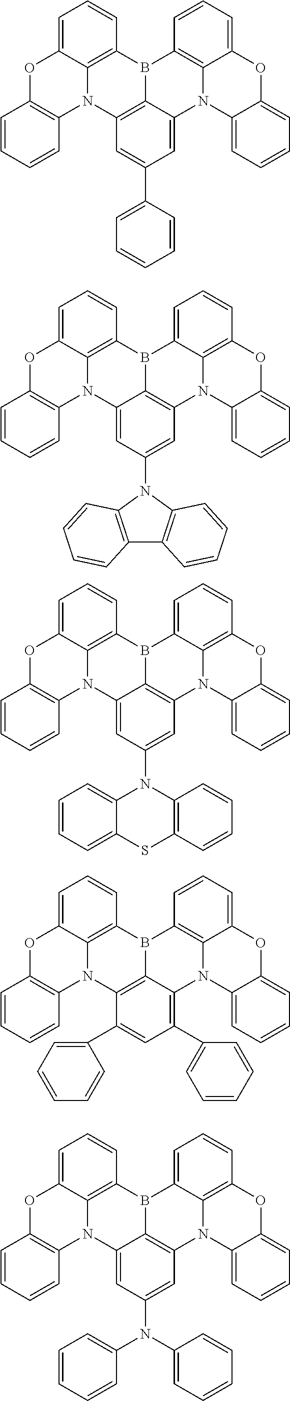

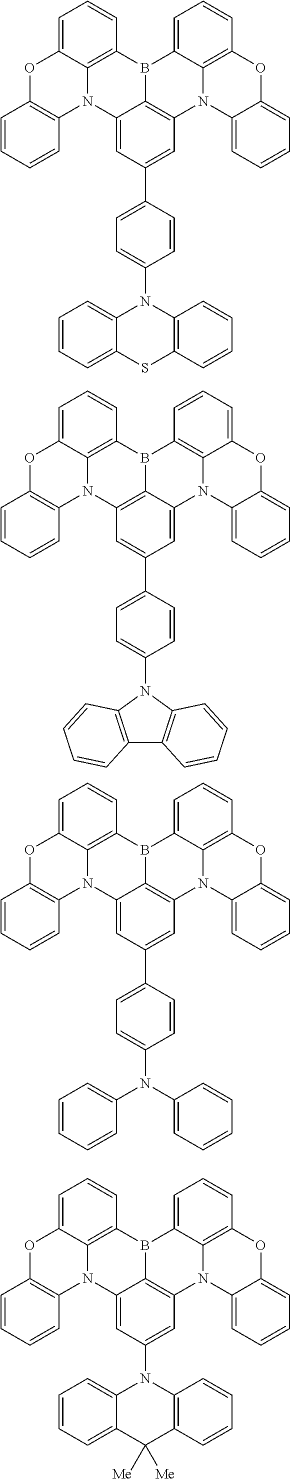

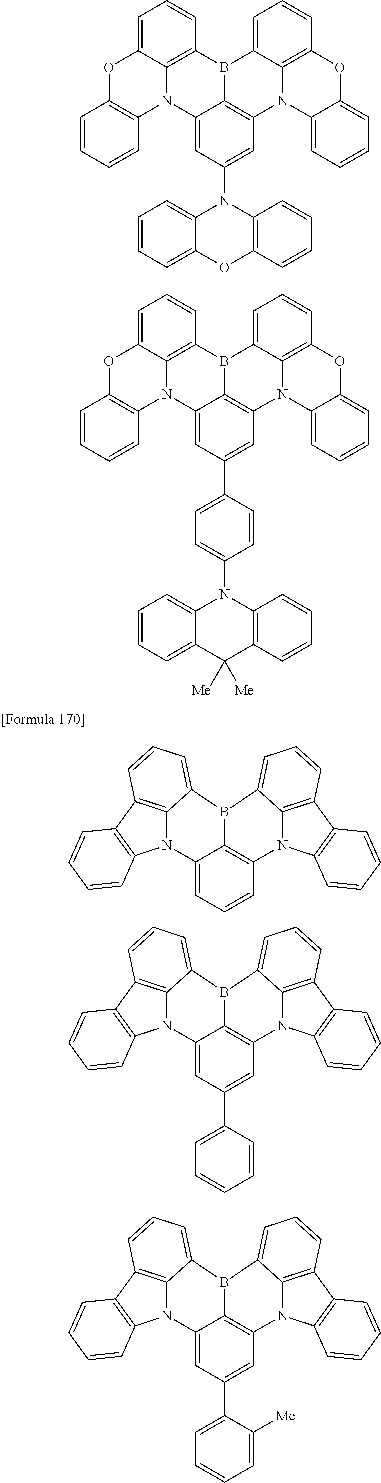

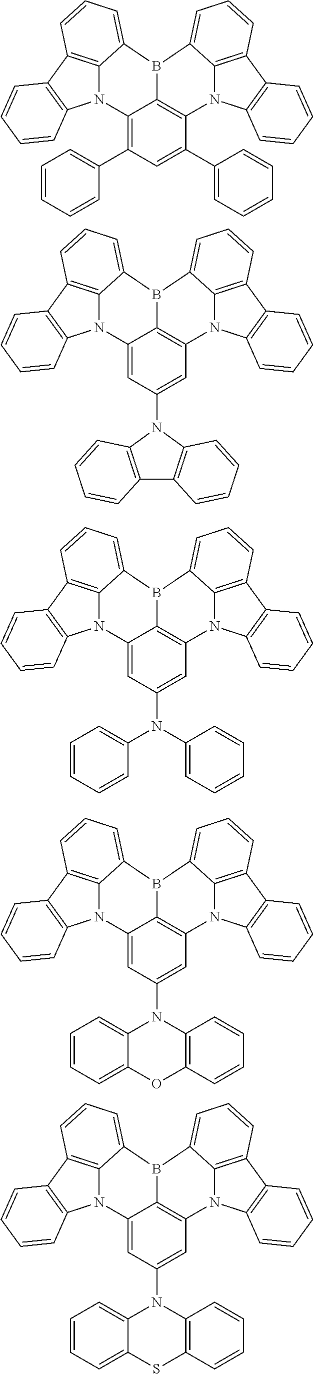

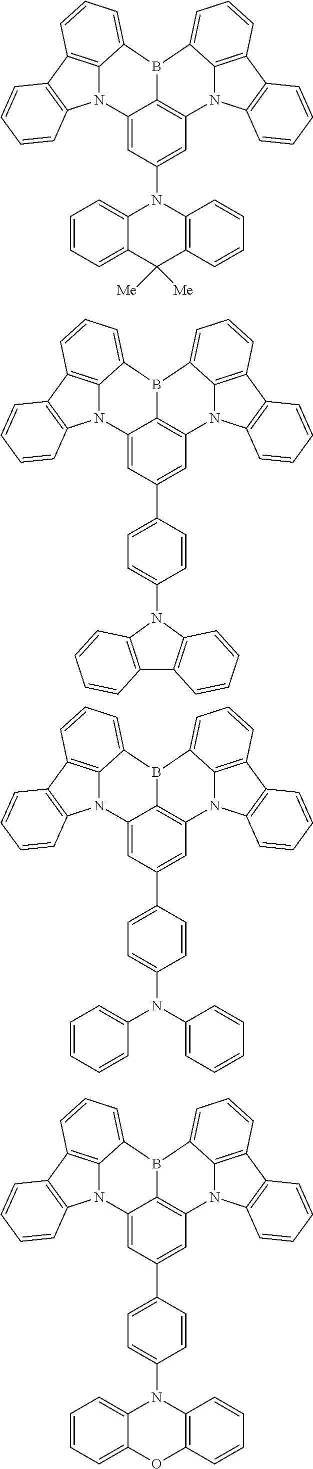

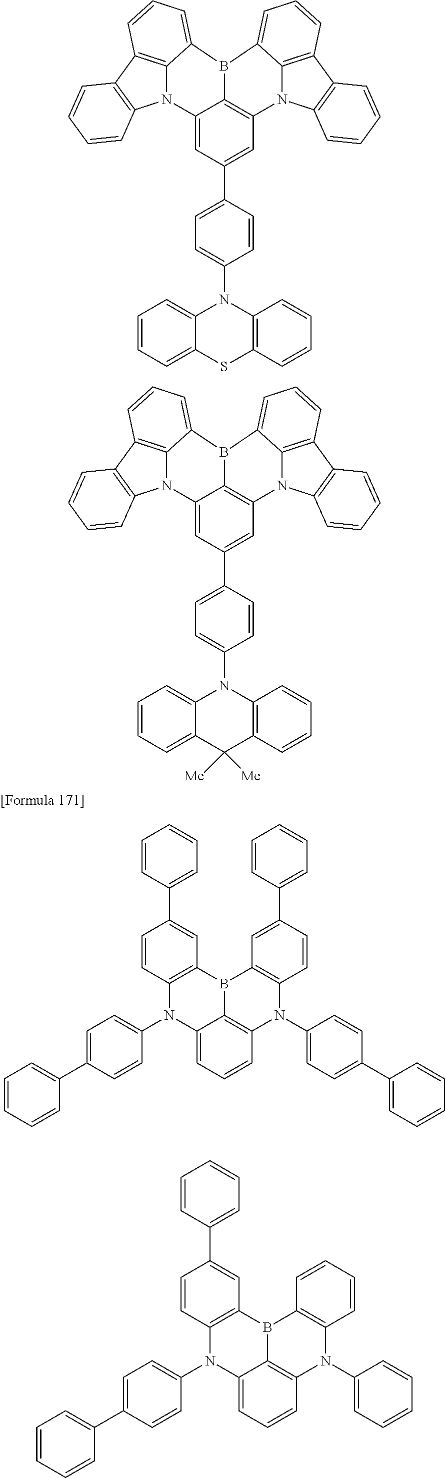

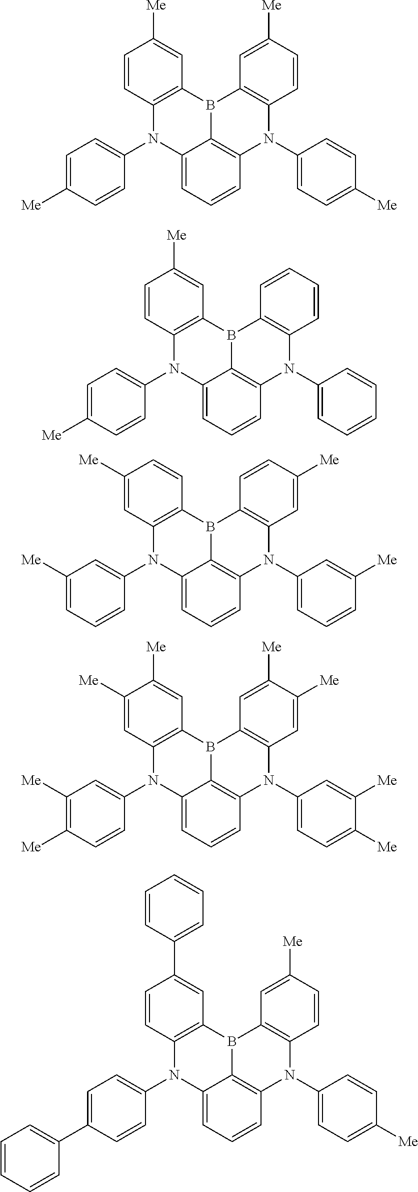

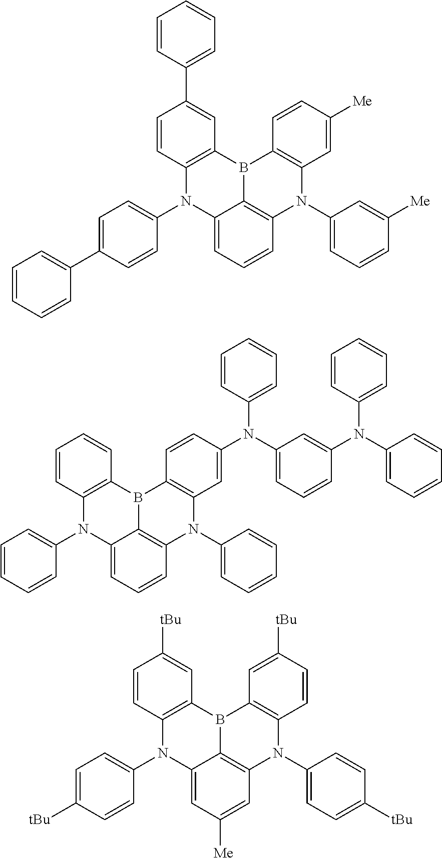

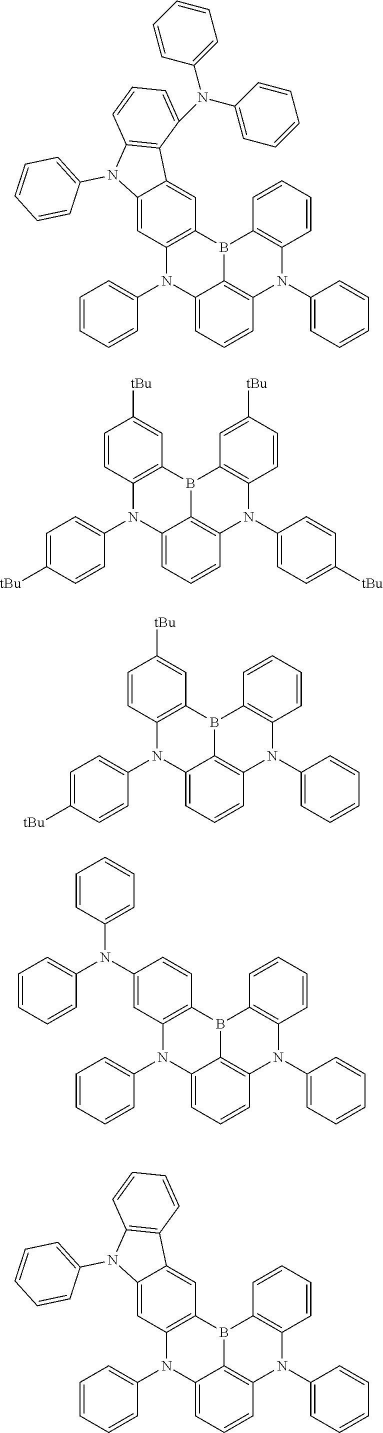

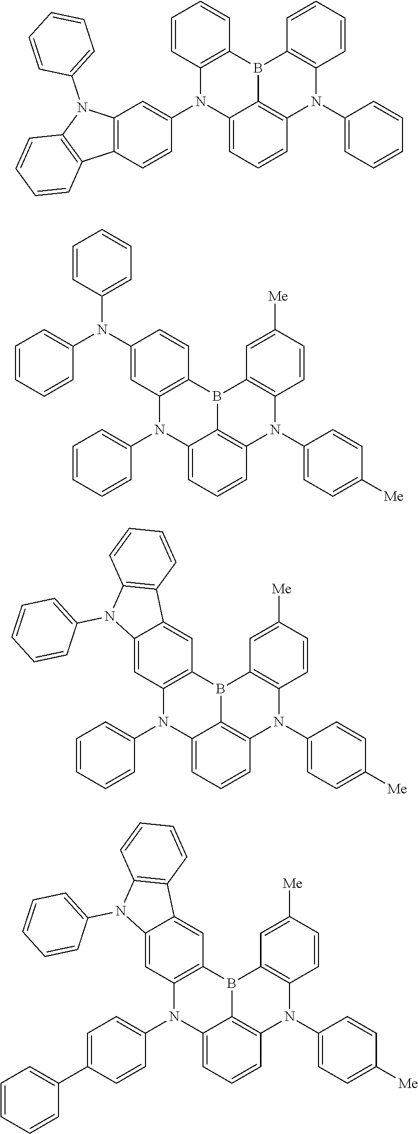

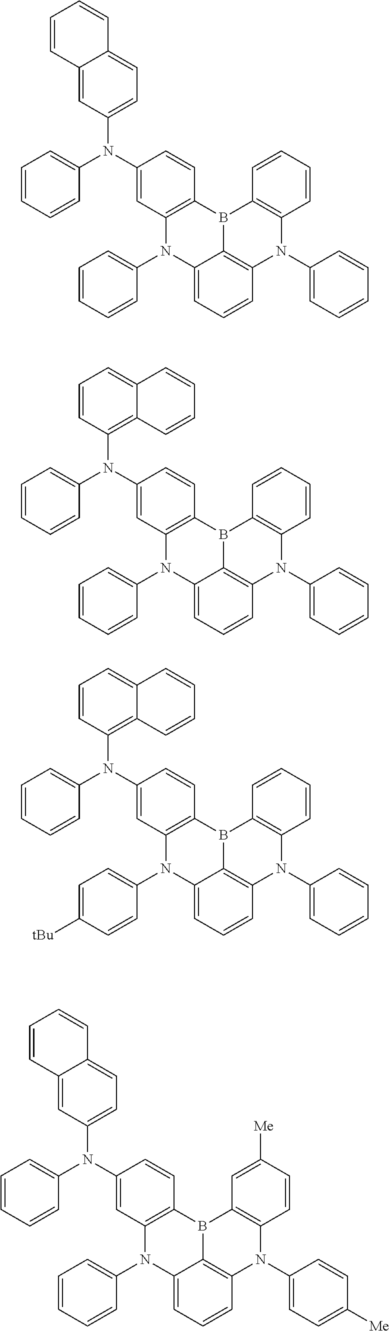

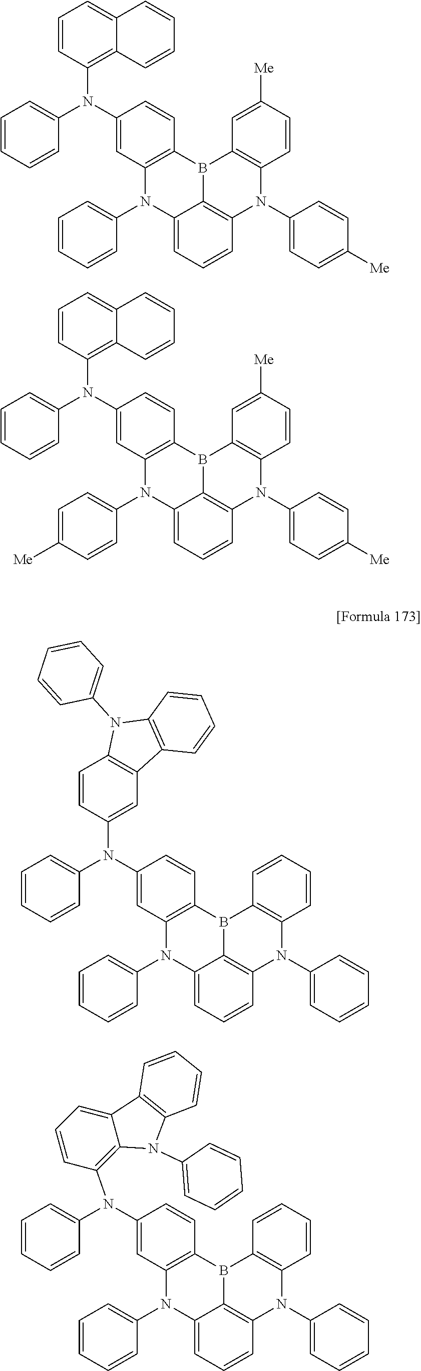

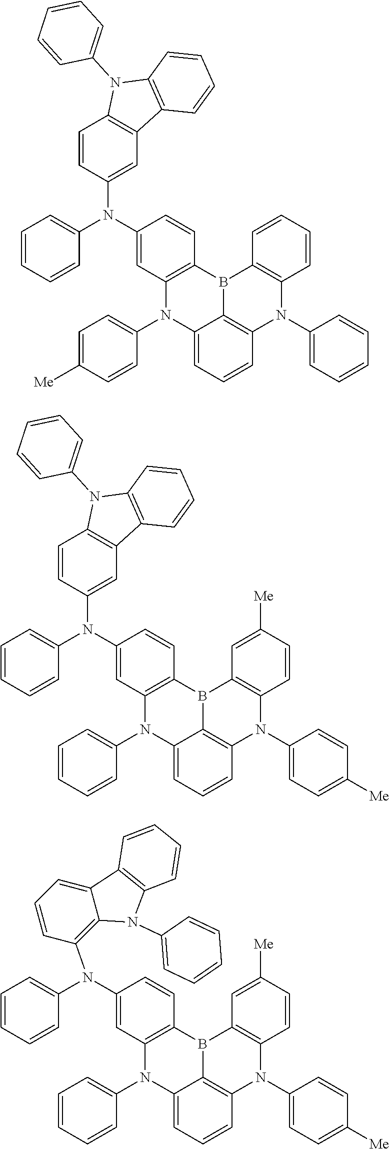

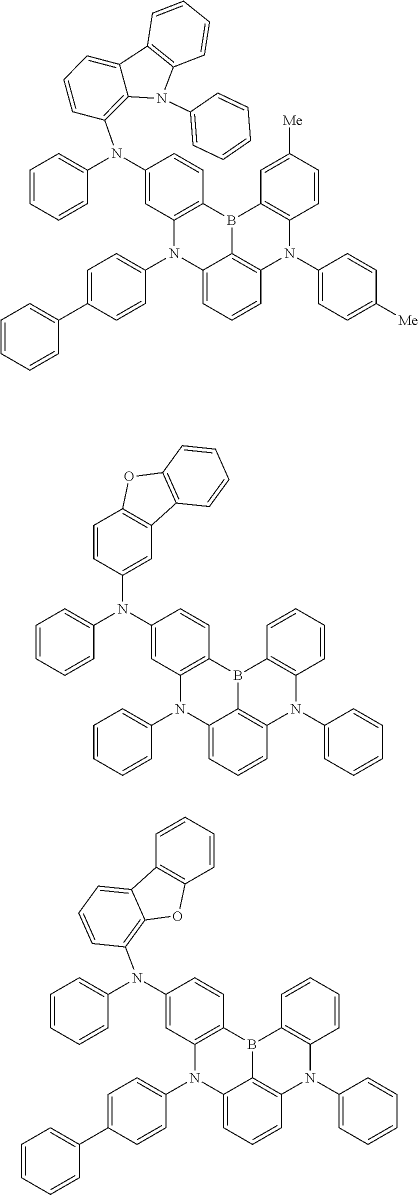 [SMILES: Cc1ccc(N2c3ccc(C)cc3B3c4ccc(N(c5ccccc5)c5cccc6c7ccccc7n(-c7ccccc7)c56)cc4N(c4ccc(-c5ccccc5)cc4)c4cccc2c43)cc1 ; c1ccc(N(c2ccc3c(c2)N(c2ccccc2)c2cccc4c2B3c2ccccc2N4c2ccccc2)c2ccc3oc4ccccc4c3c2)cc1 ; c1ccc(-c2ccc(N3c4cc(N(c5ccccc5)c5cccc6c5oc5ccccc56)ccc4B4c5ccccc5N(c5ccccc5)c5cccc3c54)cc2)cc1]

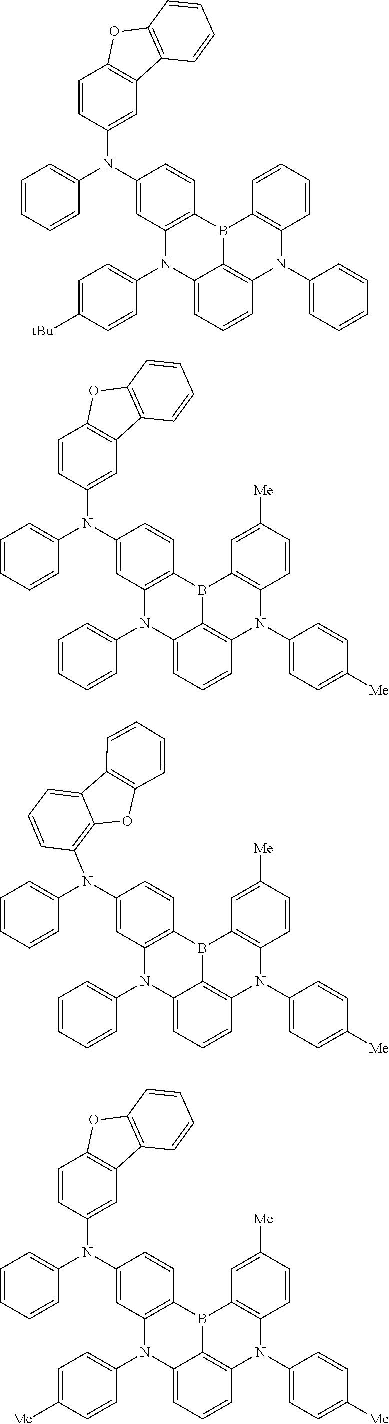 [SMILES: CC(C)(C)c1ccc(N2c3cc(N(c4ccccc4)c4ccc5oc6ccccc6c5c4)ccc3B3c4ccccc4N(c4ccccc4)c4cccc2c43)cc1 ; Cc1ccc(N2c3ccc(C)cc3B3c4ccc(N(c5ccccc5)c5ccc6oc7ccccc7c6c5)cc4N(c4ccccc4)c4cccc2c43)cc1 ; Cc1ccc(N2c3ccc(C)cc3B3c4ccc(N(c5ccccc5)c5cccc6c5oc5ccccc56)cc4N(c4ccccc4)c4cccc2c43)cc1 ; Cc1ccc(N2c3ccc(C)cc3B3c4ccc(N(c5ccccc5)c5ccc6oc7ccccc7c6c5)cc4N(c4ccc(C)cc4)c4cccc2c43)cc1]

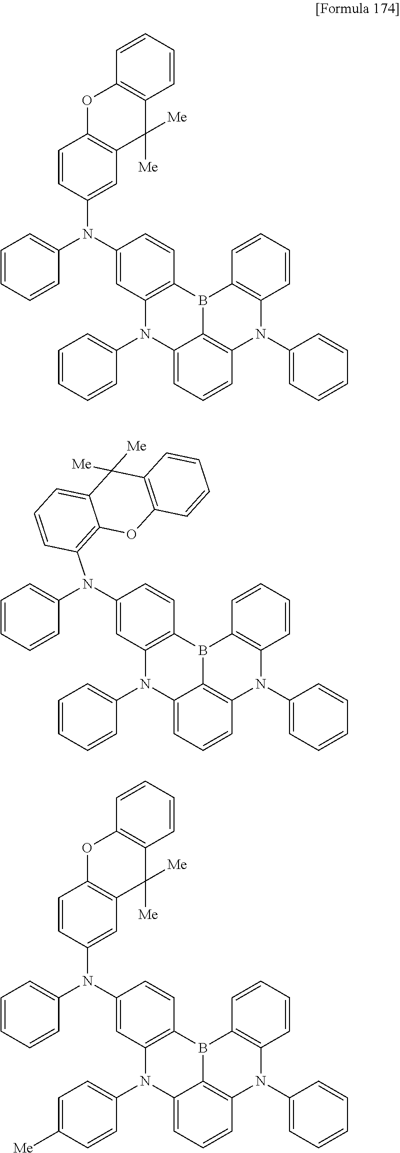 [SMILES: CC1(C)c2ccccc2Oc2ccc(N(c3ccccc3)c3ccc4c(c3)N(c3ccccc3)c3cccc5c3B4c3ccccc3N5c3ccccc3)cc21 ; CC1(C)c2ccccc2Oc2c(N(c3ccccc3)c3ccc4c(c3)N(c3ccccc3)c3cccc5c3B4c3ccccc3N5c3ccccc3)cccc21 ; Cc1ccc(N2c3cc(N(c4ccccc4)c4ccc5c(c4)C(C)(C)c4ccccc4O5)ccc3B3c4ccccc4N(c4ccccc4)c4cccc2c43)cc1]

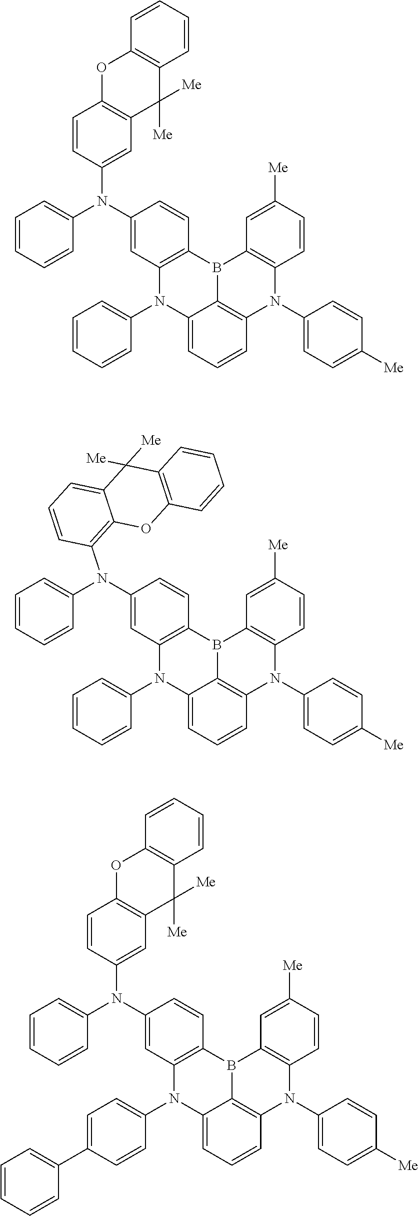 [SMILES: Cc1ccc(N2c3ccc(C)cc3B3c4ccc(N(c5ccccc5)c5ccc6c(c5)C(C)(C)c5ccccc5O6)cc4N(c4ccccc4)c4cccc2c43)cc1 ; Cc1ccc(N2c3ccc(C)cc3B3c4ccc(N(c5ccccc5)c5cccc6c5Oc5ccccc5C6(C)C)cc4N(c4ccccc4)c4cccc2c43)cc1 ; Cc1ccc(N2c3ccc(C)cc3B3c4ccc(N(c5ccccc5)c5ccc6c(c5)C(C)(C)c5ccccc5O6)cc4N(c4ccc(-c5ccccc5)cc4)c4cccc2c43)cc1]

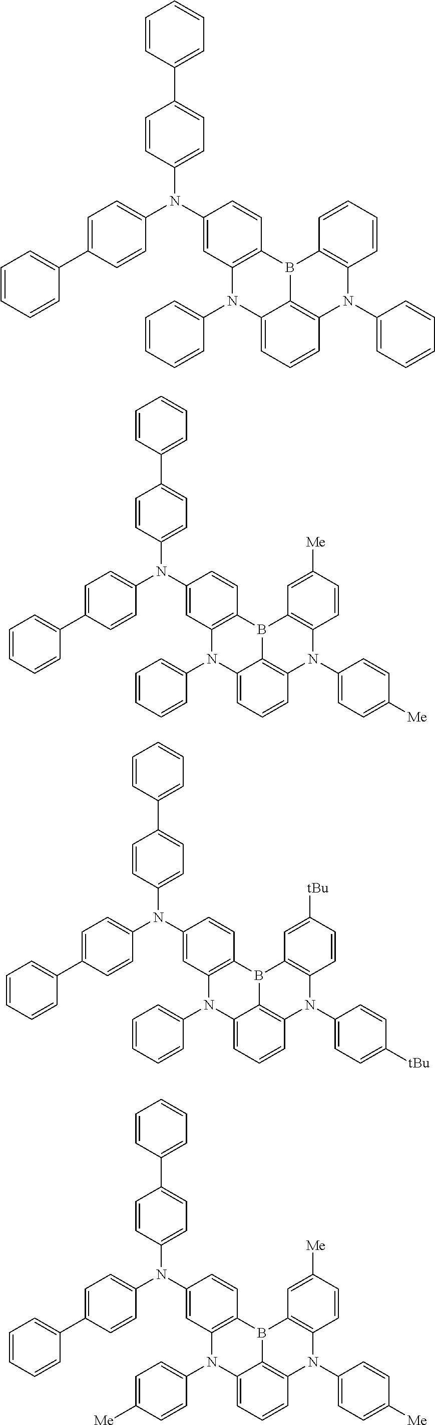

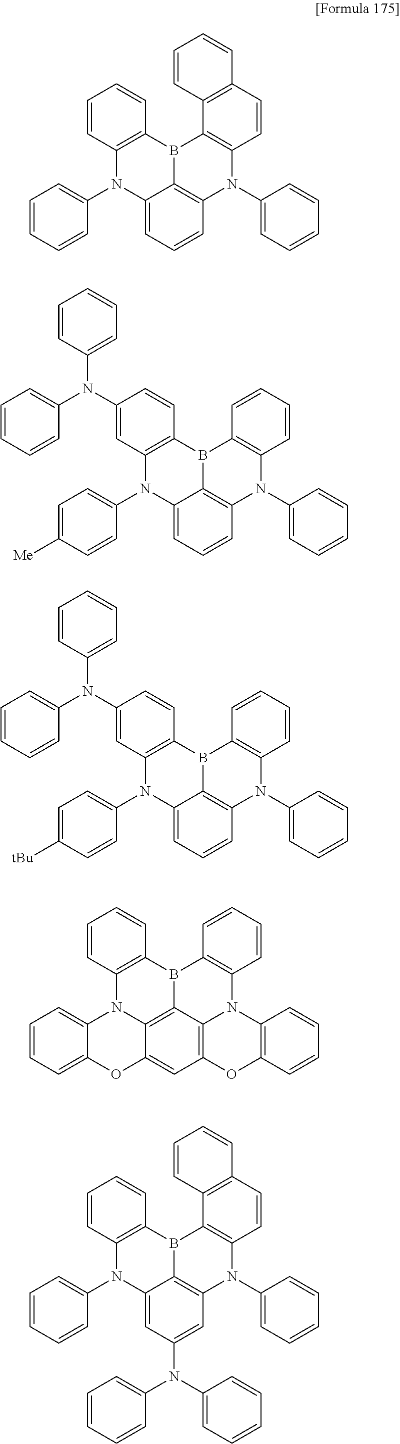

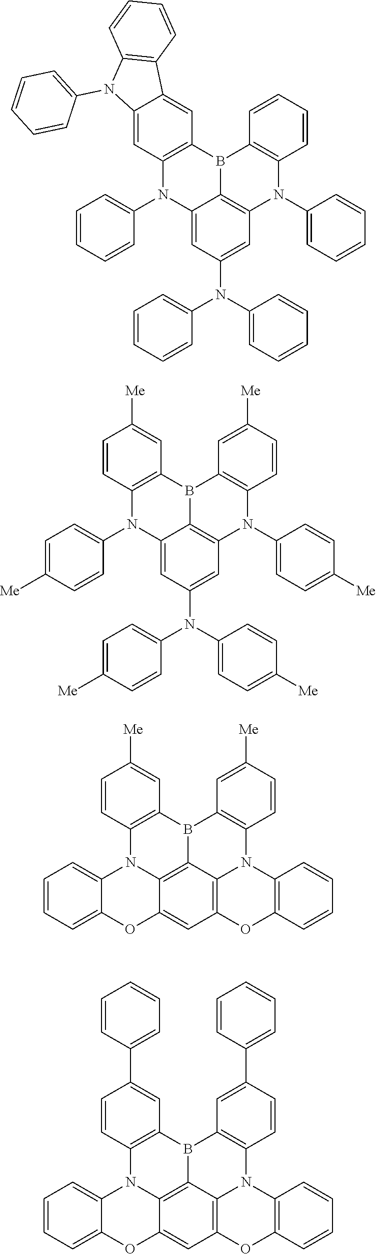

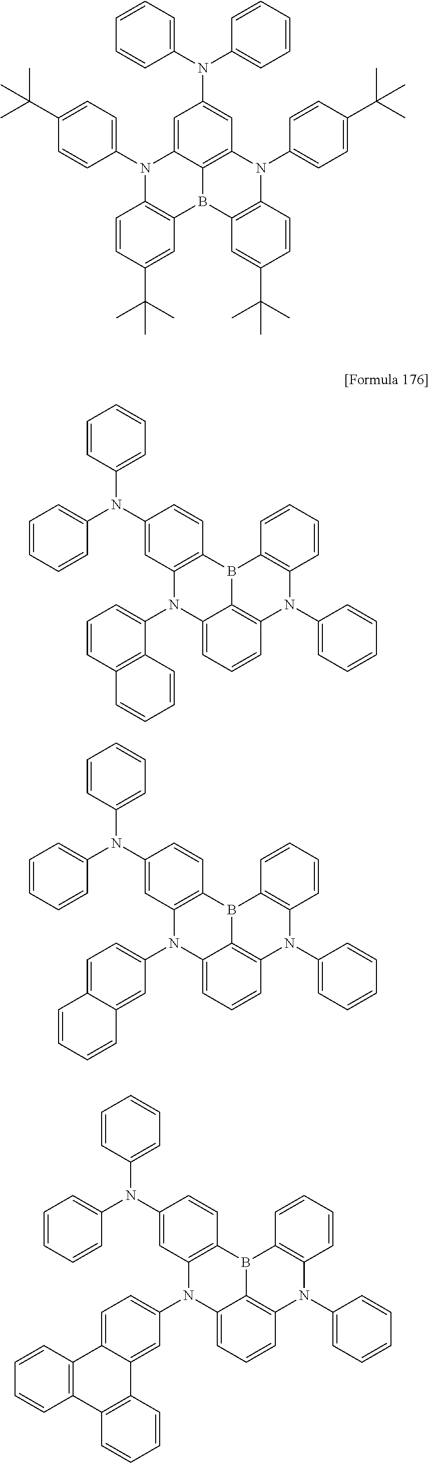

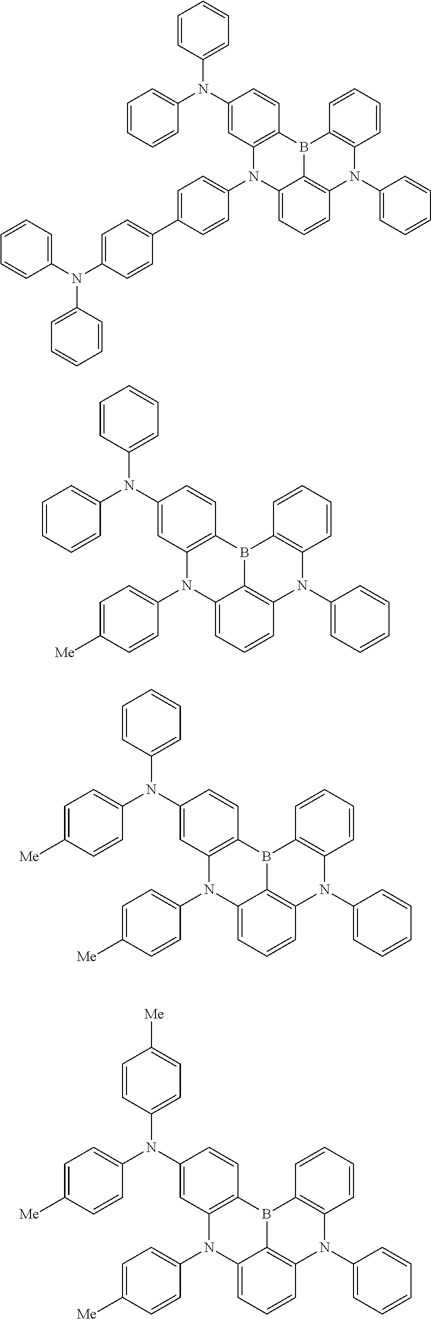

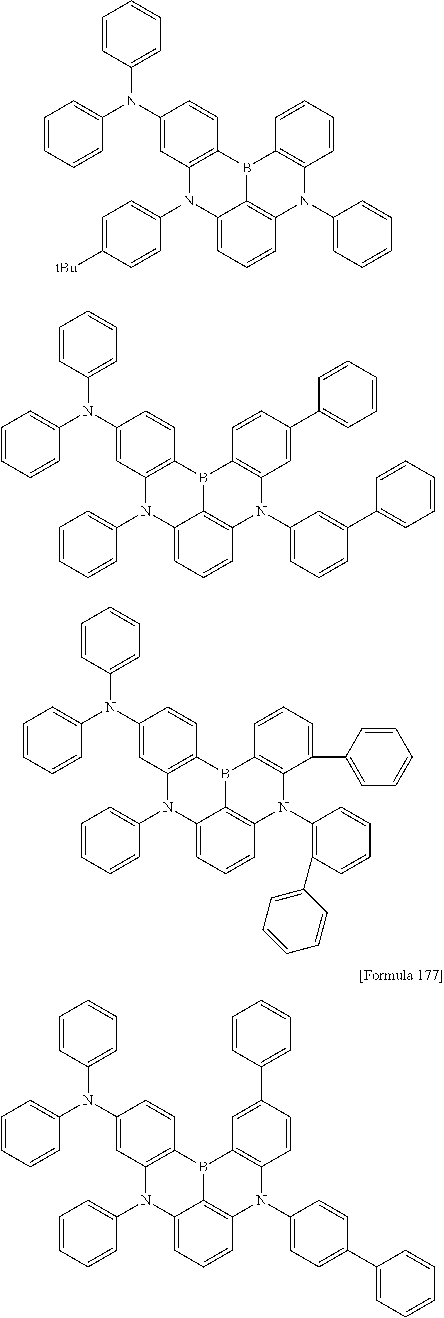

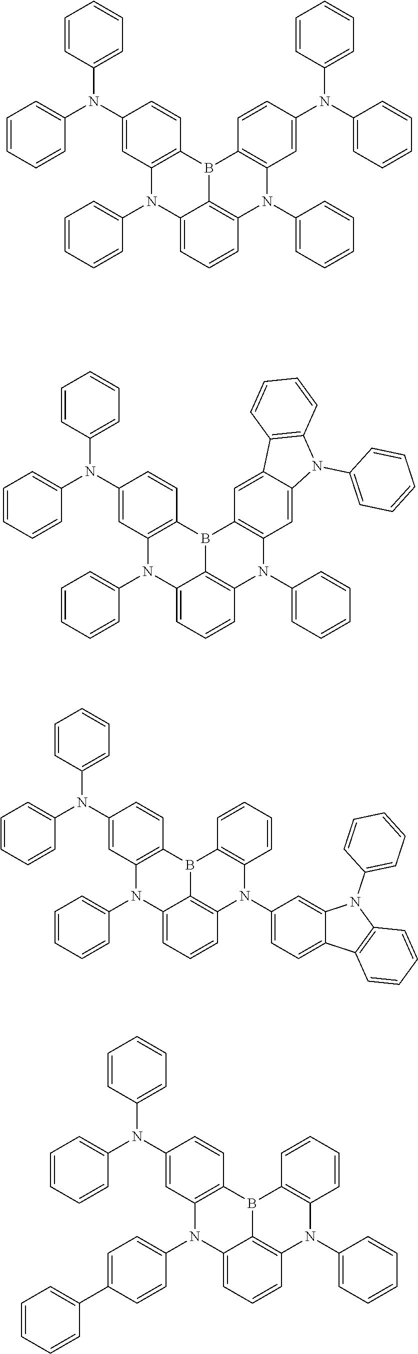 [SMILES: c1ccc(N(c2ccccc2)c2ccc3c(c2)N(c2ccccc2)c2cccc4c2B3c2ccc(N(c3ccccc3)c3ccccc3)cc2N4c2ccccc2)cc1 ; c1ccc(N(c2ccccc2)c2ccc3c(c2)N(c2ccccc2)c2cccc4c2B3c2cc3c5ccccc5n(-c5ccccc5)c3cc2N4c2ccccc2)cc1 ; c1ccc(N(c2ccccc2)c2ccc3c(c2)N(c2ccccc2)c2cccc4c2B3c2ccccc2N4c2ccc3c4ccccc4n(-c4ccccc4)c3c2)cc1 ; c1ccc(-c2ccc(N3c4cc(N(c5ccccc5)c5ccccc5)ccc4B4c5ccccc5N(c5ccccc5)c5cccc3c54)cc2)cc1]

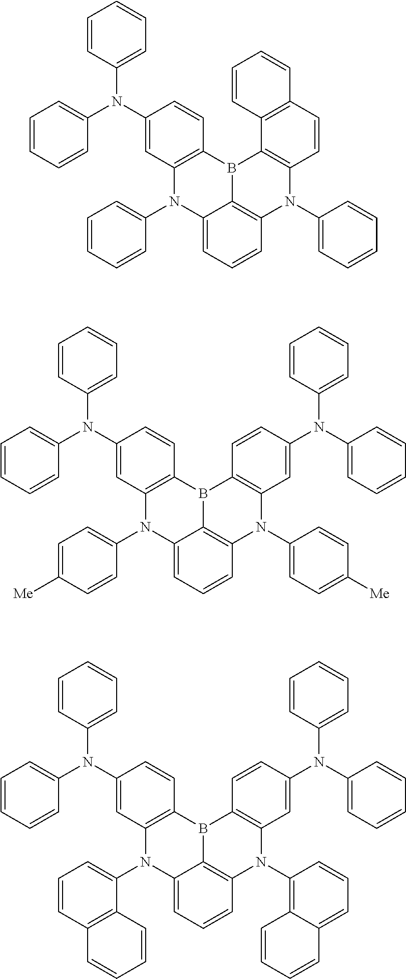 [SMILES: c1ccc(N(c2ccccc2)c2ccc3c(c2)N(c2ccccc2)c2cccc4c2B3c2c(ccc3ccccc23)N4c2ccccc2)cc1 ; Cc1ccc(N2c3cc(N(c4ccccc4)c4ccccc4)ccc3B3c4ccc(N(c5ccccc5)c5ccccc5)cc4N(c4ccc(C)cc4)c4cccc2c43)cc1 ; c1ccc(N(c2ccccc2)c2ccc3c(c2)N(c2cccc4ccccc24)c2cccc4c2B3c2ccc(N(c3ccccc3)c3ccccc3)cc2N4c2cccc3ccccc23)cc1]

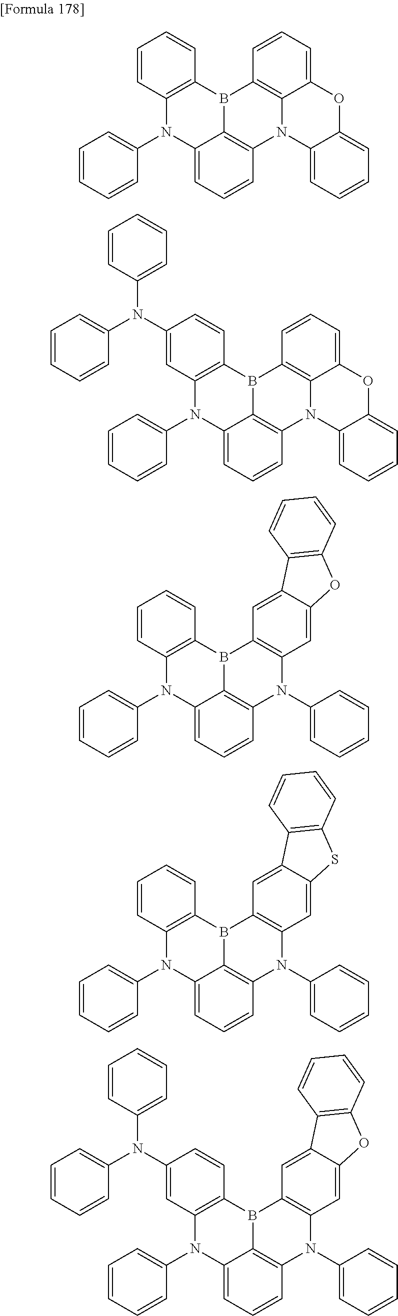

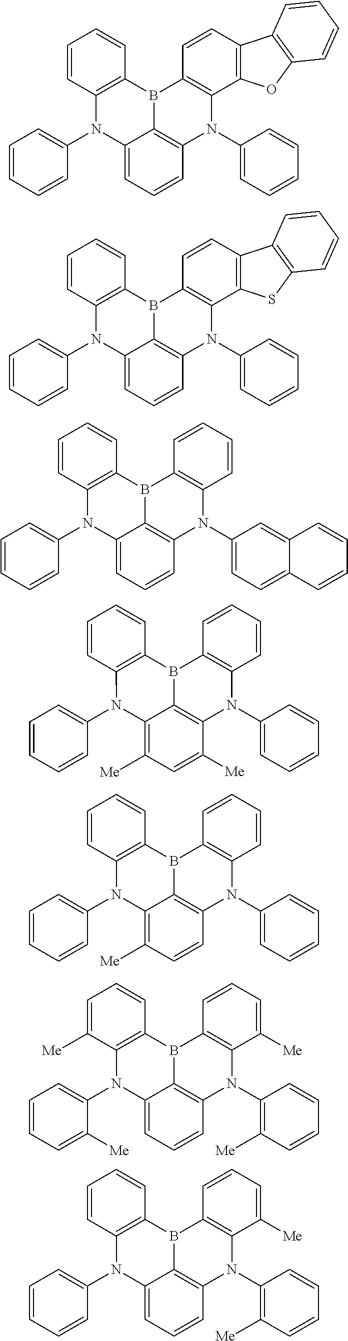

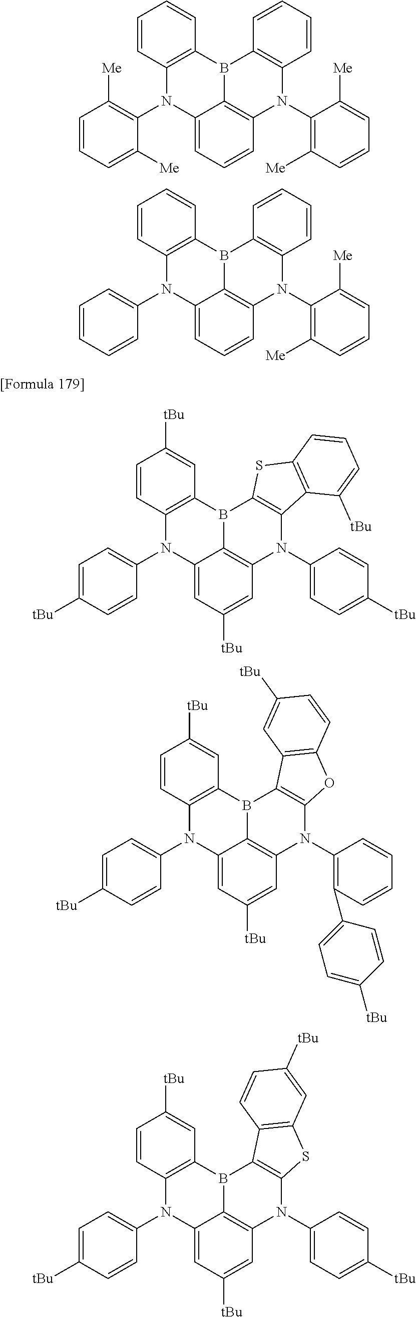

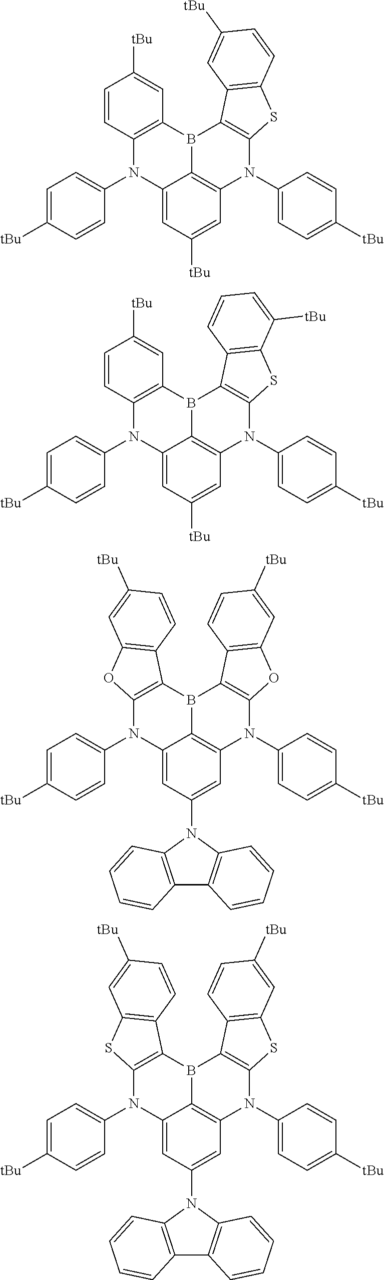

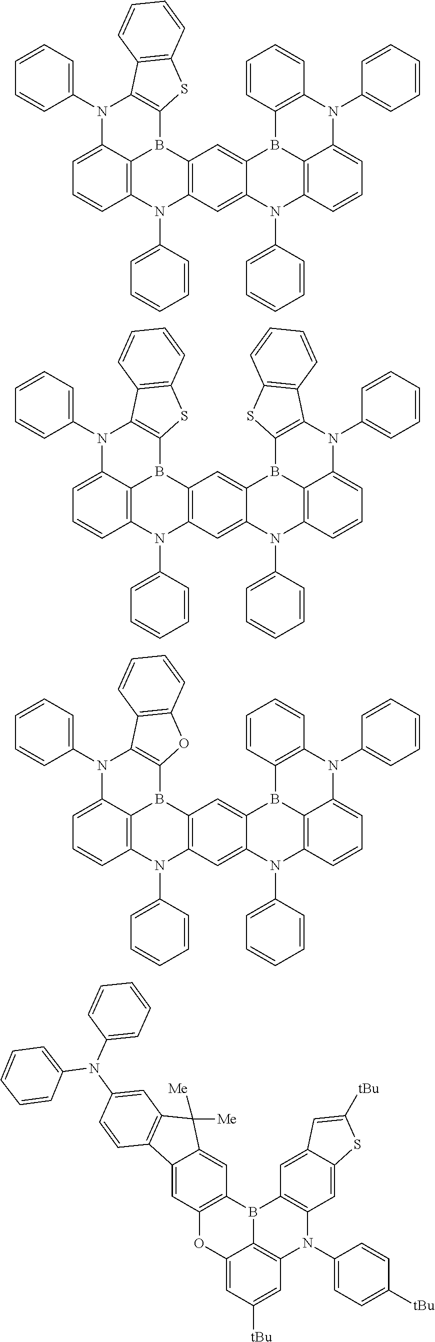

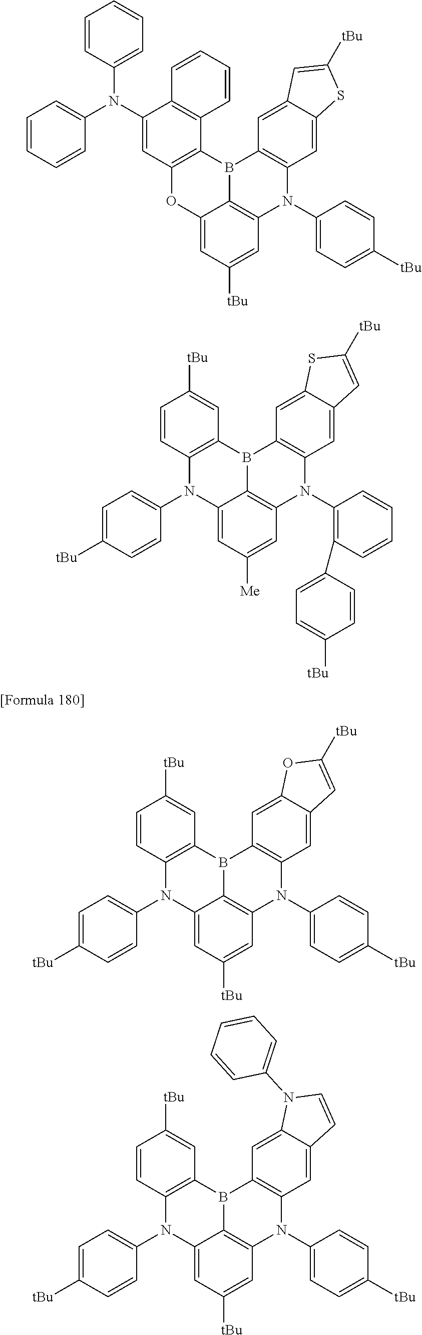

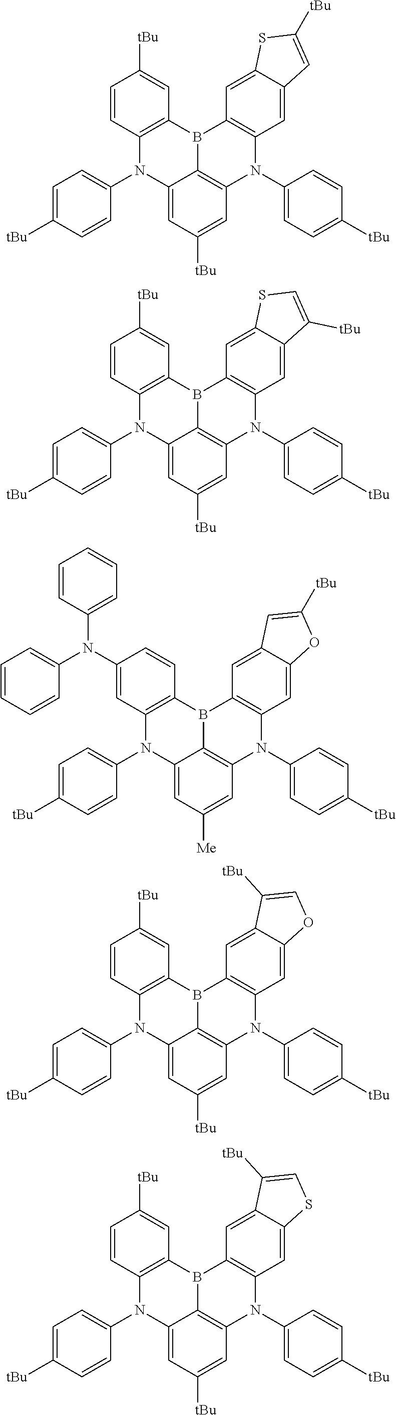

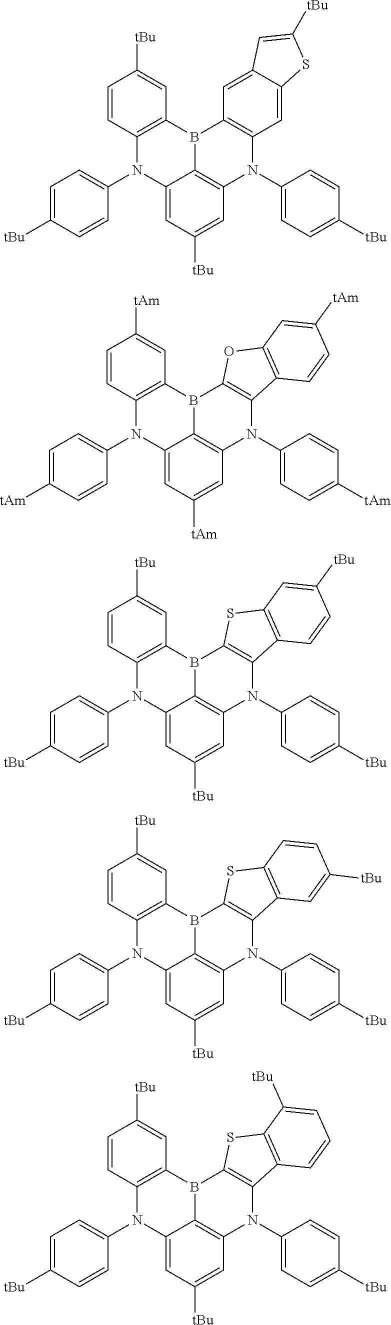

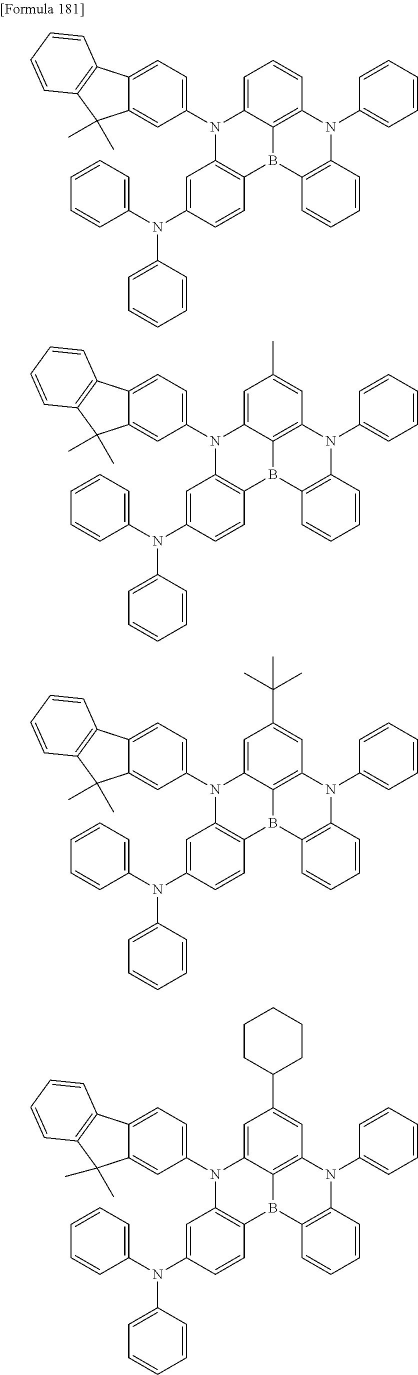 [SMILES: CC1(C)c2ccccc2-c2ccc(N3c4cc(N(c5ccccc5)c5ccccc5)ccc4B4c5ccccc5N(c5ccccc5)c5cccc3c54)cc21 ; Cc1cc2c3c(c1)N(c1ccc4c(c1)C(C)(C)c1ccccc1-4)c1cc(N(c4ccccc4)c4ccccc4)ccc1B3c1ccccc1N2c1ccccc1 ; CC(C)(C)c1cc2c3c(c1)N(c1ccc4c(c1)C(C)(C)c1ccccc1-4)c1cc(N(c4ccccc4)c4ccccc4)ccc1B3c1ccccc1N2c1ccccc1 ; CC1(C)c2ccccc2-c2ccc(N3c4cc(N(c5ccccc5)c5ccccc5)ccc4B4c5ccccc5N(c5ccccc5)c5cc(C6CCCCC6)cc3c54)cc21]

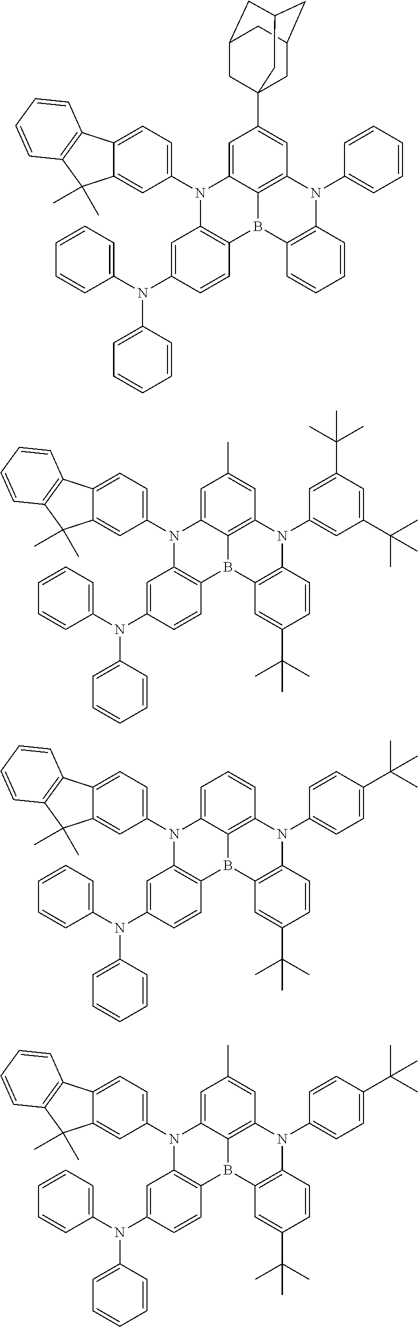 [SMILES: CC1(C)c2ccccc2-c2ccc(N3c4cc(N(c5ccccc5)c5ccccc5)ccc4B4c5ccccc5N(c5ccccc5)c5cc(C67CC8CC(CC(C8)C6)C7)cc3c54)cc21 ; Cc1cc2c3c(c1)N(c1ccc4c(c1)C(C)(C)c1ccccc1-4)c1cc(N(c4ccccc4)c4ccccc4)ccc1B3c1cc(C(C)(C)C)ccc1N2c1cc(C(C)(C)C)cc(C(C)(C)C)c1 ; CC(C)(C)c1ccc(N2c3ccc(C(C)(C)C)cc3B3c4ccc(N(c5ccccc5)c5ccccc5)cc4N(c4ccc5c(c4)C(C)(C)c4ccccc4-5)c4cccc2c43)cc1 ; Cc1cc2c3c(c1)N(c1ccc4c(c1)C(C)(C)c1ccccc1-4)c1cc(N(c4ccccc4)c4ccccc4)ccc1B3c1cc(C(C)(C)C)ccc1N2c1ccc(C(C)(C)C)cc1]

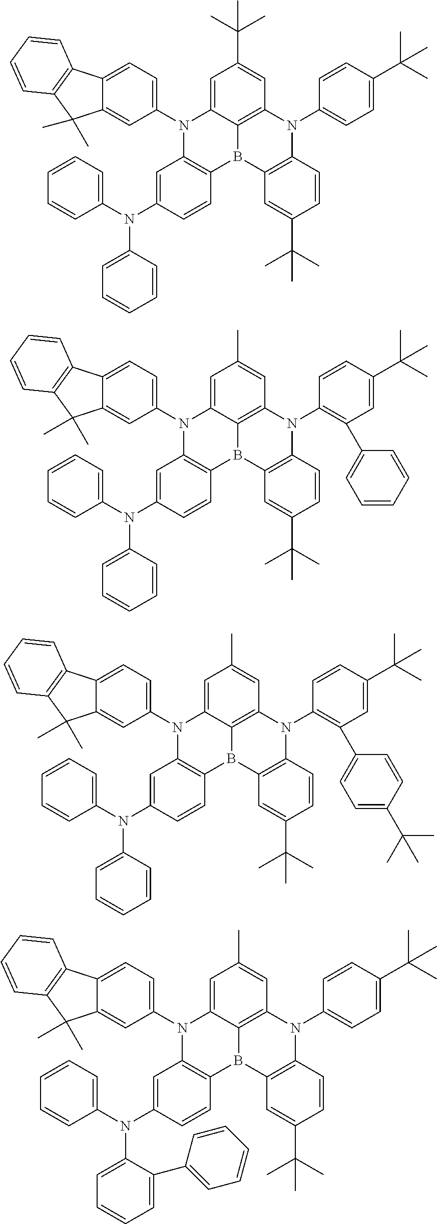

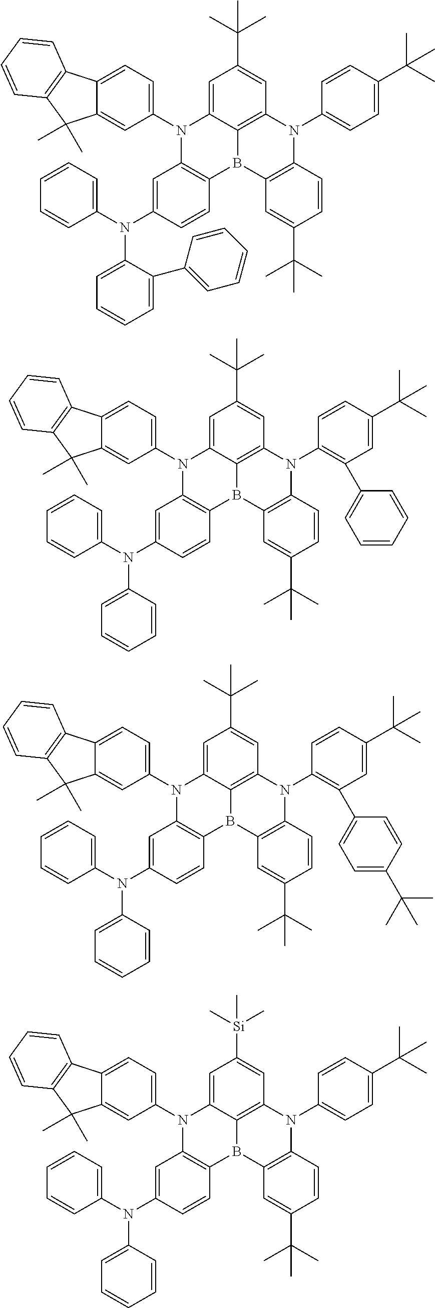

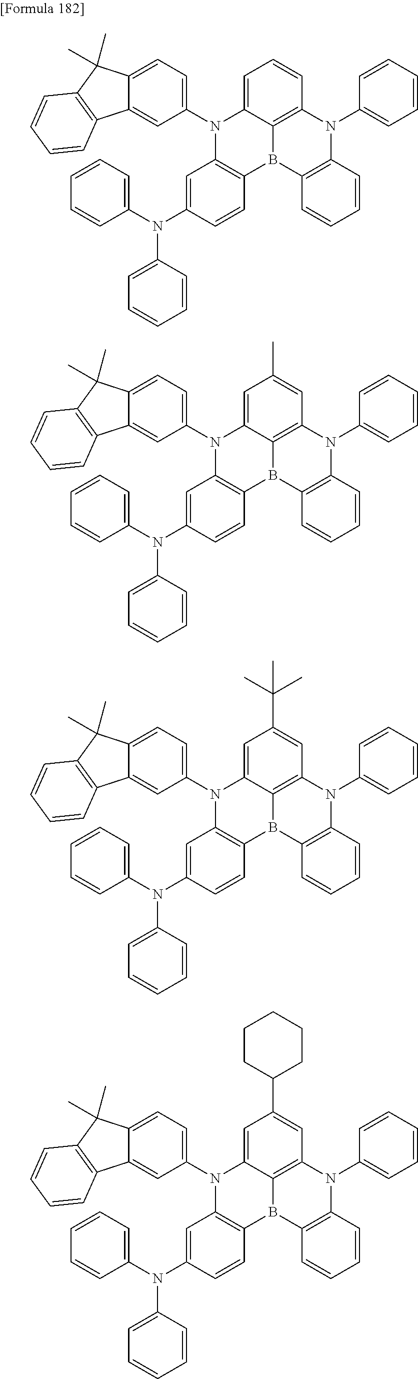

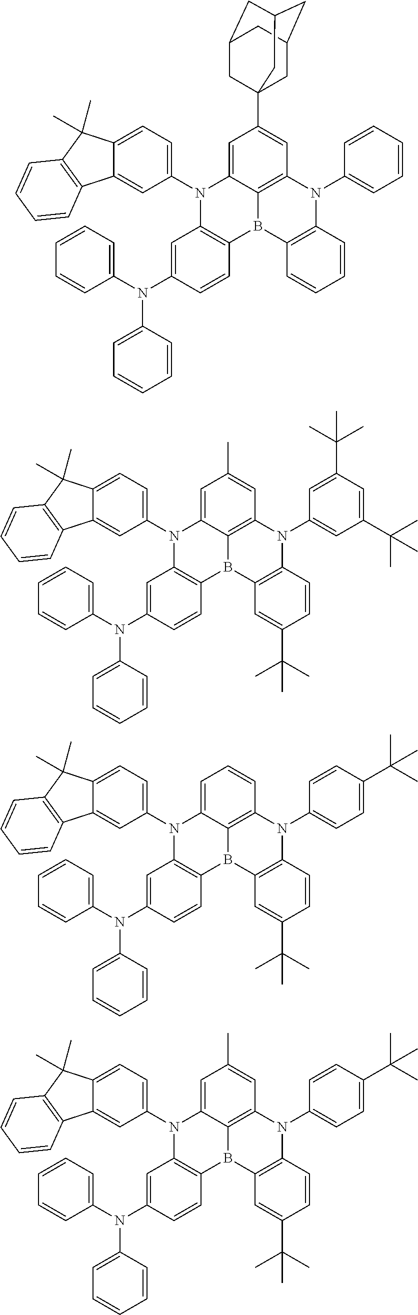

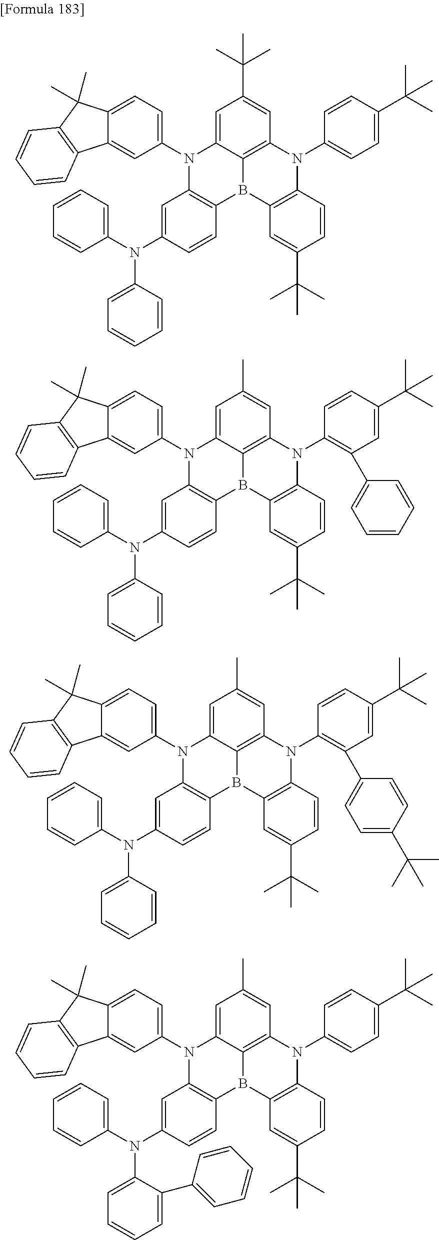

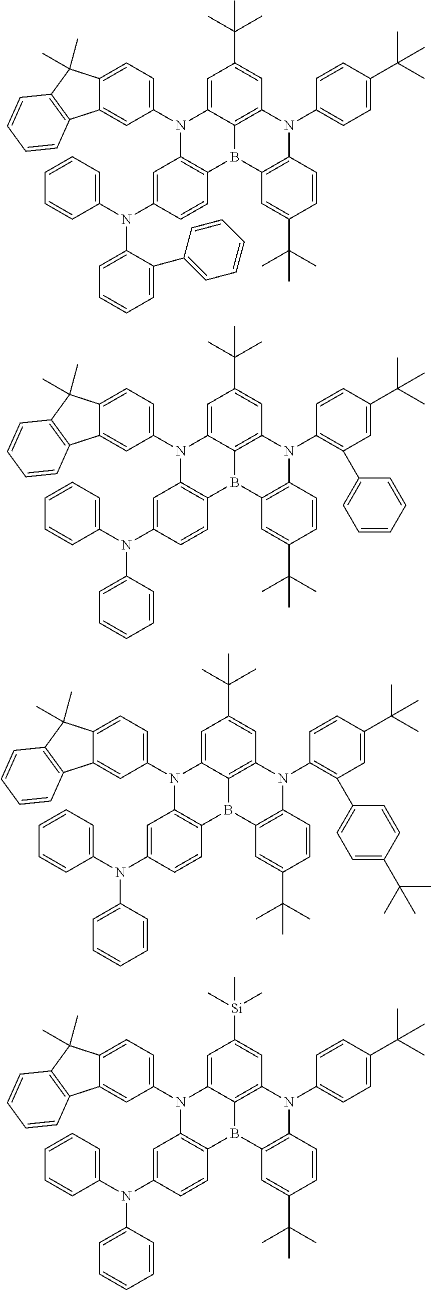

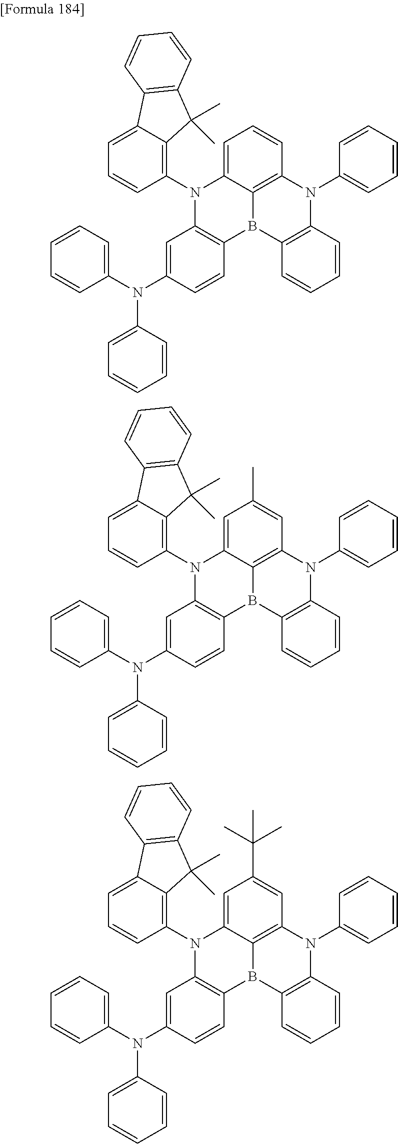

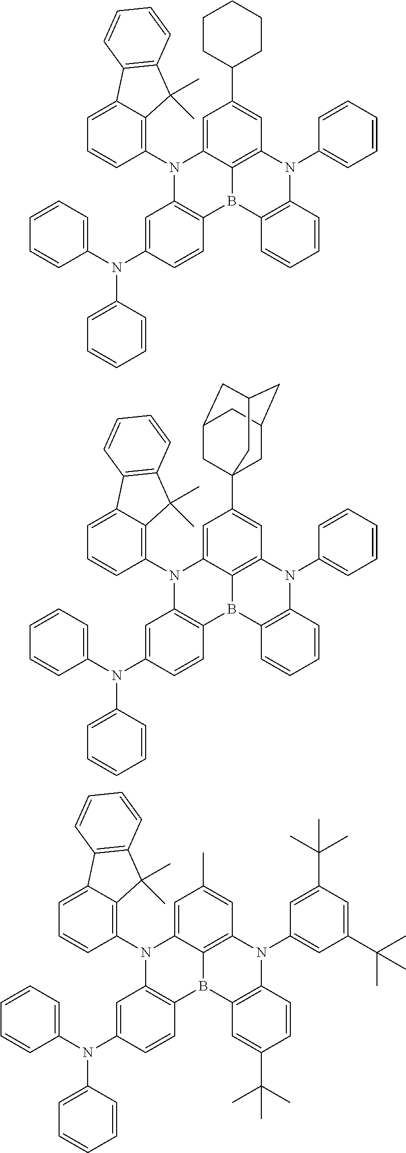

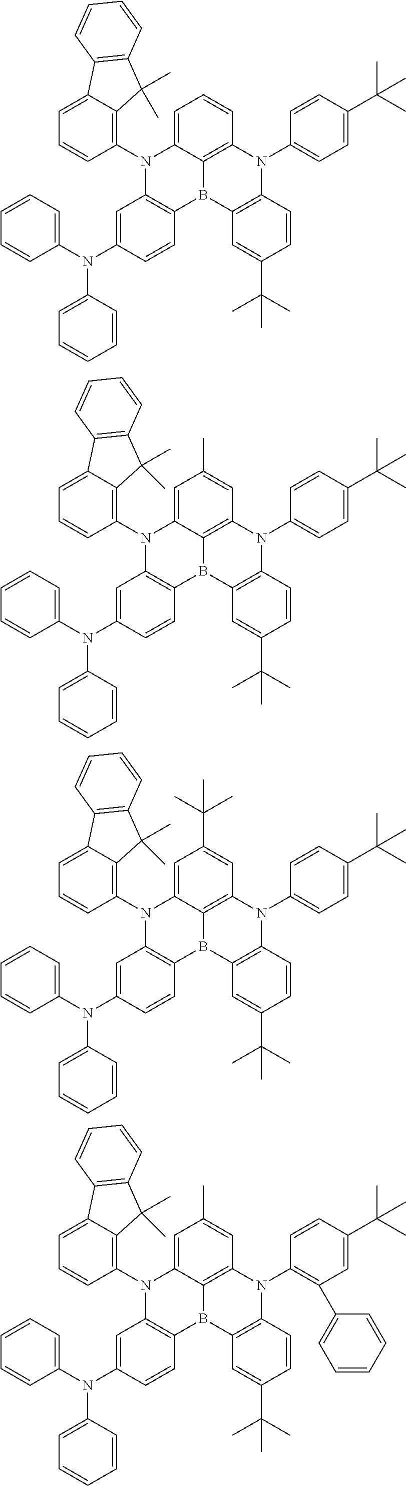

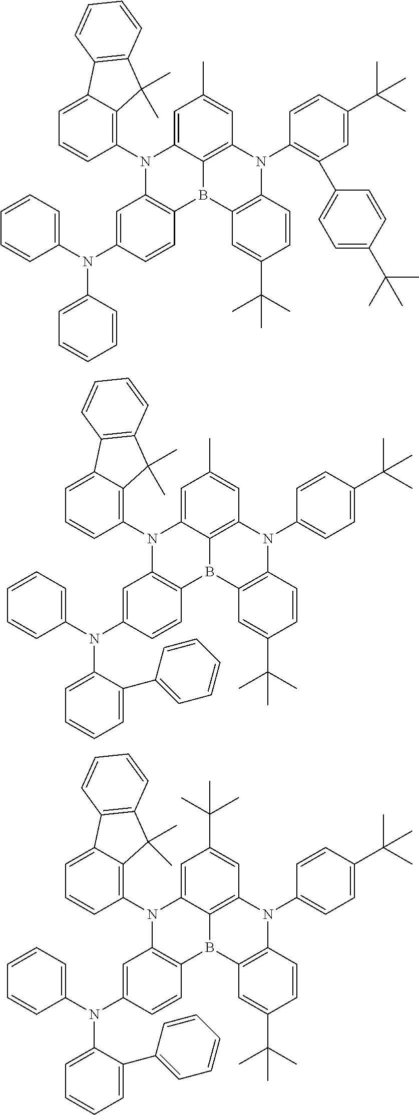

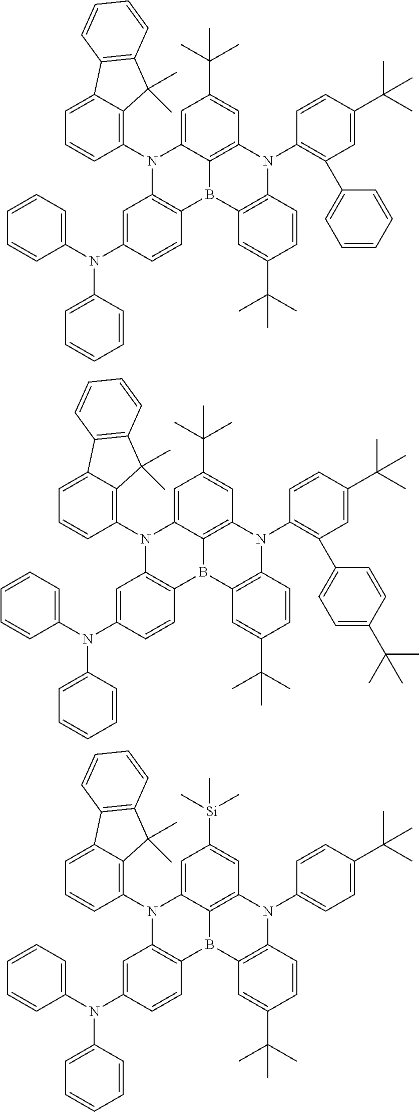

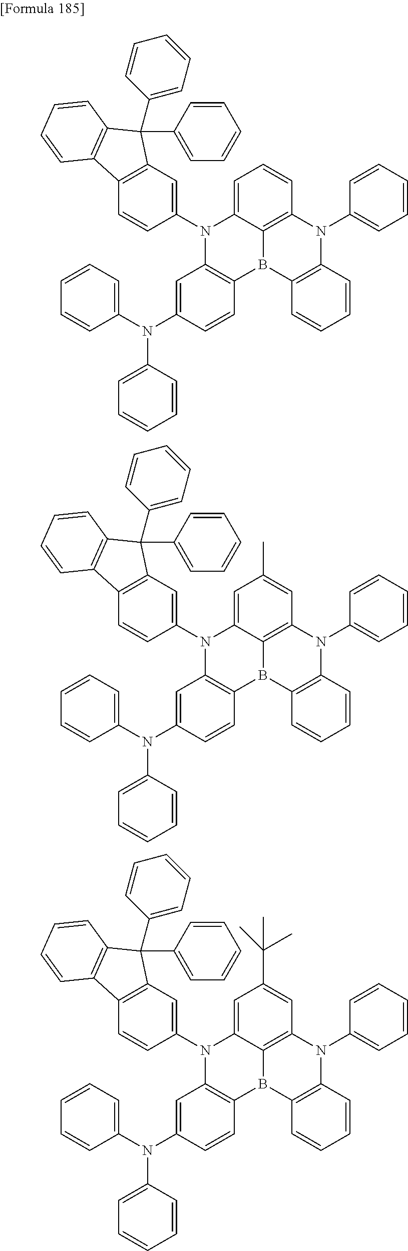

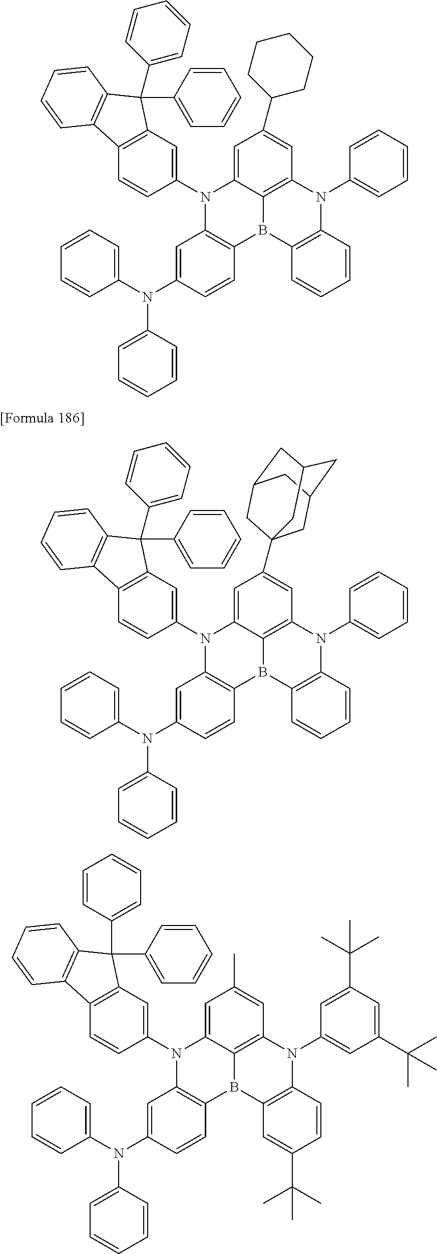

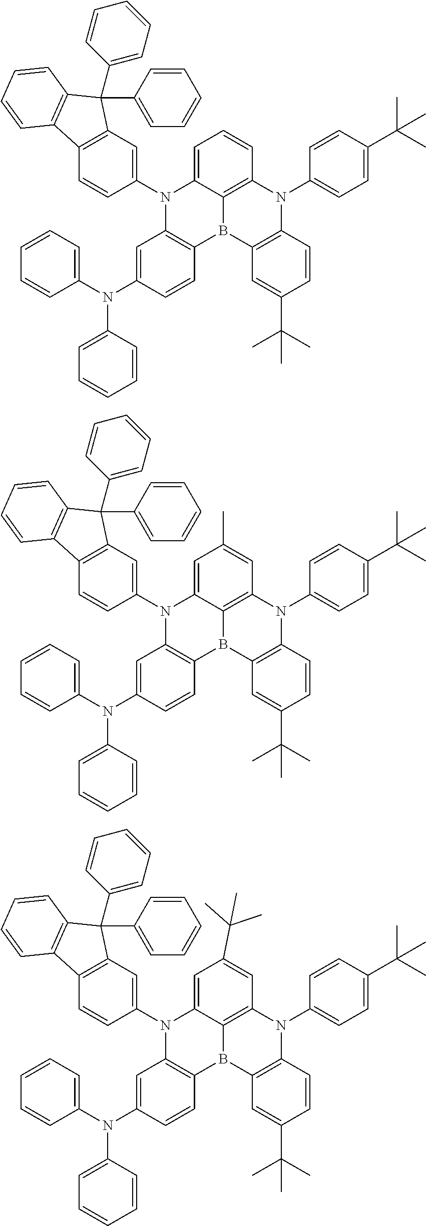

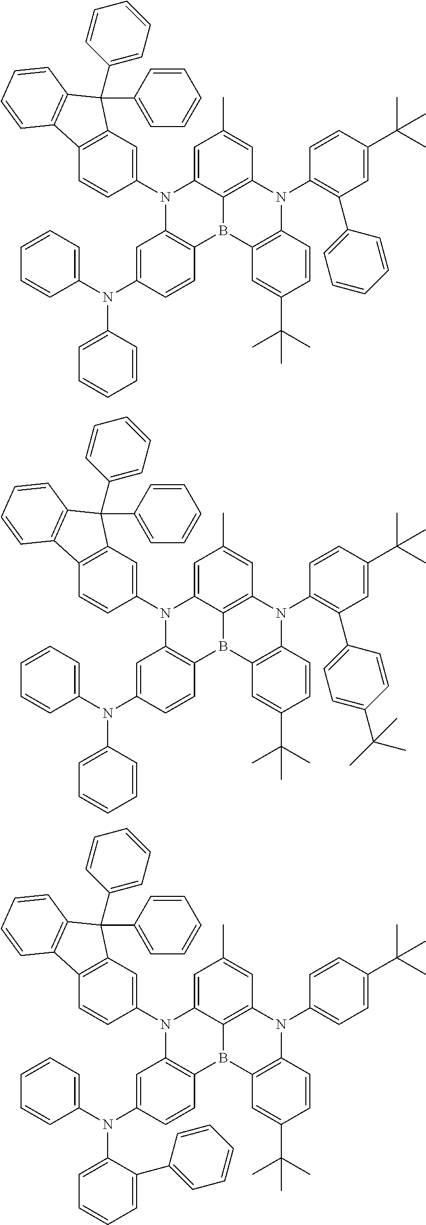

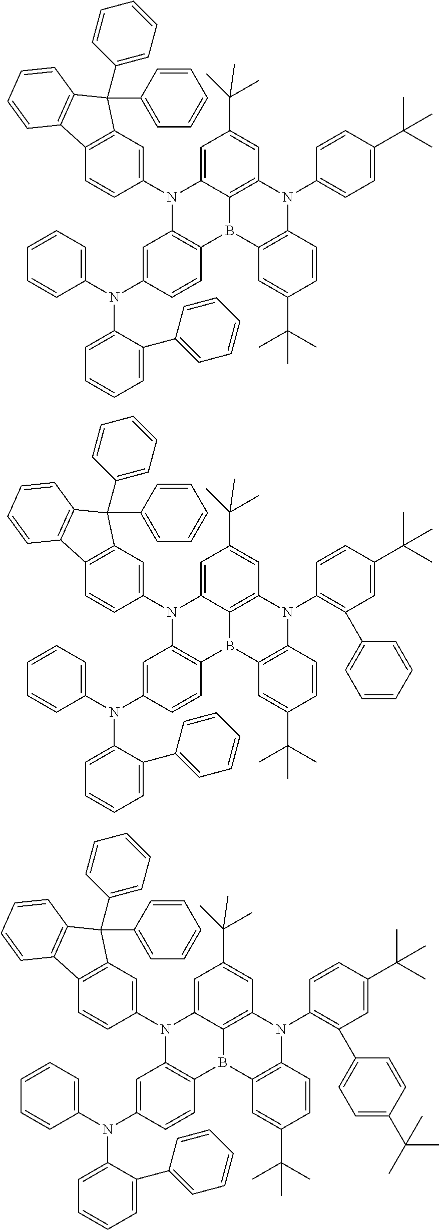

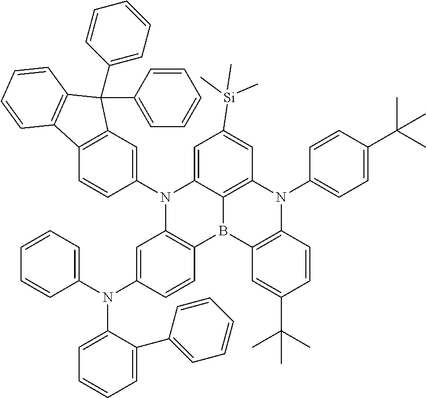 [SMILES: CC(C)(C)c1ccc(N2c3ccc(C(C)(C)C)cc3B3c4ccc(N(c5ccccc5)c5ccccc5-c5ccccc5)cc4N(c4ccc5c(c4)C(c4ccccc4)(c4ccccc4)c4ccccc4-5)c4cc([Si](C)(C)C)cc2c43)cc1]

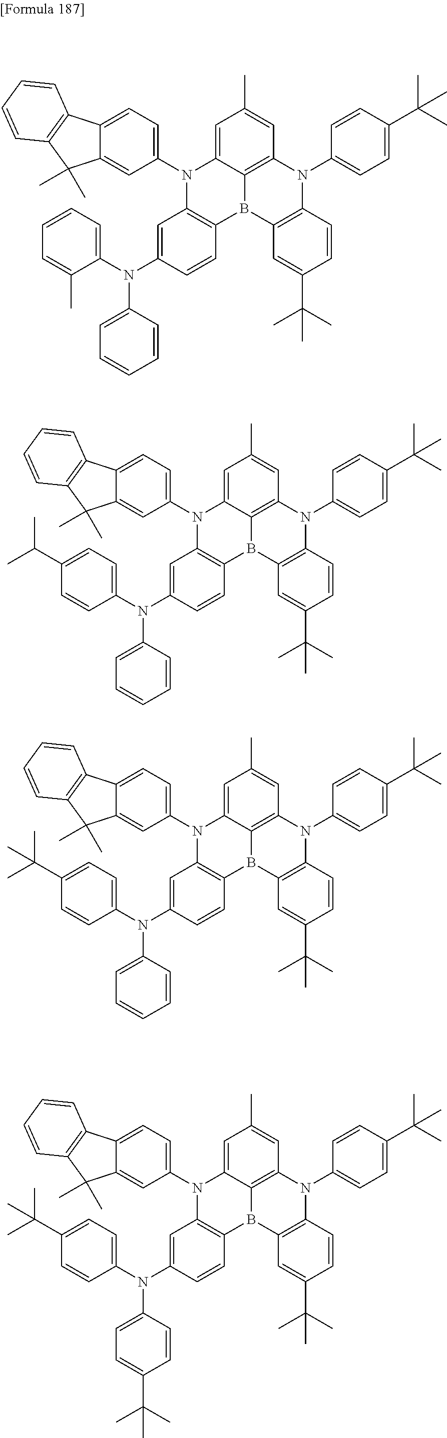

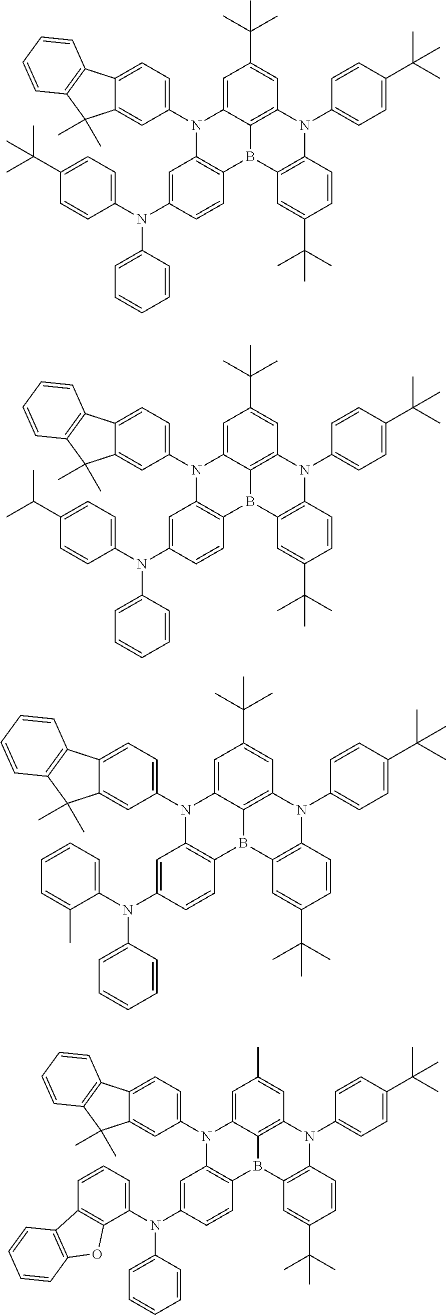

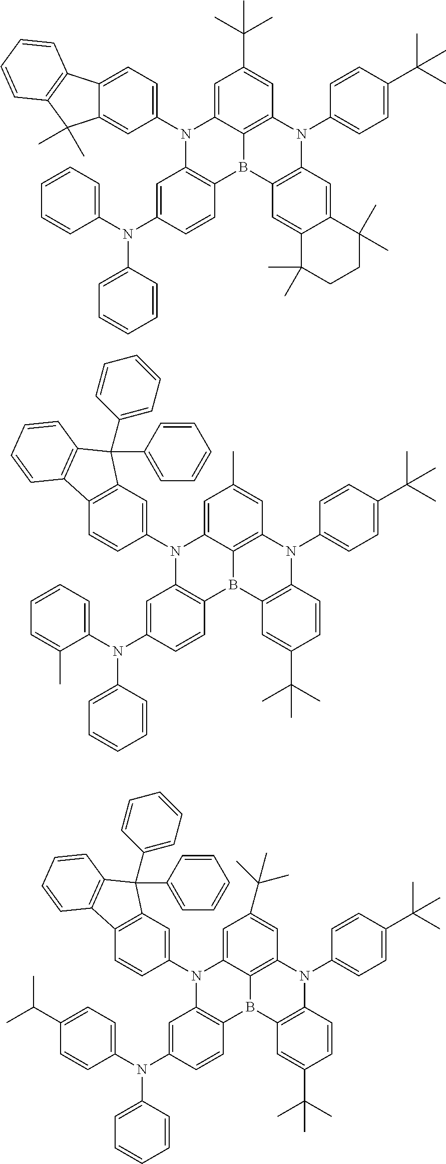

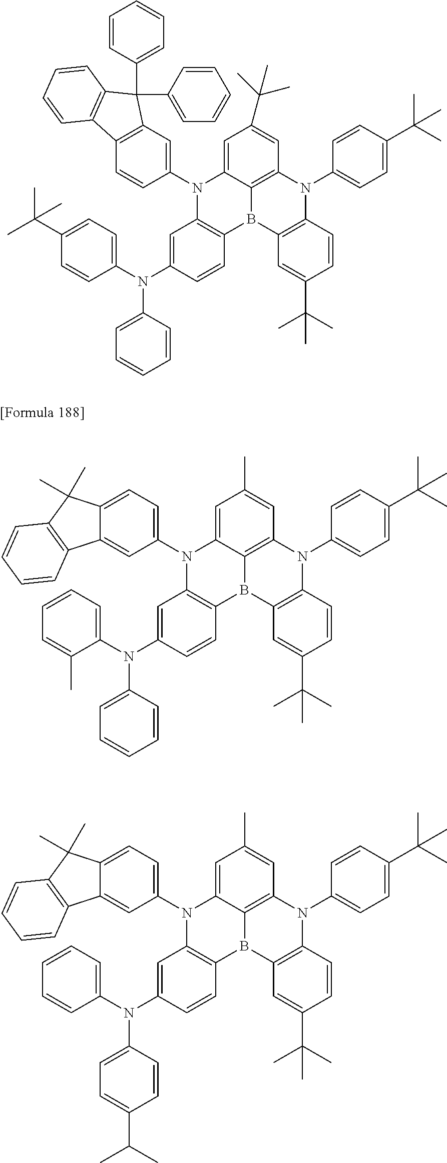 [SMILES: CC(C)(C)c1ccc(N(c2ccccc2)c2ccc3c(c2)N(c2ccc4c(c2)C(c2ccccc2)(c2ccccc2)c2ccccc2-4)c2cc(C(C)(C)C)cc4c2B3c2cc(C(C)(C)C)ccc2N4c2ccc(C(C)(C)C)cc2)cc1 ; Cc1cc2c3c(c1)N(c1ccc4c(c1)-c1ccccc1C4(C)C)c1cc(N(c4ccccc4)c4ccccc4C)ccc1B3c1cc(C(C)(C)C)ccc1N2c1ccc(C(C)(C)C)cc1 ; Cc1cc2c3c(c1)N(c1ccc4c(c1)-c1ccccc1C4(C)C)c1cc(N(c4ccccc4)c4ccc(C(C)C)cc4)ccc1B3c1cc(C(C)(C)C)ccc1N2c1ccc(C(C)(C)C)cc1]

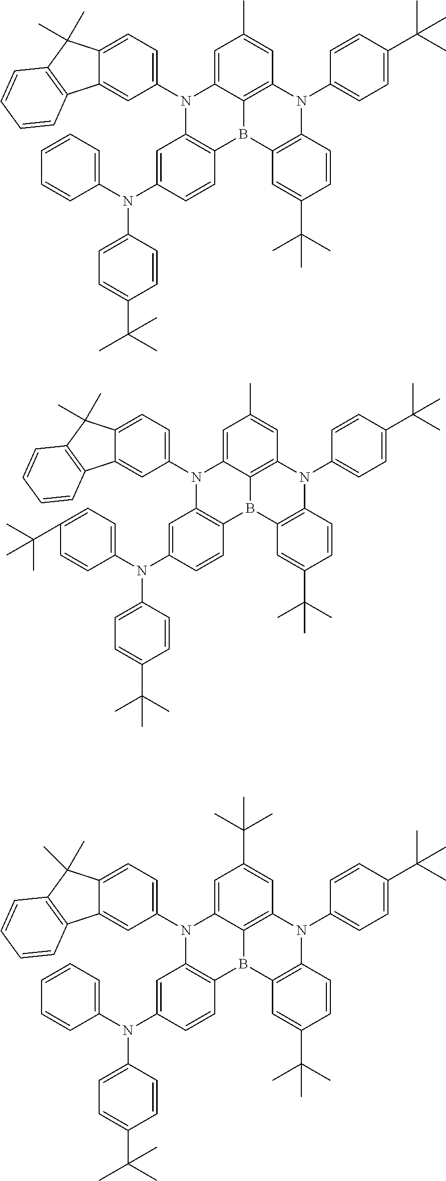

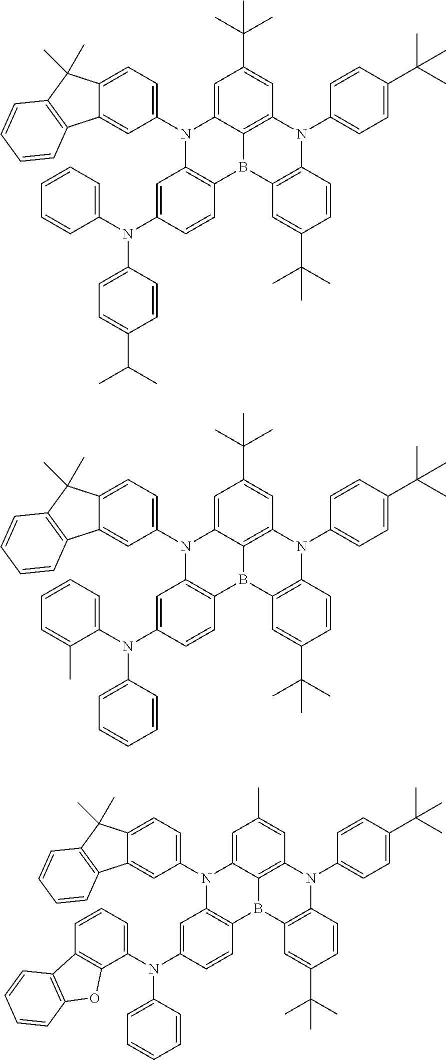 [SMILES: CC(C)c1ccc(N(c2ccccc2)c2ccc3c(c2)N(c2ccc4c(c2)-c2ccccc2C4(C)C)c2cc(C(C)(C)C)cc4c2B3c2cc(C(C)(C)C)ccc2N4c2ccc(C(C)(C)C)cc2)cc1 ; Cc1ccccc1N(c1ccccc1)c1ccc2c(c1)N(c1ccc3c(c1)-c1ccccc1C3(C)C)c1cc(C(C)(C)C)cc3c1B2c1cc(C(C)(C)C)ccc1N3c1ccc(C(C)(C)C)cc1 ; Cc1cc2c3c(c1)N(c1ccc4c(c1)-c1ccccc1C4(C)C)c1cc(N(c4ccccc4)c4cccc5c4oc4ccccc45)ccc1B3c1cc(C(C)(C)C)ccc1N2c1ccc(C(C)(C)C)cc1]

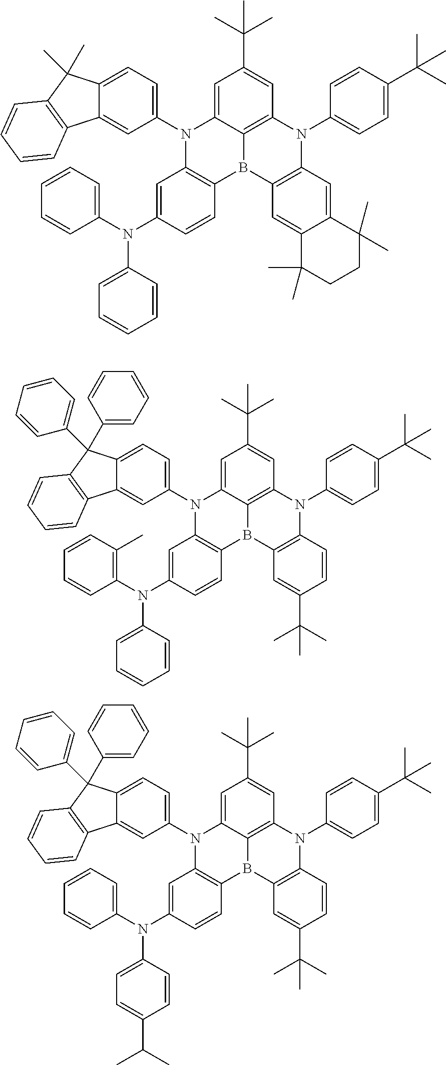

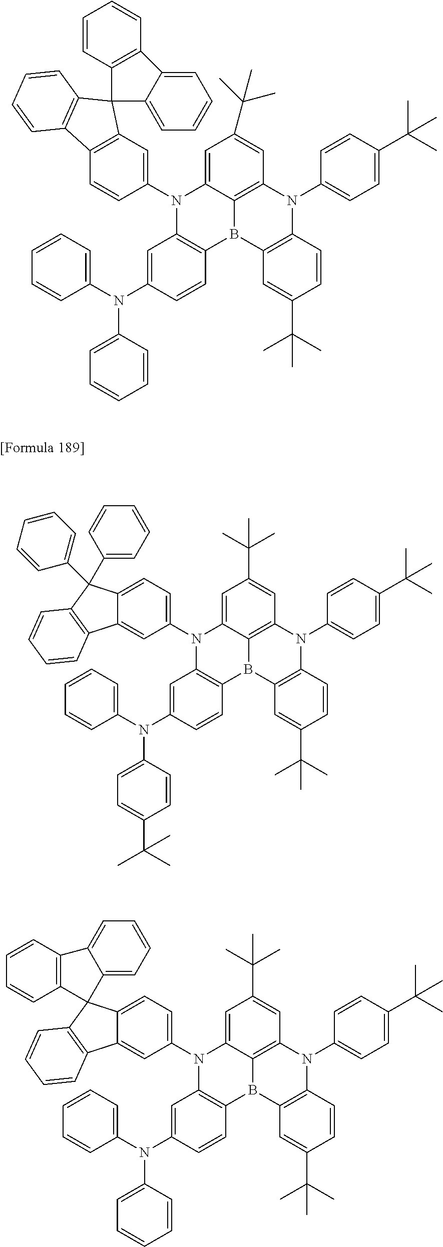 [SMILES: CC(C)(C)c1ccc(N2c3ccc(C(C)(C)C)cc3B3c4ccc(N(c5ccccc5)c5ccccc5)cc4N(c4ccc5c(c4)C4(c6ccccc6-c6ccccc64)c4ccccc4-5)c4cc(C(C)(C)C)cc2c43)cc1 ; CC(C)(C)c1ccc(N(c2ccccc2)c2ccc3c(c2)N(c2ccc4c(c2)-c2ccccc2C4(c2ccccc2)c2ccccc2)c2cc(C(C)(C)C)cc4c2B3c2cc(C(C)(C)C)ccc2N4c2ccc(C(C)(C)C)cc2)cc1 ; CC(C)(C)c1ccc(N2c3ccc(C(C)(C)C)cc3B3c4ccc(N(c5ccccc5)c5ccccc5)cc4N(c4ccc5c(c4)-c4ccccc4C54c5ccccc5-c5ccccc54)c4cc(C(C)(C)C)cc2c43)cc1]

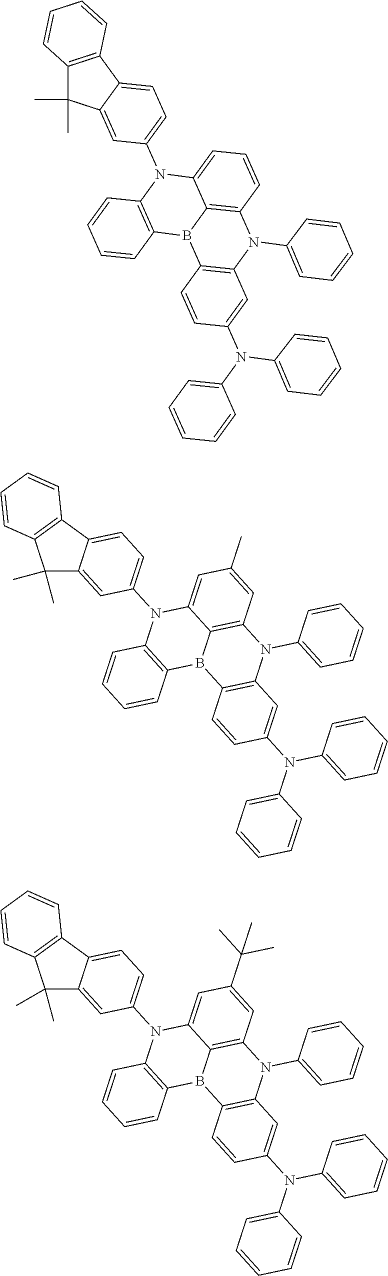 [SMILES: CC1(C)c2ccccc2-c2ccc(N3c4ccccc4B4c5ccc(N(c6ccccc6)c6ccccc6)cc5N(c5ccccc5)c5cccc3c54)cc21 ; Cc1cc2c3c(c1)N(c1ccccc1)c1cc(N(c4ccccc4)c4ccccc4)ccc1B3c1ccccc1N2c1ccc2c(c1)C(C)(C)c1ccccc1-2 ; CC(C)(C)c1cc2c3c(c1)N(c1ccccc1)c1cc(N(c4ccccc4)c4ccccc4)ccc1B3c1ccccc1N2c1ccc2c(c1)C(C)(C)c1ccccc1-2]

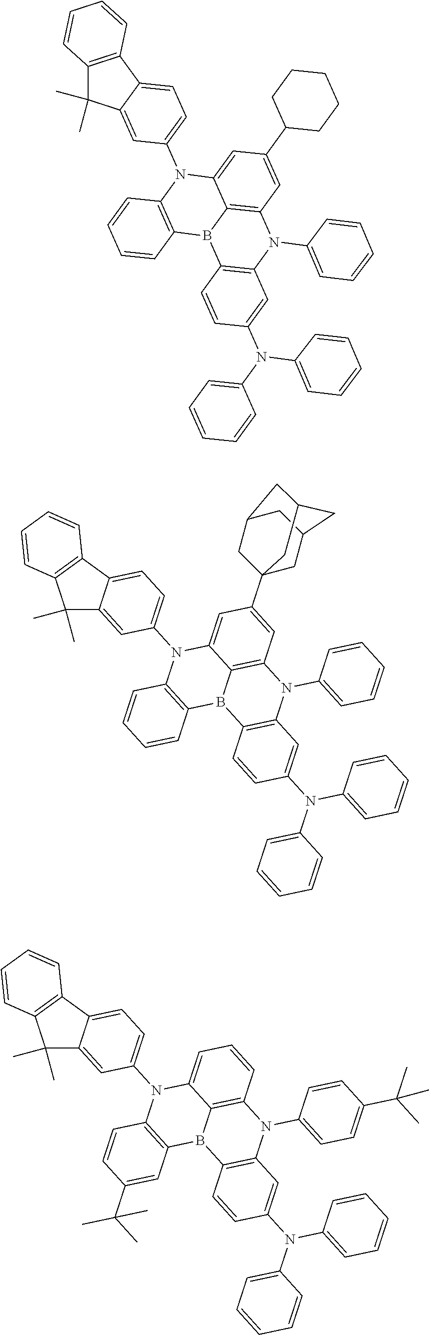 [SMILES: CC1(C)c2ccccc2-c2ccc(N3c4ccccc4B4c5ccc(N(c6ccccc6)c6ccccc6)cc5N(c5ccccc5)c5cc(C6CCCCC6)cc3c54)cc21 ; CC1(C)c2ccccc2-c2ccc(N3c4ccccc4B4c5ccc(N(c6ccccc6)c6ccccc6)cc5N(c5ccccc5)c5cc(C67CC8CC(CC(C8)C6)C7)cc3c54)cc21 ; CC(C)(C)c1ccc(N2c3cc(N(c4ccccc4)c4ccccc4)ccc3B3c4cc(C(C)(C)C)ccc4N(c4ccc5c(c4)C(C)(C)c4ccccc4-5)c4cccc2c43)cc1]

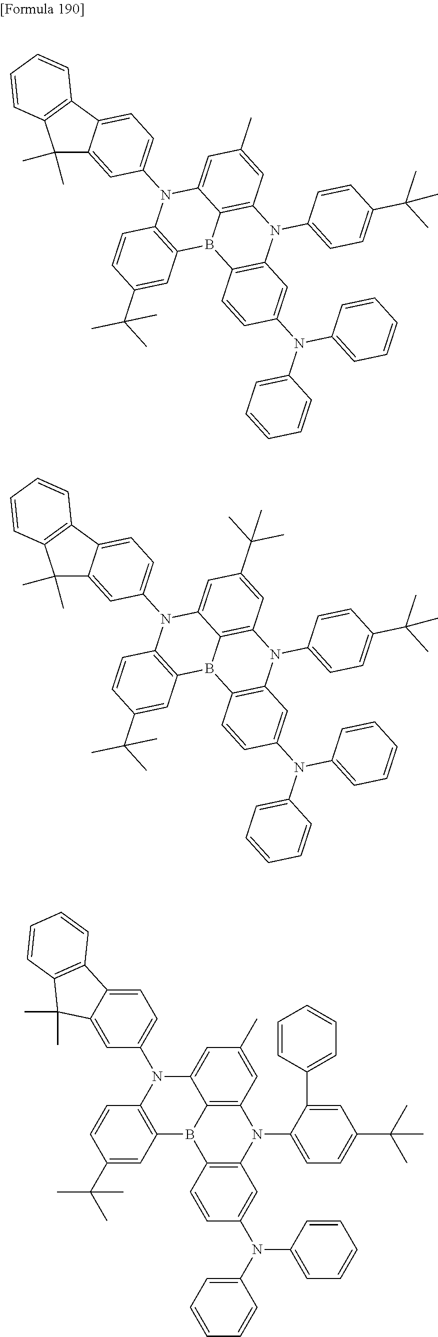

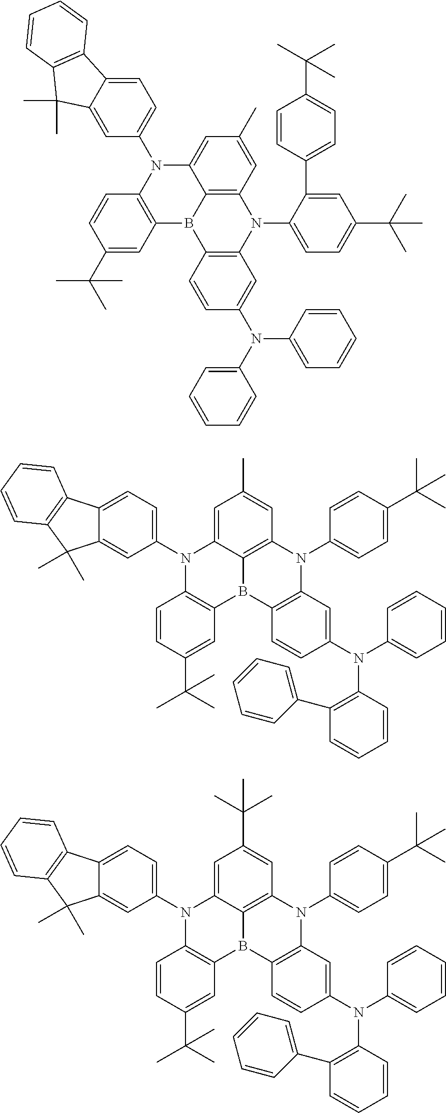

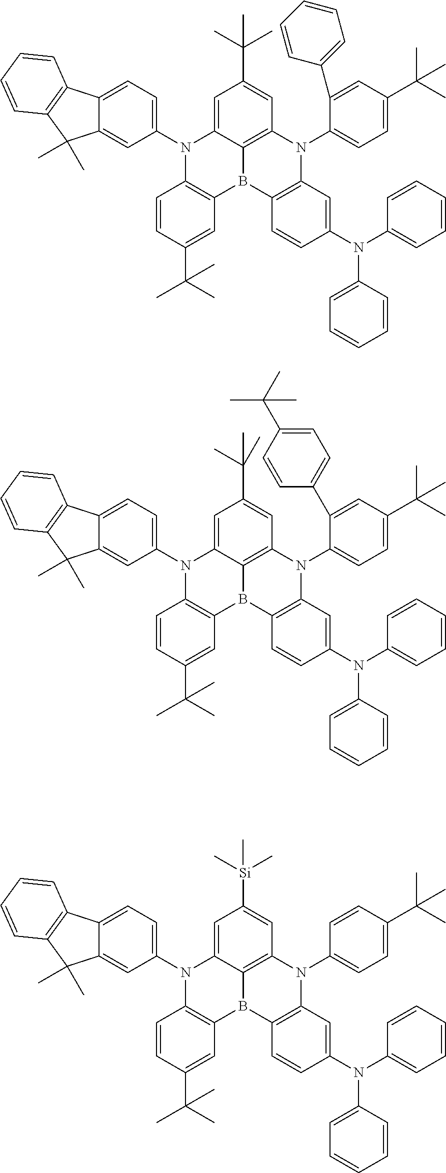 [SMILES: CC(C)(C)c1ccc2c(c1)B1c3ccc(N(c4ccccc4)c4ccccc4)cc3N(c3ccc(C(C)(C)C)cc3-c3ccccc3)c3cc(C(C)(C)C)cc(c31)N2c1ccc2c(c1)C(C)(C)c1ccccc1-2 ; CC(C)(C)c1ccc(-c2cc(C(C)(C)C)ccc2N2c3cc(N(c4ccccc4)c4ccccc4)ccc3B3c4cc(C(C)(C)C)ccc4N(c4ccc5c(c4)C(C)(C)c4ccccc4-5)c4cc(C(C)(C)C)cc2c43)cc1 ; CC(C)(C)c1ccc(N2c3cc(N(c4ccccc4)c4ccccc4)ccc3B3c4cc(C(C)(C)C)ccc4N(c4ccc5c(c4)C(C)(C)c4ccccc4-5)c4cc([Si](C)(C)C)cc2c43)cc1]

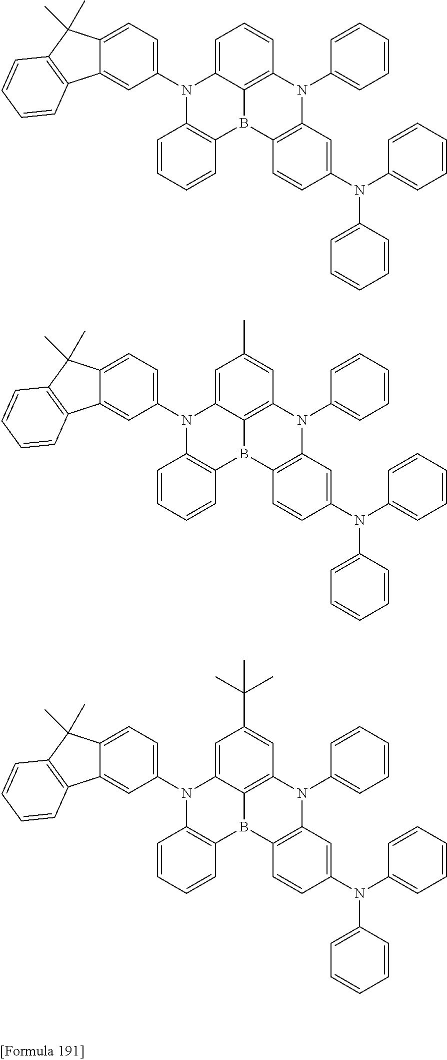 [SMILES: CC1(C)c2ccccc2-c2cc(N3c4ccccc4B4c5ccc(N(c6ccccc6)c6ccccc6)cc5N(c5ccccc5)c5cccc3c54)ccc21 ; Cc1cc2c3c(c1)N(c1ccccc1)c1cc(N(c4ccccc4)c4ccccc4)ccc1B3c1ccccc1N2c1ccc2c(c1)-c1ccccc1C2(C)C ; CC(C)(C)c1cc2c3c(c1)N(c1ccccc1)c1cc(N(c4ccccc4)c4ccccc4)ccc1B3c1ccccc1N2c1ccc2c(c1)-c1ccccc1C2(C)C]

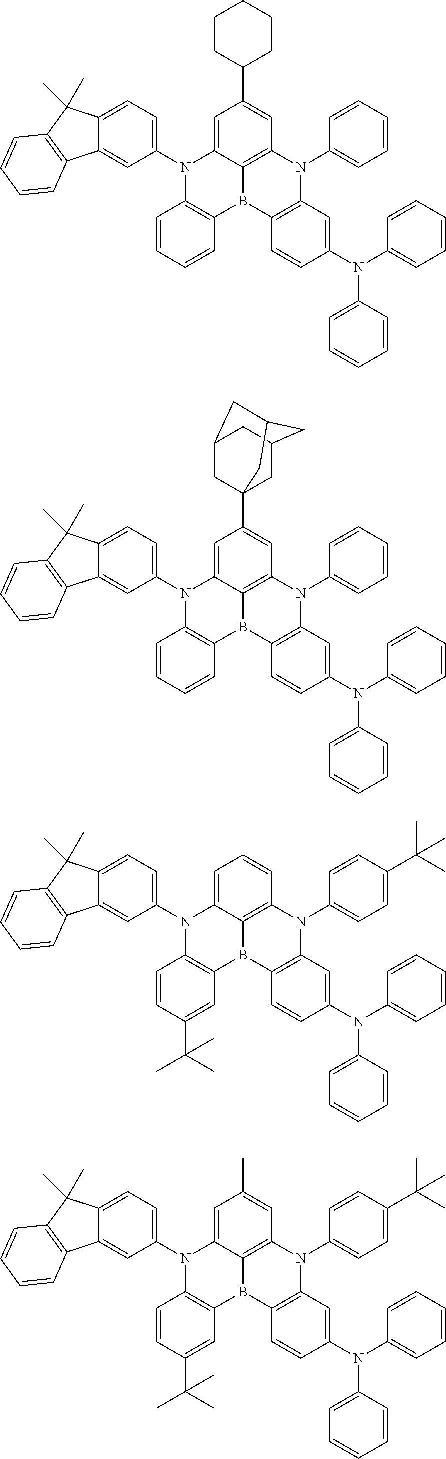 [SMILES: CC1(C)c2ccccc2-c2cc(N3c4ccccc4B4c5ccc(N(c6ccccc6)c6ccccc6)cc5N(c5ccccc5)c5cc(C6CCCCC6)cc3c54)ccc21 ; CC1(C)c2ccccc2-c2cc(N3c4ccccc4B4c5ccc(N(c6ccccc6)c6ccccc6)cc5N(c5ccccc5)c5cc(C67CC8CC(CC(C8)C6)C7)cc3c54)ccc21 ; CC(C)(C)c1ccc(N2c3cc(N(c4ccccc4)c4ccccc4)ccc3B3c4cc(C(C)(C)C)ccc4N(c4ccc5c(c4)-c4ccccc4C5(C)C)c4cccc2c43)cc1 ; Cc1cc2c3c(c1)N(c1ccc(C(C)(C)C)cc1)c1cc(N(c4ccccc4)c4ccccc4)ccc1B3c1cc(C(C)(C)C)ccc1N2c1ccc2c(c1)-c1ccccc1C2(C)C]

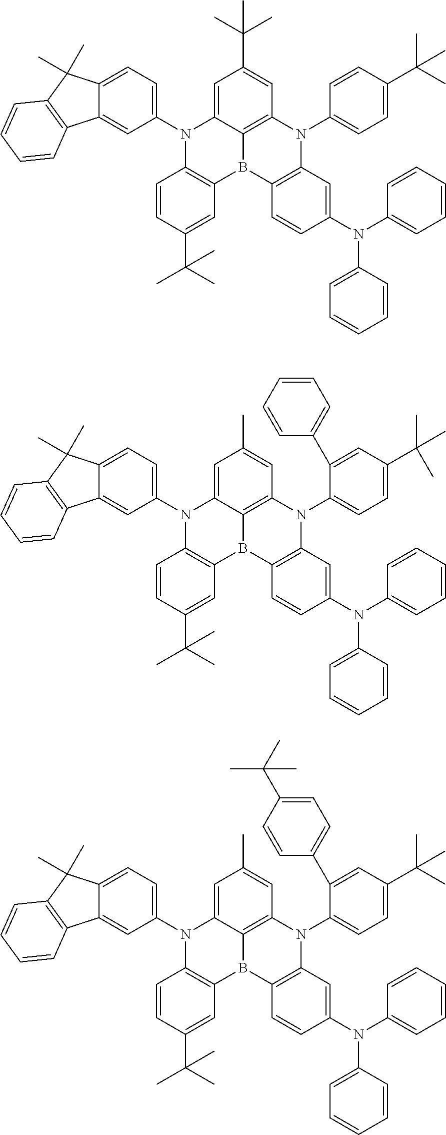 [SMILES: CC(C)(C)c1ccc(N2c3cc(N(c4ccccc4)c4ccccc4)ccc3B3c4cc(C(C)(C)C)ccc4N(c4ccc5c(c4)-c4ccccc4C5(C)C)c4cc(C(C)(C)C)cc2c43)cc1 ; Cc1cc2c3c(c1)N(c1ccc(C(C)(C)C)cc1-c1ccccc1)c1cc(N(c4ccccc4)c4ccccc4)ccc1B3c1cc(C(C)(C)C)ccc1N2c1ccc2c(c1)-c1ccccc1C2(C)C ; Cc1cc2c3c(c1)N(c1ccc(C(C)(C)C)cc1-c1ccc(C(C)(C)C)cc1)c1cc(N(c4ccccc4)c4ccccc4)ccc1B3c1cc(C(C)(C)C)ccc1N2c1ccc2c(c1)-c1ccccc1C2(C)C]

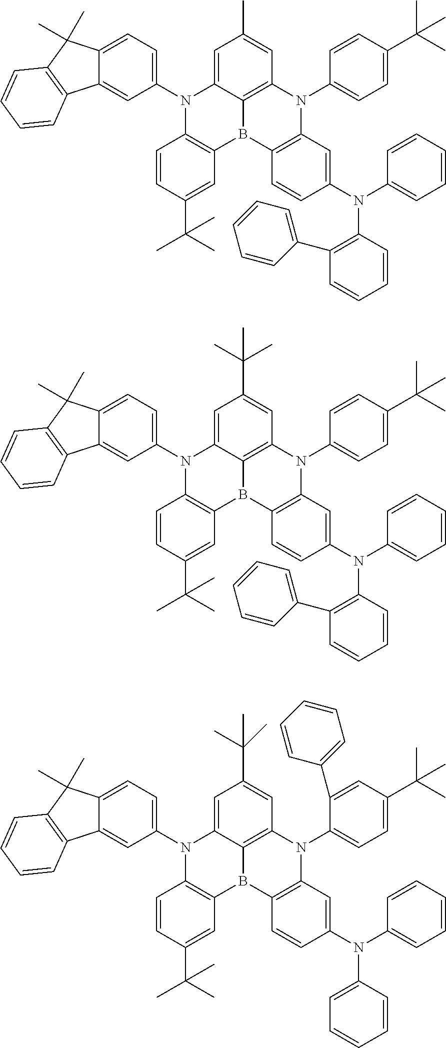 [SMILES: Cc1cc2c3c(c1)N(c1ccc(C(C)(C)C)cc1)c1cc(N(c4ccccc4)c4ccccc4-c4ccccc4)ccc1B3c1cc(C(C)(C)C)ccc1N2c1ccc2c(c1)-c1ccccc1C2(C)C ; CC(C)(C)c1ccc(N2c3cc(N(c4ccccc4)c4ccccc4-c4ccccc4)ccc3B3c4cc(C(C)(C)C)ccc4N(c4ccc5c(c4)-c4ccccc4C5(C)C)c4cc(C(C)(C)C)cc2c43)cc1 ; CC(C)(C)c1ccc2c(c1)B1c3ccc(N(c4ccccc4)c4ccccc4)cc3N(c3ccc(C(C)(C)C)cc3-c3ccccc3)c3cc(C(C)(C)C)cc(c31)N2c1ccc2c(c1)-c1ccccc1C2(C)C]

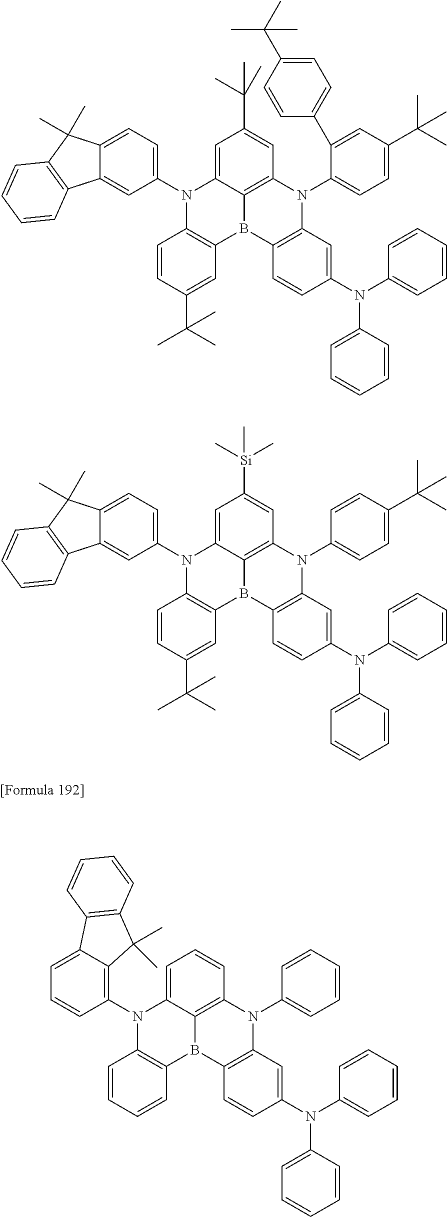 [SMILES: CC(C)(C)c1ccc(-c2cc(C(C)(C)C)ccc2N2c3cc(N(c4ccccc4)c4ccccc4)ccc3B3c4cc(C(C)(C)C)ccc4N(c4ccc5c(c4)-c4ccccc4C5(C)C)c4cc(C(C)(C)C)cc2c43)cc1 ; CC(C)(C)c1ccc(N2c3cc(N(c4ccccc4)c4ccccc4)ccc3B3c4cc(C(C)(C)C)ccc4N(c4ccc5c(c4)-c4ccccc4C5(C)C)c4cc([Si](C)(C)C)cc2c43)cc1 ; CC1(C)c2ccccc2-c2cccc(N3c4ccccc4B4c5ccc(N(c6ccccc6)c6ccccc6)cc5N(c5ccccc5)c5cccc3c54)c21]

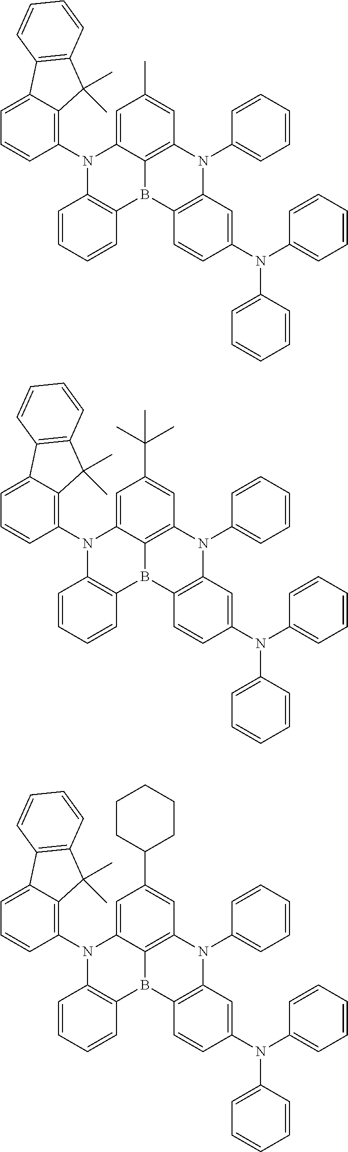 [SMILES: Cc1cc2c3c(c1)N(c1cccc4c1C(C)(C)c1ccccc1-4)c1ccccc1B3c1ccc(N(c3ccccc3)c3ccccc3)cc1N2c1ccccc1 ; CC(C)(C)c1cc2c3c(c1)N(c1cccc4c1C(C)(C)c1ccccc1-4)c1ccccc1B3c1ccc(N(c3ccccc3)c3ccccc3)cc1N2c1ccccc1 ; CC1(C)c2ccccc2-c2cccc(N3c4ccccc4B4c5ccc(N(c6ccccc6)c6ccccc6)cc5N(c5ccccc5)c5cc(C6CCCCC6)cc3c54)c21]

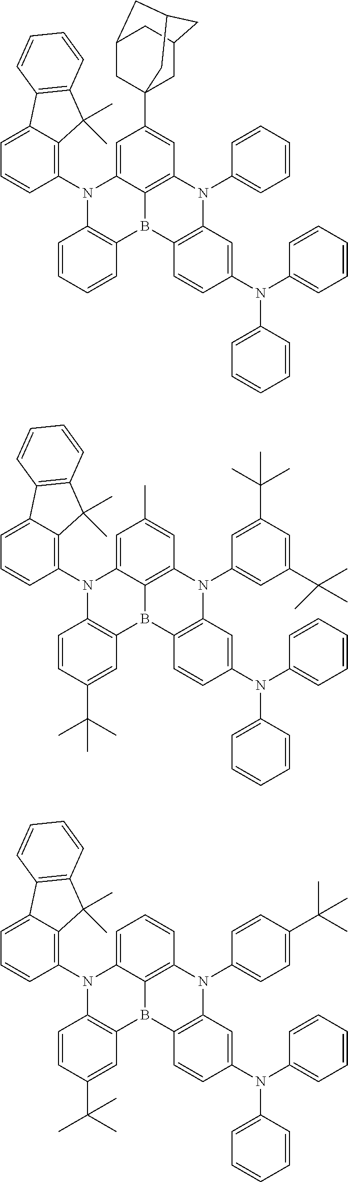 [SMILES: CC1(C)c2ccccc2-c2cccc(N3c4ccccc4B4c5ccc(N(c6ccccc6)c6ccccc6)cc5N(c5ccccc5)c5cc(C67CC8CC(CC(C8)C6)C7)cc3c54)c21 ; Cc1cc2c3c(c1)N(c1cccc4c1C(C)(C)c1ccccc1-4)c1ccc(C(C)(C)C)cc1B3c1ccc(N(c3ccccc3)c3ccccc3)cc1N2c1cc(C(C)(C)C)cc(C(C)(C)C)c1 ; CC(C)(C)c1ccc(N2c3cc(N(c4ccccc4)c4ccccc4)ccc3B3c4cc(C(C)(C)C)ccc4N(c4cccc5c4C(C)(C)c4ccccc4-5)c4cccc2c43)cc1]

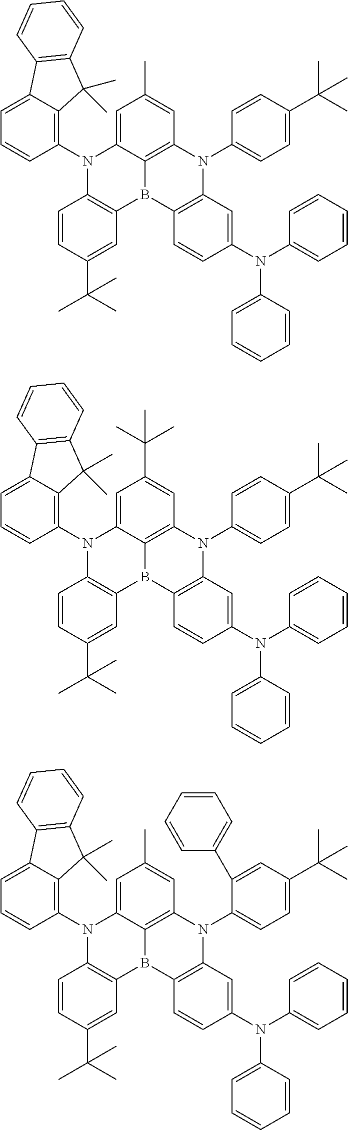 [SMILES: Cc1cc2c3c(c1)N(c1cccc4c1C(C)(C)c1ccccc1-4)c1ccc(C(C)(C)C)cc1B3c1ccc(N(c3ccccc3)c3ccccc3)cc1N2c1ccc(C(C)(C)C)cc1 ; CC(C)(C)c1ccc(N2c3cc(N(c4ccccc4)c4ccccc4)ccc3B3c4cc(C(C)(C)C)ccc4N(c4cccc5c4C(C)(C)c4ccccc4-5)c4cc(C(C)(C)C)cc2c43)cc1 ; Cc1cc2c3c(c1)N(c1cccc4c1C(C)(C)c1ccccc1-4)c1ccc(C(C)(C)C)cc1B3c1ccc(N(c3ccccc3)c3ccccc3)cc1N2c1ccc(C(C)(C)C)cc1-c1ccccc1]

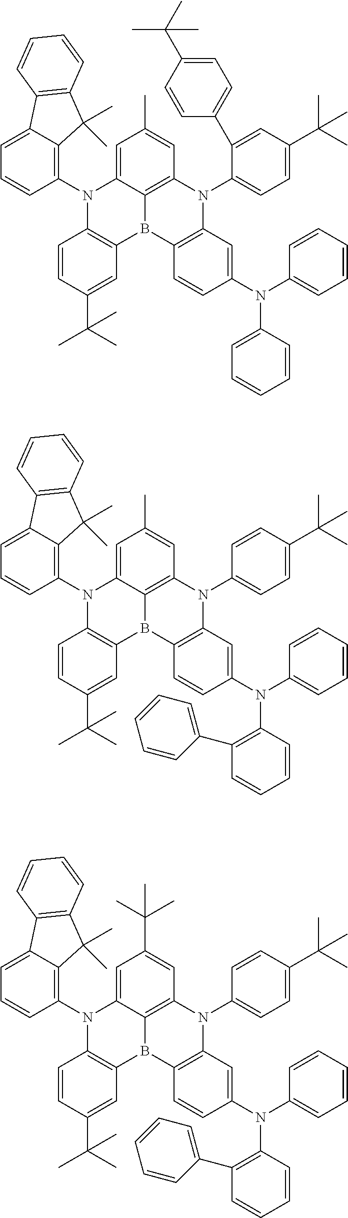 [SMILES: Cc1cc2c3c(c1)N(c1cccc4c1C(C)(C)c1ccccc1-4)c1ccc(C(C)(C)C)cc1B3c1ccc(N(c3ccccc3)c3ccccc3)cc1N2c1ccc(C(C)(C)C)cc1-c1ccc(C(C)(C)C)cc1 ; Cc1cc2c3c(c1)N(c1cccc4c1C(C)(C)c1ccccc1-4)c1ccc(C(C)(C)C)cc1B3c1ccc(N(c3ccccc3)c3ccccc3-c3ccccc3)cc1N2c1ccc(C(C)(C)C)cc1 ; CC(C)(C)c1ccc(N2c3cc(N(c4ccccc4)c4ccccc4-c4ccccc4)ccc3B3c4cc(C(C)(C)C)ccc4N(c4cccc5c4C(C)(C)c4ccccc4-5)c4cc(C(C)(C)C)cc2c43)cc1]

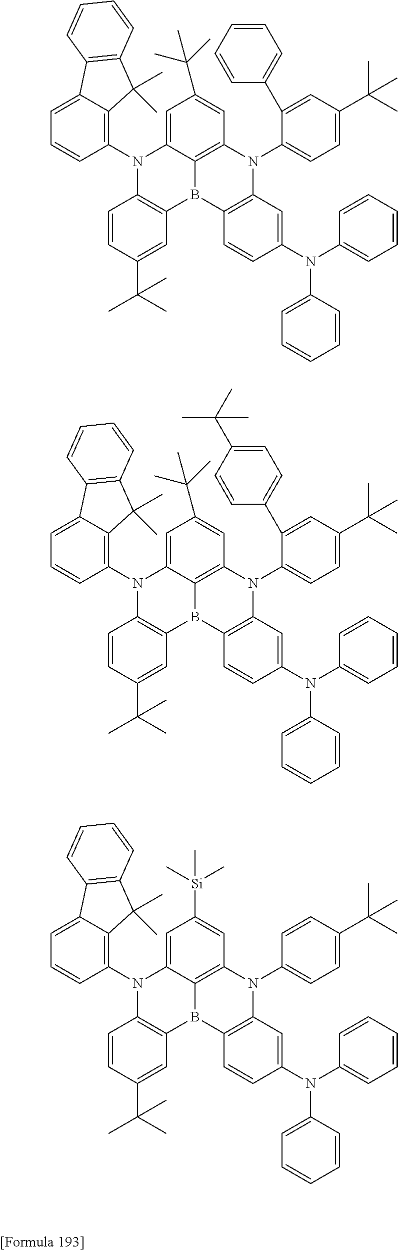 [SMILES: CC(C)(C)c1ccc2c(c1)B1c3ccc(N(c4ccccc4)c4ccccc4)cc3N(c3ccc(C(C)(C)C)cc3-c3ccccc3)c3cc(C(C)(C)C)cc(c31)N2c1cccc2c1C(C)(C)c1ccccc1-2 ; CC(C)(C)c1ccc(-c2cc(C(C)(C)C)ccc2N2c3cc(N(c4ccccc4)c4ccccc4)ccc3B3c4cc(C(C)(C)C)ccc4N(c4cccc5c4C(C)(C)c4ccccc4-5)c4cc(C(C)(C)C)cc2c43)cc1 ; CC(C)(C)c1ccc(N2c3cc(N(c4ccccc4)c4ccccc4)ccc3B3c4cc(C(C)(C)C)ccc4N(c4cccc5c4C(C)(C)c4ccccc4-5)c4cc([Si](C)(C)C)cc2c43)cc1]

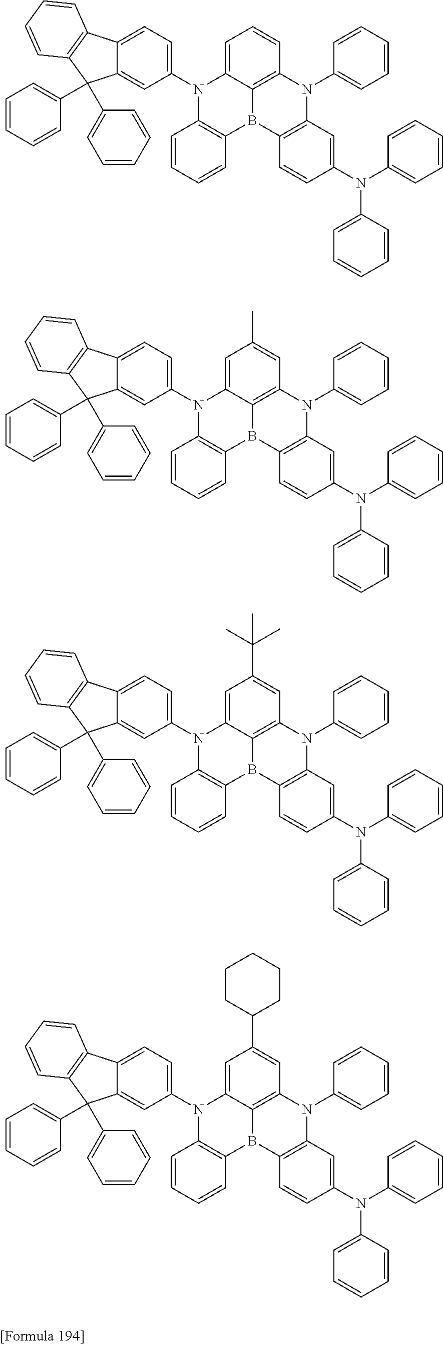 [SMILES: c1ccc(N(c2ccccc2)c2ccc3c(c2)N(c2ccccc2)c2cccc4c2B3c2ccccc2N4c2ccc3c(c2)C(c2ccccc2)(c2ccccc2)c2ccccc2-3)cc1 ; Cc1cc2c3c(c1)N(c1ccccc1)c1cc(N(c4ccccc4)c4ccccc4)ccc1B3c1ccccc1N2c1ccc2c(c1)C(c1ccccc1)(c1ccccc1)c1ccccc1-2 ; CC(C)(C)c1cc2c3c(c1)N(c1ccccc1)c1cc(N(c4ccccc4)c4ccccc4)ccc1B3c1ccccc1N2c1ccc2c(c1)C(c1ccccc1)(c1ccccc1)c1ccccc1-2 ; c1ccc(N(c2ccccc2)c2ccc3c(c2)N(c2ccccc2)c2cc(C4CCCCC4)cc4c2B3c2ccccc2N4c2ccc3c(c2)C(c2ccccc2)(c2ccccc2)c2ccccc2-3)cc1]

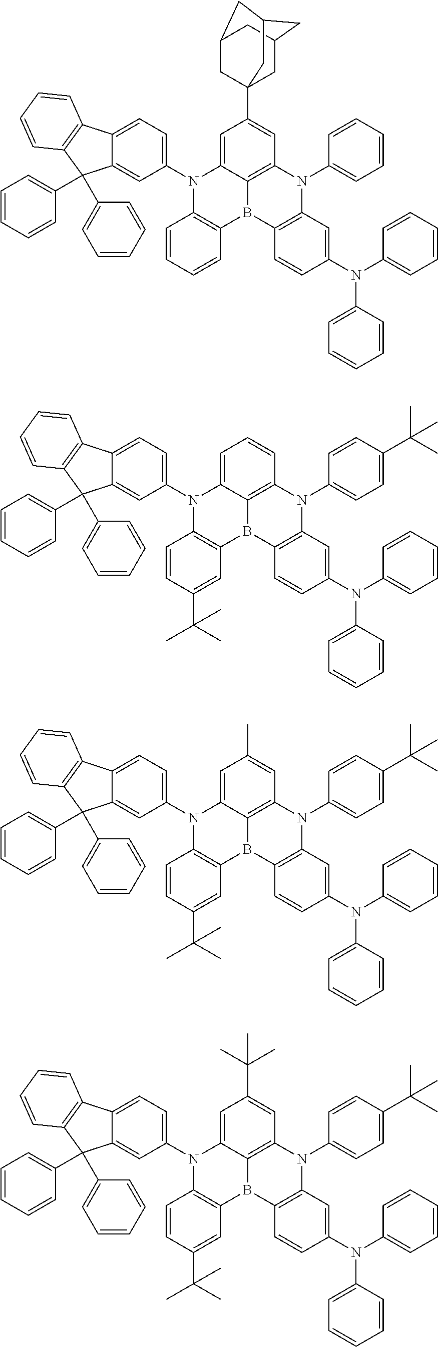

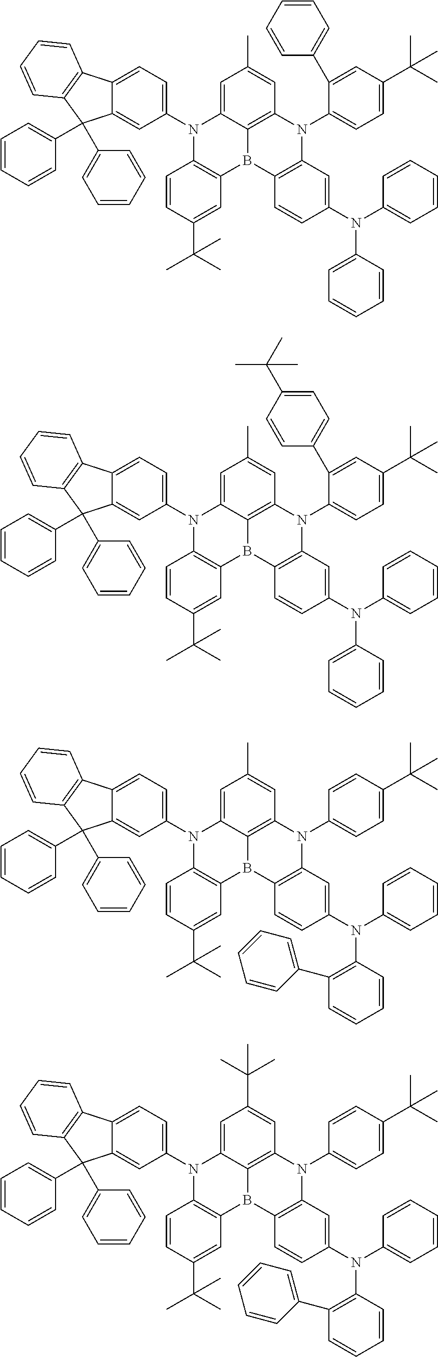

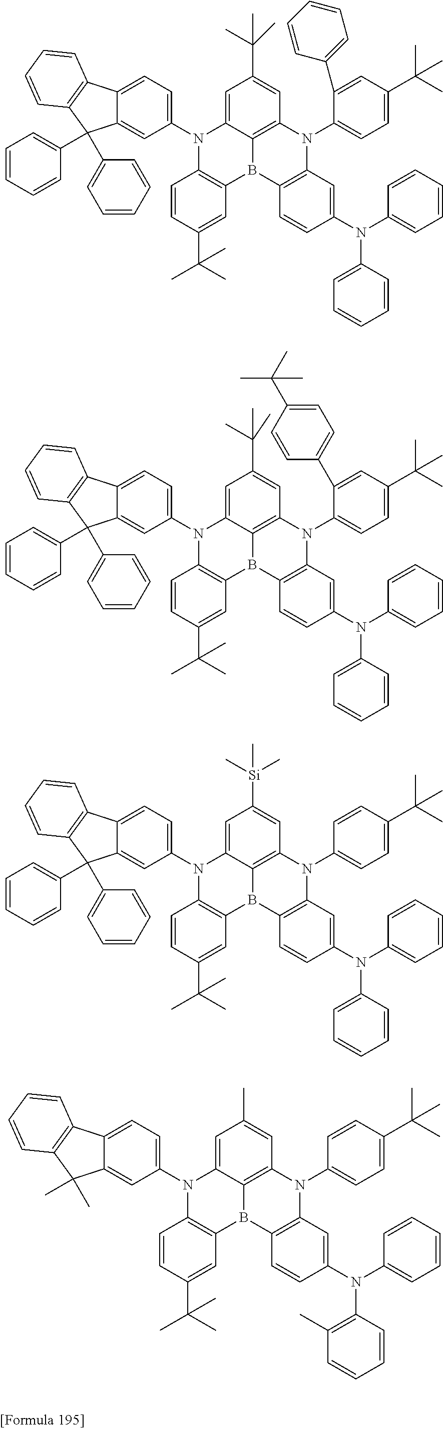

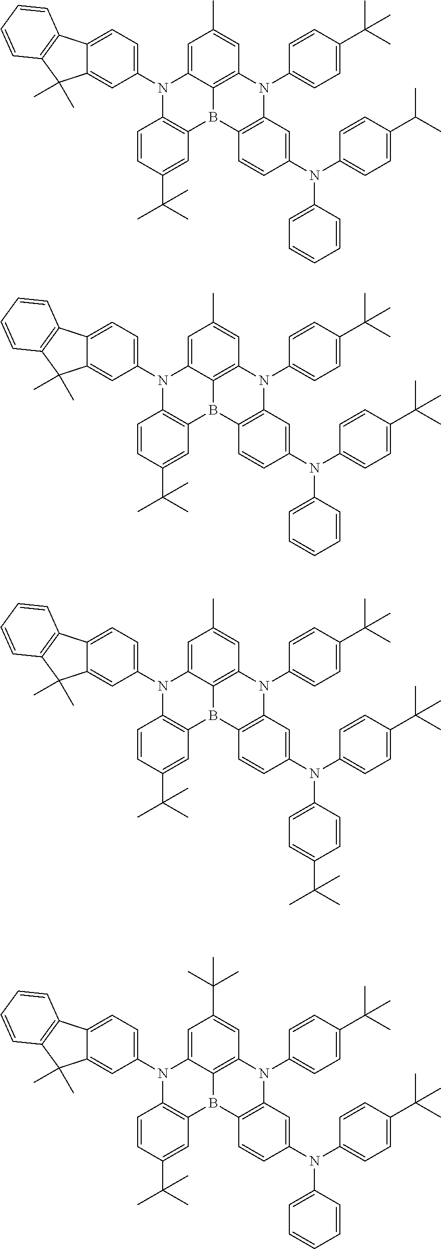

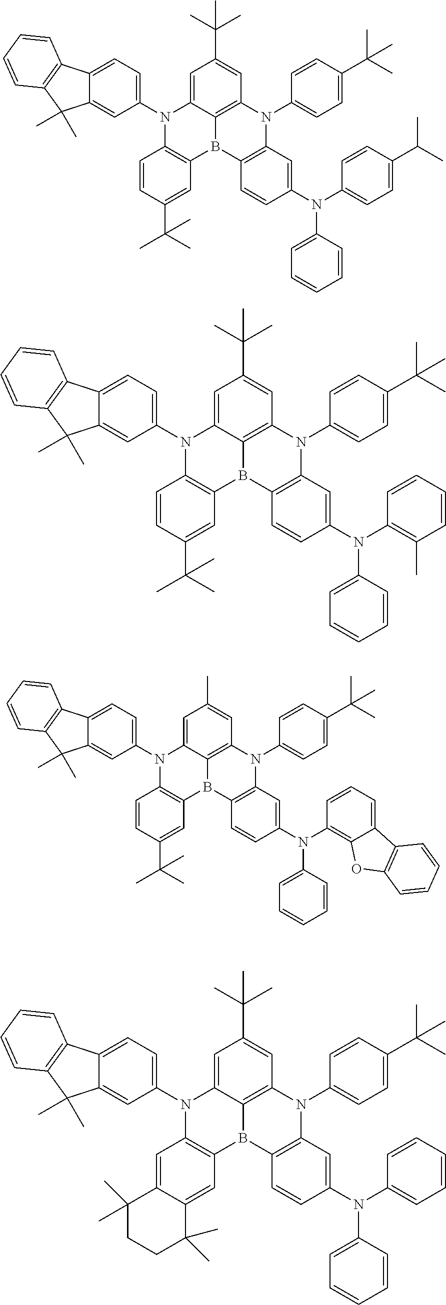

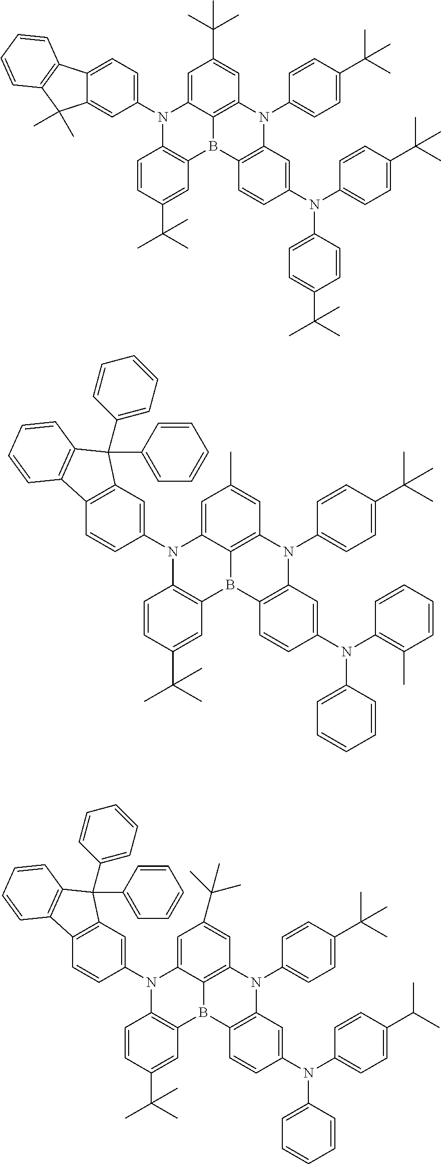 [SMILES: CC(C)(C)c1ccc(N(c2ccc(C(C)(C)C)cc2)c2ccc3c(c2)N(c2ccc(C(C)(C)C)cc2)c2cc(C(C)(C)C)cc4c2B3c2cc(C(C)(C)C)ccc2N4c2ccc3c(c2)C(C)(C)c2ccccc2-3)cc1 ; Cc1cc2c3c(c1)N(c1ccc(C(C)(C)C)cc1)c1cc(N(c4ccccc4)c4ccccc4C)ccc1B3c1cc(C(C)(C)C)ccc1N2c1ccc2c(c1)C(c1ccccc1)(c1ccccc1)c1ccccc1-2 ; CC(C)c1ccc(N(c2ccccc2)c2ccc3c(c2)N(c2ccc(C(C)(C)C)cc2)c2cc(C(C)(C)C)cc4c2B3c2cc(C(C)(C)C)ccc2N4c2ccc3c(c2)C(c2ccccc2)(c2ccccc2)c2ccccc2-3)cc1]

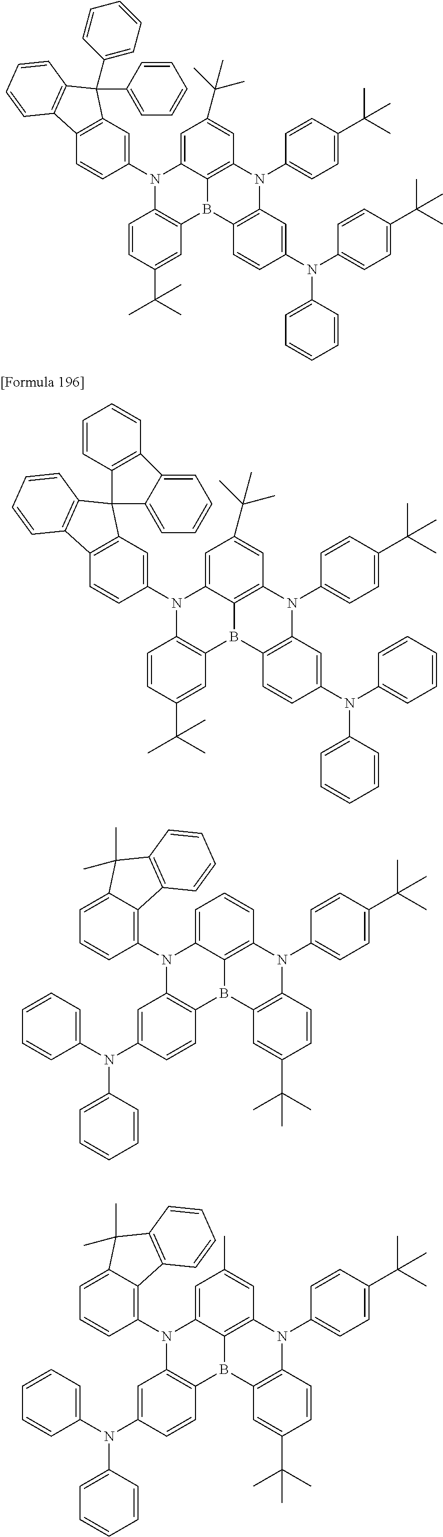

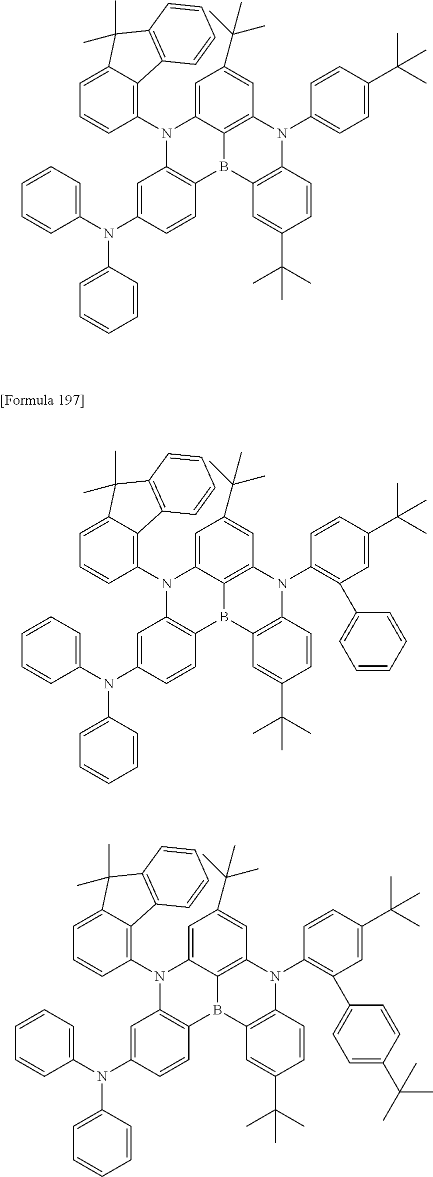 [SMILES: CC(C)(C)c1ccc(N2c3ccc(C(C)(C)C)cc3B3c4ccc(N(c5ccccc5)c5ccccc5)cc4N(c4cccc5c4-c4ccccc4C5(C)C)c4cc(C(C)(C)C)cc2c43)cc1 ; CC(C)(C)c1ccc2c(c1)B1c3ccc(N(c4ccccc4)c4ccccc4)cc3N(c3cccc4c3-c3ccccc3C4(C)C)c3cc(C(C)(C)C)cc(c31)N2c1ccc(C(C)(C)C)cc1-c1ccccc1 ; CC(C)(C)c1ccc(-c2cc(C(C)(C)C)ccc2N2c3ccc(C(C)(C)C)cc3B3c4ccc(N(c5ccccc5)c5ccccc5)cc4N(c4cccc5c4-c4ccccc4C5(C)C)c4cc(C(C)(C)C)cc2c43)cc1]

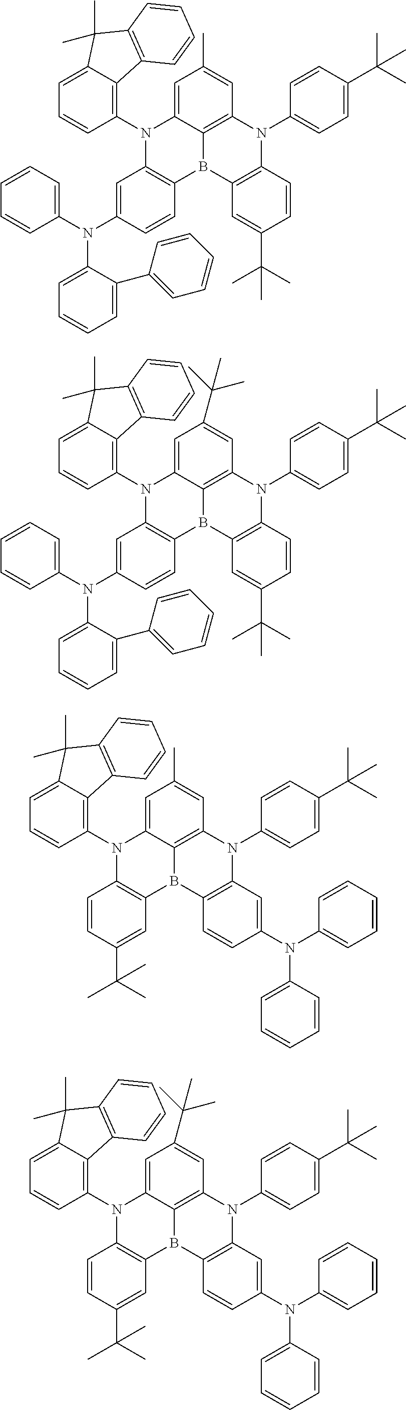

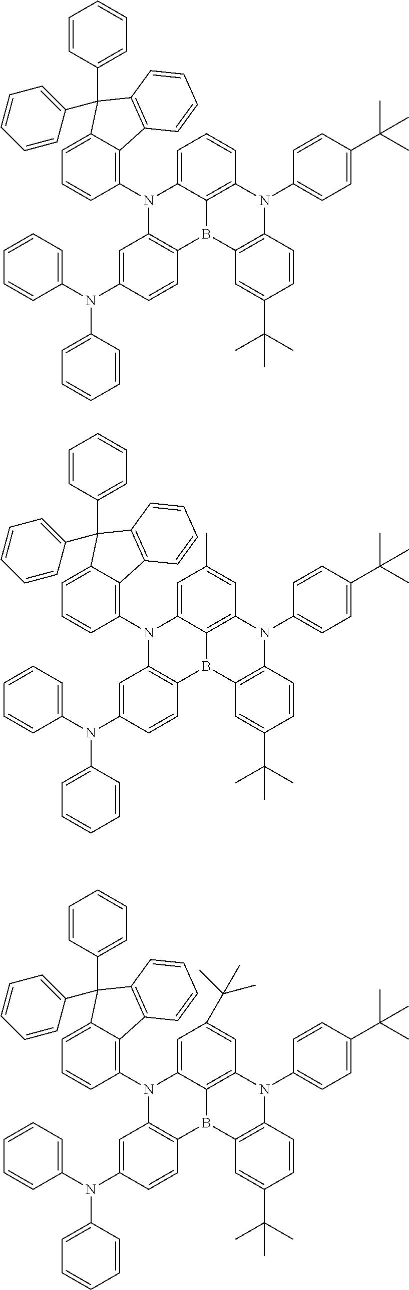

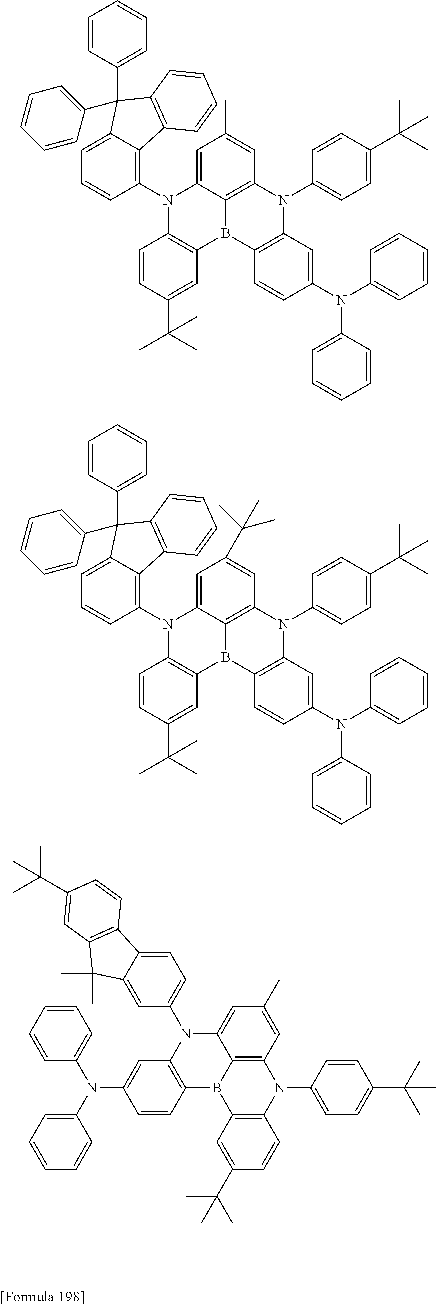 [SMILES: Cc1cc2c3c(c1)N(c1cccc4c1-c1ccccc1C4(c1ccccc1)c1ccccc1)c1ccc(C(C)(C)C)cc1B3c1ccc(N(c3ccccc3)c3ccccc3)cc1N2c1ccc(C(C)(C)C)cc1 ; CC(C)(C)c1ccc(N2c3cc(N(c4ccccc4)c4ccccc4)ccc3B3c4cc(C(C)(C)C)ccc4N(c4cccc5c4-c4ccccc4C5(c4ccccc4)c4ccccc4)c4cc(C(C)(C)C)cc2c43)cc1 ; Cc1cc2c3c(c1)N(c1ccc4c(c1)C(C)(C)c1cc(C(C)(C)C)ccc1-4)c1cc(N(c4ccccc4)c4ccccc4)ccc1B3c1cc(C(C)(C)C)ccc1N2c1ccc(C(C)(C)C)cc1]

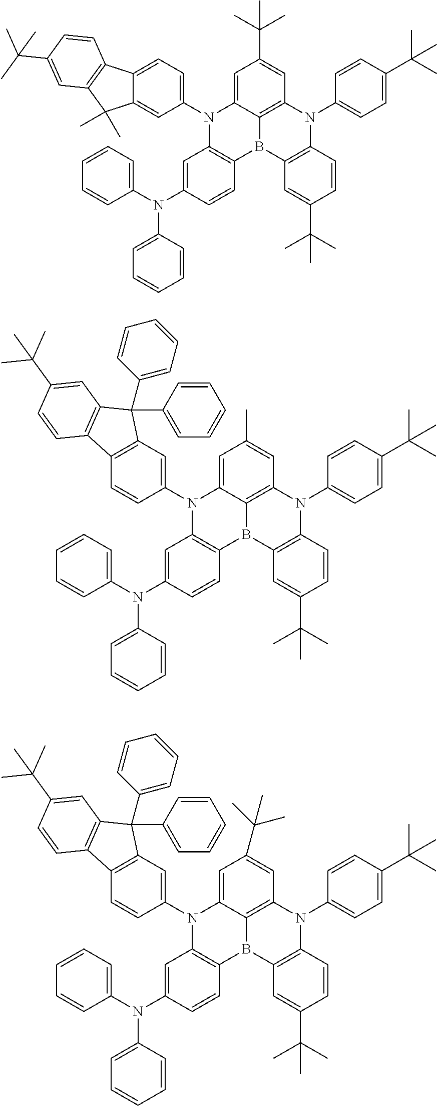

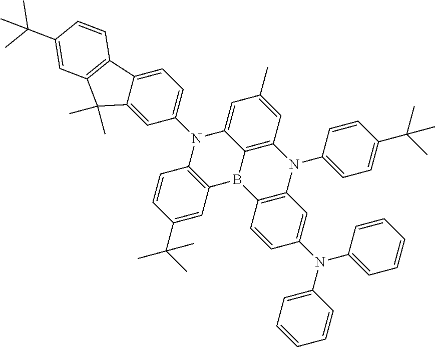 [SMILES: Cc1cc2c3c(c1)N(c1ccc(C(C)(C)C)cc1)c1cc(N(c4ccccc4)c4ccccc4)ccc1B3c1cc(C(C)(C)C)ccc1N2c1ccc2c(c1)C(C)(C)c1cc(C(C)(C)C)ccc1-2]

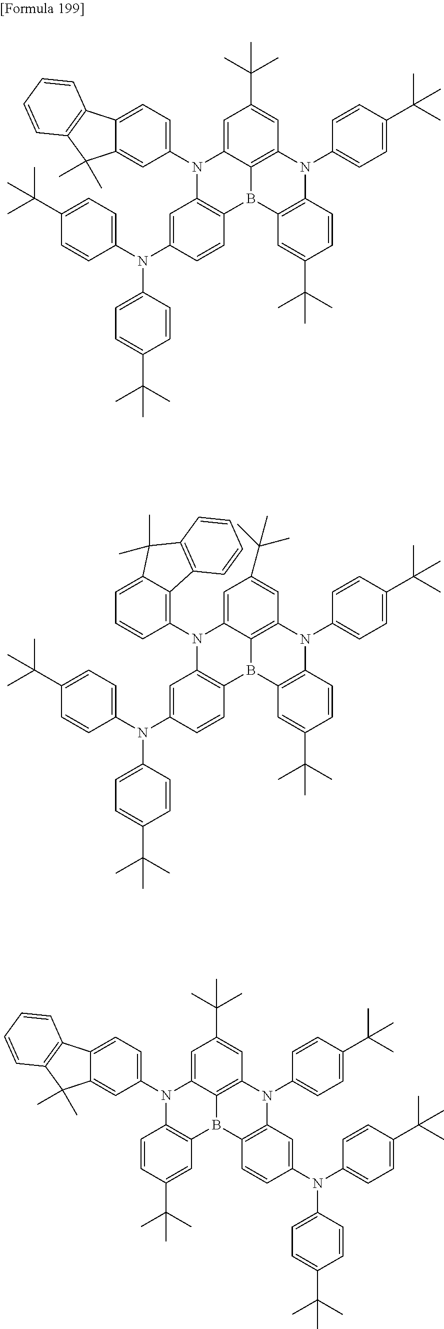

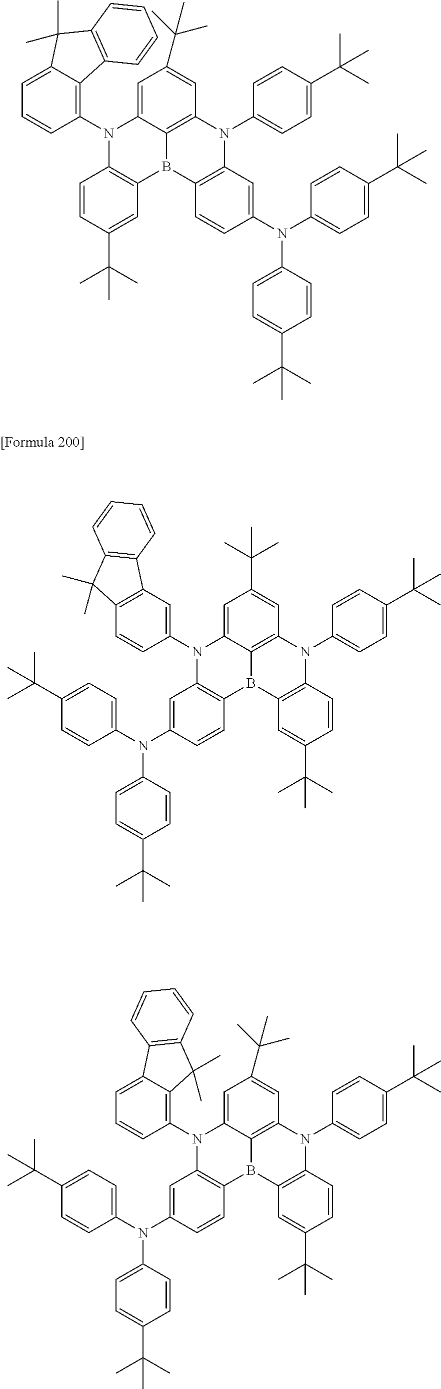

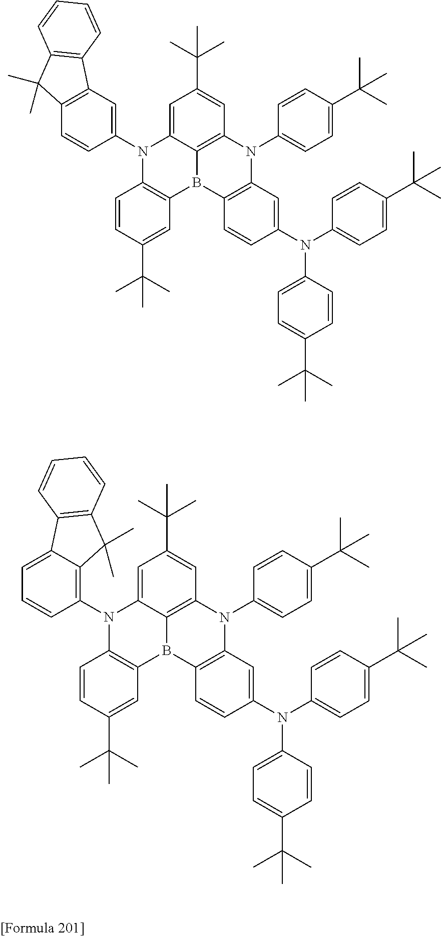 [SMILES: CC(C)(C)c1ccc(N(c2ccc(C(C)(C)C)cc2)c2ccc3c(c2)N(c2ccc(C(C)(C)C)cc2)c2cc(C(C)(C)C)cc4c2B3c2cc(C(C)(C)C)ccc2N4c2ccc3c(c2)-c2ccccc2C3(C)C)cc1 ; CC(C)(C)c1ccc(N(c2ccc(C(C)(C)C)cc2)c2ccc3c(c2)N(c2ccc(C(C)(C)C)cc2)c2cc(C(C)(C)C)cc4c2B3c2cc(C(C)(C)C)ccc2N4c2cccc3c2C(C)(C)c2ccccc2-3)cc1]

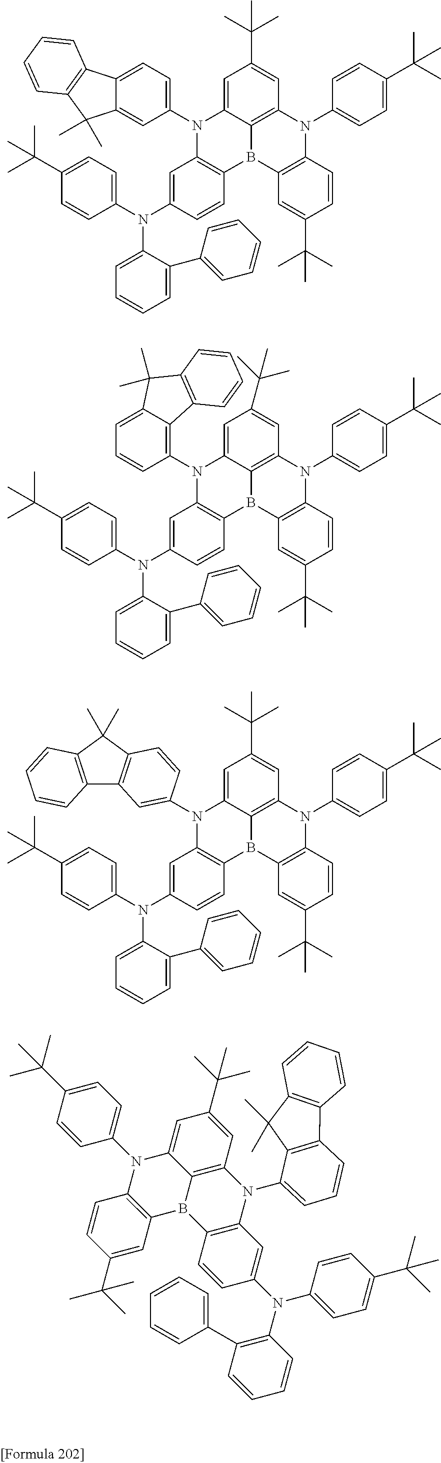

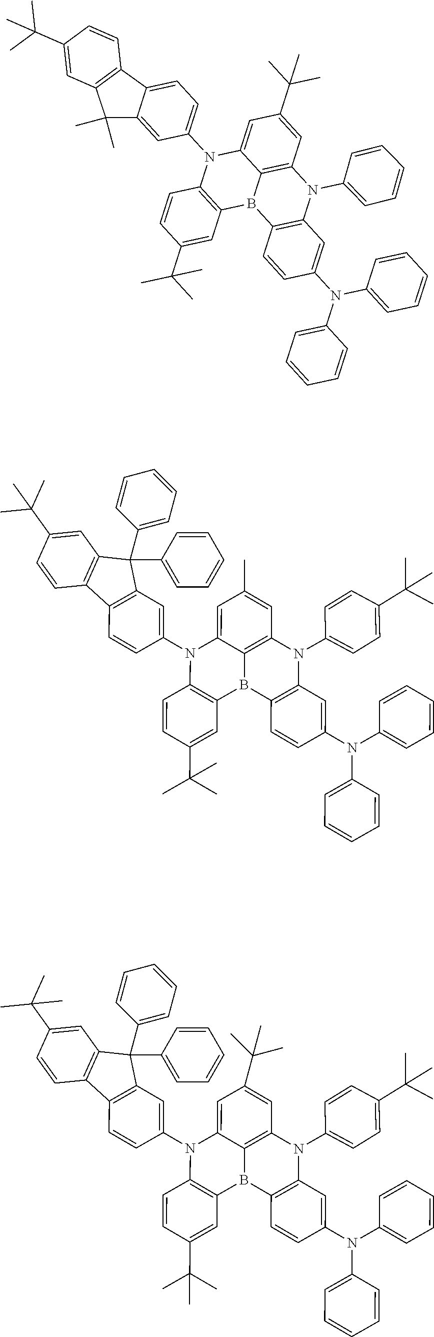 [SMILES: CC(C)(C)c1ccc2c(c1)B1c3ccc(N(c4ccccc4)c4ccccc4)cc3N(c3ccccc3)c3cc(C(C)(C)C)cc(c31)N2c1ccc2c(c1)C(C)(C)c1cc(C(C)(C)C)ccc1-2 ; Cc1cc2c3c(c1)N(c1ccc(C(C)(C)C)cc1)c1cc(N(c4ccccc4)c4ccccc4)ccc1B3c1cc(C(C)(C)C)ccc1N2c1ccc2c(c1)C(c1ccccc1)(c1ccccc1)c1cc(C(C)(C)C)ccc1-2 ; CC(C)(C)c1ccc(N2c3cc(N(c4ccccc4)c4ccccc4)ccc3B3c4cc(C(C)(C)C)ccc4N(c4ccc5c(c4)C(c4ccccc4)(c4ccccc4)c4cc(C(C)(C)C)ccc4-5)c4cc(C(C)(C)C)cc2c43)cc1]

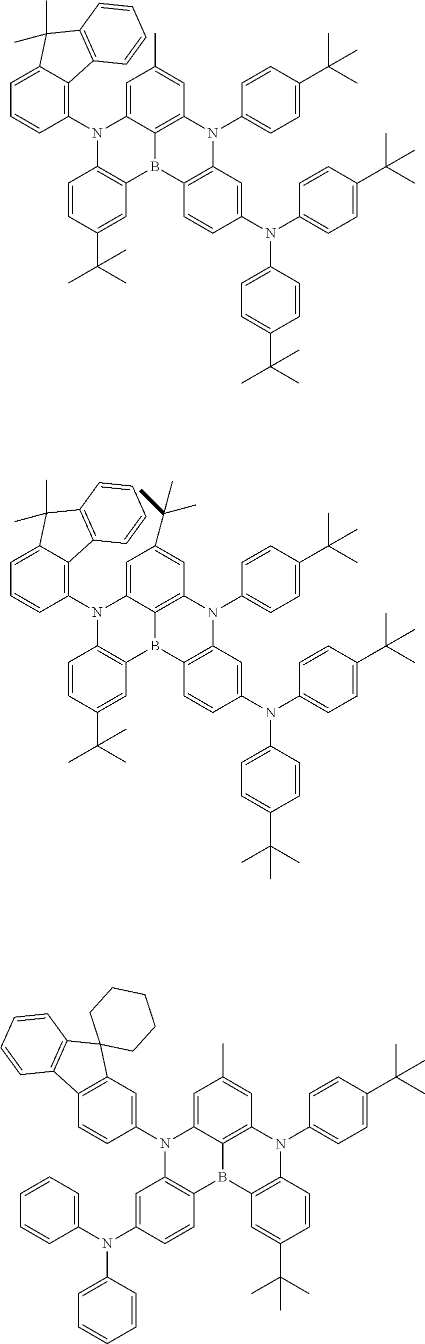

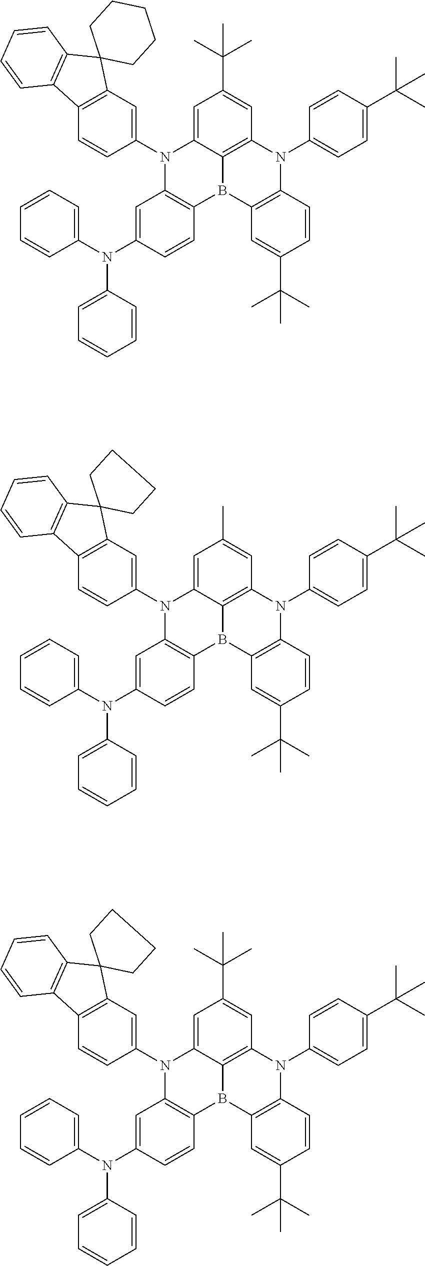 [SMILES: CC(C)(C)c1ccc(N2c3ccc(C(C)(C)C)cc3B3c4ccc(N(c5ccccc5)c5ccccc5)cc4N(c4ccc5c(c4)C4(CCCCC4)c4ccccc4-5)c4cc(C(C)(C)C)cc2c43)cc1 ; Cc1cc2c3c(c1)N(c1ccc4c(c1)C1(CCCC1)c1ccccc1-4)c1cc(N(c4ccccc4)c4ccccc4)ccc1B3c1cc(C(C)(C)C)ccc1N2c1ccc(C(C)(C)C)cc1 ; CC(C)(C)c1ccc(N2c3ccc(C(C)(C)C)cc3B3c4ccc(N(c5ccccc5)c5ccccc5)cc4N(c4ccc5c(c4)C4(CCCC4)c4ccccc4-5)c4cc(C(C)(C)C)cc2c43)cc1]

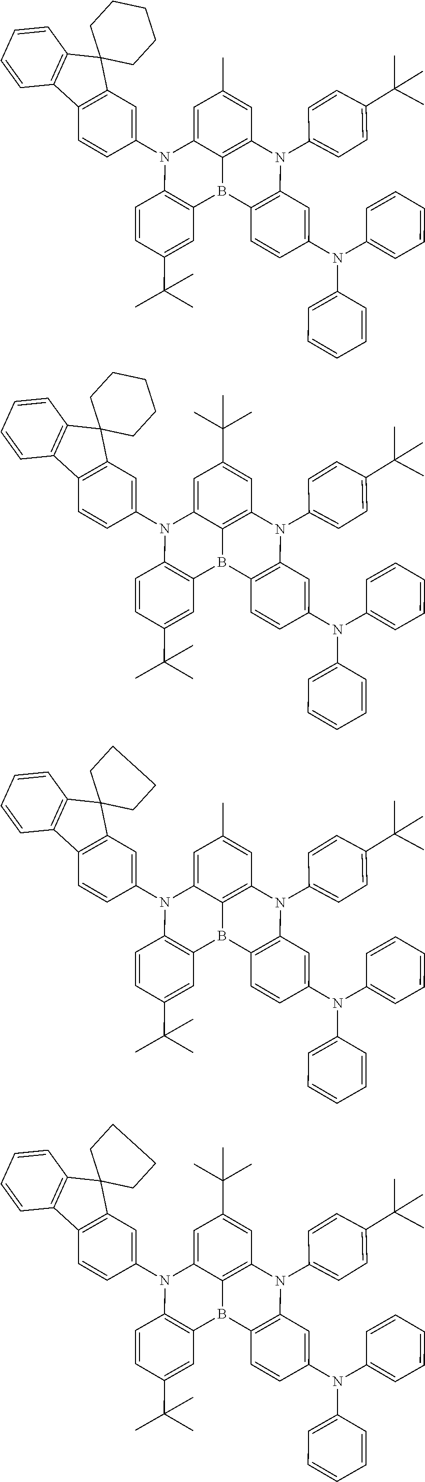 [SMILES: Cc1cc2c3c(c1)N(c1ccc(C(C)(C)C)cc1)c1cc(N(c4ccccc4)c4ccccc4)ccc1B3c1cc(C(C)(C)C)ccc1N2c1ccc2c(c1)C1(CCCCC1)c1ccccc1-2 ; CC(C)(C)c1ccc(N2c3cc(N(c4ccccc4)c4ccccc4)ccc3B3c4cc(C(C)(C)C)ccc4N(c4ccc5c(c4)C4(CCCCC4)c4ccccc4-5)c4cc(C(C)(C)C)cc2c43)cc1 ; Cc1cc2c3c(c1)N(c1ccc(C(C)(C)C)cc1)c1cc(N(c4ccccc4)c4ccccc4)ccc1B3c1cc(C(C)(C)C)ccc1N2c1ccc2c(c1)C1(CCCC1)c1ccccc1-2 ; CC(C)(C)c1ccc(N2c3cc(N(c4ccccc4)c4ccccc4)ccc3B3c4cc(C(C)(C)C)ccc4N(c4ccc5c(c4)C4(CCCC4)c4ccccc4-5)c4cc(C(C)(C)C)cc2c43)cc1]

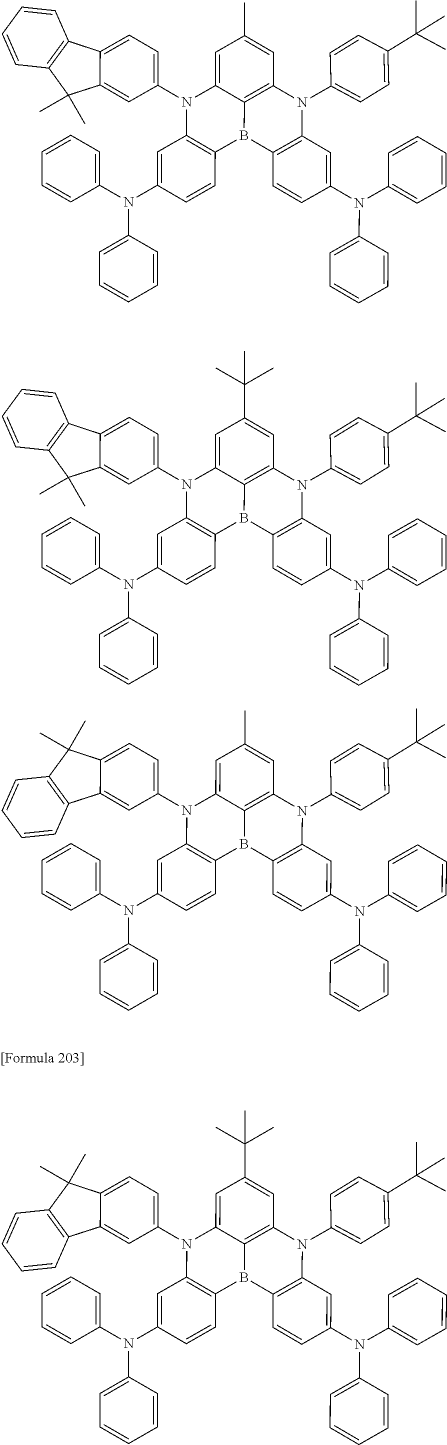

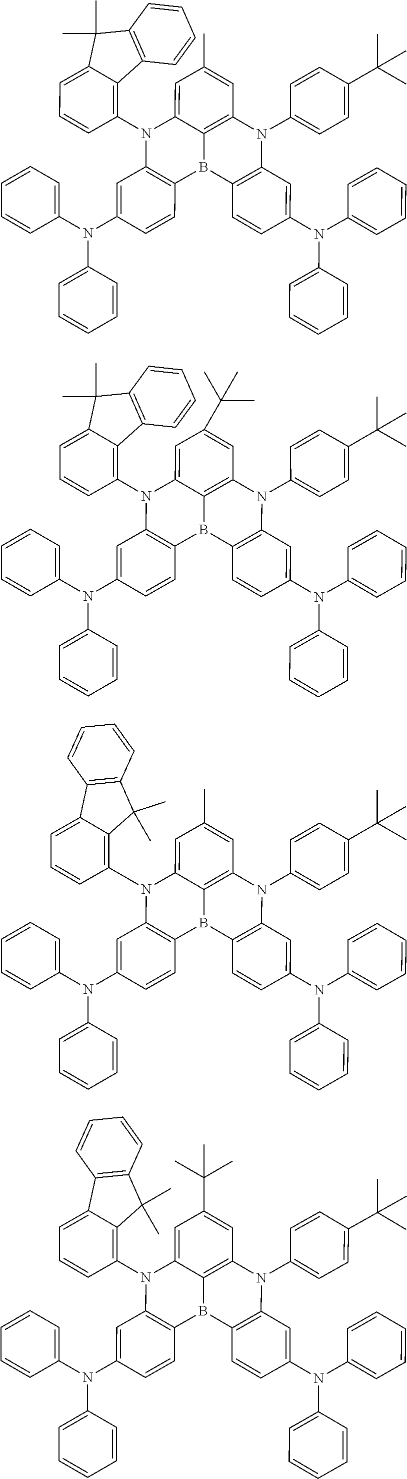

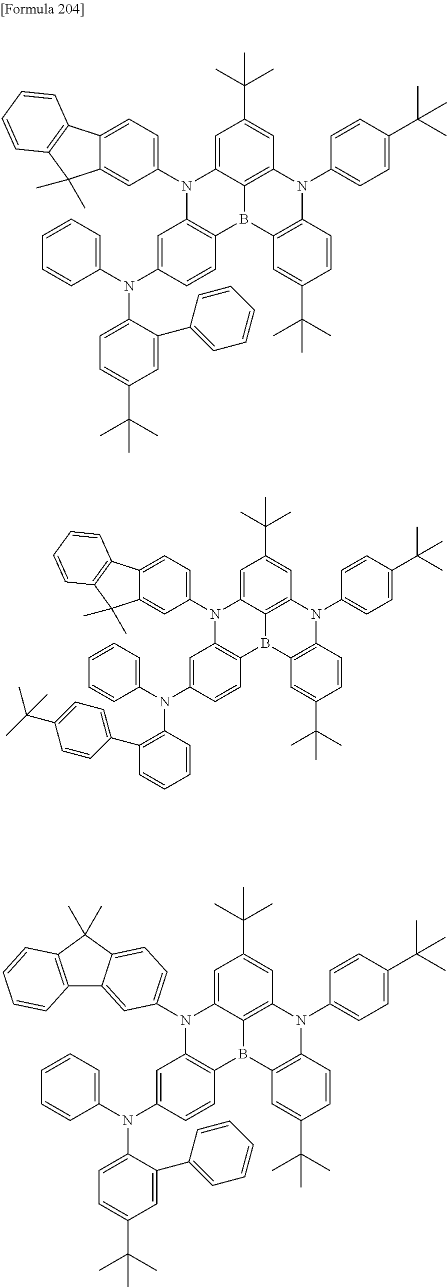

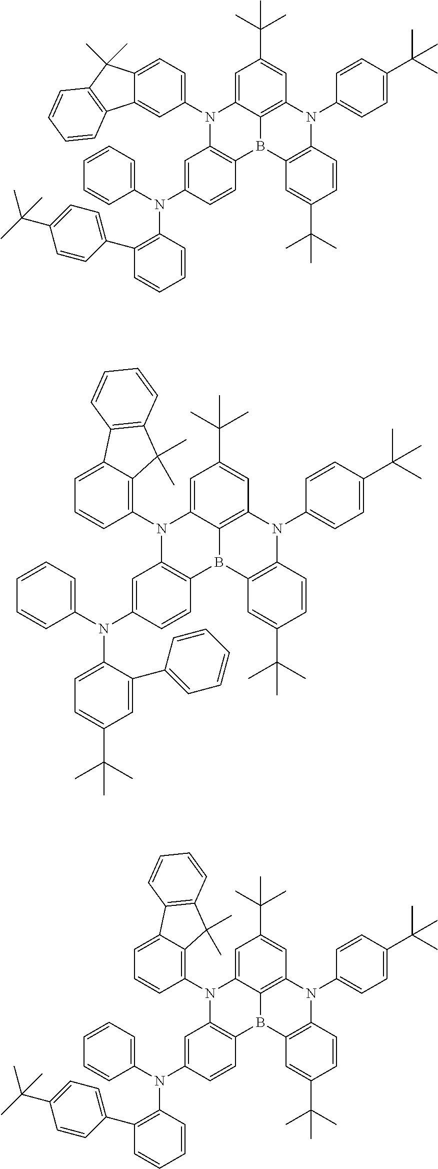

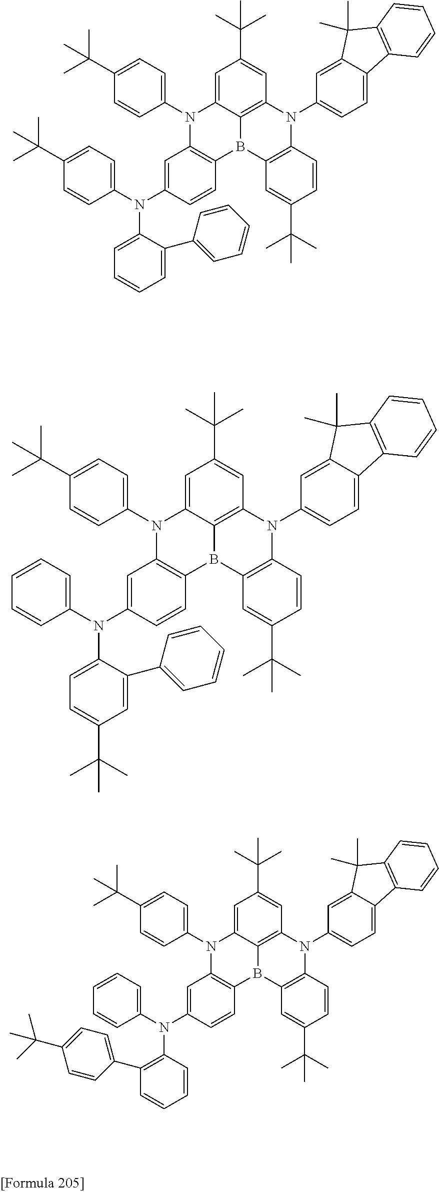 [SMILES: CC(C)(C)c1ccc(N(c2ccc3c(c2)N(c2ccc(C(C)(C)C)cc2)c2cc(C(C)(C)C)cc4c2B3c2cc(C(C)(C)C)ccc2N4c2ccc3c(c2)C(C)(C)c2ccccc2-3)c2ccccc2-c2ccccc2)cc1 ; CC(C)(C)c1ccc(N2c3cc(N(c4ccccc4)c4ccc(C(C)(C)C)cc4-c4ccccc4)ccc3B3c4cc(C(C)(C)C)ccc4N(c4ccc5c(c4)C(C)(C)c4ccccc4-5)c4cc(C(C)(C)C)cc2c43)cc1 ; CC(C)(C)c1ccc(-c2ccccc2N(c2ccccc2)c2ccc3c(c2)N(c2ccc(C(C)(C)C)cc2)c2cc(C(C)(C)C)cc4c2B3c2cc(C(C)(C)C)ccc2N4c2ccc3c(c2)C(C)(C)c2ccccc2-3)cc1]

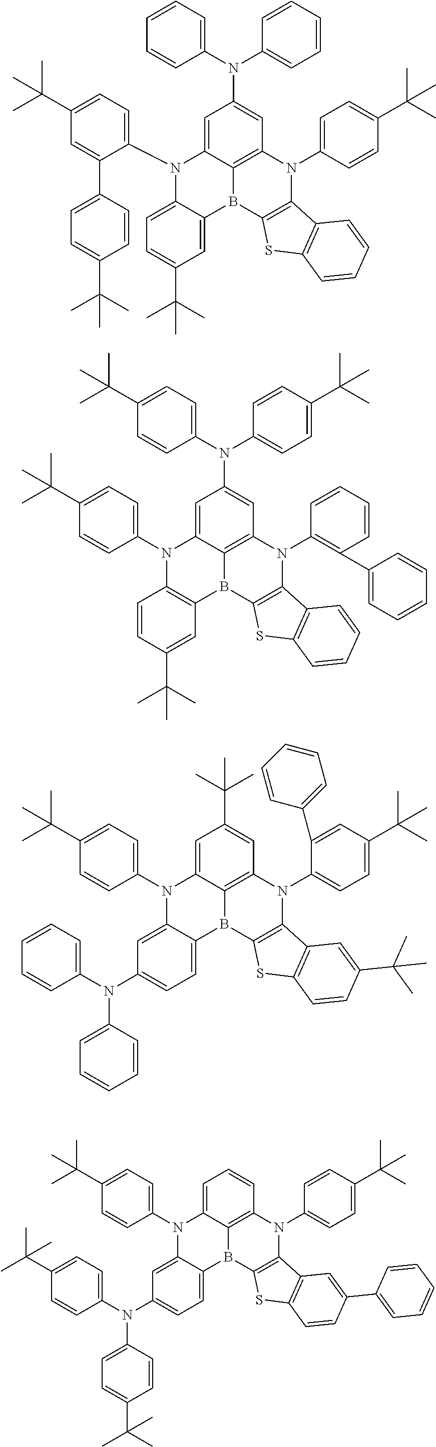

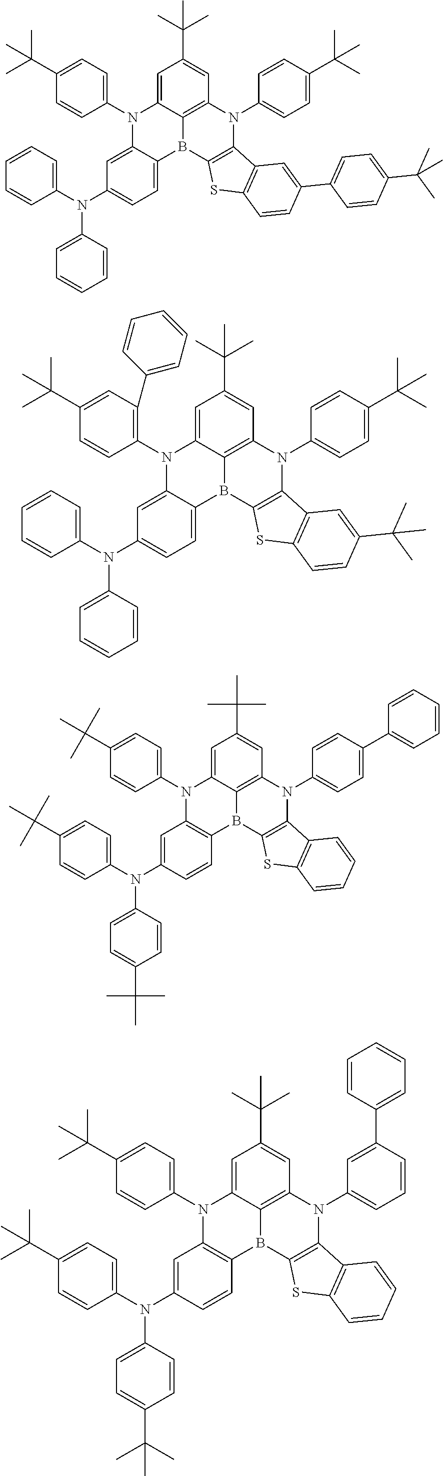

### Second Exemplary Embodiment

### Electronic Device

An electronic device according to the second exemplary embodiment is installed with the organic EL device according to any arrangement of the above exemplary embodiment. Examples of the electronic device include a display device and a light-emitting unit. Examples of the display device include, for instance, a display component (e.g., an organic EL panel module), TV, mobile phone, tablet and personal computer. Examples of the light-emitting unit include an illuminator and a vehicle light. The light-emitting unit can also be used for a display device, for instance, as a backlight of the display device.

### Modifications of Exemplary Embodiment

The scope of the invention is not limited by the above-described exemplary embodiments but includes any modification and improvement as long as such modification and improvement are compatible with the invention.

For instance, the number of the emitting layers included in the organic EL device is not limited to two, but three or more emitting layers may be layered. When the organic EL device includes three or more emitting layers, it is only necessary that at least two emitting layers (the first emitting layer and the second emitting layer) should satisfy the requirements described in the above exemplary embodiment(s). For instance, the rest of the emitting layers may be a fluorescent emitting layer or a phosphorescent emitting layer with the use of emission caused by electron transfer from the triplet excited state directly to the ground state.

When the organic EL device includes a plurality of emitting layers, these emitting layers may be mutually adjacently provided, or may form a so-called tandem organic EL device in which a plurality of emitting units are layered via an intermediate layer.

The specific structure, shape, and the like of the components in the invention may be designed in any manner as long as an object of the invention can be achieved.

### EXAMPLES

The invention will be described in further detail with reference to Examples. The scope of the invention is by no means limited to Examples.

### Compounds

Structures of compounds as the first host material used for producing organic EL devices in Examples 1 to 20 and Reference Examples 1 to 2 are given below.

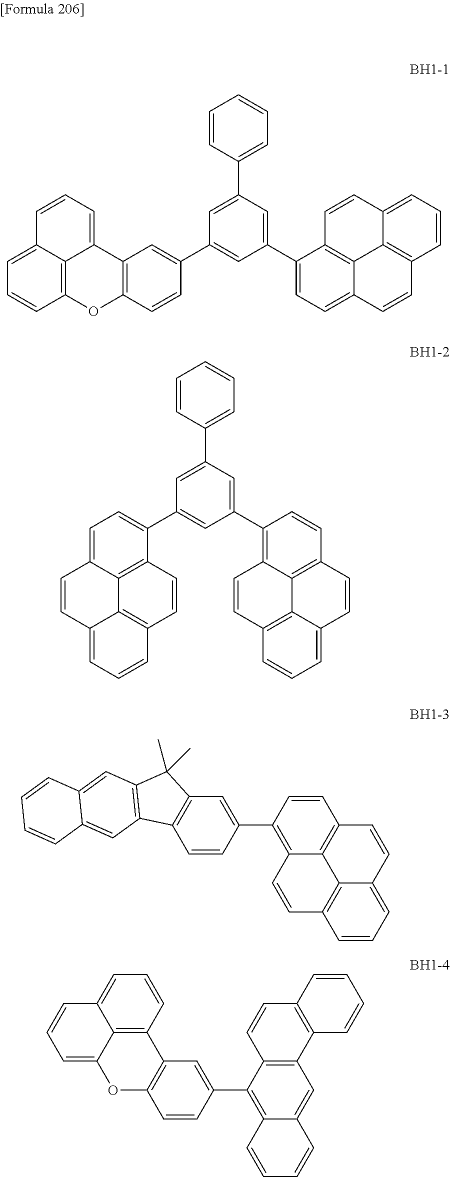

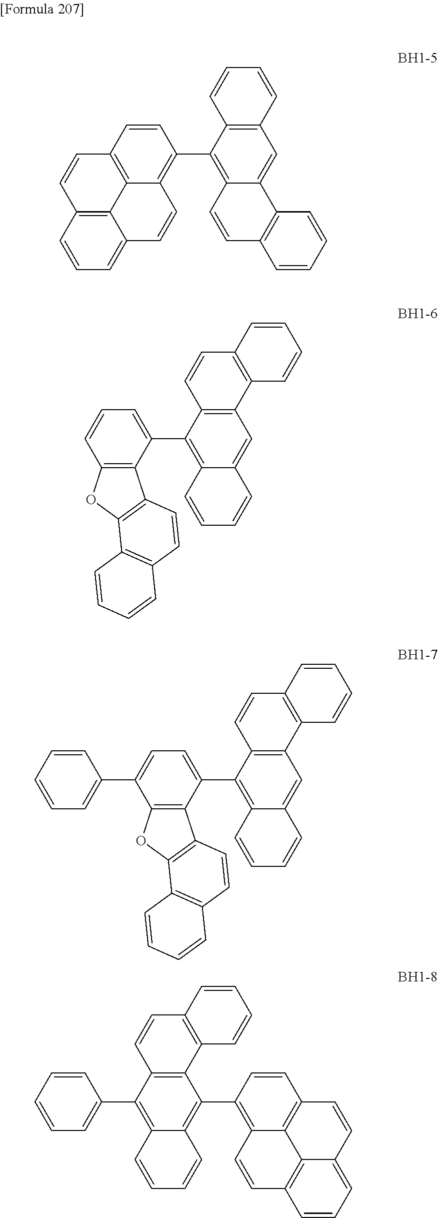

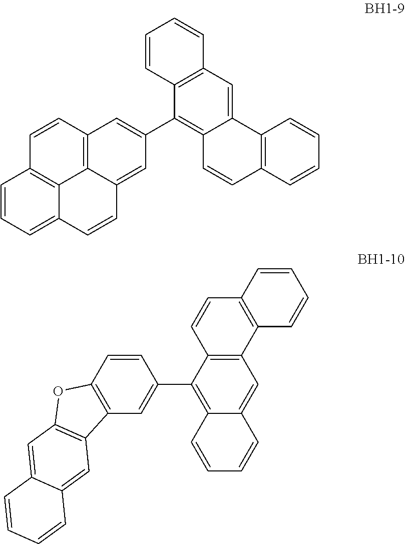

A structure of a compound as the second host material used for producing organic EL devices in Examples 1 to 20 and Reference Examples 1 to 2 is given below.

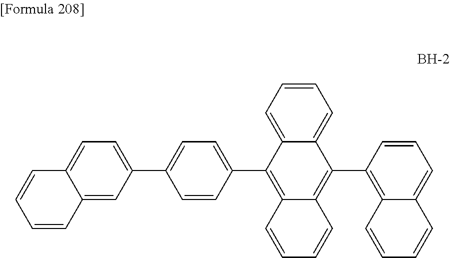 [SMILES: c1ccc2cc(-c3ccc(-c4c5ccccc5c(-c5cccc6ccccc56)c5ccccc45)cc3)ccc2c1]

Structures of the first luminescent compound or the second luminescent compound used for producing the organic EL devices in Examples 1 to 20 and Reference Examples 1 to 2 are given below.

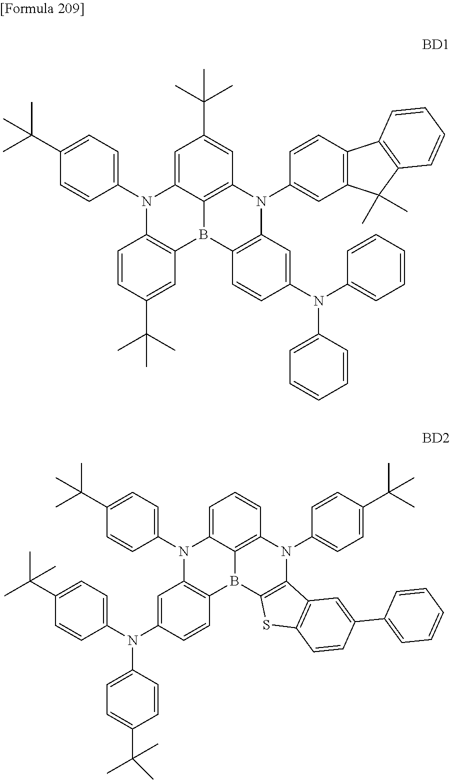 [SMILES: CC(C)(C)c1ccc(N2c3ccc(C(C)(C)C)cc3B3c4ccc(N(c5ccccc5)c5ccccc5)cc4N(c4ccc5c(c4)C(C)(C)c4ccccc4-5)c4cc(C(C)(C)C)cc2c43)cc1 ; CC(C)(C)c1ccc(N(c2ccc(C(C)(C)C)cc2)c2ccc3c(c2)N(c2ccc(C(C)(C)C)cc2)c2cccc4c2B3c2sc3ccc(-c5ccccc5)cc3c2N4c2ccc(C(C)(C)C)cc2)cc1]

Structures of other compounds used for producing organic EL devices in Examples 1 to 20 and Reference Examples 1 to 2 are given below.

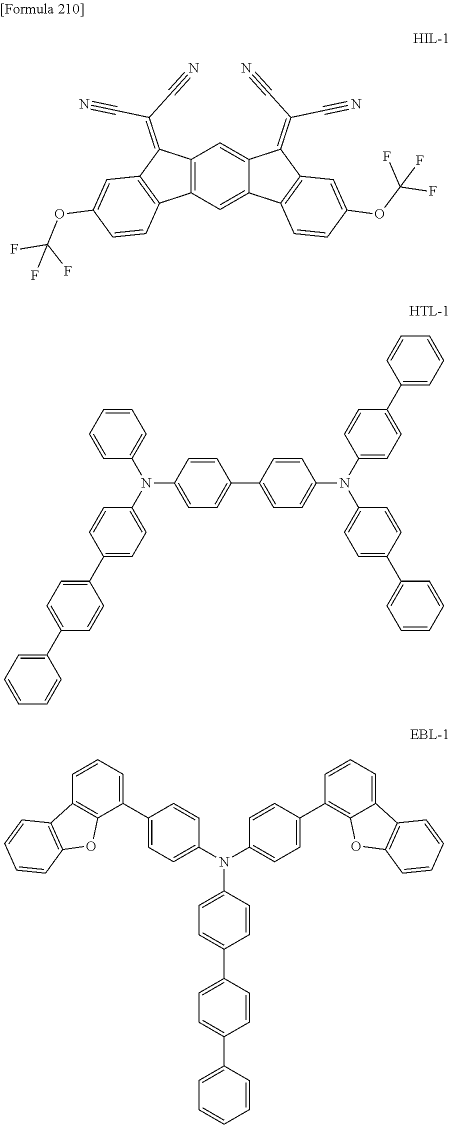 [SMILES: N#CC(C#N)=C1c2cc(OC(F)(F)F)ccc2-c2cc3c(cc21)C(=C(C#N)C#N)c1cc(OC(F)(F)F)ccc1-3 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1]

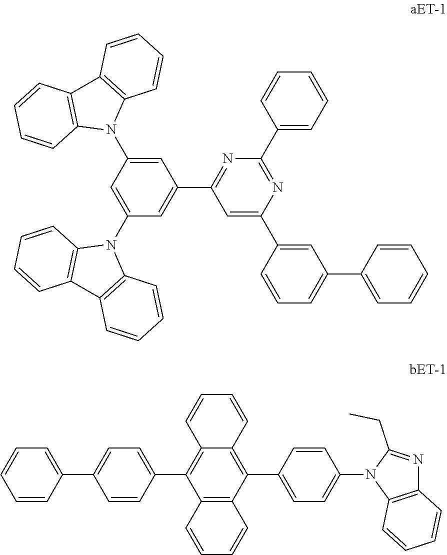 [SMILES: c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; CCc1nc2ccccc2n1-c1ccc(-c2c3ccccc3c(-c3ccc(-c4ccccc4)cc3)c3ccccc23)cc1]

### Production of Organic EL Device

The organic EL devices were produced and evaluated as follows.

### Example 1

A glass substrate (size: 25 mm×75 mm×1.1 mm thick, produced by Geomatec Co., Ltd.) having an indium tin oxide (ITO) transparent electrode (anode) was ultrasonic-cleaned in isopropyl alcohol for five minutes, and then UV-ozone-cleaned for 30 minutes. The film thickness of the ITO transparent electrode was 130 nm.

After the glass substrate having the transparent electrode line was cleaned, the glass substrate was mounted on a substrate holder of a vacuum deposition apparatus. Firstly, the compound HIL-1 was vapor-deposited on a surface of the glass substrate where the transparent electrode line was provided in a manner to cover the transparent electrode, thereby forming a 5-nm-thick hole injecting layer.

Subsequently, the compound HTL-1 was vapor-deposited on the hole injecting layer to form an 80-nm-thick first hole transporting layer.

Subsequently, the compound EBL-1 was vapor-deposited on the first hole transporting layer to form a 10-nm-thick second hole transporting layer (occasionally referred to as an electron blocking layer).

Subsequently, the compound BH1-1 (first host material) and the compound BD1 (first luminescent compound) were co-deposited on the second hole transporting layer, thereby forming a 5-nm-thick first emitting layer. The ratios of the compound BH1-1 and the compound BD1 in the first emitting layer were 98 mass % and 2 mass %, respectively.

Subsequently, the compound BH-2 (second host material) and the compound BD1 (second luminescent compound) were co-deposited on the first emitting layer, thereby forming a 20-nm-thick second emitting layer. The ratios of the compound BH-2 and the compound BD1 in the second emitting layer were 98 mass % and 2 mass %, respectively.

Subsequently, the compound aET-1 was vapor-deposited on the second emitting layer to form a 10-nm-thick first electron transporting layer (occasionally referred to as a hole blocking layer).

Subsequently, the compound bET-1 was vapor-deposited on the first electron transporting layer to form a 15-nm-thick second electron transporting layer.

Subsequently, the compound Liq was vapor-deposited on the second electron transporting layer to form a 1-nm-thick electron injecting layer. Liq is an abbreviation of (8-quinolinolato)lithium ((8-Quinolinolato)lithium).

Next, metal Al was vapor-deposited on the electron injecting layer to form an 80-nm-thick cathode.

A device arrangement of the organic EL device in Example 1 is roughly shown as follows.

$$ITO ( 1 \; 30 ) / HIL - 1 ( 5 ) / HTL - 1 ( 80 ) / EBL - 1 ( 10 ) / BH 1 - 1 : BD 1 ( 5.98 \% : 2 \% ) \text{} / BH - 2 : BD 1 ( 20.98 \% : 2 \% ) / aET - 1 ( 10 ) / bET - 1 ( 15 ) / Liq ( 1 ) / Al ( 80 )$$

In the device arrangement roughly shown above, numerals in parentheses each represent a film thickness (unit: nm). The numerals (98%:2%) represented by percentage in the same parentheses indicate a ratio (mass %) between the host material (the compound BH1-1 or BH-2) and the luminescent compound (the compound BD1) in the first emitting layer or the second emitting layer. Similar notations apply to the description below.

### Examples 2, 3 and 7 to 13

The organic EL devices in Examples 2, 3 and 7 to 13 were each produced as in Example 1 except that the compound BH1-1 as the first host material used for forming the first emitting layer was replaced with compounds shown in Table 1.

### Example 4

The organic EL device in Example 4 was produced as in Example 1 except that the compound BD1 as the first luminescent compound and the second luminescent compound was replaced with the compound BD2.

### Examples 5, 6 and 14 to 20

The organic EL devices in Examples 5, 6 and 14 to 20 were each produced as in Example 1 except that the compound BH1-1 as the first host material used for forming the first emitting layer was replaced with compounds shown in Table 2, and the compound BD1 as the first luminescent compound and the second luminescent compound was replaced with the compound BD2.

### Reference Example 1

The organic EL device in Reference Example 1 was produced as in Example 1 except that the first emitting layer and the second emitting layer in Example 1 were replaced with the second emitting layer only and a film thickness thereof was changed to 25 nm.

### Reference Example 2

The organic EL device in Reference Example 2 was produced as in Example 4 except that the first emitting layer and the second emitting layer in Example 4 were replaced with the second emitting layer only and a film thickness thereof was changed to 25 nm.

### Evaluation of Organic EL Devices

The organic EL devices produced in Examples 1 to 20 and Reference Examples 1 to 2 were evaluated as follows. Tables 1 to 2 show evaluation results.

First Orientation σ₁ and Second Orientation σ₂

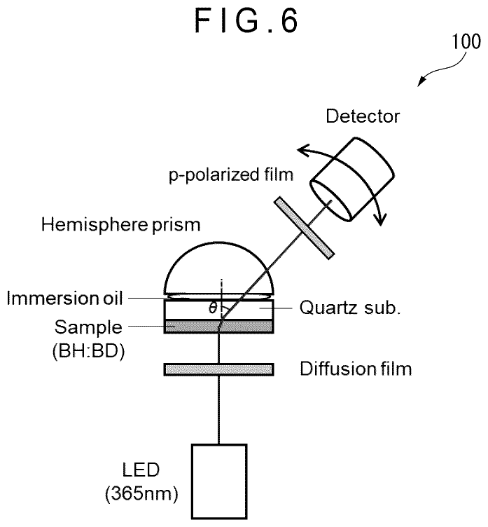

The orientation of the luminescent compound was calculated by comparing simulation results obtained using the optical simulation software Setfos 5.0 (produced by Fluxim AG) with experimental values obtained using an apparatus 100 illustrated in FIG. 6.

### Calculation of Experimental Value

A 50 nm-thick film (see “Sample (BH:BD)” illustrated in FIG. 6) containing a host material (see “BH” illustrated in FIG. 6) and a luminescent compound (see “BD” illustrated in FIG. 6) was formed by vacuum deposition on a quartz substrate (see “Quartz sub.” illustrated in FIG. 6) having a refractive index of 1.46 at 460 nm. A mass ratio of the host material and the luminescent compound in the film was 98:2, i.e., the host material: the luminescent compound=98:2.

The quartz substrate formed with the film was set on a jig of IMS-5000 system (the apparatus 100 illustrated in FIG. 6) manufactured by Asahi Spectra Co., Ltd. so that a surface of the film faced downwards.

Immersion oil (see “Immersion oil” illustrated in FIG. 6) having a refractive index of 1.515 was thinly applied to the quartz substrate, and a hemisphere prism (see “Hemisphere prism” illustrated in FIG. 6) was placed thereon so that air was prevented from entering between silicon oil and the hemisphere prism.

The surface of the film was irradiated from below with an LED light source (see “LED” illustrated in FIG. 6) having excitation light of 365 nm absorbed by the host material through a diffusion film (see “diffusion film” illustrated in FIG. 6) disposed in between, thereby bringing the host material into an excited state, and the photoluminescence spectrum measurement of emission of the luminescent compound energy-transferred from the host material was performed by a detector (see “Detector” illustrated in FIG. 6). The detector was provided with a p polarizer (see “p-polarized film” illustrated in FIG. 6), and it was possible to perform the spectrum measurement through the polarized film that was set so that only p polarized light was transmitted therethrough.

Since a measurement angle of the detector was changeable, the photoluminescence spectrum was measured in a wavelength range from 350 nm to 800 nm while the measurement angle was changed in three degree increments in a range from 0 degrees to 72 degrees, where a vertical direction was defined as 0 degrees.

### Calculation of Simulation Value

The optical simulation software Setfos 5.0 was activated, and a film thickness was input in the order of air/the host material: the luminescent compound/the quartz substrate/the immersion oil/the hemisphere prism so as to be the same as the film thickness in the experiment.

As the refractive indices of air, the quartz substrate, the immersion oil and the hemisphere prism, 1.00, 1.46, 1.515, and 1.52 were input, respectively. As the refractive index of the host material, n and k data files obtained through spectroscopic ellipsometry measurement were read.

Detection angular dependency of the p polarization intensity was calculated for each of values ranging from 0.70 to 1.00 of molecular orientation indicating a degree of orientation of the luminescent compound.

The obtained experimental values and the simulation values were superposed, and the value of the molecular orientation on a simulation curve that was most coincident with an experimental curve, in a detection angle range from 45 degrees to 72 degrees, was defined as a value of the orientation of the luminescent compound.

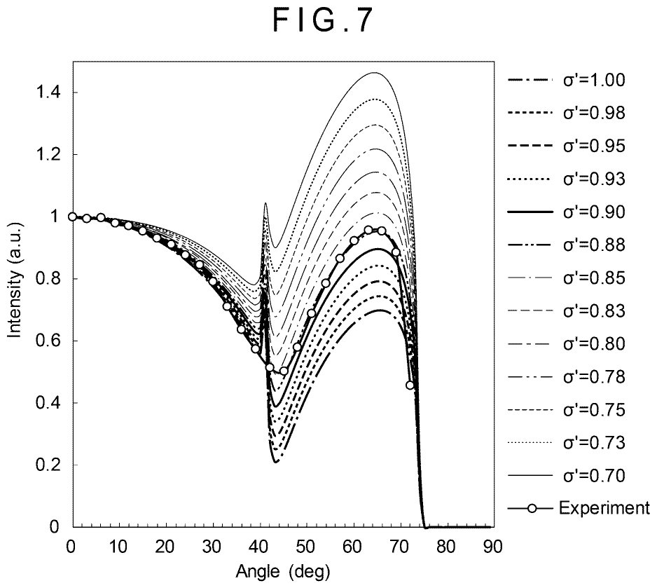

FIG. 7 illustrates an exemplary graph showing the experimental values and the simulation values, where the photoluminescence intensity of p polarized light at 465 nm of the photoluminescence spectrum (in a range from 350 nm to 800 nm) was plotted with respect to each detection angle. In FIG. 7, σ′ represents the molecular orientation. It is understood from FIG. 7 that the experimental value approximates the simulation value when the molecular orientation is 0.88.

### Relative Value of External Quantum Efficiency EQE

Voltage was applied to the organic EL devices such that a current density was 10 mA/cm², where spectral radiance spectrum was measured by a spectroradiometer CS-2000 (produced by Konica Minolta, Inc.). The external quantum efficiency EQE (unit: %) was calculated based on the obtained spectral radiance spectra, assuming that the spectra were provided under a Lambertian radiation.

Assuming that the EQE (%) of Reference Example 1 was 100, the EQE (%) of each of Examples (Examples 1 to 3, Examples 7 to 13, and Reference Example 1) was obtained as “EQE (relative value: %)” using a numerical formula (Numerical Formula 100) below.

$$E Q E ( relative value : \% ) of each Example = ( E Q E ( \% ) of each Example / E \text{} Q \text{} \text{} E \text{} ( \% ) of Reference Example 1 ) \times 100 \qquad ( Numerical Formula 100 )$$

Assuming that the EQE (%) of Reference Example 2 was 100, the EQE (%) of each of Examples (Examples 4 to 6, Examples 14 to 20, and Reference Example 2) was obtained as “EQE (relative value: %)” using a numerical formula (Numerical Formula 101) below.

$$E Q E ( relative value : \% ) of each Example = ( E Q E ( \% ) of each Example / E \text{} Q \text{} \text{} E \text{} ( \% ) of Reference Example 2 ) \times 100 \qquad ( Numerical Formula 101 )$$

### Relative Value of Luminous Efficiency EQE_{Prompt} of Prompt Luminescence Component

The external quantum efficiency EQE can be classified into luminous efficiency EQE_{Prompt} of a luminescence component (the prompt luminescence component (Prompt component)) from singlet excitons generated in first recombination, and luminous efficiency EQE_{TFT} of a luminescence component by the TTF mechanism. The luminous efficiency EQE_{Prompt} is obtained by calculating the ratio of luminous intensity derived from TTF and subtracting the luminous efficiency EQE_{TFT} from the external quantum efficiency EQE.

The ratio of luminous intensity derived from TTF is measurable by a transient EL method. The transient EL method is a method for measuring attenuation behavior (transient property) of EL emission after DC voltage applied on the device is removed. The EL luminous intensity is classified into a luminescence component from singlet excitons generated in the first recombination and a luminescence component from singlet excitons generated through the TTF phenomenon. Since lifetime of the singlet excitons is very short at a nanosecond order, the EL emission is rapidly attenuated after the removal of DC voltage.

On the other hand, since the TTF phenomenon provides emission from singlet excitons generated through long-life triplet excitons, the EL emission is gradually attenuated. Thus, since there is a large difference in time between the emission from the singlet excitons and the emission from the triplet excitons, the luminous intensity derived from TTF is obtainable. Specifically, the luminous intensity can be determined by the following method.

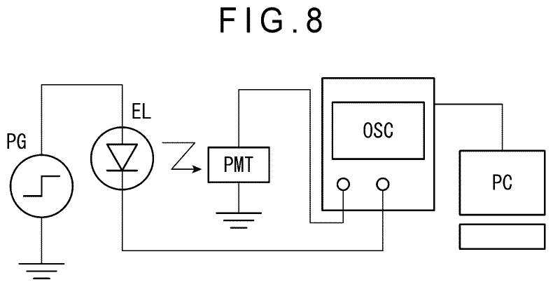

Transient EL waveform is measured as follows (see FIG. 8). Pulse voltage waveform output from a voltage pulse generator (PG) is applied on an EL device. The applied voltage waveform is loaded in an oscilloscope (OSC). When pulse voltage is applied on the EL device, the EL device generates pulse emission. This emission is loaded in the oscilloscope (OSC) through a photomultiplier (PMT). The voltage waveform and the pulse emission are synchronized and loaded in a personal computer (PC).

The ratio of luminous intensity derived from TTF is determined as follows based on analysis of the transient EL waveform.

A rate equation for attenuation behavior of triplet excitons is solved, and the attenuation behavior of luminous intensity based on the TTF phenomenon is brought into modeling. Time-varying attenuation of a density n_{T} of triplet excitons within the emitting layer is expressed by the following rate equation using an attenuation speed v_{A} due to lifetime of the triplet excitons and an attenuation speed v_{C} caused by collision of the triplet excitons.

$$\frac{{dn}_{T}}{dt} = - {v}_{A} \cdot {n}_{T} - {v}_{C} \cdot {n}_{T}^{2} \qquad [ Numerical Formula 11 ]$$

When the above differential equation is approximately solved, the following formula is obtained. Herein, ITTF represents luminous intensity derived from TTF, and A is a constant. Thus, when the transient EL emission is based on TTF, an inverse number of the square root of the intensity of the transient EL emission is shown approximately in a linear line. The measured transient EL waveform data is fit in the following approximate expression to obtain the constant A. At this time, luminous intensity 1/A² at the time t=0 when the DC voltage is removed is defined as the ratio of luminous intensity derived from TTF.

$$\frac{1}{\sqrt{{I}_{TTF}}} ∝ A + {v}_{C} \cdot t \qquad [ Numerical Formula 12 ]$$

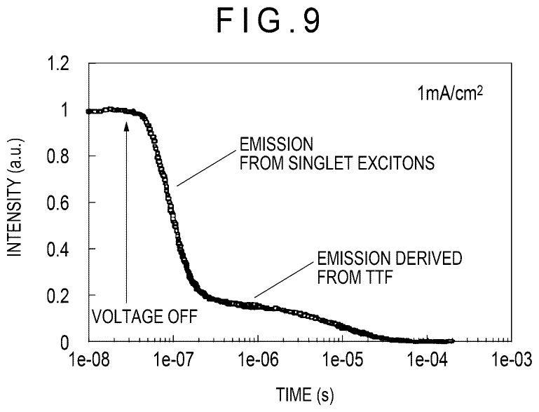

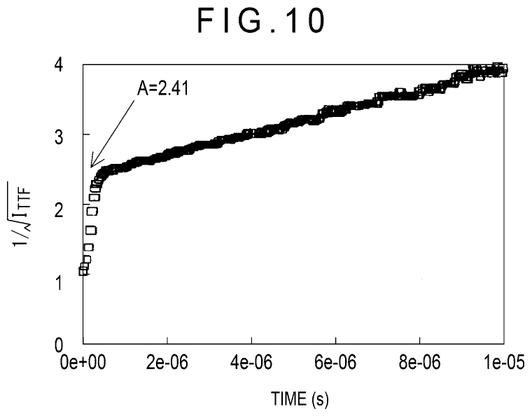

A graph of FIG. 9 illustrates a measurement example where a predetermined DC voltage was applied on the EL device and then the DC voltage was removed, which shows time-varying luminous intensity of the EL device. The DC voltage was removed at the time of about 3×10⁻⁸ seconds in the graph of FIG. 9. In the graph, the luminance when the voltage was removed is defined as 1. After rapid attenuation before the elapse of about 2×10⁻⁷ seconds, a gradual attenuation component appears. In the graph of FIG. 10, the voltage removal time is a starting point and the inverse numbers of the square root of luminous intensity before the elapse of 10⁻⁵ seconds after voltage removal are plotted in an approximately linear line. A value at an intersection A of the ordinate axis and the linear line extended to the starting point is 2.41. Accordingly, the ratio of luminous intensity derived from TTF obtained from the transient EL waveform is 1/2.41²=0.17, which means that 17% of the entire luminous intensity is derived from TTF.

The luminous intensity is preferably fitted in a linear line by the method of least squares. In this case, the luminous intensity before the elapse of 10⁻⁵ seconds is preferably fitted.

The luminous efficiency EQE_{Prompt} from singlet excitons generated in the first recombination (the luminous efficiency EQE_{Prompt} of the prompt luminescence component (Prompt component)) (unit: %) is obtained in a numerical formula below, using the external quantum efficiency EQE (unit: %) of the entire device.

$${EQE}_{Prompt} = EQE \cdot ( 1 - \frac{1}{{A}^{2}} ) \qquad [ Numerical Formula 13 ]$$

Organic EL devices of Examples and Reference Examples were prepared in the method described above, voltage pulse waveform (pulse width: 500 micro second, frequency: 20 Hz, voltage: equivalent to 0.1 to 100 mA/cm²) output from a pulse generator (8114A: manufactured by Agilent Technologies) was applied. EL emission was input in a photomultiplier (R928: manufactured by Hamamatsu Photonics K.K.). The pulse voltage waveform and the EL emission were synchronized and loaded in an oscilloscope (2440: manufactured by Tektronix) to obtain a transient EL waveform.

Voltage was applied on the organic EL devices of Examples and Reference Examples at the room temperature. The pulse voltage was removed at the time of about 3×10⁻⁸ seconds.

The prompt luminous efficiency EQE_{Prompt} (unit: %) at a current density of 10 mA/cm² was obtained, by performing analysis based on the graph, where the voltage removal time was a starting point and the inverse numbers of the square root of luminous intensity before the elapse of 1.5×10⁻⁵ seconds after voltage removal were plotted.

Assuming that the prompt luminous efficiency EQE_{Prompt} (%) of Reference Example 1 was 100, the EQE_{Prompt} (%) of each of Examples (Examples 1 to 3, Examples 7 to 13, and Reference Example 1) was obtained as “EQE_{Prompt} (relative value: %)” using a numerical formula (Numerical Formula 102) below.

$$E Q {E}_{Prompt} ( relative value : \% ) of each Example = ( E Q {E}_{Prompt} ( \% ) of each Example / E Q \text{} {E}_{Prompt} ( \% ) of Reference Example 1 ) \times 100 \qquad ( Numerical Formula 102 )$$

Assuming that the prompt luminous efficiency EQE_{Prompt} (%) of Reference Example 2 was 100, the EQE_{Prompt} (%) of each of Examples (Examples 4 to 6, Examples 14 to 20, and Reference Example 2) was obtained as “EQE_{Prompt} (relative value: %)” using a numerical formula (Numerical Formula 103) below.

$$E Q {E}_{Prompt} ( relative value : \% ) of each Example = ( E Q {E}_{Prompt} ( \% ) of each Example / E Q \text{} {E}_{Prompt} ( \% ) of Reference Example 2 ) \times 100 \qquad ( Numerical Formula 103 )$$

### |λ1−λ21 and |FWHM1−FWHM2|

The first and second films were prepared by the above-described method, and the maximum peak wavelength λ1 and the full width at half maximum FWHM1 of the photoluminescence spectrum of the first film (having the same configuration as that of the first emitting layer) and the maximum peak wavelength λ2 and the full width at half maximum FWHM2 of the photoluminescence spectrum of the second film (having the same configuration as that of the second emitting layer) were measured. FWHM is an abbreviation of Full Width at Half Maximum.

|λ1−λ2| (unit: nm) and |FWHM1−FWHM2| (unit: nm) were calculated from the obtained values.

In Tables 1 and 2, Δλ represents |λ1−λ21, and ΔFWHM represents |FWHM1−FWHM2|.

TABLE 1

| | | | | | | | Second Emitting Layer | | | |
|---|---|---|---|---|---|---|---|---|---|---|
| | First Emitting Layer | | | | | | | | | Second |
| | First Host Material | | | First Luminescent Compound | | | Second Host Material | | | Luminescent |
| | | S₁ | T₁ | | S₁ | T₁ | | S₁ | T₁ | Compound |
| | Name | (eV) | (eV) | Name | (eV) | (eV) | Name | (eV) | (eV) | Name |
| Ex. 1 | BH1-1 | 3.08 | 2.09 | BD1 | 2.70 | 2.64 | BH-2 | 3.01 | 1.87 | BD1 |
| Ex. 2 | BH1-2 | 3.31 | 2.09 | BD1 | 2.70 | 2.64 | BH-2 | 3.01 | 1.87 | BD1 |
| Ex. 3 | BH1-3 | 3.15 | 2.10 | BD1 | 2.70 | 2.64 | BH-2 | 3.01 | 1.87 | BD1 |
| Ex. 7 | BH1-4 | 3.08 | 2.07 | BD1 | 2.70 | 2.64 | BH-2 | 3.01 | 1.87 | BD1 |
| Ex. 8 | BH1-5 | 3.08 | 2.07 | BD1 | 2.70 | 2.64 | BH-2 | 3.01 | 1.87 | BD1 |
| Ex. 9 | BH1-6 | 3.11 | 2.07 | BD1 | 2.70 | 2.64 | BH-2 | 3.01 | 1.87 | BD1 |
| Ex. 10 | BH1-7 | 3.09 | 2.07 | BD1 | 2.70 | 2.64 | BH-2 | 3.01 | 1.87 | BD1 |
| Ex. 11 | BH1-8 | 3.02 | 2.05 | BD1 | 2.70 | 2.64 | BH-2 | 3.01 | 1.87 | BD1 |
| Ex. 12 | BH1-9 | 3.11 | 2.08 | BD1 | 2.70 | 2.64 | BH-2 | 3.01 | 1.87 | BD1 |
| Ex. 13 | BH1-10 | 3.19 | 2.08 | BD1 | 2.70 | 2.64 | BH-2 | 3.01 | 1.87 | BD1 |
| Ref. Ex. 1 | — | — | — | — | — | — | BH-2 | 3.01 | 1.87 | BD1 |

| | | | | Device Evaluation Results | | | |
|---|---|---|---|---|---|---|---|
| | Orientation of | | | EQE | | | |
| | Luminescent Compound | | | prompt | EQE | | |
| | First | Second | | (Relative | (Relative | | |
| | Orientation | Orientation | | Value) | Value) | \| Δλ \| | \| ΔFWHM \| |
| | (σ₁) | (σ₂) | σ₁/σ₂ | (%) | (%) | (nm) | (nm) |
| Ex. 1 | 0.88 | 0.90 | 0.98 | 98.1 | 107.3 | 1 | 1 |
| Ex. 2 | 0.88 | 0.90 | 0.98 | 98.0 | 108.9 | 2 | 2 |
| Ex. 3 | 0.83 | 0.90 | 0.92 | 94.9 | 103.7 | 2 | 2 |
| Ex. 7 | 0.86 | 0.90 | 0.96 | 95.9 | 108.9 | 1 | 0 |
| Ex. 8 | 0.90 | 0.90 | 1.00 | 99.7 | 109.4 | 2 | 1 |
| Ex. 9 | 0.90 | 0.90 | 1.00 | 100.3 | 111.3 | 1 | 0 |
| Ex. 10 | 0.90 | 0.90 | 1.00 | 100.0 | 110.2 | 1 | 0 |
| Ex. 11 | 0.90 | 0.90 | 1.00 | 99.9 | 111.7 | 1 | 0 |
| Ex. 12 | 0.89 | 0.90 | 0.99 | 99.0 | 107.8 | 1 | 1 |
| Ex. 13 | 0.90 | 0.90 | 1.00 | 99.3 | 110.0 | 0 | 1 |
| Ref. Ex. 1 | — | 0.90 | — | 100.0 | 100.0 | — | — |

TABLE 2

| | | | | | | | Second Emitting Layer | | | |
|---|---|---|---|---|---|---|---|---|---|---|
| | First Emitting Layer | | | | | | | | | Second |
| | First Host Material | | | First Luminescent Compound | | | Second Host Material | | | Luminescent |
| | | S₁ | T₁ | | S₁ | T₁ | | S₁ | T₁ | Compound |
| | Name | (eV) | (eV) | Name | (eV) | (eV) | Name | (eV) | (eV) | Name |
| Ex. 4 | BH1-1 | 3.08 | 2.09 | BD2 | 2.70 | 2.41 | BH-2 | 3.01 | 1.87 | BD2 |
| Ex. 5 | BH1-2 | 3.31 | 2.09 | BD2 | 2.70 | 2.41 | BH-2 | 3.01 | 1.87 | BD2 |
| Ex. 6 | BH1-3 | 3.15 | 2.10 | BD2 | 2.70 | 2.41 | BH-2 | 3.01 | 1.87 | BD2 |
| Ex. 14 | BH1-4 | 3.08 | 2.07 | BD2 | 2.70 | 2.41 | BH-2 | 3.01 | 1.87 | BD2 |
| Ex. 15 | BH1-5 | 3.08 | 2.07 | BD2 | 2.70 | 2.41 | BH-2 | 3.01 | 1.87 | BD2 |
| Ex. 16 | BH1-6 | 3.11 | 2.07 | BD2 | 2.70 | 2.41 | BH-2 | 3.01 | 1.87 | BD2 |
| Ex. 17 | BH1-7 | 3.09 | 2.07 | BD2 | 2.70 | 2.41 | BH-2 | 3.01 | 1.87 | BD2 |
| Ex. 18 | BH1-8 | 3.02 | 2.05 | BD2 | 2.70 | 2.41 | BH-2 | 3.01 | 1.87 | BD2 |
| Ex. 19 | BH1-9 | 3.11 | 2.08 | BD2 | 2.70 | 2.41 | BH-2 | 3.01 | 1.87 | BD2 |
| Ex. 20 | BH1-10 | 3.19 | 2.08 | BD2 | 2.70 | 2.41 | BH-2 | 3.01 | 1.87 | BD2 |
| Ref. Ex. 2 | — | — | — | — | — | — | BH-2 | 3.01 | 1.87 | BD2 |

| | | | | Device Evaluation Results | | | |
|---|---|---|---|---|---|---|---|
| | Orientation of | | | EQE | | | |
| | Luminescent Compound | | | prompt | EQE | | |
| | First | Second | | (Relative | (Relative | | |
| | Orientation | Orientation | | Value) | Value) | \| Δλ \| | \| ΔFWHM \| |
| | (σ₁) | (σ₂) | σ₁/σ₂ | (%) | (%) | (nm) | (nm) |
| Ex. 4 | 0.90 | 0.92 | 0.98 | 98.3 | 107.8 | 1 | 2 |
| Ex. 5 | 0.89 | 0.92 | 0.97 | 97.1 | 108.2 | 2 | 2 |
| Ex. 6 | 0.85 | 0.92 | 0.92 | 94.5 | 104.2 | 2 | 2 |
| Ex. 14 | 0.90 | 0.92 | 0.98 | 98.6 | 107.2 | 1 | 0 |
| Ex. 15 | 0.92 | 0.92 | 1.00 | 99.4 | 109.7 | 1 | 2 |
| Ex. 16 | 0.92 | 0.92 | 1.00 | 100.3 | 111.8 | 1 | 1 |
| Ex. 17 | 0.90 | 0.92 | 0.98 | 98.8 | 110.3 | 1 | 1 |
| Ex. 18 | 0.92 | 0.92 | 1.00 | 99.8 | 111.3 | 1 | 1 |
| Ex. 19 | 0.90 | 0.92 | 0.98 | 98.5 | 108.0 | 1 | 2 |
| Ex. 20 | 0.90 | 0.92 | 0.98 | 98.8 | 108.6 | 1 | 2 |
| Ref. Ex. 2 | — | 0.92 | — | 100.0 | 100.0 | — | — |

In the organic EL devices in Examples 1 to 20, when the relationships of the numerical formulae (Numerical Formula 1 and Numerical Formula 2) were satisfied, the external quantum efficiency EQE was improved, resulting in improving the luminous efficiency of the entire device.

In the organic EL devices in Examples 1 to 3 and Examples 7 to 13, as the value of σ₁/σ₂ was closer to 1, the prompt luminous efficiency EQE_{Prompt} was closer to the prompt luminous efficiency EQE_{Prompt} of Reference Example 1, thereby improving the light extraction efficiency of the prompt luminescence component in the first emitting layer.

In the organic EL devices in Examples 4 to 6 and Examples 14 to 20, as the value of σ₁/σ₂ was closer to 1, the prompt luminous efficiency EQE_{Prompt} was closer to the prompt luminous efficiency EQE_{Prompt} of Reference Example 2, thereby improving the light extraction efficiency of the prompt luminescence component in the first emitting layer.

From the above-described results, in the organic EL devices in Examples 1 to 20, when the relationships of the numerical formulae (Numerical Formula 1 and Numerical Formula 2) were satisfied, the organic EL devices with improved luminous efficiency were obtainable irrespective of the structure of the first host material used for forming the first emitting layer.

### Evaluation on Compounds

The compounds used for producing the organic EL device were evaluated by a method below.

### Triplet Energy T₁

A measurement target compound was dissolved in EPA (diethylether isopentane:ethanol=5:5:2 in volume ratio) at a concentration of 10 μmol/L, and the obtained solution was put in a quartz cell to provide a measurement sample. A phosphorescence spectrum (ordinate axis: phosphorescent luminous intensity, abscissa axis: wavelength) of the measurement sample was measured at a low temperature (77K). A tangent was drawn to the rise of the phosphorescence spectrum close to the short-wavelength region. An energy amount was calculated by a conversion equation (F1) below on a basis of a wavelength value λ_{edge} [nm] at an intersection of the tangent and the abscissa axis. The calculated energy amount was defined as triplet energy T₁. It should be noted that the triplet energy T₁ may have an error of about plus or minus 0.02 eV depending on measurement conditions.

$$Conversion Equation ( F 1 ) : {T}_{1} [ eV ] = 1239 \text{.85} / {λ}_{edge}$$

The tangent to the rise of the phosphorescence spectrum close to the short-wavelength region is drawn as follows. While moving on a curve of the phosphorescence spectrum from the short-wavelength region to the local maximum value closest to the short-wavelength region among the local maximum values of the phosphorescence spectrum, a tangent is checked at each point on the curve toward the long-wavelength of the phosphorescence spectrum. An inclination of the tangent is increased along the rise of the curve (i.e., a value of the ordinate axis is increased). A tangent drawn at a point of the local maximum inclination (i.e., a tangent at an inflection point) is defined as the tangent to the rise of the phosphorescence spectrum close to the short-wavelength region.

A local maximum point where a peak intensity is 15% or less of the maximum peak intensity of the spectrum is not counted as the above-mentioned local maximum peak intensity closest to the short-wavelength region. The tangent drawn at a point that is closest to the local maximum peak intensity closest to the short-wavelength region and where the inclination of the curve is the local maximum is defined as a tangent to the rise of the phosphorescence spectrum close to the short-wavelength region.

For phosphorescence measurement, a spectrophotofluorometer body F-4500 produced by Hitachi High-Technologies Corporation was used.

### Singlet Energy S₁

A toluene solution of a measurement target compound at a concentration of 10 μmol/L was prepared and put in a quartz cell. An absorption spectrum (ordinate axis: absorption intensity, abscissa axis: wavelength) of the thus-obtained sample was measured at a normal temperature (300K). A tangent was drawn to the fall of the absorption spectrum close to the long-wavelength region, and a wavelength value λ_{edge} [nm] at an intersection of the tangent and the abscissa axis was assigned to a conversion equation (F2) below to calculate a singlet energy.

$$Conversion Equation ( F 2 ) : {S}_{1} [ eV ] = 1239 \text{.85} / {λ}_{edge}$$

A spectrophotometer (U3310 manufactured by Hitachi, Ltd.) was used for measuring absorption spectrum.

The tangent to the fall of the absorption spectrum close to the long-wavelength region is drawn as follows. While moving on a curve of the absorption spectrum from the local maximum value closest to the long-wavelength region, among the local maximum values of the absorption spectrum, in a long-wavelength direction, a tangent at each point on the curve is checked. An inclination of the tangent is decreased and increased in a repeated manner as the curve falls (i.e., a value of the ordinate axis is decreased). A tangent drawn at a point where the inclination of the curve is the local minimum closest to the long-wavelength region (except when absorbance is 0.1 or less) is defined as the tangent to the fall of the absorption spectrum close to the long-wavelength region.

The local maximum absorbance of 0.2 or less is not counted as the above-mentioned local maximum absorbance closest to the long-wavelength region.

### Maximum Peak Wavelength of Compounds

A maximum peak wavelength λ_{SOL} of each compound was measured by a method below.

A toluene solution of the measurement target compound at a concentration of 5 μmol/L was prepared and put in a quartz cell. An emission spectrum (ordinate axis: luminous intensity, abscissa axis: wavelength) of the thus-obtained sample was measured at a normal temperature (300K). In Examples, the emission spectrum was measured with a spectrophotofluorometer (apparatus name: F-7000) produced by Hitachi High-Tech Corporation. It should be noted that the apparatus for measuring the emission spectrum is not limited to the apparatus used herein. A peak wavelength of the emission spectrum exhibiting the maximum luminous intensity was defined as the maximum peak wavelength λ_{SOL}.

The maximum peak wavelength λ_{SOL} of the compound BD1 was 458 nm.

The maximum peak wavelength λ_{SOL} of the compound BD2 was 456 nm.

### EXPLANATION OF CODES

1 . . . organic EL device, 2 . . . substrate, 3 . . . anode, 4 . . . cathode, 51 . . . first emitting layer, 52 . . . second emitting layer, 6 . . . hole injecting layer, 7 . . . hole transporting layer, 8 . . . electron transporting layer, 9 . . . electron injecting layer.

1: An organic electroluminescence device comprising:
an anode;
a cathode; and
an emitting region between the anode and the cathode, wherein
the emitting region includes a first emitting layer and a second emitting layer,
the first emitting layer contains a first host material and a first luminescent compound,
the second emitting layer contains a second host material and a second luminescent compound,
the first host material and the second host material are mutually different,
the first luminescent compound and the second luminescent compound are mutually the same or different,
a triplet energy of the first host material T₁(H1) and a triplet energy of the second host material T₁(H2) satisfy a relationship of a numerical formula (Numerical Formula 1) below,
the first luminescent compound exhibits a first orientation (σ₁) in a first film containing the first host material and the first luminescent compound,
the second luminescent compound exhibits a second orientation (σ₂) in a second film containing the second host material and the second luminescent compound, and
a ratio of the first orientation (σ₁) to the second orientation (σ₂) satisfies a relationship of a numerical formula (Numerical Formula 2) below,
$${T}_{1} ( H 1 ) > {T}_{1} ( H 2 ) \qquad ( Numerical Formula 1 )$$
$${σ}_{1} / {σ}_{2} \geq 0.9 . \qquad ( Numerical Formula 2 )$$

2: The organic electroluminescence device according to claim 1, wherein the first orientation (σ₁) is 0.80 or more.

3: The organic electroluminescence device according to claim 1, wherein the second orientation (σ₂) is 0.90 or more.

4: The organic electroluminescence device according to claim 1, wherein a maximum peak wavelength λ1 and a full width at half maximum FWHM1 of a photoluminescence spectrum of the first film, and a maximum peak wavelength λ2 and a full width at half maximum FWHM2 of a photoluminescence spectrum of the second film satisfy numerical formulae (Numerical Formula 20 and Numerical Formula 30) below,
$$\vert λ1 - λ2 \vert \leq 3 nm \qquad ( Numerical Formula 20 )$$
$$\vert FWHM 1 - FWHM 2 \vert \leq 2 nm . \qquad ( Numerical Formula 30 )$$

5: The organic electroluminescence device according to claim 1, wherein the first emitting layer is disposed between the anode and the second emitting layer.

6: The organic electroluminescence device according to claim 1, wherein the first emitting layer and the second emitting layer are in direct contact with each other.

7: The organic electroluminescence device according to claim 1, wherein a triplet energy of the first luminescent compound T₁(D1) and the triplet energy of the first host material T₁(H1) satisfy a relationship of a numerical formula (Numerical Formula 3) below,
$${T}_{1} ( D 1 ) > {T}_{1} ( H 1 ) . \qquad ( Numerical Formula 3 )$$

8: The organic electroluminescence device according to claim 1, wherein a singlet energy of the first host material S₁(H1) and a singlet energy of the first luminescent compound S₁(D1) satisfy a relationship of a numerical formula (Numerical Formula 4) below,
$${S}_{1} ( H 1 ) > {S}_{1} ( D 1 ) . \qquad ( Numerical Formula 4 )$$

9: The organic electroluminescence device according to claim 1, wherein a triplet energy of the second luminescent compound T₁(D2) and the triplet energy of the second host material T₁(H2) satisfy a relationship of a numerical formula (Numerical Formula 5) below,
$${T}_{1} ( D 2 ) > {T}_{1} ( H 2 ) . \qquad ( Numerical Formula 5 )$$

10: The organic electroluminescence device according to claim 1, wherein a singlet energy of the second host material S₁(H2) and a singlet energy of the second luminescent compound S₁(D2) satisfy a relationship of a numerical formula (Numerical Formula 6) below,
$${S}_{1} ( H 2 ) > {S}_{1} ( D 2 ) . \qquad ( Numerical Formula 6 )$$

11: The organic electroluminescence device according to claim 1, wherein the first luminescent compound and the second luminescent compound are each independently a compound that emits light having a maximum peak wavelength of 500 nm or less.

12: The organic electroluminescence device according to claim 1, wherein the first luminescent compound and the second luminescent compound are each independently represented by a formula (6) below, 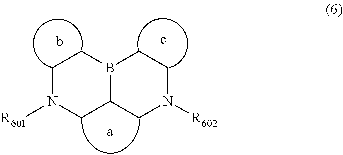
where, in the formula (6):
a ring a, a ring b and a ring c are each independently a substituted or unsubstituted aromatic hydrocarbon ring having 6 to 50 ring carbon atoms, or a substituted or unsubstituted heterocycle having 5 to 50 ring atoms;
R₆₀₁ and R₆₀₂ are each independently bonded with the ring a, the ring b or the ring c to form a substituted or unsubstituted heterocycle, or not bonded therewith to form no substituted or unsubstituted heterocycle; and
R₆₀₁ and R₆₀₂ not forming the substituted or unsubstituted heterocycle are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

13: The organic electroluminescence device according to claim 12, wherein
at least one ring of the ring a, the ring b or the ring c has at least one group represented by —N(R_{6A})(R_{6B}),
R_{6A} and R_{6B} are each independently a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms;
when two or more R_{6A} are present, the two or more R_{6A} are mutually the same or different; and
when two or more R_{6B} are present, the two or more R_{6B} are mutually the same or different.

14: The organic electroluminescence device according to claim 1, wherein
the first host material has, in a molecule, a linking structure including a benzene ring and a naphthalene ring that are linked to each other with a single bond,
the benzene ring and the naphthalene ring in the linking structure are each independently fused or not fused with a further monocyclic ring or fused ring, and
the benzene ring and the naphthalene ring in the linking structure are further linked to each other by cross-linking at at least one site other than the single bond.

15: The organic electroluminescence device according to claim 14,
wherein the cross-linking includes a double bond.

16: The organic electroluminescence device according to claim 1, wherein
the first host material has, in a molecule, a biphenyl structure including a first benzene ring and a second benzene ring linked to each other with a single bond, and
the first benzene ring and the second benzene ring in the biphenyl structure are further linked to each other by cross-linking at at least one site other than the single bond.

17: The organic electroluminescence device according to claim 16, wherein the first benzene ring and the second benzene ring in the biphenyl structure are further linked to each other by the cross-linking at one site other than the single bond.

18: The organic electroluminescence device according to claim 16, wherein the cross-linking includes a double bond.

19: The organic electroluminescence device according to claim 16, wherein
the first benzene ring and the second benzene ring in the biphenyl structure are further linked to each other by the cross-linking at two sites other than the single bond, and
the cross-linking includes no double bond.

20-22. (canceled)

23: An electronic device comprising the organic electroluminescence device according to claim 1.
